(19) United States
(12) Patent Application Publication
(10) Pub. No.: US 2025/0113733 A1
(43) Pub. Date: Apr. 3, 2025

(54) LIGHT EMITTING ELEMENT, POLYCYCLIC COMPOUND FOR THE LIGHT EMITTING ELEMENT, AND DISPLAY DEVICE INCLUDING THE LIGHT EMITTING ELEMENT

(71) Applicant: Samsung Display Co., Ltd., Yongin-si (KR)

(72) Inventors: SERAN KIM, Yongin-si (KR); HOI-LIM KIM, Yongin-si (KR); SAE ROM PARK, Yongin-si (KR); SEUNGIN BAEK, Yongin-si (KR); Dongsun YOO, Yongin-si (KR)

(73) Assignee: Samsung Display Co., Ltd., Yongin-si (KR)

(21) Appl. No.: 18/678,240

(22) Filed: May 30, 2024

(30) Foreign Application Priority Data
Aug. 14, 2023 (KR) 10-2023-0106403

(51) Int. Cl. H10K 85/60; C07F 5/02; C09K 11/06; H10K 50/12

(52) U.S. Cl. CPC H10K 85/658; C07F 5/027; C09K 11/06; C07B 2200/05; C09K 2211/1018; H10K 50/12

(57) ABSTRACT

Embodiments provide a polycyclic compound, a light emitting element including the polycyclic compound, and a display device including the light emitting element. The light emitting element includes a first electrode, a second electrode disposed on the first electrode, and a light emitting layer disposed between the first electrode and the second electrode. The light emitting layer includes a polycyclic compound represented by Formula 1, which is explained in the specification:

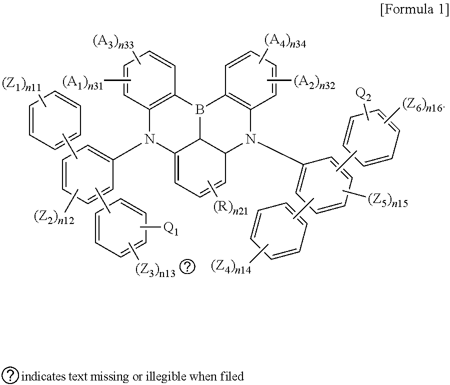

### CROSS-REFERENCE TO RELATED APPLICATION(S)

This application claims priority to and benefits of Korean Patent Application No. 10-2023-0106403 under 35 U.S.C. § 119, filed on Aug. 14, 2023, in the Korean Intellectual Property Office, the entire contents of which are incorporated herein by reference.

### BACKGROUND

### 1. Technical Field

The disclosure relates to a light emitting element, a polycyclic compound for the light emitting element, and a display device including the light emitting element.

### 2. Description of the Related Art

Active development continues for an organic electroluminescence display device and the like as an image display device. An organic electroluminescence display device is a display device that includes a so-called self-luminescent light emitting element in which holes and electrons respectively injected from a first electrode and a second electrode recombine in a light emitting layer, so that a light emitting material in the light emitting layer emits light to achieve display.

In the application of a light emitting element to a display device, there is a constant demand for improvements in luminous efficiency, lifespan, and the like, and continuous development is required on materials for a light emitting element that are capable of stably achieving such characteristics.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element with improved luminous efficiency and lifespan and a display device including the light emitting element.

The disclosure also provides a polycyclic compound, which is a material for a light emitting element that improves luminous efficiency and lifespan.

According to an embodiment, a light emitting element may include a first electrode, a hole transport region disposed on the first electrode, a light emitting layer disposed on the hole transport region, an electron transport region disposed on the light emitting layer, and a second electrode disposed on the electron transport region, wherein the light emitting layer includes a first compound represented by Formula 1.

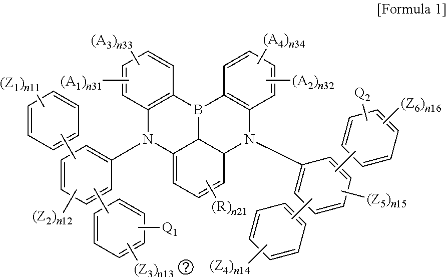

In Formula 1, Z₁ to Z₆ may each independently be a hydrogen atom, a deuterium atom, a substituted or unsubstituted alkyl group having 1 to 30 carbon atoms, or a substituted or unsubstituted aryl group having 6 to 30 ring-forming carbon atoms; R may be a hydrogen atom, a deuterium atom, a substituted or unsubstituted alkyl group having 1 to 20 carbon atoms, a substituted or unsubstituted cycloalkyl group having 3 to 60 ring-forming carbon atoms, a substituted or unsubstituted aryl group having 6 to 60 ring-forming carbon atoms, or a substituted or unsubstituted heteroaryl group having 2 to 60 ring-forming carbon atoms; A₁ and A₂ may each independently be a substituted or unsubstituted heteroaryl group having 2 to 60 ring-forming carbon atoms; A₃ and A₄ may each independently be a hydrogen atom, a deuterium atom, a substituted or unsubstituted alkyl group having 1 to 20 carbon atoms, or a substituted or unsubstituted aryl group having 6 to 60 ring-forming carbon atoms; Q₁ and Q₂ may each independently be a substituted or unsubstituted biphenyl group; n11 and n14 may each independently be an integer from 0 to 5; n12, n15, n21, n33, and n34 may each independently be an integer from 0 to 3; n13 and n16 may each independently be an integer from 0 to 4; n31 and n32 may each independently be an integer from 1 to 4, the sum of n31 and n33 may be an integer from 1 to 4; and the sum of n32 and n34 may be an integer from 1 to 4.

In an embodiment, the light emitting layer may further include at least one of a second compound represented by Formula HT-1, a third compound represented by Formula ET-1, and a fourth compound represented by Formula D-1.

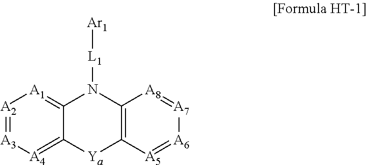

In Formula HT-1, A₁ to A₈ may each independently be N or C(R₅₁); L₁ may be a direct linkage, a substituted or unsubstituted arylene group having 6 to 30 ring-forming carbon atoms, or a substituted or unsubstituted heteroarylene group having 2 to 30 ring-forming carbon atoms; Yₐ may be a direct linkage, C(R₅₂)(R₅₃), or Si(R₅₄)(R₅₅); Ar₁ may be a substituted or unsubstituted aryl group having 6 to 30 ring-forming carbon atoms or a substituted or unsubstituted heteroaryl group having 2 to 30 ring-forming carbon atoms; and R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring.

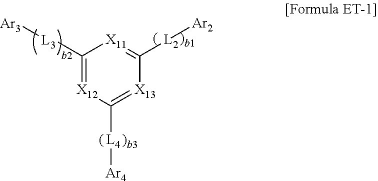

In Formula ET-1, at least one of X₁₁ to X₁₃ may each be N; the remainder of X₁₁ to X₁₃ may each independently be C(R₅₆);

R₅₆ may be a hydrogen atom, a deuterium atom, a substituted or unsubstituted alkyl group having 1 to 20 carbons, a substituted or unsubstituted aryl group having 6 to 60 ring-forming carbon atoms, or a substituted or unsubstituted heteroaryl group having 2 to 60 ring-forming carbon atoms; b1 to b3 may each independently be an integer from 0 to 10; Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms.

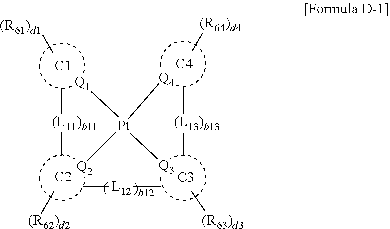

In Formula D-1, Q₁ to Q₄ may each independently be C or N; C1 to C4 may each independently be a substituted or unsubstituted hydrocarbon ring group having 5 to 30 ring-forming carbon atoms or a substituted or unsubstituted heterocyclic group having 2 to 30 ring-forming carbon atoms; L₁₁ to L₁₃ may each independently be a direct linkage, *—O—*, *—S—*,

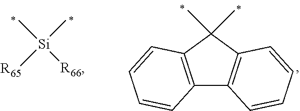

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; b11 to b13 may each independently be 0 or 1; R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring; and d1 to d4 may each independently be an integer from 0 to 4.

In an embodiment, the first compound may be represented by Formula 2.

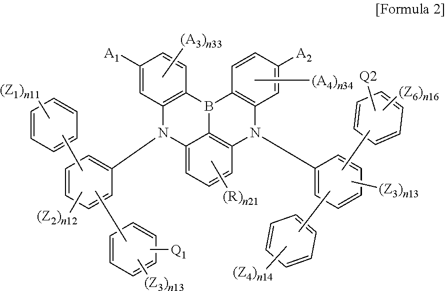

In Formula 2, Z₁ to Z₆, R, A₁ to A₄, Q₁, Q₂, n11 to n16, n21, n33, and n34 are the same as defined in Formula 1.

In an embodiment, the first compound may be represented by Formula 3.

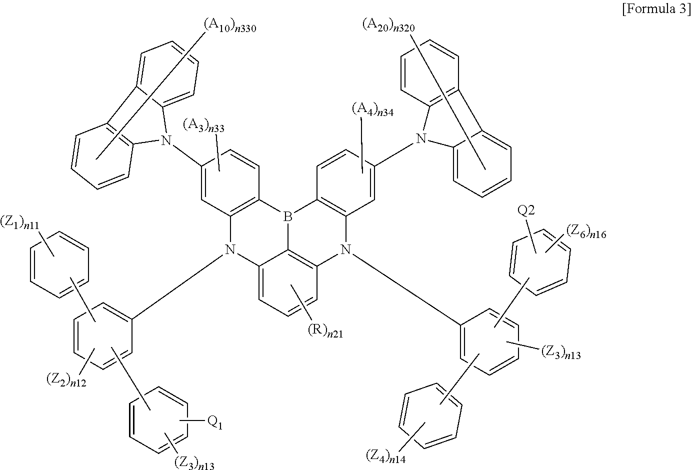

In Formula 3, A₁₀ and A₂₀ may each independently be a hydrogen atom, a deuterium atom, a halogen atom, a cyano group, a substituted or unsubstituted silyl group, a substituted or unsubstituted oxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring; n310 and n320 may each independently be an integer from 0 to 8; and Z₁ to Z₆, R, A₃, A₄, Q₁, Q₂, n11 to n16, n21, n33, and n34 are the same as defined in Formula 1.

In an embodiment, in Formula 1, R may be a group represented by one of Formula X-1 to Formula X-8.

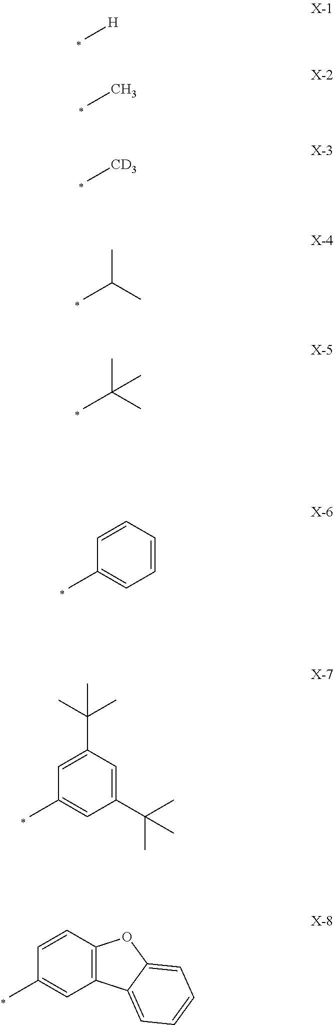

In Formula X-1 to Formula X-8, *— is a position connected to Formula 1.

In an embodiment, the first compound may be represented by Formula 4.

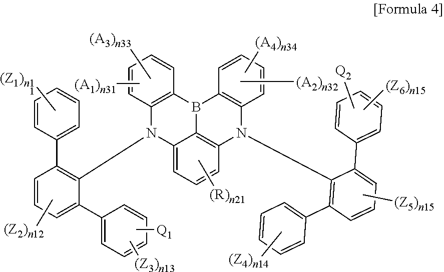

In Formula 4, Z₁ to Z₆, R, A₁ to A₄, Q₁, Q₂, n11 to n16, n21, and n31 to n34 are the same as defined in Formula 1.

In an embodiment, the first compound may be represented by Formula 5-1 or Formula 5-2.

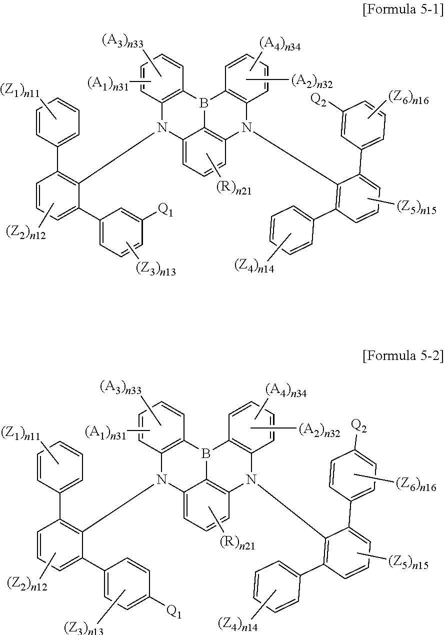

In Formula 5-1 and Formula 5-2, Z₁ to Z₆, R, A₁ to A₄, Q₁, Q₂, n11 to n16, n21, and n31 to n34 are the same as defined in Formula 1.

In an embodiment, the first compound may be represented by one of Formula 6-1 to Formula 6-4.

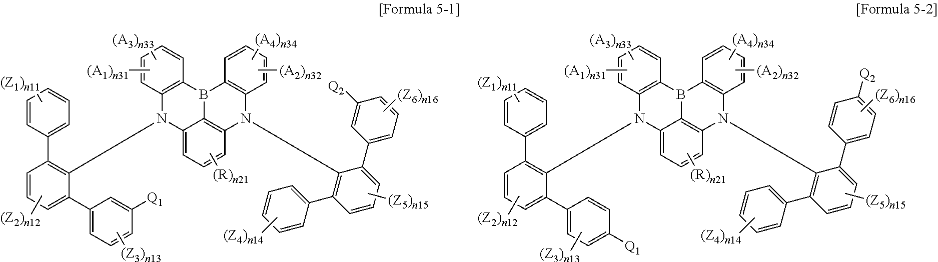

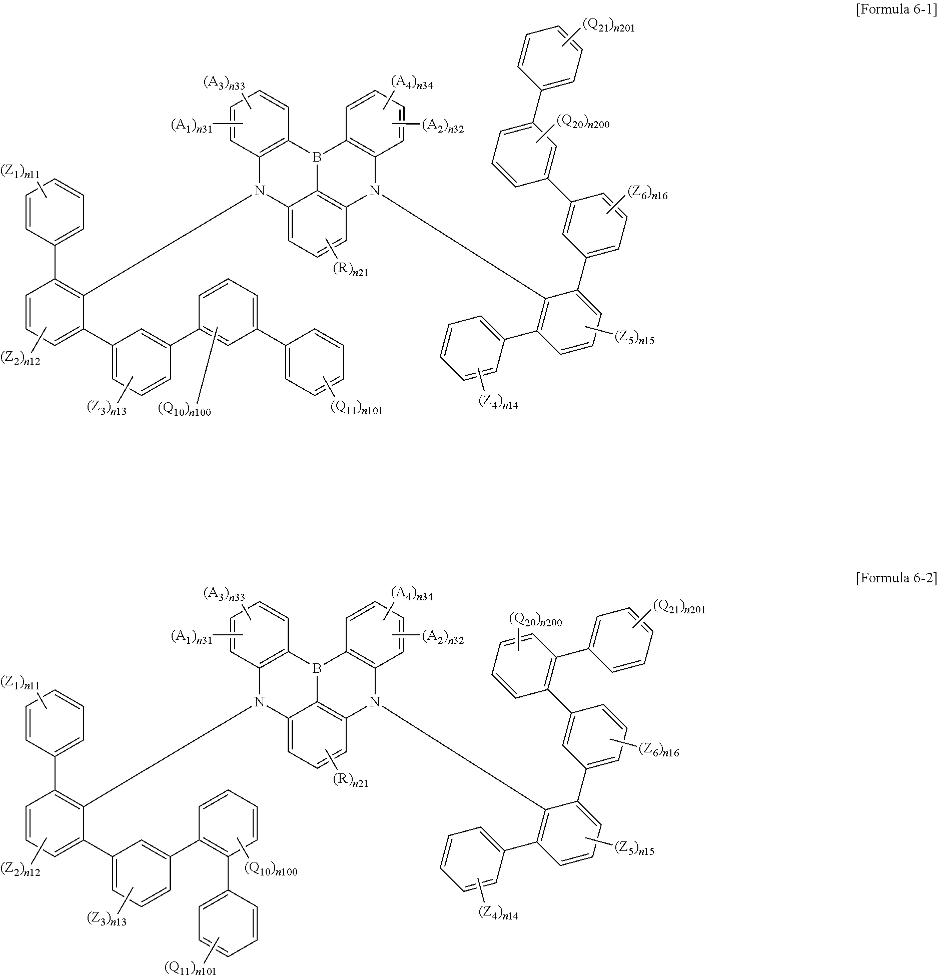

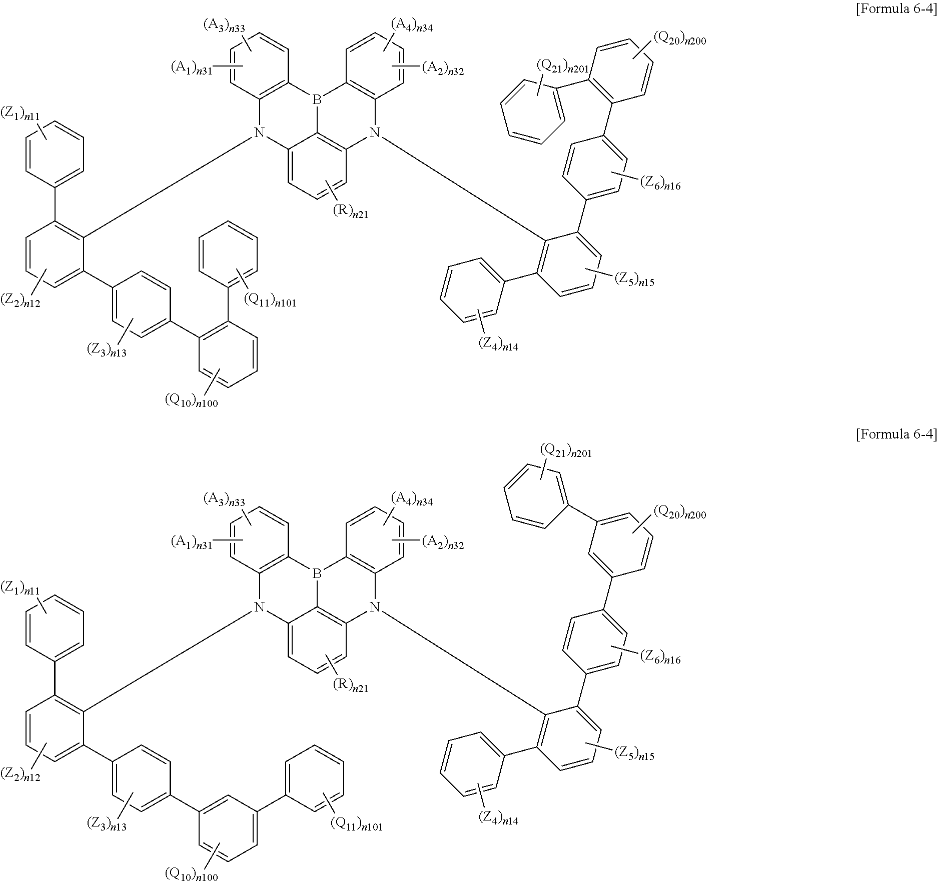

In Formula 6-1 to Formula 6-4, Q₁₀, Q₁₁, Q₂₀, and Q₂₁ may each independently be a hydrogen atom, a deuterium atom, a halogen atom, a cyano group, a substituted or unsubstituted silyl group, a substituted or unsubstituted oxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring; n100 and n200 may each independently be an integer from 0 to 4; n101 and n201 may each independently be an integer from 0 to 5; and A₁ to A₄, Z₁ to Z₆, R, n11 to n16, n21, and n31 to n34 are the same as defined in Formula 1.

In an embodiment, in Formula 1, Z₂ and Z₅ may each independently be a group represented by one of Formula Y-1 to Formula Y-7.

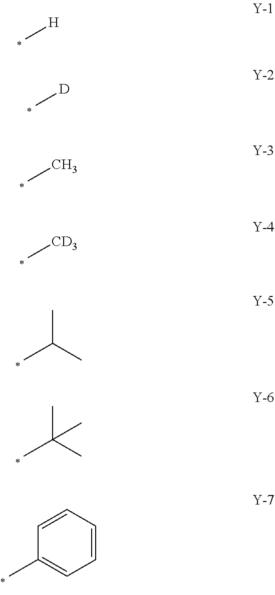

In Formula Y-1 to Formula Y-7, *— is a position connected to Formula 1.

In an embodiment, the first compound may include at least one compound selected from Compound Group 1, which is explained below.

According to an embodiment, a display device may include a circuit layer disposed on a base layer; and a display element layer disposed on the circuit layer, and including a light emitting element, wherein

the light emitting element may include a first electrode, a second electrode disposed on the first electrode, and a light emitting layer disposed between the first electrode and the second electrode and including a first compound represented by Formula 1, which is explained herein.

According to an embodiment, a polycyclic compound may be represented by Formula 1, which is explained herein.

In an embodiment, the polycyclic compound represented by Formula 1 may be a polycyclic compound represented by Formula 2, which is explained herein.

In an embodiment, the polycyclic compound represented by Formula 1 may be a polycyclic compound represented by Formula 3, which is explained herein.

In an embodiment, in Formula 1, R may be a group represented by one of Formula X-1 to Formula X-8, which are explained herein.

In an embodiment, the polycyclic compound represented by Formula 1 may be a polycyclic compound represented by Formula 4, which is explained herein.

In an embodiment, the polycyclic compound represented by Formula 4 may be a polycyclic compound represented by Formula 5-1 or Formula 5-2, which are explained herein.

In an embodiment, the polycyclic compound represented by Formula 4 may be a polycyclic compound represented by one of Formula 6-1 to Formula 6-4, which are explained herein.

In an embodiment, in Formula 1, Z₂ and Z₅ may each independently be a group represented by one of Formula Y-1 to Formula Y-7, which are explained herein.

In an embodiment, the polycyclic compound represented by Formula 1 may be selected from Compound Group 1, which is explained below.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a display device according to an embodiment;

FIG. 8 is a schematic cross-sectional view of a display device according to an embodiment;

FIG. 9 is a schematic cross-sectional view of a display device according to an embodiment;

FIG. 10 is a schematic cross-sectional view of a display device according to an embodiment; and

FIG. 11 is a schematic perspective view of an interior of a vehicle that includes a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may be interpreted as a group that is bonded to an adjacent group to form a substituted or unsubstituted hydrocarbon ring or a substituted or unsubstituted heterocycle. The hydrocarbon ring may be aliphatic or aromatic. The heterocycle may be aliphatic or aromatic. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, and an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldodecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not particularly limited, and may be 2 to 30, 2 to 20, or 2 to 10. Examples of an alkenyl group may include a vinyl group, a 1-butenyl group, a 1-pentenyl group, a 1,3-butadienyl group, a styrenyl group, a styryl vinyl group, etc., but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. The number of carbon atoms in an alkynyl group is not particularly limited, and may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

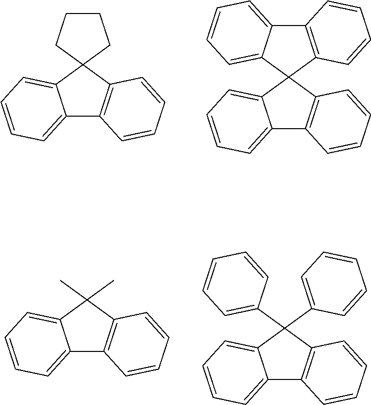

In the specification, a heterocyclic group may be any functional group or substituent derived from a ring that includes at least one of B, O, N, P, Si, S, and Se as a heteroatom. A heterocyclic group may be aliphatic or aromatic. An aromatic heterocyclic group may be a heteroaryl group. An aliphatic heterocyclic group and an aromatic heterocyclic group may each independently be monocyclic or polycyclic.

If a heterocyclic group includes two or more heteroatoms, the two or more heteroatoms may be the same as or different from each other. The number of ring-forming carbon atoms in a heterocyclic group may be 2 to 30, 2 to 20, or 2 to 10.

Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group except that a heteroarylene group is a divalent group.

In the specification, a silyl group may be an alkylsilyl group or an arylsilyl group. An alkyl group in an alkylsilyl group may be linear, branched, or cyclic. The number of carbon atoms in an alkylsilyl group is not particularly limited, and may be, for example, 1 to 20 or 1 to 10. The number of carbon atoms in an arylsilyl group is not particularly limited, and may be, for example, 6 to 30, 6 to 20, or 6 to 15. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, but may be 1 to 40, 1 to 30, or 1 to 20. For example, a carbonyl group may have one of the following structures, but embodiments are not limited thereto.

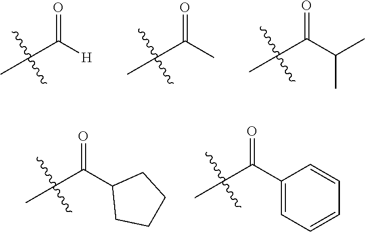

In the specification, the number of carbon atoms in a sulfinyl group or in a sulfonyl group is not particularly limited, and may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. An alkyl group in an alkylthio group may be linear, branched, or cyclic. The number of carbon atoms in an alkylthio is not particularly limited, and may be, for example, 1 to 20 or 1 to 10. The number of carbon atoms in an arylthio group is not particularly limited, and may be, for example, 6 to 30, 6 to 20, or 6 to 15. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not particularly limited, and may be, for example, 1 to 20 or 1 to 10. The number of carbon atoms in an aryl oxy group is not particularly limited, and the number of ring-forming carbon atoms may be, for example, 6 to 30, 6 to 20, or 6 to 15. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. An alkyl group in an alkyl boron group may be linear, branched, or cyclic. The number of carbon atoms in an alkyl boron group is not particularly limited, and may be, for example, 1 to 20 or 1 to 10. The number of carbon atoms in an aryl boron group is not particularly limited, and may be, for example, 6 to 30, 6 to 20, or 6 to 15. Examples of a boron group may include a dimethylboron group, a t-butylmethylboron group, a diphenylboron group, a phenylboron group, etc., but embodiments are not limited thereto.

In the specification, an amine group may be an alkyl amine group or an aryl amine group. An alkyl group in an alkyl amine group may be linear, branched, or cyclic. The number of carbon atoms in an alkyl amine group is not particularly limited, and may be, for example, 1 to 20 or 1 to 10. The number of carbon atoms in an aryl amine group is not particularly limited, and may be, for example, 6 to 30, 6 to 20, or 6 to 15. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, a phosphine oxide group may be —P(═O)— that is combined with an alkyl group or an aryl group as defined above. The number of carbon atoms in a phosphine oxide group is not particularly limited, and may be 1 to 30, 1 to 20, or 1 to 10. A phosphine oxide group may be an alkyl phosphine oxide group or an aryl phosphine oxide group. For example, a phosphine oxide group may have one of the structures shown below, but embodiments are not limited thereto.

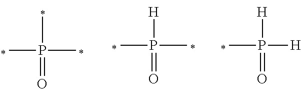

In the specification, a phosphine sulfide group may be —P(═S)— that is combined with an alkyl group or an aryl group as defined above. The number of carbon atoms in a phosphine sulfide group is not —P(═S)-limited, and may be 1 to 30, 1 to 20, or 1 to 10. A phosphine sulfide group may be an alkyl phosphine sulfide group or an aryl phosphine sulfide group. For example, a phosphine sulfide group may have one of the structures shown below, but embodiments are not limited thereto.

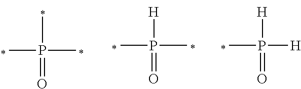

In the specification, an alkyl group within an alkoxy group, an alkylthio group, an alkyl sulfinyl group, an alkylsulfonyl group, an alkylaryl group, an alkylamino group, an alkyl boron group, an alkyl silyl group, an alkyl phosphine oxide group, an alkyl phosphine sulfide group, or an alkyl amine group may be the same as an example of an alkyl group as described above.

In the specification, an aryl group within an aryloxy group, an arylthio group, an arylsulfonyl group, an arylamino group, an arylboron group, an arylsilyl group, an aryl phosphine oxide group, an aryl phosphine sulfide group, or an arylamine group may be the same as an example of an aryl group as described above.

In the specification, a direct linkage may be a single bond.

In the specification, the symbols

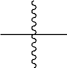

and —* each represent a bond to a neighboring atom in a corresponding formula or moiety.

Hereinafter, embodiments will be described with reference to the accompanying drawings.

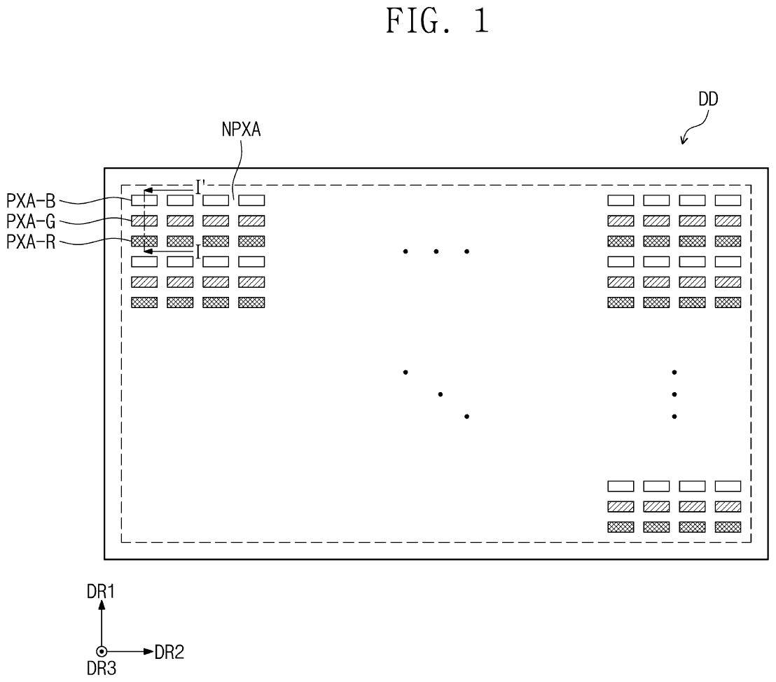

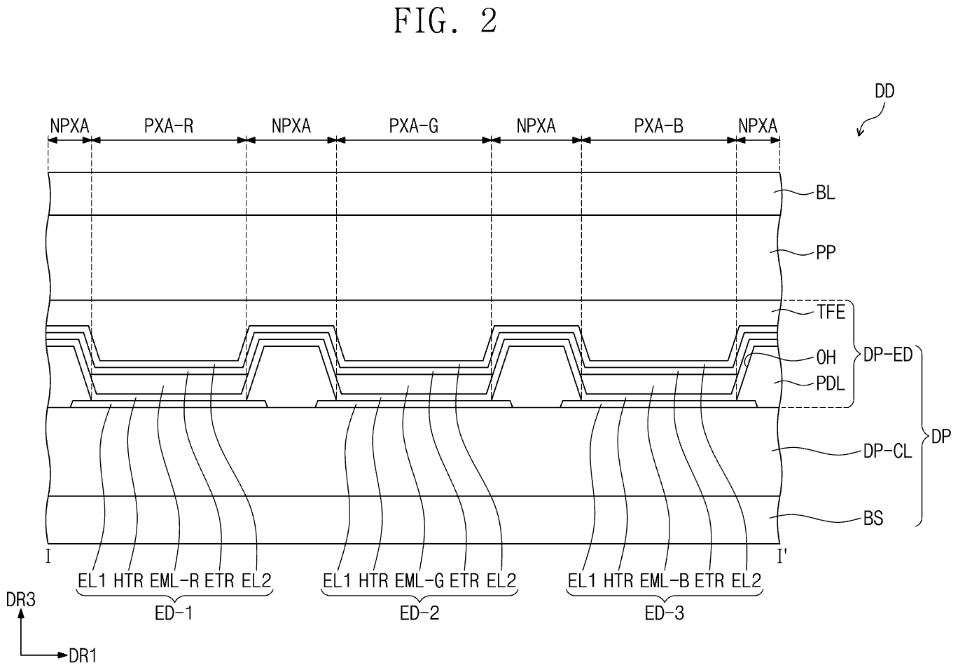

FIG. 1 is a schematic plan view of a display device DD according to an embodiment. FIG. 2 is a schematic cross-sectional view of a display device DD according to an embodiment. FIG. 2 is a schematic cross-sectional view illustrating a part taken along virtual line I-I′ in FIG. 1.

The display device DD may include a display panel DP and an optical layer PP disposed on the display panel DP. The display panel DP includes light emitting elements ED-1, ED-2, and ED-3. The display device DD may include multiples of the light emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and the display device layer DP-ED. The display device layer DP-ED may include a pixel defining film PDL, light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display device layer DP-ED.

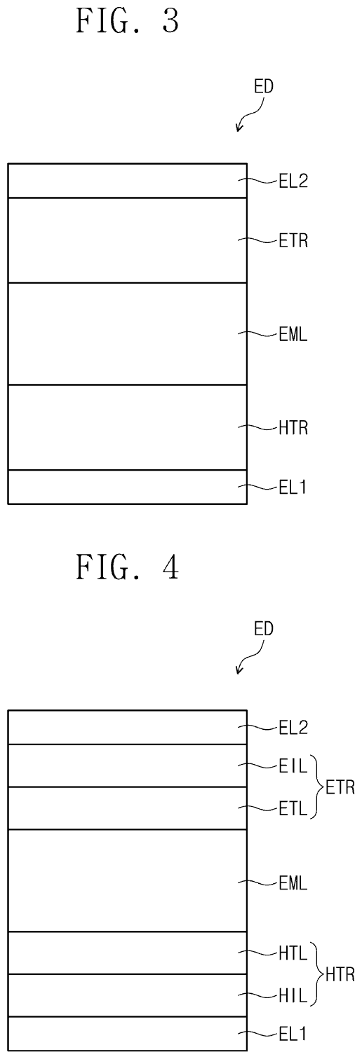

The light emitting elements ED-1, ED-2, and ED-3 may each have a structure of a light emitting element ED of an embodiment according to any of FIGS. 3 to 6, which will be described later. The light emitting elements ED-1, ED-2, and ED-3 may each include a first electrode EL1, a hole transport region HTR, light emitting layers EML-R, EML-G, and EML-B, an electron transport region ETR, and a second electrode EL2.

FIG. 2 illustrates an embodiment in which the light emitting layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for the light emitting elements ED-1, ED-2, and ED-3. However, embodiments are not limited thereto. Although not illustrated in FIG. 2, in an embodiment, the hole transport region HTR and the electron transport region ETR may each be provided by being patterned in the openings OH defined in the pixel defining film PDL. For example, in an embodiment, the hole transport region HTR, the light emitting layers EML-R, EML-G, and EML-B, and the electron transport region ETR of the light emitting elements ED-1, ED-2, and ED-3 may each be provided by being patterned by an inkjet printing method.

The encapsulation layer TFE may cover the light emitting elements ED-1, ED-2, and ED-3. The encapsulation layer TFE may seal the light emitting elements ED-1, ED-2, and ED-3 in the display device layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). In an embodiment, the encapsulation layer TFE may include at least one organic film (hereinafter, an encapsulation-organic film) and at least one encapsulation-inorganic film.

The encapsulation-inorganic film protects the display device layer DP-ED from moisture and/or oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region that emits light respectively generated by the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may be regions that are separated from each other by the pixel defining film PDL. The non-light emitting regions NPXA may be areas between the adjacent light emitting regions PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light emitting elements ED-1, ED-2, and ED-3. The light emitting layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment illustrated in FIGS. 1 and 2, three light emitting regions PXA-R, PXA-G, and PXA-B, which respectively emit red light, green light, and blue light, are illustrated as an example. For example, the display device DD may include a red light emitting region PXA-R, a green light emitting region PXA-G, and a blue light emitting region PXA-B, which are distinct from each other.

In the display device DD according to an embodiment, the light emitting elements ED-1, ED-2, and ED-3 may emit light having wavelengths that are different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range, or at least one light emitting element may emit light in a wavelength range that is different from the remainder. For example, the first to third light emitting elements ED-1, ED-2, and ED-3 may each emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be arranged in this repeating order along a first directional axis DR1.

FIGS. 1 and 2 illustrate that the light emitting regions PXA-R, PXA-G, and PXA-B all have a similar area, but embodiments are not limited thereto. In an embodiment, the light emitting regions PXA-R, PXA-G, and PXA-B may be different in size or shape from each other, according to a wavelength range of emitted light. The areas of the light emitting regions PXA-R, PXA-G, and PXA-B may be areas in a plan view that are defined by the first directional axis DR1 and the second directional axis DR2. A third directional axis DR3 may be perpendicular to a plane defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations, according to the display quality characteristics that are required for the display device DD. For example, the light emitting regions PXA-R, PXA-G, and PXA-B may be arranged in a pentile configuration (such as PenTile®) or in a diamond configuration (such as Diamond Pixel®) arrangement form.

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIG. 3 to FIG. 6 are each a schematic cross-sectional view of a light emitting element ED according to an embodiment. Embodiments provide a light emitting element ED which may include a first electrode EL1, a hole transport region HTR, a light emitting layer EML, an electron transport region ETR, and a second electrode EL2, stacked in that order.

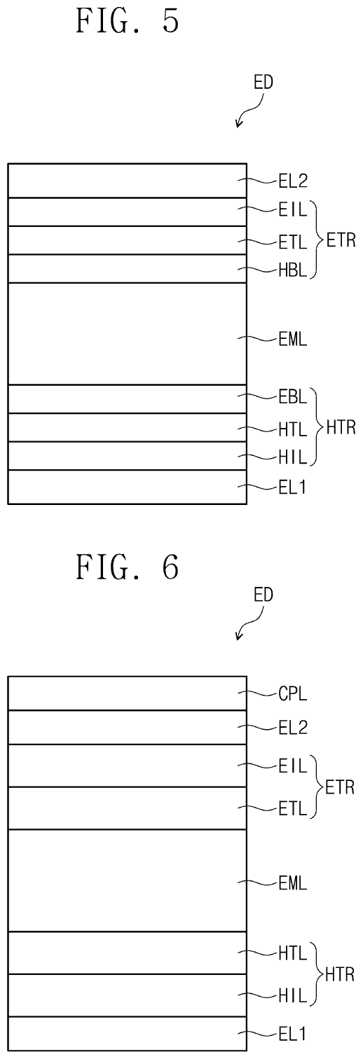

In comparison to FIG. 3, FIG. 4 is a schematic cross-sectional view of alight emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 is a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 is a schematic cross-sectional view of a light emitting element ED according to an embodiment that includes a capping layer CPL disposed on a second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, and Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include at least one of Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. In an embodiment, the first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission-auxiliary layer (not shown), and an electron blocking layer EBL. A thickness of the hole transport region HTR may be, for example, in a range of about 50 Å to about 15,000 Å.

The hole transport region HTR may be a layer consisting of a single material, a layer including different materials, or a structure including multiple layers including different materials.

In embodiments, the hole transport region HTR may have a single layer structure of a hole injection layer HIL or a hole transport layer HTL, or may have a single layer structure formed of a hole injection material and a hole transport material. In embodiments, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIIbuffer layer (not shown), a hole transport layer HTLbuffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1:

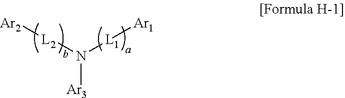

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ groups or multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Ar₃ includes an amine group as a substituent. In still another embodiment, the compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and a compound represented by Formula H-1 is not limited to Compound Group H:

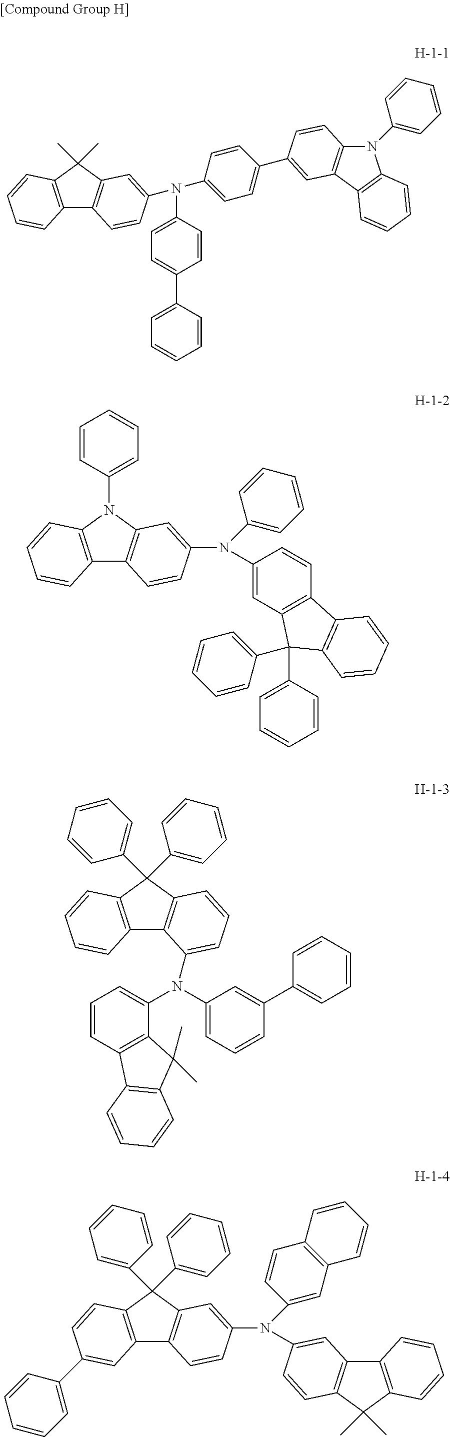 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

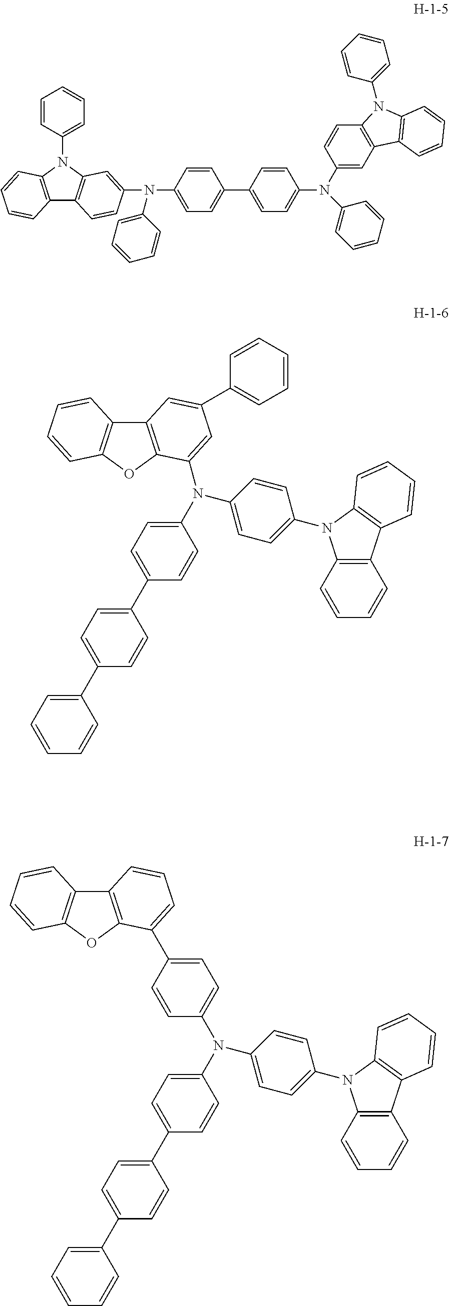 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

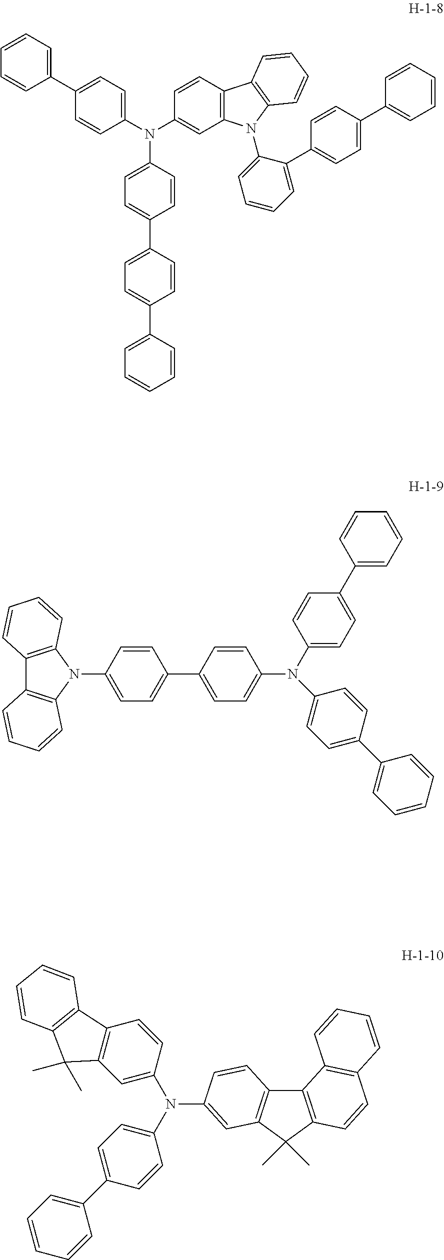 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

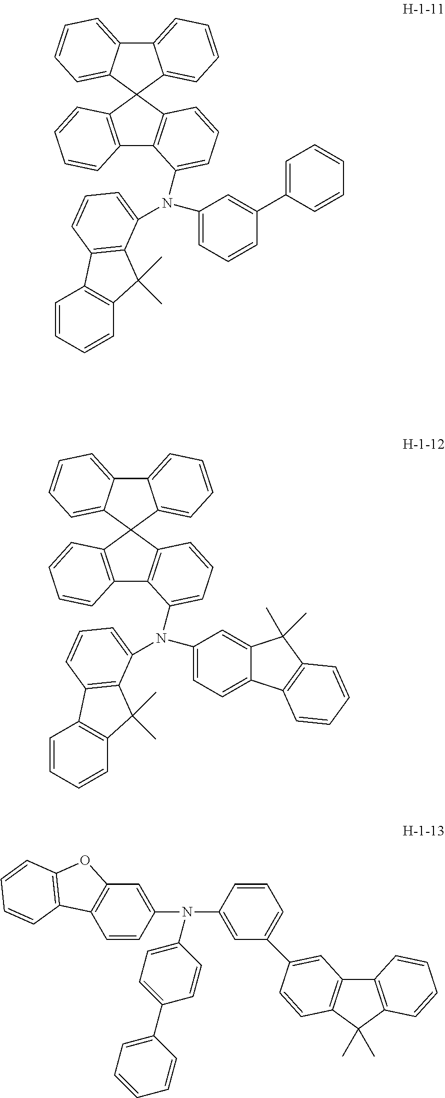 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

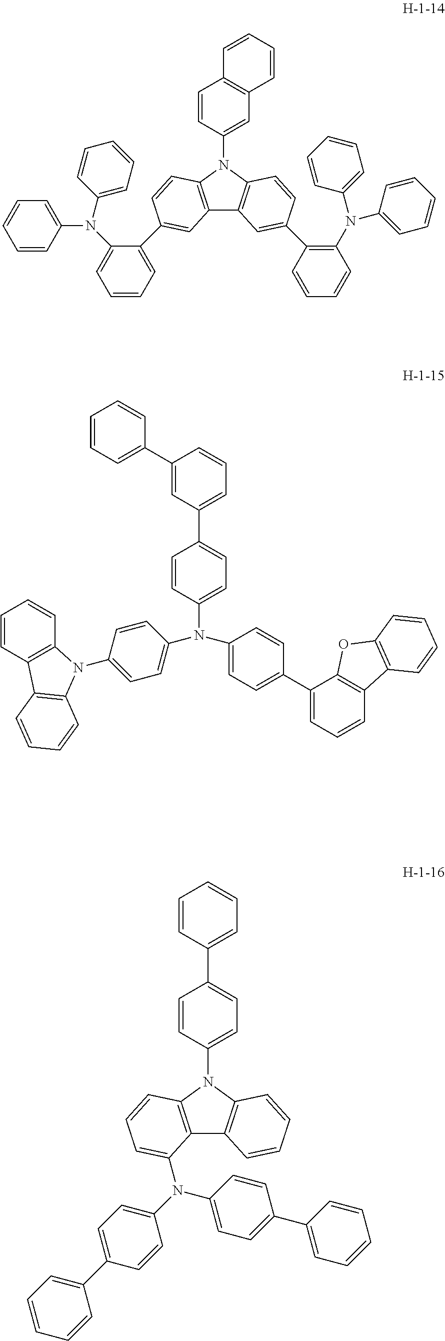 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

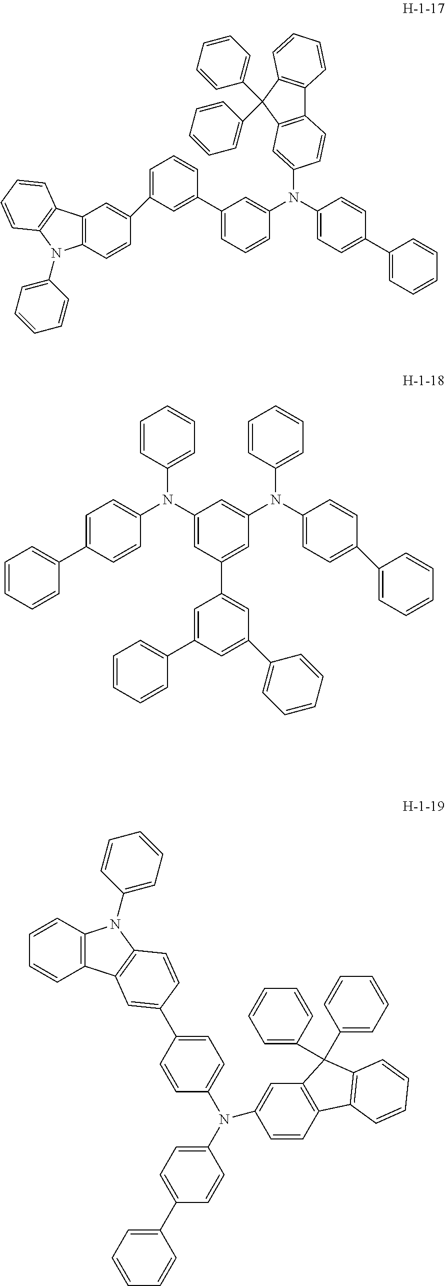 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HAT-CN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(carbazol-9-yl)triphenylamine (TCTA), N,N′-di(naphthalene-1-yl)-N,N′-diphenyl-benzidine (NPB), 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), or 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region HTR in at least one of a hole injection layer HIL, a hole transport layer HTL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 30 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a metal halide, a quinone derivative, a metal oxide, and a cyano group-containing compound, but embodiments are not limited thereto. For example, the p-dopant may include a metal halide such as CuI or RbI, a quinone derivative such as tetracyanoquinodimethane (TCNQ) or 2,3,5,6-tetrafluoro-7,7′,8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HAT-CN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) and an electron blocking layer EBL, in addition to a hole injection layer HIL or a hole transport layer HTL. The buffer layer (not shown) may compensate for a resonance distance according to a wavelength of light emitted from the light emitting layer EML and may thus increase luminous efficiency. A material that may be included in the hole transport region HTR may be used as a material in the buffer layer (not shown). The electron blocking layer EBL may prevent the injection of electrons from an electron transport region ETR to a hole transport region HTR.

In the light emitting element ED, the light emitting layer EML may include a first compound according to an embodiment. In an embodiment, the light emitting layer EML may further include at least one of a second compound, a third compound, and a fourth compound. The second compound may include a condensed tricyclic moiety containing a nitrogen atom as a ring-forming atom. The third compound may include a central six-membered heterocyclic moiety containing at least one nitrogen atom as a ring-forming atom. The fourth compound may be an organometallic complex. The second, third, and fourth compounds will be described below in further detail.

In the specification, the first compound may be referred to as a polycyclic compound according to an embodiment. The polycyclic compound may include a fused ring core that includes two nitrogen atoms and a boron atom as ring-forming atoms. The polycyclic compound according to an embodiment may have a substituent bonded at a para position to the boron atom, which is a ring-forming atom of the fused ring core. The substituent that is bonded at a para position to the boron atom, which is a ring-forming atom of the fused ring core, may be a carbazole group. The polycyclic compound may include a substituted or unsubstituted aryl group bonded to the nitrogen atom, which is a ring-forming atom of the fused ring core. The aryl group bonded to the nitrogen atom, which is a ring-forming atom of the fused ring core, may include multiple benzene rings. For example, the aryl group bonded to the nitrogen atom, which is a ring-forming atom of the fused ring core, may include at least five benzene rings.

The light emitting element ED according to an embodiment may include a polycyclic compound according to an embodiment. The polycyclic compound according to an embodiment may be represented by Formula 1.

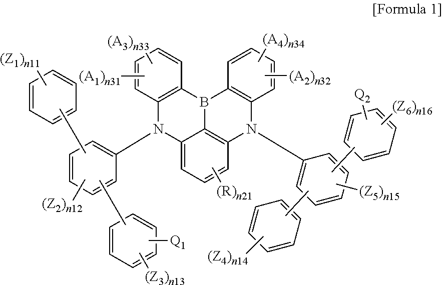

In Formula 1, Z₁ to Z₆ may each independently be a hydrogen atom, a deuterium atom, a substituted or unsubstituted alkyl group having 1 to 30 carbon atoms, or a substituted or unsubstituted aryl group having 6 to 30 ring-forming carbon atoms. For example, Z₁ to Z₆ may each independently be a hydrogen atom, a deuterium atom, an unsubstituted methyl group, a methyl group substituted with a deuterium atom, an unsubstituted isopropyl group, or an unsubstituted t-butyl group. In an embodiment, in Formula 1, Z₁ and Z₄ may not be a substituted or unsubstituted biphenyl group. In an embodiment, in Formula 1, Z₁ and Q₁ may be different from each other. In an embodiment, in Formula 1, Z₄ and Q₂ may be different from each other.

In an embodiment, in Formula 1, Z₂ and Z₅ may each independently be a group represented by any one of Formula Y-1 to Formula Y-7.

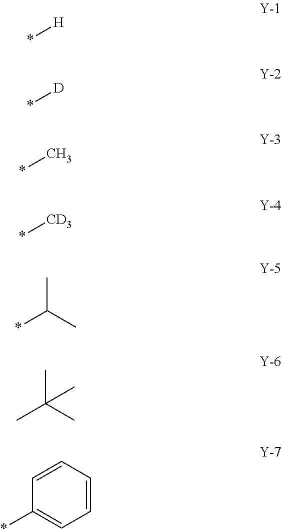

In Formula Y-1 to Formula Y-7, *— is a position connected to Formula 1.

In Formula 1, n11 and n14 may each independently be an integer from 0 to 5. When n11 is 0, the polycyclic compound may not be substituted with Z₁. A case in which n11 is 5 and five Z₁ groups are all hydrogen atoms may be the same as a case in which n11 is 0. When n11 is 2 or greater, multiple Z₁ groups may all be identical, or at least one thereof may be different from the remainder. When n14 is 0, the polycyclic compound may not be substituted with Z₄. A case in which n14 is 5 and five Z₄ groups are all hydrogen atoms may be the same as a case in which n14 is 0. When n14 is 2 or greater, multiple Z₄ groups may all be identical, or at least one thereof may be different from the remainder.

In Formula 1, n12 and n15 may each independently be an integer from 0 to 3. When n12 is 0, the polycyclic compound may not be substituted with Z₂. A case in which n12 is 3 and three Z₂ groups are all hydrogen atoms may be the same as a case in which n12 is 0. When n12 is 2 or greater, multiple Z₂ groups may all be identical, or at least one thereof may be different from the remainder. When n15 is 0, the polycyclic compound may not be substituted with Z₅. A case in which n15 is 3 and three Z₅ groups are all hydrogen atoms may be the same as a case in which n15 is 0. When n15 is 2 or greater, multiple Z₅ groups may all be identical, or at least one thereof may be different from the remainder.

In Formula 1, n13 and n16 may each independently be an integer from 0 to 4. When n13 is 0, the polycyclic compound may not be substituted with Z₃. A case in which n13 is 4 and four Z₃ groups are all hydrogen atoms may be the same as a case in which n13 is 0. When n13 is 2 or greater, multiple Z₃ groups may all be identical, or at least one thereof may be different from the remainder. When n16 is 0, the polycyclic compound may not be substituted with Z₆. A case in which n16 is 4 and four Z₆ groups are all hydrogen atoms may be the same as a case in which n16 is 0. When n16 is 2 or greater, multiple Z₆ groups may all be identical, or at least one thereof may be different from the remainder.

In Formula 1, R may be a hydrogen atom, a deuterium atom, a substituted or unsubstituted alkyl group having 1 to 20 carbon atoms, a substituted or unsubstituted cycloalkyl group having 3 to 60 ring-forming carbon atoms, a substituted or unsubstituted aryl group having 6 to 60 ring-forming carbon atoms, or a substituted or unsubstituted heteroaryl group having 2 to 60 ring-forming carbon atoms. For example, R may be an unsubstituted methyl group, a methyl group substituted with a deuterium atom, an unsubstituted isopropyl group, an unsubstituted t-butyl group, an unsubstituted phenyl group, an unsubstituted di-tert-butylphenyl group, or an unsubstituted dibenzofuran group.

In an embodiment, in Formula 1, R may be a group represented by any one of Formula X-1 to Formula X-8.

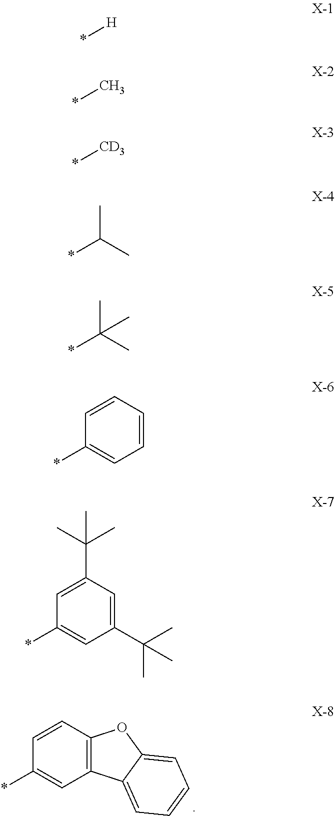

In Formula X-1 to Formula X-8, *— is a position connected to Formula 1.

In Formula 1, n21 may be an integer from 0 to 3. When n21 is 0, the polycyclic compound may not be substituted with R. A case in which n21 is 3 and three R groups are all hydrogen atoms may be the same as a case in which n21 is 0. When n21 is 2 or greater, multiple R groups may all be identical, or at least one thereof may be different from the remainder.

In Formula 1, A₁ and A₂ may each independently be a substituted or unsubstituted heteroaryl group having 2 to 60 ring-forming carbon atoms. For example, A₁ and A₂ may each independently be a substituted or unsubstituted carbazole group, a substituted or unsubstituted phenothiazine group, a substituted or unsubstituted dibenzoazasiline group, or a substituted or unsubstituted dimethylacridyl group. In an embodiment, A₁ and A₂ may each independently be a substituted or unsubstituted N-carbazole group. For example, A₁ and A₂ may each independently be a group represented by any one of Formula W-1 to Formula W-15.

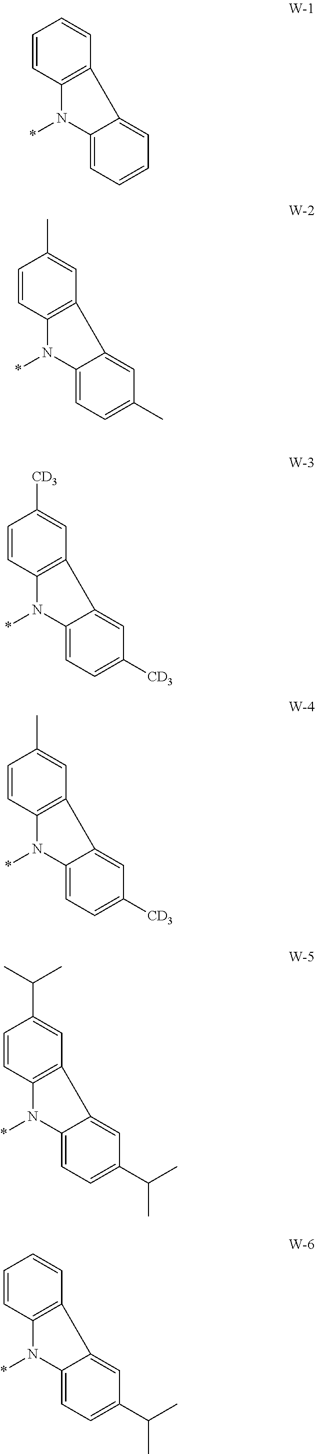 [SMILES: *n1c2ccccc2c2ccccc21 ; *n1c2ccc(C)cc2c2cc(C)ccc21 ; *n1c2ccc(C([2H])([2H])[2H])cc2c2cc(C([2H])([2H])[2H])ccc21 ; *n1c2ccc(C)cc2c2cc(C([2H])([2H])[2H])ccc21 ; *n1c2ccc(C(C)C)cc2c2cc(C(C)C)ccc21 ; *n1c2ccccc2c2cc(C(C)C)ccc21]

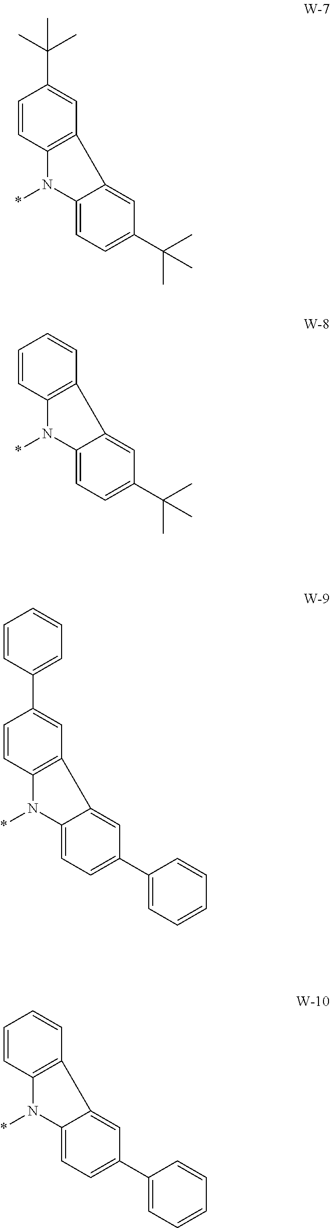 [SMILES: *n1c2ccc(C(C)(C)C)cc2c2cc(C(C)(C)C)ccc21 ; *n1c2ccccc2c2cc(C(C)(C)C)ccc21 ; *n1c2ccc(-c3ccccc3)cc2c2cc(-c3ccccc3)ccc21 ; *n1c2ccccc2c2cc(-c3ccccc3)ccc21]

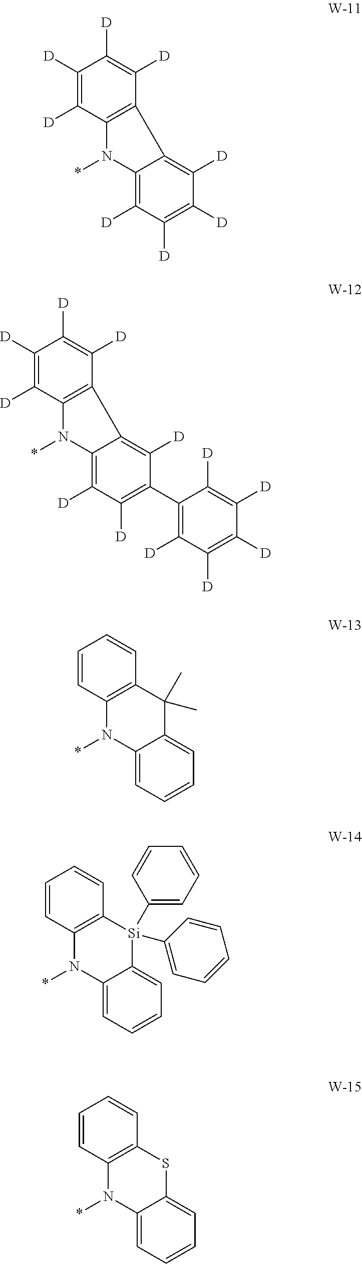 [SMILES: *n1c2c([2H])c([2H])c([2H])c([2H])c2c2c([2H])c([2H])c([2H])c([2H])c21 ; *n1c2c([2H])c([2H])c([2H])c([2H])c2c2c([2H])c(-c3c([2H])c([2H])c([2H])c([2H])c3[2H])c([2H])c([2H])c21 ; *N1c2ccccc2C(C)(C)c2ccccc21 ; *N1c2ccccc2[Si](c2ccccc2)(c2ccccc2)c2ccccc21 ; *N1c2ccccc2Sc2ccccc21]

In Formula 1, A₃ and A₄ may each independently be a hydrogen atom, a deuterium atom, a substituted or unsubstituted alkyl group having 1 to 20 carbon atoms, or a substituted or unsubstituted aryl group having 6 to 60 ring-forming carbon atoms. For example, A₃ and A₄ may each independently be a hydrogen atom, a deuterium atom, an unsubstituted methyl group, or an unsubstituted isopropyl group.

In Formula 1, n31 and n32 may each independently be an integer from 1 to 4. When n31 is 2 or greater, multiple A₁ groups may all be identical, or at least one thereof may be different from the remainder. When n32 is 2 or greater, multiple A₂ groups may all be identical, or at least one thereof may be different from the remainder.

In Formula 1, n33 and n34 may each independently be an integer from 0 to 3. In Formula 1, the sum of n31 and n33 may be an integer from 1 to 4; and the sum of n32 and n34 may be an integer from 1 to 4. A case in which n33 is 3 and three A₃ groups are all hydrogen atoms may be the same as a case in which n33 is 0 and n31 is 1. When n33 is 2 or greater, multiple A₃ groups may all be identical, or at least one thereof may be different from the remainder. A case in which n34 is 3 and three A₄ groups are all hydrogen atoms may be the same as a case in which n34 is 0 and n32 is 1. When n34 is 2 or greater, multiple A₄ groups may all be identical, or at least one thereof may be different from the remainder.

In Formula 1, Q₁ and Q₂ may each independently be a substituted or unsubstituted biphenyl group. For example, Q₁ and Q₂ may each independently be a group represented by Formula A.

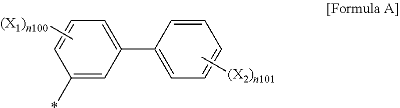

In Formula A, X₁ and X₂ may each independently be a hydrogen atom, a deuterium atom, a halogen atom, a cyano group, a substituted or unsubstituted silyl group, a substituted or unsubstituted oxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, X₁ and X₂ may each be an unsubstituted t-butyl group. In Formula A, n100 may be an integer from 0 to 4; and n101 may be an integer from 0 to 5. When n100 is 0, the polycyclic compound may not be substituted with X₁. A case in which n100 is 4 and four X₁ groups are all hydrogen atoms may be the same as a case in which n100 is 0. When n100 is 2 or greater, multiple X₁ groups may all be identical, or at least one thereof may be different from the remainder. When n101 is 0, the polycyclic compound may not be substituted with X₂. A case in which n101 is 5 and five X₂ groups are all hydrogen atoms may be the same as a case in which n101 is 0. When n101 is 2 or greater, multiple X₂ groups may all be identical, or at least one thereof may be different from the remainder. In Formula A, *— indicates a position connected to Formula 1.

In an embodiment, the polycyclic compound represented by Formula 1 may be represented by Formula 2.

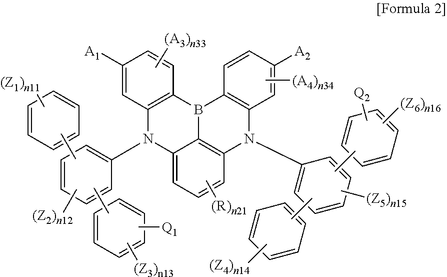

In Formula 2, Z₁ to Z₆, R, A₁ to A₄, Q₁, Q₂, n11 to n16, n21, n33, and n34 are the same as defined in Formula 1.

In an embodiment, the polycyclic compound represented by Formula 1 may be represented by Formula 3.

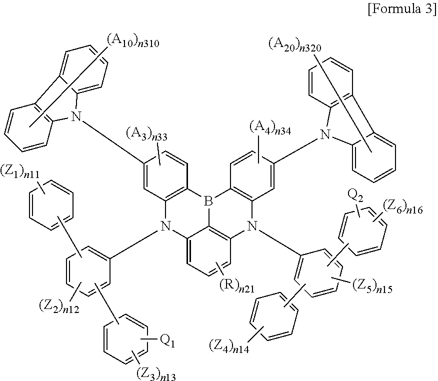

In Formula 3, A₁₀ and A₂₀ may each independently be a hydrogen atom, a deuterium atom, a halogen atom, a cyano group, a substituted or unsubstituted silyl group, a substituted or unsubstituted oxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, A₁₀ and A₂₀ may each independently be a hydrogen atom, a deuterium atom, an unsubstituted methyl group, an unsubstituted isopropyl group, an unsubstituted t-butyl group, an unsubstituted phenyl group, a methyl group in which all hydrogen atoms are substituted with deuterium atoms, or a phenyl group in which all hydrogen atoms are substituted with deuterium atoms.

In Formula 3, n310 and n320 may each independently bean integer from 0 to 8. When n310 is 0, the polycyclic compound may not be substituted with A₁₀. A case in which n310 is 8 and eight A₁₀ groups are all hydrogen atoms may be the same as a case in which n310 is 0. When n310 is 2 or greater, multiple A₁₀ groups may all be identical, or at least one thereof may be different from the remainder. When n320 is 0, the polycyclic compound may not be substituted with A₂₀. A case in which n320 is 8 and eight A₂₀ groups are all hydrogen atoms may be the same as a case in which n320 is 0. When n320 is 2 or greater, multiple A₂₀ groups may all be identical, or at least one thereof may be different from the remainder.

In Formula 3, Z₁ to Z₆, R, A₃, A₄, Q₁, Q₂, n11 to n16, n21, n33, and n34, are the same as defined in Formula 1.

In an embodiment, the polycyclic compound represented by Formula 1 may be represented by Formula 4.

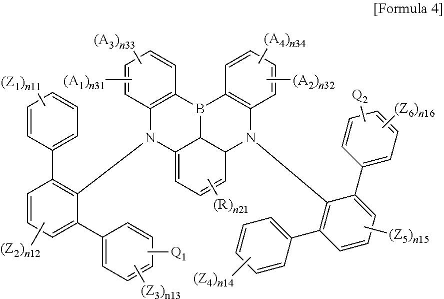

In Formula 4, Z₁ to Z₆, R, A₁ to A₄, Q₁, Q₂, n11 to n16, n21, and n31 to n34 are the same as defined in Formula 1.

In an embodiment, the polycyclic compound represented by Formula 4 may be represented by Formula 5-1 or Formula 5-2.

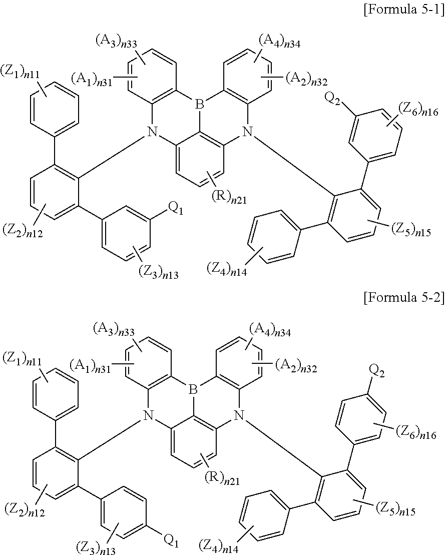

In Formula 5-1 and Formula 5-2, Z₁ to Z₆, R, A₁ to A₄, Q₁, Q₂, n11 to n16, n21, and n31 to n34 are the same as defined in Formula 1.

In an embodiment, the polycyclic compound represented by Formula 4 may be represented by any one of Formula 6-1, Formula 6-2, Formula 6-3, and Formula 6-4.

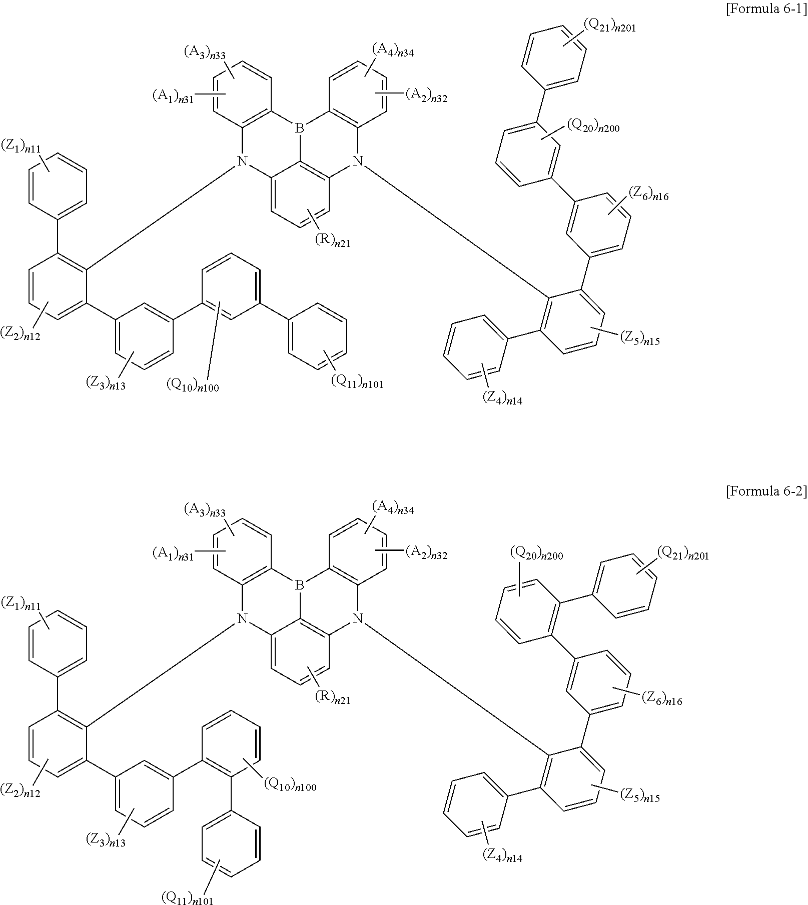

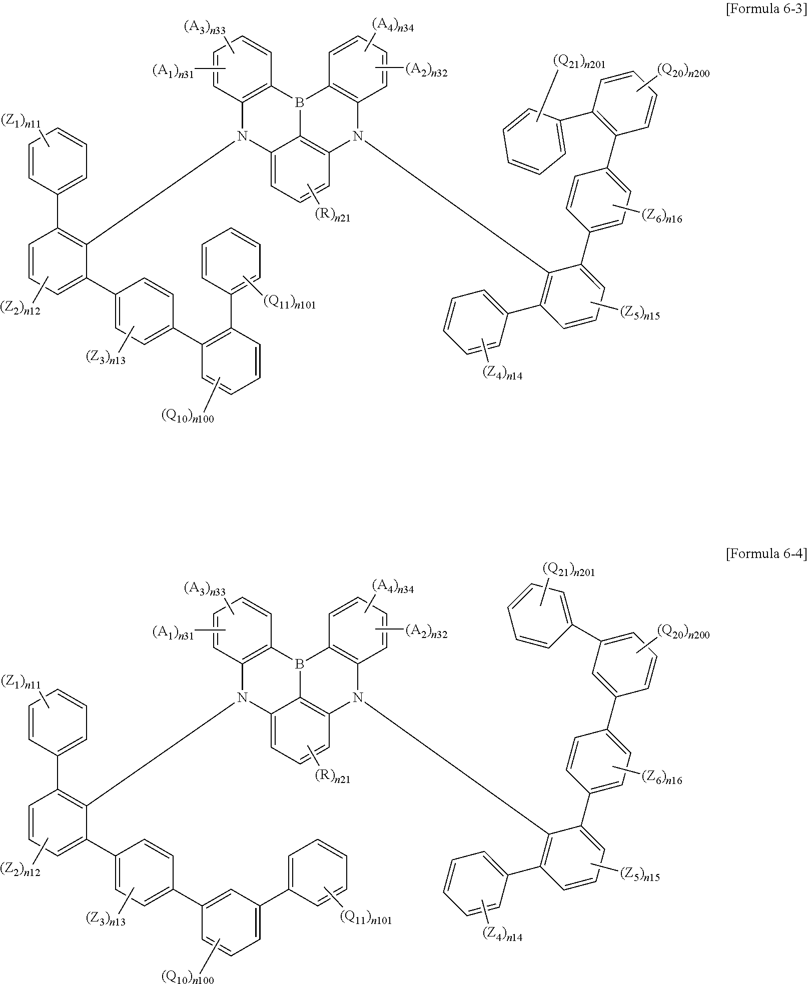

In Formula 6-1 to Formula 6-4, Q₁₀, Q₁₁, Q₂₀, and Q₂₁ may each independently be a hydrogen atom, a deuterium atom, a halogen atom, a cyano group, a substituted or unsubstituted silyl group, a substituted or unsubstituted oxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, Q₁₀, Q₁₁, Q₂₀, and Q₂₁ may each independently be a hydrogen atom, a deuterium atom, or an unsubstituted t-butyl group.

In Formula 6-1 to Formula 6-4, n100 and n200 may each independently be an integer from 0 to 4. When n100 is 0, the polycyclic compound may not be substituted with Q₁₀. A case in which n100 is 4 and four Q₁₀ groups are all hydrogen atoms may be the same as a case in which n100 is 0. When n100 is 2 or greater, multiple Q₁₀ groups may all be identical, or at least one thereof may be different from the remainder. When n200 is 0, the polycyclic compound may not be substituted with Q₂₀. A case in which n200 is 4 and four Q₂₀ groups are all hydrogen atoms may be the same as a case in which n200 is 0. When n200 is 2 or greater, multiple Q₂₀ groups may all be identical, or at least one thereof may be different from the remainder.

In Formula 6-1 to Formula 6-4, n101 and n201 may each independently be an integer from 0 to 5. When n101 is 0, the polycyclic compound may not be substituted with Q₁₁. A case in which n101 is 5 and five Q₁₁ groups are all hydrogen atoms may be the same as a case in which n101 is 0. When n101 is 2 or greater, multiple Q₁₁ groups may all be identical, or at least one thereof may be different from the remainder. When n201 is 0, the polycyclic compound may not be substituted with Q₂₁. A case in which n201 is 5 and five Q₂₁ groups are all hydrogen atoms may be the same as a case in which n201 is 0. When n201 is 2 or greater, multiple Q₂₁ groups may all be identical, or at least one thereof may be different from the remainder.

In Formula 6-1 to Formula 6-4, A₁ to A₄, Z₁ to Z₆, R, n11 to n16, n21, and n31 to n34 are the same as defined in Formula 1.

In an embodiment, the polycyclic compound may be any compound selected from Compound Group 1. In an embodiment, in the light emitting element ED, a light emitting layer EML may include at least one polycyclic compound selected from Compound Group 1. In Compound Group 1, D represents a deuterium atom.

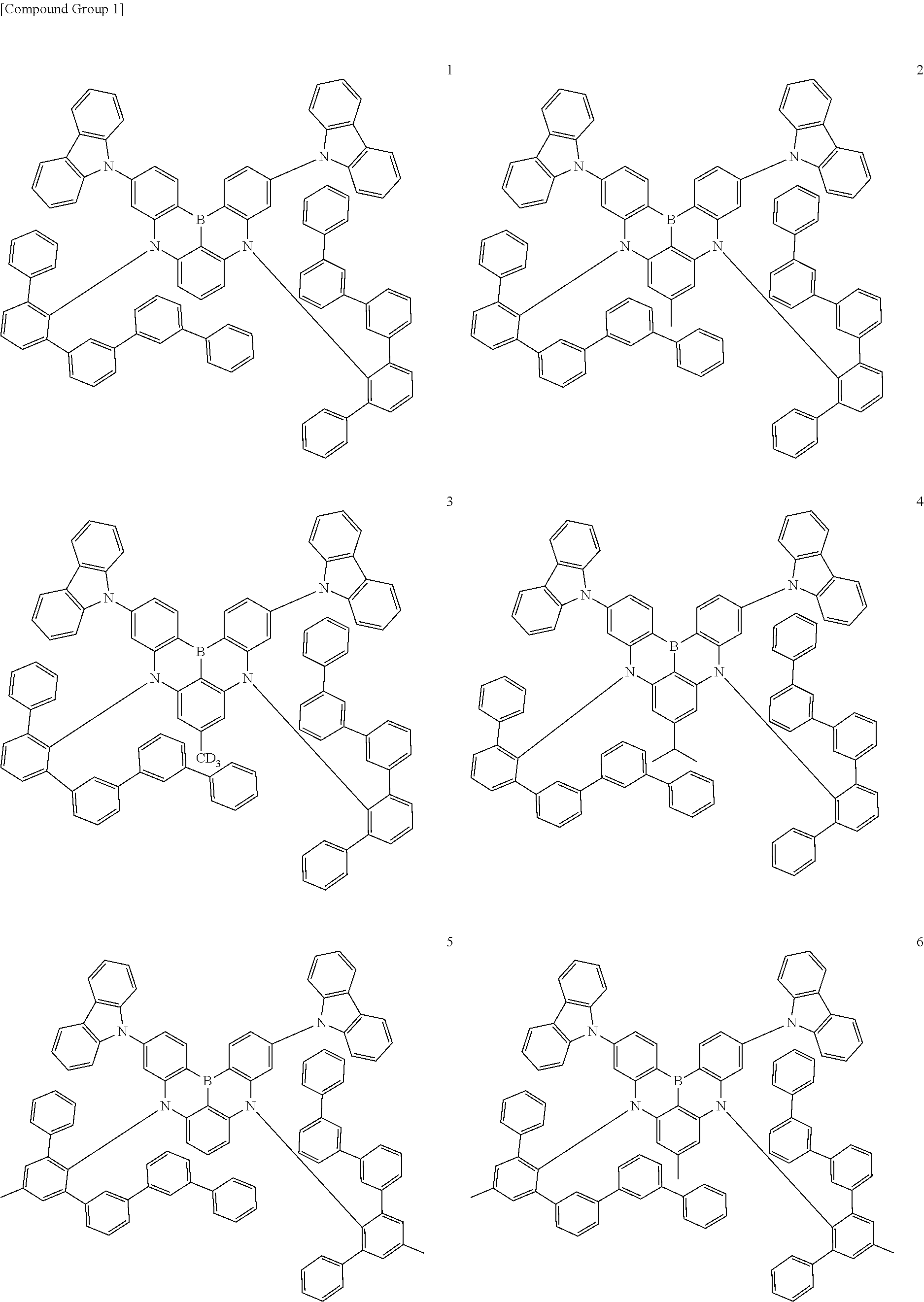

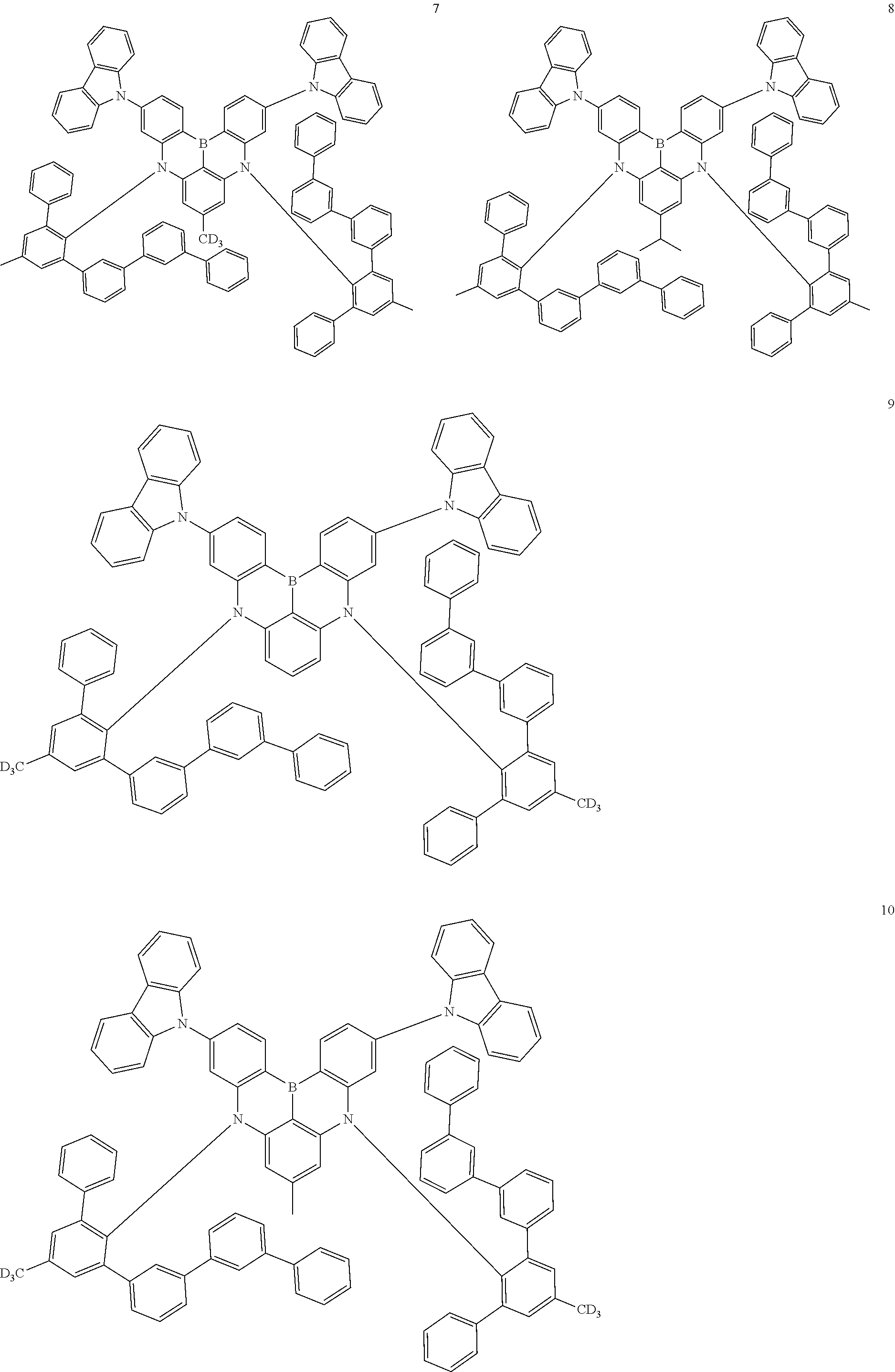

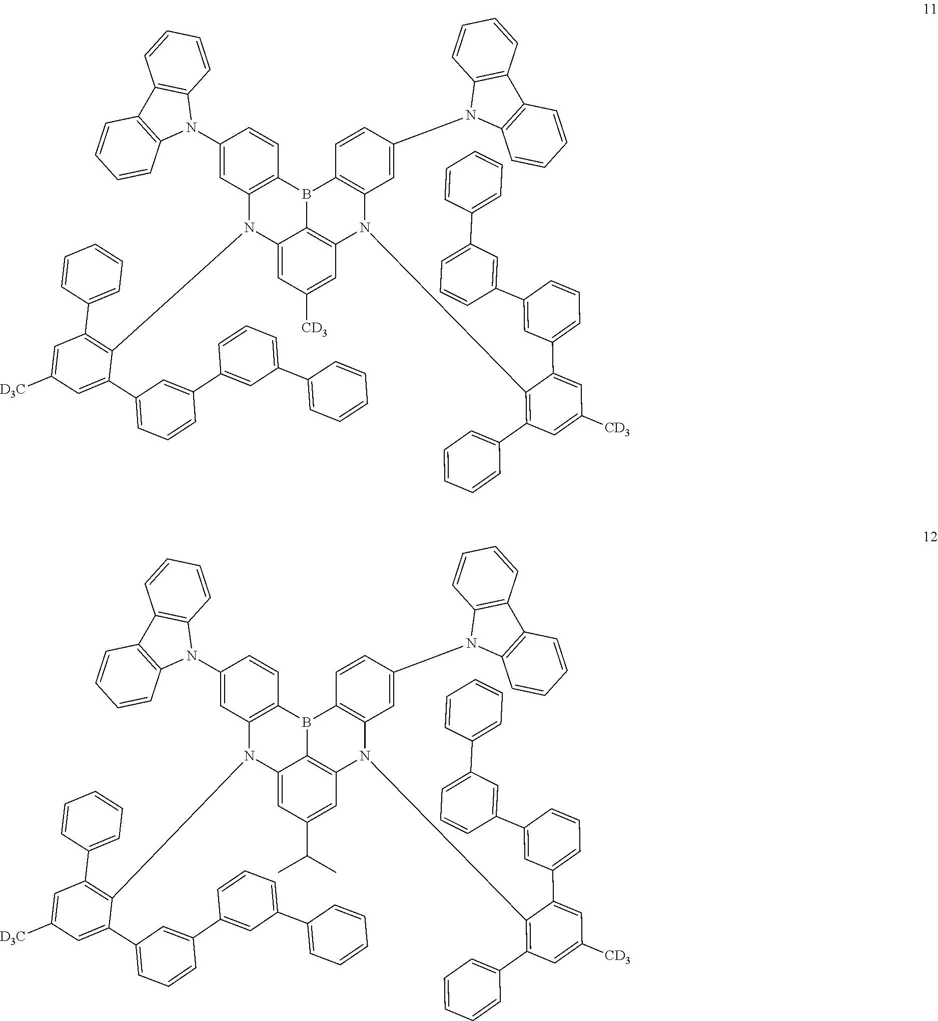 [SMILES: [2H]C([2H])([2H])c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(C([2H])([2H])[2H])cc4-c4cccc(-c5cccc(-c6ccccc6)c5)c4)c4cc(C([2H])([2H])[2H])cc2c43)c(-c2cccc(-c3cccc(-c4ccccc4)c3)c2)c1 ; [2H]C([2H])([2H])c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(C([2H])([2H])[2H])cc4-c4cccc(-c5cccc(-c6ccccc6)c5)c4)c4cc(C(C)C)cc2c43)c(-c2cccc(-c3cccc(-c4ccccc4)c3)c2)c1]

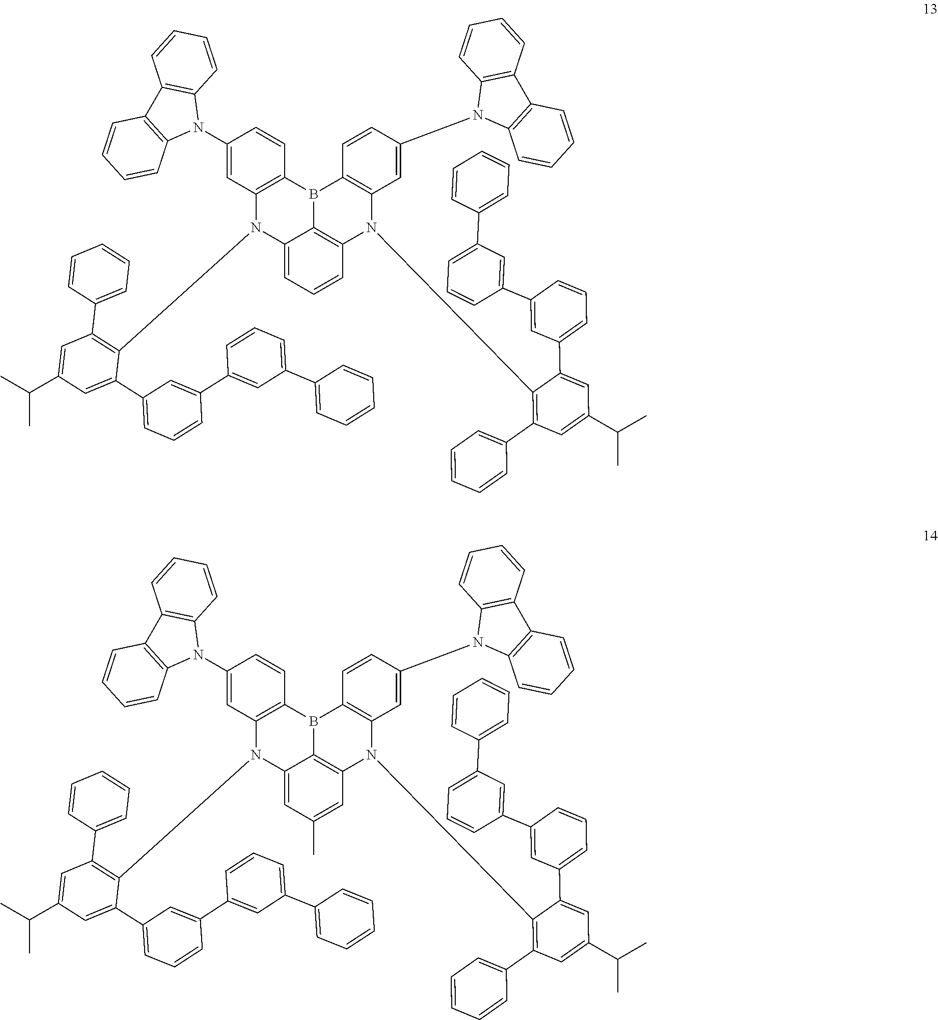

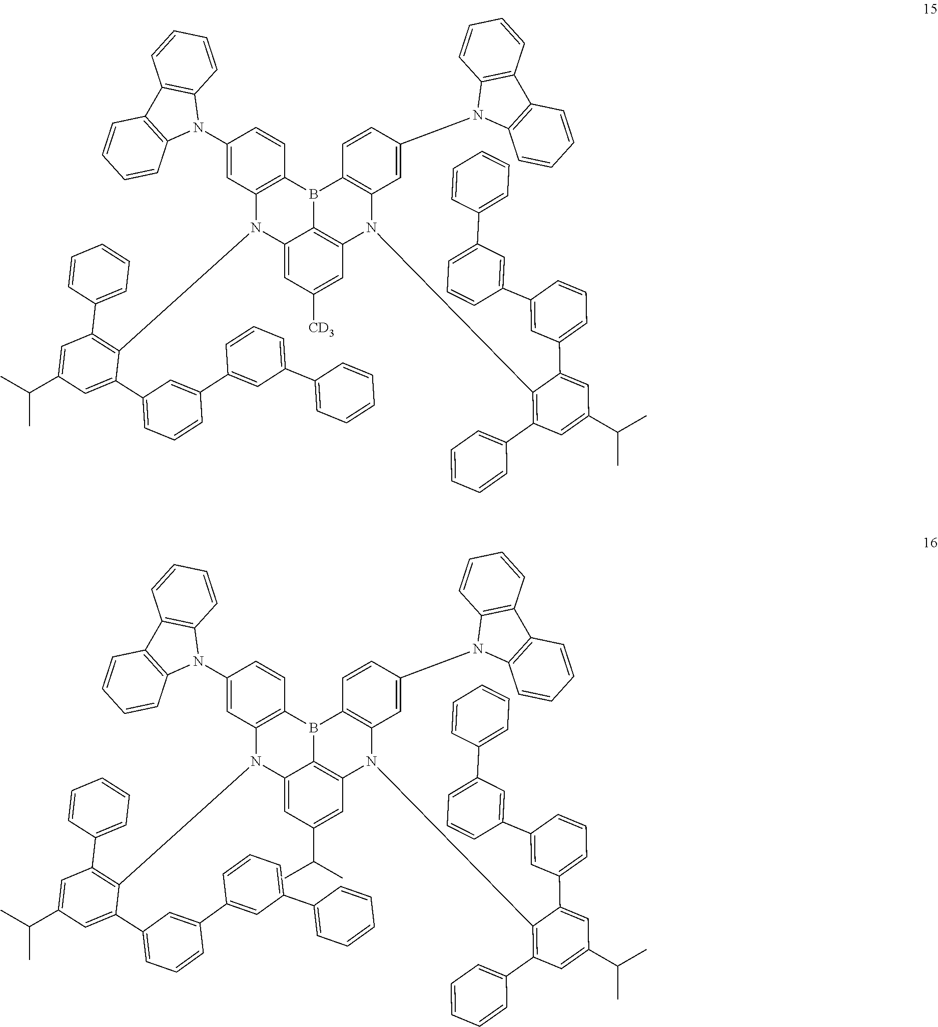

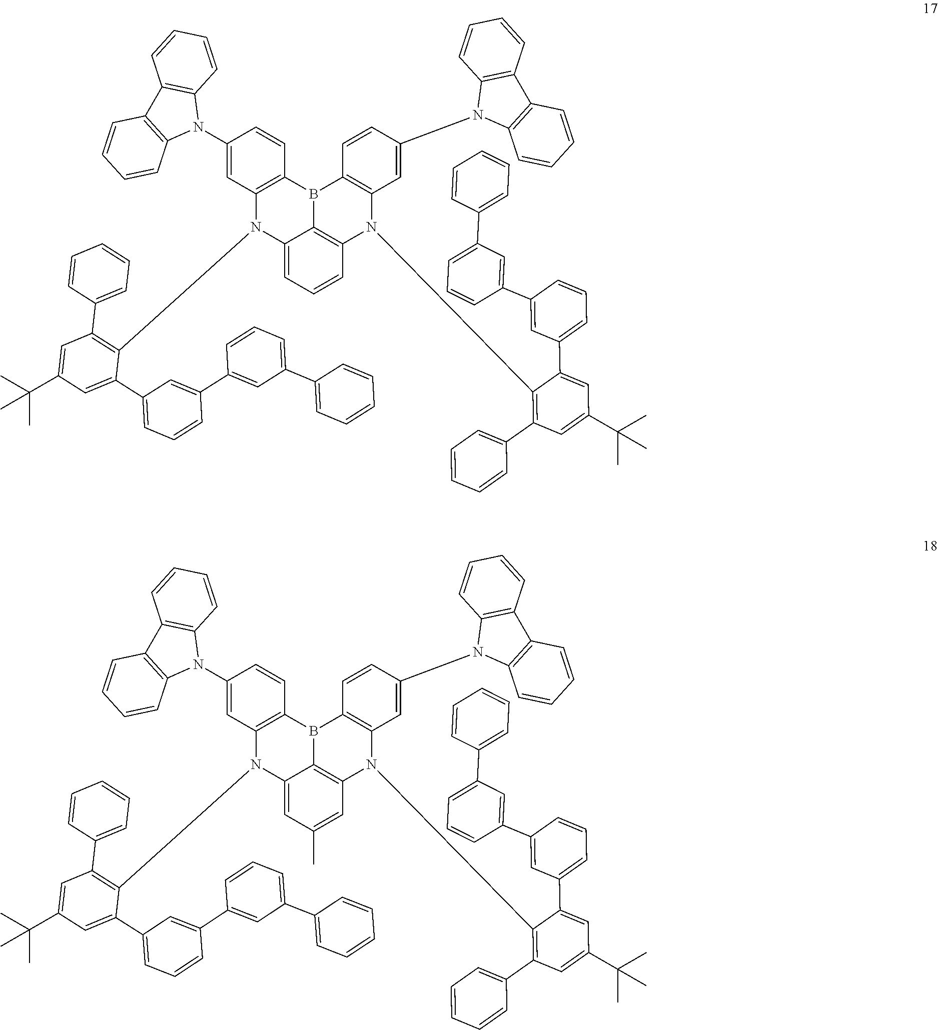

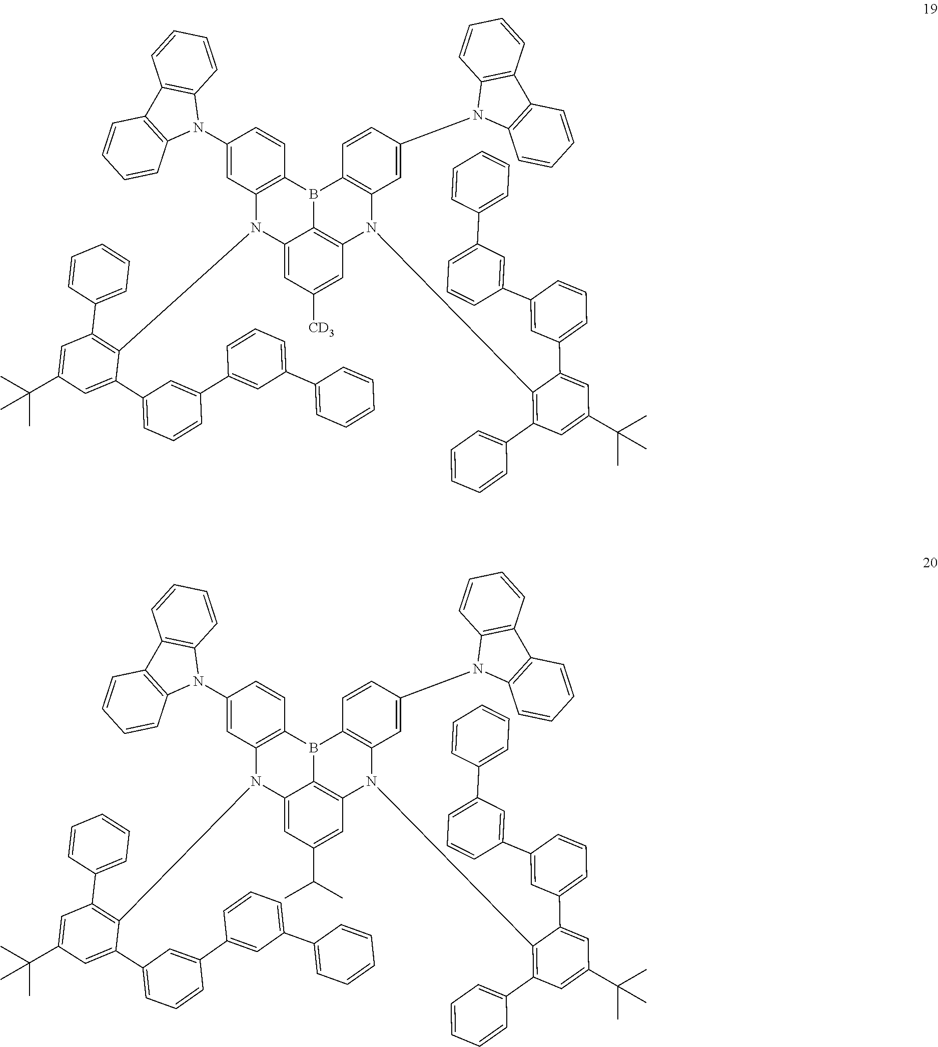

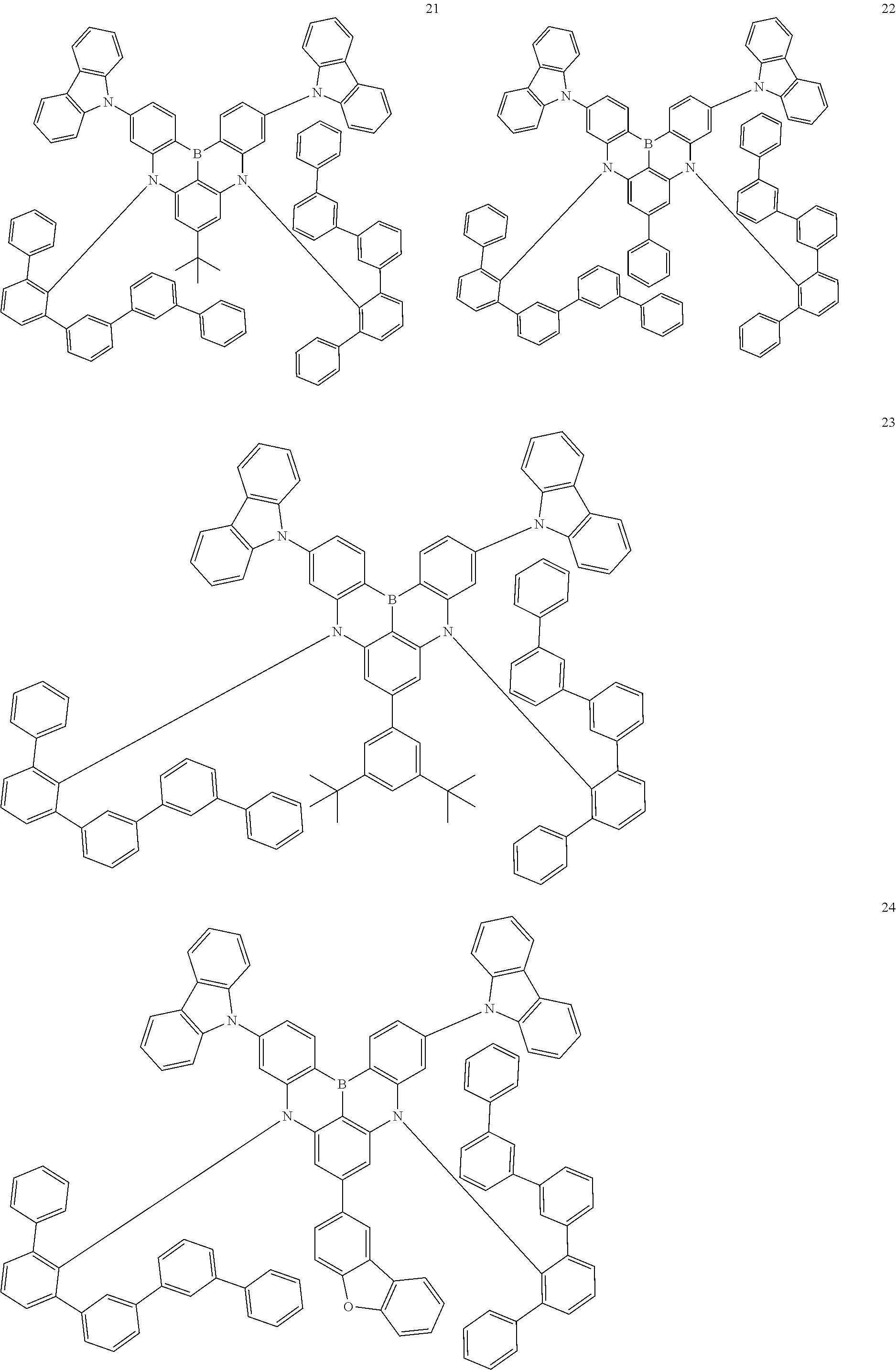

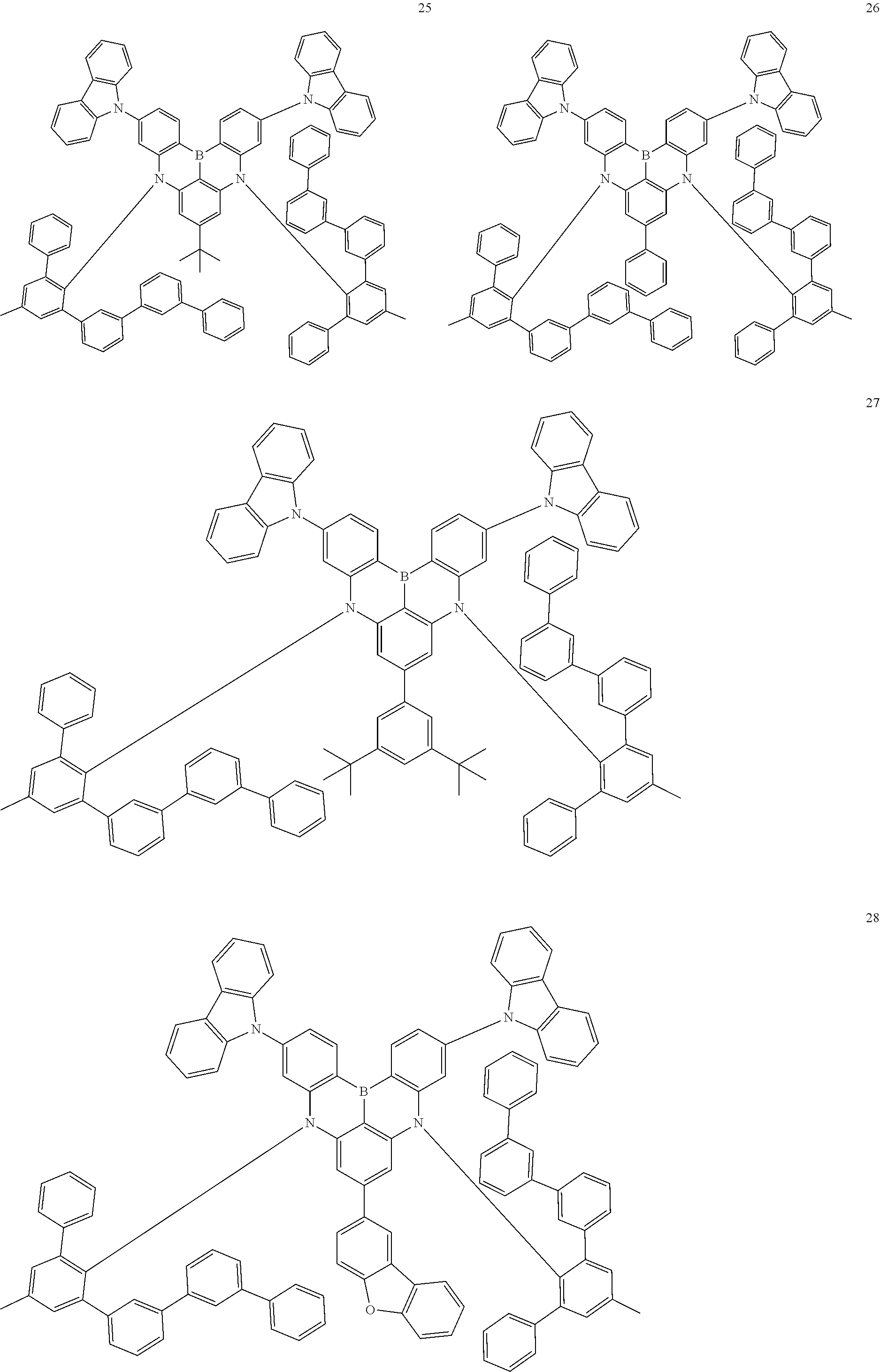

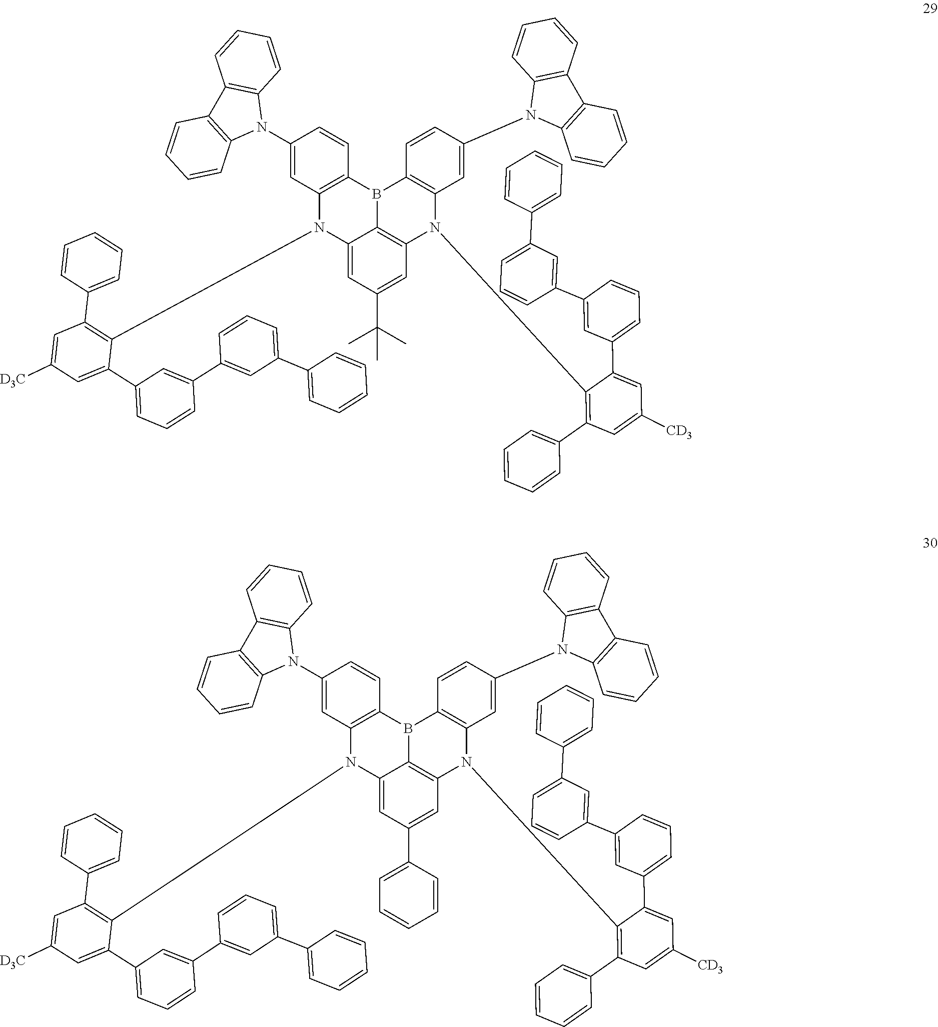 [SMILES: [2H]C([2H])([2H])c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(C([2H])([2H])[2H])cc4-c4cccc(-c5cccc(-c6ccccc6)c5)c4)c4cc(C(C)(C)C)cc2c43)c(-c2cccc(-c3cccc(-c4ccccc4)c3)c2)c1 ; [2H]C([2H])([2H])c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(C([2H])([2H])[2H])cc4-c4cccc(-c5cccc(-c6ccccc6)c5)c4)c4cc(-c5ccccc5)cc2c43)c(-c2cccc(-c3cccc(-c4ccccc4)c3)c2)c1]

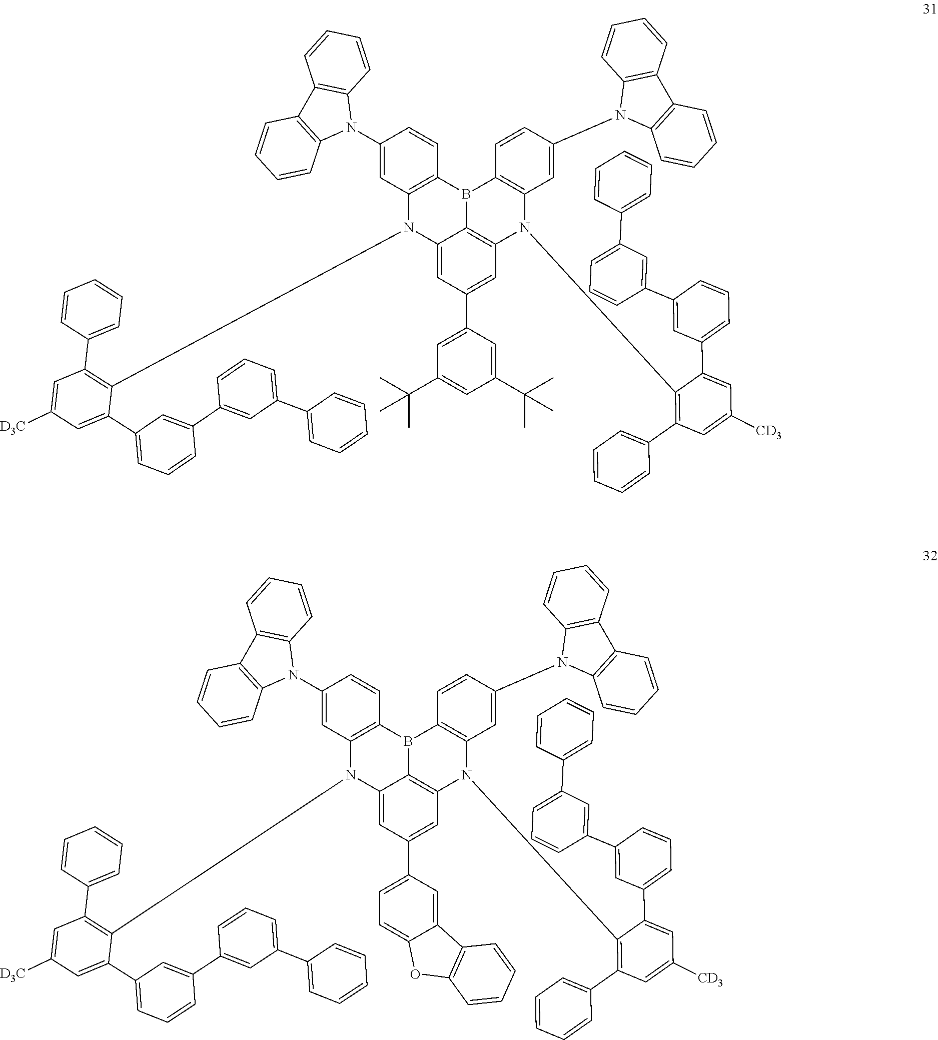 [SMILES: [2H]C([2H])([2H])c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(C([2H])([2H])[2H])cc4-c4cccc(-c5cccc(-c6ccccc6)c5)c4)c4cc(-c5cc(C(C)(C)C)cc(C(C)(C)C)c5)cc2c43)c(-c2cccc(-c3cccc(-c4ccccc4)c3)c2)c1 ; [2H]C([2H])([2H])c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cc(C([2H])([2H])[2H])cc4-c4cccc(-c5cccc(-c6ccccc6)c5)c4)c4cc(-c5ccc6oc7ccccc7c6c5)cc2c43)c(-c2cccc(-c3cccc(-c4ccccc4)c3)c2)c1]

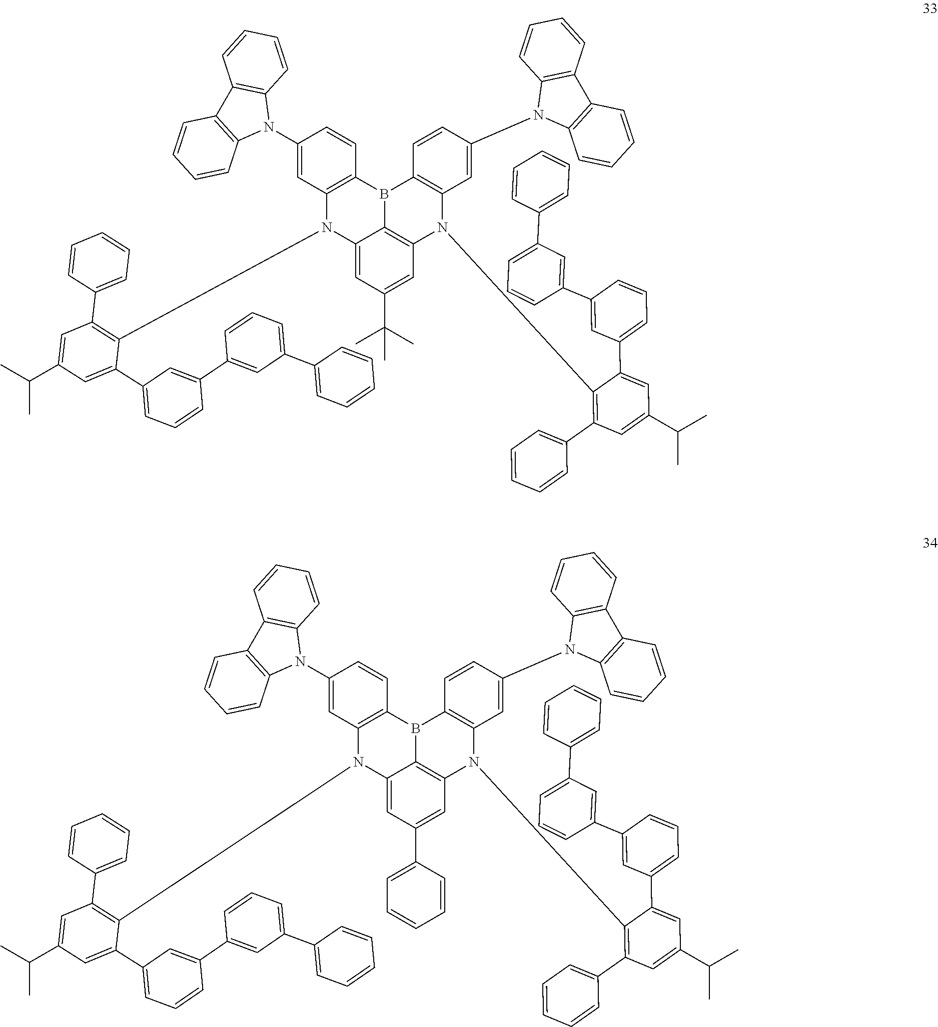

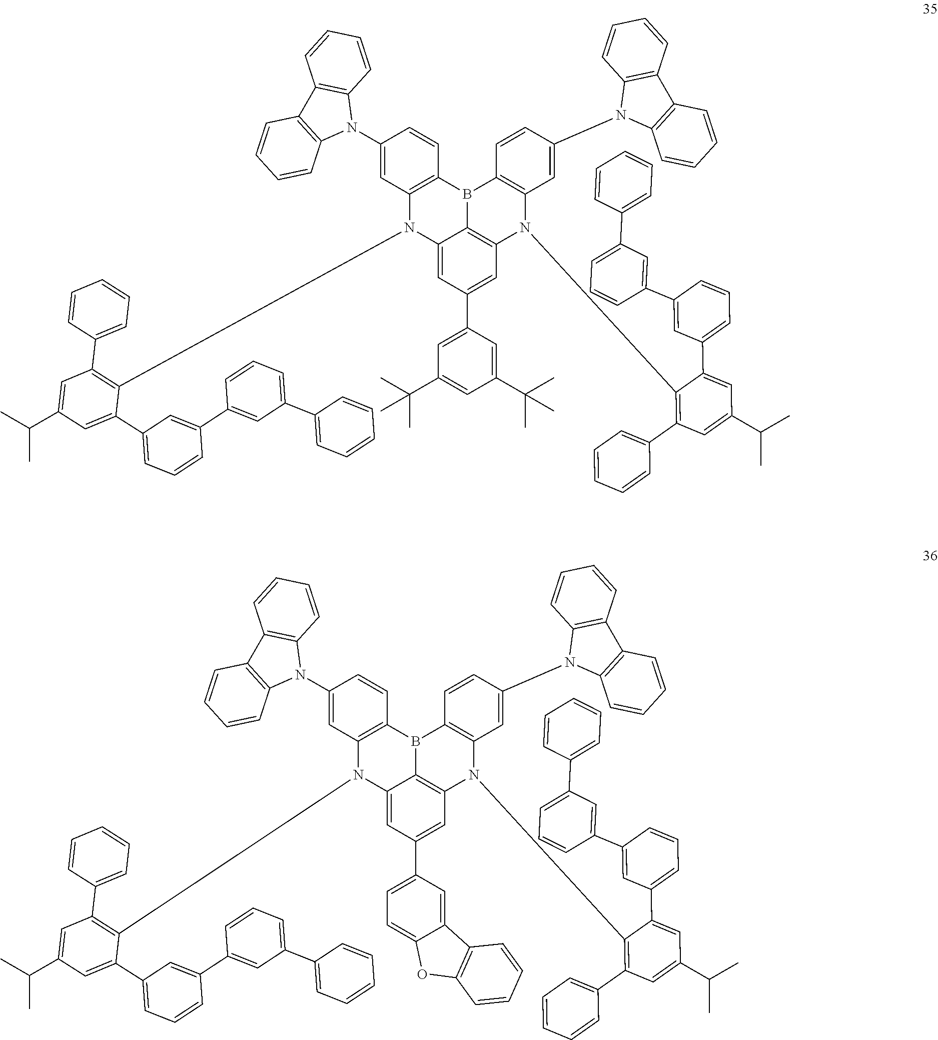

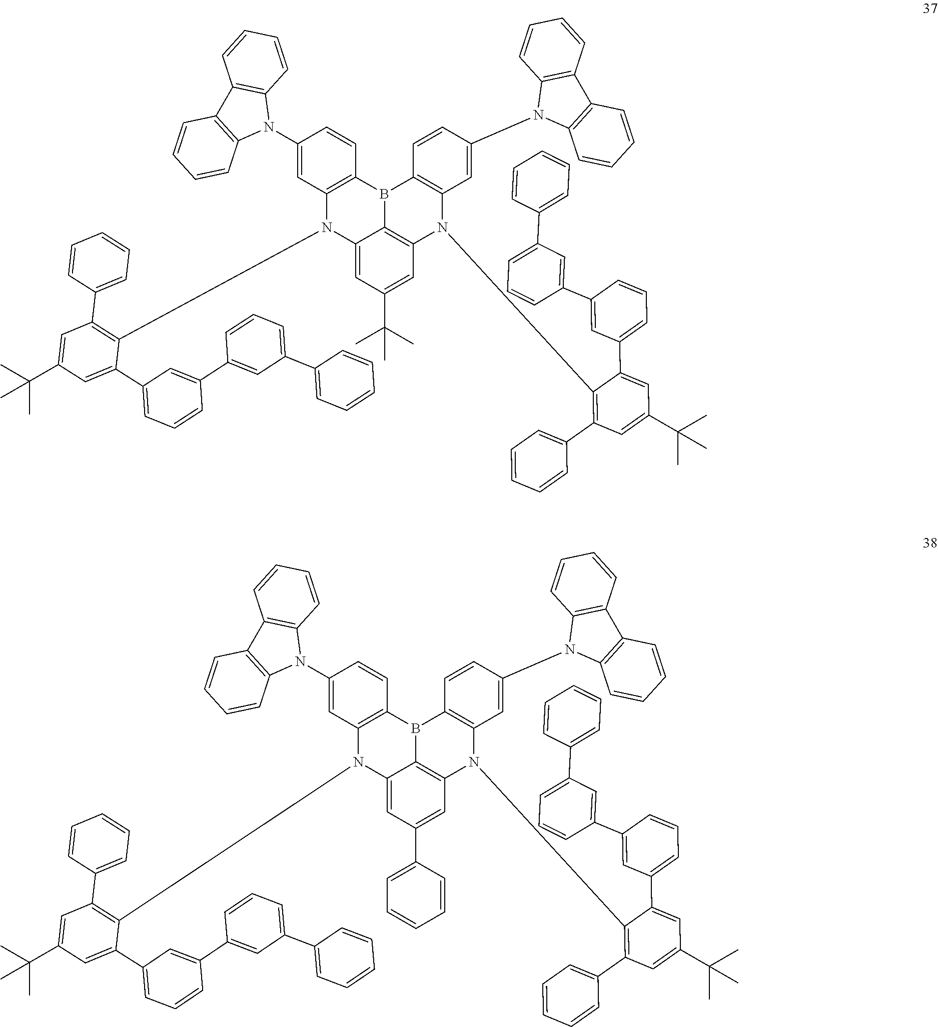

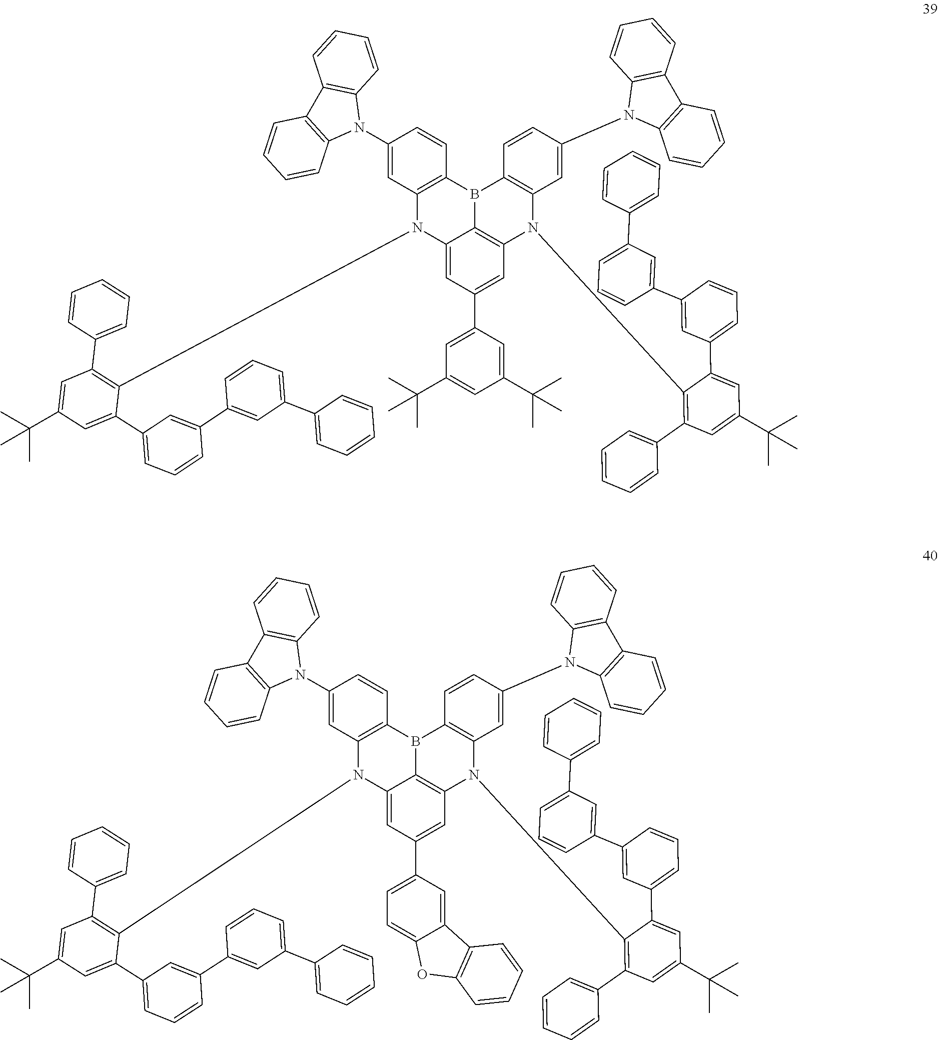

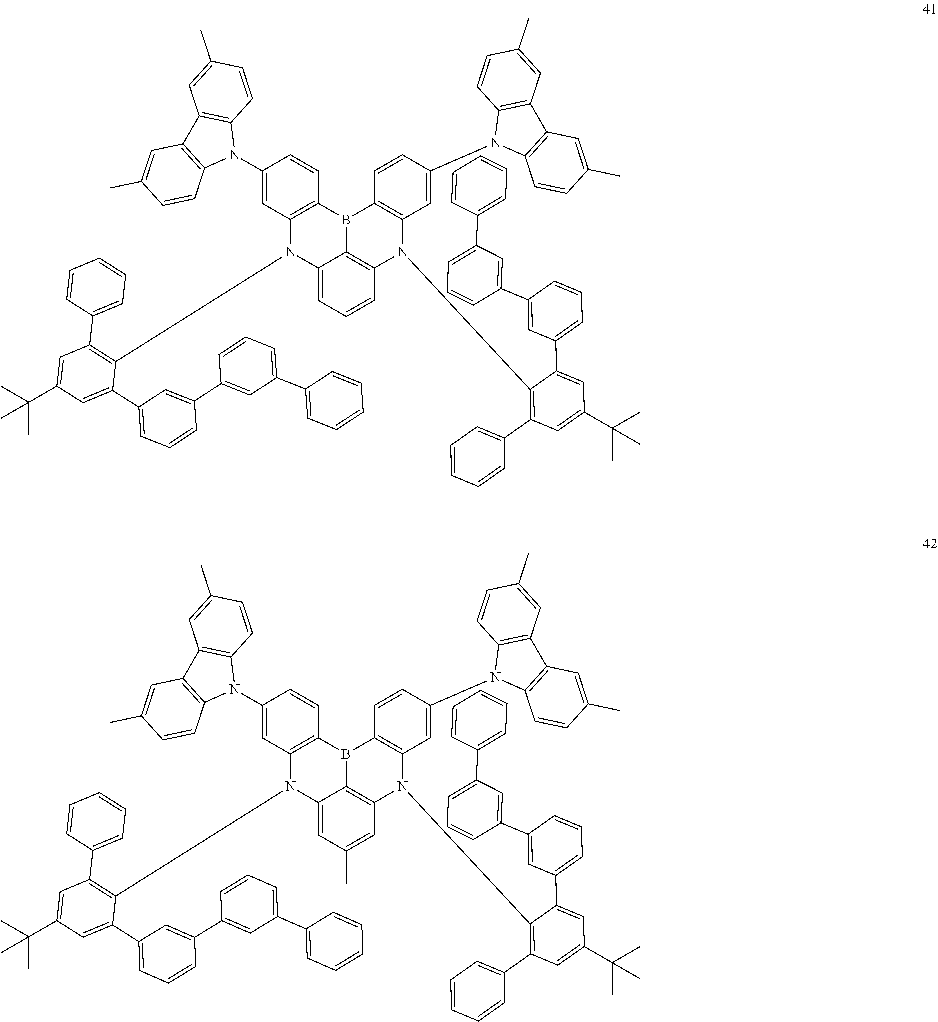

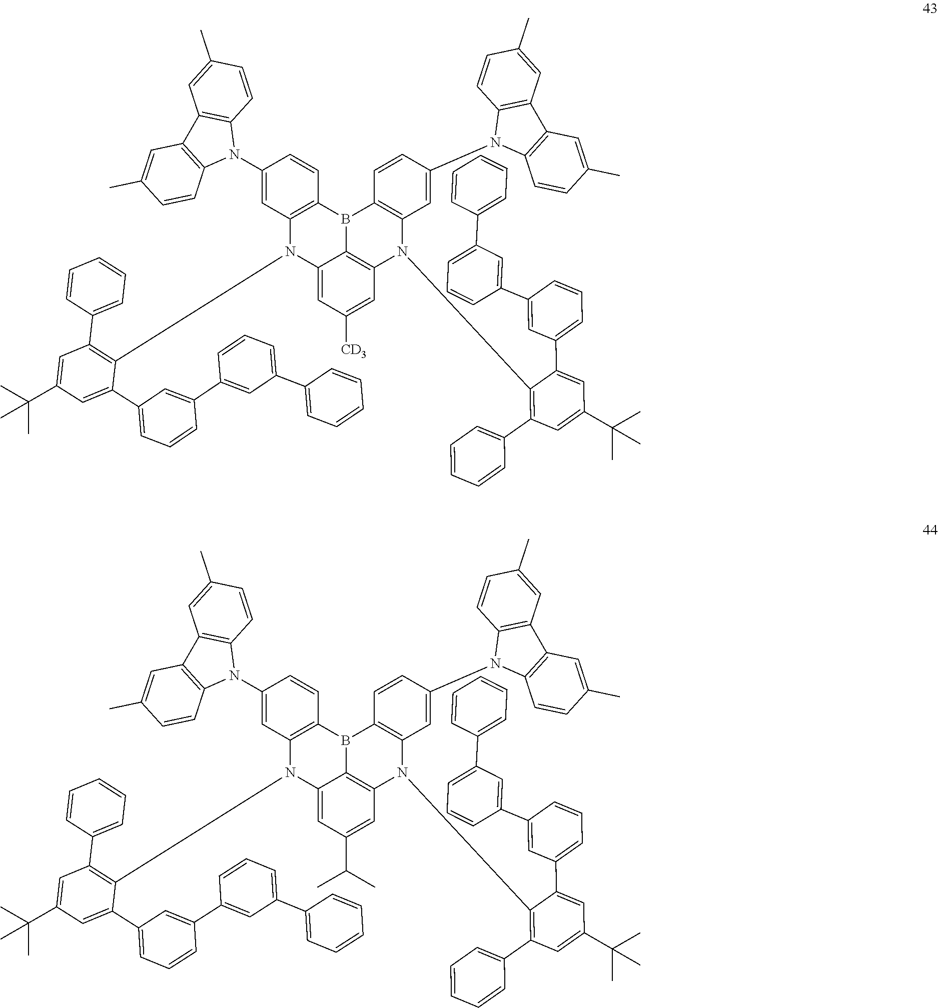

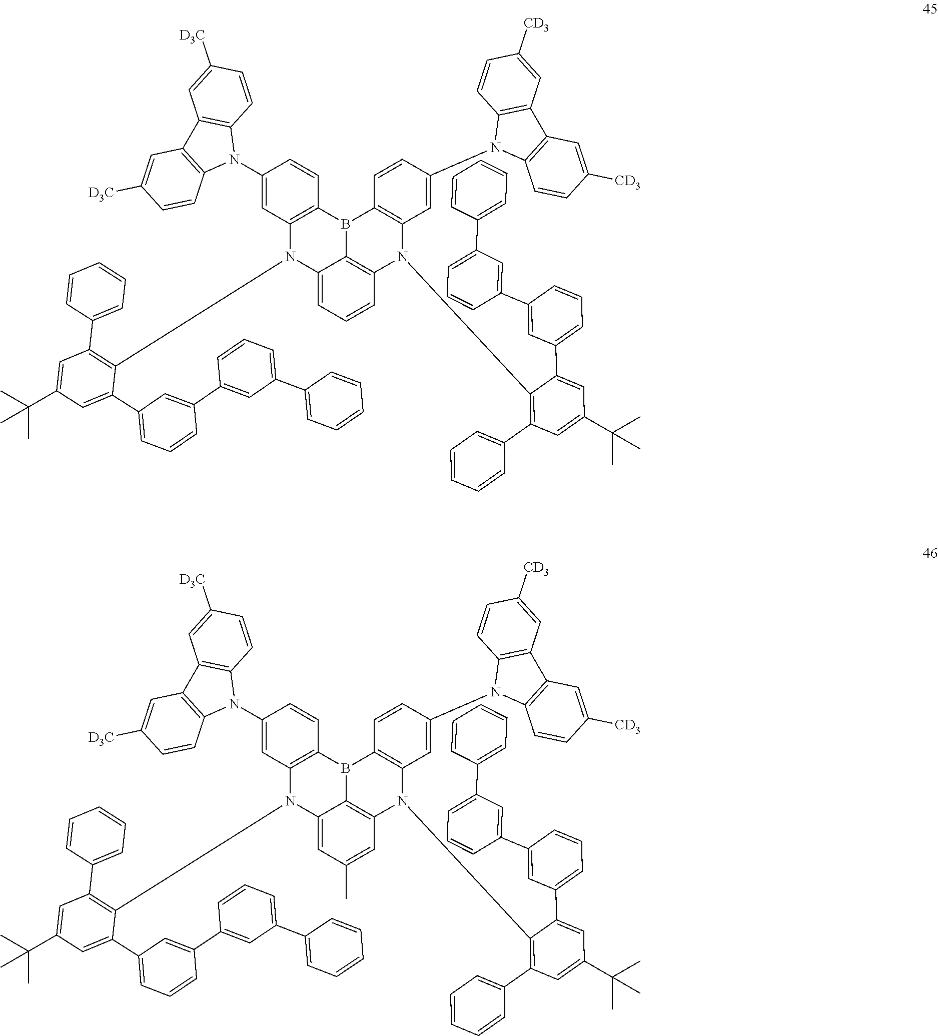

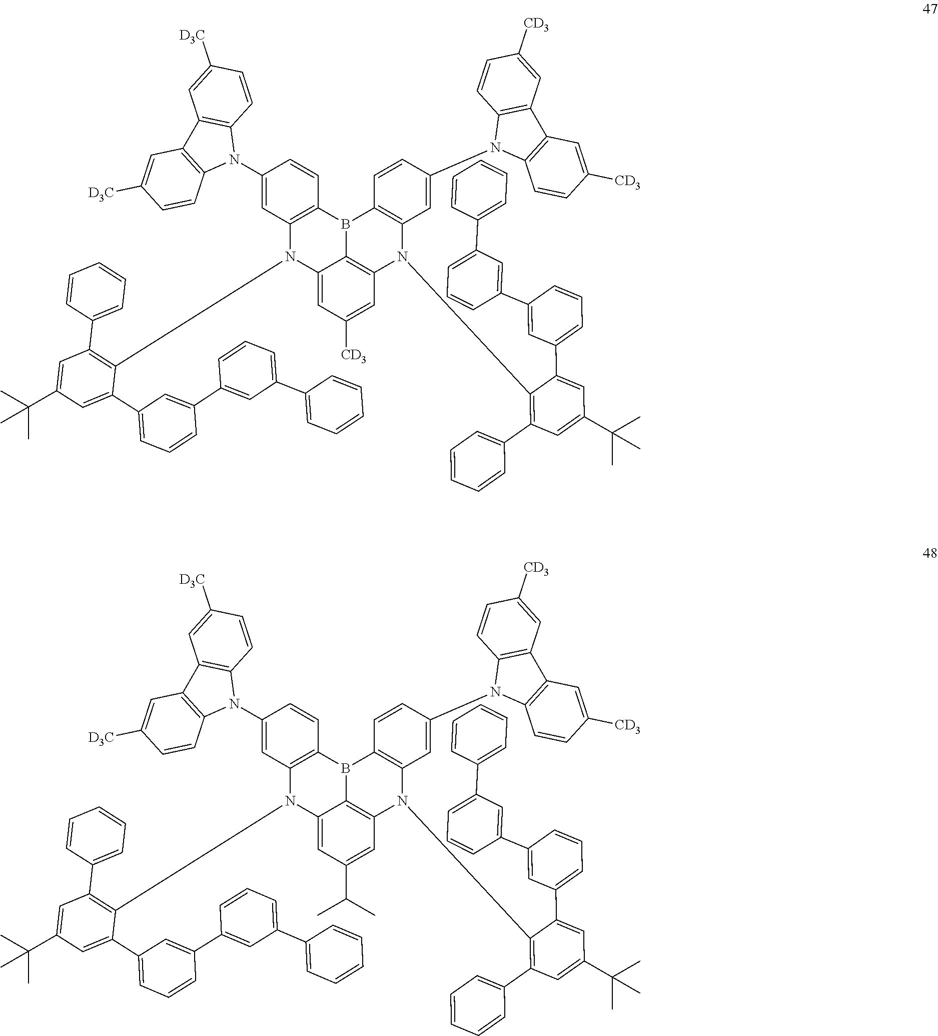

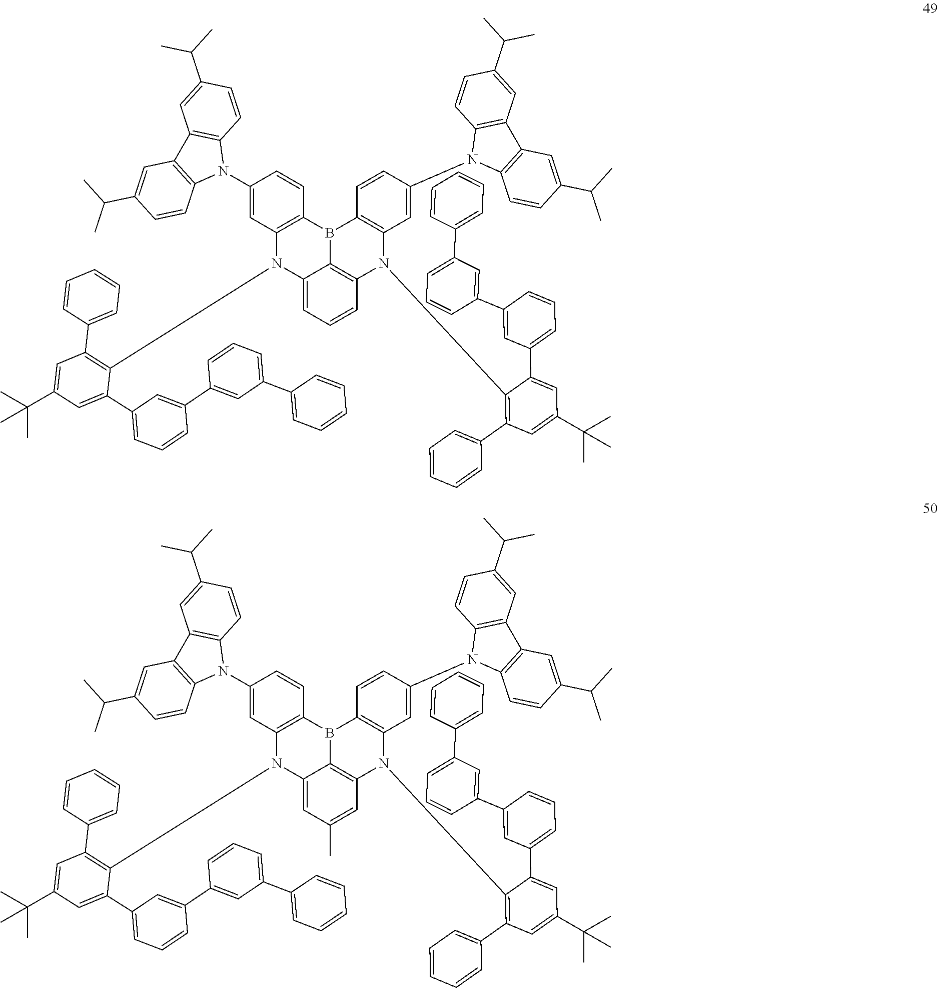

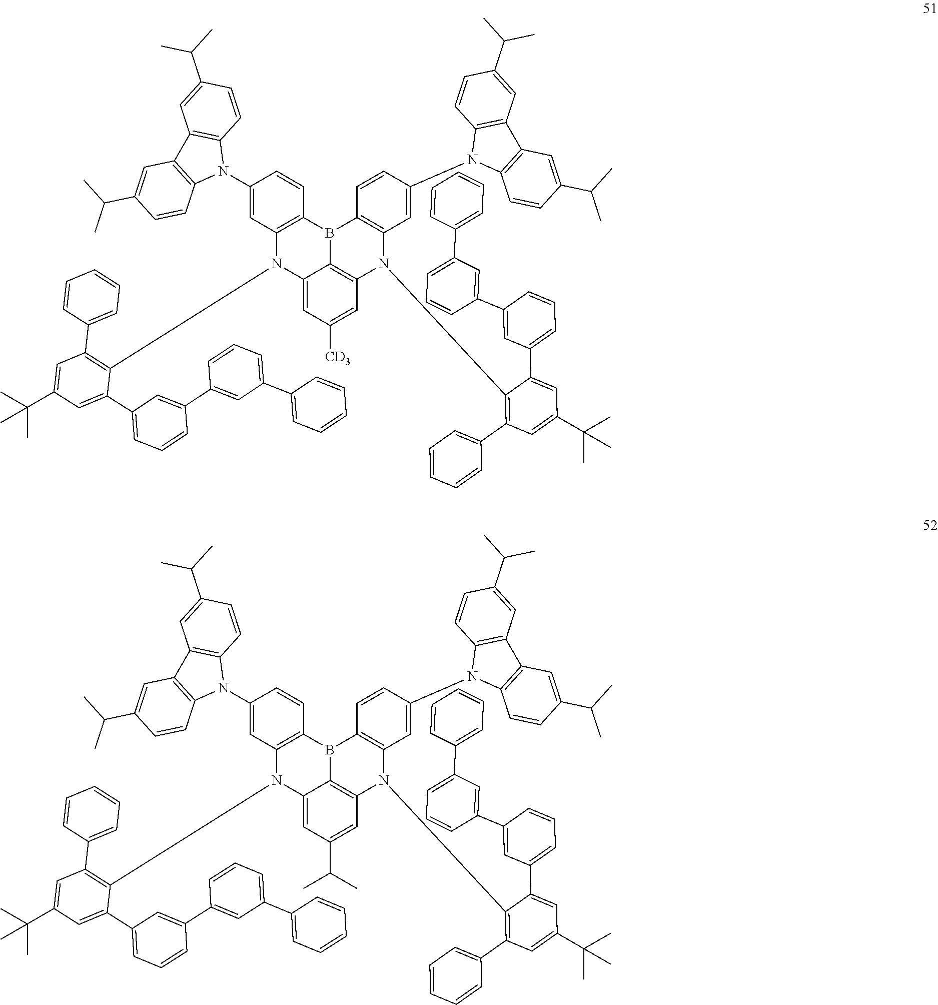

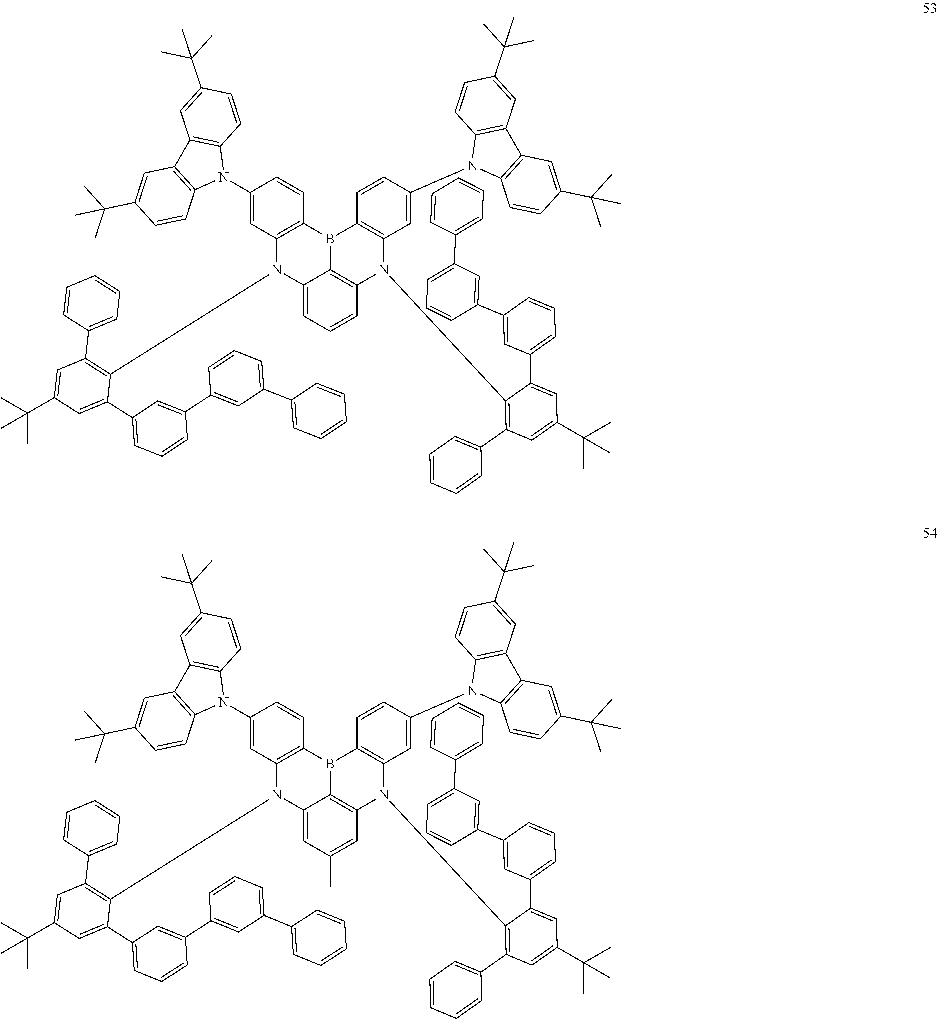

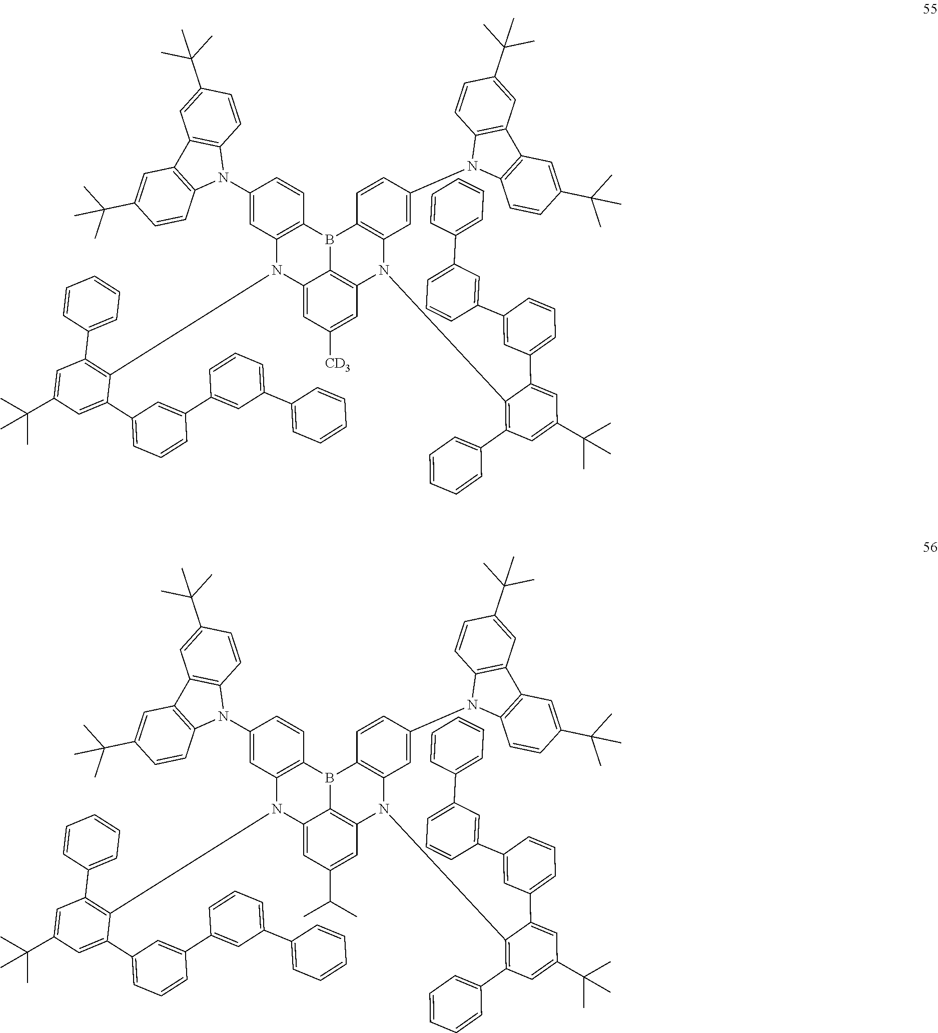

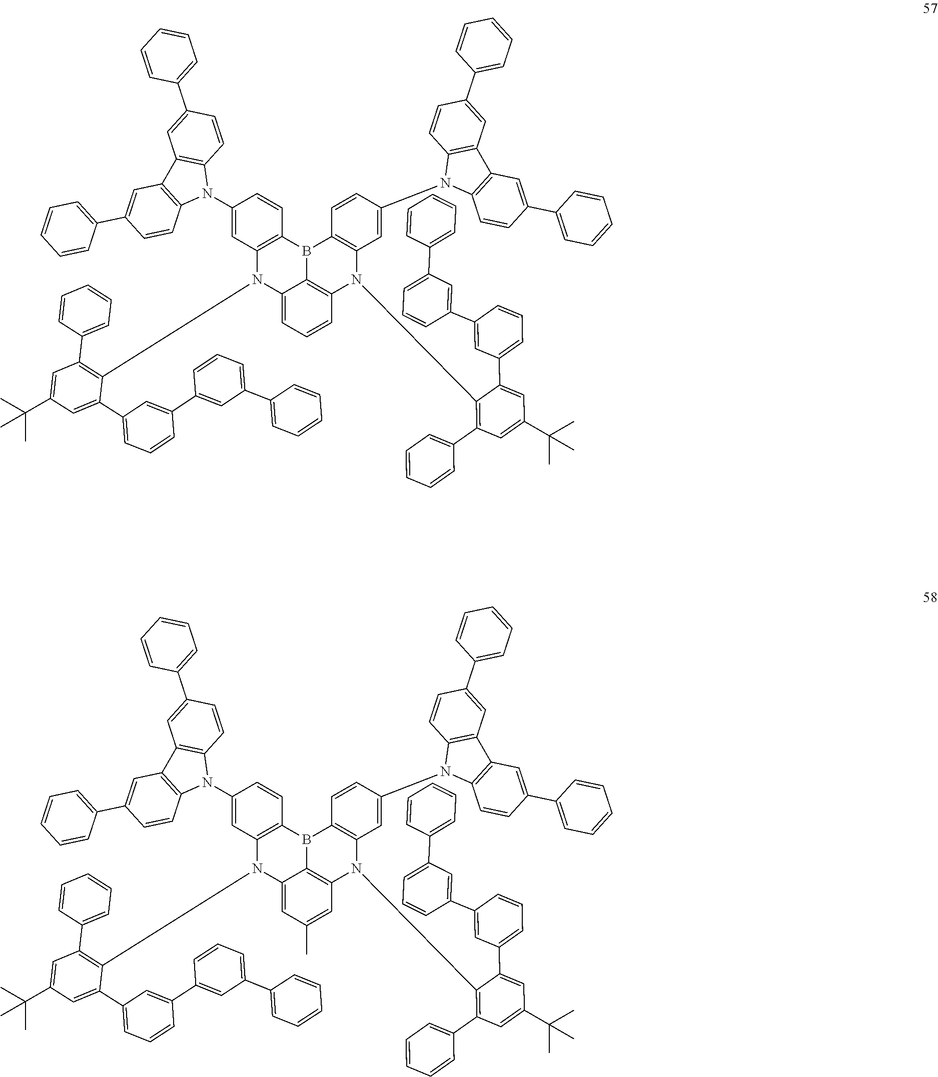 [SMILES: CC(C)(C)c1cc(-c2ccccc2)c(N2c3cc(-n4c5ccc(-c6ccccc6)cc5c5cc(-c6ccccc6)ccc54)ccc3B3c4ccc(-n5c6ccc(-c7ccccc7)cc6c6cc(-c7ccccc7)ccc65)cc4N(c4c(-c5ccccc5)cc(C(C)(C)C)cc4-c4cccc(-c5cccc(-c6ccccc6)c5)c4)c4cccc2c43)c(-c2cccc(-c3cccc(-c4ccccc4)c3)c2)c1 ; Cc1cc2c3c(c1)N(c1c(-c4ccccc4)cc(C(C)(C)C)cc1-c1cccc(-c4cccc(-c5ccccc5)c4)c1)c1cc(-n4c5ccc(-c6ccccc6)cc5c5cc(-c6ccccc6)ccc54)ccc1B3c1ccc(-n3c4ccc(-c5ccccc5)cc4c4cc(-c5ccccc5)ccc43)cc1N2c1c(-c2ccccc2)cc(C(C)(C)C)cc1-c1cccc(-c2cccc(-c3ccccc3)c2)c1]

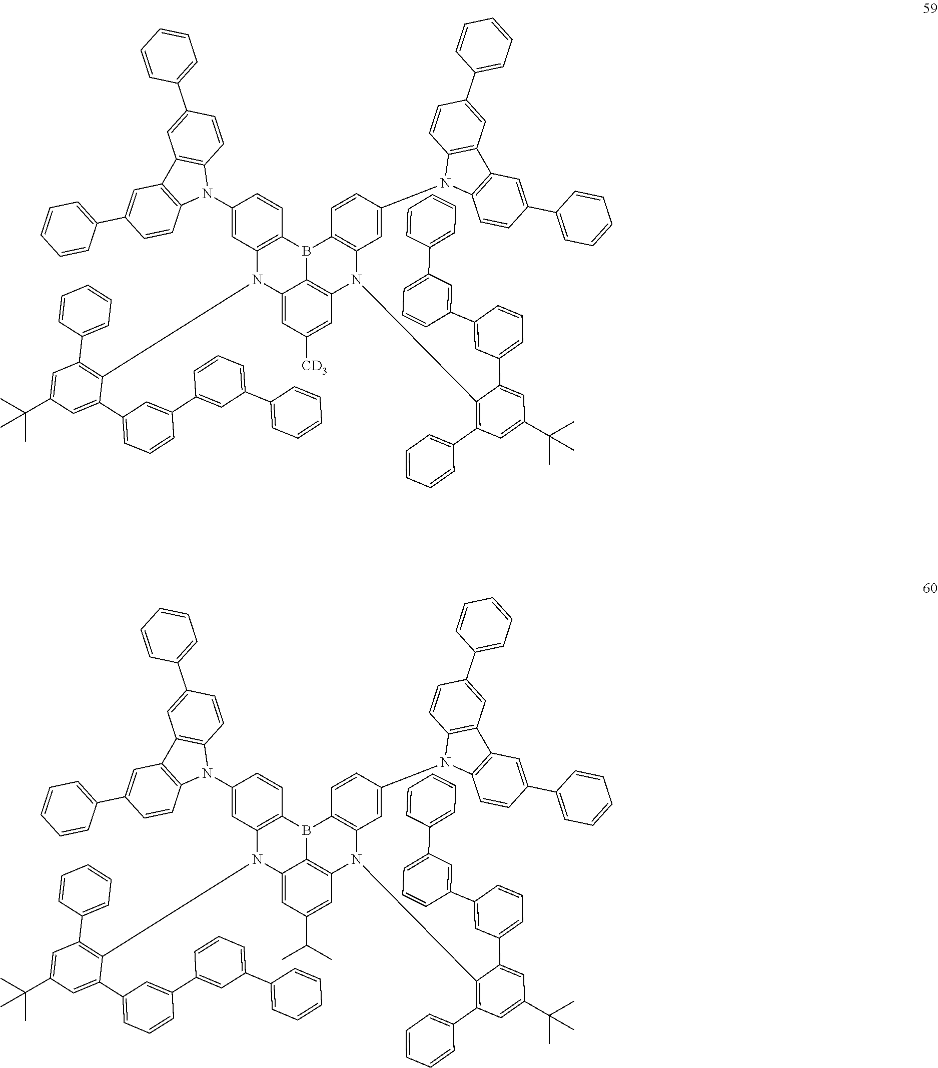

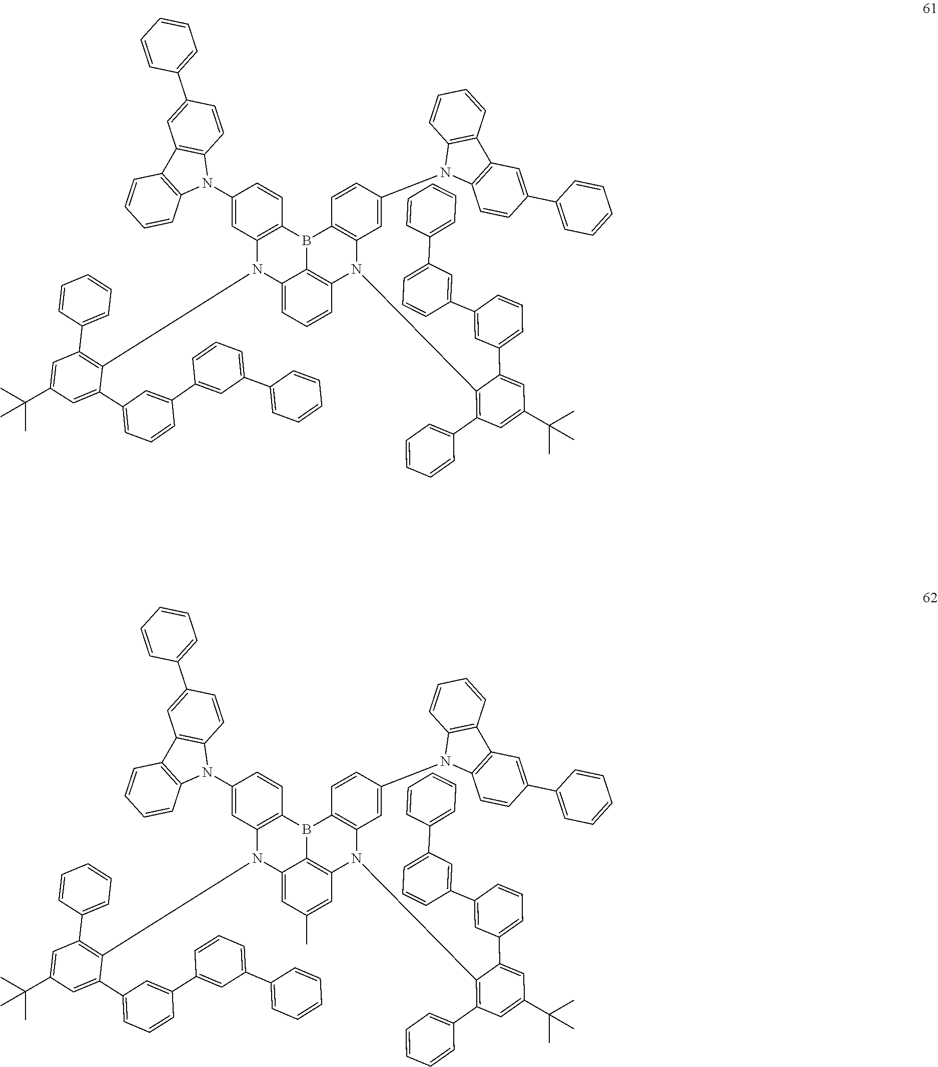 [SMILES: CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccccc5)cc(C(C)(C)C)cc4-c4cccc(-c5cccc(-c6ccccc6)c5)c4)c4cccc2c43)c(-c2cccc(-c3cccc(-c4ccccc4)c3)c2)c1 ; Cc1cc2c3c(c1)N(c1c(-c4ccccc4)cc(C(C)(C)C)cc1-c1cccc(-c4cccc(-c5ccccc5)c4)c1)c1cc(-n4c5ccccc5c5cc(-c6ccccc6)ccc54)ccc1B3c1ccc(-n3c4ccccc4c4cc(-c5ccccc5)ccc43)cc1N2c1c(-c2ccccc2)cc(C(C)(C)C)cc1-c1cccc(-c2cccc(-c3ccccc3)c2)c1]

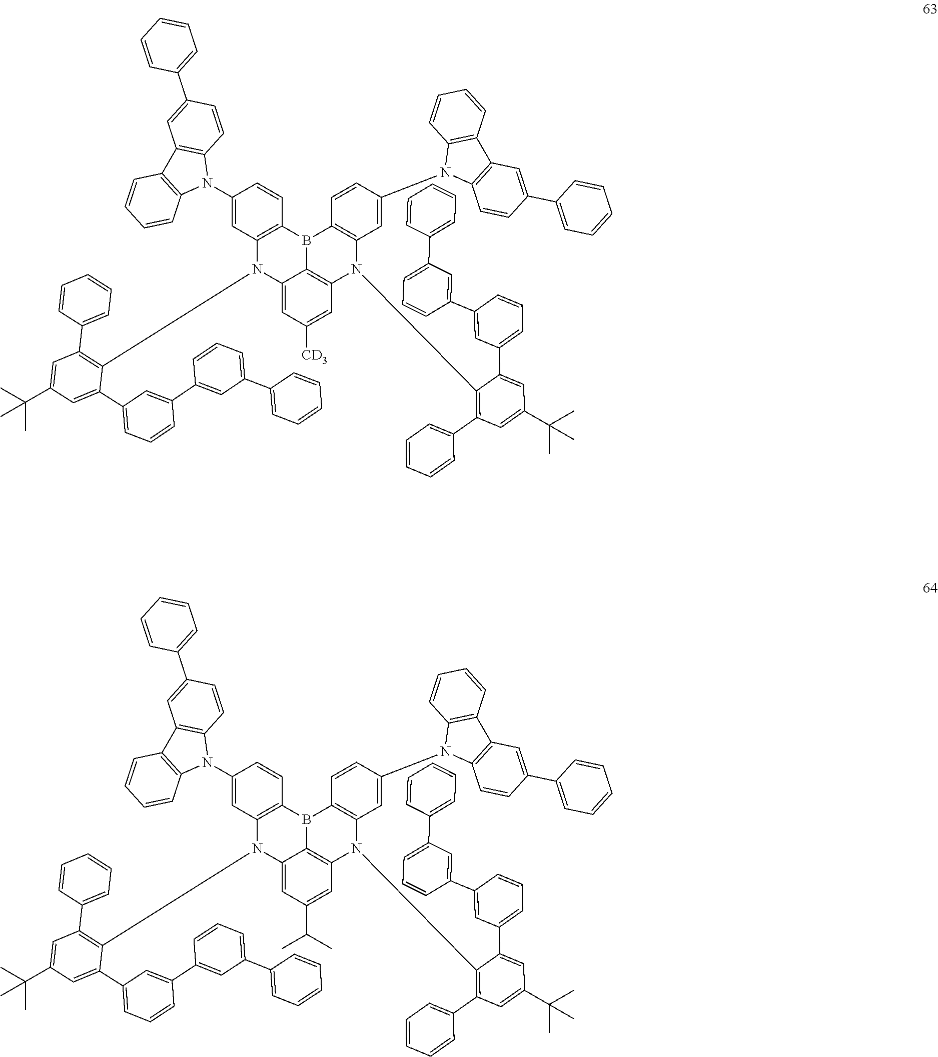 [SMILES: [2H]C([2H])([2H])c1cc2c3c(c1)N(c1c(-c4ccccc4)cc(C(C)(C)C)cc1-c1cccc(-c4cccc(-c5ccccc5)c4)c1)c1cc(-n4c5ccccc5c5cc(-c6ccccc6)ccc54)ccc1B3c1ccc(-n3c4ccccc4c4cc(-c5ccccc5)ccc43)cc1N2c1c(-c2ccccc2)cc(C(C)(C)C)cc1-c1cccc(-c2cccc(-c3ccccc3)c2)c1 ; CC(C)c1cc2c3c(c1)N(c1c(-c4ccccc4)cc(C(C)(C)C)cc1-c1cccc(-c4cccc(-c5ccccc5)c4)c1)c1cc(-n4c5ccccc5c5cc(-c6ccccc6)ccc54)ccc1B3c1ccc(-n3c4ccccc4c4cc(-c5ccccc5)ccc43)cc1N2c1c(-c2ccccc2)cc(C(C)(C)C)cc1-c1cccc(-c2cccc(-c3ccccc3)c2)c1]

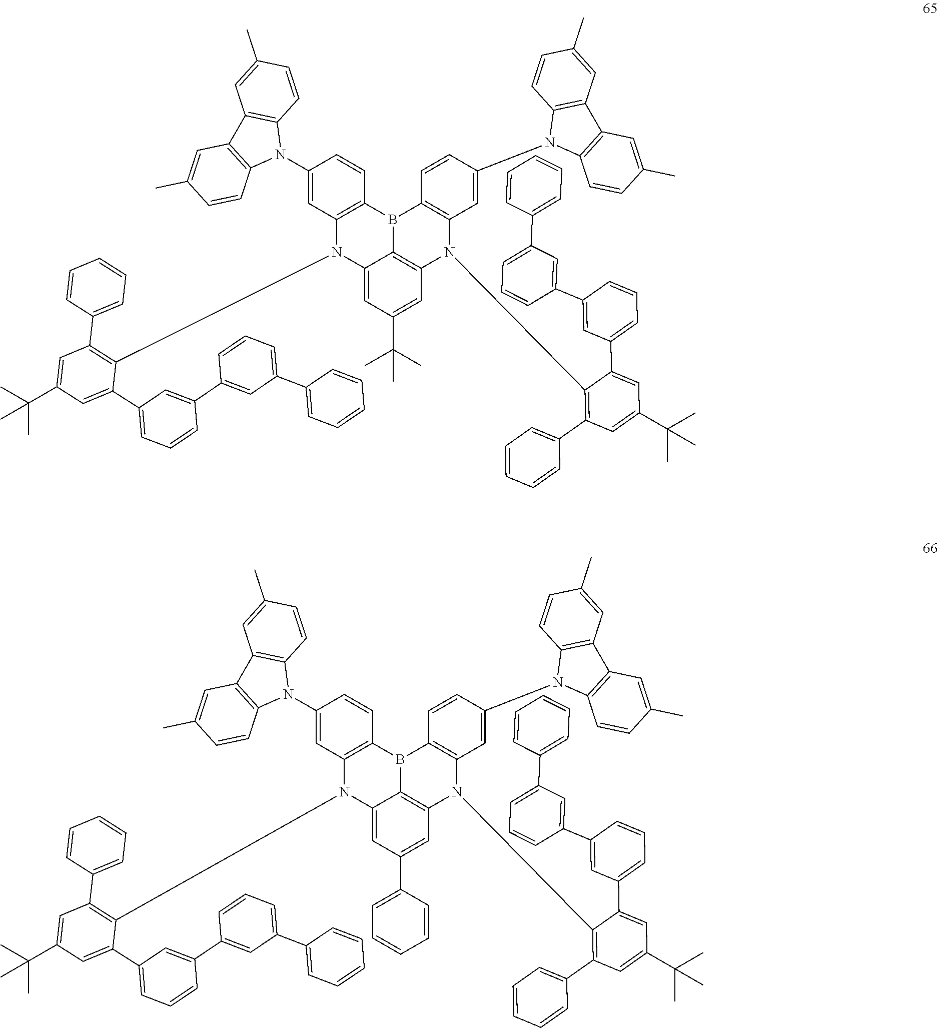

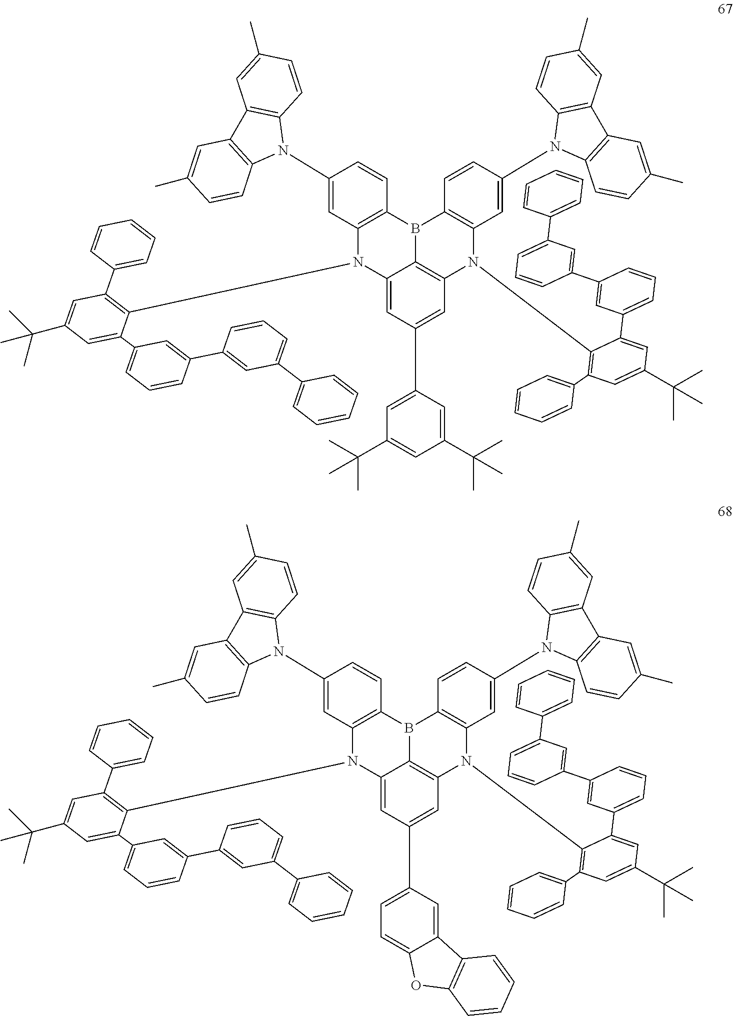

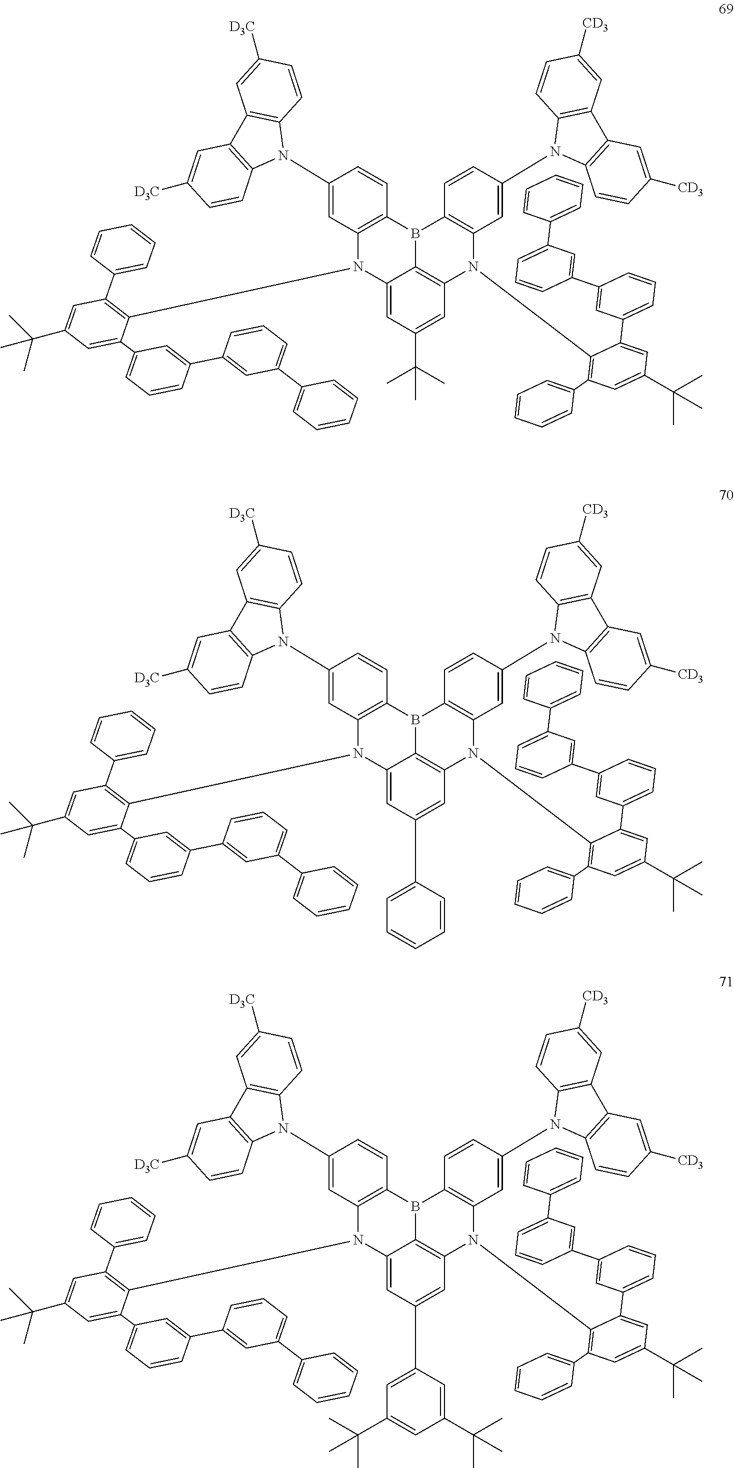

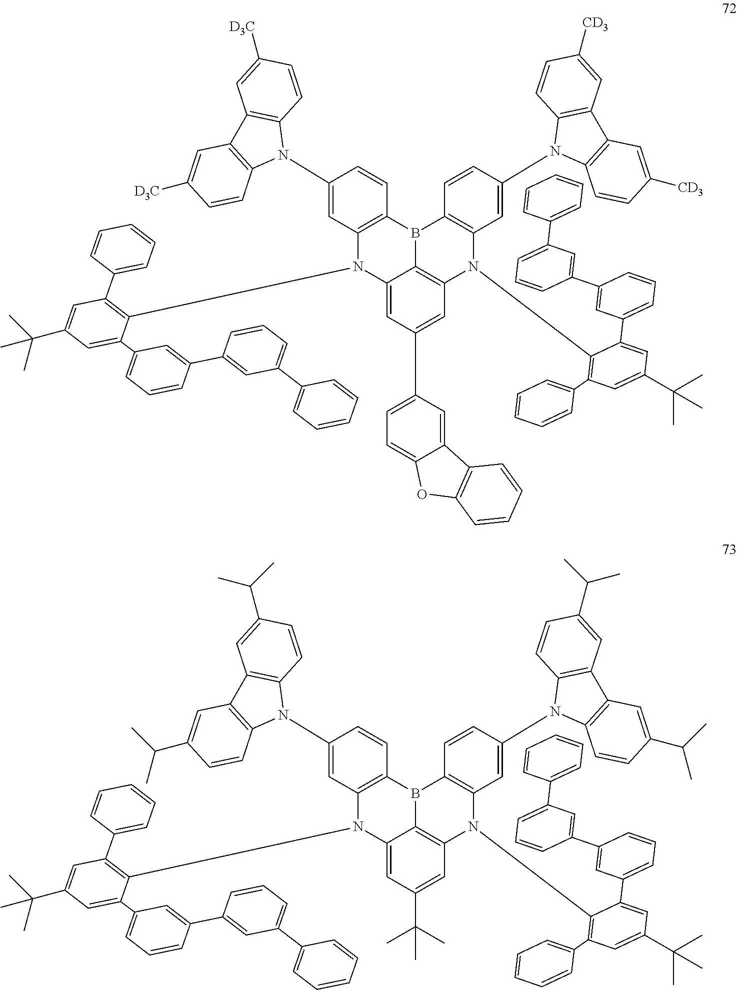

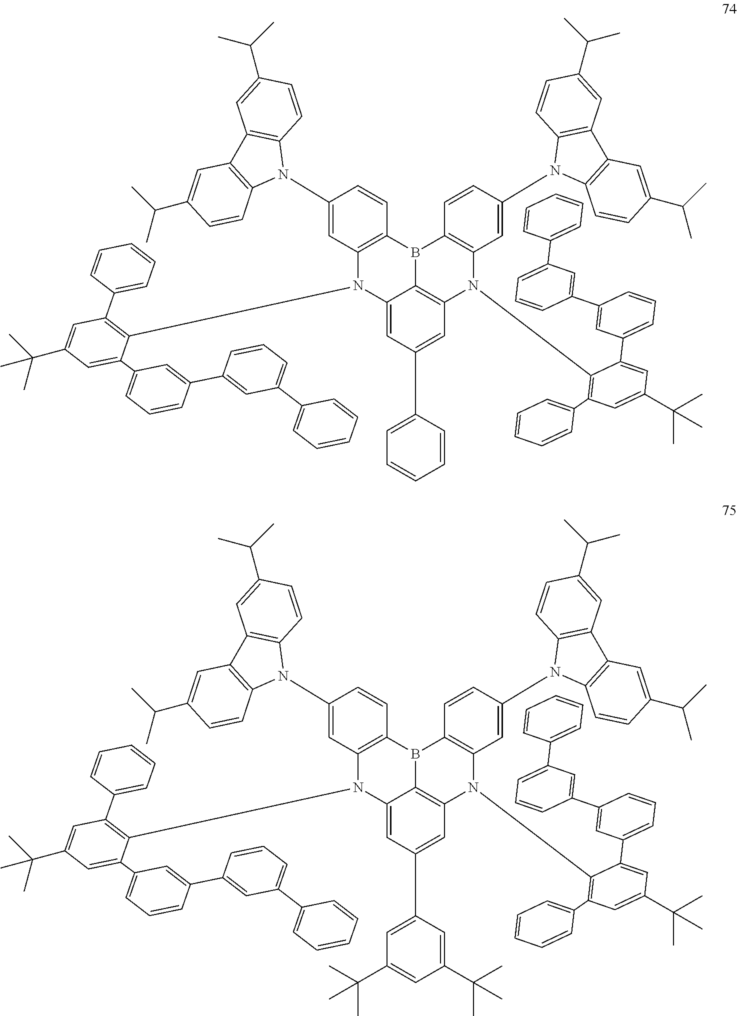

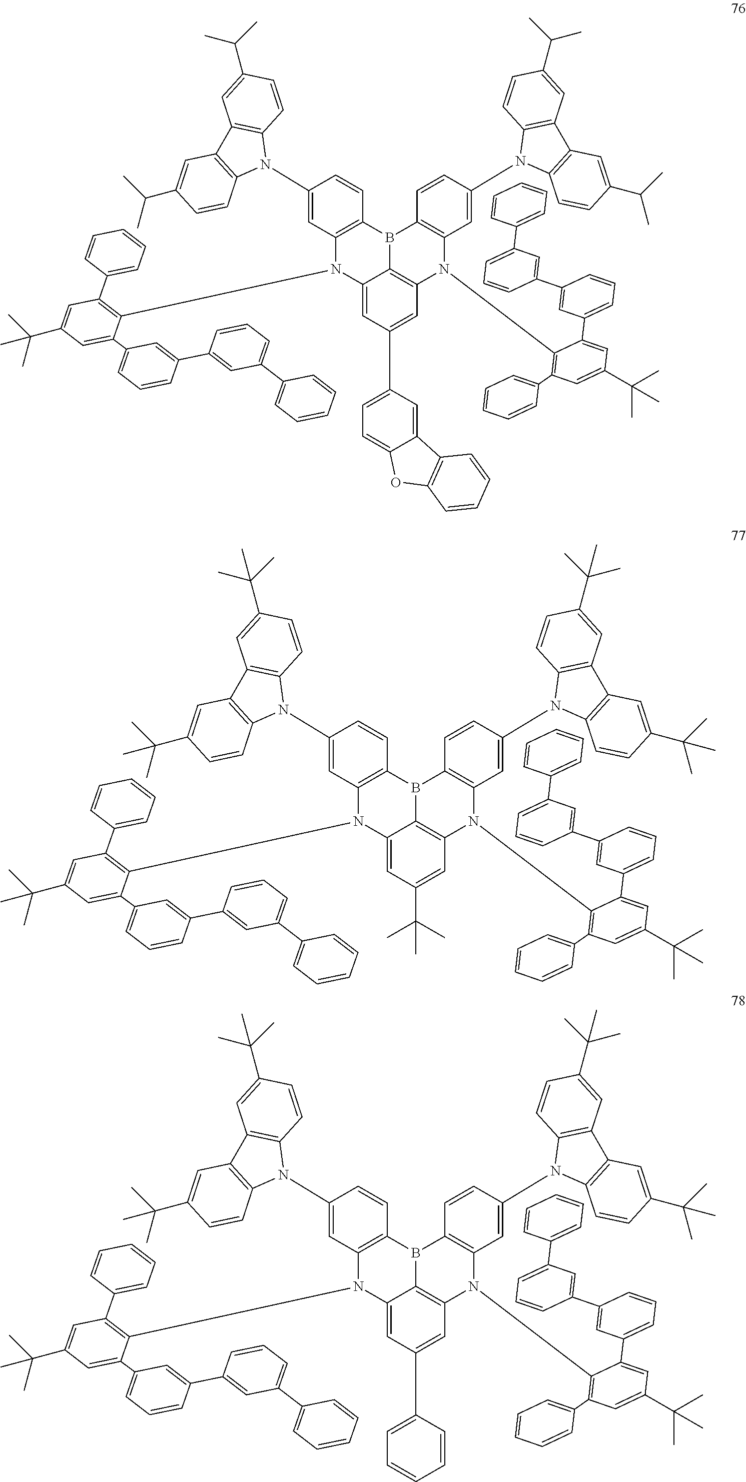

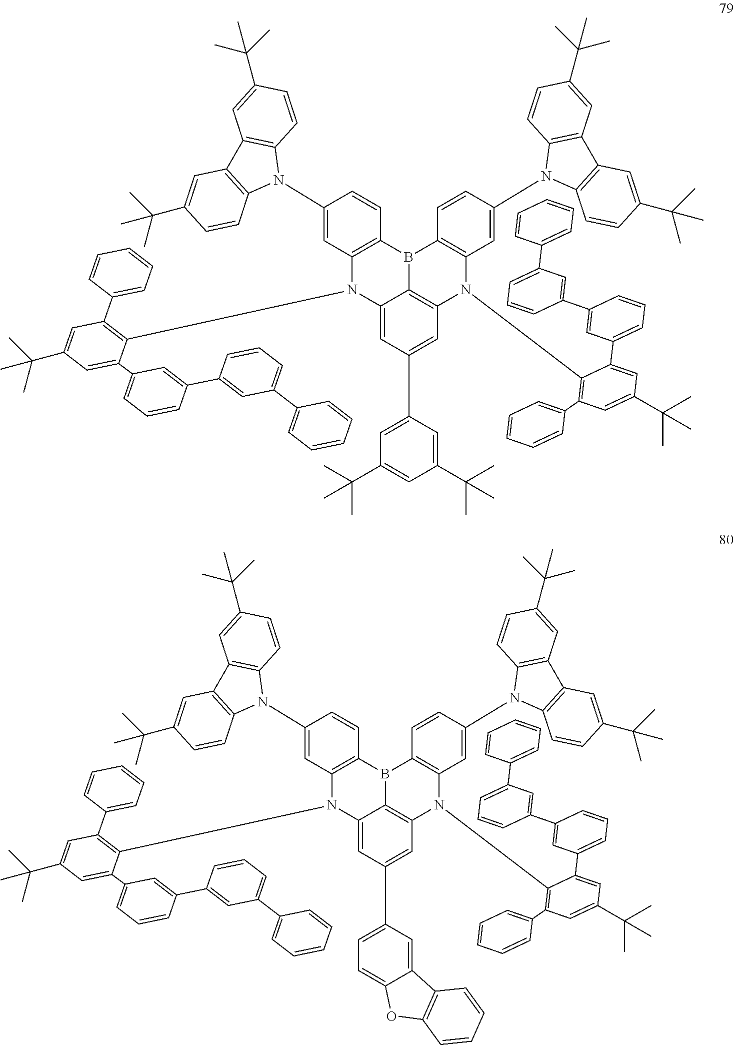

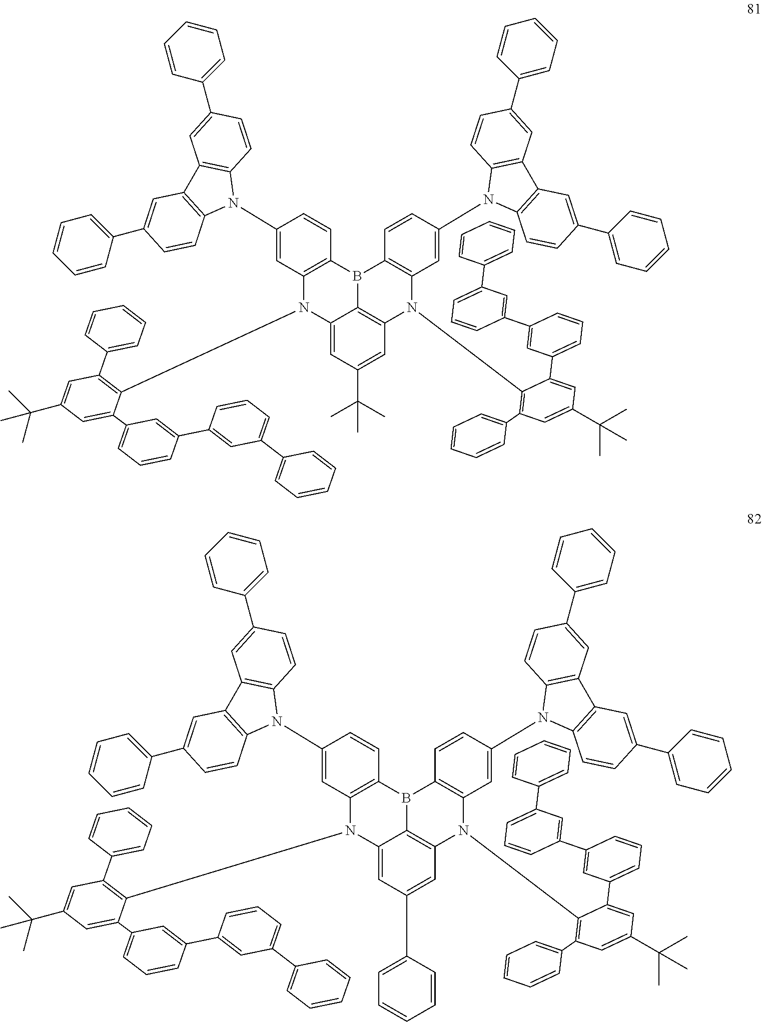

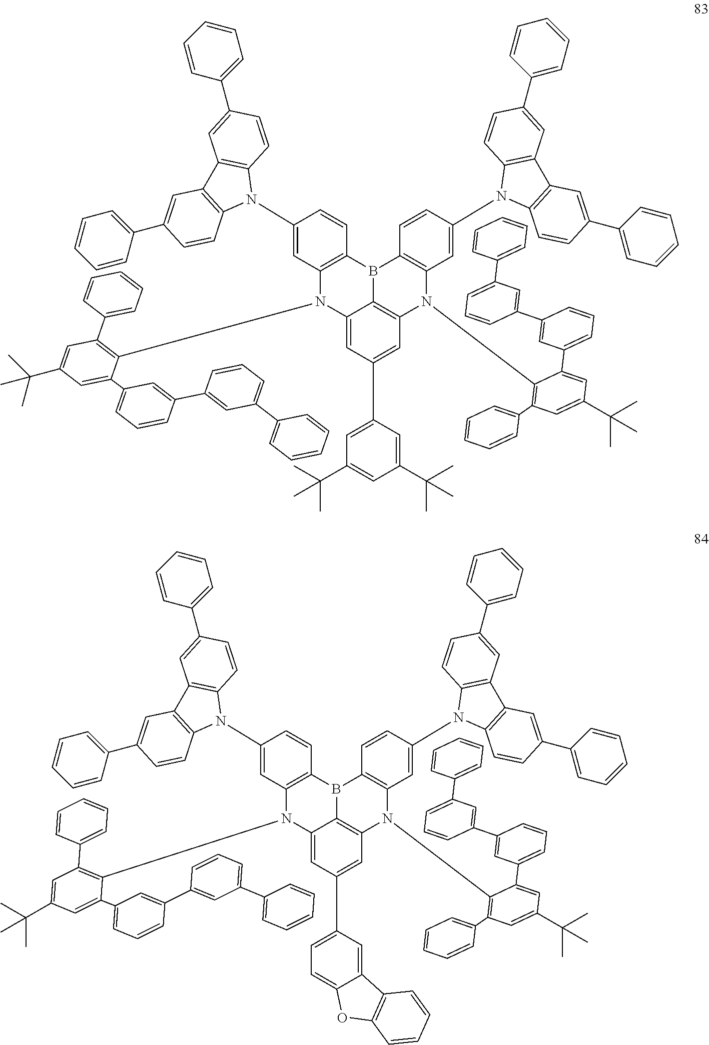

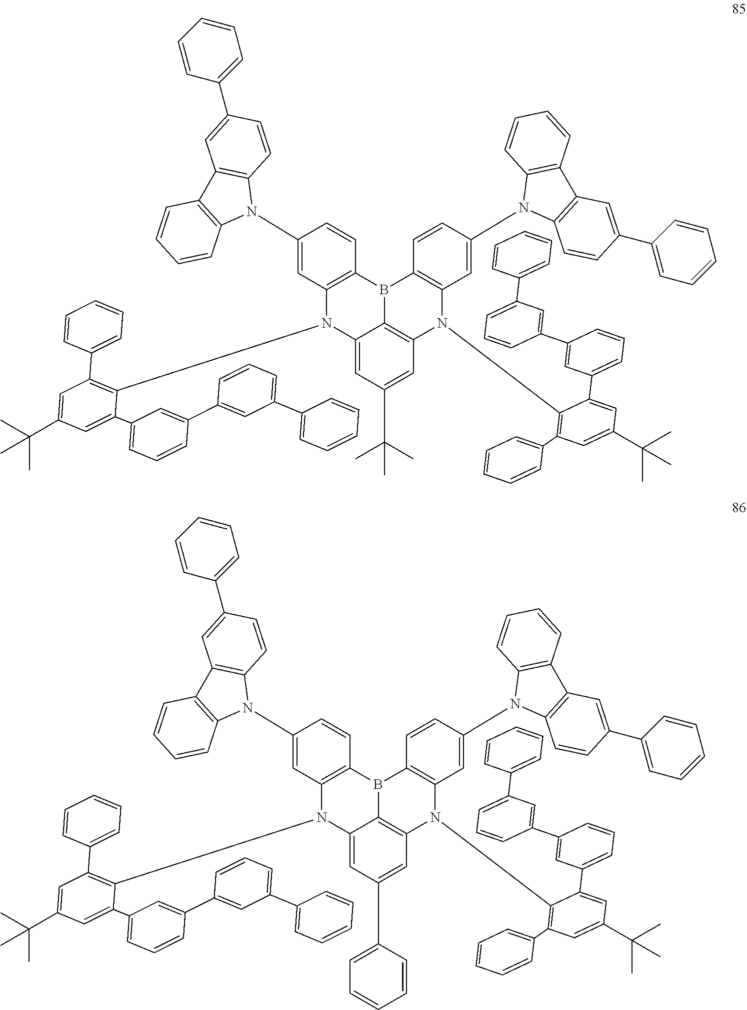 [SMILES: CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccccc5)cc(C(C)(C)C)cc4-c4cccc(-c5cccc(-c6ccccc6)c5)c4)c4cc(C(C)(C)C)cc2c43)c(-c2cccc(-c3cccc(-c4ccccc4)c3)c2)c1 ; CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccccc5)cc(C(C)(C)C)cc4-c4cccc(-c5cccc(-c6ccccc6)c5)c4)c4cc(-c5ccccc5)cc2c43)c(-c2cccc(-c3cccc(-c4ccccc4)c3)c2)c1]

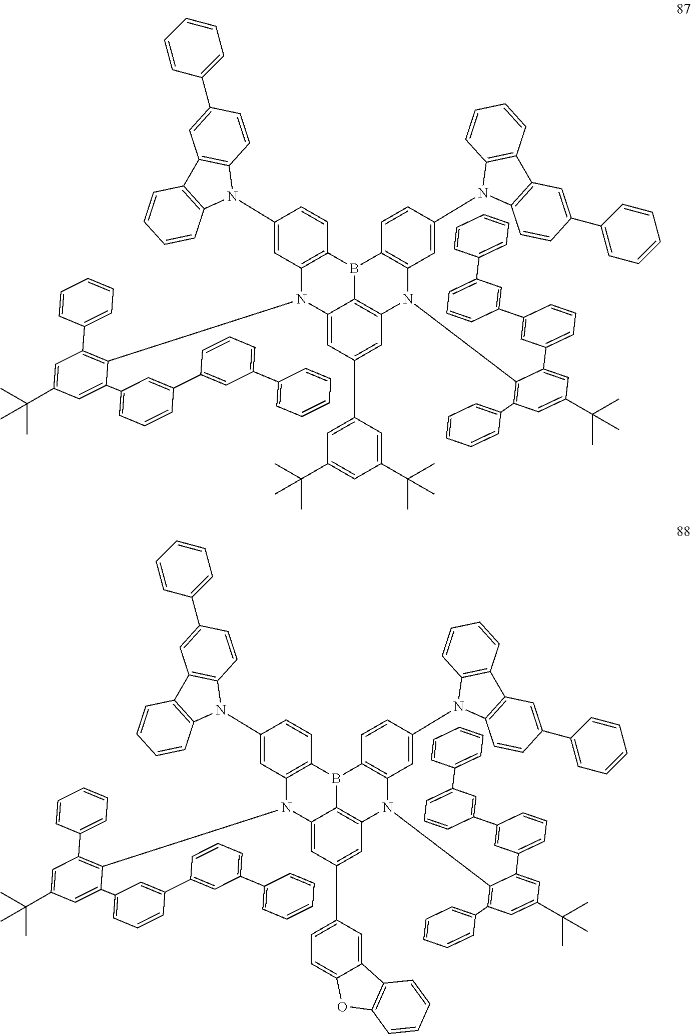 [SMILES: CC(C)(C)c1cc(-c2cc3c4c(c2)N(c2c(-c5ccccc5)cc(C(C)(C)C)cc2-c2cccc(-c5cccc(-c6ccccc6)c5)c2)c2cc(-n5c6ccccc6c6cc(-c7ccccc7)ccc65)ccc2B4c2ccc(-n4c5ccccc5c5cc(-c6ccccc6)ccc54)cc2N3c2c(-c3ccccc3)cc(C(C)(C)C)cc2-c2cccc(-c3cccc(-c4ccccc4)c3)c2)cc(C(C)(C)C)c1 ; CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccccc5)cc(C(C)(C)C)cc4-c4cccc(-c5cccc(-c6ccccc6)c5)c4)c4cc(-c5ccc6oc7ccccc7c6c5)cc2c43)c(-c2cccc(-c3cccc(-c4ccccc4)c3)c2)c1]

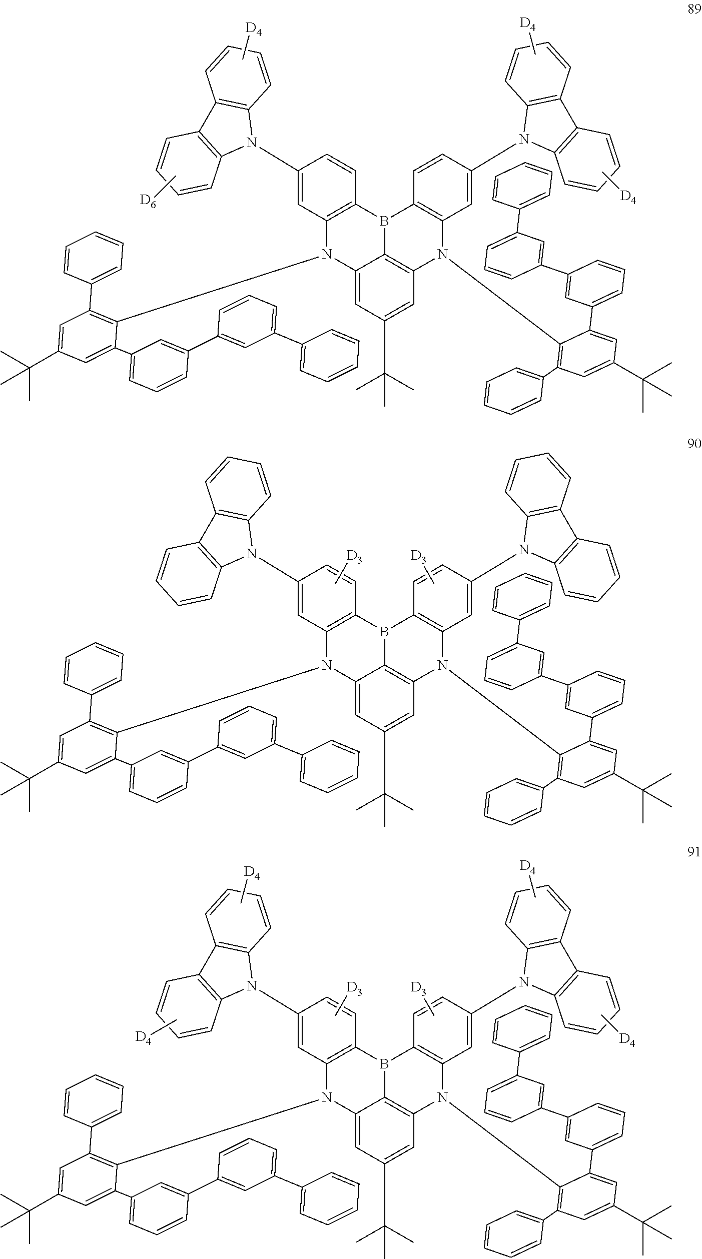

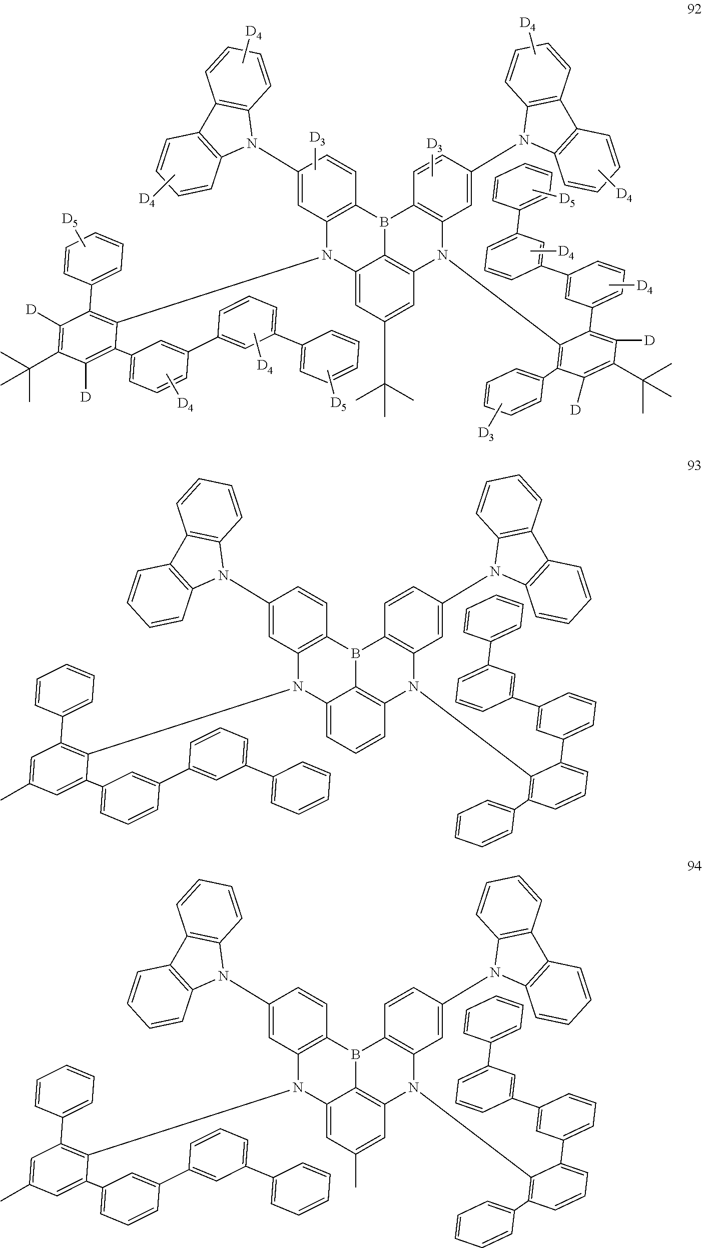

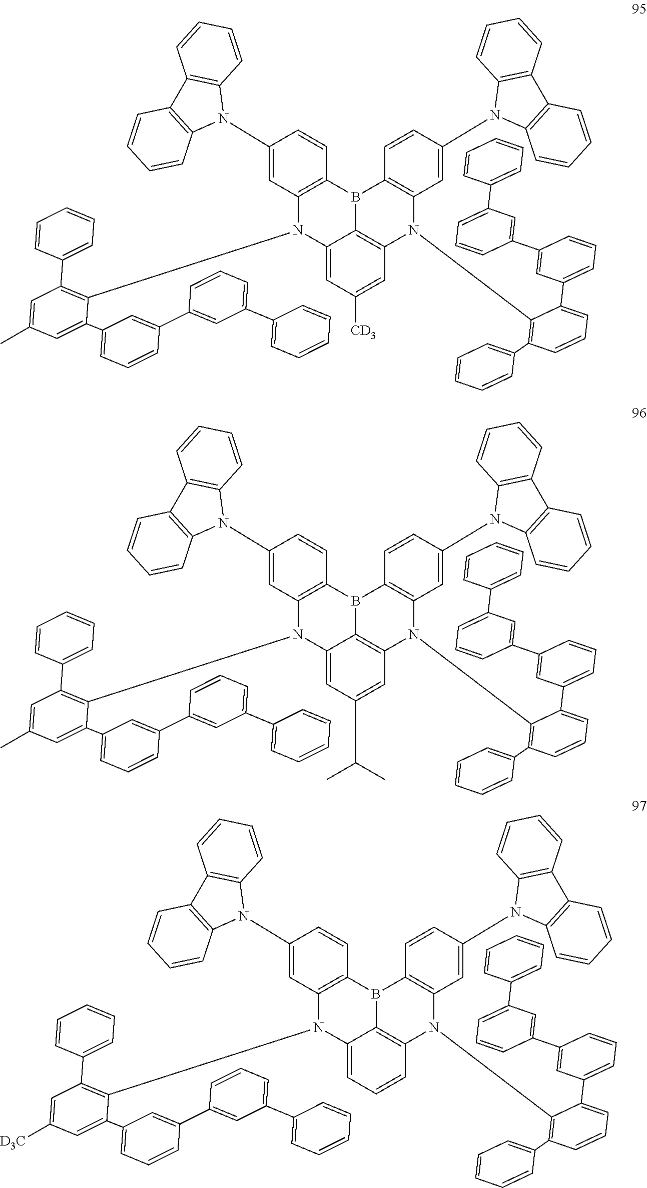

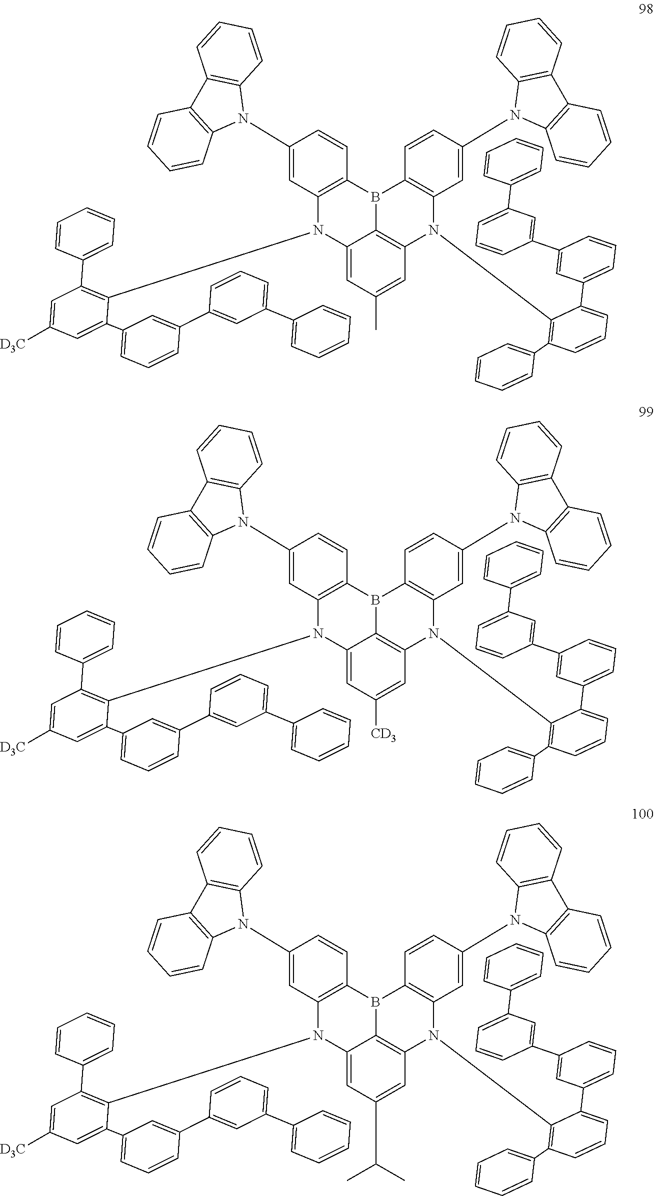

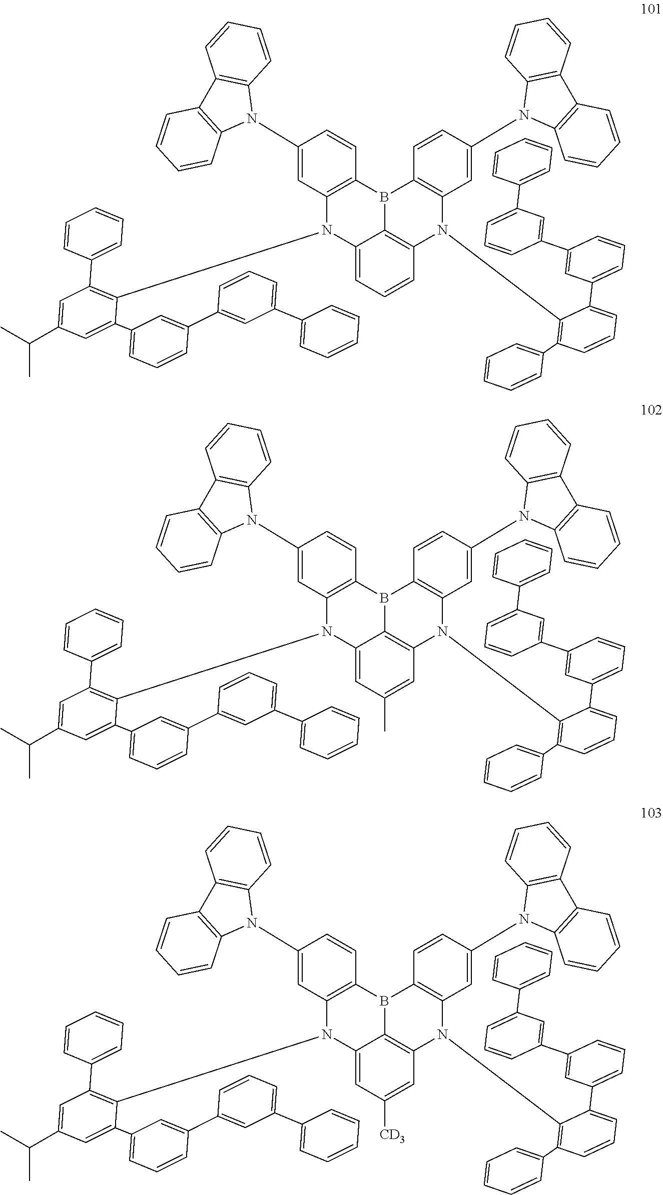

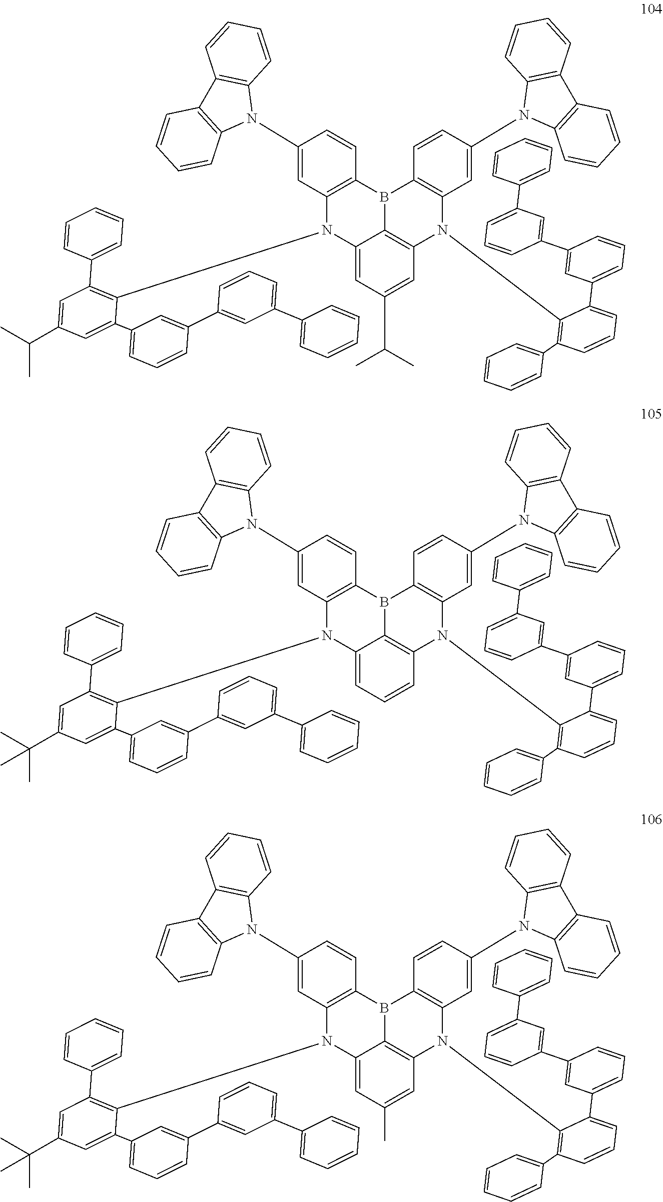

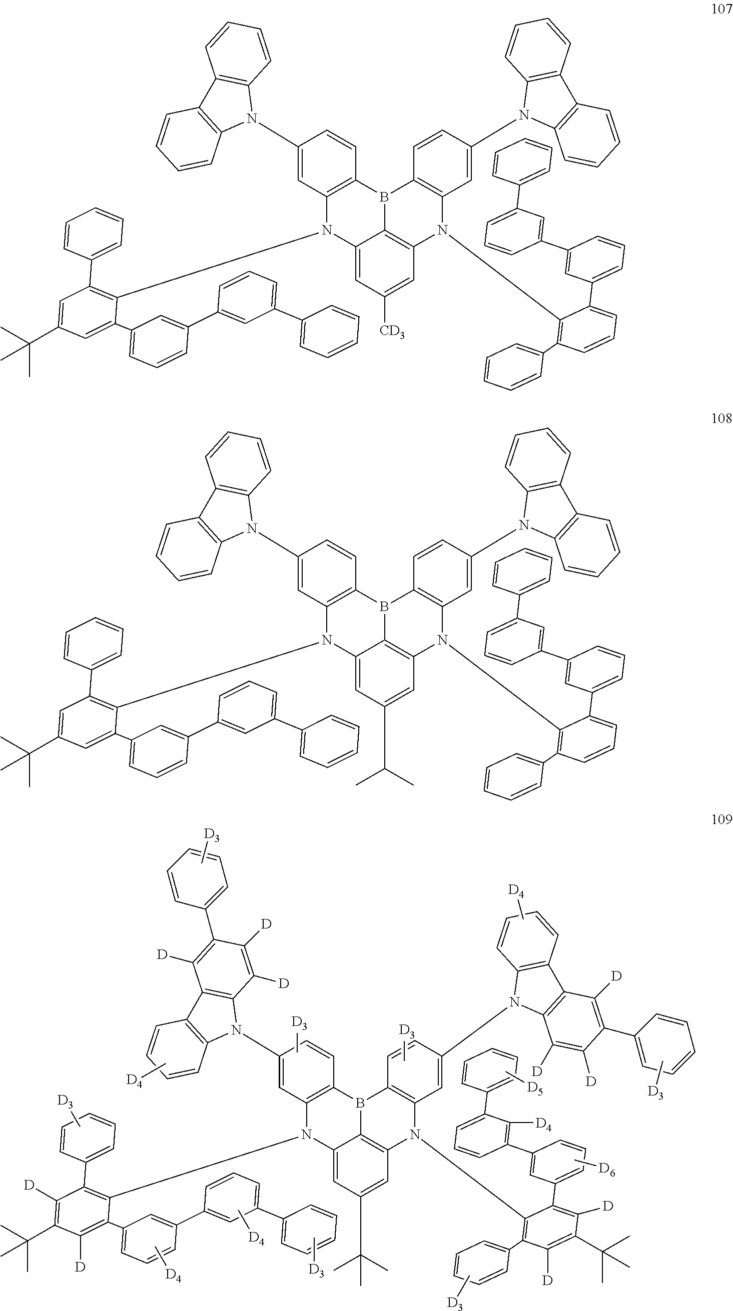

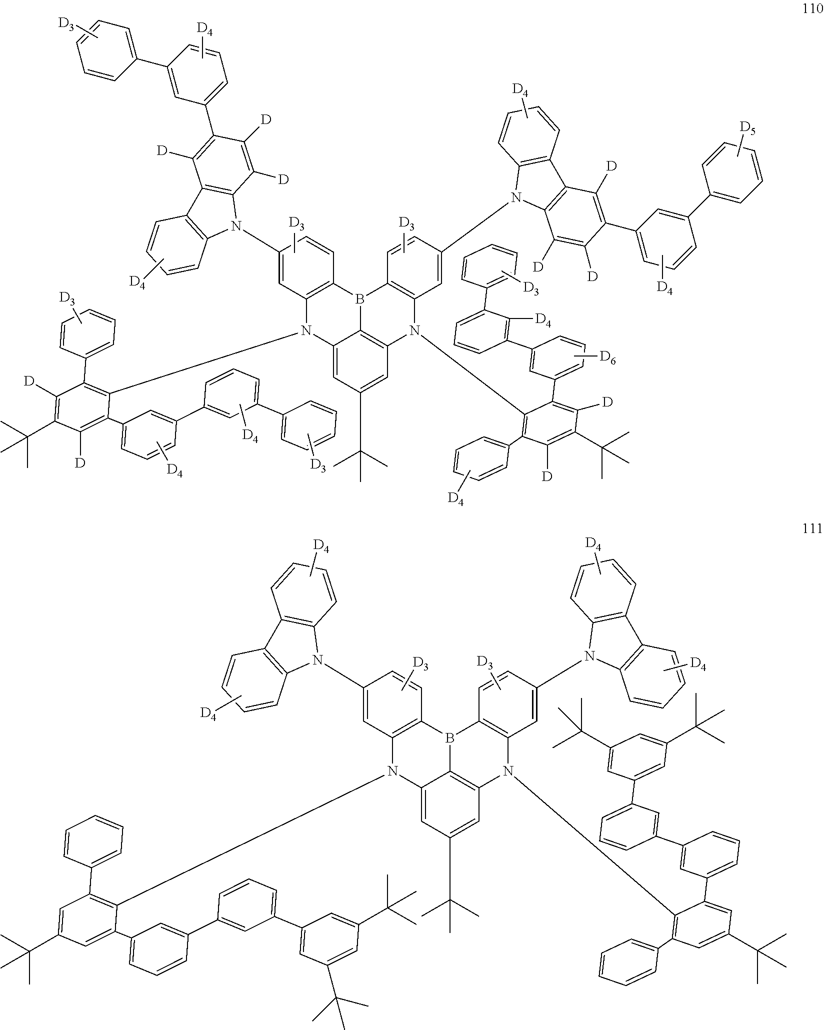

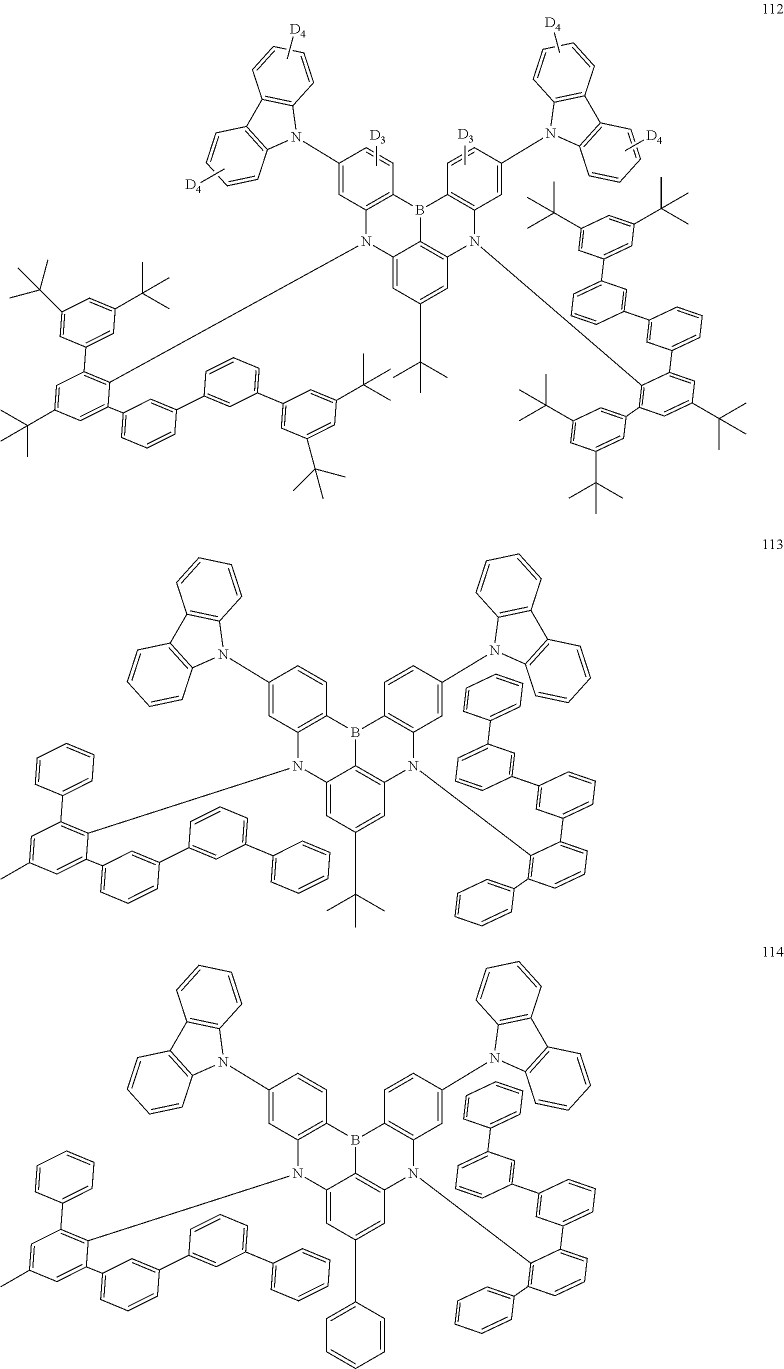

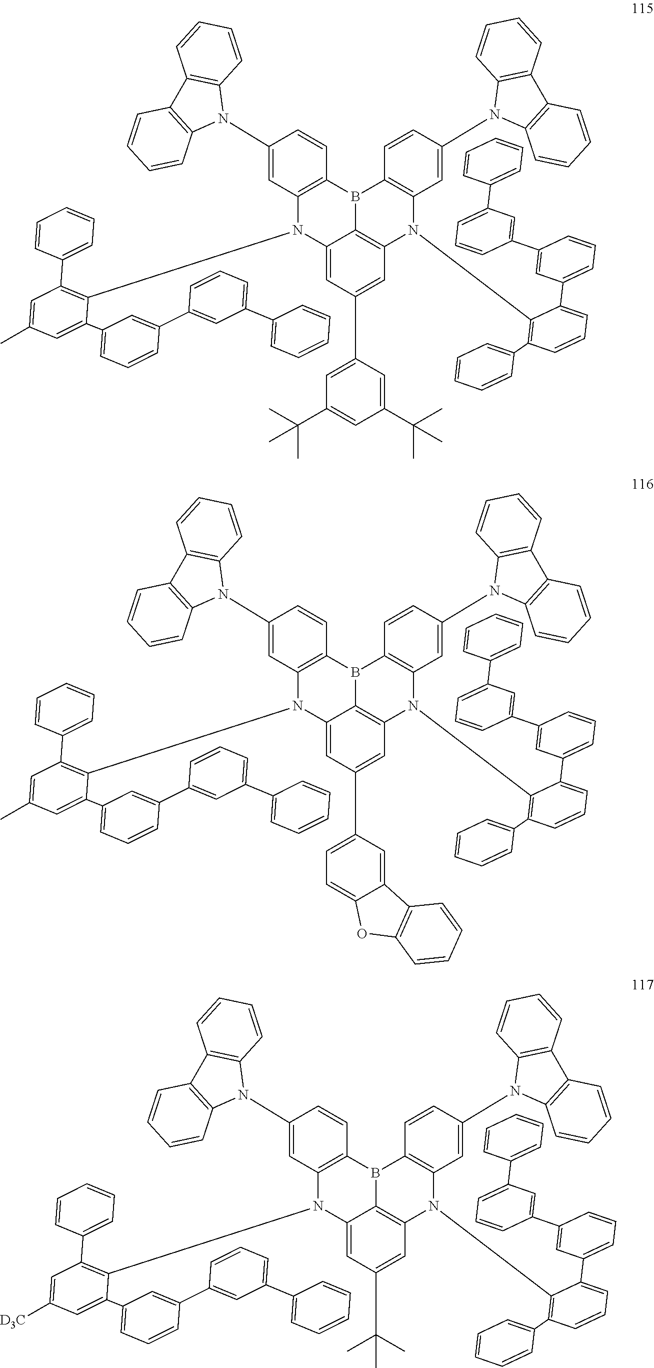

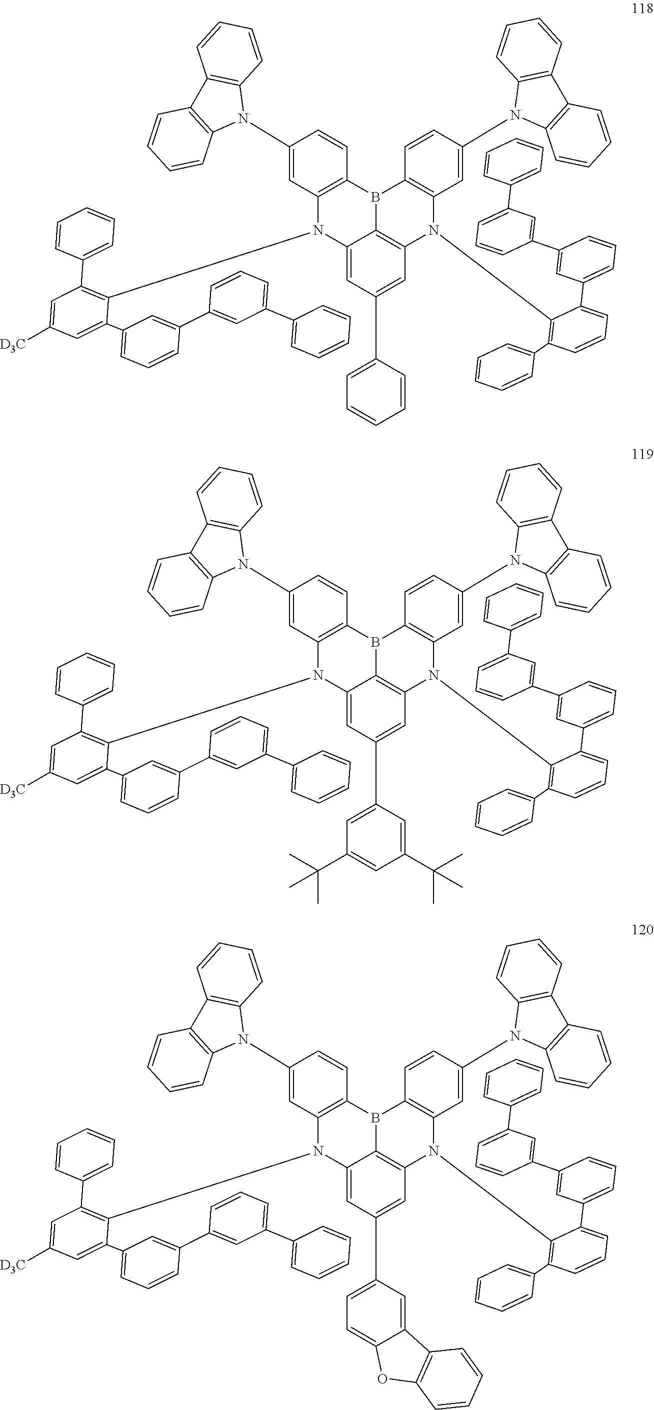

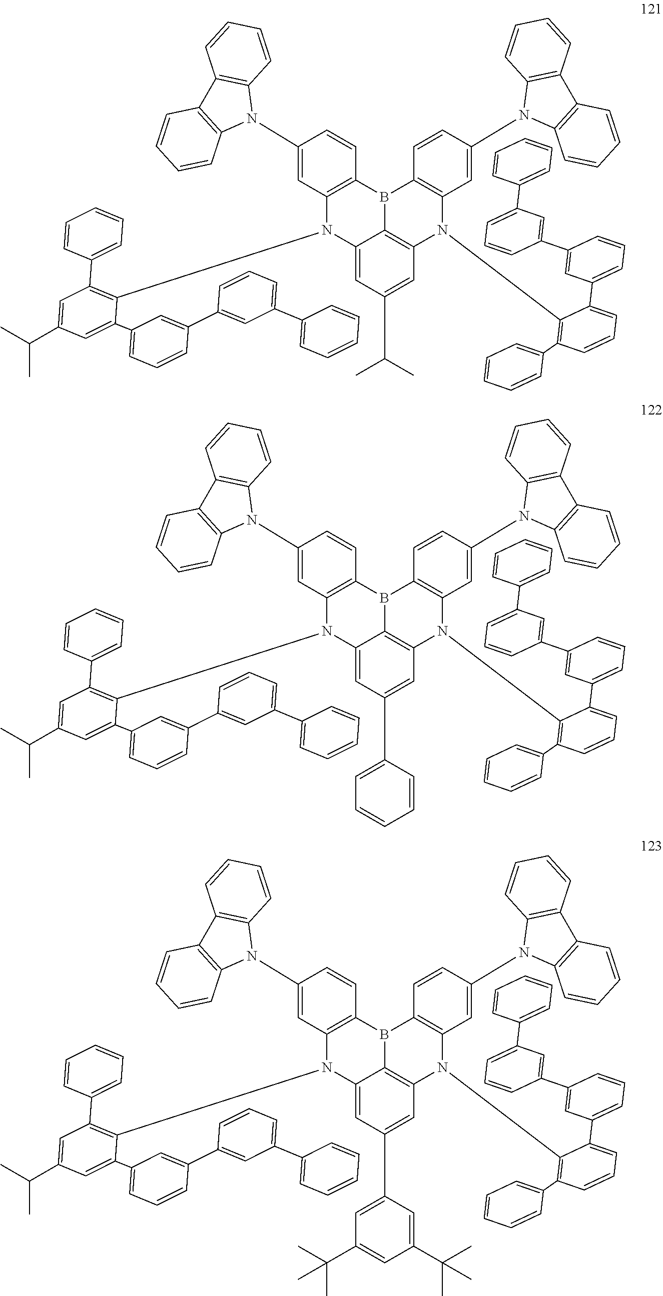

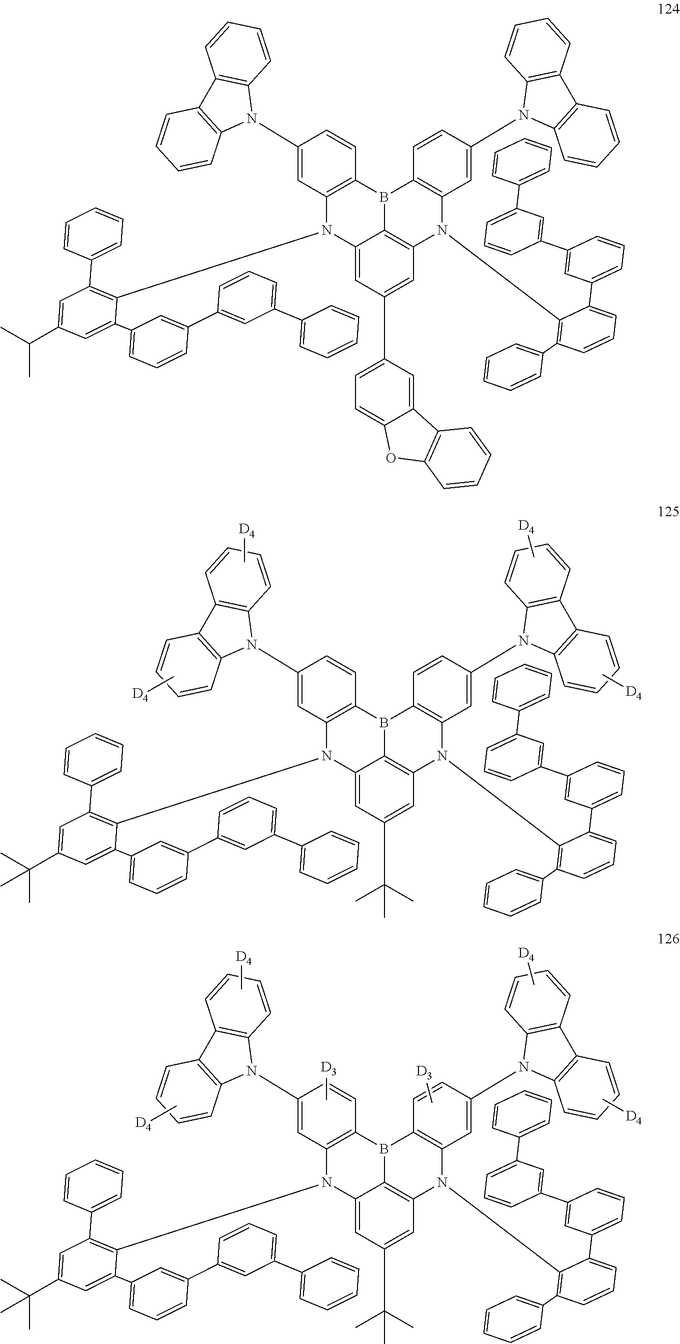

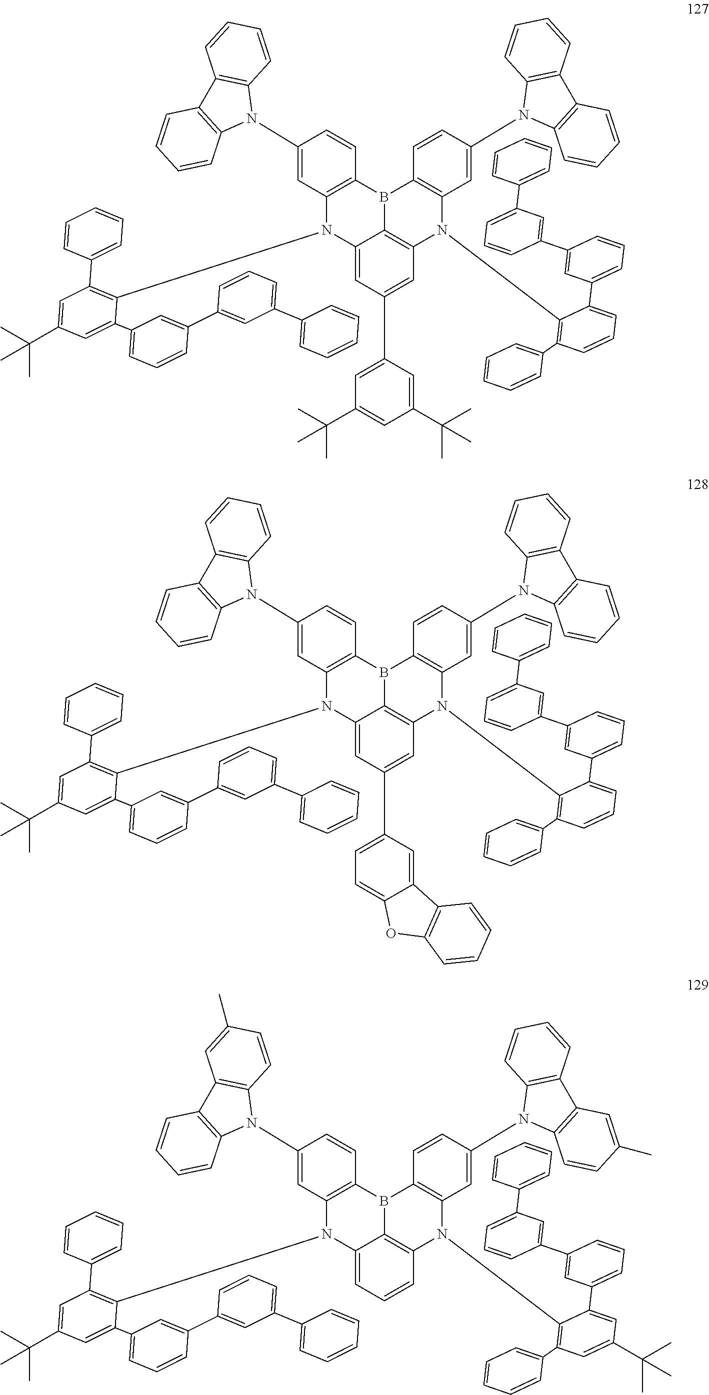

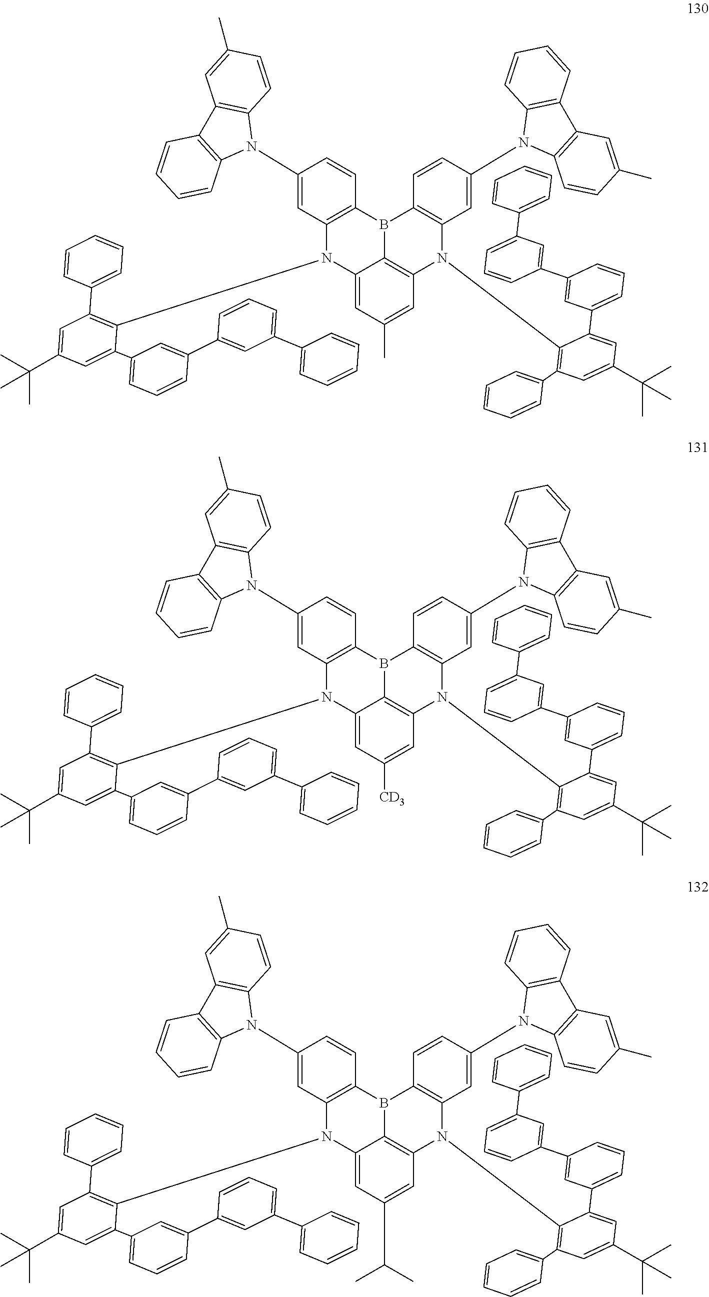

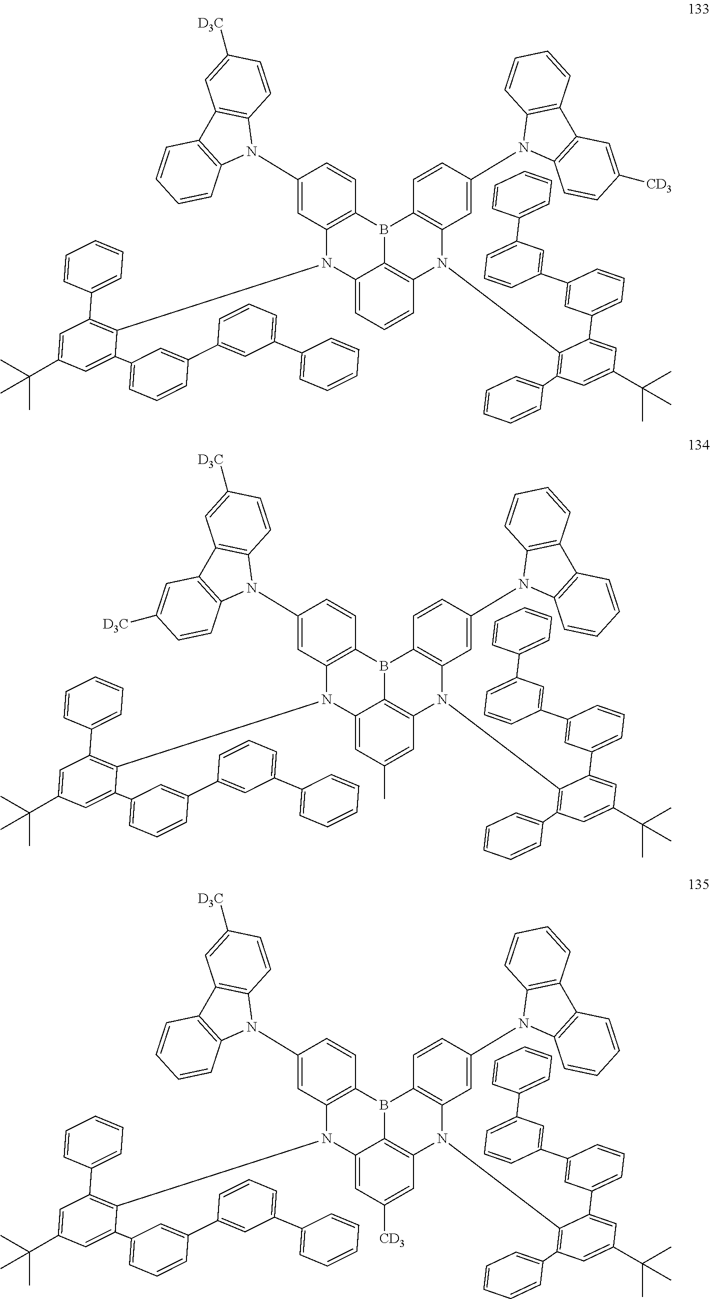

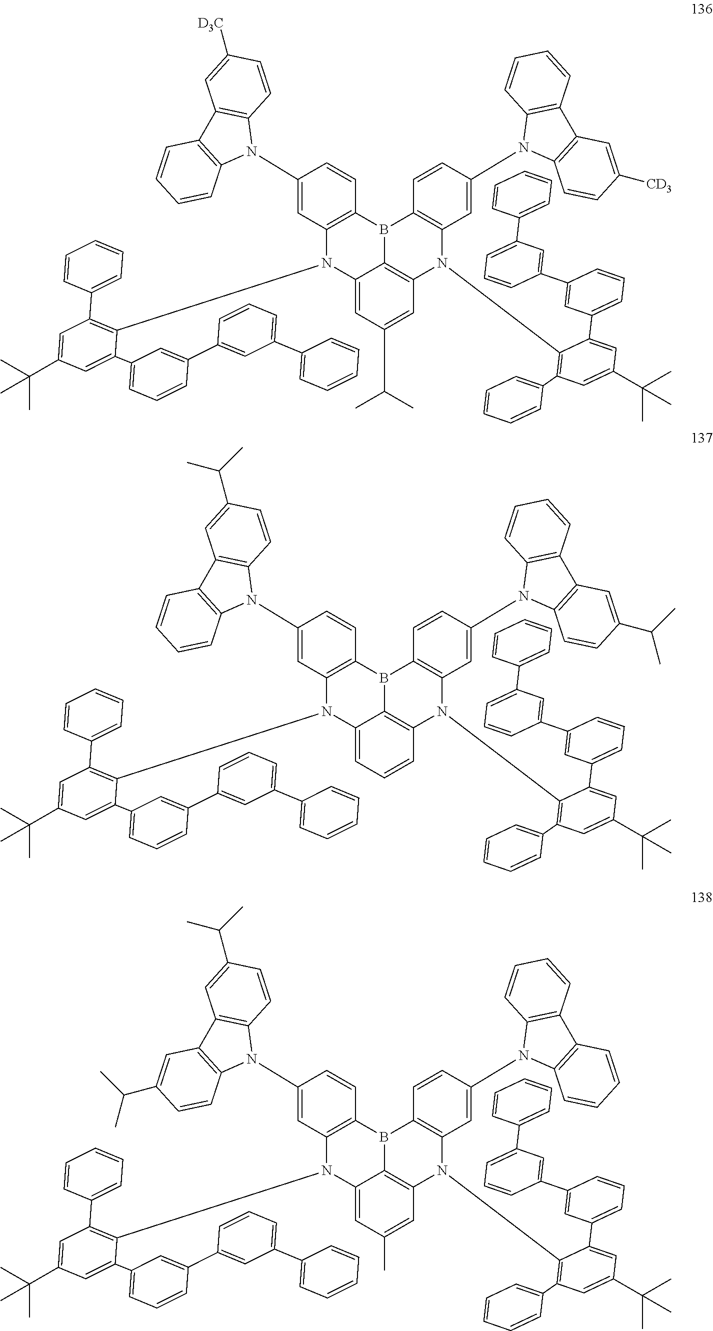

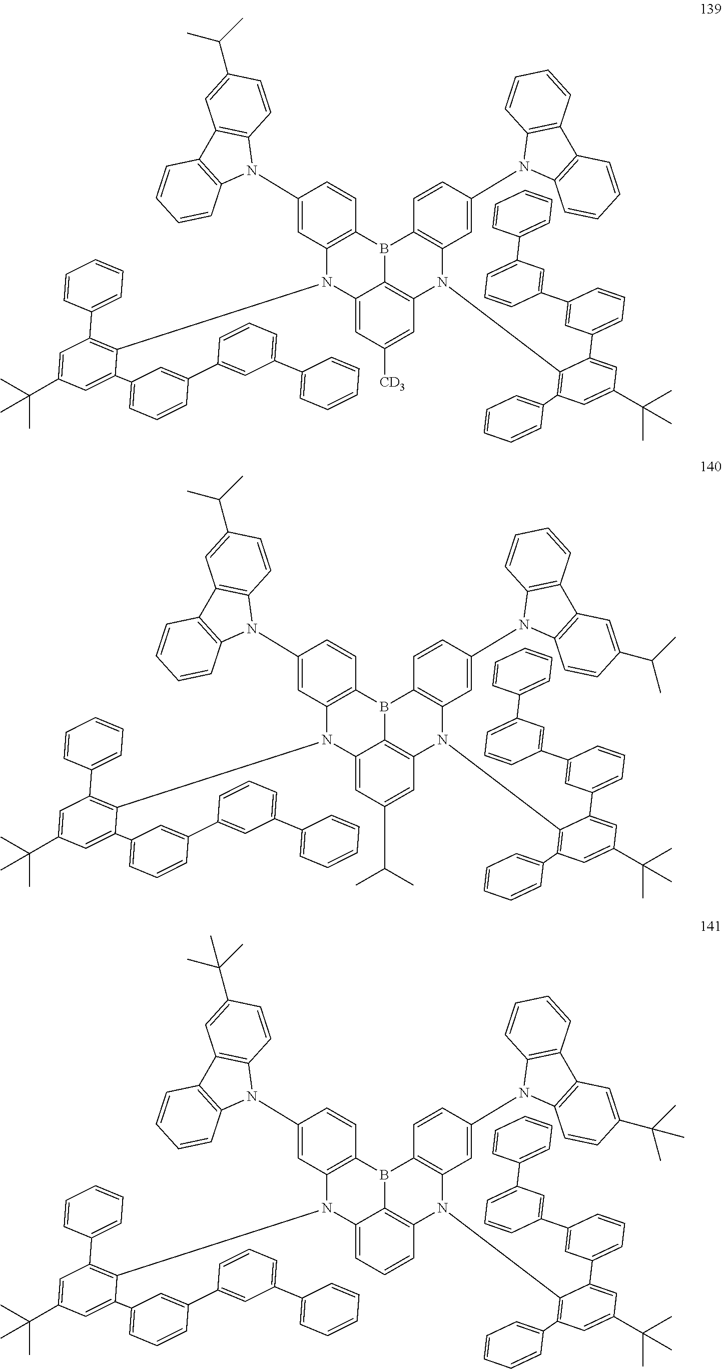

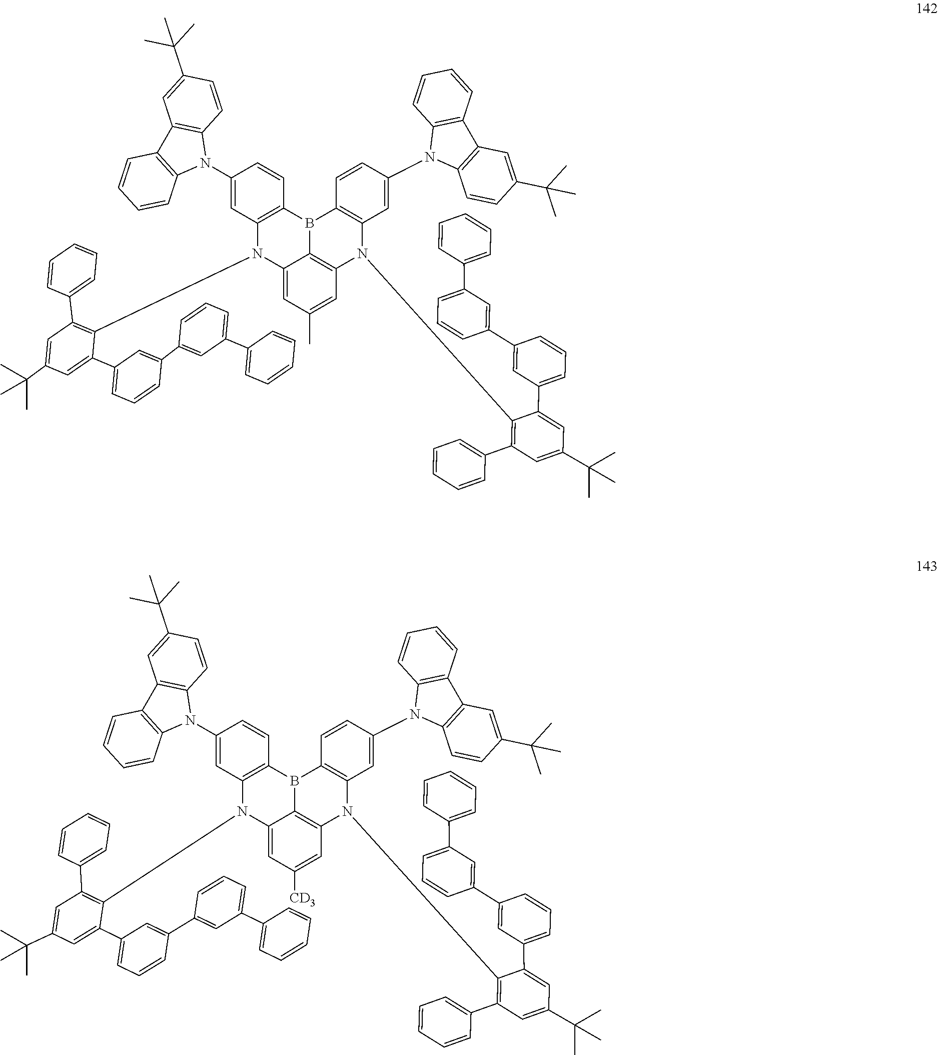

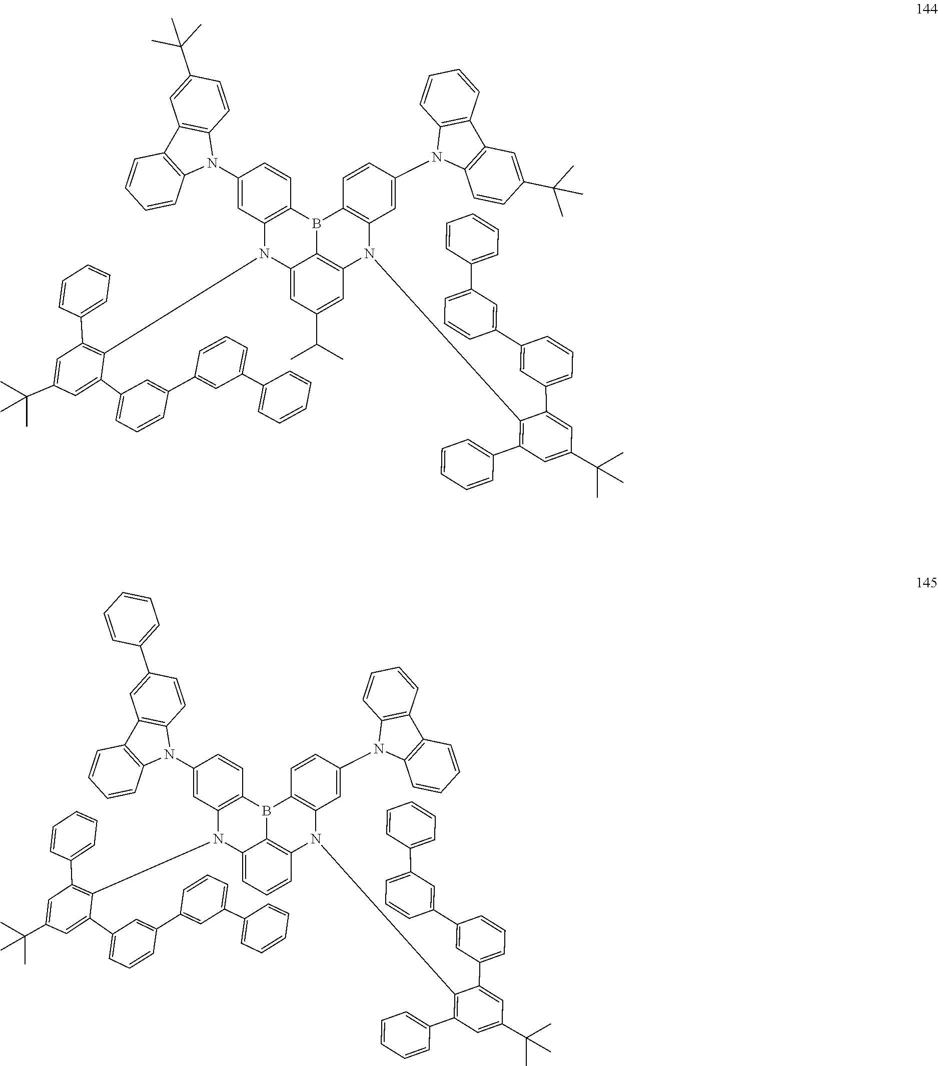

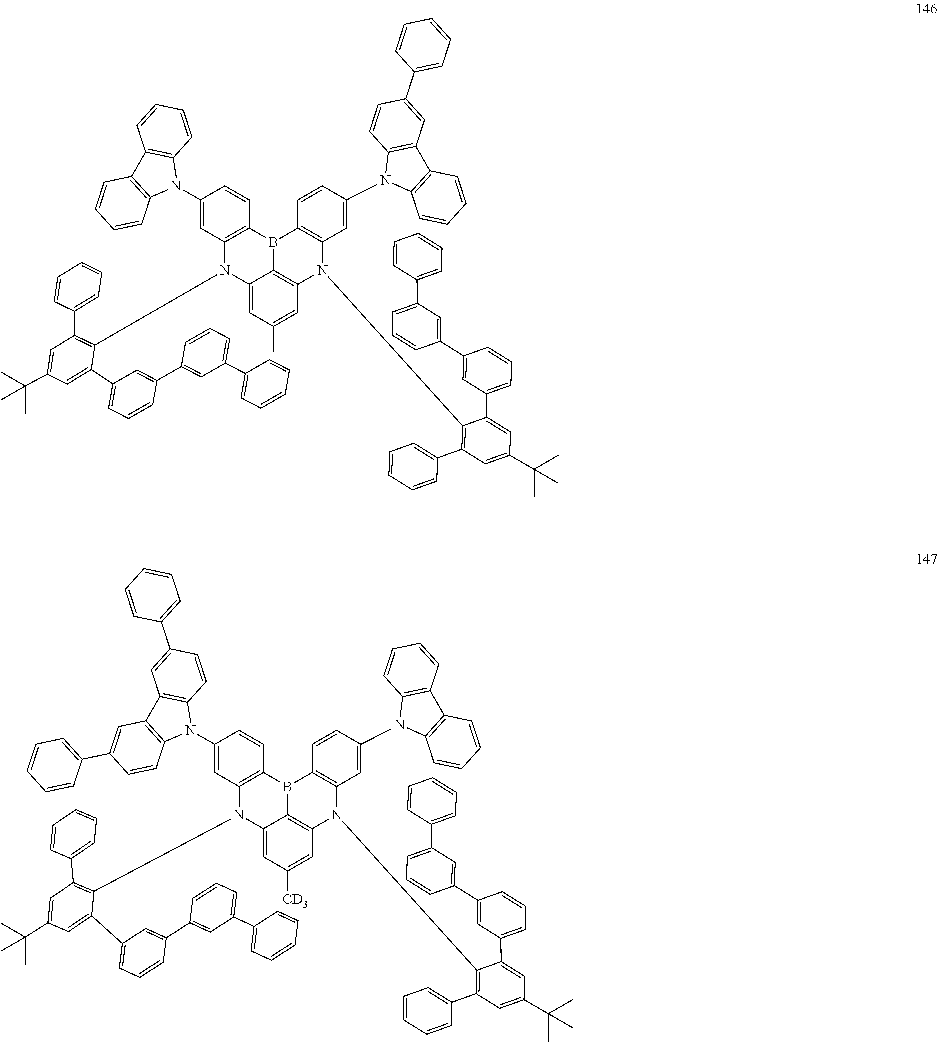

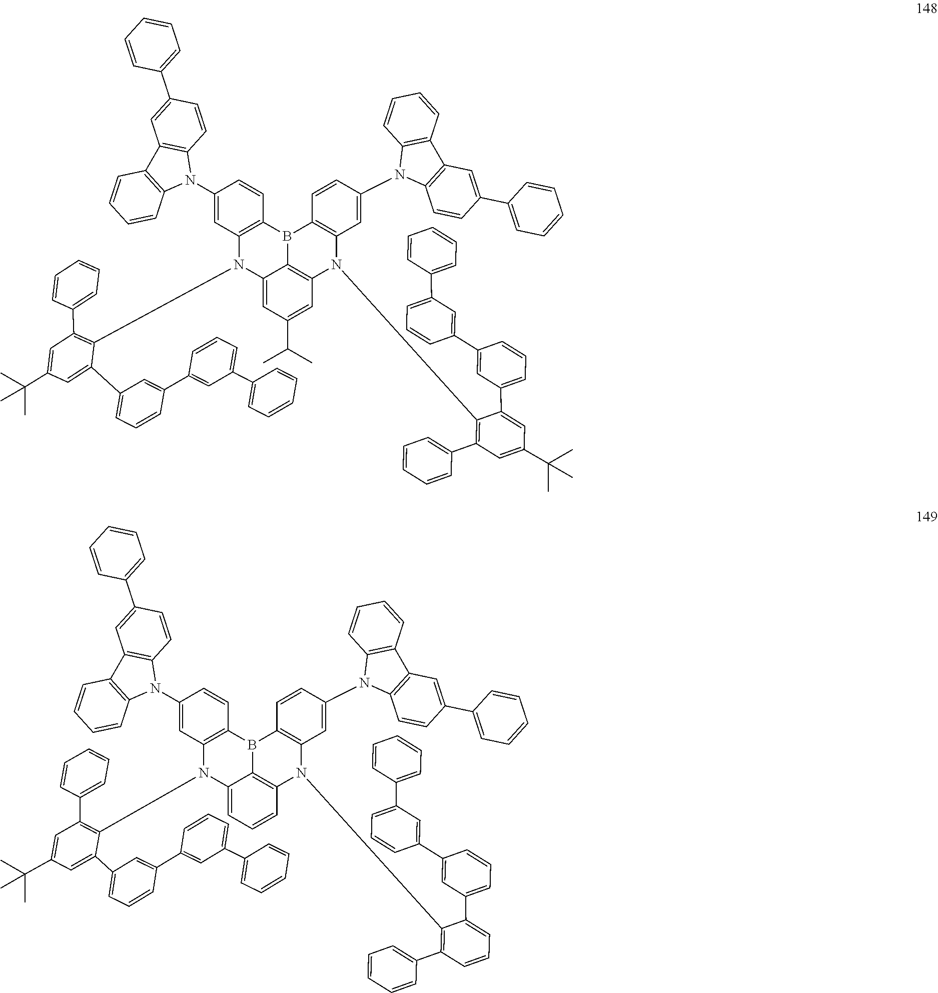

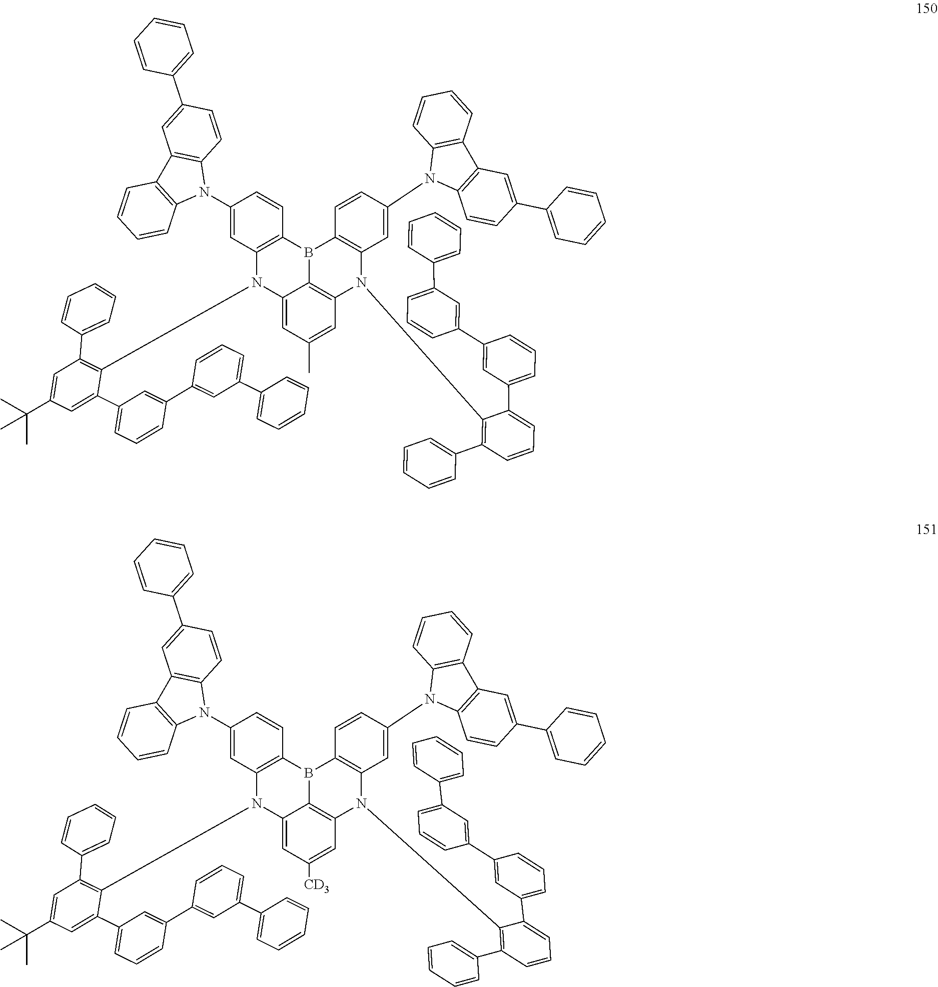 [SMILES: Cc1cc2c3c(c1)N(c1c(-c4ccccc4)cc(C(C)(C)C)cc1-c1cccc(-c4cccc(-c5ccccc5)c4)c1)c1cc(-n4c5ccccc5c5cc(-c6ccccc6)ccc54)ccc1B3c1ccc(-n3c4ccccc4c4cc(-c5ccccc5)ccc43)cc1N2c1c(-c2ccccc2)cccc1-c1cccc(-c2cccc(-c3ccccc3)c2)c1 ; [2H]C([2H])([2H])c1cc2c3c(c1)N(c1c(-c4ccccc4)cc(C(C)(C)C)cc1-c1cccc(-c4cccc(-c5ccccc5)c4)c1)c1cc(-n4c5ccccc5c5cc(-c6ccccc6)ccc54)ccc1B3c1ccc(-n3c4ccccc4c4cc(-c5ccccc5)ccc43)cc1N2c1c(-c2ccccc2)cccc1-c1cccc(-c2cccc(-c3ccccc3)c2)c1]

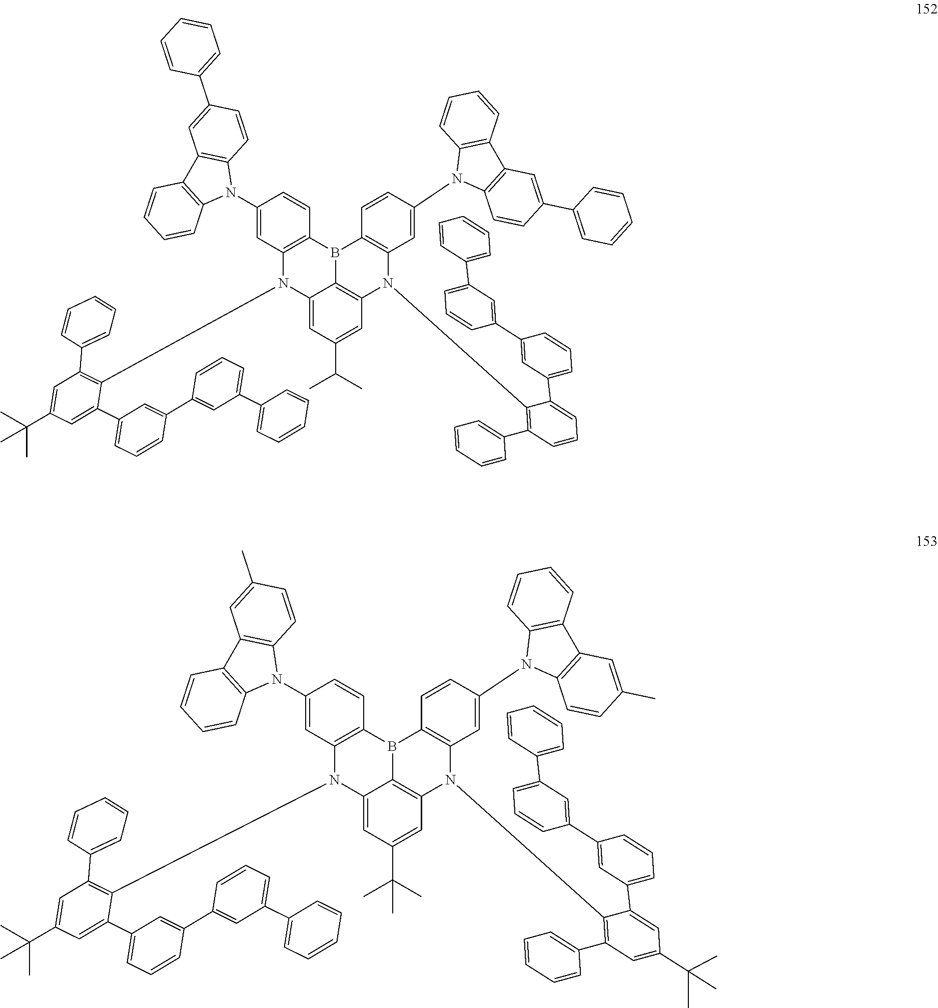 [SMILES: CC(C)c1cc2c3c(c1)N(c1c(-c4ccccc4)cc(C(C)(C)C)cc1-c1cccc(-c4cccc(-c5ccccc5)c4)c1)c1cc(-n4c5ccccc5c5cc(-c6ccccc6)ccc54)ccc1B3c1ccc(-n3c4ccccc4c4cc(-c5ccccc5)ccc43)cc1N2c1c(-c2ccccc2)cccc1-c1cccc(-c2cccc(-c3ccccc3)c2)c1 ; Cc1ccc2c(c1)c1ccccc1n2-c1ccc2c(c1)N(c1c(-c3ccccc3)cc(C(C)(C)C)cc1-c1cccc(-c3cccc(-c4ccccc4)c3)c1)c1cc(C(C)(C)C)cc3c1B2c1ccc(-n2c4ccccc4c4cc(C)ccc42)cc1N3c1c(-c2ccccc2)cc(C(C)(C)C)cc1-c1cccc(-c2cccc(-c3ccccc3)c2)c1]

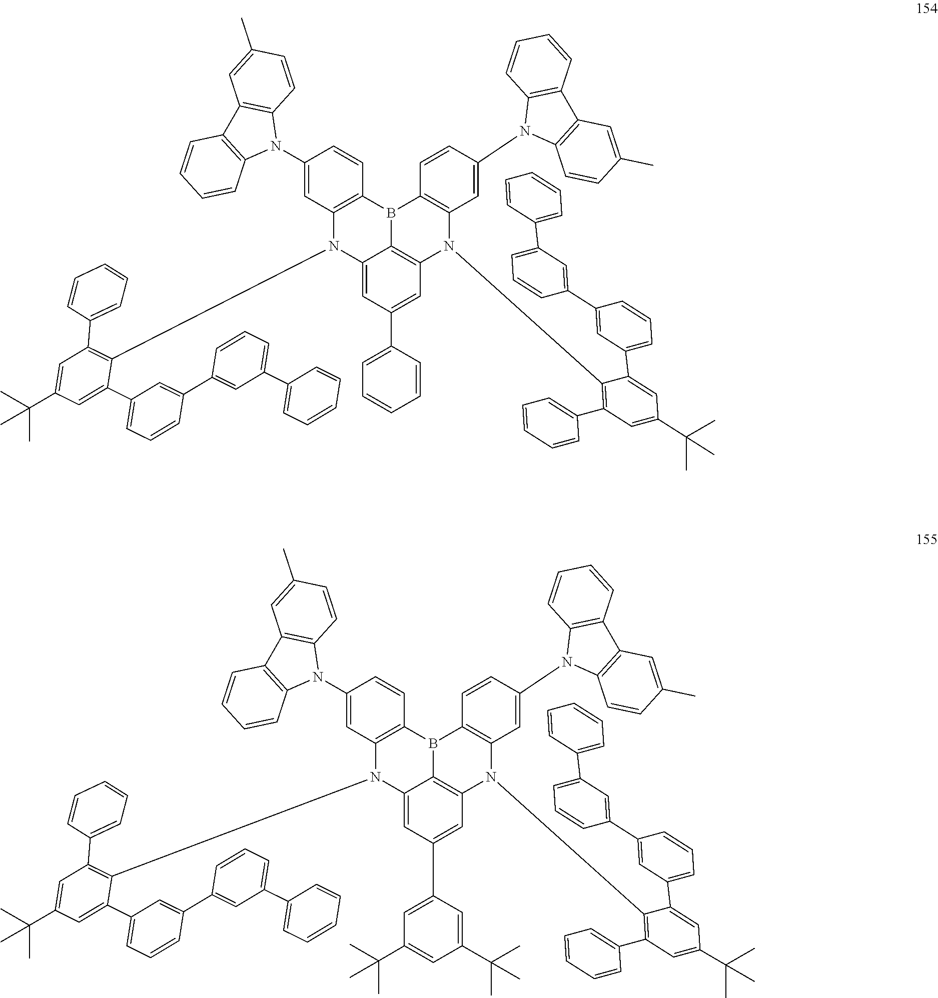

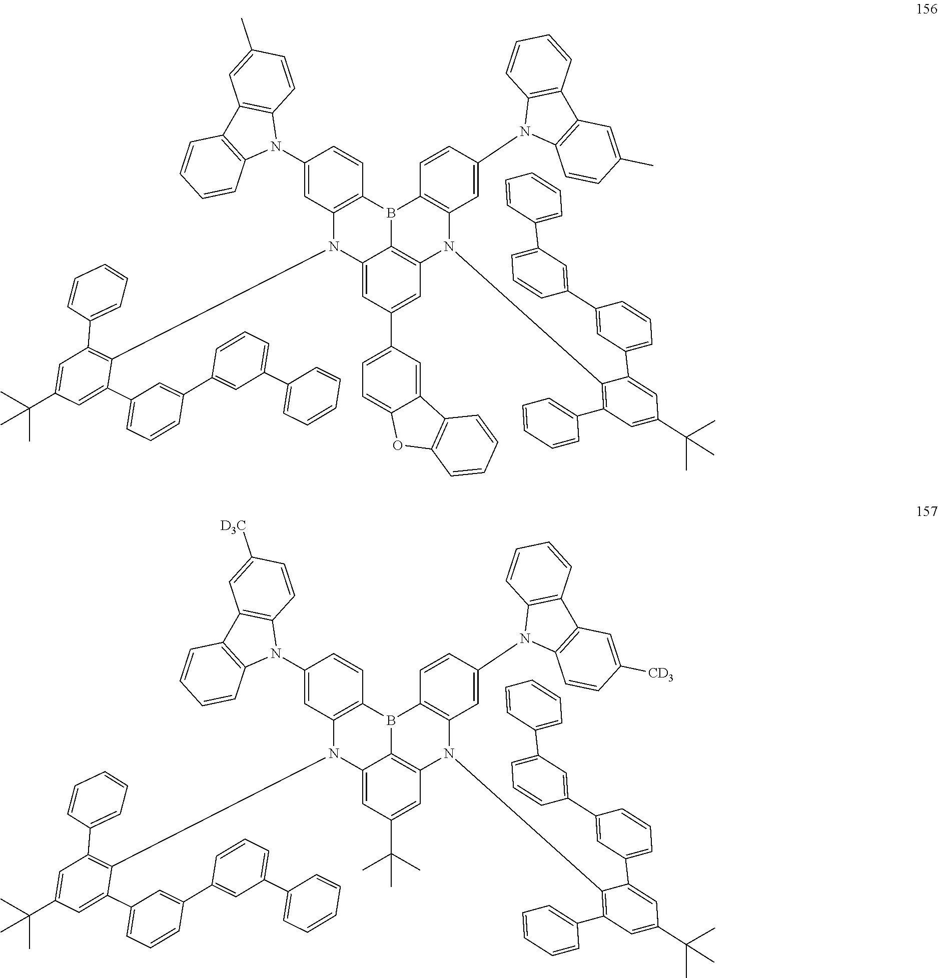

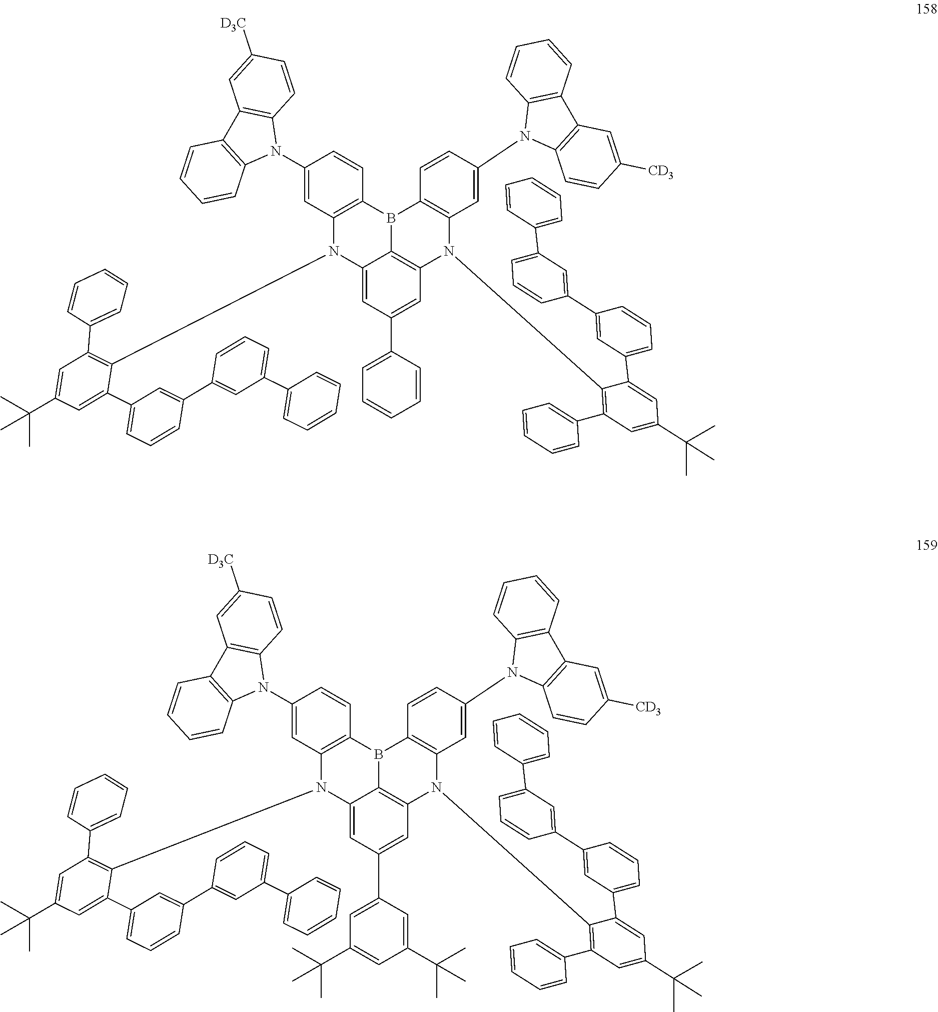

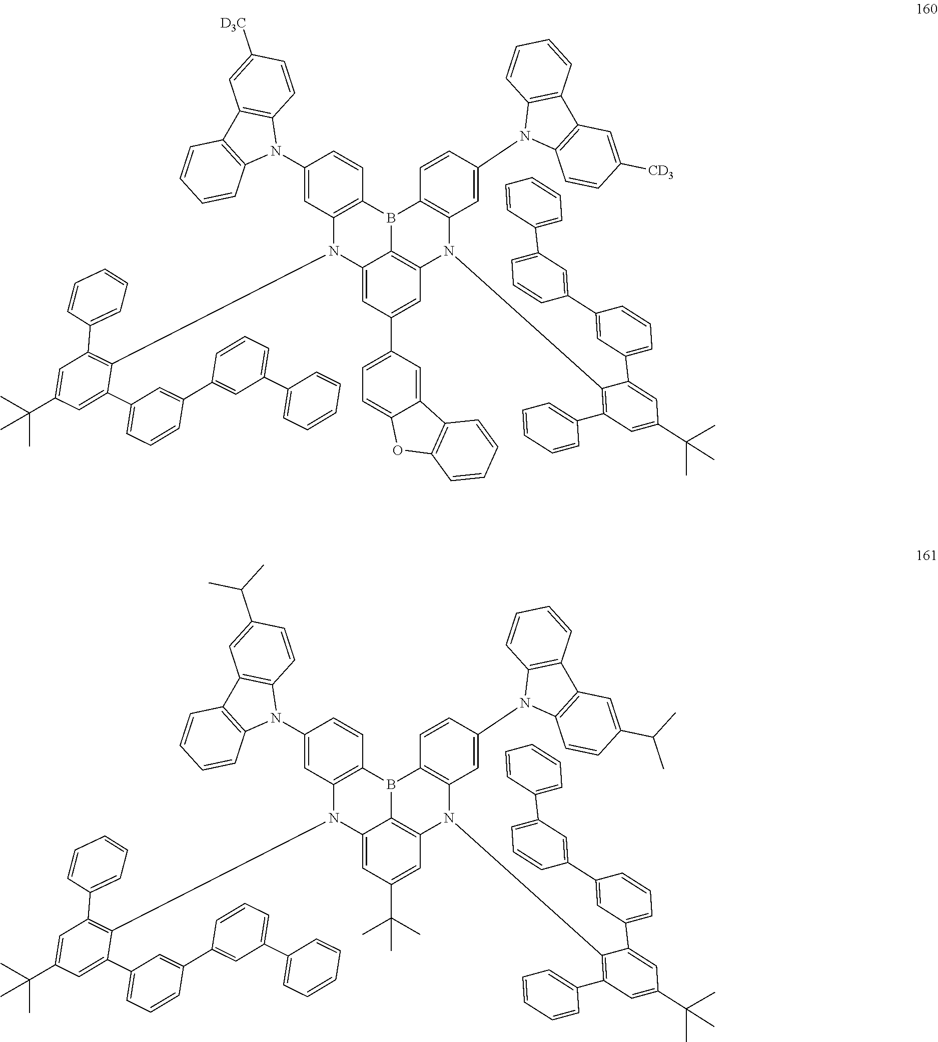

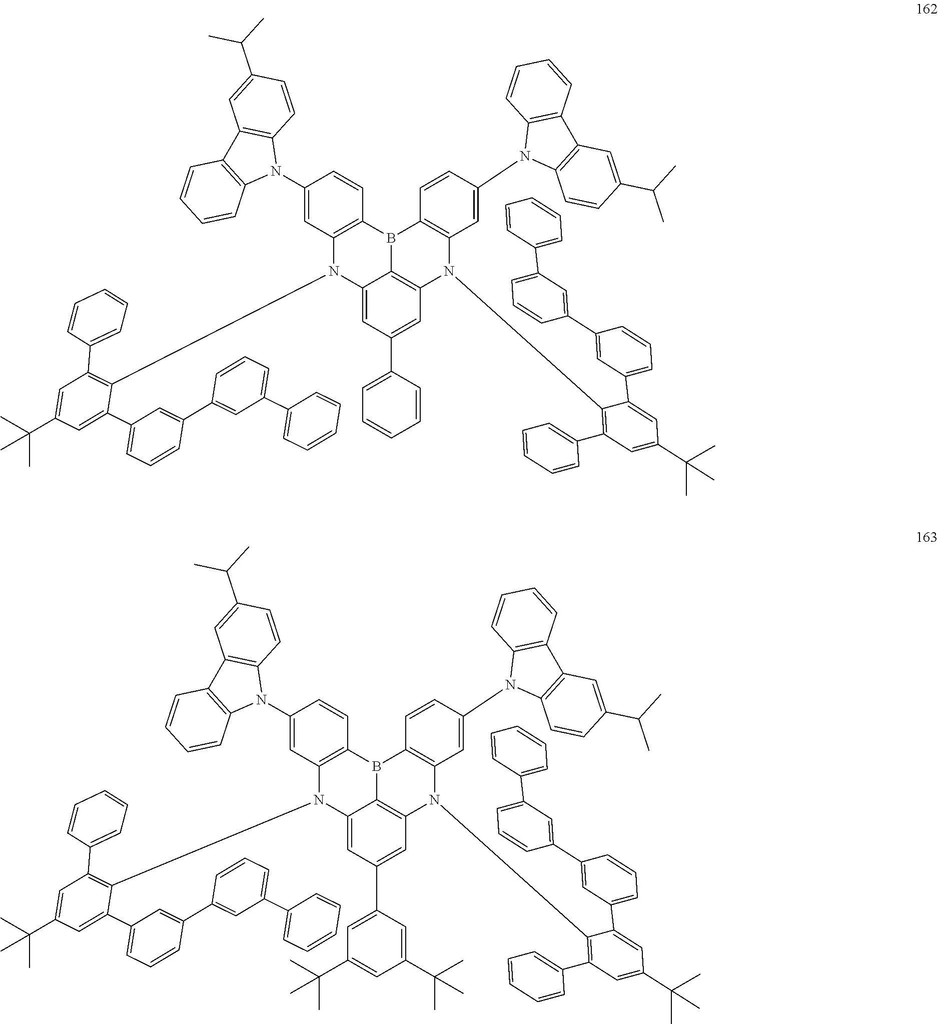

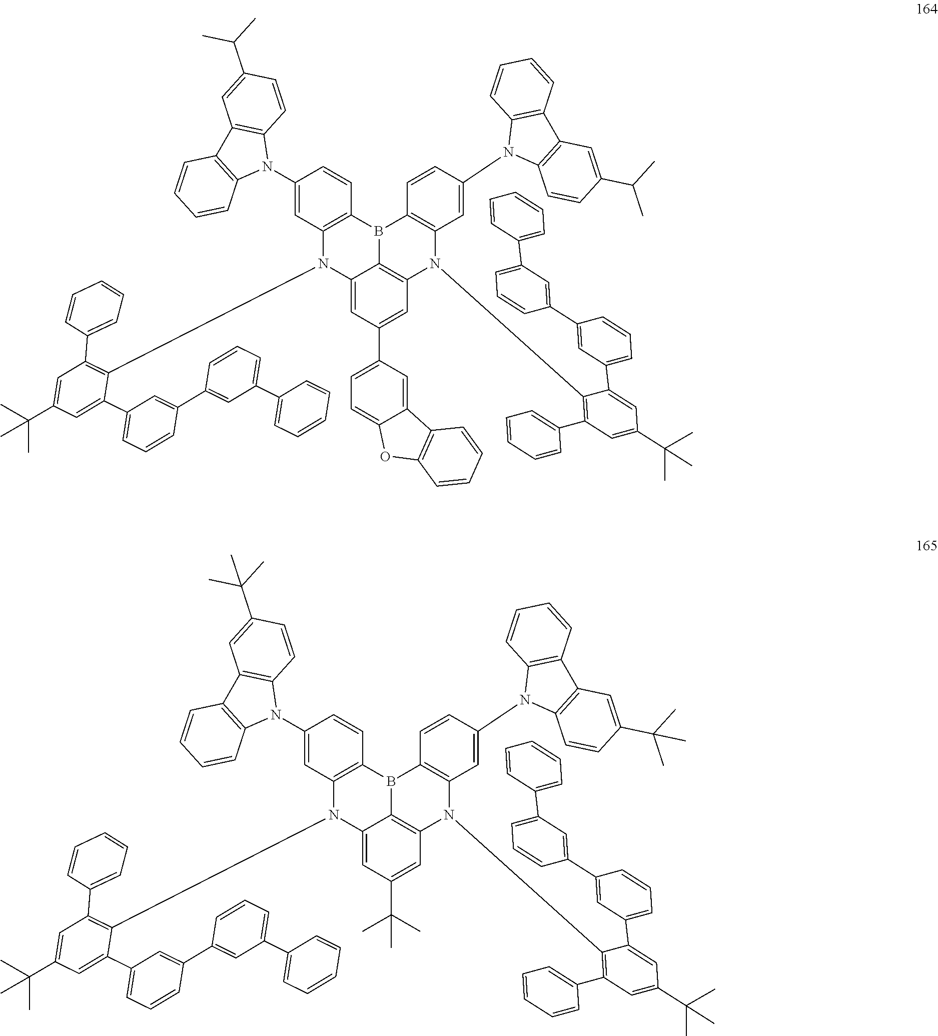

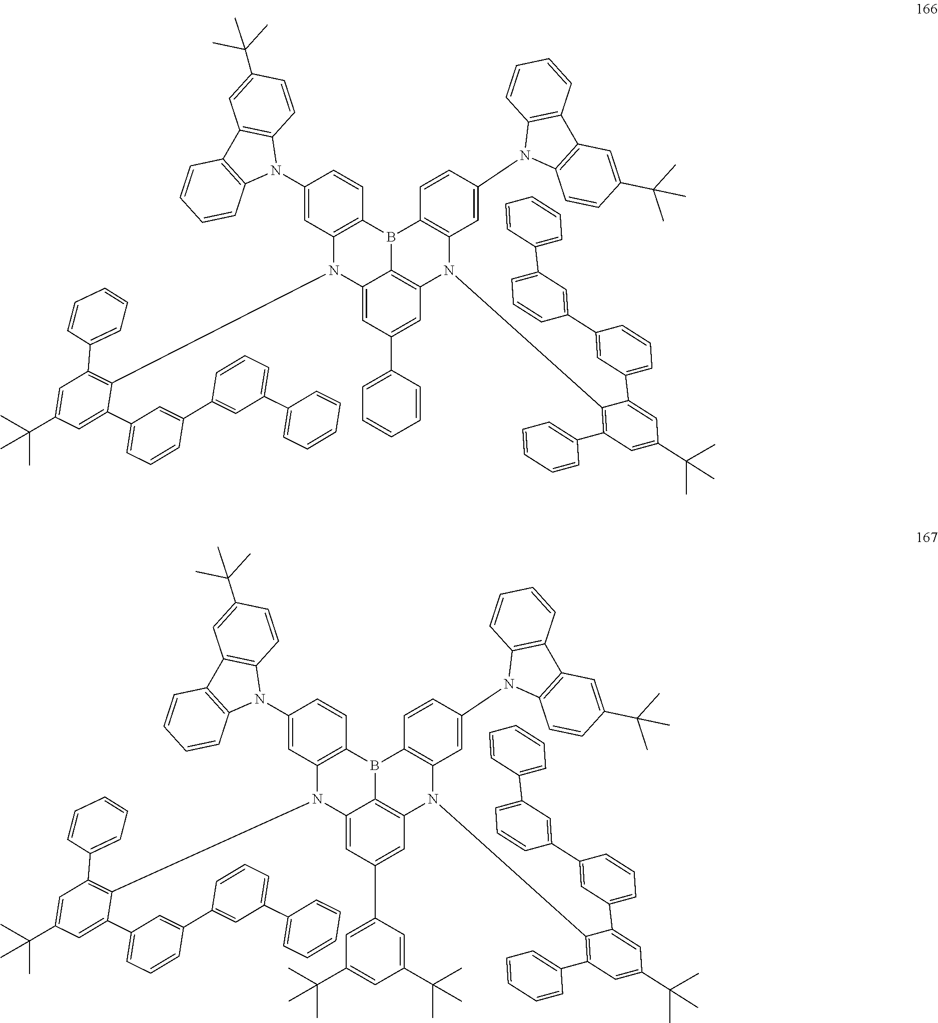

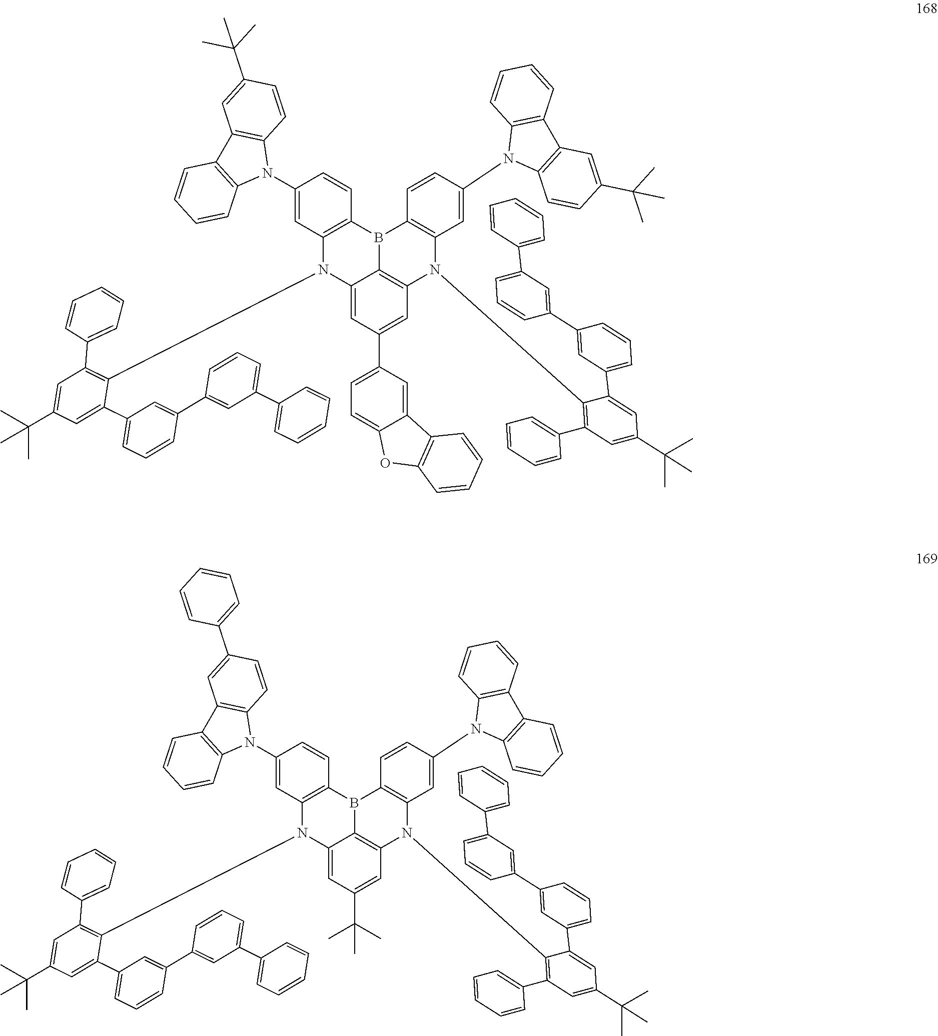

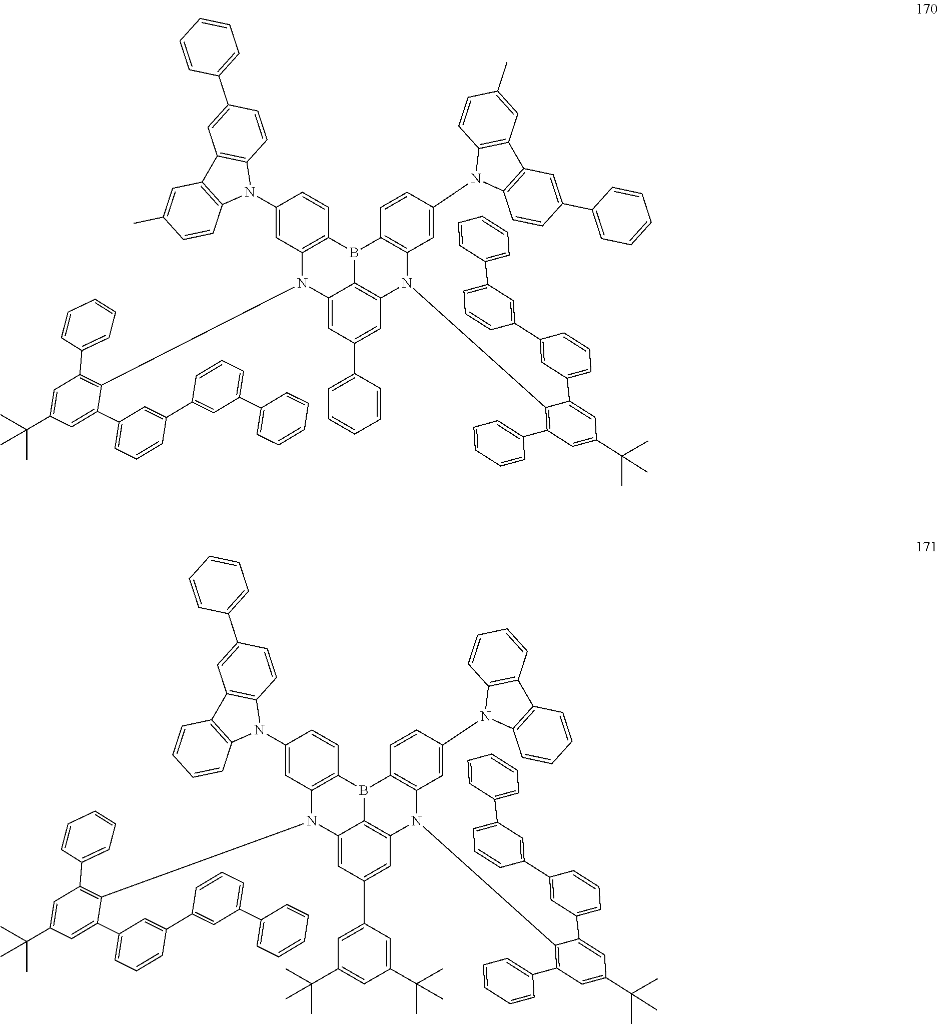 [SMILES: Cc1ccc2c(c1)c1cc(-c3ccccc3)ccc1n2-c1ccc2c(c1)N(c1c(-c3ccccc3)cc(C(C)(C)C)cc1-c1cccc(-c3cccc(-c4ccccc4)c3)c1)c1cc(-c3ccccc3)cc3c1B2c1ccc(-n2c4ccc(C)cc4c4cc(-c5ccccc5)ccc42)cc1N3c1c(-c2ccccc2)cc(C(C)(C)C)cc1-c1cccc(-c2cccc(-c3ccccc3)c2)c1 ; CC(C)(C)c1cc(-c2cc3c4c(c2)N(c2c(-c5ccccc5)cc(C(C)(C)C)cc2-c2cccc(-c5cccc(-c6ccccc6)c5)c2)c2cc(-n5c6ccccc6c6cc(-c7ccccc7)ccc65)ccc2B4c2ccc(-n4c5ccccc5c5ccccc54)cc2N3c2c(-c3ccccc3)cc(C(C)(C)C)cc2-c2cccc(-c3cccc(-c4ccccc4)c3)c2)cc(C(C)(C)C)c1]

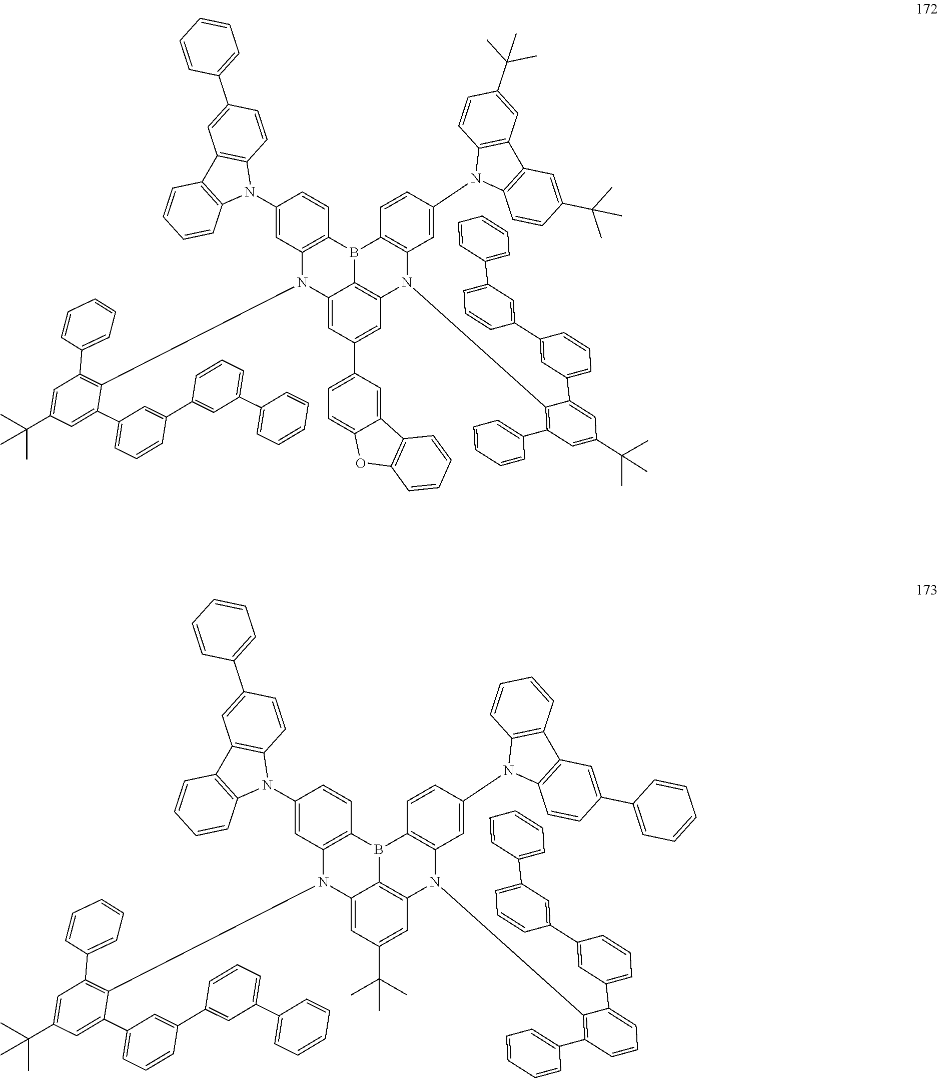

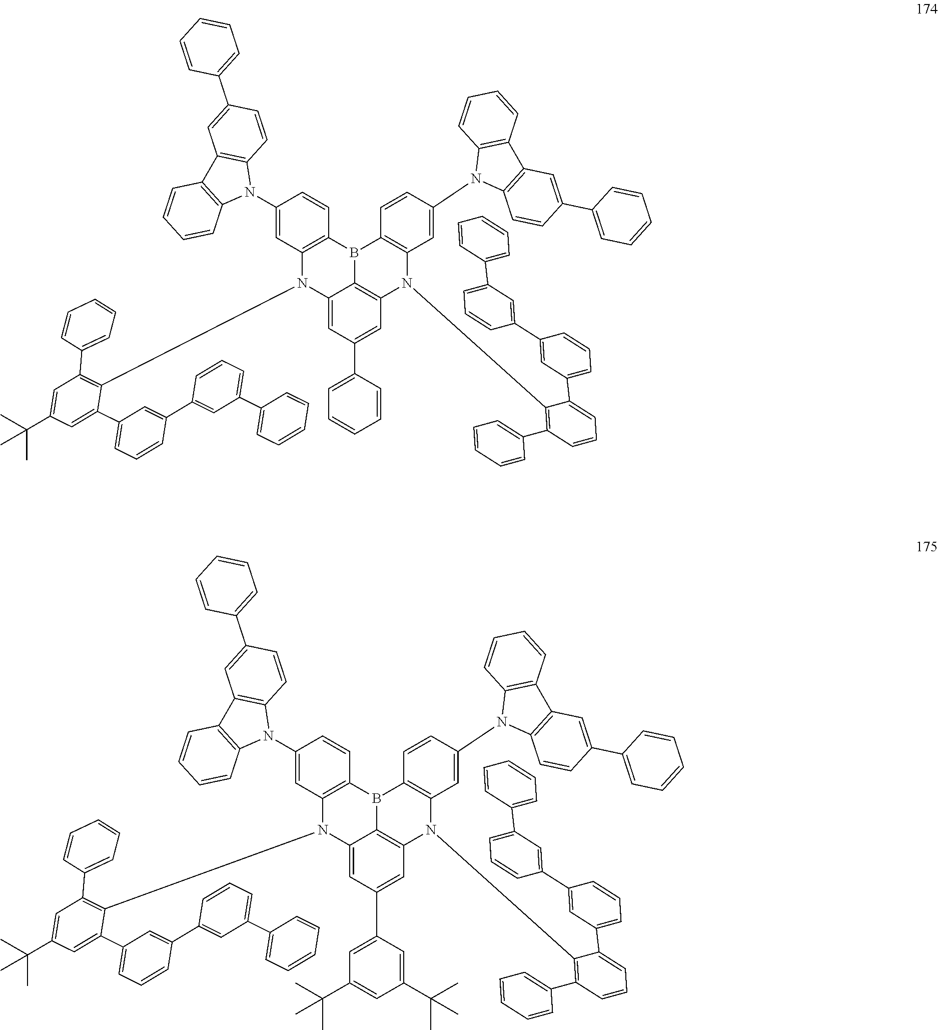 [SMILES: CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccccc5)cccc4-c4cccc(-c5cccc(-c6ccccc6)c5)c4)c4cc(-c5ccccc5)cc2c43)c(-c2cccc(-c3cccc(-c4ccccc4)c3)c2)c1 ; CC(C)(C)c1cc(-c2cc3c4c(c2)N(c2c(-c5ccccc5)cc(C(C)(C)C)cc2-c2cccc(-c5cccc(-c6ccccc6)c5)c2)c2cc(-n5c6ccccc6c6cc(-c7ccccc7)ccc65)ccc2B4c2ccc(-n4c5ccccc5c5cc(-c6ccccc6)ccc54)cc2N3c2c(-c3ccccc3)cccc2-c2cccc(-c3cccc(-c4ccccc4)c3)c2)cc(C(C)(C)C)c1]

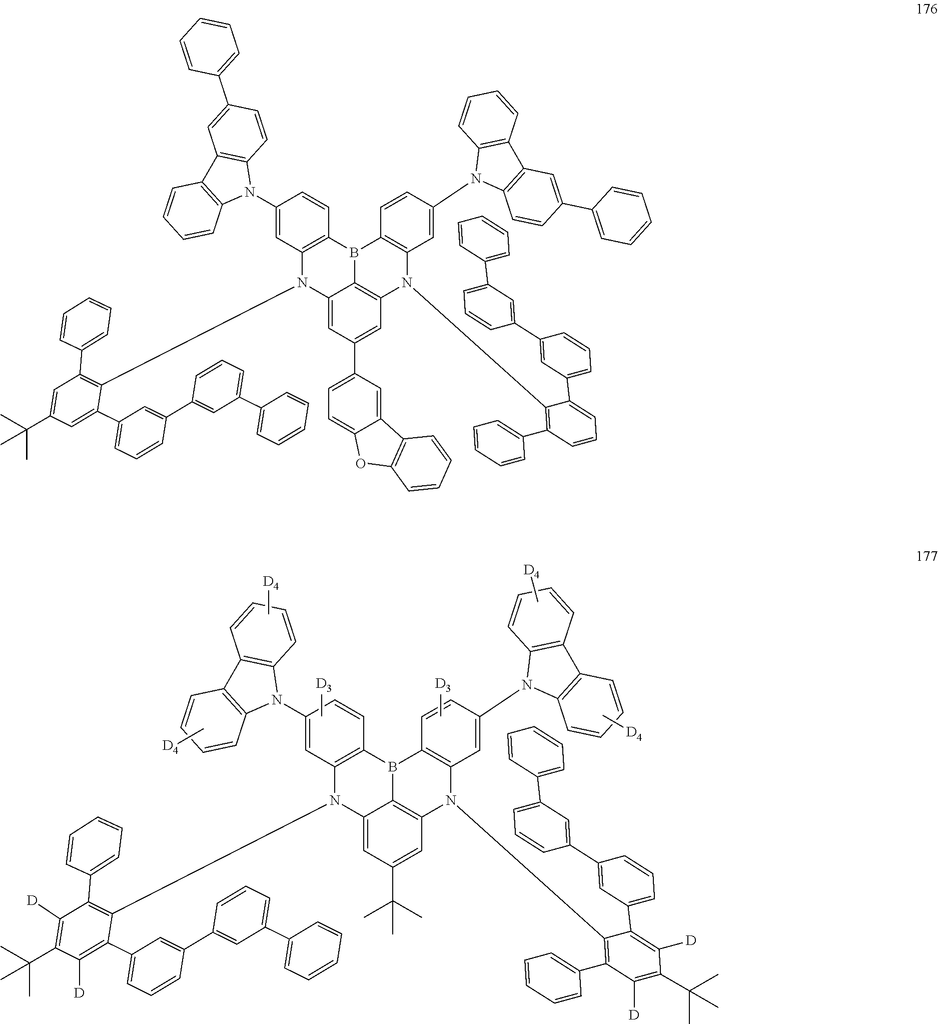

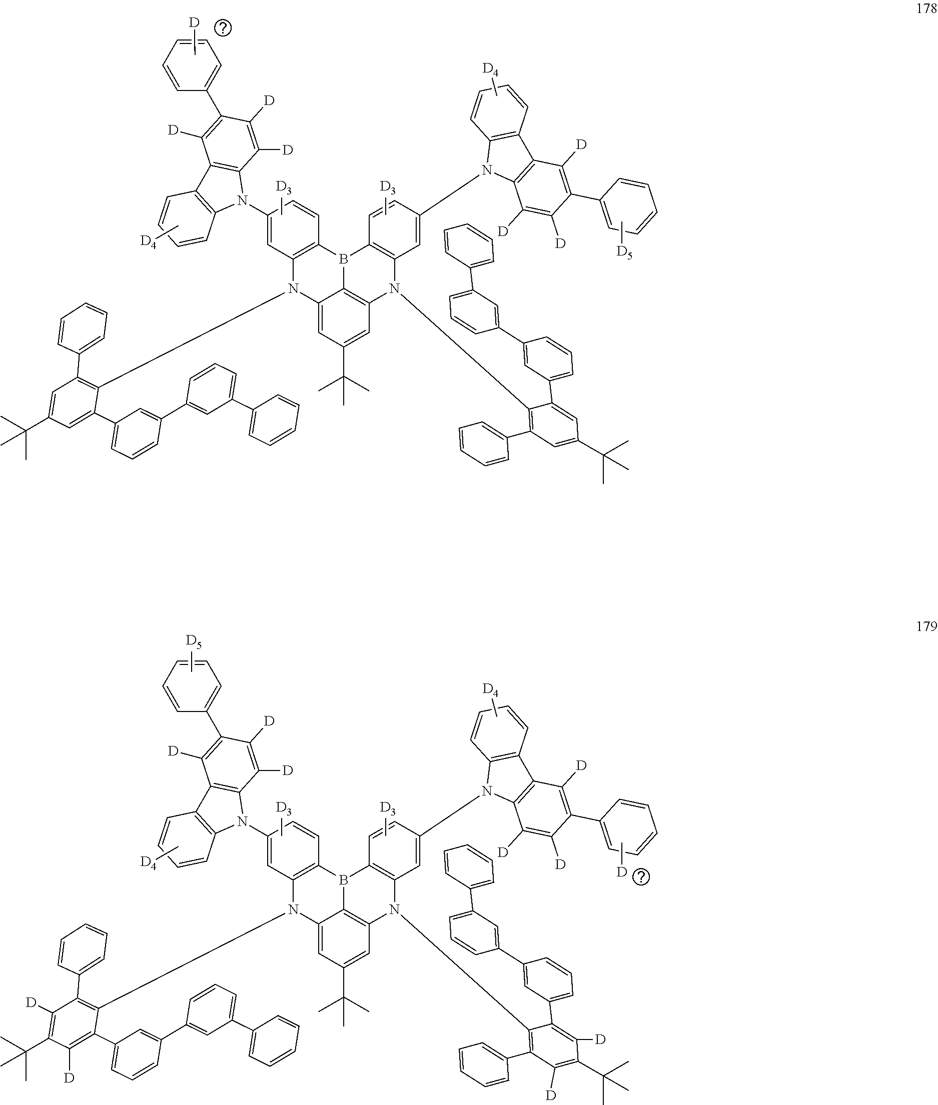

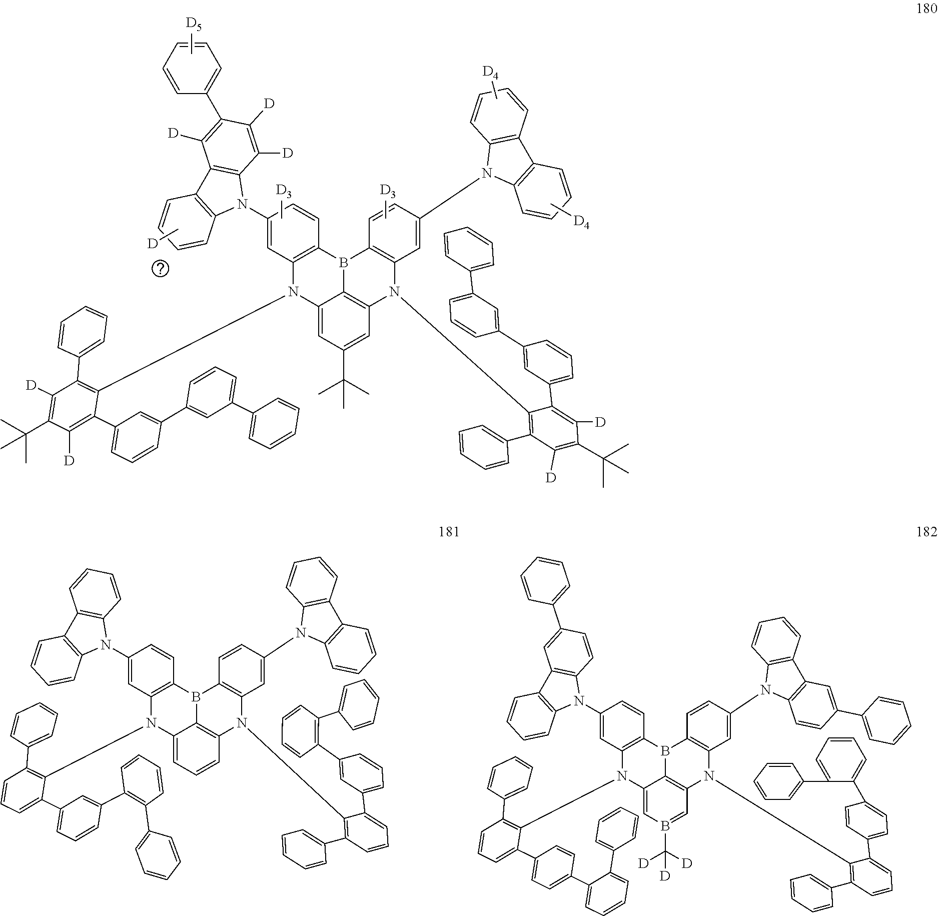

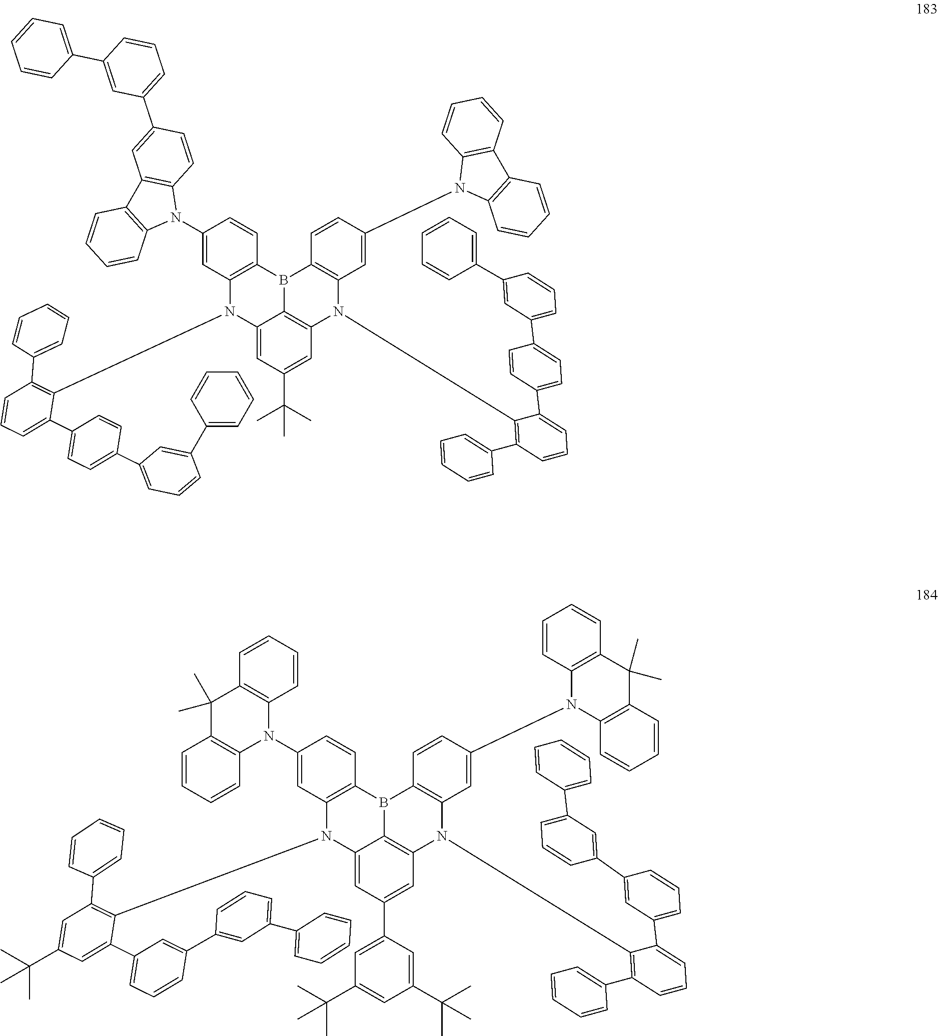 [SMILES: CC(C)(C)c1cc2c3c(c1)N(c1c(-c4ccccc4)cccc1-c1ccc(-c4cccc(-c5ccccc5)c4)cc1)c1cc(-n4c5ccccc5c5cc(-c6cccc(-c7ccccc7)c6)ccc54)ccc1B3c1ccc(-n3c4ccccc4c4ccccc43)cc1N2c1c(-c2ccccc2)cccc1-c1ccc(-c2cccc(-c3ccccc3)c2)cc1 ; CC(C)(C)c1cc(-c2cc3c4c(c2)N(c2c(-c5ccccc5)cc(C(C)(C)C)cc2-c2cccc(-c5cccc(-c6ccccc6)c5)c2)c2cc(N5c6ccccc6C(C)(C)c6ccccc65)ccc2B4c2ccc(N4c5ccccc5C(C)(C)c5ccccc54)cc2N3c2c(-c3ccccc3)cccc2-c2cccc(-c3cccc(-c4ccccc4)c3)c2)cc(C(C)(C)C)c1]

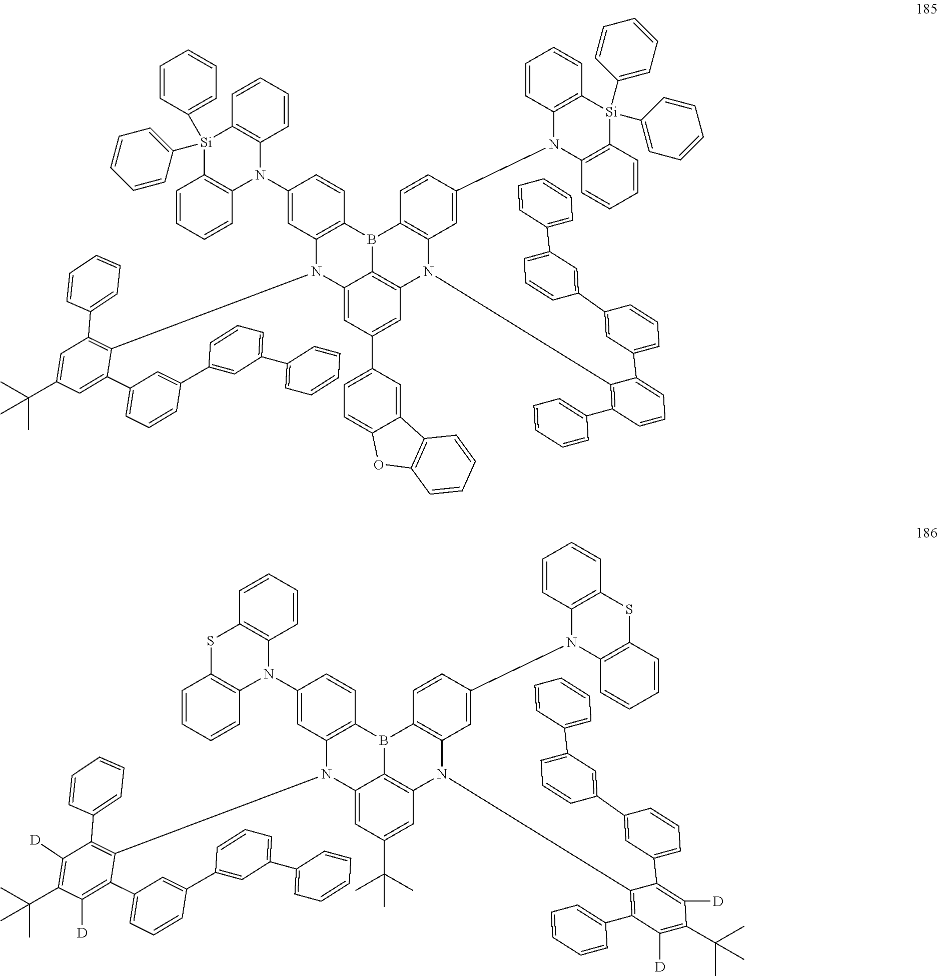 [SMILES: CC(C)(C)c1cc(-c2ccccc2)c(N2c3cc(N4c5ccccc5[Si](c5ccccc5)(c5ccccc5)c5ccccc54)ccc3B3c4ccc(N5c6ccccc6[Si](c6ccccc6)(c6ccccc6)c6ccccc65)cc4N(c4c(-c5ccccc5)cccc4-c4cccc(-c5cccc(-c6ccccc6)c5)c4)c4cc(-c5ccc6oc7ccccc7c6c5)cc2c43)c(-c2cccc(-c3cccc(-c4ccccc4)c3)c2)c1 ; [2H]c1c(-c2ccccc2)c(N2c3cc(N4c5ccccc5Sc5ccccc54)ccc3B3c4ccc(N5c6ccccc6Sc6ccccc65)cc4N(c4c(-c5ccccc5)c([2H])c(C(C)(C)C)c([2H])c4-c4cccc(-c5cccc(-c6ccccc6)c5)c4)c4cc(C(C)(C)C)cc2c43)c(-c2cccc(-c3cccc(-c4ccccc4)c3)c2)c([2H])c1C(C)(C)C]

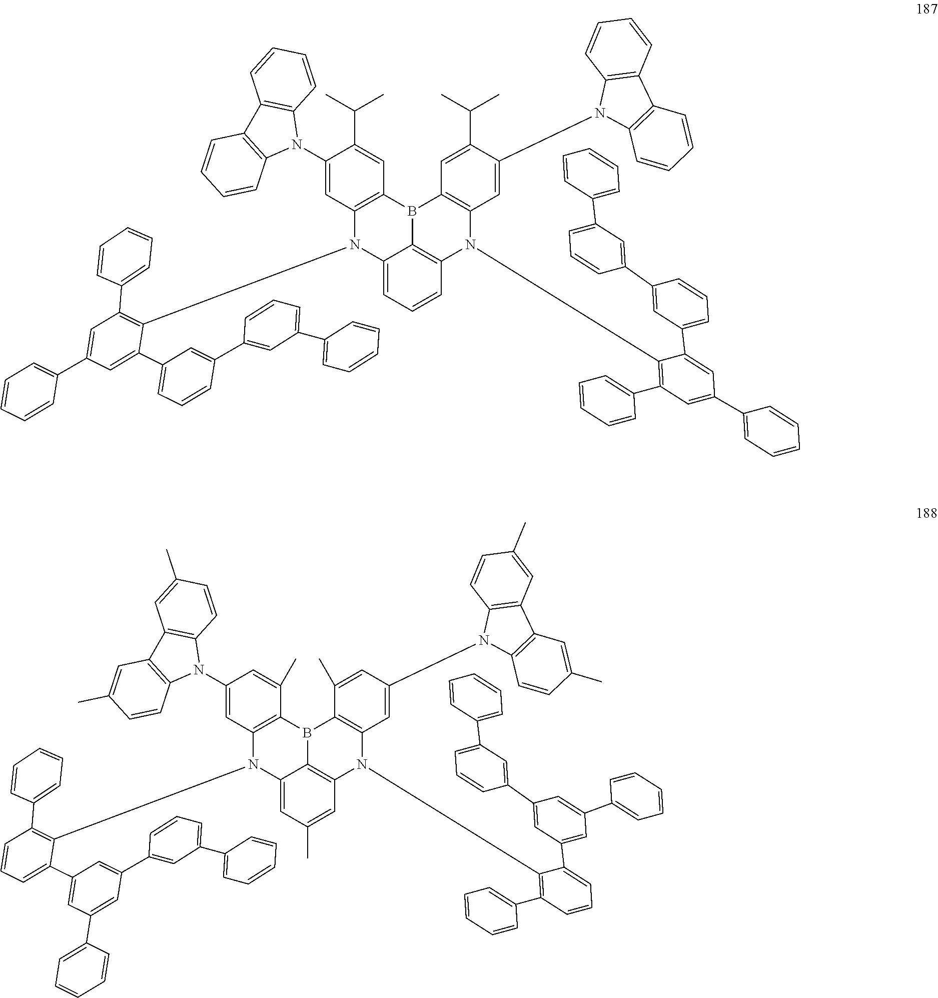 [SMILES: CC(C)c1cc2c(cc1-n1c3ccccc3c3ccccc31)N(c1c(-c3ccccc3)cc(-c3ccccc3)cc1-c1cccc(-c3cccc(-c4ccccc4)c3)c1)c1cccc3c1B2c1cc(C(C)C)c(-n2c4ccccc4c4ccccc42)cc1N3c1c(-c2ccccc2)cc(-c2ccccc2)cc1-c1cccc(-c2cccc(-c3ccccc3)c2)c1 ; Cc1cc2c3c(c1)N(c1c(-c4ccccc4)cccc1-c1cc(-c4ccccc4)cc(-c4cccc(-c5ccccc5)c4)c1)c1cc(-n4c5ccc(C)cc5c5cc(C)ccc54)cc(C)c1B3c1c(C)cc(-n3c4ccc(C)cc4c4cc(C)ccc43)cc1N2c1c(-c2ccccc2)cccc1-c1cc(-c2ccccc2)cc(-c2cccc(-c3ccccc3)c2)c1]

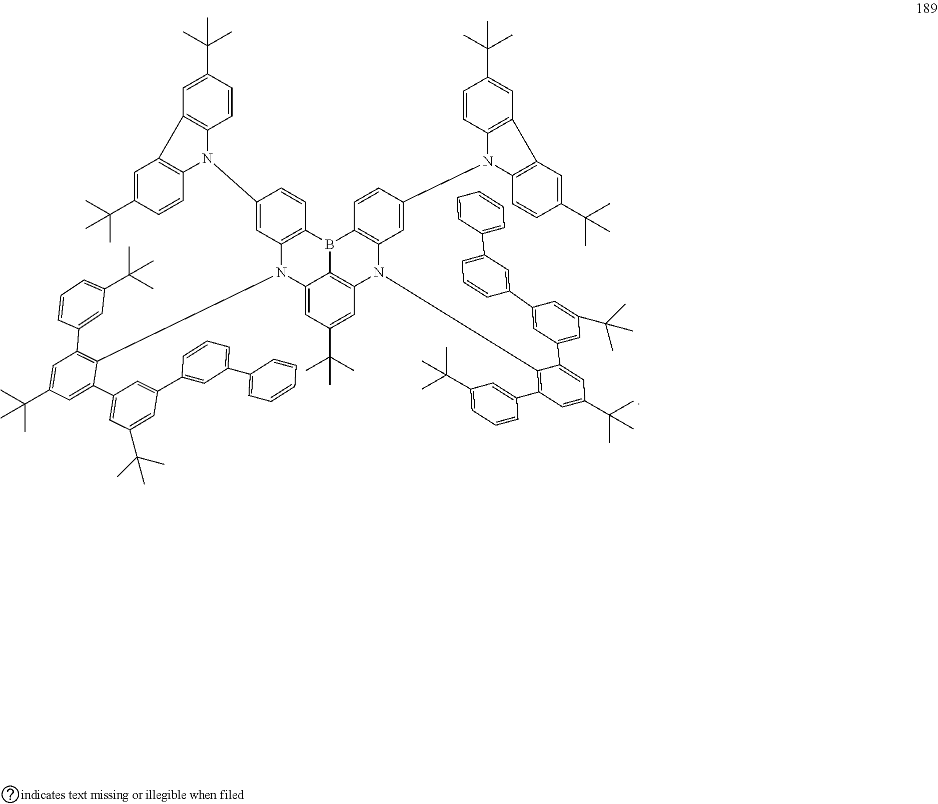 [SMILES: CC(C)(C)c1cccc(-c2cc(C(C)(C)C)cc(-c3cc(-c4cccc(-c5ccccc5)c4)cc(C(C)(C)C)c3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5cccc(C(C)(C)C)c5)cc(C(C)(C)C)cc4-c4cc(-c5cccc(-c6ccccc6)c5)cc(C(C)(C)C)c4)c4cc(C(C)(C)C)cc2c43)c1]

A light emitting layer EML may include the polycyclic compound according to an embodiment as a dopant. The polycyclic compound according to an embodiment may be a thermally activated delayed fluorescence (TADF) material. The polycyclic compound according to an embodiment may be a thermally activated delayed fluorescence material having multiple resonance (MR) properties.

A dopant of the related art having a condensed polycyclic structure that includes a boron atom and two nitrogen atoms as ring-forming atoms in a central moiety has an electron-deficient state because the boron atom has an empty p orbital. When the p orbital readily receives an electron from the surroundings and combines with another compound, or when the boron atom has a deformed three-dimensional structure due to a received electron, thereby losing a trigonal planar structure, the properties of a light emitting element may deteriorate. A dopant having a condensed polycyclic structure that includes a boron atom and two nitrogen atoms as ring-forming atoms in a central moiety is a molecule having multiple resonance properties, wherein luminescence transition occurs in a condensed polycyclic central moiety containing the boron atom, and therefore, when improvements are made such that the p orbital of the boron atom is prevented from receiving an electron, luminous efficiency and lifespan properties of a light emitting element may be improved. In the specification, the term “symmetric group” may be interpreted as a group that is symmetrical with respect to the sigma bond that combines the group with nitrogen atom of fused ring core. According to embodiments, an asymmetric aryl group, such as an aryl group bonded to a nitrogen atom in Formula 1, may be introduced to physically protect the p orbital of a boron atom from electrons, thereby preventing degradation of the luminescence transition process. When an asymmetric aryl group is introduced to the fused ring core as described above, the p orbital of the boron atom may be protected by such a substituent having a relatively lower molecular weight at least as well as by an asymmetric aryl group substituent that is introduced to a fused ring core. The polycyclic compound according to an embodiment has a more spherical shape as compared to a compound that includes a symmetric aryl substituent, so that the molecular stability of the polycyclic compound is improved, and the sublimation temperature is also improved to 330° C., thereby facilitating synthesis. The polycyclic compound according to an embodiment further includes a heteroaryl group, such as a carbazole group, which is substituted at a para position to a boron atom, which is a ring-forming atom of the fused ring core, and thus, has improved bond dissociation energy, as compared to a compound having a structure that includes a typical diphenyl amine substituent. In the specification, bond dissociation energy refers to a bond dissociation energy between a nitrogen atom forming a condensed ring with a boron atom and a carbon atom bonded to the nitrogen atom. When bond dissociation energy is improved, molecular stability of the polycyclic compound is improved, so that the luminous efficiency and lifespan properties of a light emitting element may be improved.

The polycyclic compound according to an embodiment may emit blue light, and may have a central wavelength in a range of about 430 nm to about 490 nm. The light emitting element ED including the polycyclic compound according to an embodiment may emit light having a central wavelength in a range of about 430 nm to about 490 nm. The light emitting element ED including the polycyclic compound according to an embodiment may emit blue light. For example, the third light emitting element ED-3 (see FIG. 2), which emits blue light, may include the polycyclic compound according to an embodiment.

In an embodiment, the light emitting layer EML may include the polycyclic compound according to an embodiment as a first compound, and may further include at least one of a second compound, a third compound, and a fourth compound.

In an embodiment, the light emitting layer EML may further include a second compound represented by Formula HT-1. In an embodiment, the second compound may be used as a hole transporting host material in the light emitting layer EML.

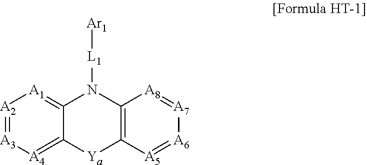

In Formula HT-1, A₁ to A₈ may each independently be N or C(R₅₁). For example, A₁ to A₈ may each independently be C(R₅₁). As another example, any one of A₁ to A₈ may be N, and the remainder of A₁ to A₈ may each independently be C(R₅₁).

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but embodiments are not limited thereto.

In Formula HT-1, Yₐ may be a direct linkage, C(R₅₂)(R₅₃), or Si(R₅₄)(R₅₅). For example, the two benzene rings that are linked to the nitrogen atom in Formula HT-1 may be connected to each other via a direct linkage,

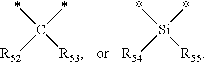

In Formula HT-1, when Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₅₁ to R₅5 may each independently be a hydrogen atom or a deuterium atom. For example, R₅₁ to R₅5 may each independently be an unsubstituted methyl group or an unsubstituted phenyl group.

In an embodiment, the second compound represented by Formula HT-1 may be selected from Compound Group 2. In an embodiment, in the light emitting element ED, the second compound may include at least one compound selected from Compound Group 2.

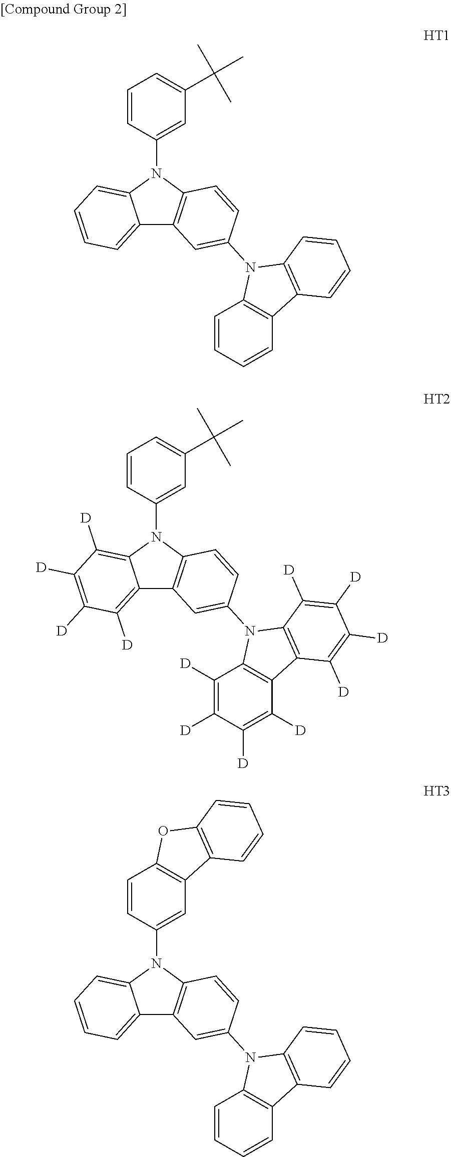

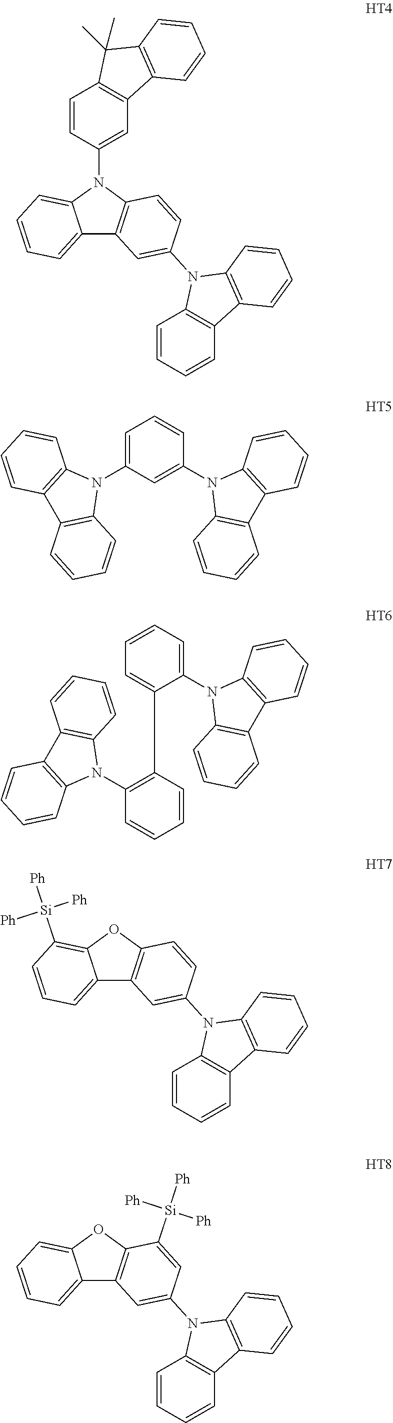 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

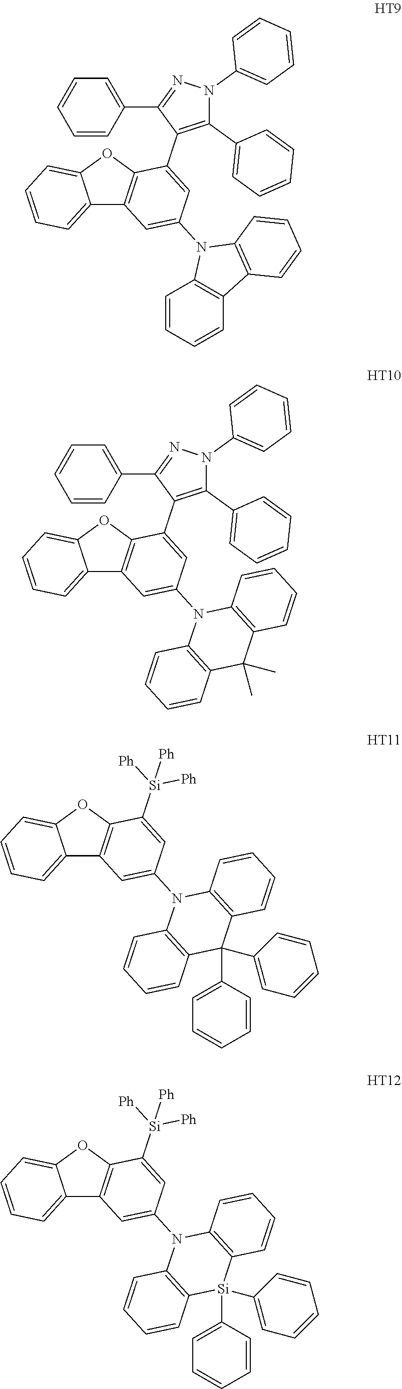

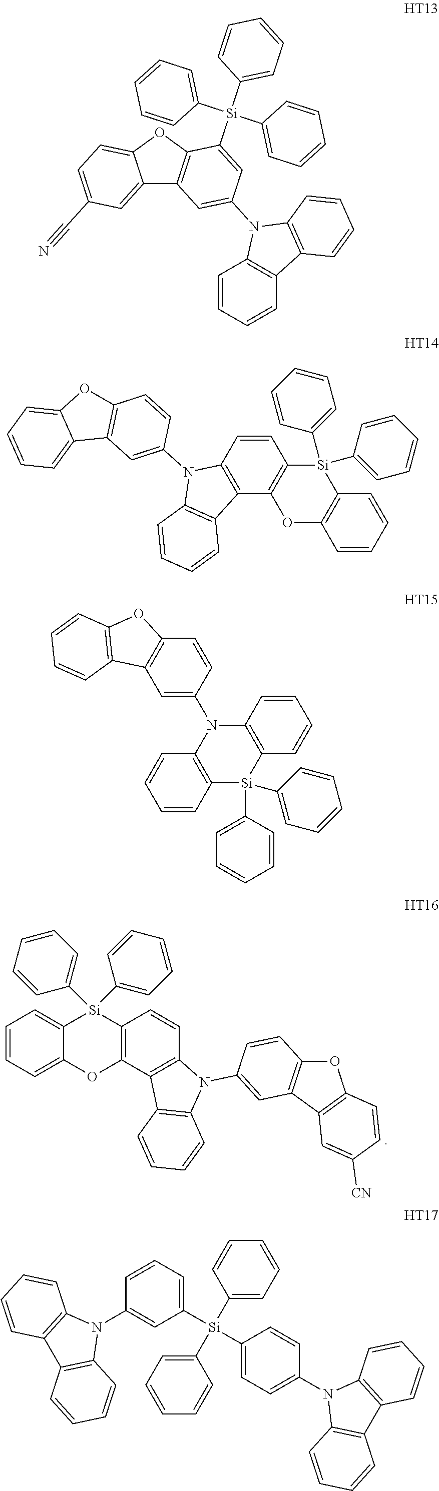 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2ccc(-n3c4ccccc4c4ccccc43)cc2)c2cccc(-n3c4ccccc4c4ccccc43)c2)cc1]

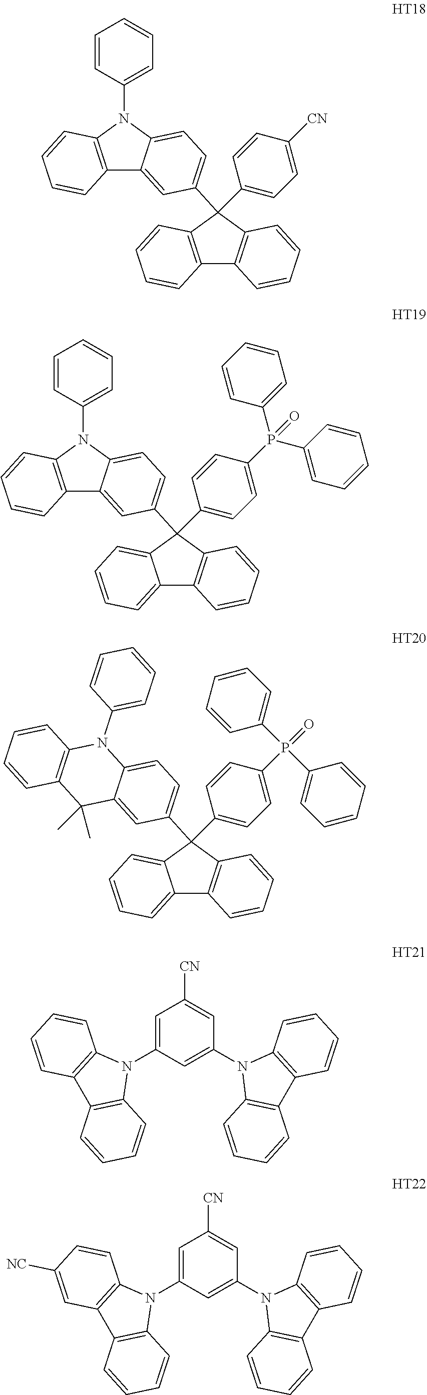

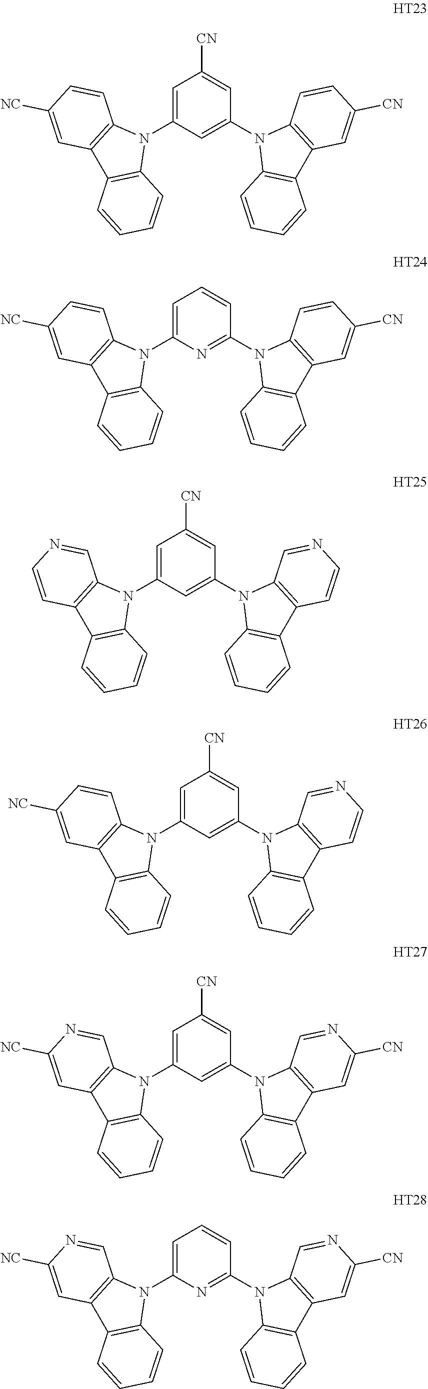 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

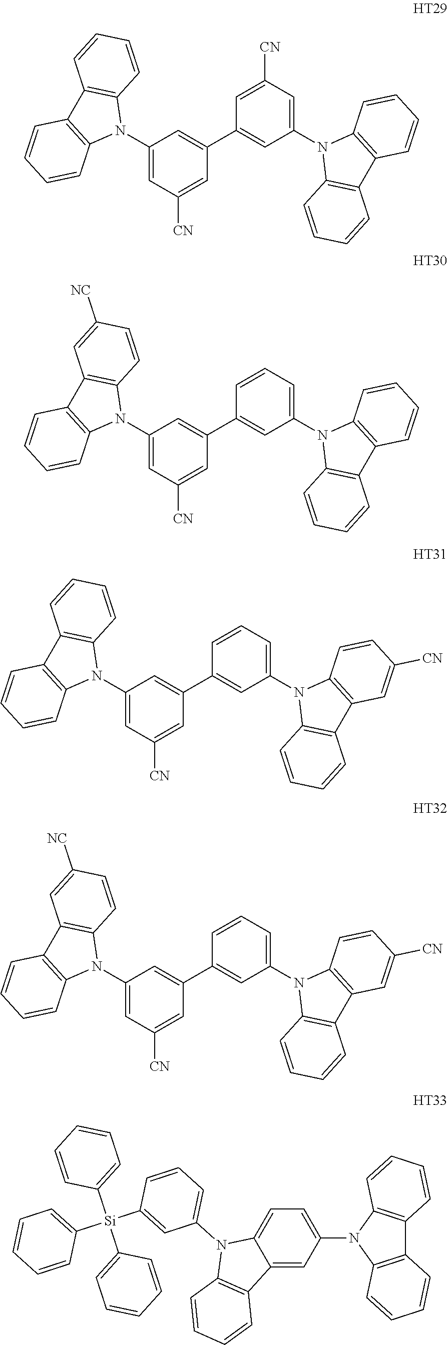 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

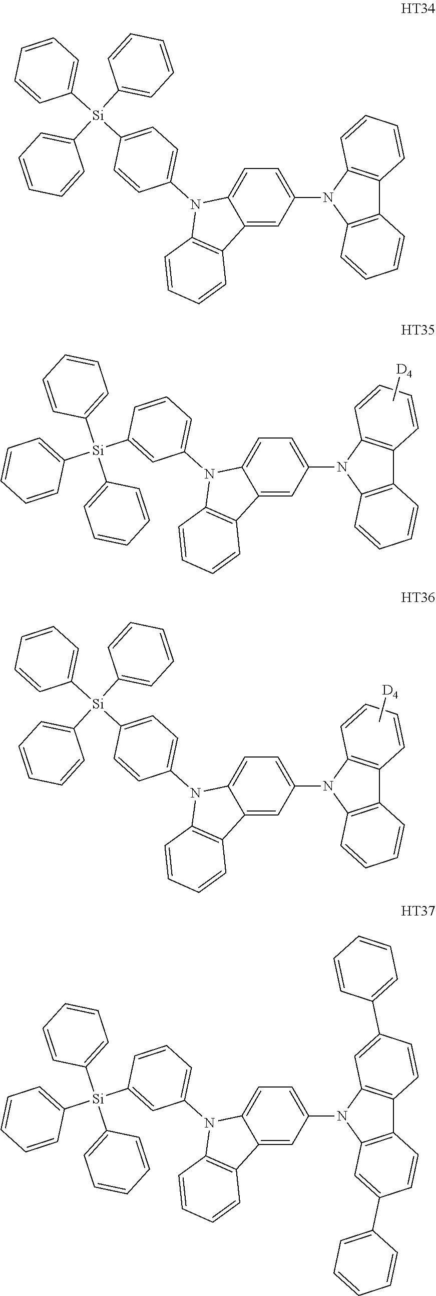

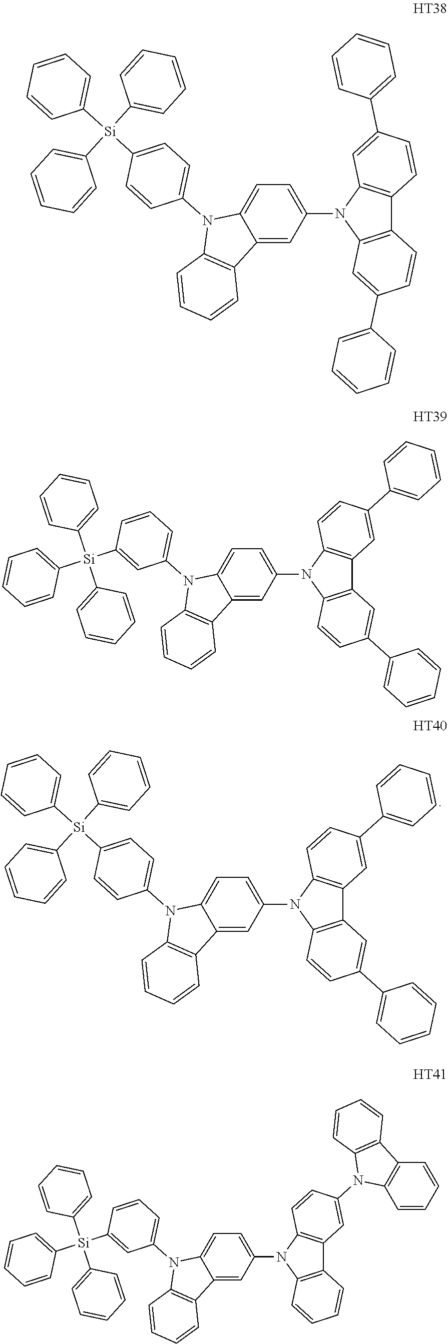 [SMILES: c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1]

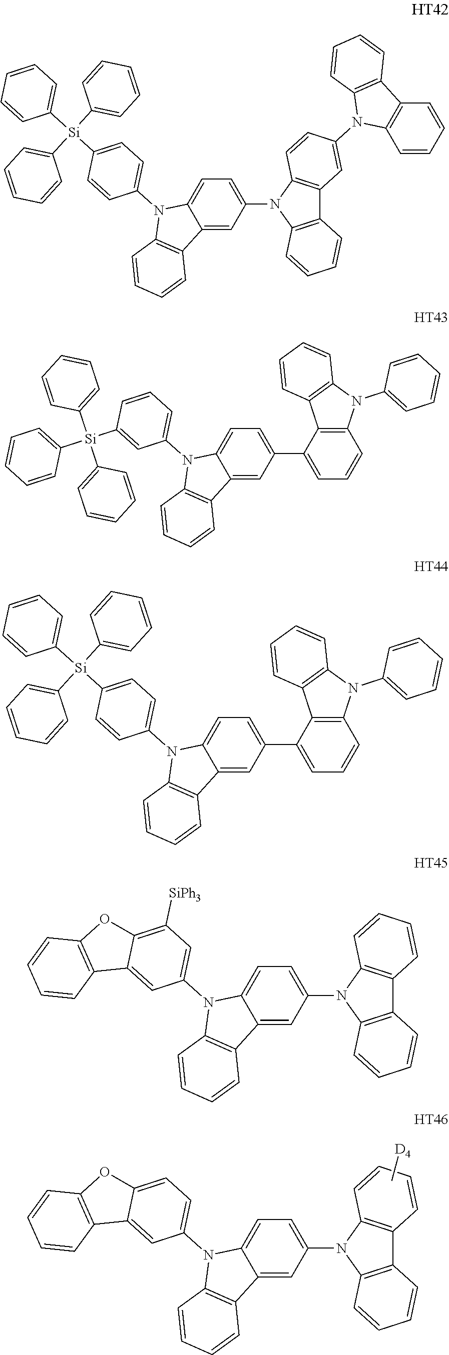

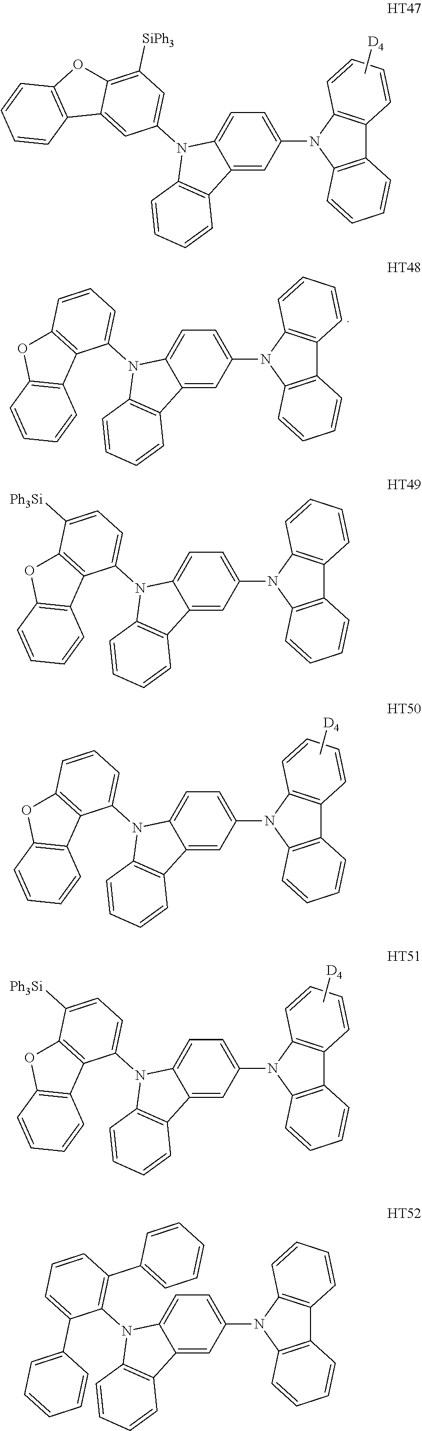

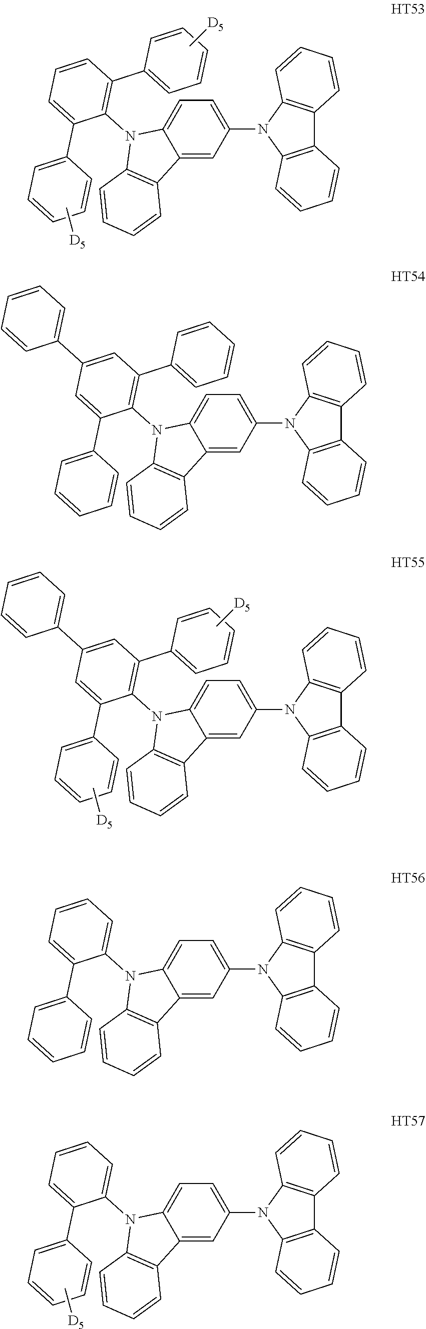

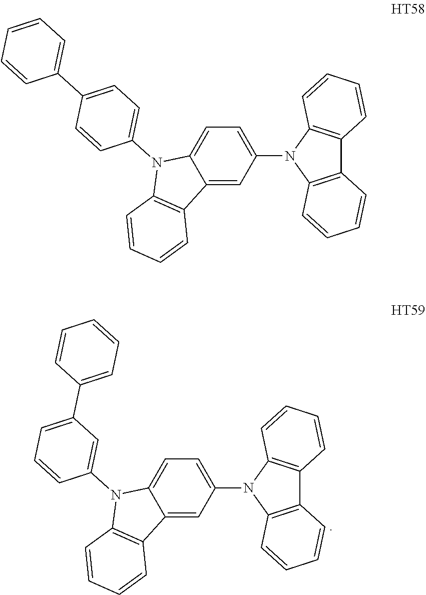 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

In Compound Group 2, D represents a deuterium atom, and Ph represents a substituted or unsubstituted phenyl group. For example, in Compound Group 2, Ph may represent an unsubstituted phenyl group.

In an embodiment, the light emitting layer EML may further include a third compound represented by Formula ET-1. In an embodiment, the third compound may be used as an electron transport host material in the light emitting layer EML.

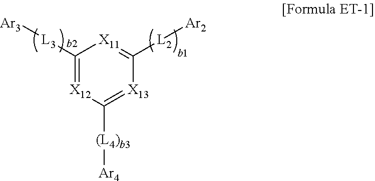

In Formula ET-1, at least one of X₁₁ to X₁₃ may each be N, and the remainder of X₁₁ to X₁₃ may each independently be C(R₅₆). For example, one of X₁₁ to X₁₃ may be N, and the remainder of X₁₁ to X₁₃ may each independently be C(R₅₆). Thus, the third compound represented by Formula ET-1 may include a pyridine moiety. As another example, two of X₁₁ to X₁₃ may each be N, and the remainder of X₁ to X₃ may each independently be C(R₆). Thus, the third compound represented by Formula ET-1 may include a pyrimidine moiety. As yet another example, X₁₁ to X₁₃ may each be N. Thus, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer from 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. When b1 to b3 are each 2 or greater, multiple groups of each of L₂ to L₄ may each independently be a substituted or unsubstituted arylene group having 6 to 30 ring-forming carbon atoms or a substituted or unsubstituted heteroarylene group having 2 to 30 ring-forming carbon atoms.

In an embodiment, the third compound represented by Formula ET-1 may be selected from Compound Group 3. In an embodiment, in the light emitting element ED, the third compound may include at least one compound selected from Compound Group 3.

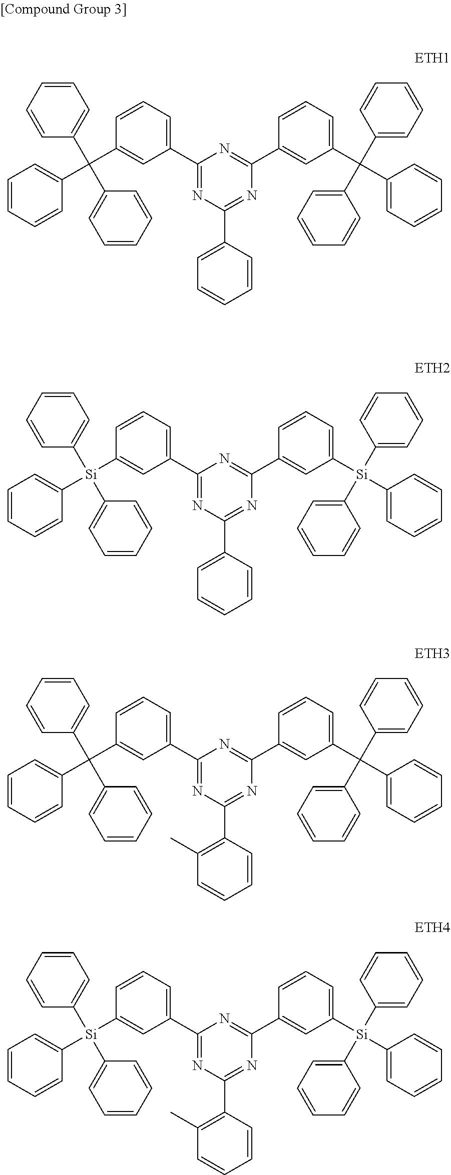 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

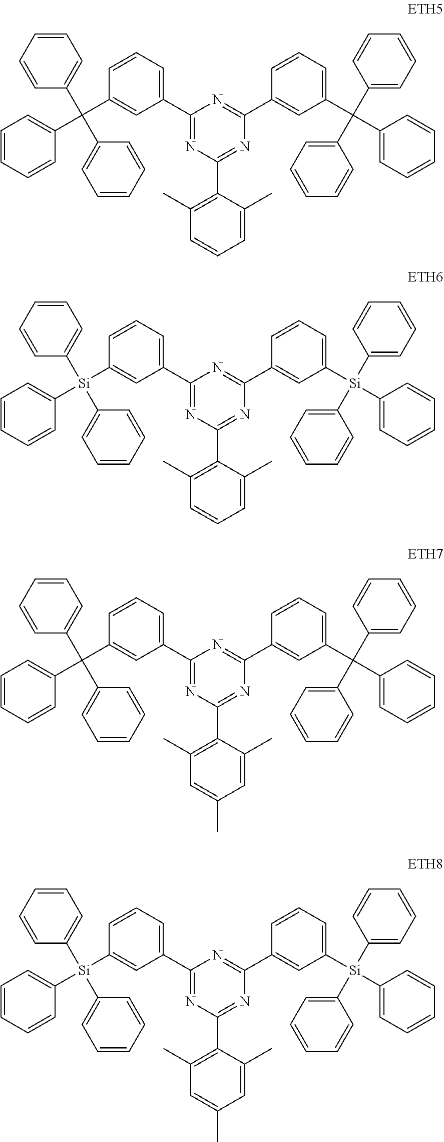 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

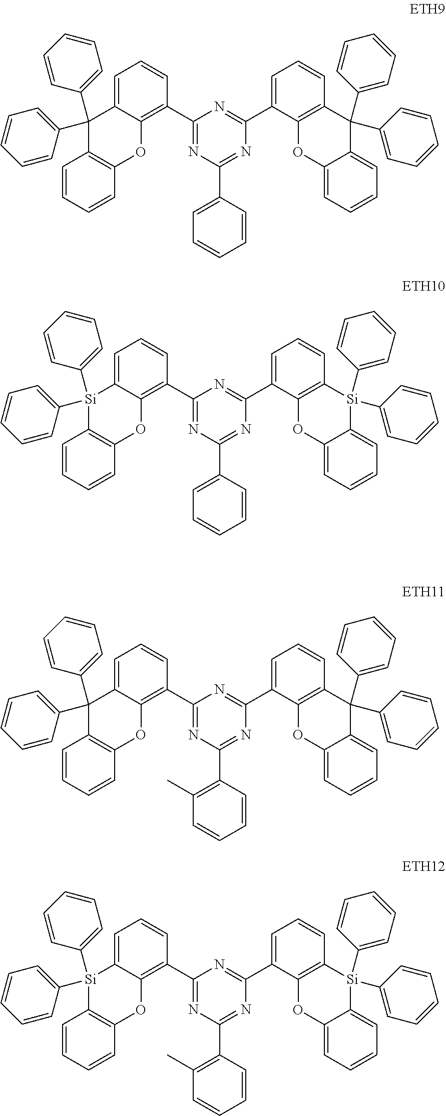 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

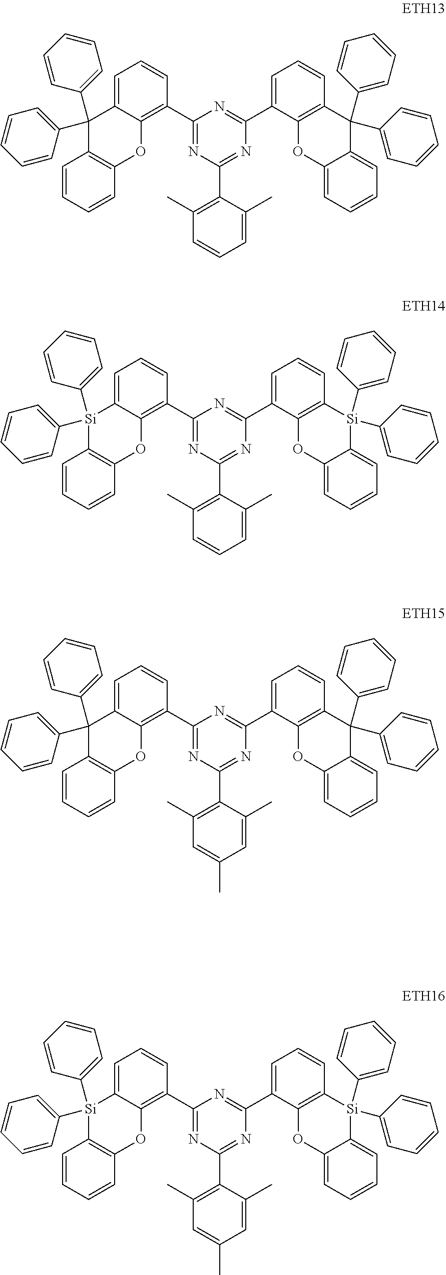 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

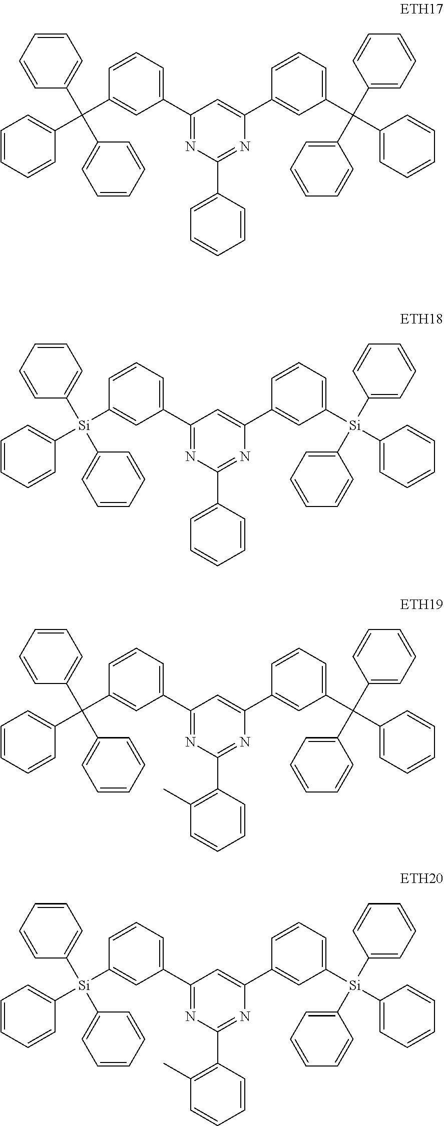 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

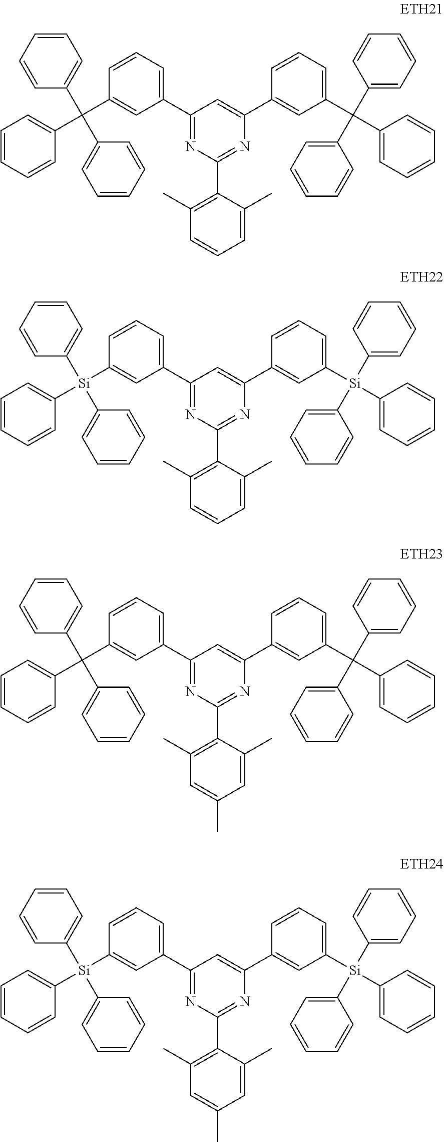 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

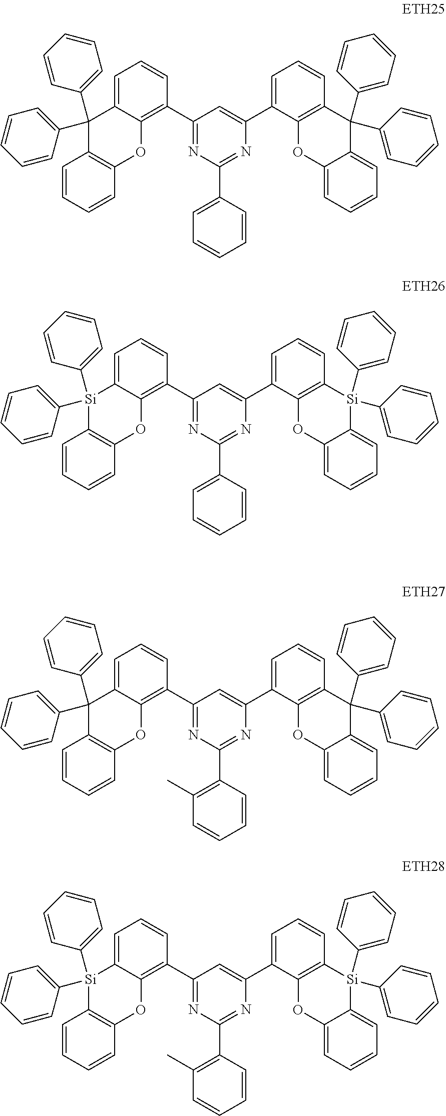 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

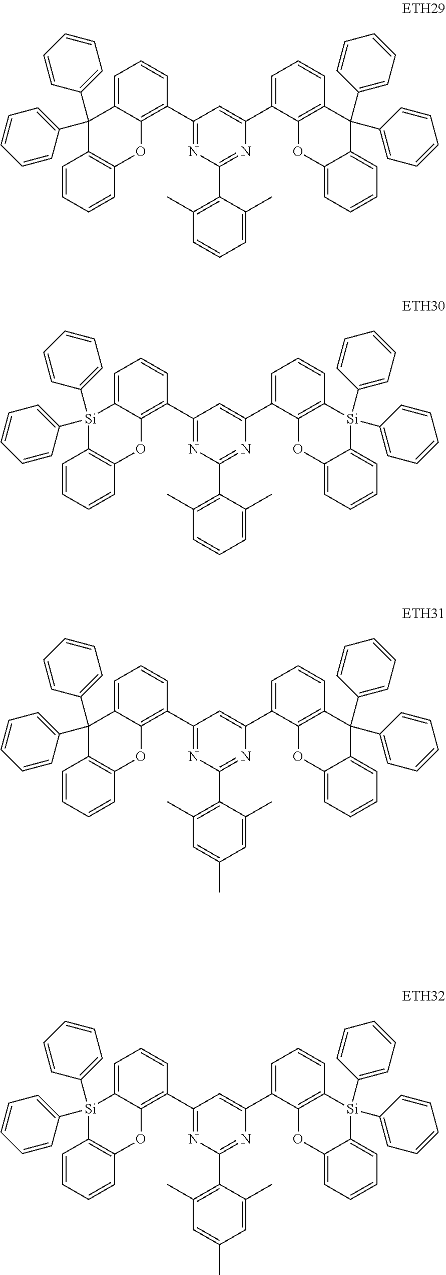 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

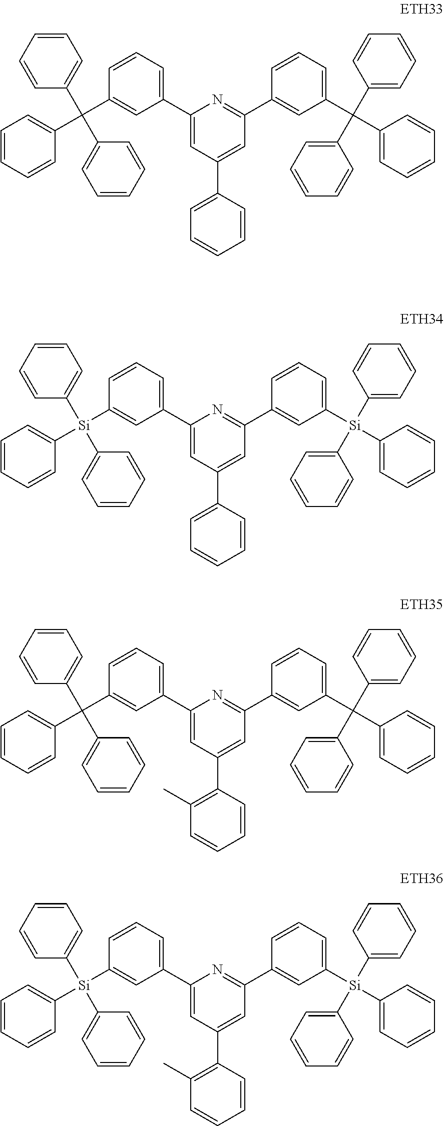 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

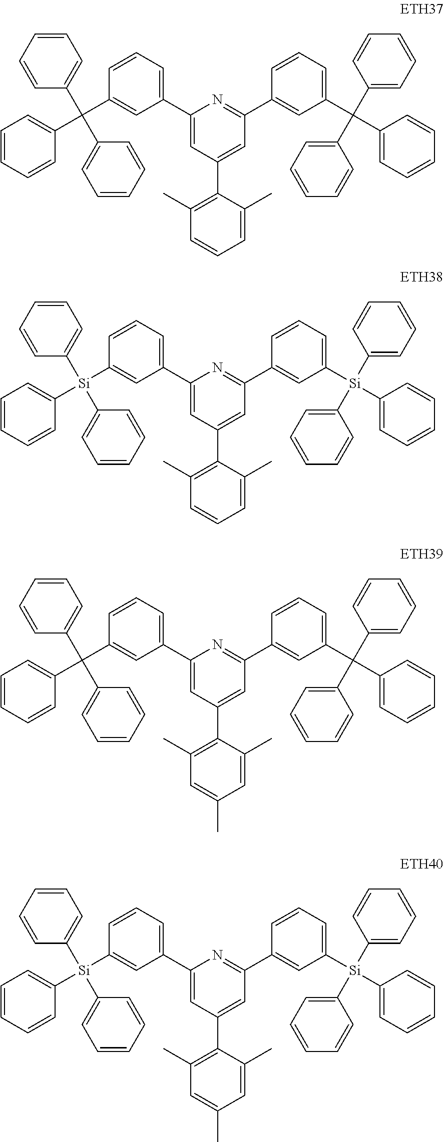 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

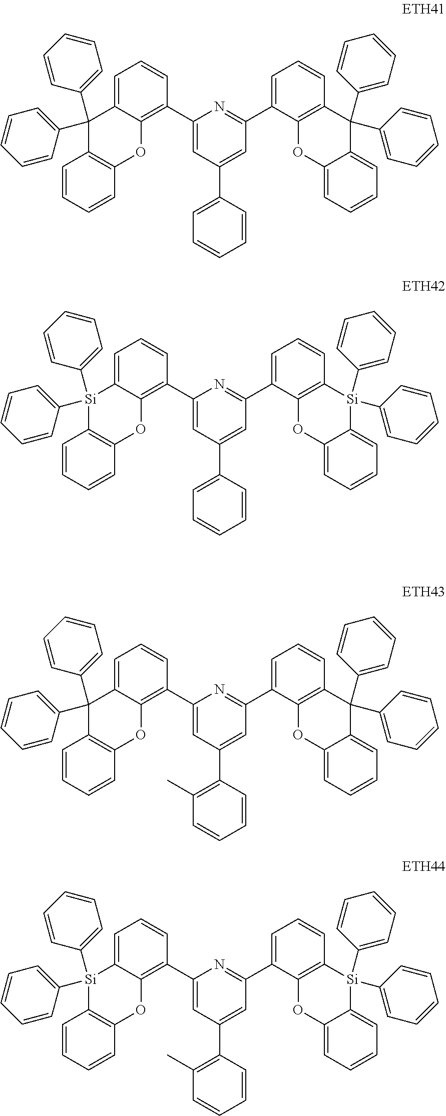 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

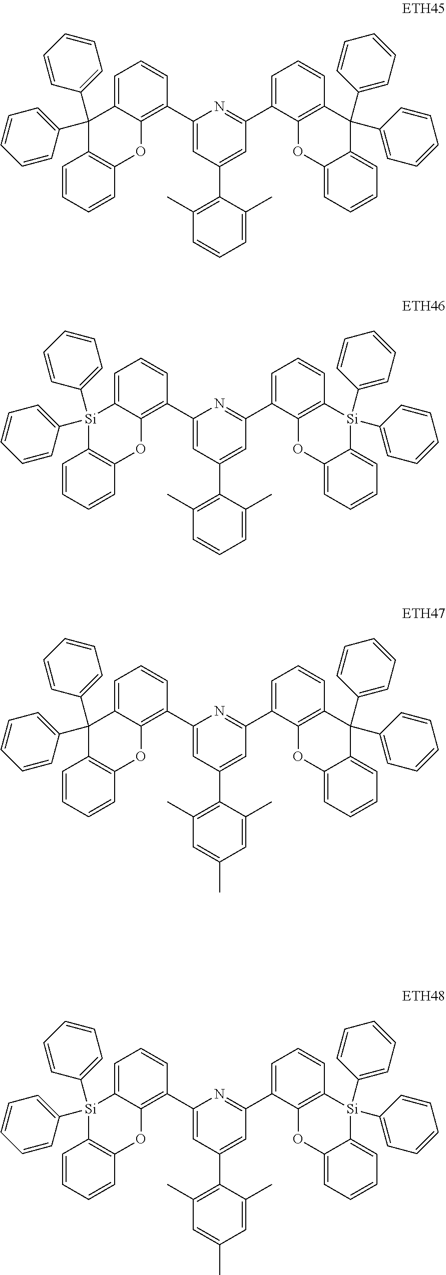 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

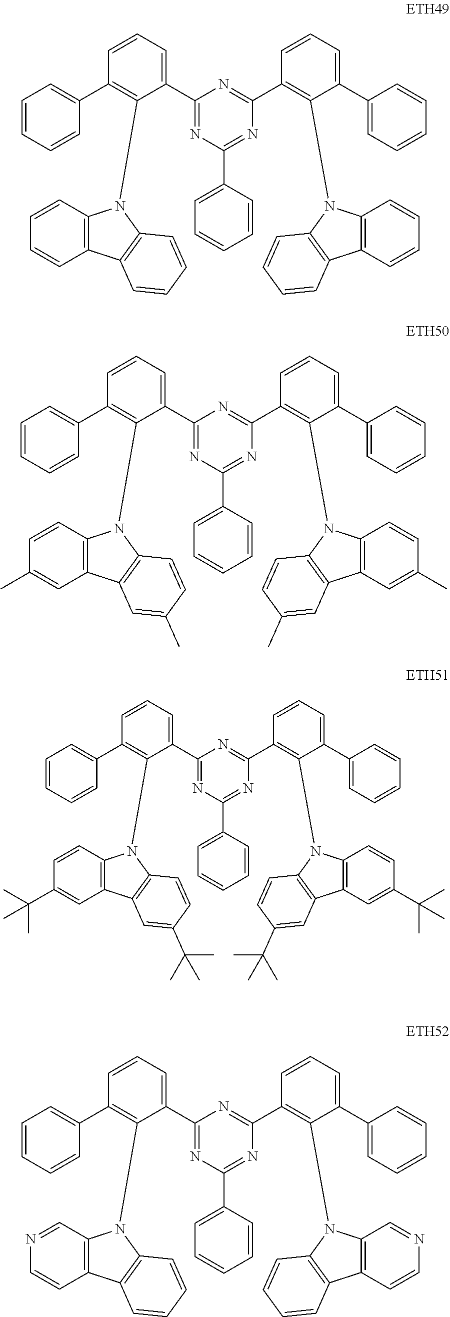

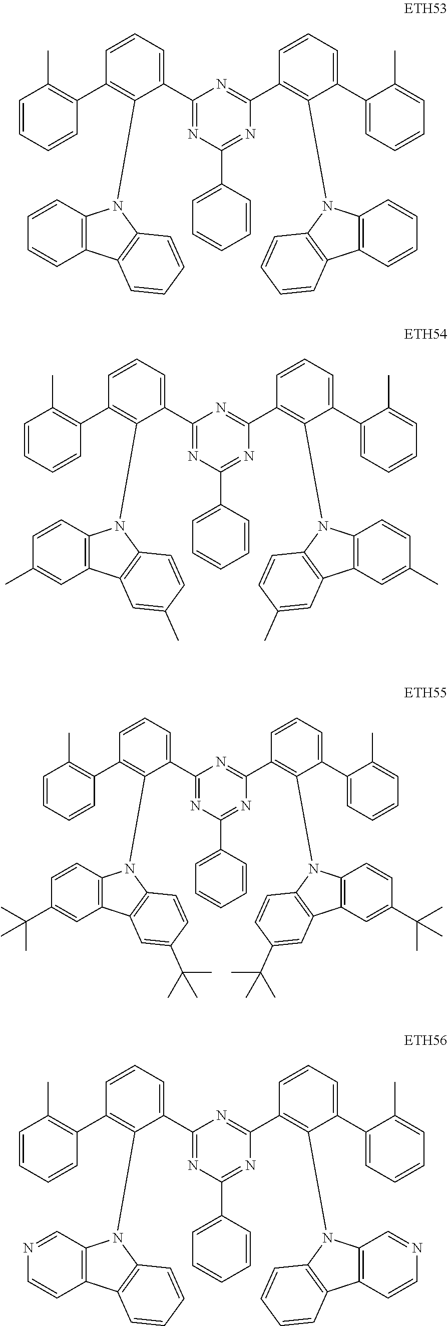

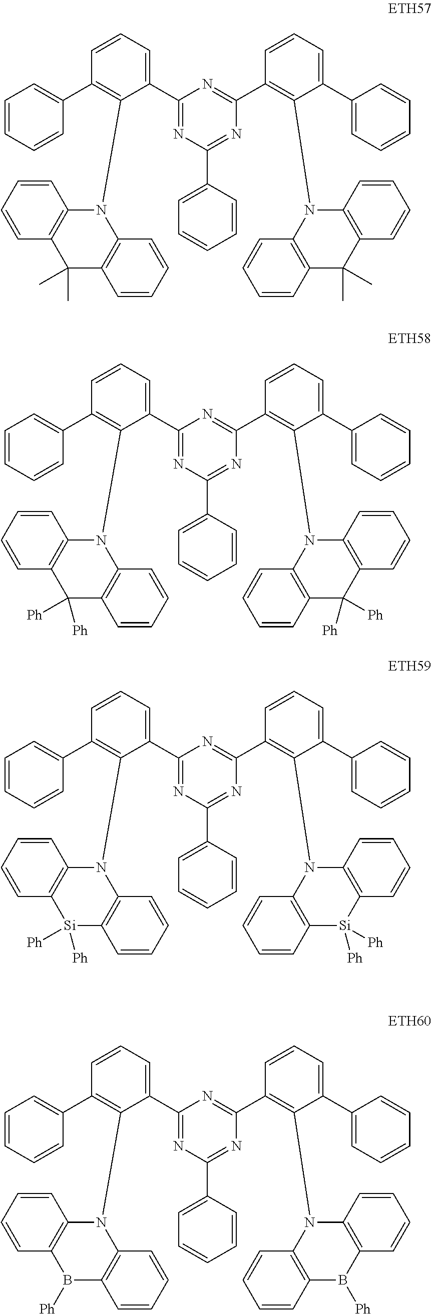

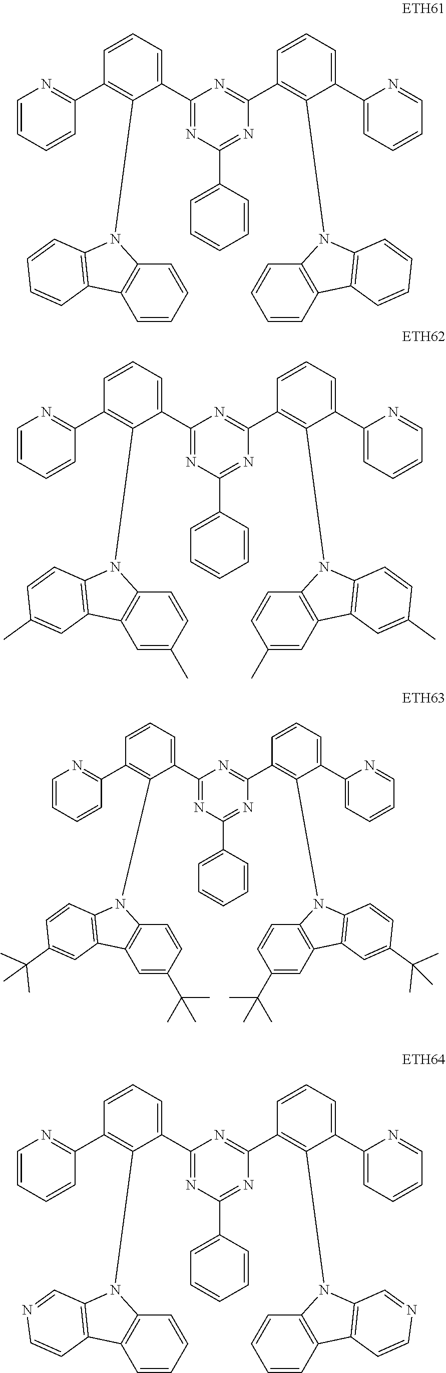

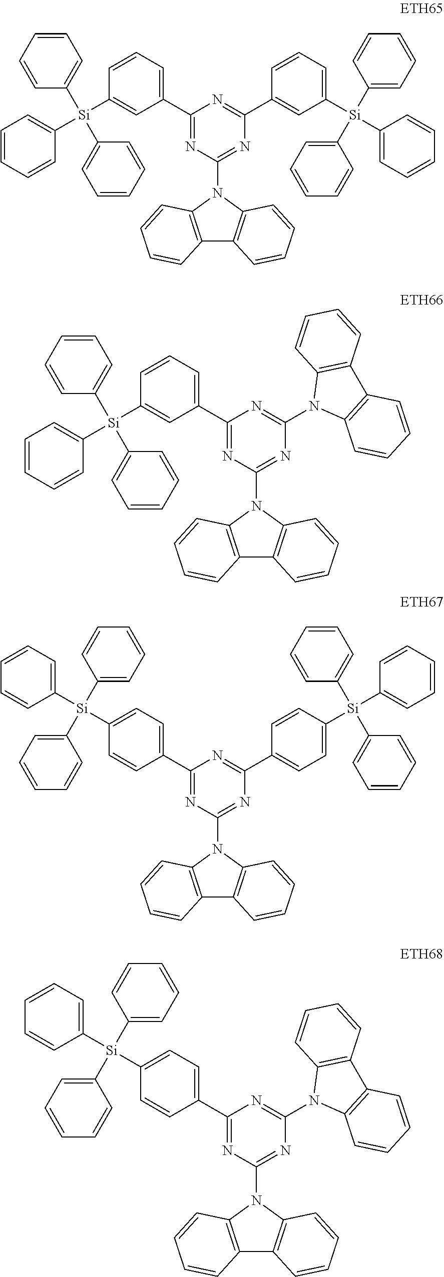 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

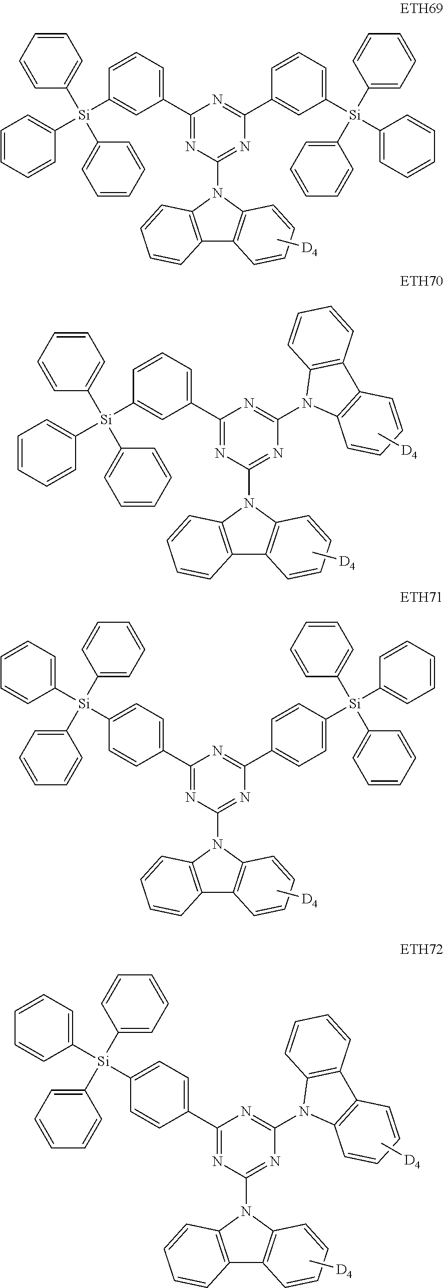

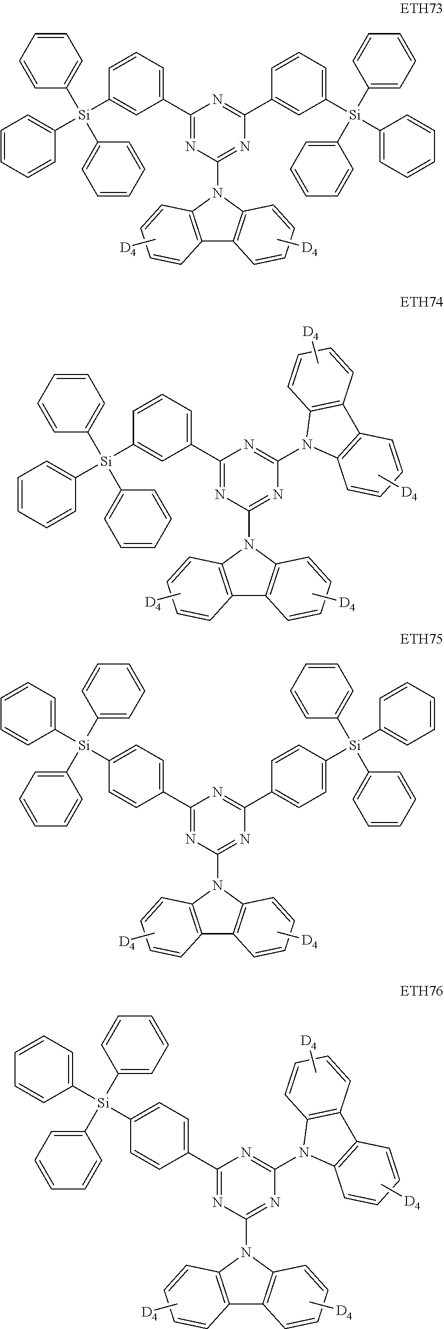

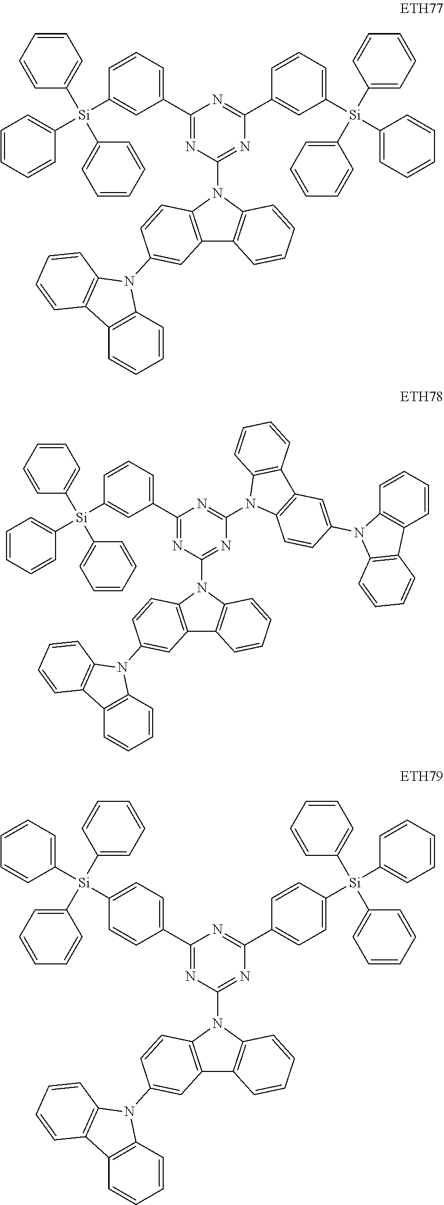 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

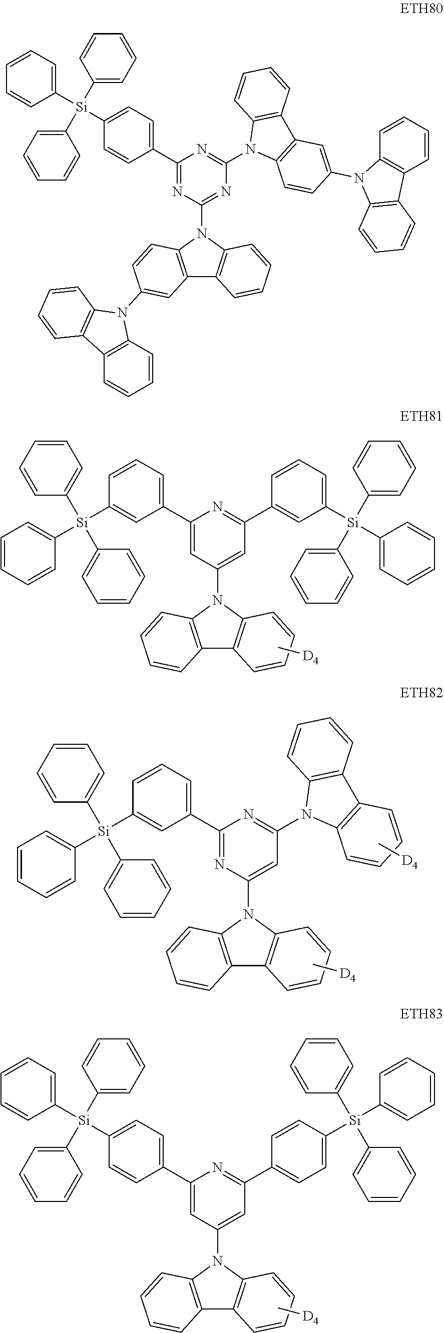

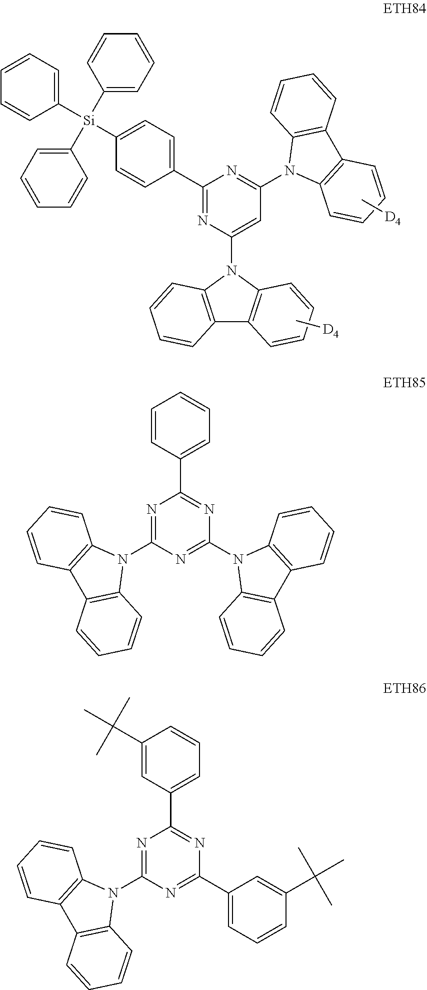

In Compound Group 3, D represents a deuterium atom, and Ph represents an unsubstituted phenyl group. unsubstituted phenyl group.

In an embodiment, the light emitting layer EML may include the second compound and the third compound, and the second compound and the third compound may form an exciplex. In the light emitting layer EML, an exciplex may be formed by a hole transport host and an electron transport host. A triplet energy level of the exciplex formed by a hole transporting host and an electron transporting host may correspond to a difference between a lowest unoccupied molecular orbital (LUMO) energy level of the electron transporting host and a highest occupied molecular orbital (HOMO) energy level of the hole transporting host.

For example, an absolute value of a triplet energy level (T1) of the exciplex formed by the hole transporting host and the electron transporting host may be in a range of about 2.4 eV to about 3.0 eV. The triplet energy level of the exciplex may have a value that is smaller than an energy gap of each host material. The exciplex may have a triplet energy level equal to or less than about 3.0 eV, which is an energy gap between the hole transporting host and the electron transporting host.

In an embodiment, the light emitting layer EML may include a fourth compound, in addition to the first compound, the second compound, and the third compound as described above. The fourth compound may be used as a sensitizer in the light emitting layer EML. Energy may be transferred from the fourth compound to the first compound, thereby effecting light emission.

In an embodiment, the light emitting layer EML may include, as a fourth compound, an organometallic complex that includes platinum (Pt) as a central metal atom and ligands linked to the central metal atom. In an embodiment, the light emitting layer EML may further include a fourth compound represented by Formula D-1:

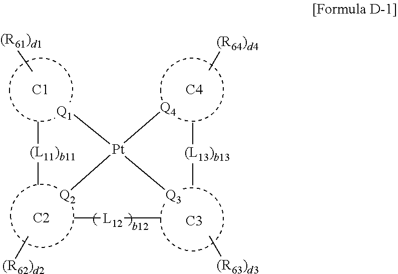

In Formula D-1, Q₁ to Q₄ may each independently be C or N.

In Formula D-1, C₁ to C₄ may each independently be a substituted or unsubstituted hydrocarbon ring group having 5 to 30 ring-forming carbon atoms or a substituted or unsubstituted heterocyclic group having 2 to 30 ring-forming carbon atoms.

In Formula D-1, L₁₁ to L₁₃ may each independently be a direct linkage, *—O—*, *—S—*,

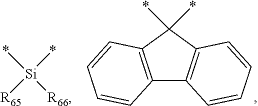

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, —* represents a bond to one of C1 to C4.

In Formula D-1, b11 to b13 may each independently be 0 or 1. If b11 is 0, C1 and C2 may not be directly linked to each other. If b12 is 0, C2 and C3 may not be directly linked to each other. If b13 is 0, C3 and C4 may not be directly linked to each other.

In Formula D-1, R₆₁ to R₆, may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₆₁ to R₆, may each independently be a substituted or unsubstituted methyl group or a substituted or unsubstituted t-butyl group.

In Formula D-1, d1 to d4 may each independently be an integer from 0 to 4. If d1 to d4 are each 0, the fourth compound may not be substituted with R₆₁ to R₆₄, respectively. A case where d1 to d4 are each 4 and four groups of each of R₆₁ to R₆₄ are all hydrogen atoms may be the same as a case where d1 to d4 are each 0. When d1 to d4 are each 2 or more, multiple groups of each of R₆₁ to R₆₄ may all be the same or at least one thereof may be different from the remainder.

In an embodiment, in Formula D-1, C1 to C4 may each independently be a substituted or unsubstituted hydrocarbon ring or a substituted or unsubstituted heterocycle that is represented by any one of Formula C-1 to Formula C-4:

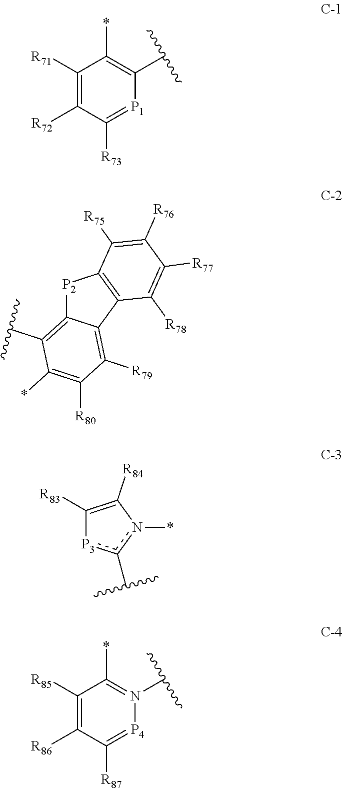

In Formula C-1 to Formula C4, P₁ may be C—* or C(R₇₄), P₂ may be N—* or N(R₈₁), P₃ may be N—* or N(R₈₂), and P₄ may be C—* or C(R₈₈).

In Formula C-1 to Formula C-4, R₇₁ to Rss may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula C-1 to Formula C-4,

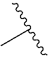

represents a bond to Pt, which is a central metal atom, and —* represents a bond to a neighboring cyclic group (C1 to C4) or to a linking moiety (L₁₁ to L₁₃).

In an embodiment, the light emitting layer EML may include the first compound represented by Formula 1, and at least one of the second compound, the third compound, and the fourth compound. In an embodiment, the light emitting layer EML may include the first compound, the second compound, and the third compound. In the light emitting layer EML, the second compound and the third compound may form an exciplex, and energy may be transferred from the exciplex to the first compound, thereby effecting light emission.

In another embodiment, the light emitting layer EML may include the first compound, the second compound, the third compound, and the fourth compound. In the light emitting layer EML, the second compound and the third compound may form an exciplex, and energy may be transferred from the exciplex to the fourth compound and the first compound, thereby effecting light emission. In an embodiment, the fourth compound may be a sensitizer. The fourth compound included in the light emitting layer EML of the light emitting element ED may serve as a sensitizer that transfers energy from the host (for example, an exciplex host) to the first compound, which is a light emitting dopant. For example, the fourth compound, which serves as an auxiliary dopant, may accelerate energy transfer to the first compound, which serves as a light emitting dopant, thereby increasing an emission ratio of the first compound. Therefore, the light emitting layer EML may exhibit improved luminous efficiency. When energy transfer to the first compound is increased, excitons formed in the light emitting layer EML may not accumulate inside the light emitting layer EML and may rapidly emit light, so that deterioration of the light emitting element ED may be reduced. Accordingly the service life of the light emitting element ED may increase.

The light emitting element ED may include the first compound, the second compound, the third compound, and the fourth compound, and the light emitting layer EML may include the combination of two host materials and two dopant materials. In the light emitting element ED, the light emitting layer EML may include the second compound and the third compound, which are two different hosts, the first compound that emits delayed fluorescence, and the fourth compound that includes an organometallic complex, and thus the light emitting element ED may exhibit excellent luminous efficiency characteristics.

In an embodiment, the fourth compound represented by Formula D-1 may be selected from Compound Group 4. In an embodiment, in the light emitting element ED, the fourth compound may include at least one compound selected from Compound Group 4.

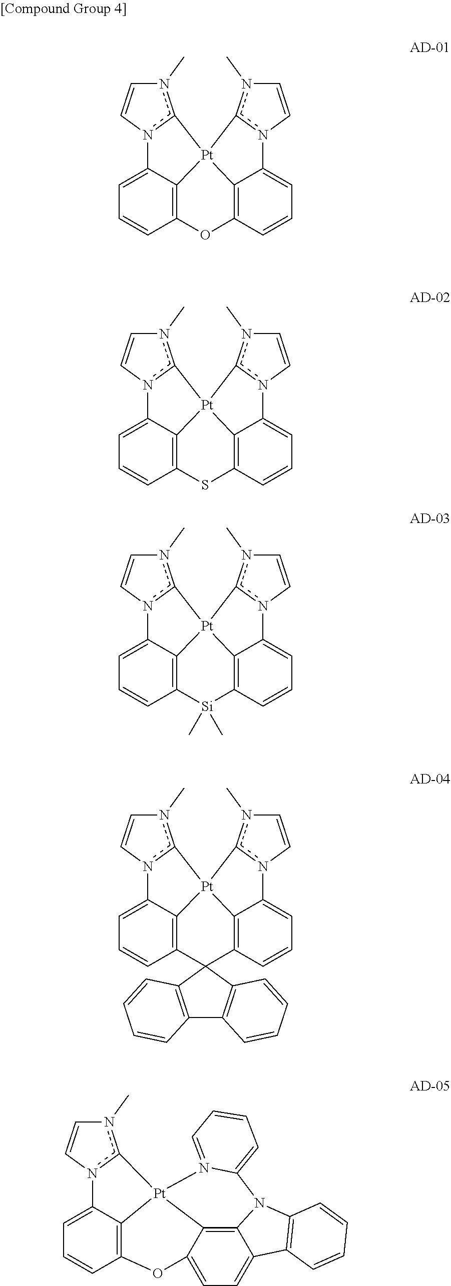

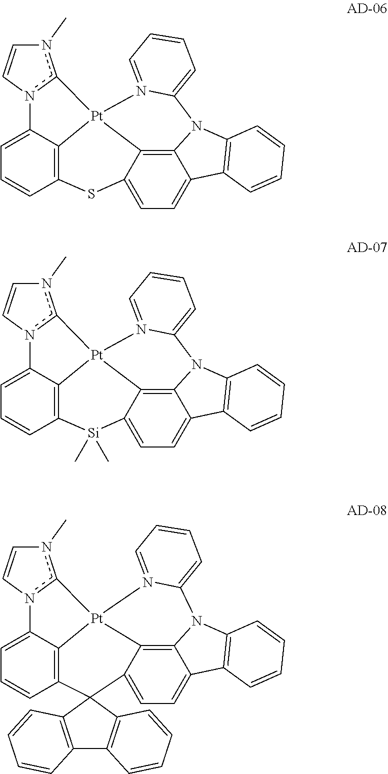

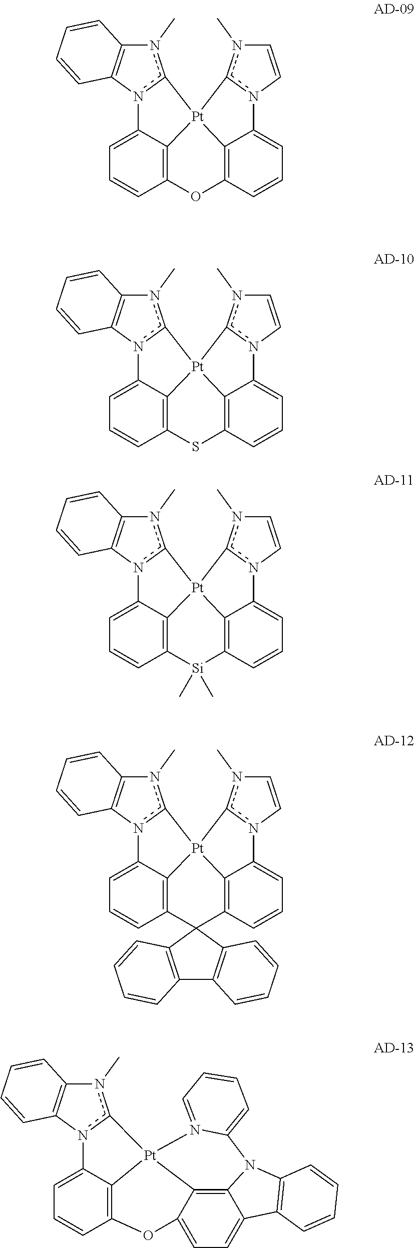

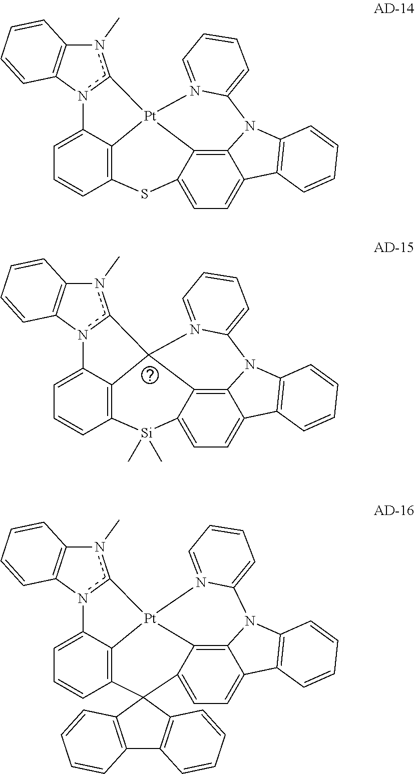

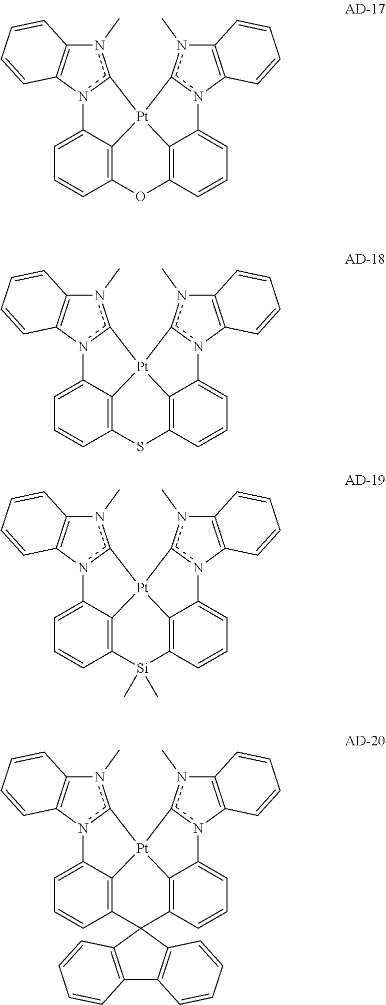

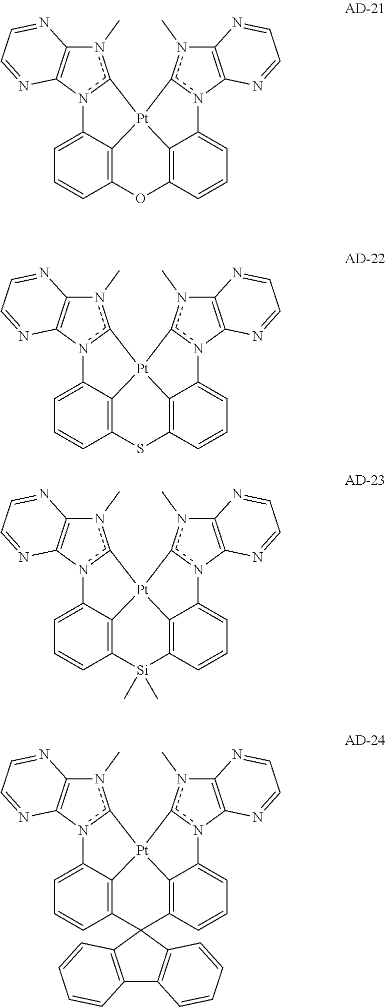

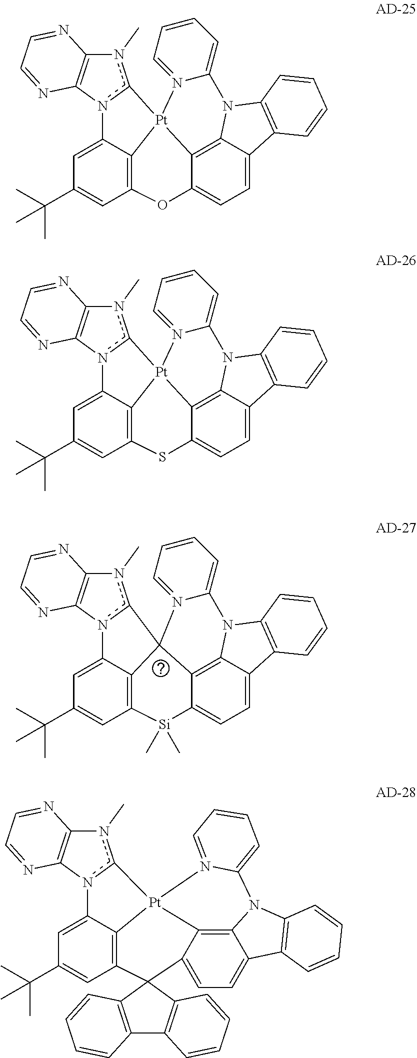

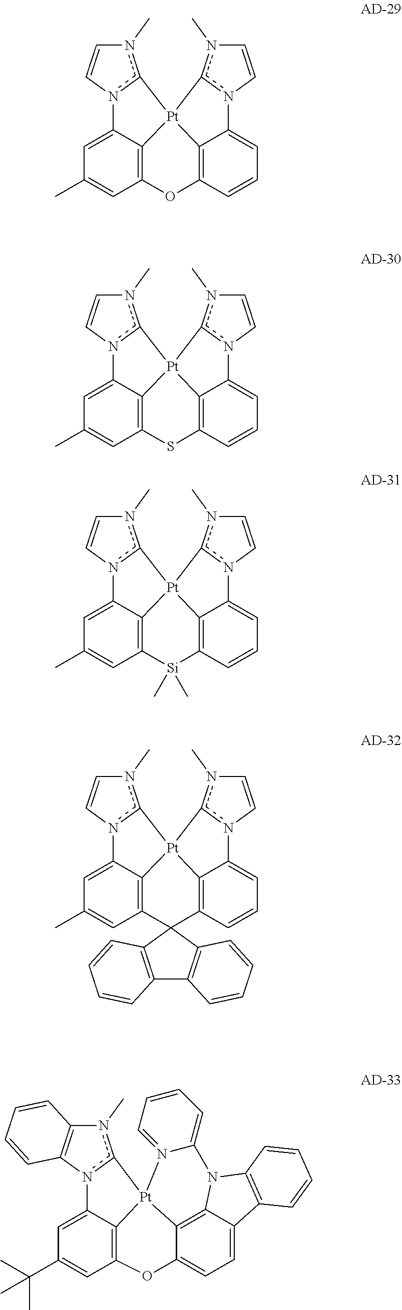

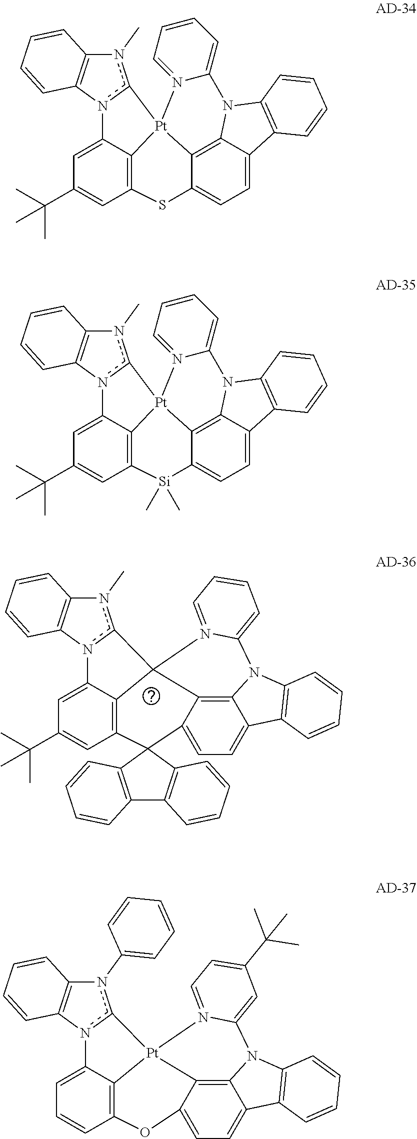

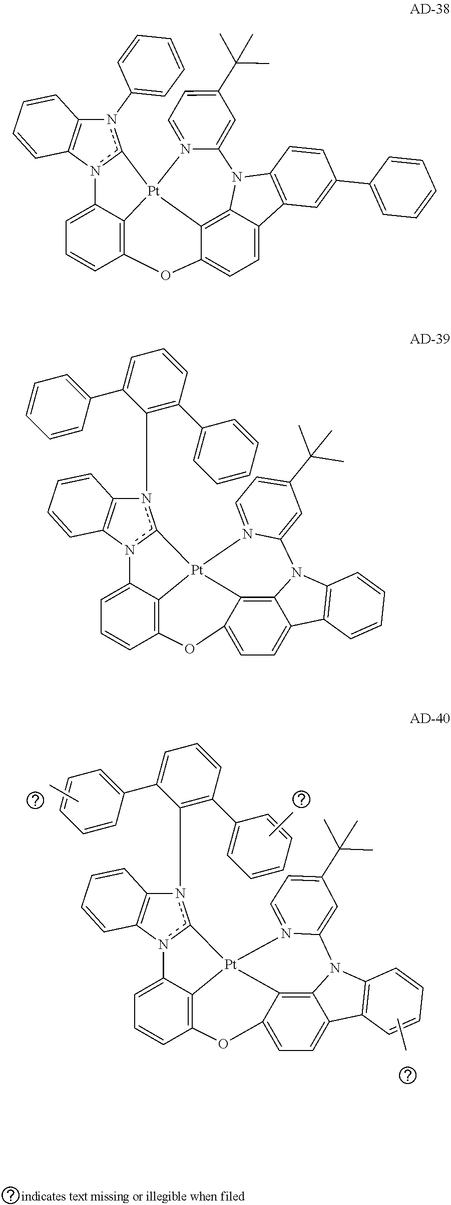

In Compound Group 4, D represents a deuterium atom.

In the light emitting element ED, when the light emitting layer EML includes the first compound, the second compound, and the third compound, an amount of the first compound may be in a range of about 0.1 wt % to about 5 wt %, based on a total weight of the first compound, the second compound, and the third compound. However, embodiments are not limited thereto. When an amount of the first compound satisfies the above-described range, energy transfer from the second compound and the third compound to the first compound may increase, and thus luminous efficiency and service life may increase.

In the light emitting layer EML, a total amount of the second compound and the third compound may be the remainder of the total weight of the first compound, the second compound, and the third compound, excluding the amount of the first compound. For example, a total amount of the second compound and the third compound in the light emitting layer EML may be in a range of about 65 wt % to about 95 wt %, based on a total weight of the first compound, the second compound, and the third compound.

Within the total amount of the second compound and the third compound in the light emitting layer EML, a weight ratio of the second compound to the third compound may be in a range of about 3:7 to about 7:3.

When the amounts of the second compound and the third compound satisfy the above-described ranges and ratios, charge balance characteristics in the light emitting layer EML may be improved, and thus luminous efficiency and service life may increase. When the amounts of the second compound and the third compound deviate from the above-described ranges and ratios, charge balance in the light emitting layer EML may not be achieved, and thus luminous efficiency may be reduced and the device may readily deteriorate.

When the light emitting layer EML includes the fourth compound, an amount of the fourth compound in the light emitting layer EML may be about in a range of about 10 wt % to about 30 wt %, based on a total weight of the first compound, the second compound, the third compound, and the fourth compound. However, embodiments are not limited thereto. When an amount of the fourth compound satisfies the above-described range, energy transfer from the host (for example, an exciplex host) to the first compound, which is a light emitting dopant, may increase, so that an emission ratio may improve. Accordingly, the luminous efficiency of the light emitting layer EML may improve. When the amounts of the first compound, the second compound, the third compound, and the fourth compound included in the light emitting layer EML satisfy the above-described ranges and ratios, excellent luminous efficiency and long service life may be achieved.

The light emitting layer EML may be provided on the hole transport region HTR. The light emitting layer EML may have a thickness in a range of about 100 Å to about 1,000 Å. For example, the light emitting layer EML may have a thickness in a range of about 100 Å to about 300 Å. The light emitting layer EML may be a layer consisting of a single material, a layer including different materials, or a structure including multiple layers including different materials.

In the light emitting element ED, the light emitting layer EML may include an anthracene derivative, a pyrene derivative, a fluoranthene derivative, a chrysene derivative, a dihydrobenzanthracene derivative, or a triphenylene derivative. For example, the light emitting layer EML may include an anthracene derivative or a pyrene derivative.

In the light emitting elements ED according to embodiments as shown in each of FIGS. 3 to 6, the light emitting layer EML may further include a host and a dopant of the related art, in addition to the above-described host and dopant.

In an embodiment, the light emitting layer EML may include a compound represented by Formula E-1. The compound represented by Formula E-1 may be used as a fluorescent host material.

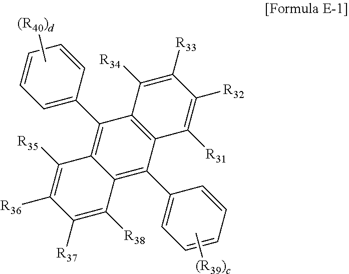

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E19:

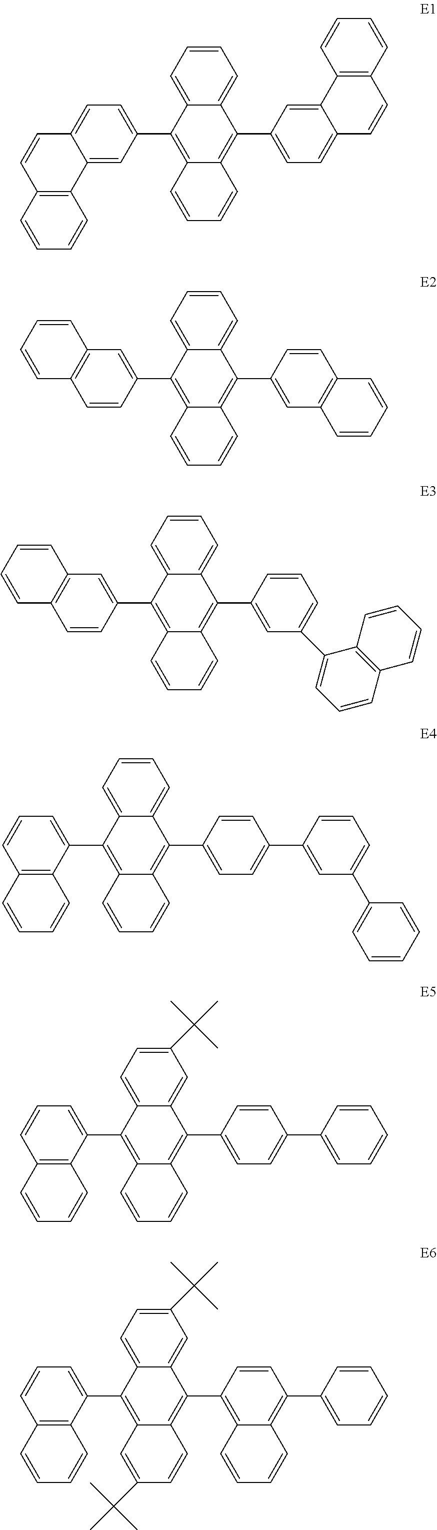

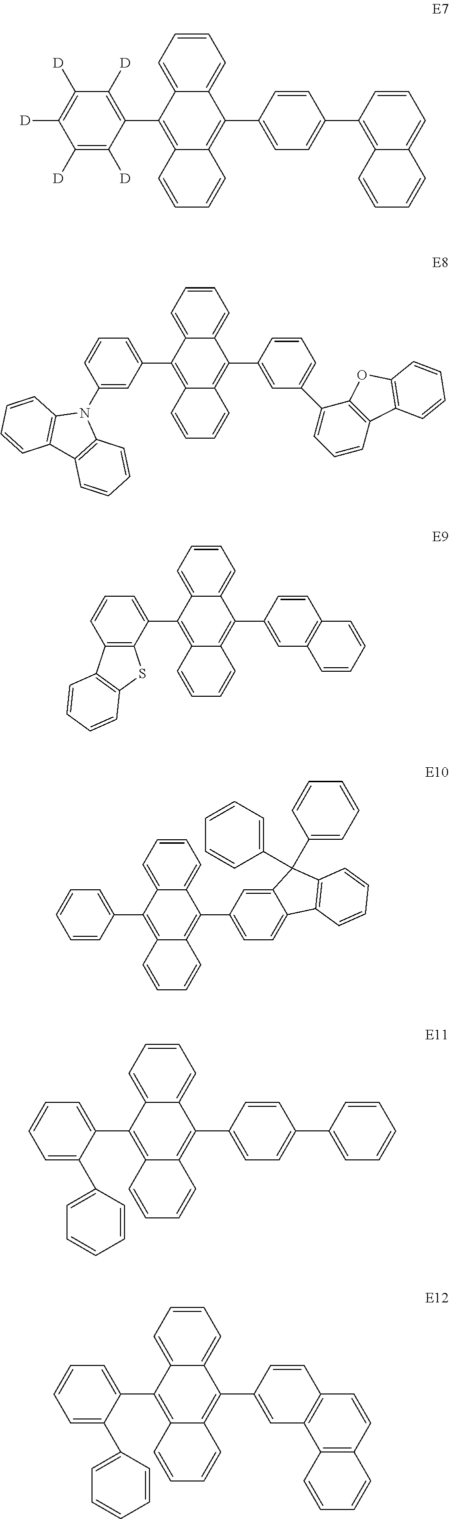

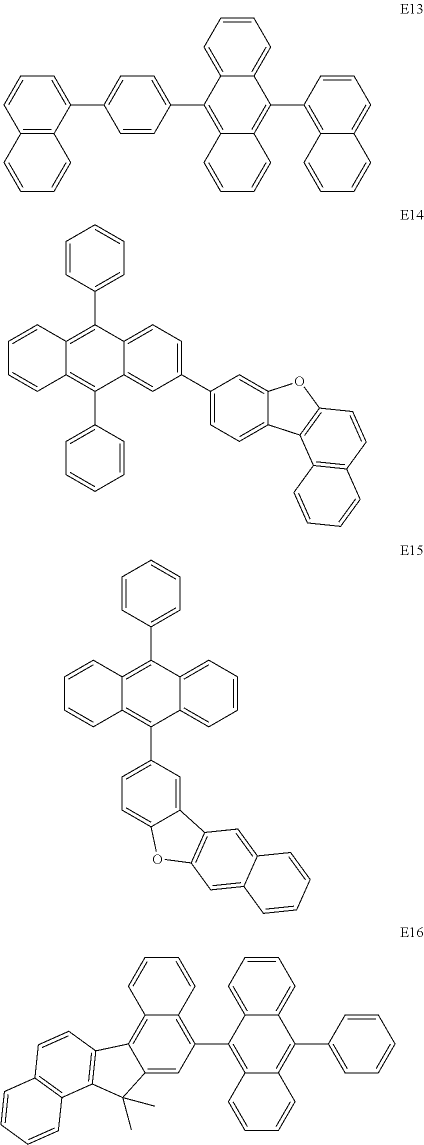

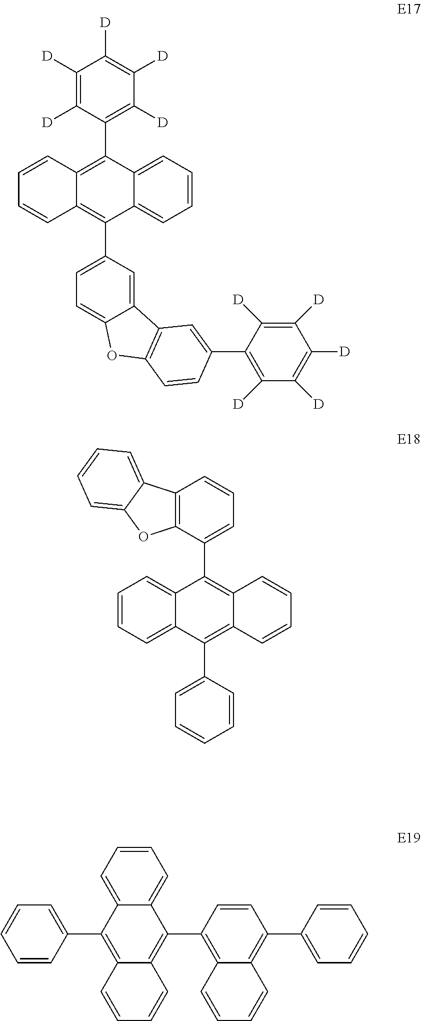

In an embodiment, the light emitting layer EML may include a compound represented by Formula E-2a or Formula E-2b. The compound represented by Formula E-2a or Formula E-2b may be used as a phosphorescent host material.

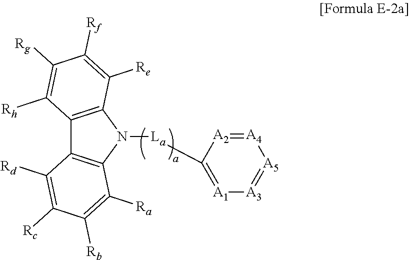

In Formula E-2a, a may be an integer from 0 to 10; and La may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple La groups may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(R₁). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₈ may each be N, and the remainder of A₁ to A₅ may each independently be C(R₁).

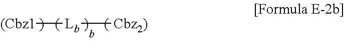

In Formula E-2b, Cbz1 and Cbz2 may each independently be an unsubstituted carbazole group or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10. When b is 2 or more, multiple L_{b} groups may each independently be a substituted or unsubstituted arylene group having 6 to 30 ring-forming carbon atoms or a substituted or unsubstituted heteroarylene group having 2 to 30 ring-forming carbon atoms.

In an embodiment, the compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

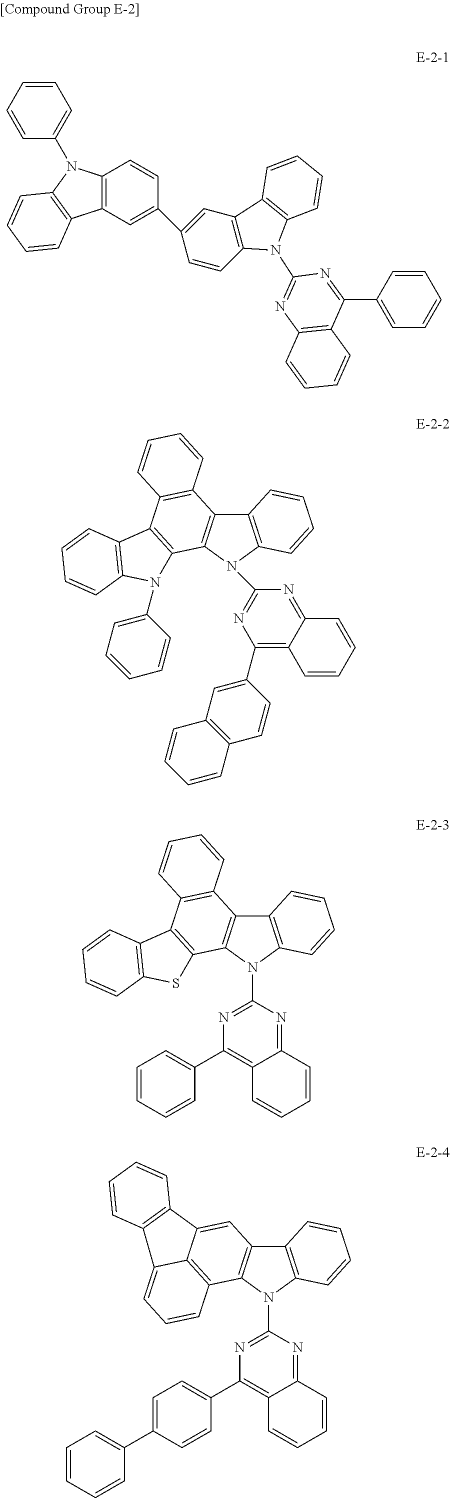 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1 ; c1ccc(-c2ccc(-c3nc(-n4c5ccccc5c5cc6c7c(cccc7c54)-c4ccccc4-6)nc4ccccc34)cc2)cc1]

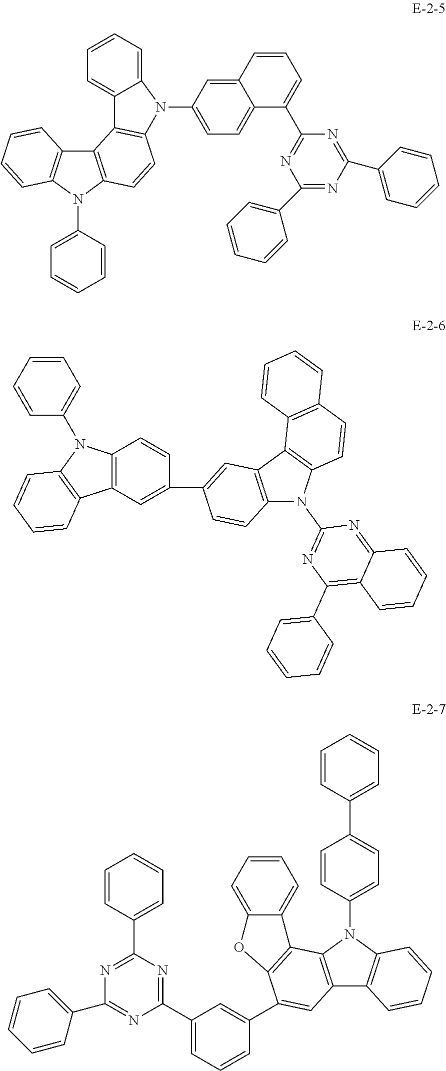 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1]

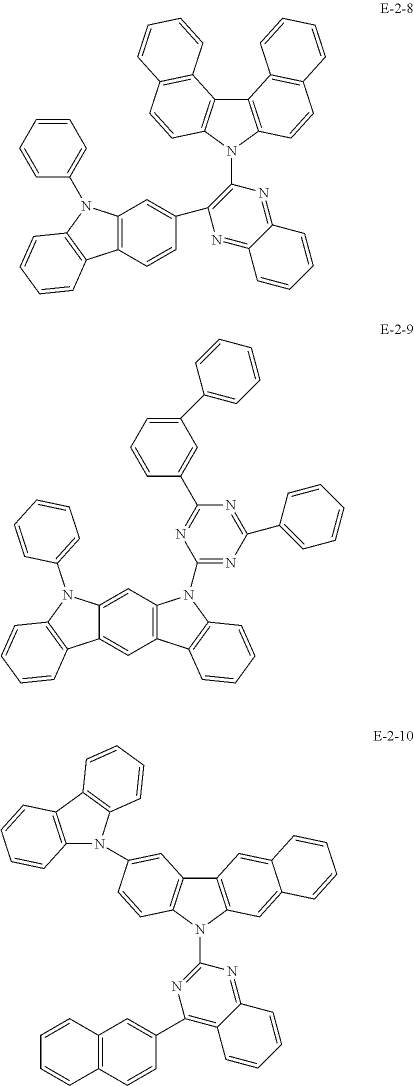 [SMILES: c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1]

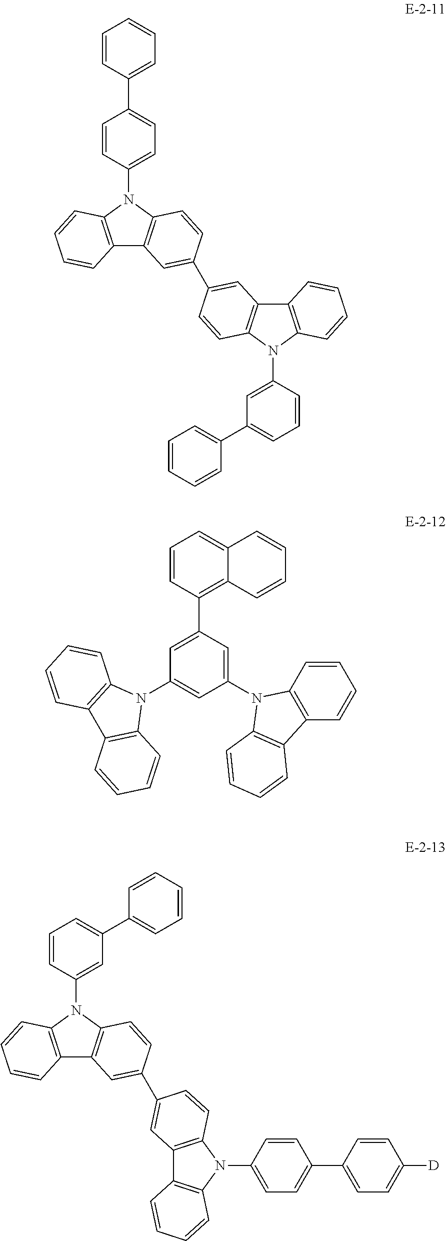 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1]

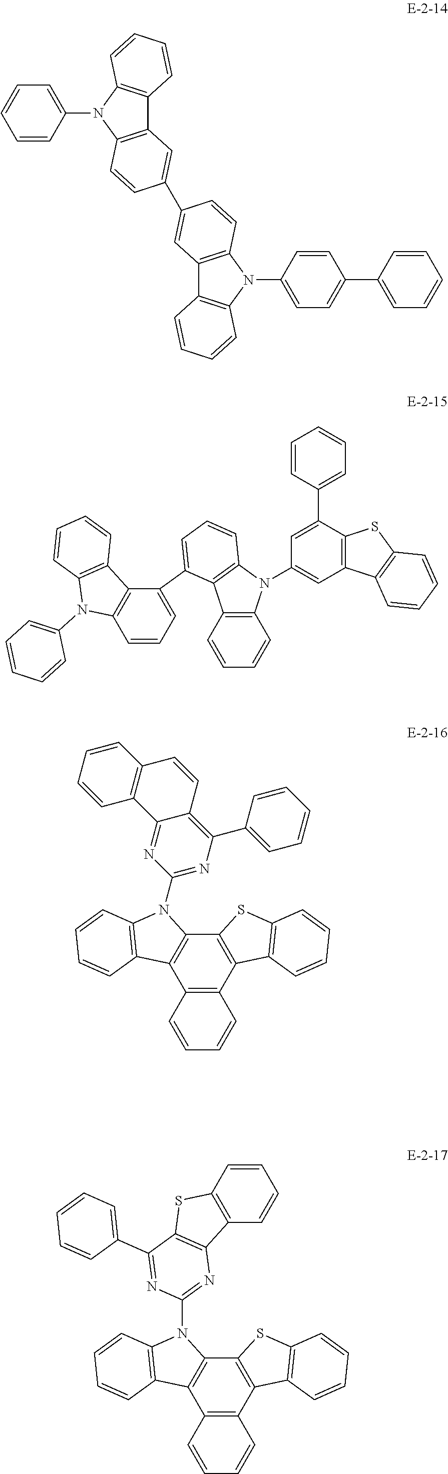 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1]

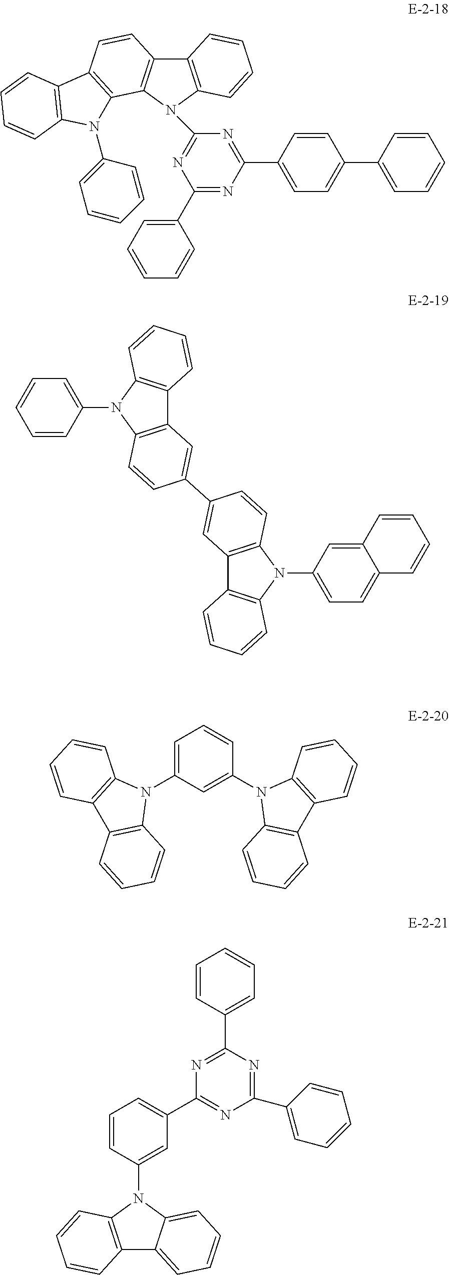 [SMILES: c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

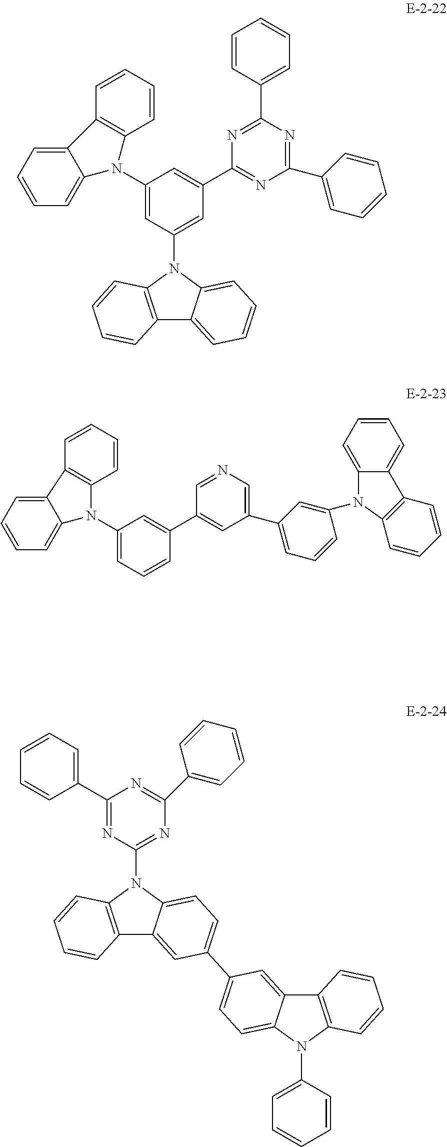 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The light emitting layer EML may further include a material of the related art as a host material. For example, the light emitting layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)triphenylamine (TCTA), and 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

In an embodiment, the light emitting layer EML may include a compound represented by Formula M-a. The compound represented by Formula M-a may be used as a phosphorescent dopant material.

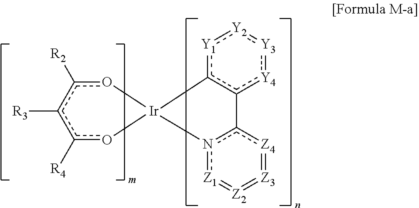

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, when m is 0, n may be 3, and when m is 1, n may be 2.

In an embodiment, the compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

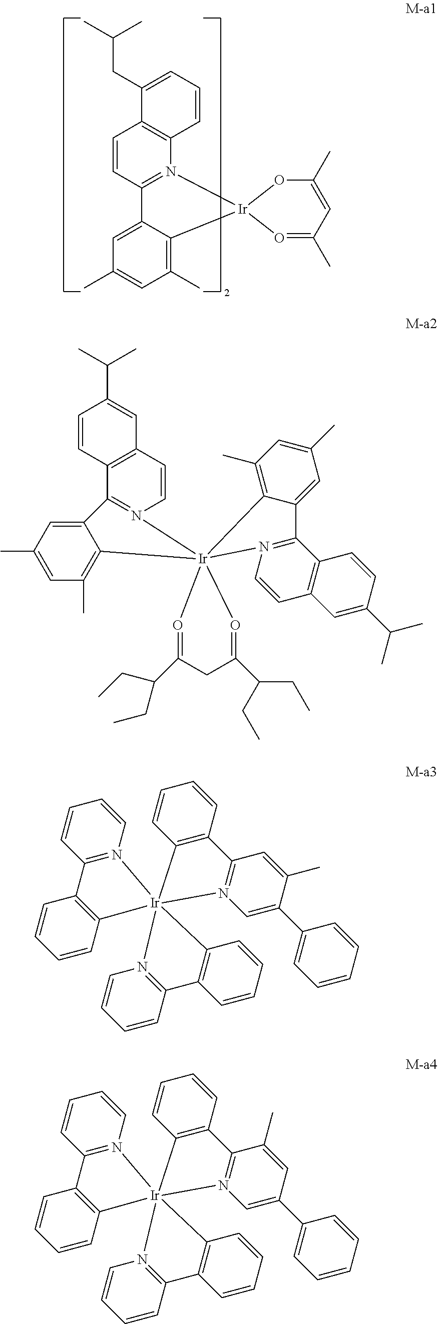

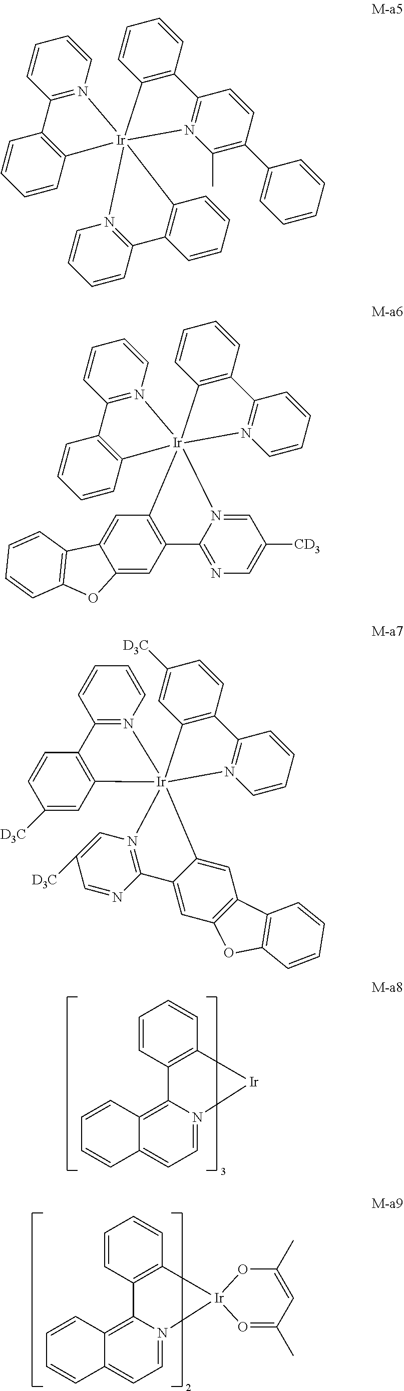

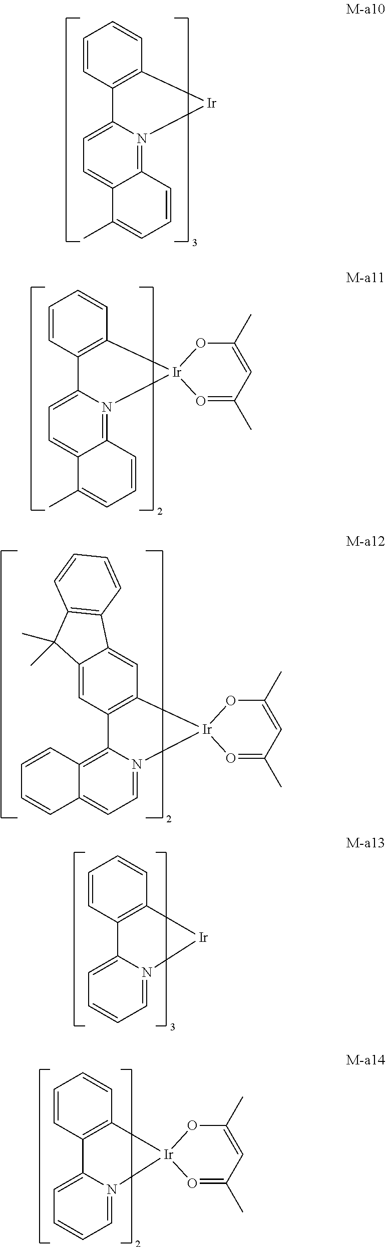

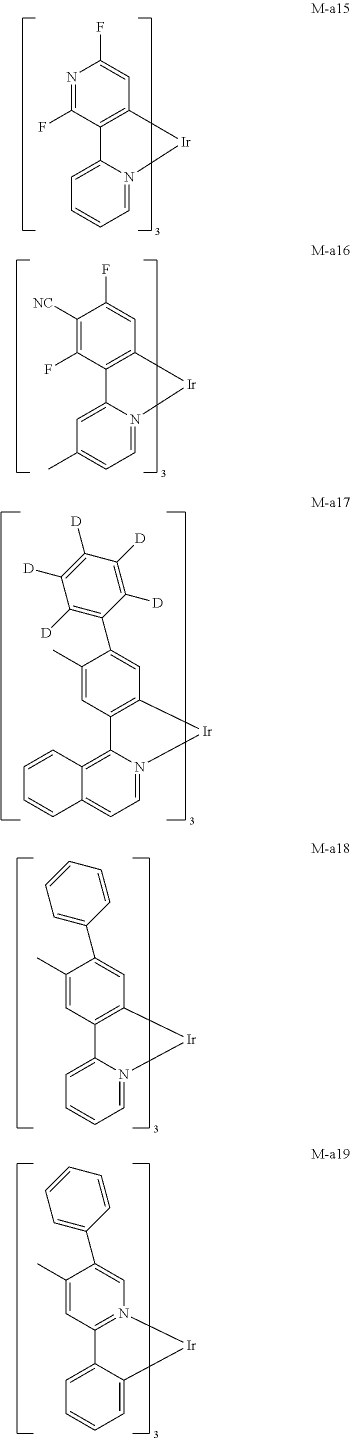

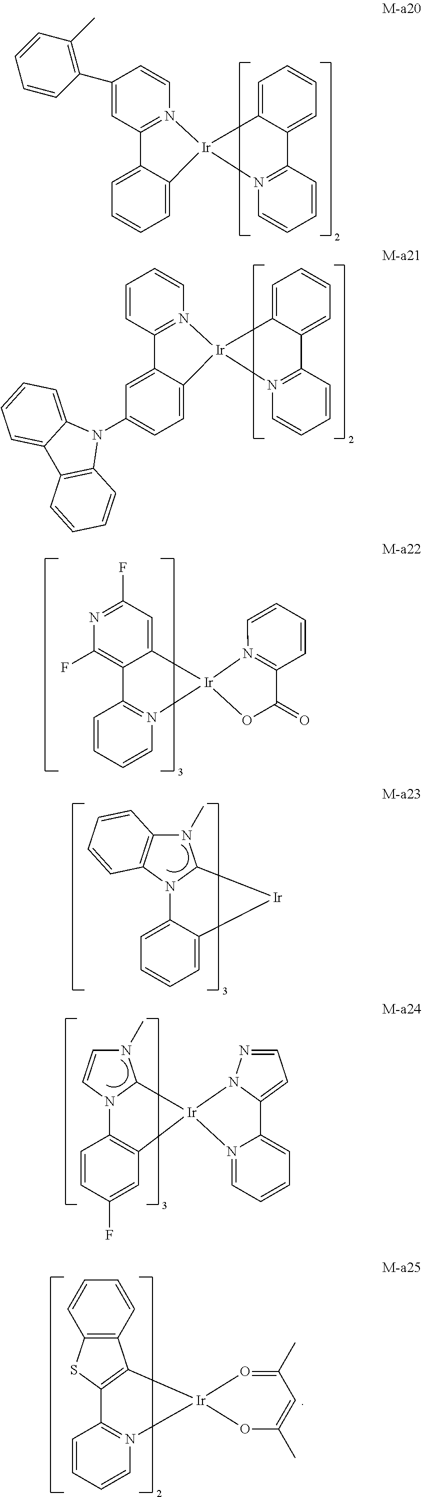

In an embodiment, the light emitting layer EML may include a compound represented by one of Formula F-a to Formula F-c. The compound represented by one of Formula F-a to Formula F-c may be used as a fluorescence dopant material.

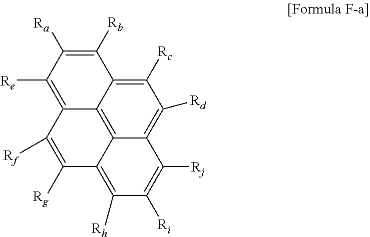

In Formula F-a, two of Rₐ to Rⱼ may each independently be substituted with a group represented by *—N₁N2. The remainder of Rₐ to Rⱼ that are not substituted with the group represented by *—N₁N₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by *—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ and Ar₂ may each independently be a heteroaryl group containing O or S as a ring-forming atom.

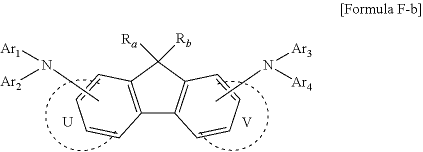

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ to Ar₄ may each independently be a heteroaryl group containing O or S as a ring-forming atom.

In Formula F-b, U and V may each independently be a substituted or unsubstituted hydrocarbon ring group having 5 to 30 ring-forming carbon atoms or a substituted or unsubstituted heterocyclic group having 2 to 30 ring-forming carbon atoms.

In Formula F-b, the number of rings represented by U and V may each independently be 0 or 1. When the number of U or V is 1, a fused ring may be present at a portion indicated by U or V, and when the number of U or V is 0, a fused ring may not be present at the portion indicated by U or V. When the number of U is 0 and the number of V is 1, or when the number of U is 1 and the number of V is 0, a fused ring having the fluorene core of Formula F-b may be a cyclic compound having four rings. When the number of U and V is each 0, a fused ring having the fluorene core of Formula F-b may be a cyclic compound having three rings. When the number of U and V is each 1, a fused ring having the fluorene core of Formula F-b may be a cyclic compound having five rings.

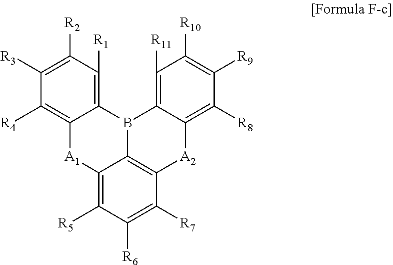

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula F-c, A₁ and A₂ may each independently be bonded to a substituent of an adjacent ring to form a fused ring. For example, when A₁ and A₂ are each independently N(Rₘ), A₁ may be bonded to R₄ or R₈ to form a ring. For example, A₂ may be bonded to R₇ or R₈ to form a ring.

In an embodiment, the light emitting layer EML may further include, as a dopant material of the related art, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi), perylene or a derivative thereof (e.g., 2,5,8,11-tetra-t-butylperylene (TBP)), pyrene or a derivative thereof (e.g., 1,1′-dipyrene, 1,4-dipyrenylbenzene, 1,4-bis(N,N-diphenylamino)pyrene), etc.

The light emitting layer EML may further include a phosphorescence dopant material of the related art. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, bis(4,6-difluorophenylpyridinato-N,C2) picolinato iridium(III) (FIrpic), bis(2,4-difluorophenylpyridinato)-tetrakis(1-pyrazolyl)borate iridium(III) (FIr6), or platinum octaethyl porphyrin (PtOEP) may be used as a phosphorescent dopant. However, embodiments are not limited thereto.

In an embodiment, the light emitting layer EML may include a quantum dot material. The quantum dot may be a Group II-VI compound, a Group III-VI compound, a Group I—III-VI compound, a Group III-V compound, a Group III—II-V compound, a Group IV-VI compound, a Group IV element, a Group IV compound, or a combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, a quaternary compound selected from the group consisting of CdZnSeS, CdZnSeTe, CdZnSTe, CdHgSeS, CdHgSeTe, CdHgSTe, HgZnSeS, HgZnSeTe, HgZnSTe, and a mixture thereof, or any combination thereof.

Examples of a Group III-VI compound may include: a binary compound such as In₂S₃ or In₂Se₃; a ternary compound such as InGaS₃ or InGaSe₃; or any combination thereof.

Examples of a Group I—III-VI compound may include: a ternary compound selected from the group consisting of AgInS, AgInS₂, CuInS, CuInS₂, AgGaS₂, CuGaS₂ CuGaO₂, AgGaO₂, AgAlO₂, and a mixture thereof, a quaternary compound such as AgInGaS₂ or CuInGaS₂; or any combination thereof.

Examples of a Group III-V compound may include: a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof, or any combination thereof. In an embodiment, a Group III-V compound may further include a Group II element. Examples of a Group III—II-V compound may include InZnP, etc.

Examples of a Group IV-VI compound may include: a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; or any combination thereof.

Examples of a Group IV element may include Si, Ge, and a mixture thereof. Examples of a Group IV compound may include a binary compound selected from the group consisting of SiC, SiGe, and a mixture thereof.

Each element included in a compound such as a binary compound, a ternary compound, or a quaternary compound, may be present in a particle at a uniform concentration distribution or at a non-uniform concentration distribution. For example, a formula may indicate the elements that are included in a compound, but an elemental ratio in the compound may vary. For example, AgInGaS₂ may be represented by AgInₓGa₁₋ₓS₂ (0<x<1).

In embodiments, a quantum dot may have a single structure in which the concentration of each element included in the quantum dot is uniform, or a quantum dot may have a core-shell structure in which a quantum dot surrounds another quantum dot. In an embodiment, a material included in the core may be different from a material included in the shell.

The shell of the quantum dot may serve as a protection layer that prevents chemical deformation of the core to maintain semiconductor properties, and/or may serve as a charging layer that imparts electrophoretic properties to the quantum dot. The shell may be a single layer or multiple layers. An interface between the core and the shell may have a concentration gradient in which the concentration of an element that is present in the shell decreases towards the center of core.

An example of a quantum dot shell may include a metal oxide, a non-metal oxide, a semiconductor compound, or a combination thereof.

Examples of a metal oxide or a non-metal oxide may include: a binary compound such as SiO₂, A₁₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission spectrum equal to or less than about 45 nm. For example, the quantum dot may have a FWHM of an emission spectrum equal to or less than about 40 nm. For example, the quantum dot may have a FWHM of an emission spectrum equal to or less than about 30 nm. Color purity or color reproducibility may be improved in any of the above ranges. Light emitted through a quantum dot may be emitted in all directions, so that a wide viewing angle may be improved.

The form of a quantum dot may be any shape that is used in the related art. For example, a quantum dot may have a spherical shape, a pyramidal shape, a multi-arm shape, or a cubic shape, the quantum dot may be in the form of nanoparticles, nanotubes, nanowires, nanofibers, nanoplate, etc.

As a size of a quantum dot is adjusted or an elemental ratio of a quantum dot compound is adjusted, the energy band gap may be controlled accordingly, and thus light in various wavelength ranges may be obtained from a quantum dot light emitting layer. Therefore, by using as quantum dot as described above (by using different sizes of quantum dots or by changing elemental ratios in a quantum dot compound), a light emitting element that emits light in various wavelength ranges may be implemented. For example, the size of a quantum dot or an elemental ratio in a quantum dot compound may be adjusted to emit red light, green light, and/or blue light. In an embodiment, quantum dots may be configured to emit white light by combining various colors of light.

In the light emitting elements ED according to embodiments as shown in each of FIGS. 3 to 6, the electron transport region ETR may be provided on the light emitting layer EML. The electron transport region ETR may include at least one of a hole blocking layer HBL, an electron transport layer ETL, and an electron injection layer EIL, but embodiments are not limited thereto.

The electron transport region ETR may be a layer consisting of a single material, a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In embodiments, the electron transport region ETR may have a single layer structure formed of different materials, or may have a structure in which an electron transport layer ETUelectron injection layer EIL, or a hole blocking layer HBUelectron transport layer ETUelectron injection layer EIL are stacked in its respective stated order from the light emitting layer EML, but embodiments are not limited thereto. The electron transport region ETR may have a thickness, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-2.

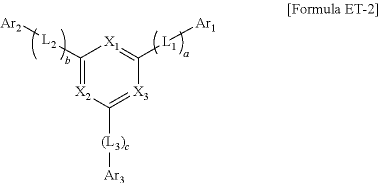

In Formula ET-2, at least one of X₁ to X₃ may each be N, and the remainder of X₁ to X₃ may each independently be C(Rₐ). In Formula ET-2, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or more, multiple groups of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N 1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or a mixture thereof.

In an embodiment, the electron transport region ETR may include at least one compound selected from Compound ET1 to Compound ET36.

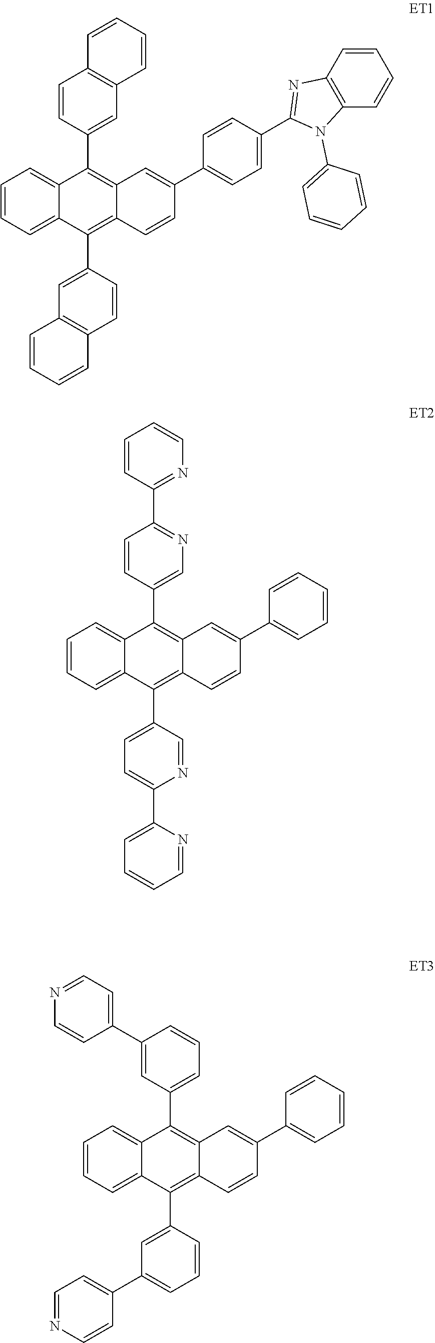 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

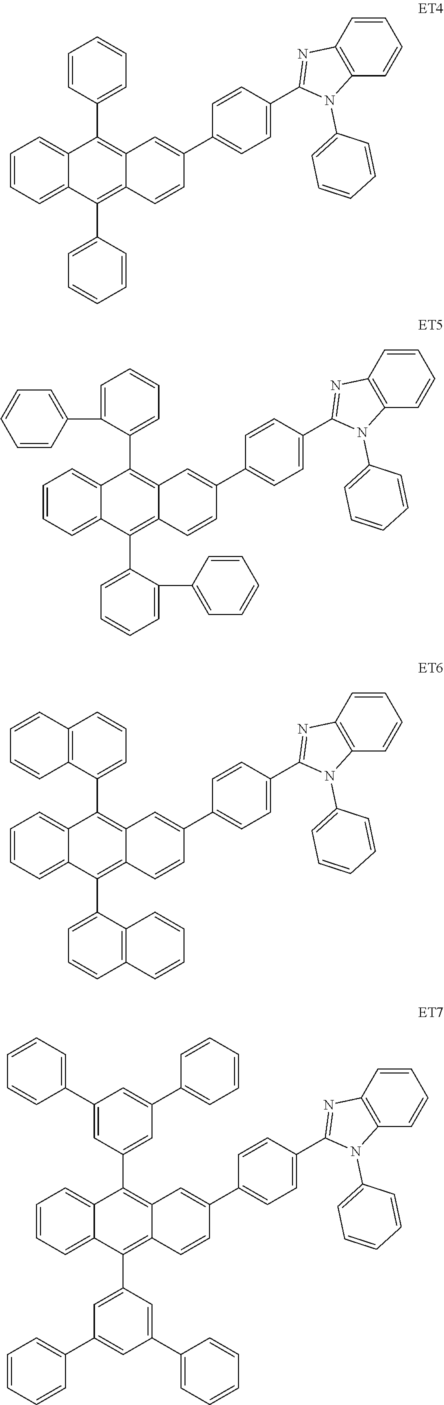 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

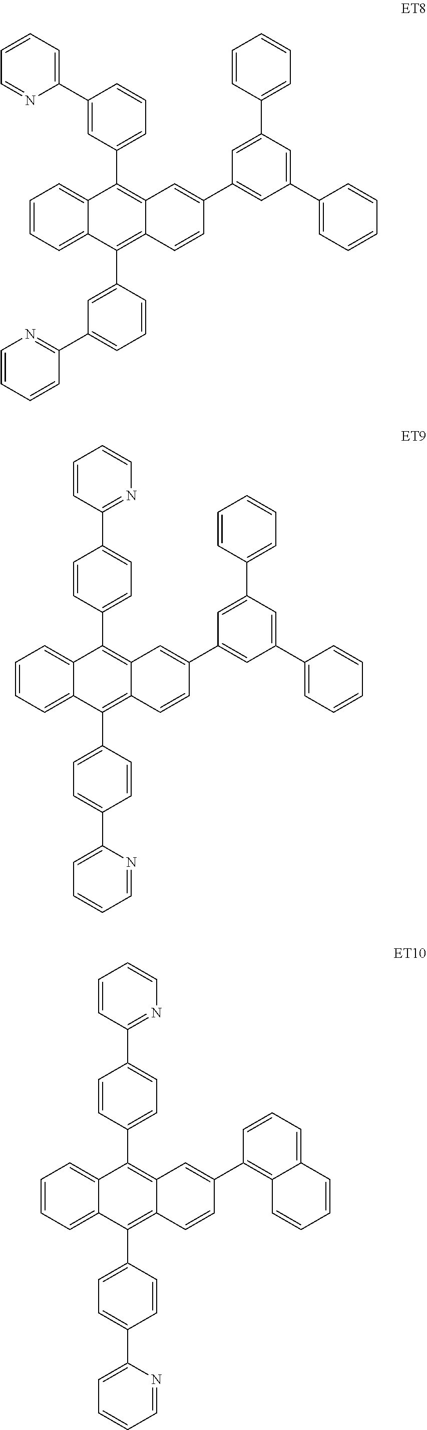 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

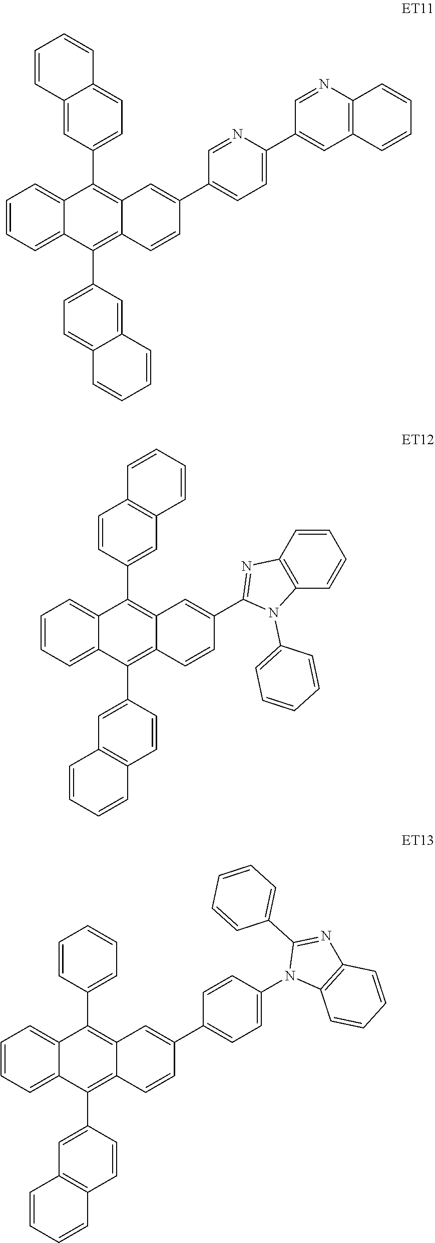 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

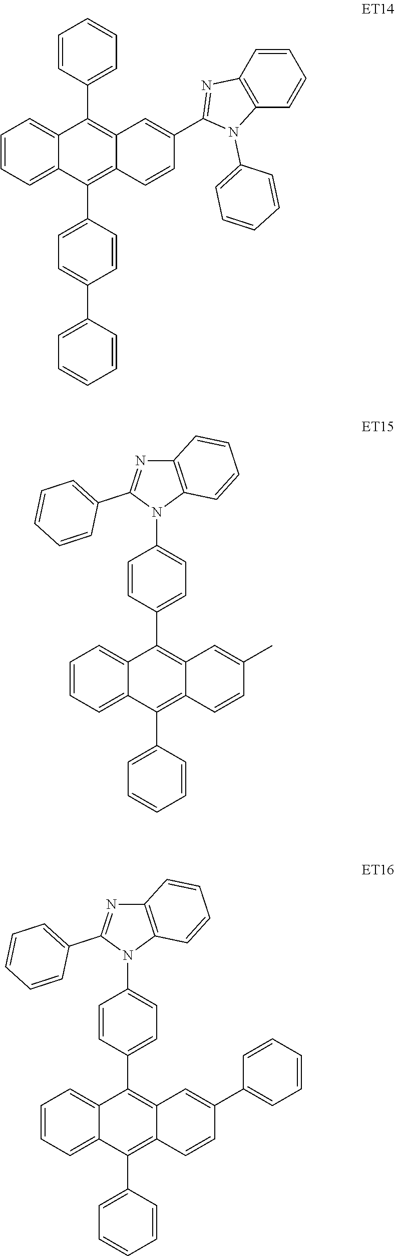 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

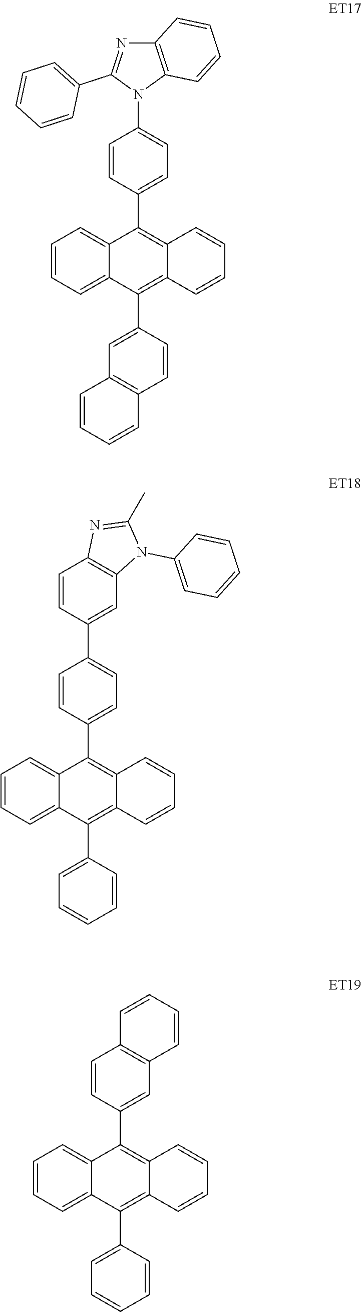

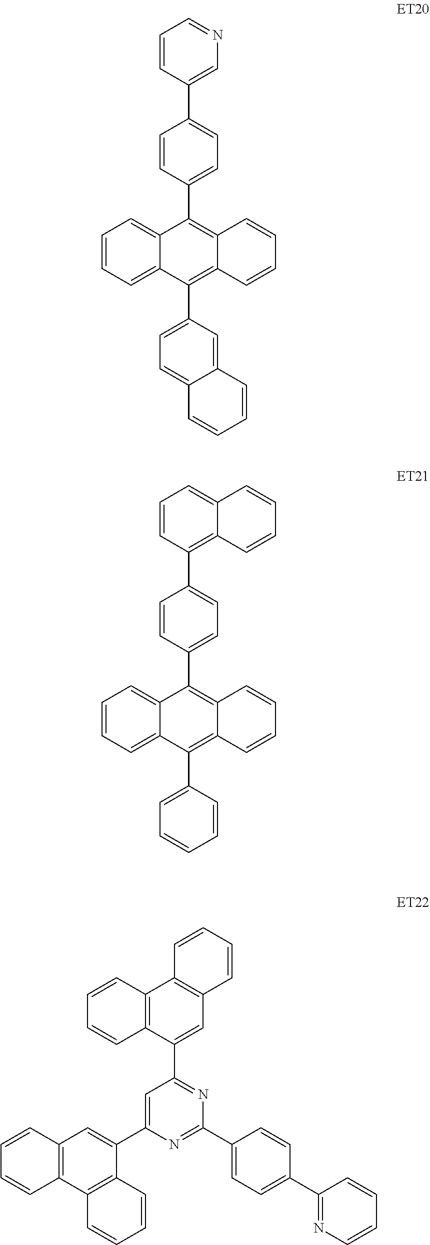

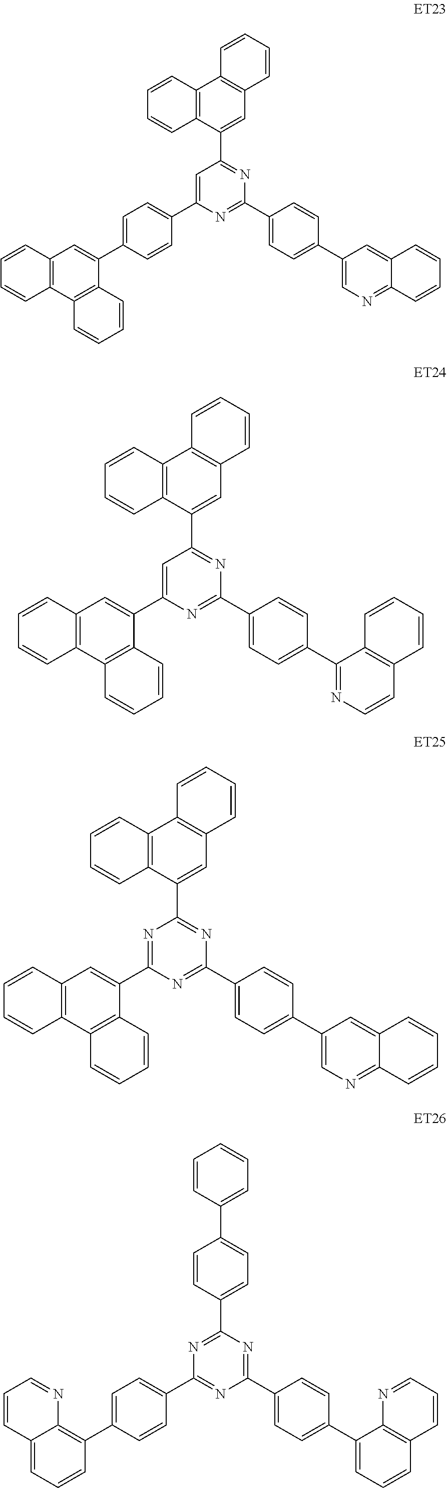 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

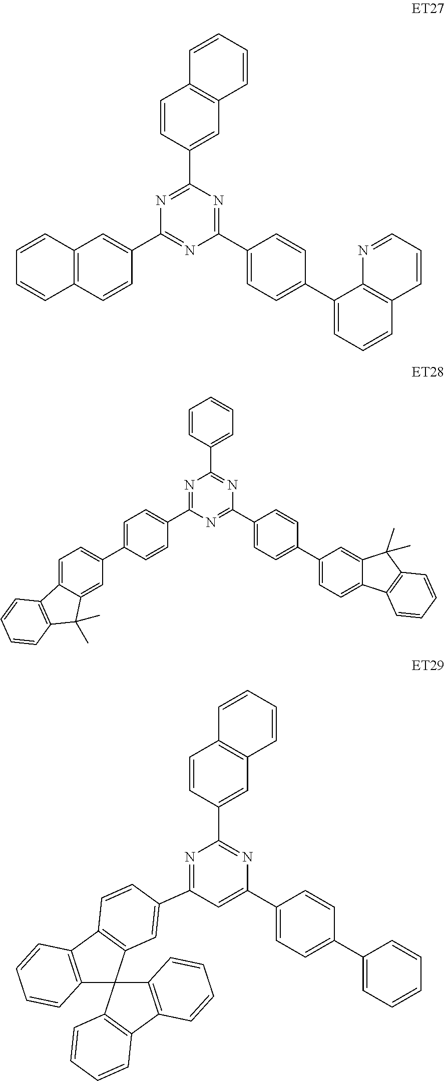 [SMILES: c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

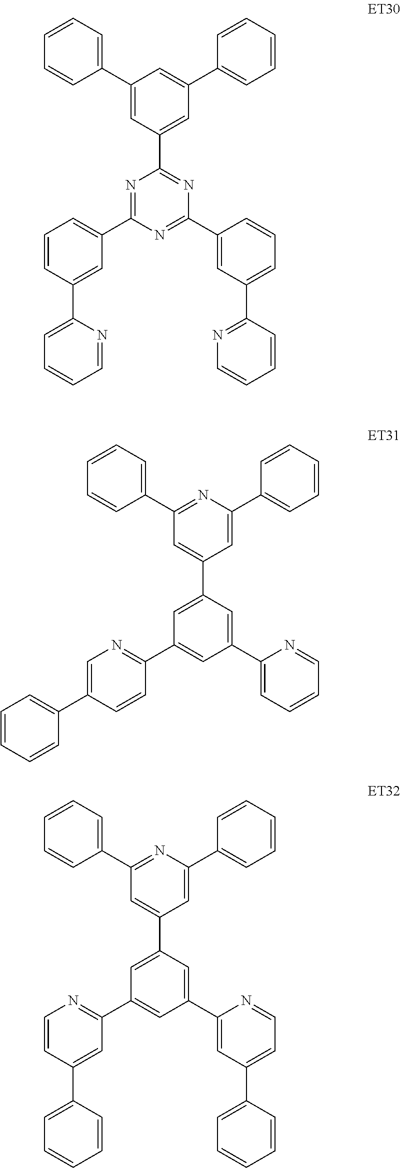 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

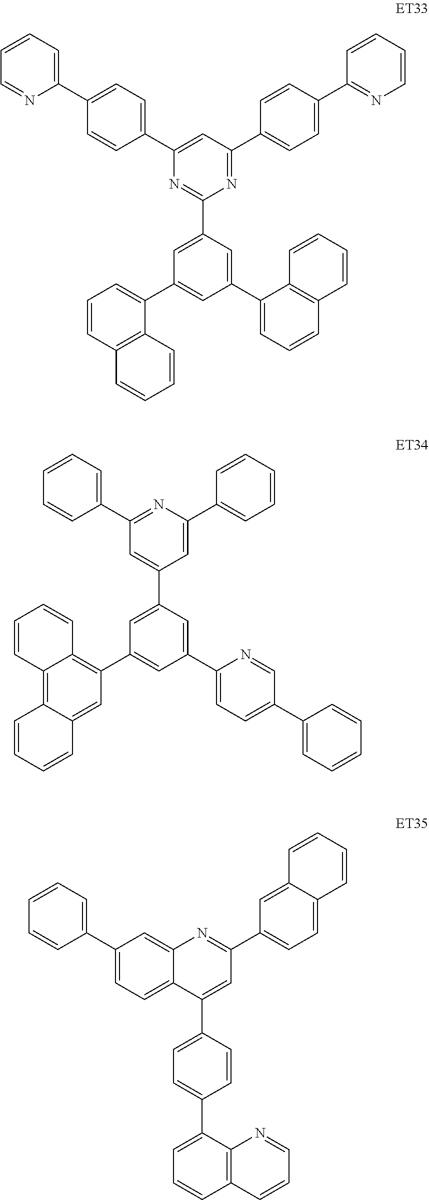 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1]

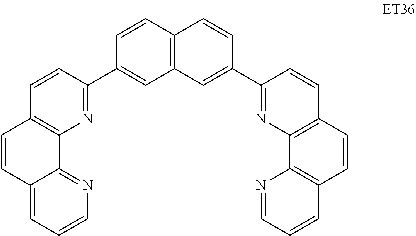 [SMILES: c1cnc2c(c1)ccc1ccc(-c3ccc4ccc(-c5ccc6ccc7cccnc7c6n5)cc4c3)nc12]

In an embodiment, the electron transport region ETR may include a metal halide such as LiF, NaCl, CsF, RbCl, RbI, CuI, and KI; a lanthanide metal such as Yb; or a co-deposited material of a metal halide and a lanthanide metal. For example, the electron transport region ETR may include KI:Yb, RbI:Yb, LiF:Yb, etc., as a co-deposited material. The electron transport region ETR may include a metal oxide such as Li₂O or BaO, or 8-hydroxyl-lithium quinolate (Liq), etc., but embodiments are not limited thereto. In an embodiment, the electron transport region ETR may be formed of a mixture material of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen), in addition to the above-described materials. However, embodiments are not limited thereto.

The electron transport region ETR may include the above-described compounds of the electron transport region ETR in at least one of an electron injection layer EIL, an electron transport layer ETL, and a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may include a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al , Mo, Ti, Yb, W, a compound thereof, or a mixture thereof (e.g., AgMg, AgYb, or MgYb). In an embodiment, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, resistance of the second electrode EL2 may decrease.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL includes an inorganic material, the inorganic material may include an alkaline metal compound (e.g., LiF), an alkaline earth metal compound (e.g., MgF₂), SiON, SiNx, SiOy, etc.

For example, when the capping layer CPL includes an organic material, the organic material may include α-NPD, NPB, TPD, m-MTDATA, Alq3, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or may include an epoxy resin, or an acrylate such as methacrylate. However, embodiments are not limited thereto. In an embodiment, the capping layer CPL may include at least one of Compounds P1 to P5.

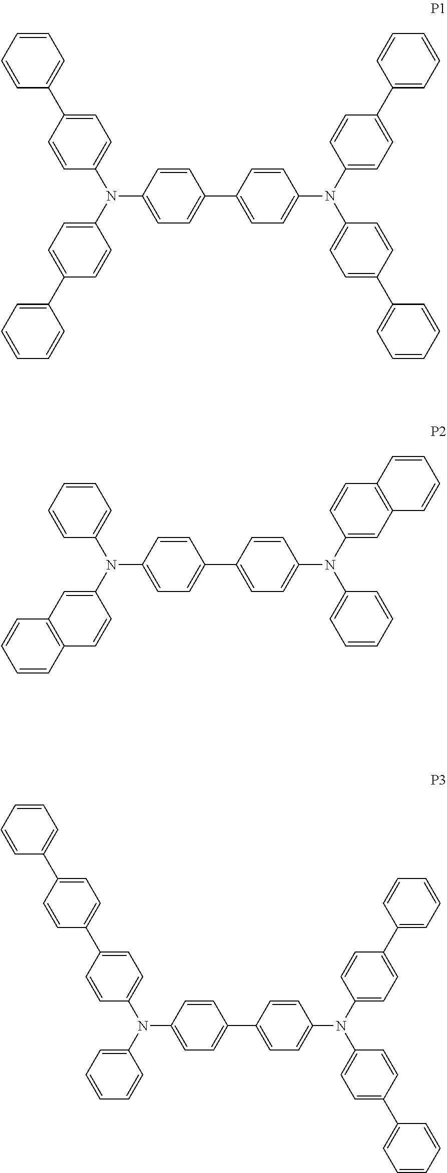 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

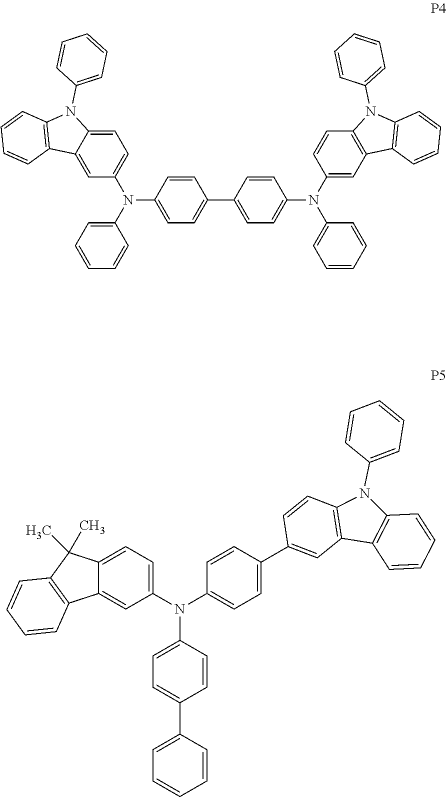 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL may be equal to or greater than about 1.6, with respect to light in a wavelength range of about 550 nm to about 660 nm.

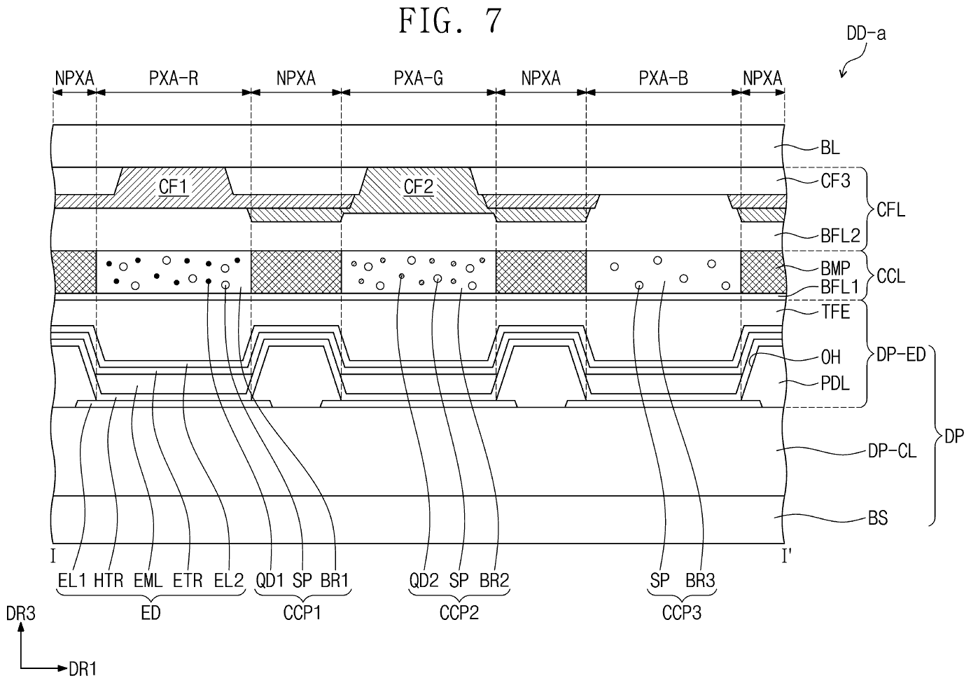

FIGS. 7 to 10 are each a schematic cross-sectional view of a display device according to an embodiment. Hereinafter, in describing the display devices according to embodiments as shown in FIGS. 7 to 10, the features which have been described above with respect to FIGS. 1 to 6 will not be explained again, and the differing features will be described.

Referring to FIG. 7, the display device DD-a according to an embodiment may include a display panel DP including a display device layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and the display device layer DP-ED, and the display device layer DP-ED may include a light emitting element ED.

The light emitting element ED may include a first electrode EL1, a hole transport region HTR disposed on the first electrode EL1, a light emitting layer EML disposed on the hole transport region HTR, an electron transport region ETR disposed on the light emitting layer EML, and a second electrode EL2 disposed on the electron transport region ETR. In embodiments, a structure of the light emitting element ED shown in FIG. 7 may be the same as a structure of a light emitting element ED according to one of FIGS. 3 to 6 as described above.

The light emitting element ED illustrated in FIG. 7 includes a polycyclic compound according to an embodiment, and thus, may exhibit high-luminous efficiency and long-lifespan properties.

Referring to FIG. 7, the light emitting layer EML may be disposed in an opening OH defined in a pixel defining film PDL. For example, the light emitting layer EML, which is separated by the pixel defining film PDL and correspondingly provided to each of the light emitting regions PXA-R, PXA-G, and PXA-B, may emit light in a same wavelength range. In the display device DD-a, the light emitting layer EML may emit blue light. Although not shown in the drawings, in an embodiment, the light emitting layer EML may be provided as a common layer for each of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and emit the resulting light. For example, the light control layer CCL may be a layer that includes a quantum dot or a layer that includes a phosphor.

The light control layer CCL may include light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3 which are spaced apart from each other, but embodiments are not limited thereto. In FIG. 7, it is shown that the divided patterns BMP do not overlap the light control parts CCP1, CCP2, and CCP3, but the edges of the light control parts CCP1, CCP2, and CCP3 may overlap at least a portion of the divided patterns BMP.

The light control layer CCL may include a first light control part CCP1 including a first quantum dot QD1 that converts first color light provided from the light emitting element ED into second color light, a second light control part CCP2 including a second quantum dot QD2 that converts the first color light into third color light, and a third light control part CCP3 that transmits the first color light.

In an embodiment, the first light control part CCP1 may provide red light, which is the second color light, and the second light control part CCP2 may provide green light, which is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The quantum dots QD1 and QD2 may each be a quantum dot as described above.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include a quantum dot but may include the scatterer SP.

The scatterer SP may be inorganic particles. For example, the scatterer SP may include at least one of TiO₂, ZnO, A₁₂O₃, SiO₂, and hollow sphere silica. The scatterer SP may include one of TiO₂, ZnO, A₁₂O₃, SiO₂, and hollow sphere silica, or may be a mixture of at least two materials selected from TiO₂, ZnO, A₁₂O₃, SiO₂, and hollow sphere silica.

The first light control part CCP1, the second light control part CCP2, and the third light control part CCP3 may include base resins BR1, BR2, and BR3, in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may block the light control parts CCP1, CCP2, and CCP3 from exposure to moisture/oxygen. The barrier layer BFL1 may cover the light control parts CCP1, CCP2, and CCP3. In an embodiment, a barrier layer BFL2 may be provided between the light control parts CCP1, CCP2, and CCP3 and filters CF1, CF2, and CF3.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures light transmittance, etc. The barrier layers BFL1 and BFL2 may each independently further include an organic layer. The barrier layers BFL1 and BFL2 may each be formed of a single layer or formed of multiple layers.

In the display device DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include filters CF1, CF2, and CF3. The color filter layer CFL may include a first filter CF1 that transmits the second color light, a second filter CF2 that transmits the third color light, and a third filter CF3 that transmits the first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be provided as separate filters but may be provided as a unitary filter.

Although not shown in the drawings, the color filter layer CFL may further include a light shielding part (not shown). The light shielding part (not shown) may be a black matrix. The light shielding part (not shown) may include an organic light shielding material or an inorganic light shielding material, each including a black pigment or a black dye. The light shielding part (not shown) may prevent light leakage, and may separate filters CF1, CF2, and CF3.

The first to third filters CF1, CF2, and CF3 may be disposed to respectively correspond to the red light emitting region PXA-R, the green light emitting region PXA-G, and the blue light emitting region PXA-B.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

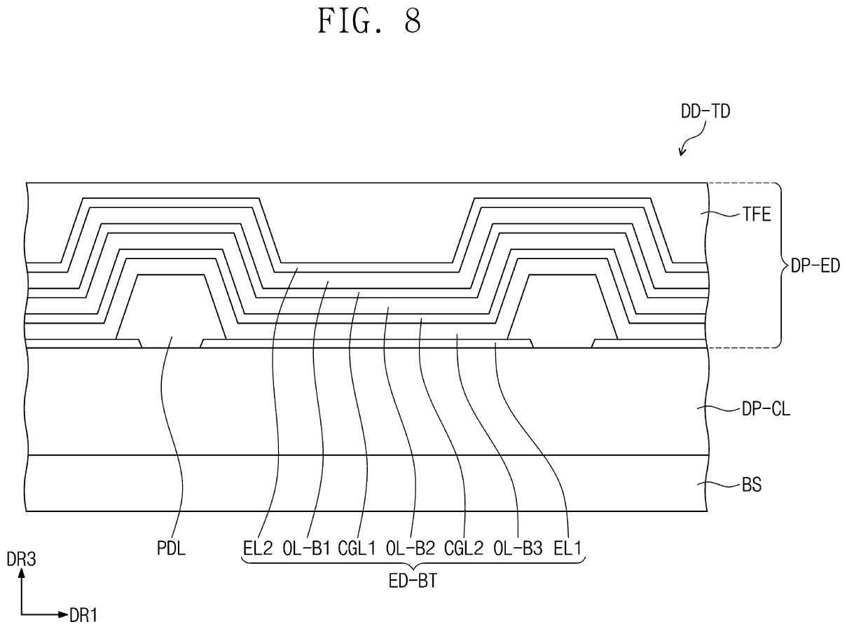

FIG. 8 is a schematic cross-sectional view of a portion of a display device according to an embodiment. In a display device DD-TD according to an embodiment, the light emitting element ED-BT may include light emitting structures OL-B1, OL-B2, and OL-B3. At least one of light emitting structures OL-B1, OL-B2, and OL-B3 may each independently include the polycyclic compound according to an embodiment. Accordingly, the light emitting element ED-BT may exhibit high-luminous efficiency and long-lifespan properties.

The light emitting element ED-BT may include a first electrode EL1 and a second electrode EL2 which face each other, and the light emitting structures OL-B1, OL-B2, and OL-B3 stacked in a thickness direction between the first electrode EL1 and the second electrode EL2. The light emitting structures OL-B1, OL-B2, and OL-B3 may each include a hole transport region HTR (FIG. 7), a light emitting layer EML (FIG. 7), and an electron transport region ETR (FIG. 7), which may be disposed in that order between the first electrode EL1 and the second electrode EL2.

For example, the light emitting element ED-BT included in the display device DD-TD may be a light emitting element having a tandem structure and including multiple light emitting layers EML.

In an embodiment illustrated in FIG. 8, light emitted from the light emitting structures OL-B1, OL-B2, and OL-B3 may each be blue light. However, embodiments are not limited thereto, and the light emitted from each of the light emitting structures OL-B1, OL-B2, and OL-B3 may have wavelength ranges that are different from each other. For example, the light emitting element ED-BT that includes the light emitting structures OL-B1, OL-B2, and OL-B3, which emit light having wavelength ranges that are different from each other, may emit white light.

Charge generation layers CGL1 and CGL2 may each be disposed between two neighboring light emitting structures among the light emitting structures OL-B1, OL-B2, and OL-B3. Charge generation layers CGL1 and CGL2 may each independently include a p-type charge generation layer and/or an n-type charge generation layer.

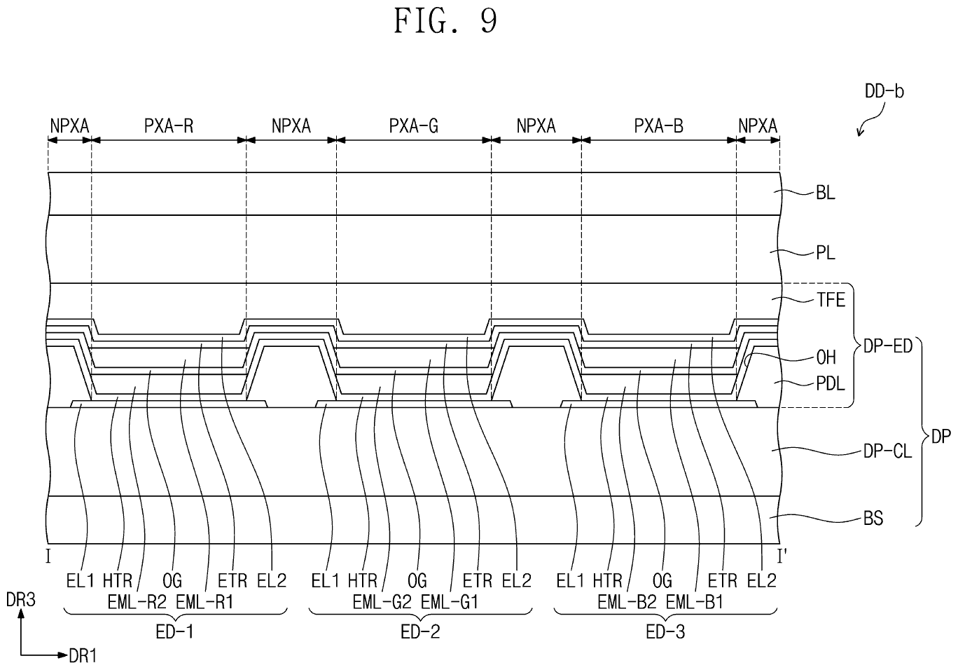

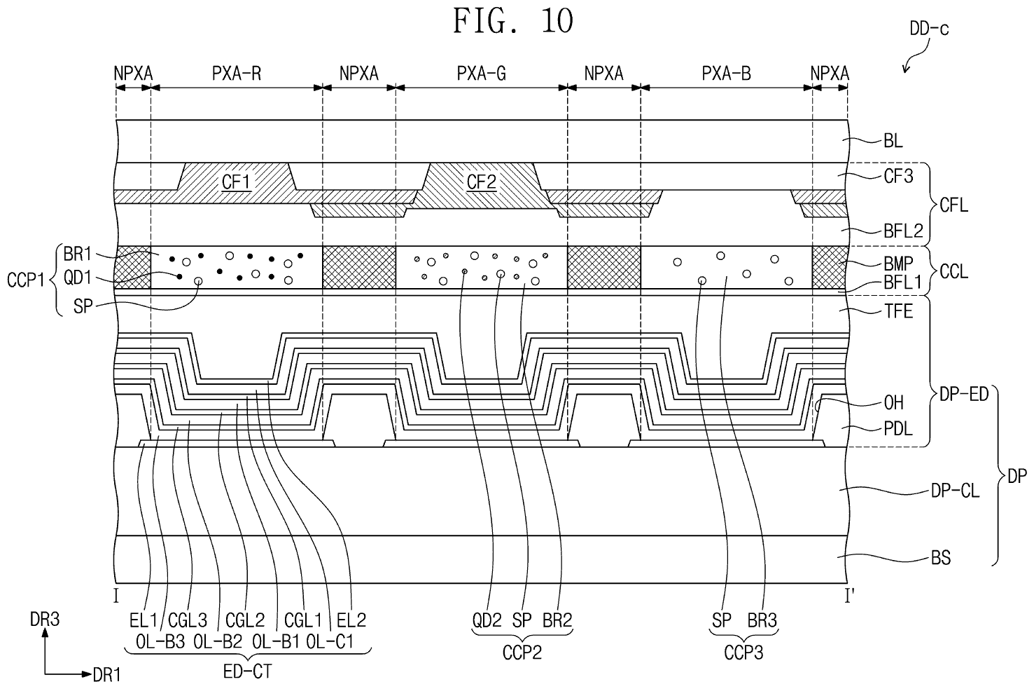

FIG. 9 is a schematic cross-sectional view of a display device according to an embodiment. FIG. 10 is a schematic cross-sectional view of a display device according to an embodiment.

Referring to FIG. 9, the display device DD-b according to an embodiment may include light emitting elements ED-1, ED-2, and ED-3 in which two light emitting layers are stacked. At least one of the light emitting elements ED-1, ED-2, and ED-3 may include the polycyclic compound according to an embodiment. Accordingly, the light emitting element (at least one of light emitting elements ED-1, ED-2, and ED-3) may exhibit high-luminous efficiency and long-lifespan properties.

In comparison to the display device DD illustrated in FIG. 2, the embodiment illustrated in FIG. 9 is different at least in that the first to third light emitting elements ED-1, ED-2, and ED-3 each include two light emitting layers that are stacked in a thickness direction. In each of the first to third light emitting elements ED-1, ED-2, and ED-3, the two light emitting layers may emit light in a same wavelength range.

The first light emitting element ED-1 may include a first red light emitting layer EML-R1 and a second red light emitting layer EML-R2. The second light emitting element ED-2 may include a first green light emitting layer EML-G1 and a second green light emitting layer EML-G2. The third light emitting element ED-3 may include a first blue light emitting layer EML-B1 and a second blue light emitting layer EML-B2. An emission auxiliary part OG may be disposed between the first red light emitting layer EML-R1 and the second red light emitting layer EML-R2, between the first green light emitting layer EML-G1 and the second green light emitting layer EML-G2, and between the first blue light emitting layer EML-B1 and the second blue light emitting layer EML-B2.

The emission auxiliary part OG may be a single layer or a multilayer. The emission auxiliary part OG may include a charge generation layer. For example, the emission auxiliary part OG may include an electron transport region (not shown), a charge generation layer (not shown), and a hole transport region (not shown), which may be stacked in that order. The emission auxiliary part OG may be provided as a common layer for each of the first to third light emitting elements ED-1, ED-2, and ED-3. However, embodiments are not limited thereto, and the emission auxiliary part OG may be provided by being patterned in the openings OH defined in the pixel defining film PDL.

The first red light emitting layer EML-R1, the first green light emitting layer EML-G1, and the first blue light emitting layer EML-B1 may each be disposed between the emission auxiliary part OG and the electron transport region ETR. The second red light emitting layer EML-R2, the second green light emitting layer EML-G2, and the second blue light emitting layer EML-B2 may each be disposed between the hole transport region HTR and the emission auxiliary part OG.

For example, the first light emitting element ED-1 may include the first electrode EL1, the hole transport region HTR, the second red light emitting layer EML-R2, the emission auxiliary part OG, the first red light emitting layer EML-R1, the electron transport region ETR, and the second electrode EL2, which are stacked in that order. The second light emitting element ED-2 may include the first electrode EL1, the hole transport region HTR, the second green light emitting layer EML-G2, the emission auxiliary part OG, the first green light emitting layer EML-G1, the electron transport region ETR, and the second electrode EL2, which are stacked in that order. The third light emitting element ED-3 may include the first electrode EL1, the hole transport region HTR, the second blue light emitting layer EML-B2, the emission auxiliary part OG, the first blue light emitting layer EML-B1, the electron transport region ETR, and the second electrode EL2, which are stacked in that order.

An optical auxiliary layer PL may be disposed on the display device layer DP-ED. The optical auxiliary layer PL may include a polarizing layer. The optical auxiliary layer PL may be disposed on the display panel DP and may control light that is reflected at the display panel DP from an external light. Although not shown in the drawings, in an embodiment, the optical auxiliary layer PL may be omitted from the display device DD-b.

In contrast to FIGS. 8 and 9, FIG. 10 illustrates that a display device DD-c that is different at least in that it includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. In the display device DD-c, at least one of the first to fourth light emitting structures OL-B1, OL-B2, OL-B3, and OL-C1 may each independently include the polycyclic compound according to an embodiment. Accordingly, the light emitting element ED-CT may exhibit high-luminous efficiency and long-lifespan properties.

Light emitting structures OL-C1, OL-B1, OL-B2, and OL-B3 may be stacked in this stated order, and charge generation layer CGL1 may be disposed between light emitting structures OL-B1 and OL-C1, charge generation layer CGL2 may be disposed between light emitting structures OL-B1 and OL-B2, and charge generation layer CGL3 may be disposed between light emitting structures OL-B2 and OL-B3. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having different wavelength ranges from each other.

The charge generation layers CGL1, CGL2, and CGL3 that are disposed between adjacent light emitting structures among the first to fourth light emitting structures OL-B1, OL-B2, OL-B3, and OL-C1 may each independently include a p-type charge generation layer and/or an n-type charge generation layer.

In an embodiment, an electronic apparatus may include a display device that includes multiple light emitting elements, and a control part that controls the display device. The electronic apparatus may be a device that is activated by an electrical signal. The electronic apparatus may include display devices according to various embodiments. Examples of an electronic apparatus may include not only large-sized electronic apparatuses such as a television set, a monitor, or a billboard, but may also include small or medium-sized electronic apparatuses such as a personal computer, a laptop computer, a personal digital terminal, a display device for a vehicle, a game console, a portable electronic device, or a camera.

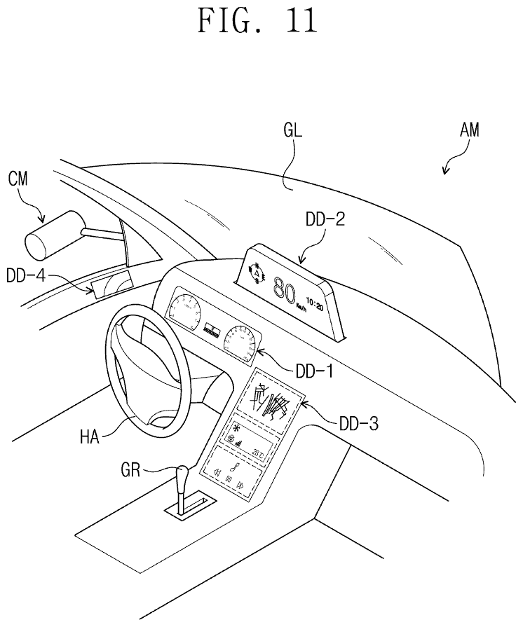

FIG. 11 is a schematic perspective view of a vehicle AM that includes first to fourth display devices DD-1, DD-2, DD-3, and DD-4. At least one of the first to fourth display devices DD-1, DD-2, DD-3, and DD-4 may have a structure according to one of display devices DD, DD-TD, DD-a, DD-b, and DD-c, as described above with reference to FIGS. 1, 2, and 7 to 10.

FIG. 11 illustrates a vehicle AM, but this is only an example, and the first to fourth display devices DD-1, DD-2, DD-3, and DD-4 may be disposed in various transportation means such as a bicycle, a motorcycle, a train, a ship, or an airplane. In an embodiment, at least one of the first to fourth display devices DD-1, DD-2, DD-3, and DD-4, each having a structure according to one of display devices DD, DD-TD, DD-a, DD-b, and DD-c, may be included in a personal computer, a laptop computer, a personal digital terminal, a game console, a portable electronic device, a television, a monitor, an outdoor billboard, or the like. However, these are merely provided as examples, and thus may be included in other electronic apparatuses.

At least one of the first to fourth display devices DD-1, DD-2, DD-3, and DD-4 may each independently include a light emitting element ED according to an embodiment as described with reference to any of FIG. 3 to FIG. 6. At least one of the first to fourth display devices DD-1, DD-2, DD-3, and DD-4 may each independently include the polycyclic compound according to an embodiment. The first to fourth display devices DD-1, DD-2, DD-3, and DD-4 that includes the polycyclic compound according to an embodiment may have improved display efficiency and display lifespan.

Referring to FIG. 11, a vehicle AM may include a steering wheel HA and a gearshift GR for operating the vehicle AM. The vehicle AM may include a front window GL that is disposed so as to face the driver.

The first display device DD-1 may be disposed in a first region that overlaps the steering wheel HA. For example, the first display device DD-1 may be a digital cluster that displays first information of the vehicle AM. The first information may include a first scale that indicates a driving speed of the vehicle AM, a second scale that indicates an engine speed (for example, as revolutions per minute (RPM)), a fuel gauge, etc. The first scale and the second scale may each be represented by a digital image.

The second display device DD-2 may be disposed in a second region facing the driver's seat and overlapping the front window GL. The driver's seat may be a seat where the steering wheel HA is disposed. For example, the second display device DD-2 may be a head up display (HUD) that displays second information of the vehicle AM. The second display device DD-2 may be optically transparent. The second information may include digital numbers that indicate a driving speed of the vehicle AM, and may further include information such as the current time. Although not shown in the drawings, in an embodiment, the second information of the second display device DD-2 may be displayed by being projected onto the front window GL.

The third display device DD-3 may be disposed in a third region that is adjacent to the gearshift GR. For example, the third display device DD-3 may be disposed between the driver's seat and the passenger seat and may be a center information display (CID) for the vehicle AM that displays third information. The passenger seat may be a seat that is spaced apart from the driver's seat, and the gearshift GR may be disposed between the driver's seat and the passenger seat. The third information may include information about traffic or road conditions (e.g., navigation information), playing music or radio, displaying an image or a video, temperatures inside the vehicle AM, etc.

The fourth display device DD-4 may be spaced apart from the steering wheel HA and the gearshift GR, and may be disposed in a fourth region that is adjacent to a side of the vehicle AM. For example, the fourth display device DD-4 may be a digital side-view mirror that displays fourth information. The fourth display device DD-4 may display an image that is exterior to the vehicle AM, which may be taken by a camera module CM disposed outside the vehicle AM. The fourth information may include an image of the exterior of the vehicle AM.

The first to fourth information as described above are only provided as examples, and the first to fourth display devices DD-1, DD-2, DD-3, and DD-4 may further display information about the interior and exterior of the vehicle AM. The first to fourth information may include information that is different from each other. However, embodiments are not limited thereto, and a part of the first to fourth information may include the same information.

Hereinafter, a polycyclic compound according to an embodiment and a light emitting element according to an embodiment will be described with reference to the Examples and the Comparative Examples. The Examples described below are only provided to facilitate in understanding the disclosure, and the scope thereof is not limited thereto.

### EXAMPLES

### 1. Synthesis of Polycyclic Compound of Embodiment

A method for synthesizing a polycyclic compound according to an embodiment will be described in detail by illustrating synthesis methods for Compounds 1, 91, 125, 143, and 180. The synthesis methods for the polycyclic compounds described below are only provided as examples, and the synthesis methods of polycyclic compounds according to an embodiment are not limited to the Examples below.

### (1) Synthesis of Compound 1

Compound 1 according to an embodiment may be synthesized, for example, by the steps of Reaction Equation 1 below.

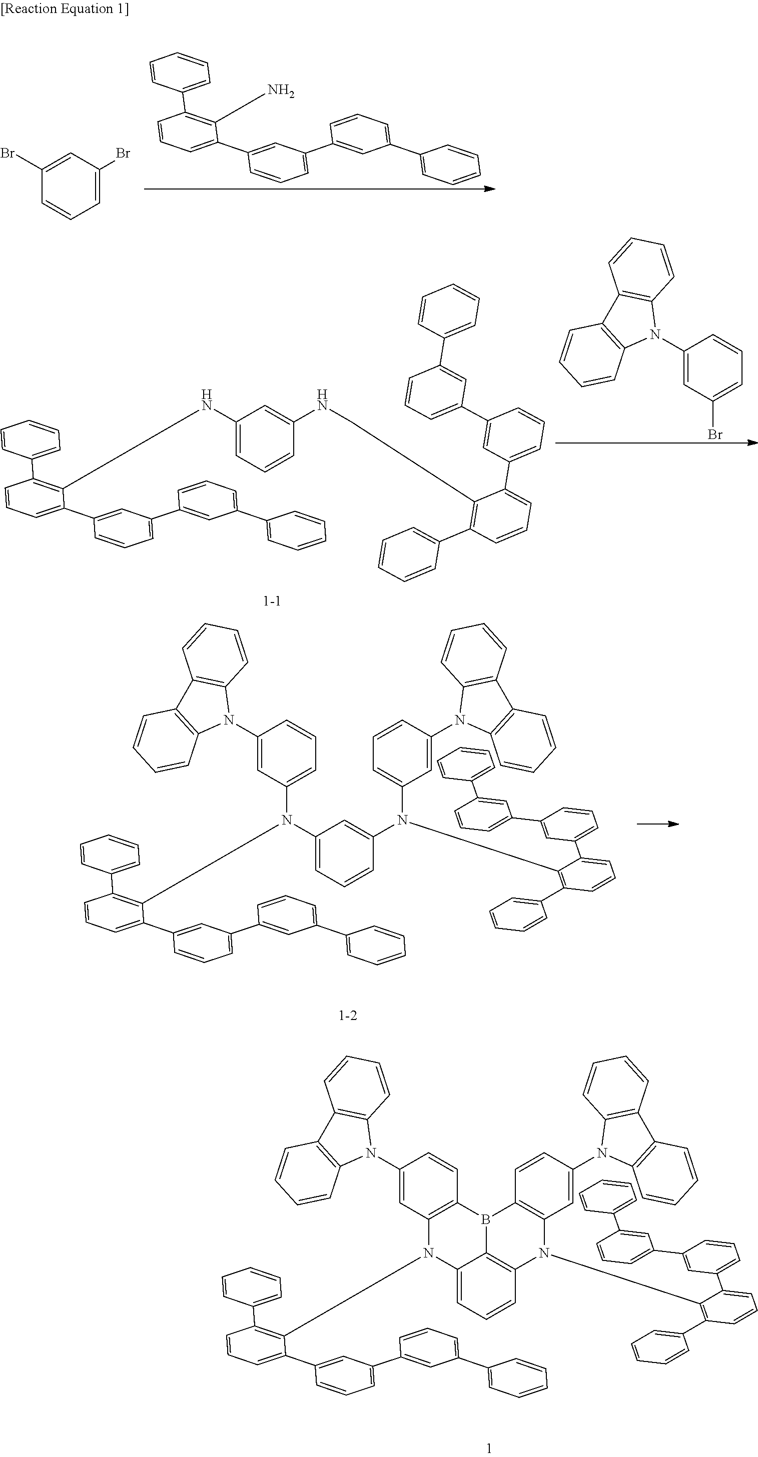

### Synthesis of Intermediate Compound 1-1

1,3-dibromobenzene (1 eq), [1,1′:3′,1″:3″,1′″:3′″,1″″-quinquephenyl]-2′-amine (1 eq), Tris(dibenzylideneacetone)dipalladium(0) (0.05 eq), Tri-tert-butylphosphine (0.1 eq), and Sodium tert-butoxide (3 eq) were dissolved in toluene and stirred at 80 degrees Celsius for 4 hours. The mixture was cooled, washed three times with ethyl acetate and water, and separated to obtain an organic layer, and the organic layer was dried using MgSO₄, and dried under reduced pressure. Purification by column chromatography was performed using methylene chloride (MC) and n-Hexane to obtain Intermediate 1-1. (Yield: 70%)

### Synthesis of Intermediate Compound 1-2

Intermediate 1-1 (1 eq), 9-(3-bromophenyl)-9H-carbazole (3 eq), Tris(dibenzylideneacetone)dipalladium(0) (0.15 eq), Tri-tert-butylphosphine (0.3 eq), and Sodium tert-butoxide (3 eq) were dissolved in o-xylene and stirred at 160 degrees Celsius for 60 hours. The mixture was cooled, washed three times with ethyl acetate and water, and separated to obtain an organic layer, and the organic layer was dried using MgSO₄, and dried under reduced pressure. Purification by column chromatography was performed using MC and n-Hexane to obtain Intermediate 1-2. (Yield: 31%)

### Synthesis of Compound 1

Intermediate 1-2 (1 eq) was dissolved in ortho dichlorobenzene, cooled to 0 degrees Celsius, and BBr₃ (4 eq) was slowly injected thereto in a nitrogen atmosphere. After dropwise addition was completed, the temperature was raised to 180 degrees Celsius and stirring was performed for 48 hours. The mixture was cooled, and trimethylamine was slowly dropped into a flask containing a reactant to terminate the reaction, and thereafter, ethyl alcohol was added to the reactant to perform precipitation and filtration to obtain a reactant. The obtained solid was purified by column chromatography using MC and n-Hexane, and recrystallized using toluene and acetone to obtain Compound 1. (Yield: 3%)

### (2) Synthesis of Compound 91

Compound 91 according to an embodiment may be synthesized, for example, by the steps of Reaction Equation 2 below.

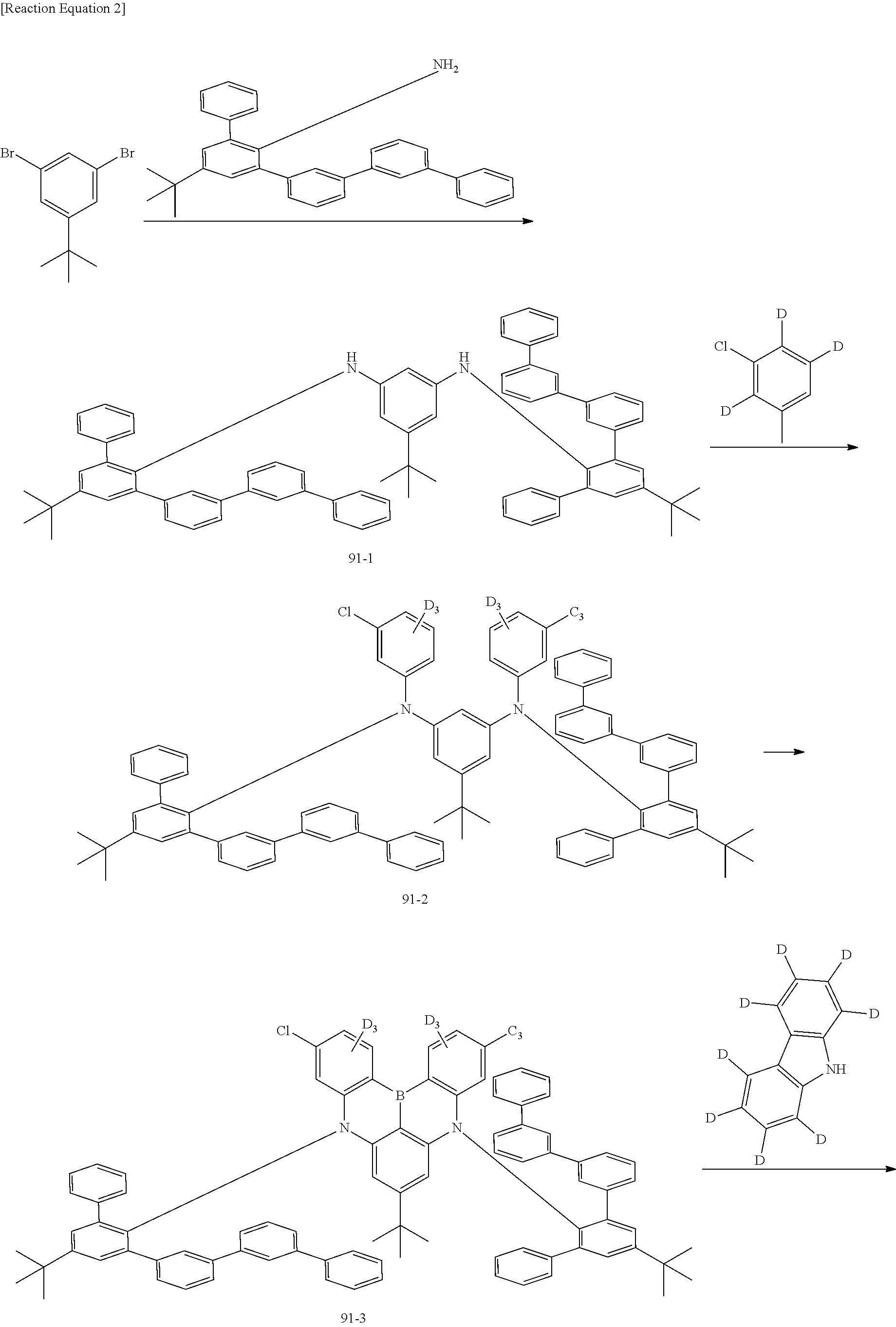

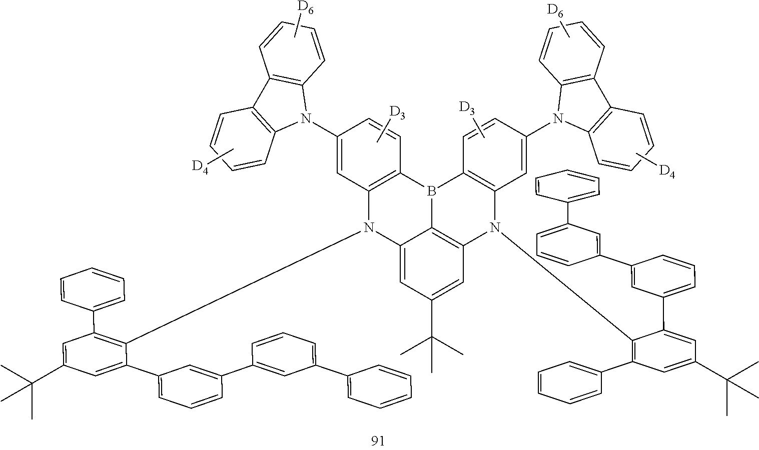

### Synthesis of Intermediate Compound 91-1

1,3-dibromo-5-(tert-butyl)benzene (1 eq), 5′-(tert-butyl)-[1,1′:3′,1″:3″,1′″:3′″,1″″-quinquephenyl]-2′-amine (1 eq), Tris(dibenzylideneacetone)dipalladium(0) (0.05 eq), Tri-tert-butylphosphine (0.1 eq), and Sodium tert-butoxide (3 eq) were dissolved in toluene and stirred at 80 degrees Celsius for 4 hours. The mixture was cooled, washed three times with ethyl acetate and water, and separated to obtain an organic layer, and the organic layer was dried using MgSO₄, and dried under reduced pressure. Purification by column chromatography was performed using MC and n-Hexane to obtain Intermediate 91-1. (Yield: 68%)

### Synthesis of Intermediate Compound 91-2

Intermediate 91-1 (1 eq), 1-chloro-3-iodobenzene-2,5,6-d₃ (2 eq), Tri-tert-butylphosphine (0.1 eq), and Sodium tert-butoxide (3 eq) were dissolved in o-xylene and stirred at 140 degrees Celsius for 2 hours. The mixture was cooled, washed three times with ethyl acetate and water, and separated to obtain an organic layer, and the organic layer was dried using MgSO₄, and dried under reduced pressure. Purification by column chromatography was performed using MC and n-Hexane to obtain Intermediate 91-2. (Yield: 66%)

### Synthesis of Intermediate Compound 91-3

Intermediate 91-2 (1 eq) was dissolved in ortho dichlorobenzene, cooled to 0 degrees Celsius, and BBr₃ (4 eq) was slowly injected thereto in a nitrogen atmosphere. After dropwise addition was completed, the temperature was raised to 180 degrees Celsius and stirring was performed for 48 hours. The mixture was cooled, and trimethylamine was slowly dropped into a flask containing a reactant to terminate the reaction, and thereafter, ethyl alcohol was added to the reactant to perform precipitation and filtration to obtain a reactant. The obtained solid was purified by column chromatography using MC and n-Hexane, and recrystallized using toluene and acetone to obtain Intermediate 91-3. (Yield: 35%)

### Synthesis of Compound 91

Intermediate 91-3 (1 eq), 9H-carbazole-1,2,3,4,5,6,7,8-d₈ (2 eq), Tris(dibenzylideneacetone)dipalladium(0) (0.05 eq), Tri-tert-butylphosphine (0.1 eq), and Sodium tert-butoxide (3 eq) were dissolved in 100 mL of Xylene, and stirred at 100 degrees Celsius for 12 hours. The mixture was cooled, washed three times with ethyl acetate and water, and separated to obtain an organic layer, and the organic layer was dried using MgSO₄, and dried under reduced pressure. The obtained solid was purified by column chromatography using MC and n-Hexane, and recrystallized using toluene and acetone to obtain Compound 91. (Yield: 2.7%)

### (3) Synthesis of Compound 125

Compound 125 according to an embodiment may be synthesized, for example, by the steps of Reaction Equation 3 below.

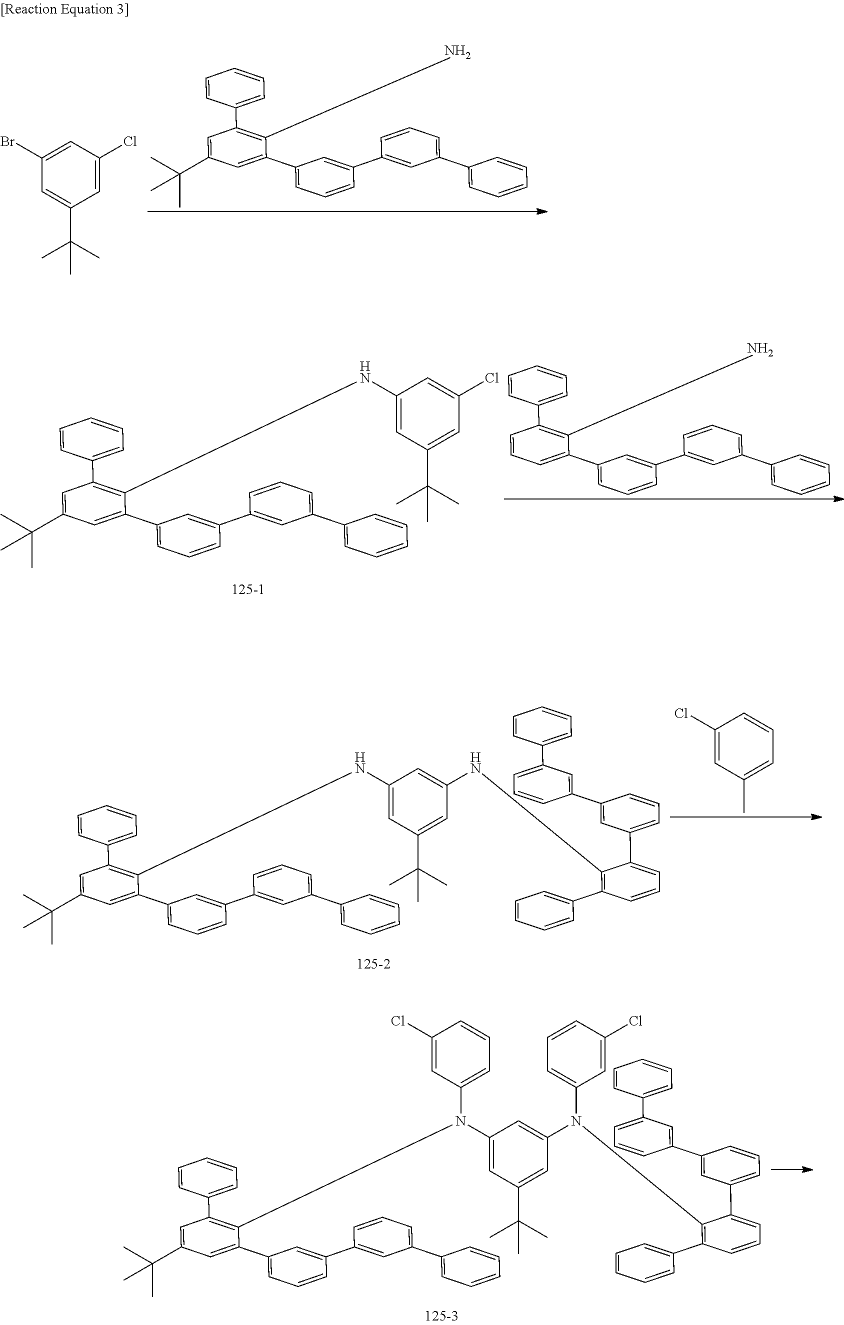

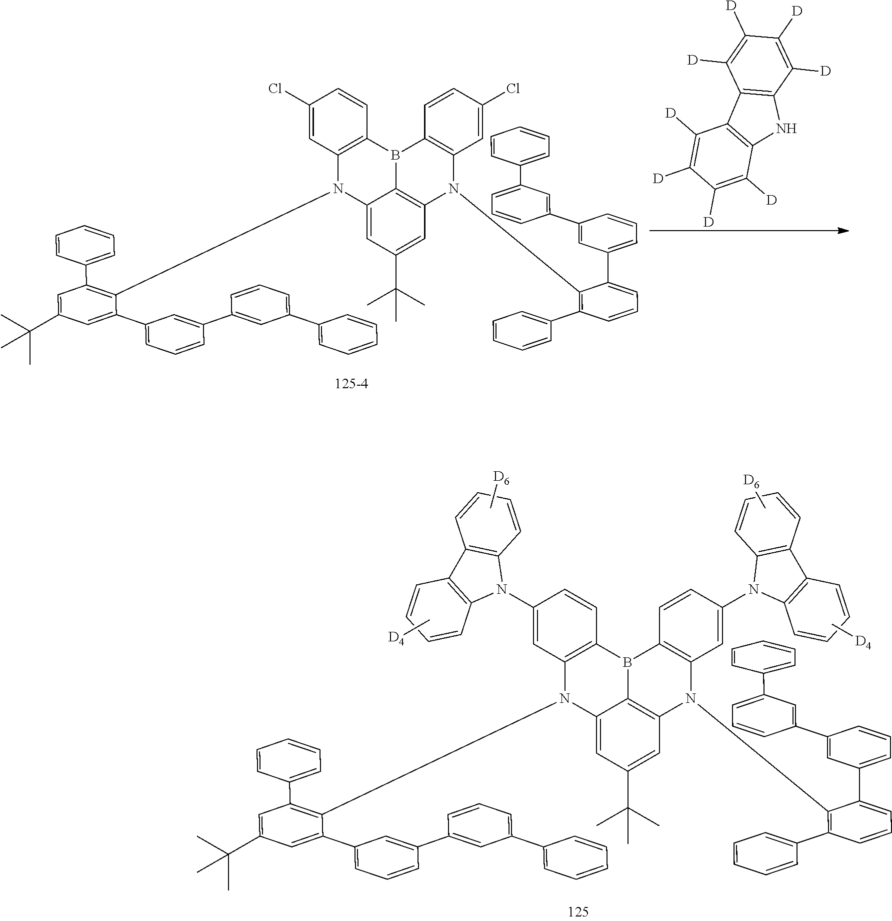

### Synthesis of Intermediate Compound 125-1

1-bromo-3-(tert-butyl)-5-chlorobenzene (1 eq), 5′-(tert-butyl)-[1,1′:3′,1″:3″,1′″:3′″,1″″-quinquephenyl]-2′-amine (1 eq), Tris(dibenzylideneacetone)dipalladium(0) (0.05 eq), Tri-tert-butylphosphine (0.1 eq), and Sodium tert-butoxide (3 eq) were dissolved in toluene and stirred at 80 degrees Celsius for 4 hours. The mixture was cooled, washed three times with ethyl acetate and water, and separated to obtain an organic layer, and the organic layer was dried using MgSO₄, and dried under reduced pressure. Purification by column chromatography was performed using MC and n-Hexane to obtain Intermediate 125-1. (Yield: 69%)

### Synthesis of Intermediate Compound 125-2

Intermediate 125-1 (1 eq), [1,1′:3′,1″:3″,1′″:3′″,1″″-quinquephenyl]-2′-amine (1 eq), Tri-tert-butylphosphine (0.1 eq), and Sodium tert-butoxide (3 eq) were dissolved in toluene and stirred at 80 degrees Celsius for 4 hours. The mixture was cooled, washed three times with ethyl acetate and water, and separated to obtain an organic layer, and the organic layer was dried using MgSO₄, and dried under reduced pressure. Purification by column chromatography was performed using MC and n-Hexane to obtain Intermediate 125-2. (Yield: 66%)

### Synthesis of Intermediate Compound 125-3

Intermediate 125-2 (1 eq), 1-chloro-3-iodobenzene (2 eq), Tri-tert-butylphosphine (0.1 eq), and Sodium tert-butoxide (3 eq) were dissolved in o-xylene and stirred at 140 degrees Celsius for 2 hours. The mixture was cooled, washed three times with ethyl acetate and water, and separated to obtain an organic layer, and the organic layer was dried using MgSO₄, and dried under reduced pressure. Purification by column chromatography was performed using MC and n-Hexane to obtain Intermediate 125-3. (Yield: 65%)

### Synthesis of Intermediate Compound 125-4

Intermediate 125-3 (1 eq) was dissolved in ortho dichlorobenzene, cooled to 0 degrees Celsius, and BBr₃ (4 eq) was slowly injected thereto in a nitrogen atmosphere. After dropwise addition was completed, the temperature was raised to 180 degrees Celsius and stirring was performed for 48 hours. The mixture was cooled, and trimethylamine was slowly dropped into a flask containing a reactant to terminate the reaction, and thereafter, ethyl alcohol was added to the reactant to perform precipitation and filtration to obtain a reactant. The obtained solid was purified by column chromatography using MC and n-Hexane, and recrystallized using toluene and acetone to obtain Intermediate 125-4. (Yield: 36%)

### Synthesis of Compound 125

Intermediate 125-4 (1 eq), 9H-carbazole-1,2,3,4,5,6,7,8-d₈ (2 eq), Tris(dibenzylideneacetone)dipalladium(0) (0.05 eq), Tri-tert-butylphosphine (0.1 eq), and Sodium tert-butoxide (3 eq) were dissolved in 100 mL of Xylene, and stirred at 100 degrees Celsius for 12 hours. The mixture was cooled, washed three times with ethyl acetate and water, and separated to obtain an organic layer, and the organic layer was dried using MgSO₄, and dried under reduced pressure. The obtained solid was purified by column chromatography using MC and n-Hexane, and recrystallized using toluene and acetone to obtain Compound 125. (Yield: 2.9%)

### (4) Synthesis of Compound 143

Compound 143 according to an embodiment may be synthesized, for example, by the steps of Reaction Equation 4 below.

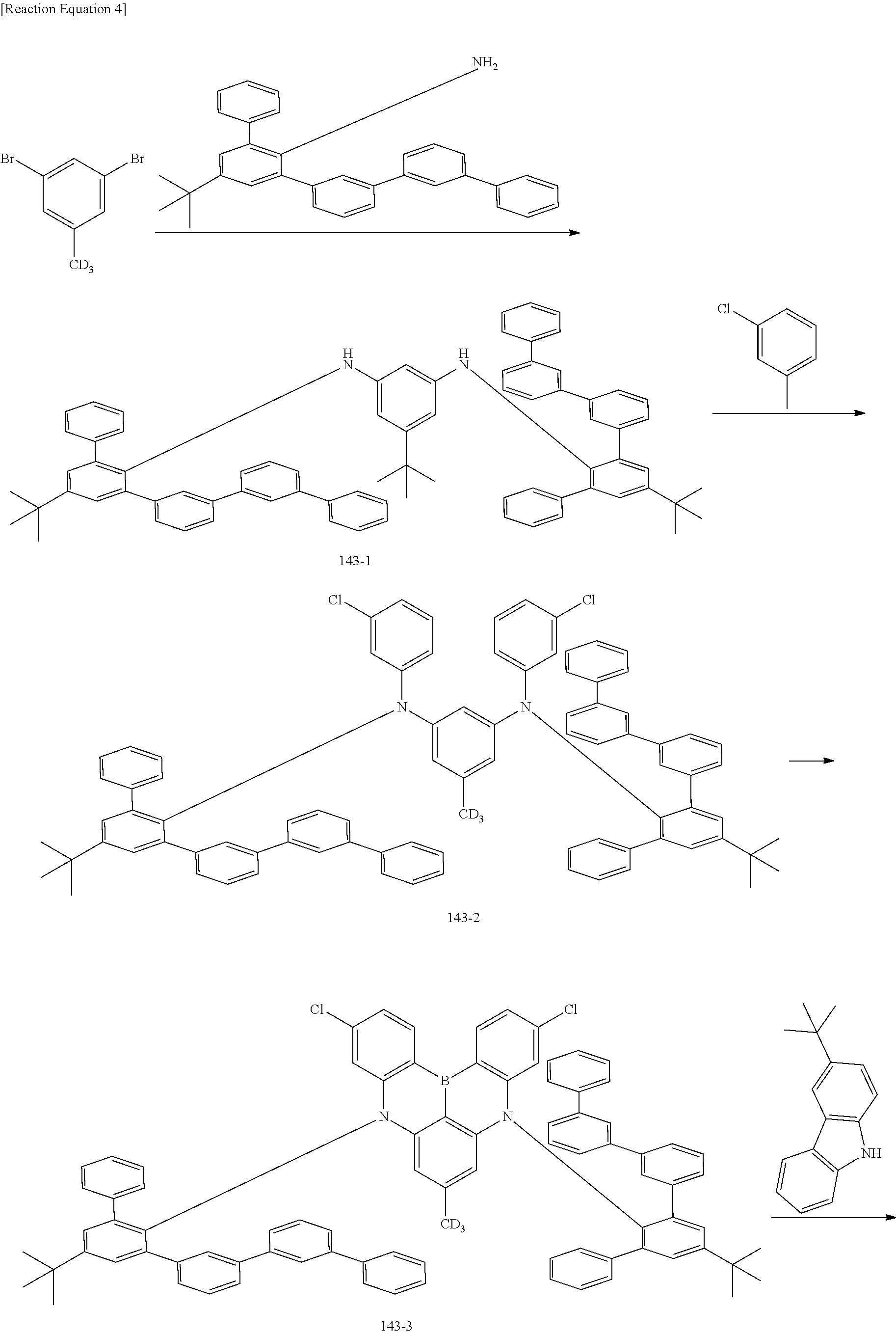

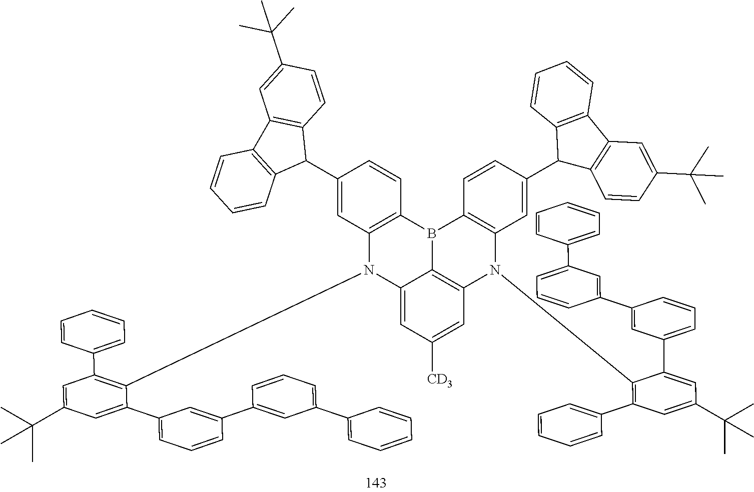 [SMILES: [2H]C([2H])([2H])c1cc2c3c(c1)N(c1c(-c4ccccc4)cc(C(C)(C)C)cc1-c1cccc(-c4cccc(-c5ccccc5)c4)c1)c1cc(C4c5ccccc5-c5cc(C(C)(C)C)ccc54)ccc1B3c1ccc(C3c4ccccc4-c4cc(C(C)(C)C)ccc43)cc1N2c1c(-c2ccccc2)cc(C(C)(C)C)cc1-c1cccc(-c2cccc(-c3ccccc3)c2)c1]

### Synthesis of Intermediate Compound 143-1

1,3-dibromo-5-(methyl-d3)benzene (1 eq), 5′-(tert-butyl)-[1,1′:3′,1″:3″,1′″:3′″,1″″-quinquephenyl]-2′-amine (1 eq), Tris(dibenzylideneacetone)dipalladium(0) (0.05 eq), Tri-tert-butylphosphine (0.1 eq), and Sodium tert-butoxide (3 eq) were dissolved in toluene and stirred at 80 degrees Celsius for 4 hours. The mixture was cooled, washed three times with ethyl acetate and water, and separated to obtain an organic layer, and the organic layer was dried using MgSO₄, and dried under reduced pressure. Purification by column chromatography was performed using MC and n-Hexane to obtain Intermediate 143-1. (Yield: 70%)

### Synthesis of Intermediate Compound 143-2

Intermediate 143-1 (1 eq), 1-chloro-3-iodobenzene (2 eq), Tri-tert-butylphosphine (0.1 eq), and Sodium tert-butoxide (3 eq) were dissolved in o-xylene and stirred at 140 degrees Celsius for 2 hours. The mixture was cooled, washed three times with ethyl acetate and water, and separated to obtain an organic layer, and the organic layer was dried using MgSO₄, and dried under reduced pressure. Purification by column chromatography was performed using MC and n-Hexane to obtain Intermediate 143-2. (Yield: 68%)

### Synthesis of Intermediate Compound 143-3

Intermediate 143-2 (1 eq) was dissolved in ortho dichlorobenzene, cooled to 0 degrees Celsius, and BBr₃ (4 eq) was slowly injected thereto in a nitrogen atmosphere. After dropwise addition was completed, the temperature was raised to 180 degrees Celsius and stirring was performed for 48 hours. The mixture was cooled, and trimethylamine was slowly dropped into a flask containing a reactant to terminate the reaction, and thereafter, ethyl alcohol was added to the reactant to perform precipitation and filtration to obtain a reactant. The obtained solid was purified by column chromatography using MC and n-Hexane, and recrystallized using toluene and acetone to obtain Intermediate 143-3. (Yield: 36%)

### Synthesis of Compound 143

Intermediate 143-3 (1 eq), 3-(tert-butyl)-9H-carbazole (2 eq), Tris(dibenzylideneacetone)dipalladium(0) (0.05 eq), Tri-tert-butylphosphine (0.1 eq), and Sodium tert-butoxide (3 eq) were dissolved in 100 mL of Xylene, and stirred at 100 degrees Celsius for 12 hours. The mixture was cooled, washed three times with ethyl acetate and water, and separated to obtain an organic layer, and the organic layer was dried using MgSO₄, and dried under reduced pressure. The obtained solid was purified by column chromatography using MC and n-Hexane, and recrystallized using toluene and acetone to obtain Compound 143. (Yield: 2.8%)

### (5) Synthesis of Compound 180

Compound 180 according to an embodiment may be synthesized, for example, by the steps of Reaction Equation 5 below.

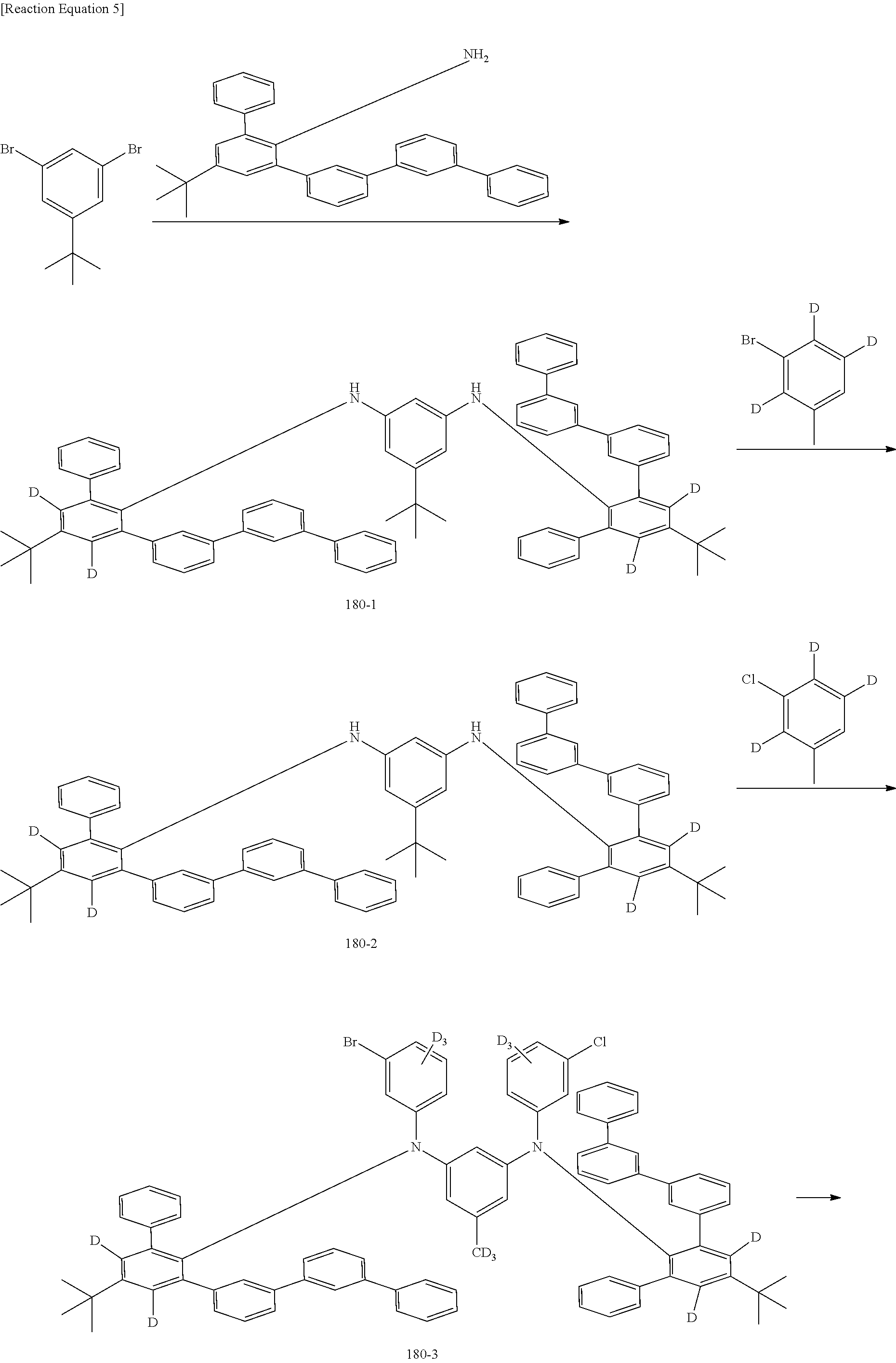

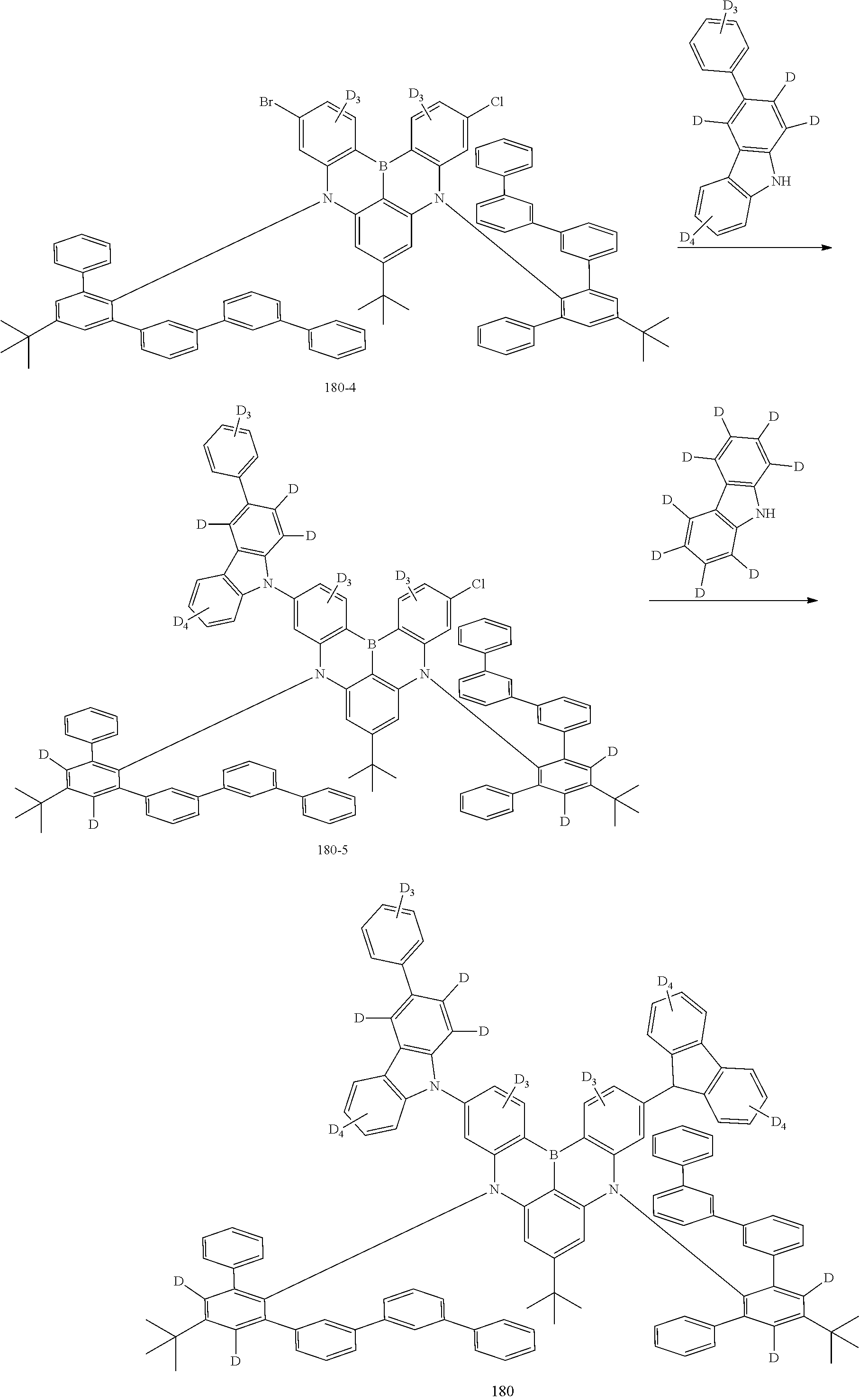

### Synthesis of Intermediate Compound 180-1

1,3-dibromo-5-(tert-butyl)benzene (1 eq), 5′-(tert-butyl)-[1,1′:3′,1″:3″,1′″:3′″,1″″-quinquephenyl]-4′,6′-d2-2′-amine (1 eq), Tris(dibenzylideneacetone)dipalladium(0) (0.05 eq), Tri-tert-butyiphosphine (0.1 eq), and Sodium tert-butoxide (3 eq) were dissolved in toluene and stirred at 80 degrees Celsius for 4 hours. The mixture was cooled, washed three times with ethyl acetate and water, and separated to obtain an organic layer, and the organic layer was dried using MgSO₄, and dried under reduced pressure. Purification by column chromatography was performed using MC and n-Hexane to obtain Intermediate 180-1. (Yield: 65%)

### Synthesis of Intermediate Compound 180-2

Intermediate 180-1 (1 eq), 1-bromo-3-iodobenzene-2,5,6-d3 (2 eq), Tri-tert-butylphosphine (0.1 eq), and Sodium tert-butoxide (3 eq) were dissolved in o-xylene and stirred at 140 degrees Celsius for 2 hours. The mixture was cooled, washed three times with ethyl acetate and water, and separated to obtain an organic layer, and the organic layer was dried using MgSO₄, and dried under reduced pressure. Purification by column chromatography was performed using MC and n-Hexane to obtain Intermediate 180-2. (Yield: 64%)

### Synthesis of Intermediate Compound 180-3

Intermediate 180-2 (1 eq), 1-chloro-3-iodobenzene-2,5,6-d₃ (2 eq), Tri-tert-butylphosphine (0.1 eq), and Sodium tert-butoxide (3 eq) were dissolved in o-xylene and stirred at 140 degrees Celsius for 2 hours. The mixture was cooled, washed three times with ethyl acetate and water, and separated to obtain an organic layer, and the organic layer was dried using MgSO₄, and dried under reduced pressure. Purification by column chromatography was performed using MC and n-Hexane to obtain Intermediate 180-3. (Yield: 63%)

### Synthesis of Intermediate Compound 180-4

Intermediate 180-3 (1 eq) was dissolved in ortho dichlorobenzene, cooled to 0 degrees Celsius, and BBr₃ (4 eq) was slowly injected thereto in a nitrogen atmosphere. After dropwise addition was completed, the temperature was raised to 180 degrees Celsius and stirring was performed for 48 hours. The mixture was cooled, and trimethylamine was slowly dropped into a flask containing a reactant to terminate the reaction, and thereafter, ethyl alcohol was added to the reactant to perform precipitation and filtration to obtain a reactant. The obtained solid was purified by column chromatography using MC and n-Hexane, and recrystallized using toluene and acetone to obtain Intermediate 180-4. (Yield: 34%)

### Synthesis of Intermediate Compound 180-5

Intermediate 180-4 (1 eq), 3-(phenyl-d₅)-9H-carbazole-1,2,4,5,6,7,8-d₇ (2 eq), Tris(dibenzylideneacetone)dipalladium(0) (0.05 eq), Tri-tert-butylphosphine (0.1 eq), and Sodium tert-butoxide (3 eq) were dissolved in 100 mL of Xylene, and stirred at 100 degrees Celsius for 12 hours. The mixture was cooled, washed three times with ethyl acetate and water, and separated to obtain an organic layer, and the organic layer was dried using MgSO₄, and dried under reduced pressure. The obtained solid was purified by column chromatography using MC and n-Hexane, and recrystallized using toluene and acetone to obtain Intermediate 180-5. (Yield: 5.5%)

### Synthesis of Compound 180

Intermediate 180-5 (1 eq), 9H-carbazole-1,2,3,4,5,6,7,8-d₈ (2 eq), Tris(dibenzylideneacetone)dipalladium(0) (0.05 eq), Tri-tert-butylphosphine (0.1 eq), and Sodium tert-butoxide (3 eq) were dissolved in 100 mL of Xylene, and stirred at 100 degrees Celsius for 12 hours. The mixture was cooled, washed three times with ethyl acetate and water, and separated to obtain an organic layer, and the organic layer was dried using MgSO₄, and dried under reduced pressure. The obtained solid was purified by column chromatography using MC and n-Hexane, and recrystallized using toluene and acetone to obtain Compound 180. (Yield: 2.6%)

### 2. Evaluation of Compounds

Table 1 shows the evaluation of the compounds of the Comparative Examples and the compounds of the Examples. The compounds of the Comparative Examples and the compounds of the Examples for the evaluation are shown below.

### Example Compounds

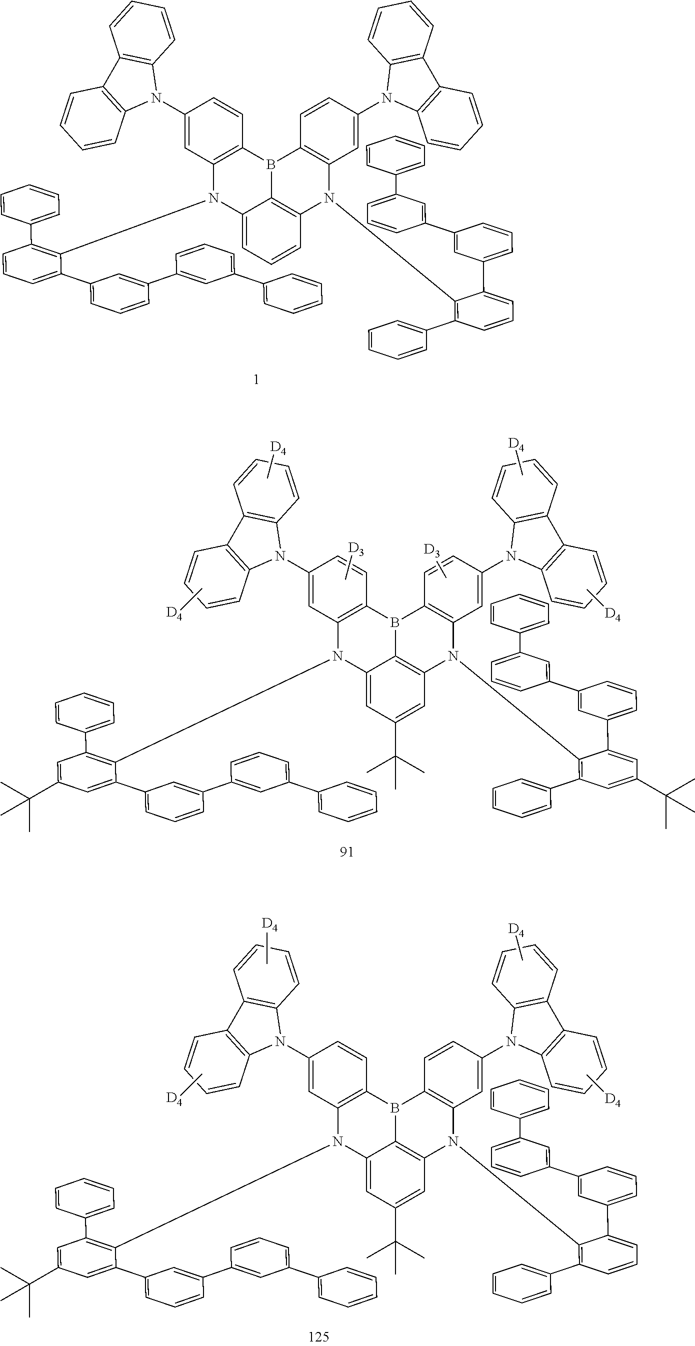

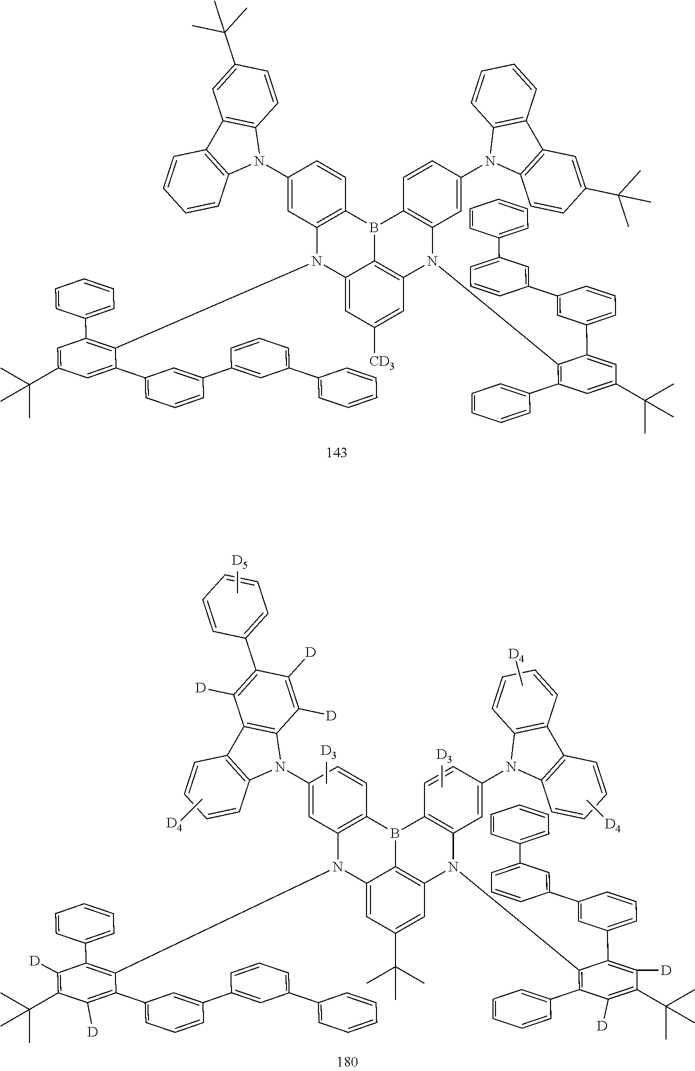

### Comparative Example Compounds

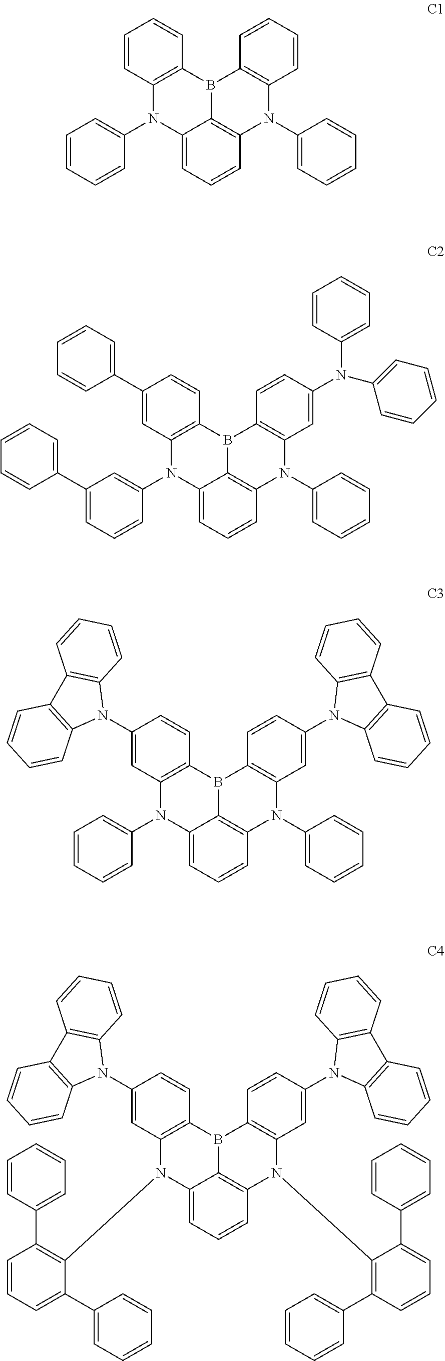 [SMILES: c1ccc(N2c3ccccc3B3c4ccccc4N(c4ccccc4)c4cccc2c43)cc1 ; c1ccc(-c2cccc(N3c4cc(-c5ccccc5)ccc4B4c5ccc(N(c6ccccc6)c6ccccc6)cc5N(c5ccccc5)c5cccc3c54)c2)cc1 ; c1ccc(N2c3cc(-n4c5ccccc5c5ccccc54)ccc3B3c4ccc(-n5c6ccccc6c6ccccc65)cc4N(c4ccccc4)c4cccc2c43)cc1 ; c1ccc(-c2cccc(-c3ccccc3)c2N2c3cc(-n4c5ccccc5c5ccccc54)ccc3B3c4ccc(-n5c6ccccc6c6ccccc65)cc4N(c4c(-c5ccccc5)cccc4-c4ccccc4)c4cccc2c43)cc1]

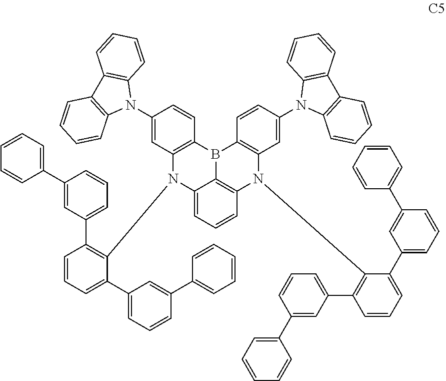 [SMILES: c1ccc(-c2cccc(-c3cccc(-c4cccc(-c5ccccc5)c4)c3N3c4cc(-n5c6ccccc6c6ccccc65)ccc4B4c5ccc(-n6c7ccccc7c7ccccc76)cc5N(c5c(-c6cccc(-c7ccccc7)c6)cccc5-c5cccc(-c6ccccc6)c5)c5cccc3c54)c2)cc1]

Table 1 shows the molecular weight (g/mol), total energy (hartree), sublimation temperature (° C.), and bond dissociation energy (eV) of Example Compound 1 and Comparative Example Compounds C3 and C5. The total energy refers to a sum of energy that a molecule has in its ground state. The bond dissociation energy refers to bond dissociation energy between a nitrogen atom of a condensed ring including a boron atom of a compound and a carbon atom of an aryl group bonded to the nitrogen atom. If sublimation temperature is low, the difficulty of compound synthesis is reduced, and if the bond dissociation energy is high, the bond strength is strong so that the stability of the molecule is improved.

TABLE 1

| | Molecular | Total | Sublimation | Bond |
|---|---|---|---|---|
| | weight | Energy | temperature | dissociation |
| Compound | [g/mol] | [Hartree] | [° C.] | energy [eV] |
| C3 | 750.7 | −2323.3311 | ~300 | 2.14 |
| C5 | 1359.5 | −4172.1838 | ~340 | 2.17 |
| Compound 1 | 1359.5 | −4172.1866 | ~330 | 2.20 |

Referring to Table 1, compared to Comparative Example Compounds C3 and C5, Example Compound 1 had the highest bond dissociation energy, so that the stability of the molecule was improved. Compared to Comparative Example Compound C5, Example Compound 1 has a substantially similar molecular weight and total energy, but has a lower sublimation temperature by 10° C., so that the difficulty of the synthesis process was reduced.

### 3. Manufacturing and Evaluation of Light Emitting Element

### (1) Manufacturing of Light Emitting Element

A light emitting element including the polycyclic compound of an embodiment, or including a Comparative Example compound in a light emitting layer of the light emitting element was manufactured in the following manner. Compounds 1, 91, 125, 143, and 180, each of which is a polycyclic compound according to an embodiment, were respectively used as dopant materials of light emitting layers to manufacture light emitting elements of Examples 1 to 5. Light emitting elements of Comparative Examples 1 to 5 were respectively manufactured using Comparative Example Compounds C1 to C5 as dopant materials of light emitting layers.

A glass substrate (product of Corning Co., Ltd.), having an ITO electrode of 15 Ω/cm² (1200 Å) formed as an anode, was cut to a size of 50 mm×50 mm×0.7 mm, ultrasonically washed for 5 minutes using isopropyl alcohol and pure water, irradiated with ultraviolet rays for 30 minutes and exposed to ozone to be washed, and mounted on a vacuum deposition apparatus.

On an upper portion of the anode, NPD(NPB) was deposited to form a hole injection layer having a thickness of 300 Å, and Compound HT-1-19 was deposited on an upper portion of the hole injection layer to form a hole transport layer having a thickness of 200 Å. CzSi was deposited on an upper portion of the hole transport layer to form a light emitting auxiliary layer (not shown) having a thickness of 100 Å.

On an upper portion of the light emitting auxiliary layer, a pre-mixed blend (1:1) of Compound HT1 (host) and Compound ETH85 (host), Compound AD-37 (phosphorescent dopant), and Compound 1 (boron dopant) were co-deposited at a weight ratio of 82:15:3 to form a light emitting layer having a thickness of 200 Å.

TSPO1 was deposited on an upper portion of the light emitting layer to form a hole blocking layer having a thickness of 200 Å, and TPBi was deposited on an upper portion of the hole blocking layer to form an electron transport layer having a thickness of 300 Å. LiF was deposited on an upper portion of the electron transport layer to form an electron injection layer having a thickness of 10 Å, and A₁ was deposited on the upper portion of the electron injection layer to form a cathode having a thickness of 3000 Å, and thereafter, Compound P4 was deposited on an upper portion of the cathode to form a capping layer having a thickness of 700 Å, thereby completing the manufacture of a light emitting element.

### [(Materials Used in Manufacturing Light Emitting Elements)]

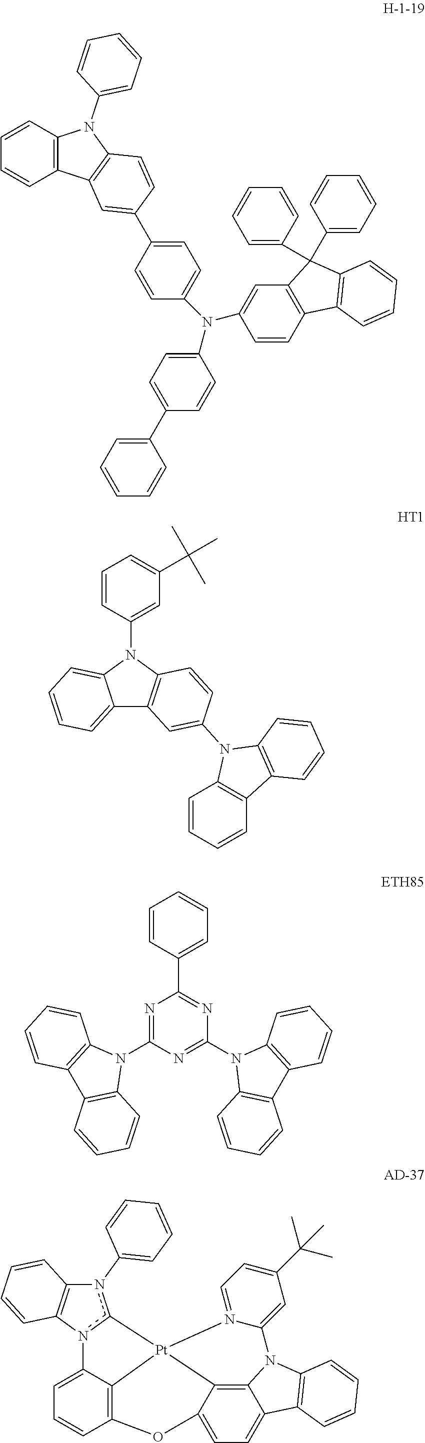

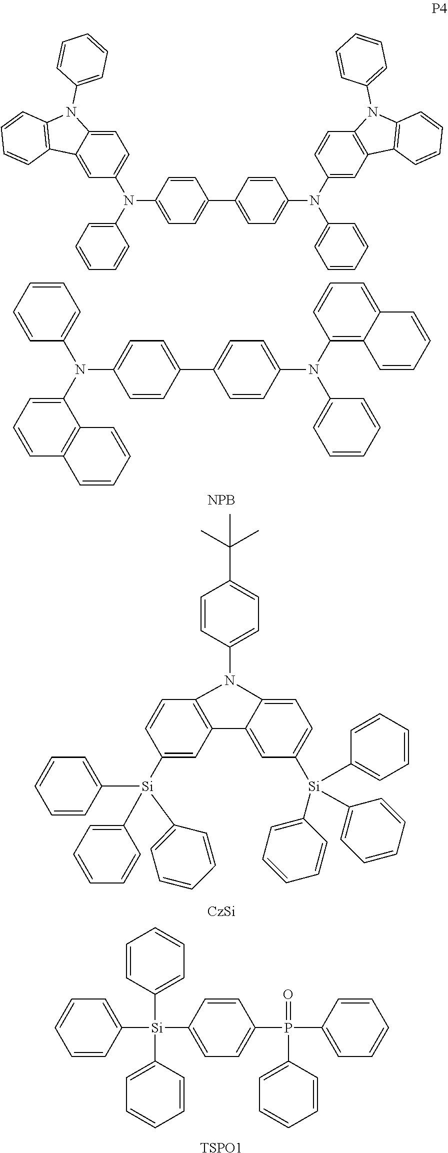

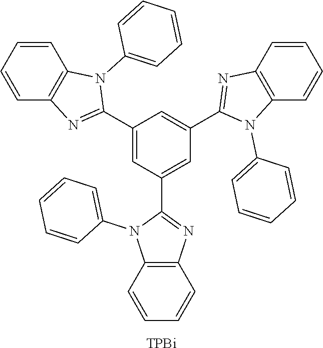

### (2) Evaluation of Light Emitting Elements

Table 2 below shows the evaluation of light emitting elements of the Comparative Examples and the Examples. The driving voltage (V), luminous efficiency (cd/A), maximum light emission wavelength (nm), and lifespan ratio at a current density of 9 mA/cm² were measured using a Keithley MU 236 and a luminance meter PR650. When a driving voltage (V) value is low, high power efficiency is achieved even when a light emitting element or material with the same quantum efficiency is used compared to a case in which the driving voltage (V) value is high. A lifespan ratio (T95) value indicates the time taken until luminance of the light emitting element reaches 95%, and the time taken until the luminance of the light emitting element of Comparative Example 1 reached 95% was defined as 1, by which the time taken until the luminance of the rest of the light emitting elements reached 95% was expressed in relative values.

TABLE 2

| | | | | | Light | Maximum | |
|---|---|---|---|---|---|---|---|
| | Host | | Light emitting | Driving | emission | luminous | Lifespan |
| | (HT:ETH | Sensitizer | material | voltage | efficiency | wavelength | (T95) |
| | 5:5) | (15 wt %) | (3 wt %) | (V) | (cd/A) | (nm) | ratio |
| Example 1 | HT1:ETH85 | AD-37 | Compound 1 | 4.2 | 28.4 | 460 | 7.3 |
| Example 2 | HT1:ETH85 | AD-37 | Compound 91 | 4.0 | 32.6 | 457 | 8.4 |
| Example 3 | HT1:ETH85 | AD-37 | Compound 125 | 4.2 | 29.7 | 458 | 7.7 |
| Example 4 | HT1:ETH85 | AD-37 | Compound 143 | 4.3 | 30.8 | 456 | 6.8 |
| Example 5 | HT1:ETH85 | AD-37 | Compound 180 | 4.3 | 32.3 | 458 | 8.5 |
| Comparative | HT1:ETH85 | AD-37 | Comparative | 4.8 | 19.2 | 457 | 1 |
| Example 1 | | | Example | | | | |
| | | | Compound C1 | | | | |
| Comparative | HT1:ETH85 | AD-37 | Comparative | 4.7 | 21.3 | 456 | 0.8 |
| Example 2 | | | Example | | | | |
| | | | Compound C2 | | | | |
| Comparative | HT1:ETH85 | AD-37 | Comparative | 4.5 | 23.2 | 458 | 2.2 |
| Example 3 | | | Example | | | | |
| | | | Compound C3 | | | | |
| Comparative | HT1:ETH85 | AD-37 | Comparative | 4.4 | 24.1 | 460 | 4.5 |
| Example 4 | | | Example | | | | |
| | | | Compound C4 | | | | |
| Comparative | HT1:ETH85 | AD-37 | Comparative | 4.4 | 24.6 | 460 | 6.0 |
| Example 5 | | | Example | | | | |
| | | | Compound C5 | | | | |

Referring to Table 2, it can be seen that the light emitting elements of Examples 1 to 5 exhibit long-lifespan properties, as compared to the light emitting elements of Comparative Examples 1 to 5. It can be seen that the light emitting elements of Examples 1 to 5 exhibit excellent light luminous efficiency, as compared to the light emitting elements of Comparative Examples 1 to 5.

Compounds 1, 91, 125, 143, and 180 each have an asymmetric pentaphenyl group introduced thereto as a substituent, and thus, may effectively protect the p orbital of the boron atom, and have a shape closer to a spherical shape compared to a dopant to which a symmetric aryl group is introduced, and thus, have the properties of improving the stability of a molecule. It can be seen that the light emitting elements of Examples 1 to 5, respectively including Compounds 1, 91, 125, 143, and 180, have improved luminous efficiency and lifespan. Therefore, in an embodiment, a light emitting element including a polycyclic compound may exhibit high-luminous efficiency and long-lifespan properties. In an embodiment, a light emitting element including a polycyclic compound may exhibit low-driving voltage properties, and thus, may contribute to improved luminous efficiency.

The stability of the comparative Example Compounds C1 and C2 is reduced because each of the comparative Example Compounds C1 and C2 does not have a carbazole group. As a result, light emitting elements respectively including Comparative Example Compounds C1 and C2 have degraded luminous efficiency and lifespan properties compared to light emitting elements that include the Example Compounds. In Comparative Example Compounds C3 to C5, a carbazole group is bonded as in the Example Compounds. However, Comparative Example Compounds C3 to C5 differ in that an aryl group bonded to the nitrogen atom forming a condensed ring with the boron atom is a symmetric aryl group rather than an asymmetric aryl group. Light emitting elements respectively including Comparative Example Compounds C3 to C5 in which a symmetric aryl group is bonded to a nitrogen atom, unlike the Example Compounds, have degraded luminous efficiency and lifespan properties compared to light emitting elements including Example Compounds. When an asymmetric aryl group is introduced, the P orbital of a boron atom may be protected equally or better even with a relatively lower molecular weight compared to a dopant to which a symmetric aryl group is introduced. The polycyclic compound according to an embodiment has a shape that is closer to a spherical shape compared to a dopant to which a symmetric aryl group is introduced, so that the stability of the molecule is improved, and the sublimation temperature is also improved to 330° C., thereby facilitating the synthesis.

A light emitting element according to an embodiment and a display device including the same may include a polycyclic compound according to an embodiment, and thus, may exhibit high-luminous efficiency and long-lifespan properties.

A polycyclic compound according to an embodiment may contribute to high luminous efficiency and long lifespan of a light emitting element.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

1. A light emitting element comprising:
a first electrode;
a hole transport region disposed on the first electrode;
a light emitting layer disposed on the hole transport region;
an electron transport region disposed on the light emitting layer; and
a second electrode disposed on the electron transport region, wherein
the light emitting layer includes a first compound represented by Formula 1: 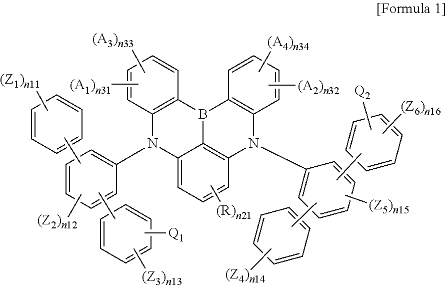
wherein in Formula 1,
Z₁ to Z₆ are each independently a hydrogen atom, a deuterium atom, a substituted or unsubstituted alkyl group having 1 to 30 carbon atoms, or a substituted or unsubstituted aryl group having 6 to 30 ring-forming carbon atoms,
R is a hydrogen atom, a deuterium atom, a substituted or unsubstituted alkyl group having 1 to 20 carbon atoms, a substituted or unsubstituted cycloalkyl group having 3 to 60 ring-forming carbon atoms, a substituted or unsubstituted aryl group having 6 to 60 ring-forming carbon atoms, or a substituted or unsubstituted heteroaryl group having 2 to 60 ring-forming carbon atoms,
A₁ and A₂ are each independently a substituted or unsubstituted heteroaryl group having 2 to 60 ring-forming carbon atoms,
A₃ and A₄ are each independently a hydrogen atom, a deuterium atom, a substituted or unsubstituted alkyl group having 1 to 20 carbon atoms, or a substituted or unsubstituted aryl group having 6 to 60 ring-forming carbon atoms,
Q₁ and Q₂ are each independently a substituted or unsubstituted biphenyl group,
n11 and n14 are each independently an integer from 0 to 5,
n12, n15, n21, n33, and n34 are each independently an integer from 0 to 3,
n13 and n16 are each independently an integer from 0 to 4,
n31 and n32 are each independently an integer from 1 to 4,
the sum of n31 and n33 is an integer from 1 to 4, and
the sum of n32 and n34 is an integer from 1 to 4.

2. The light emitting element of claim 1, wherein the light emitting layer further comprises at least one of a second compound represented by Formula HT-1, a third compound represented by Formula ET-1, and a fourth compound represented by Formula D-1: 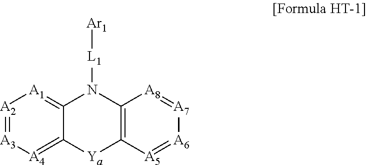
wherein in Formula HT-1,
A₁ to A₈ are each independently N or C(R₅₁),
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, C(R₅₂)(R₅₃), or Si(R₅₄)(R₅₅),
Ar₁ is a substituted or unsubstituted aryl group having 6 to 30 ring-forming carbon atoms or a substituted or unsubstituted heteroaryl group having 2 to 30 ring-forming carbon atoms, and
R₅₁ to R₅5 are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring; 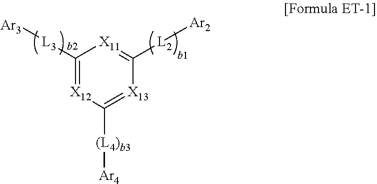
wherein in Formula ET-1,
at least one of X₁₁ to X₁₃ is each N,
the remainder of X₁₁ to X₁₃ is each independently C(R₅₆),
R₅₆ is a hydrogen atom, a deuterium atom, a substituted or unsubstituted alkyl group having 1 to 20 carbons, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer from 0 to 10,
Ar₂ to Ar₄ are each independently a hydrogen atom, a deuterium atom, a substituted or unsubstituted alkyl group having 1 to 20 carbons, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms; 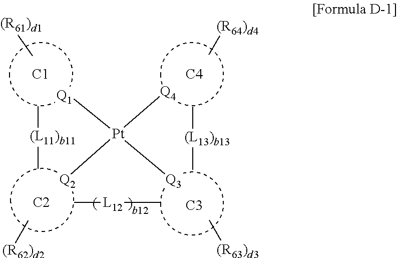
wherein in Formula D-1,
Q₁ to Q₄ are each independently C or N,
C1 to C4 are each independently a substituted or unsubstituted hydrocarbon ring having 5 to 30 ring-forming carbon atoms or a substituted or unsubstituted heterocycle having 2 to 30 ring-forming carbon atoms,
L₁₁ to L₁₃ are each independently a direct linkage, *—O—* , *—S—* , 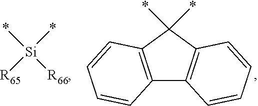
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 are each independently an integer from 0 to 4.

3. The light emitting element of claim 1, wherein the first compound is represented by Formula 2: 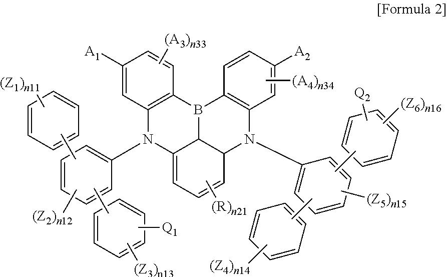
wherein in Formula 2,
Z₁ to Z₆, R, A₁ to A₄, Q₁, Q₂, n11 to n16, n21, n33, and n34 are the same as defined in Formula 1.

4. The light emitting element of claim 1, wherein the first compound is represented by Formula 3: 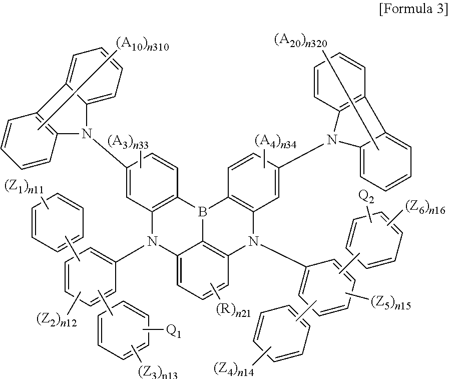
wherein in Formula 3,
A₁₀ and A₂₀ are each independently a hydrogen atom, a deuterium atom, a halogen atom, a cyano group, a substituted or unsubstituted silyl group, a substituted or unsubstituted oxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring,
n310 and n320 are each independently an integer from 0 to 8, and
Z₁ to Z₆, R, A₃, A₄, Q₁, Q₂, n11 to n16, n21, n33, and n34 are the same as defined in Formula 1.

5. The light emitting element of claim 1, wherein in Formula 1, R is a group represented by one of Formula X-1 to Formula X-8: 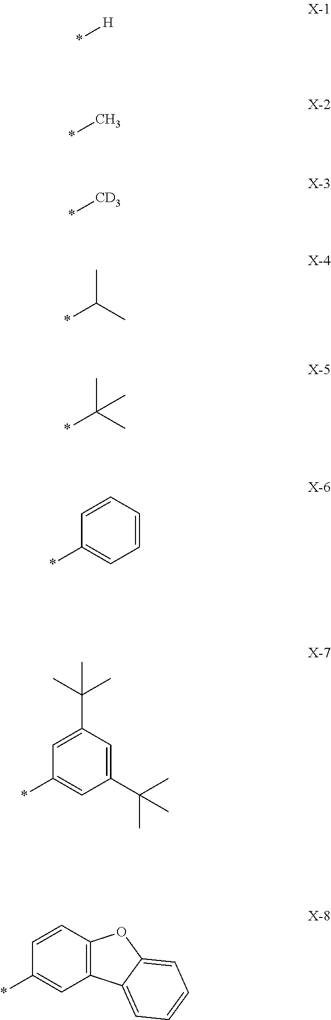
wherein in Formula X-1 to Formula X-8,
*— is a position connected to Formula 1.

6. The light emitting element of claim 1, wherein the first compound is represented by Formula 4: 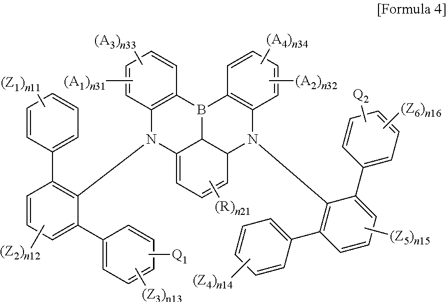
wherein in Formula 4,
Z₁ to Z₆, R, A₁ to A₄, Q₁, Q₂, n11 to n16, n21, and n31 to n34 are the same as defined in Formula 1.

7. The light emitting element of claim 6, wherein the first compound is represented by Formula 5-1 or Formula 5-2: 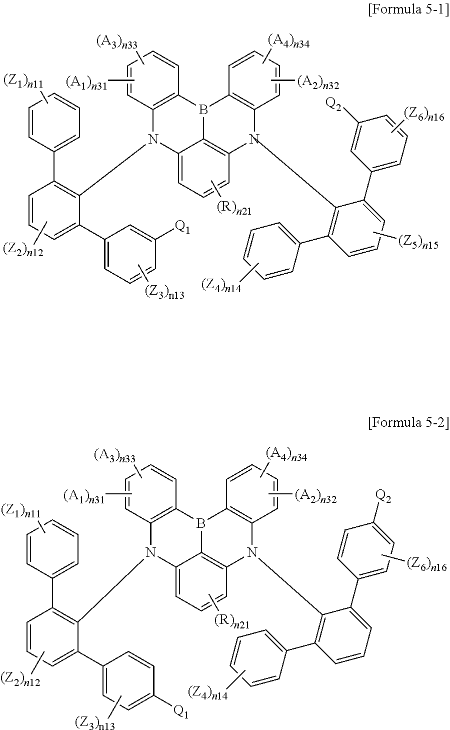
wherein in Formula 5-1 and Formula 5-2,
Z₁ to Z₆, R, A₁ to A₄, Q₁, Q₂, n11 to n16, n21, and n31 to n34 are the same as defined in Formula 1.

8. The light emitting element of claim 6, wherein the first compound is represented b one of Formula 6-1 to Formula 6-4: 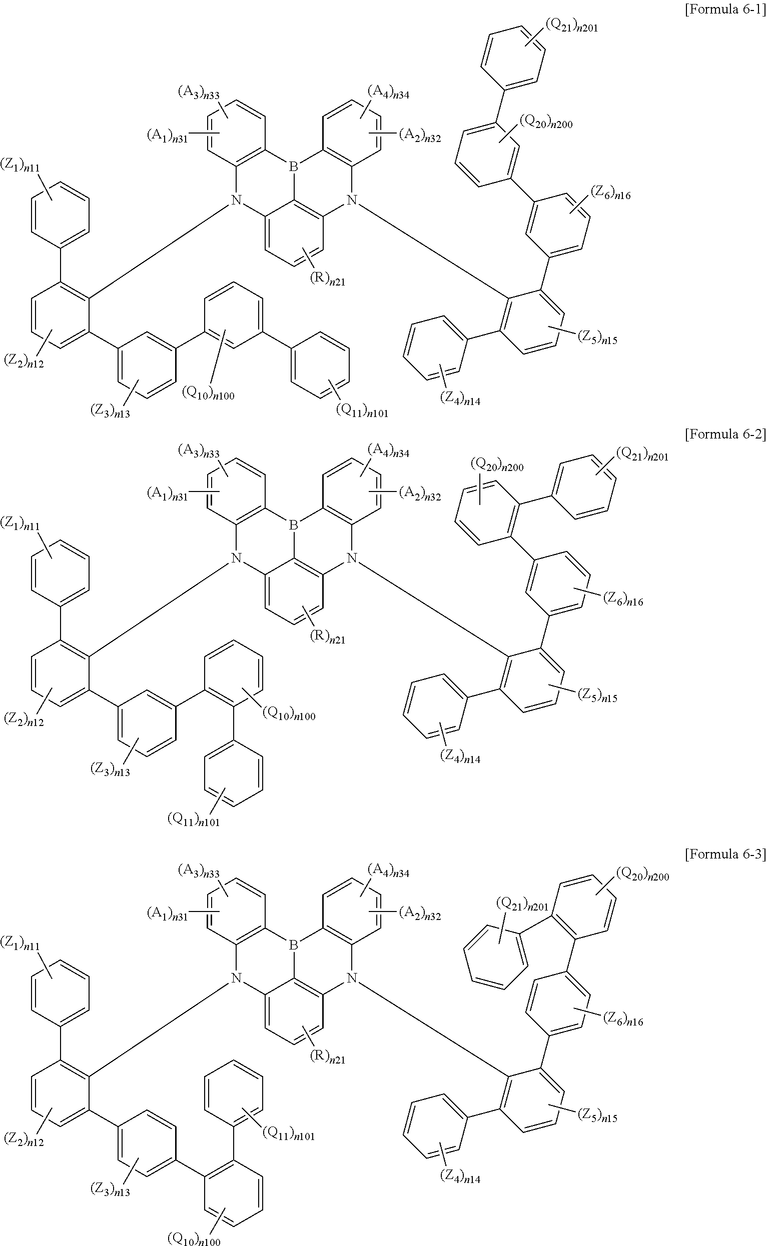 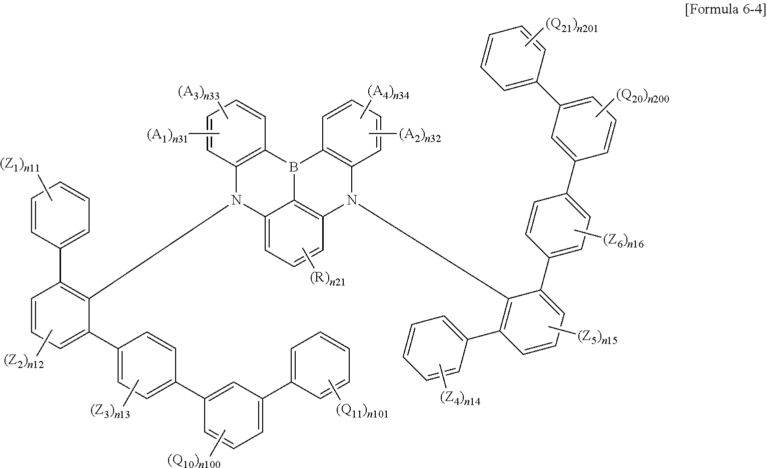
wherein in Formula 6-1 to Formula 6-4,
Q₁₀, Q₁₁, Q₂₀, and Q₂₁ are each independently a hydrogen atom, a deuterium atom, a halogen atom, a cyano group, a substituted or unsubstituted silyl group, a substituted or unsubstituted oxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring,
n100 and n200 are each independently an integer from 0 to 4,
n101 and n201 are each independently an integer from 0 to 5, and
A₁ to A₄, Z₁ to Z₆, R, n11 to n16, n21, and n31 to n34 are the same as defined in Formula 1.

9. The light emitting element of claim 1, wherein in Formula 1, Z₂ and Z₅ are each independently a group represented by one of Formula Y-1 to Formula Y-7: 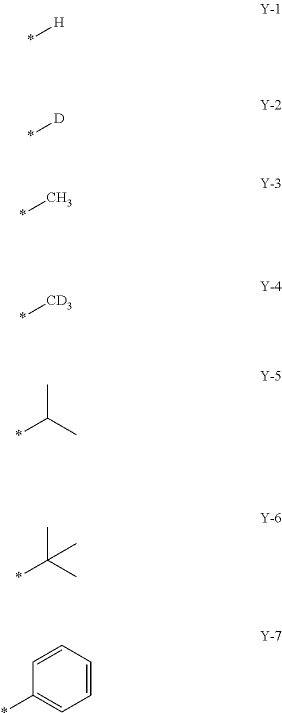
wherein in Formula Y-1 to Formula Y-7,
*— is a position connected to Formula 1.

10. The light emitting element of claim 1, wherein the first compound includes at least one compound selected from Compound Group 1:

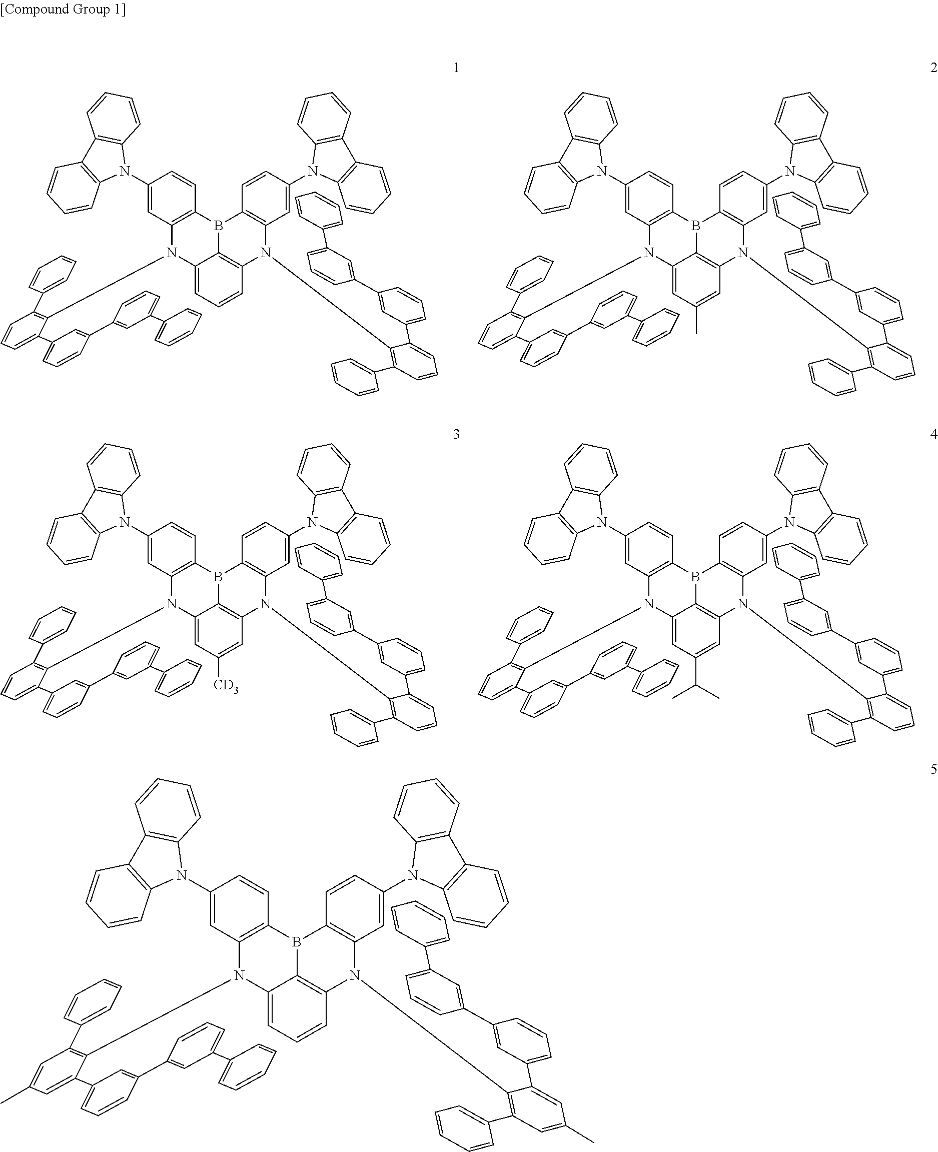

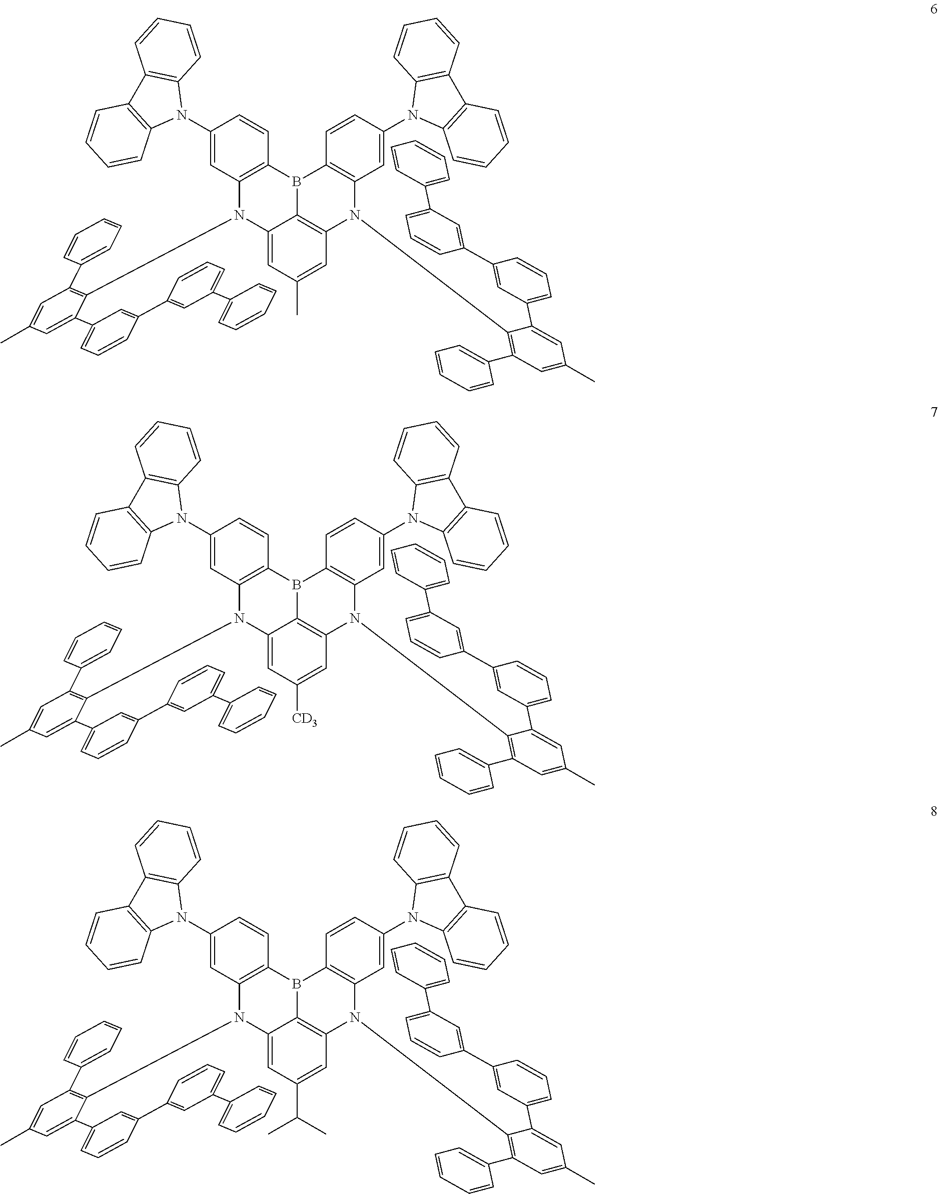

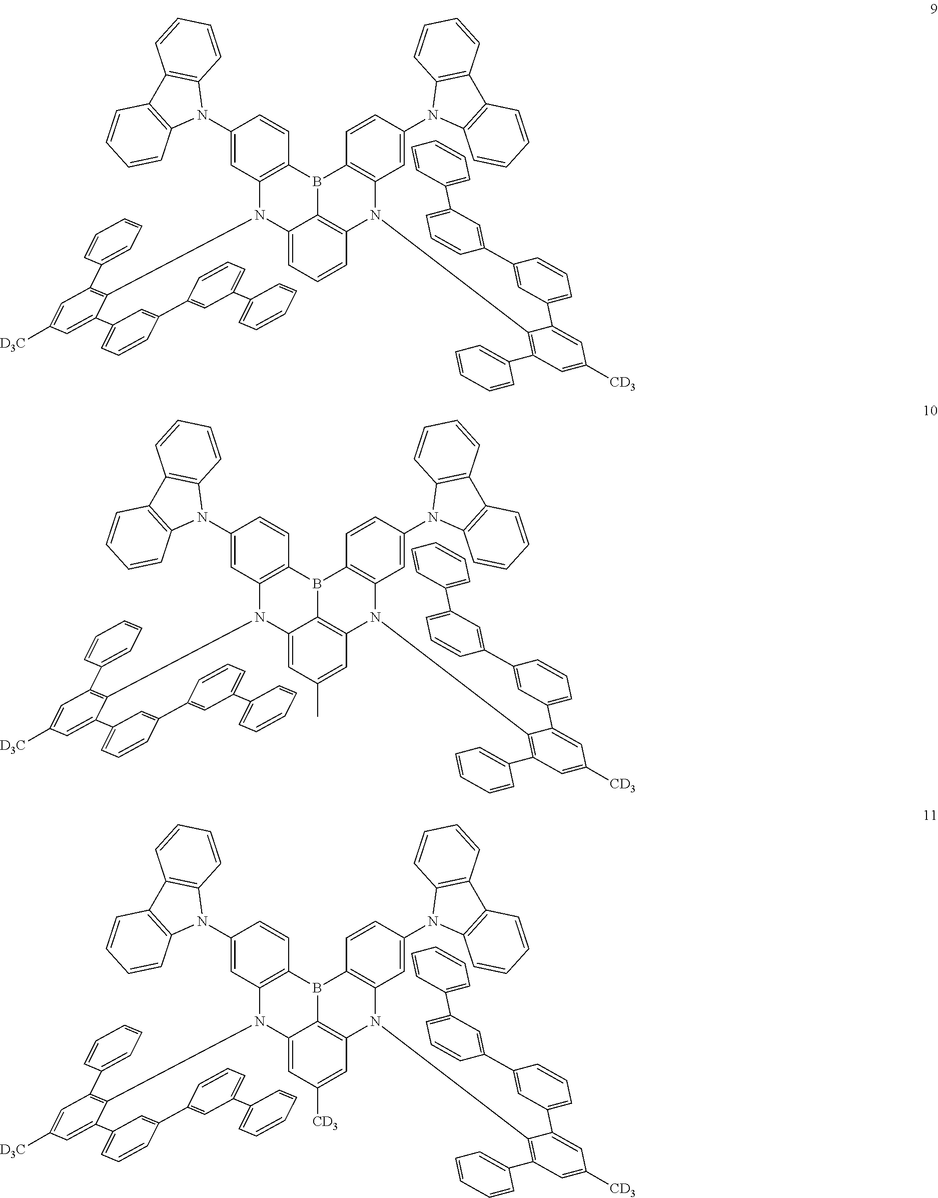

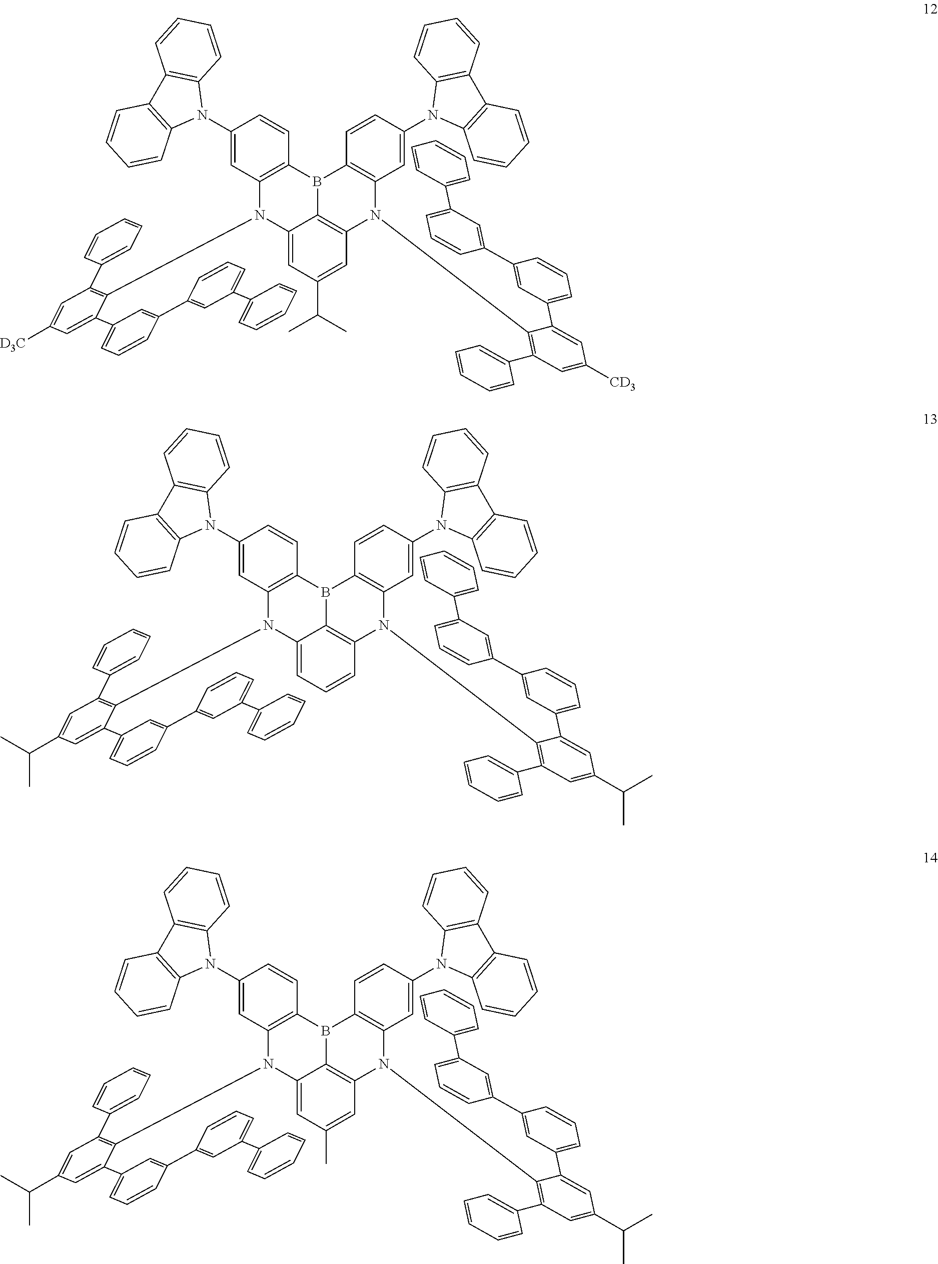

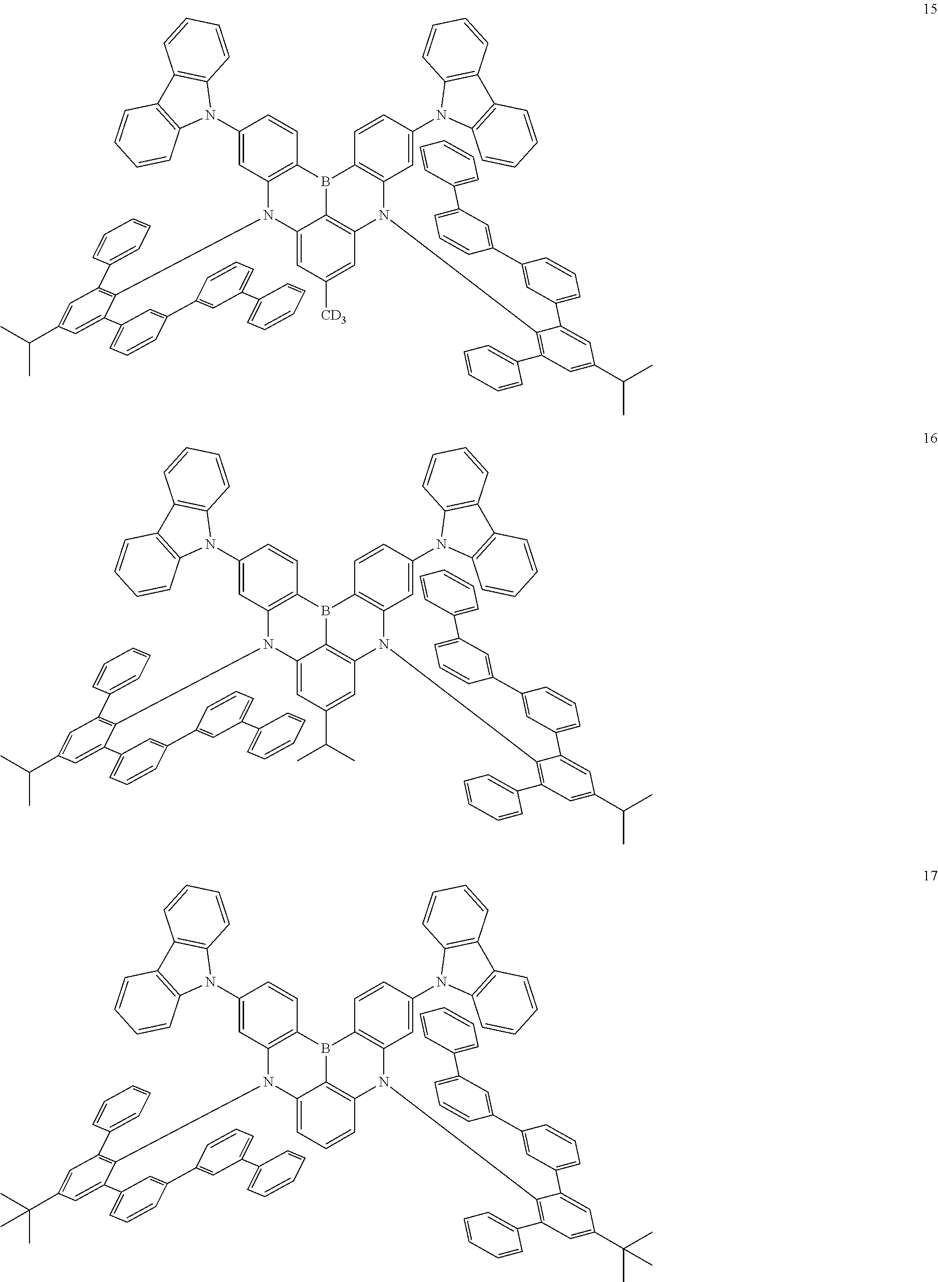

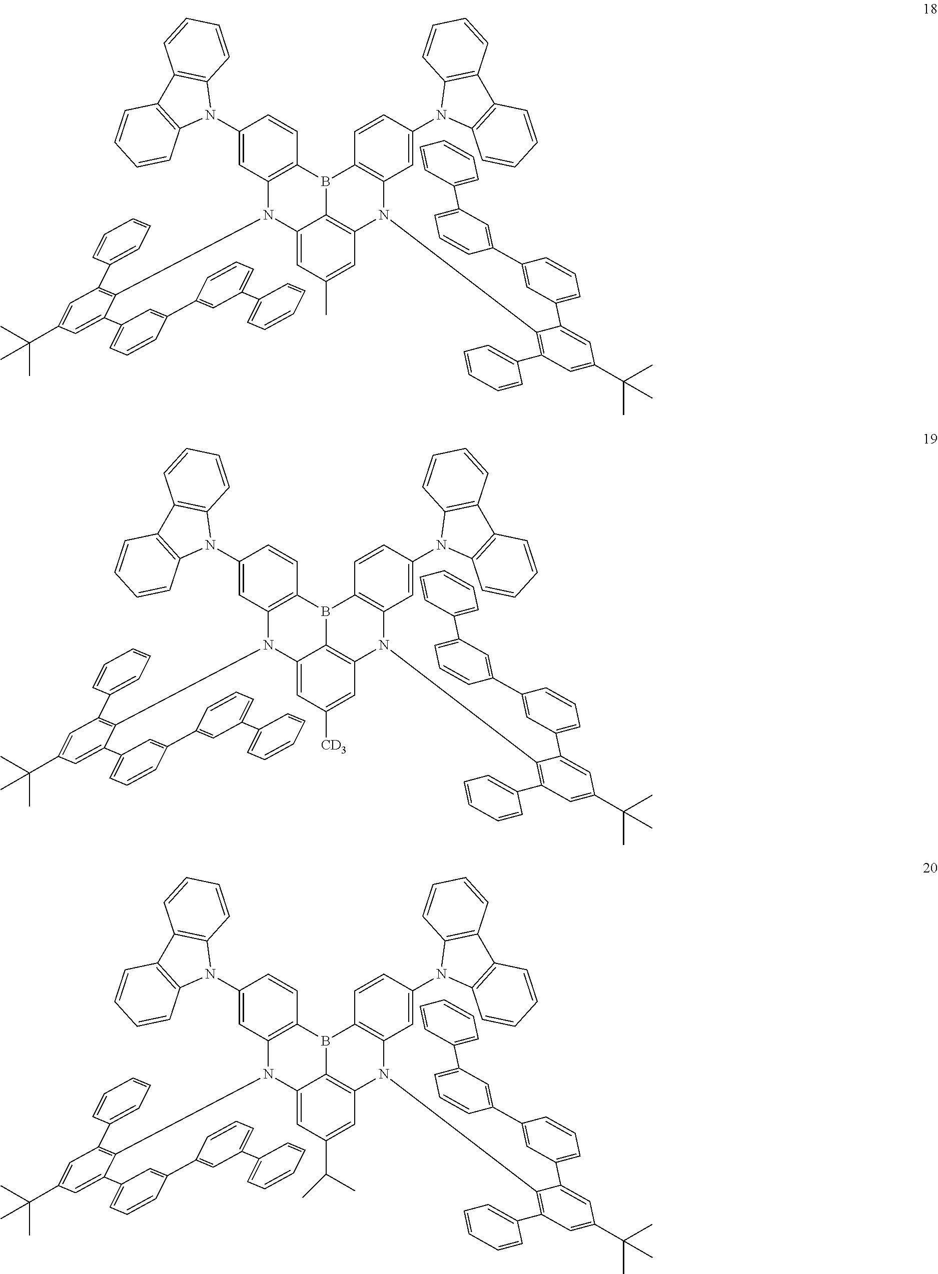

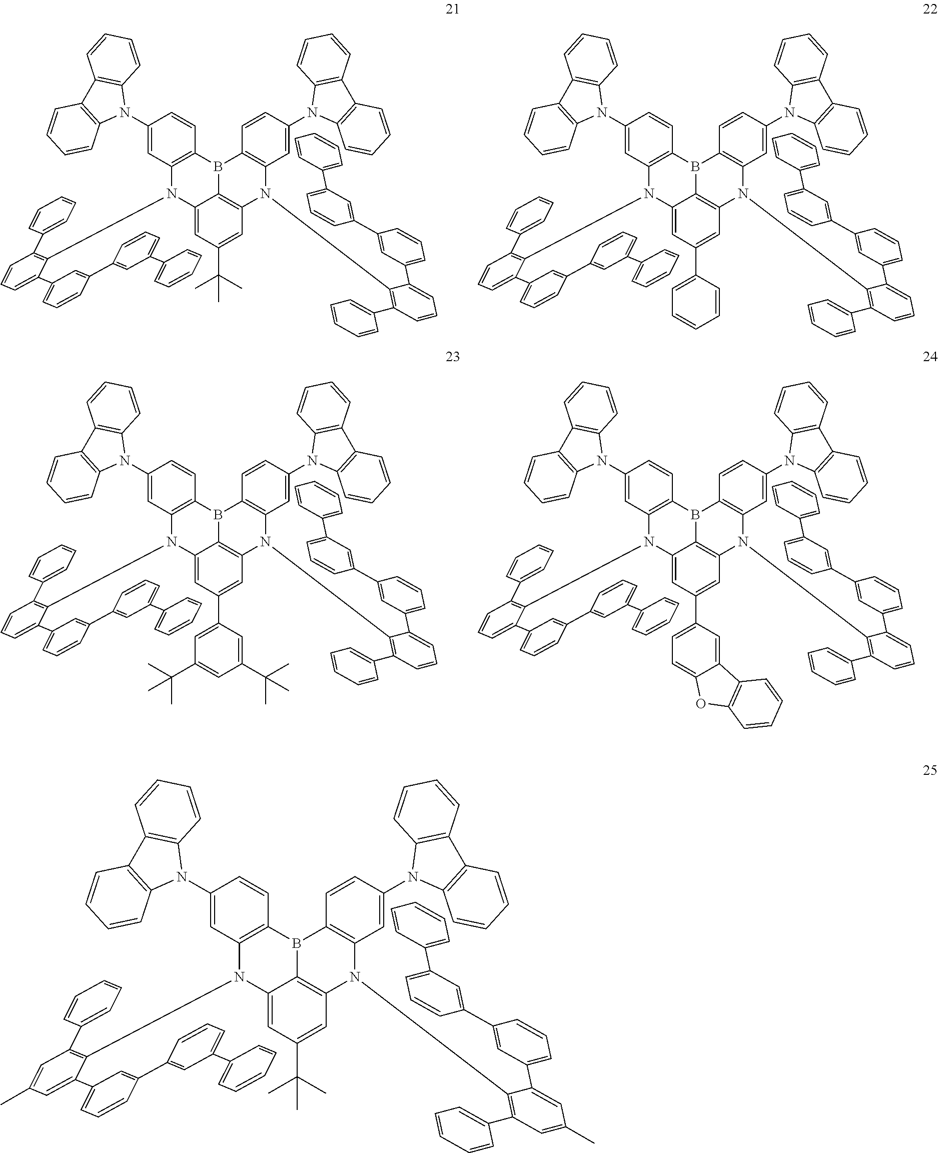

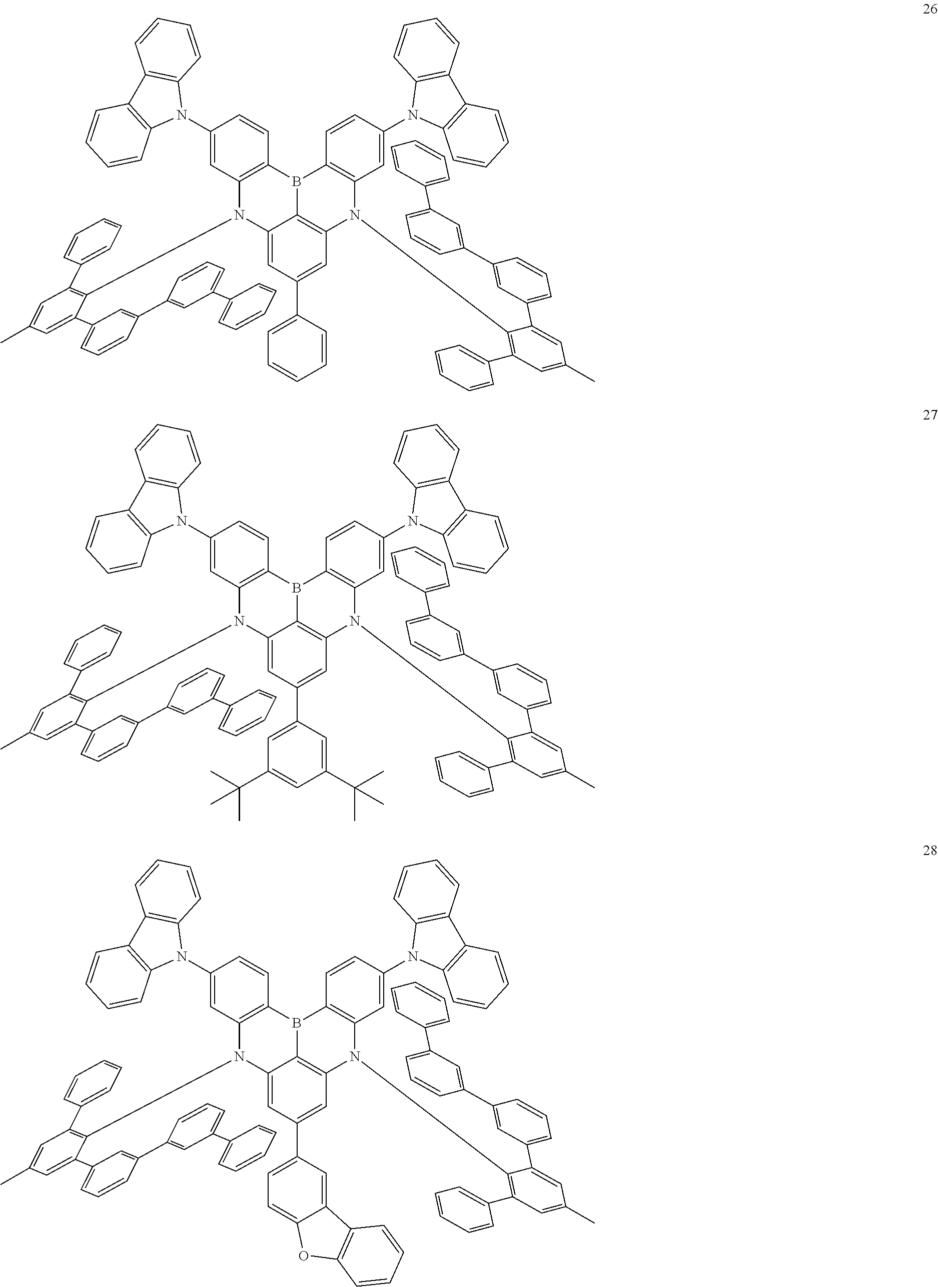

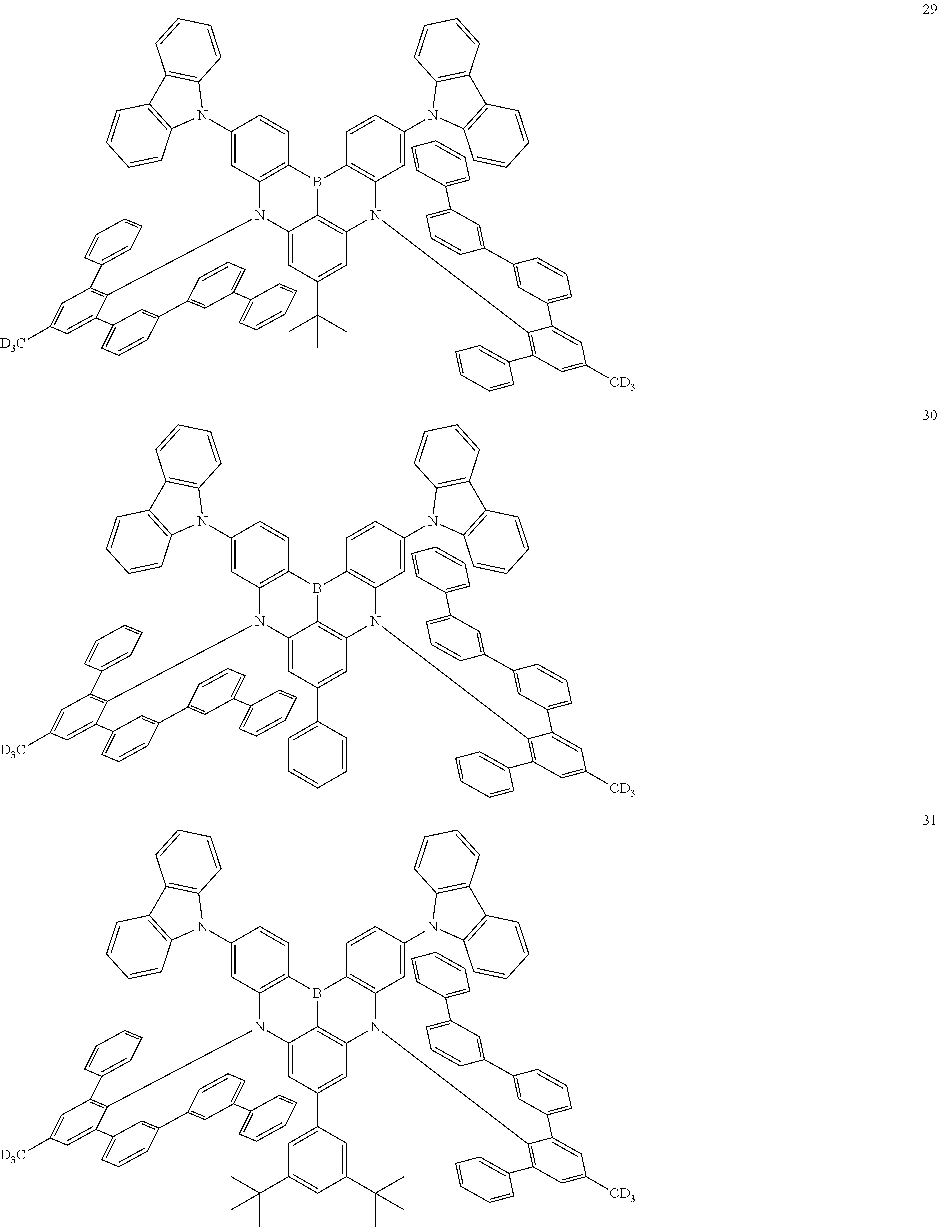

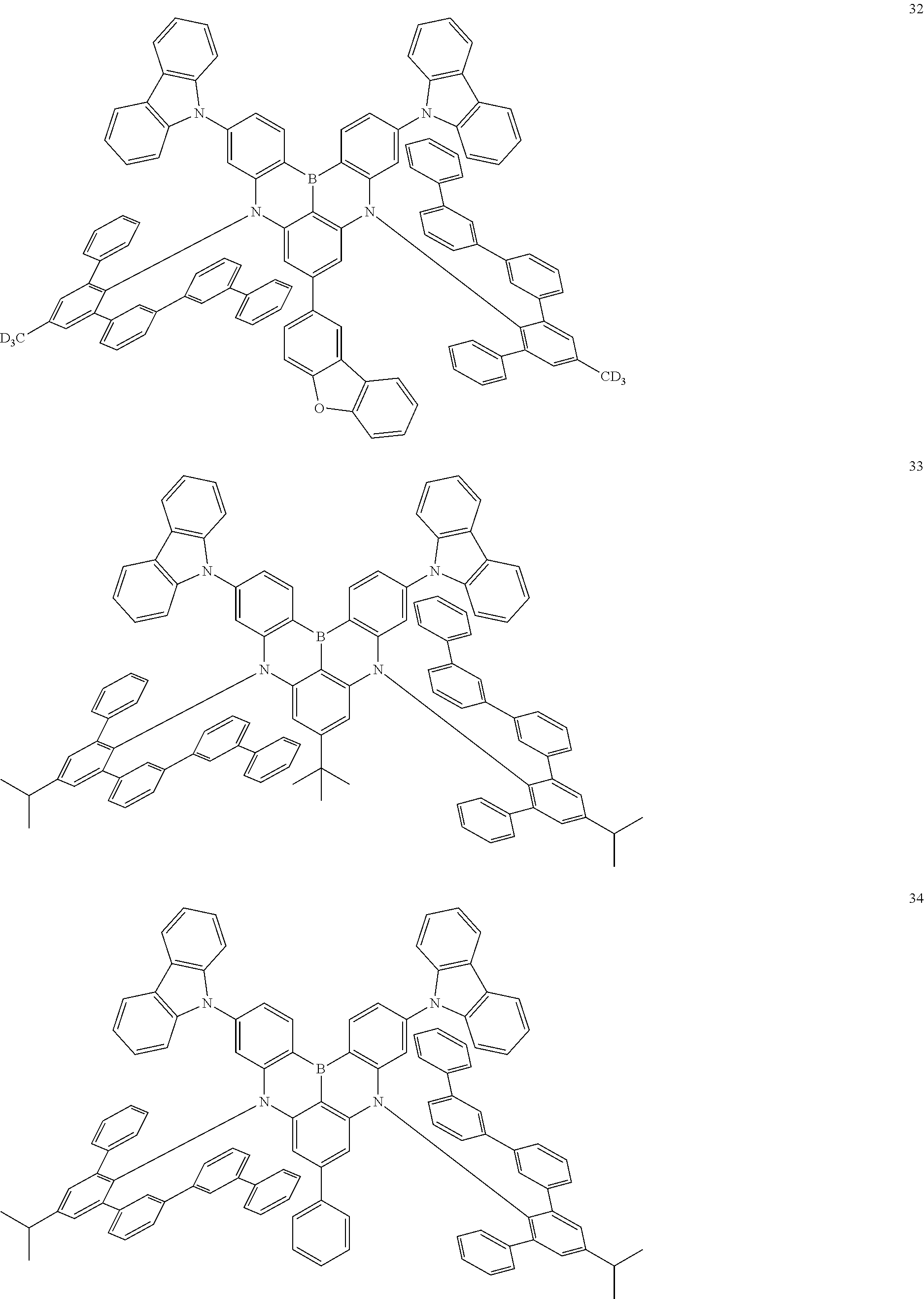

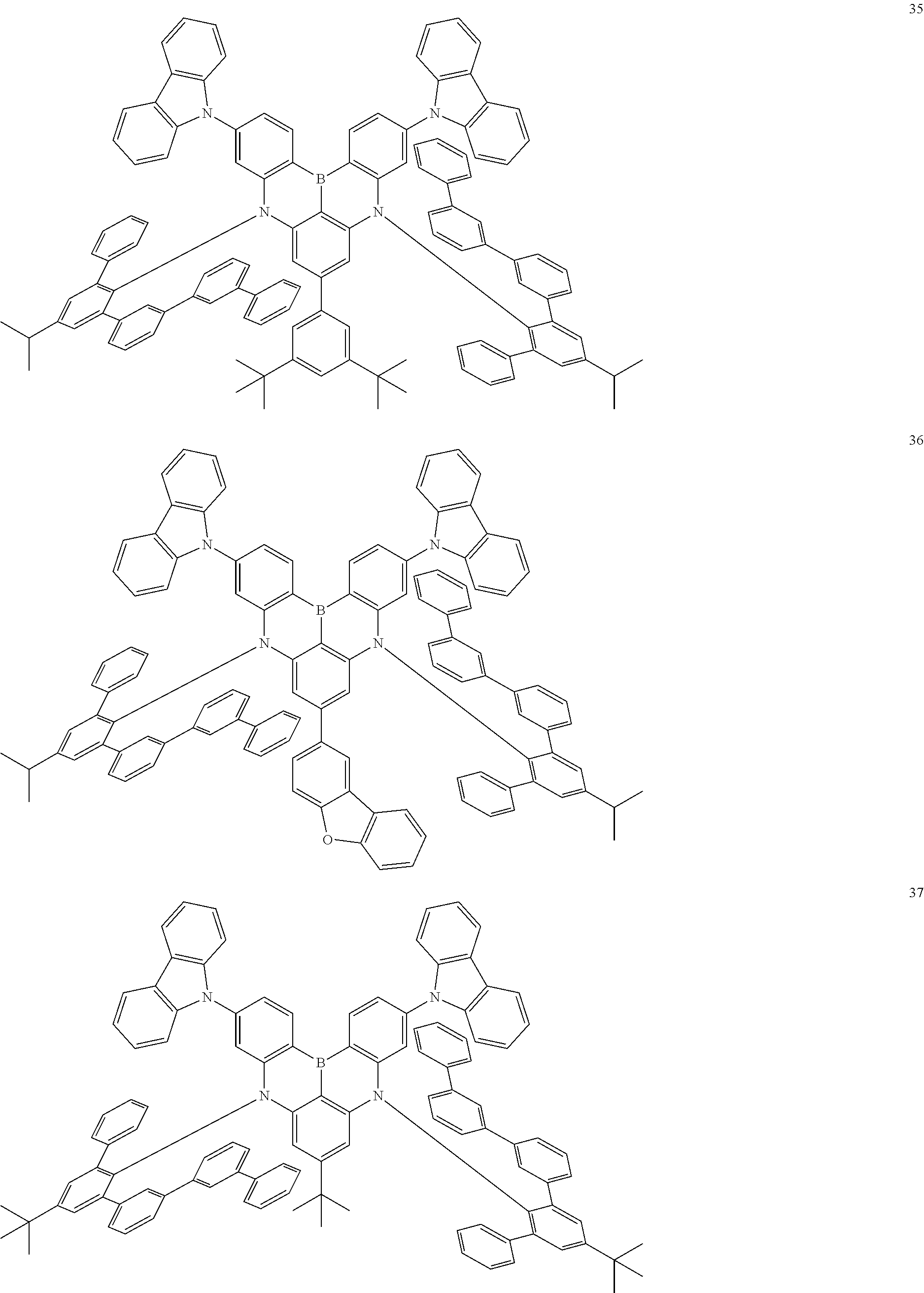

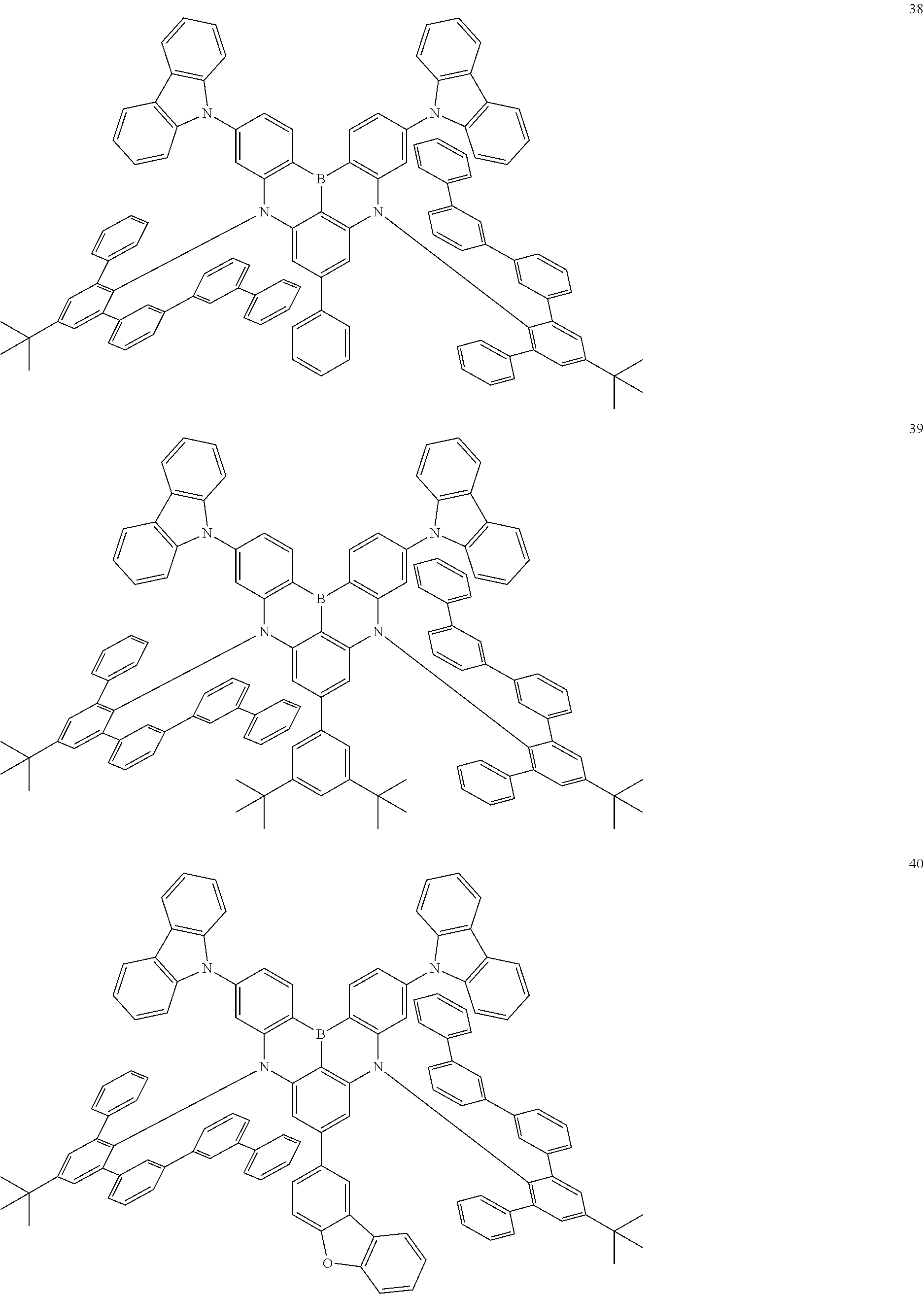

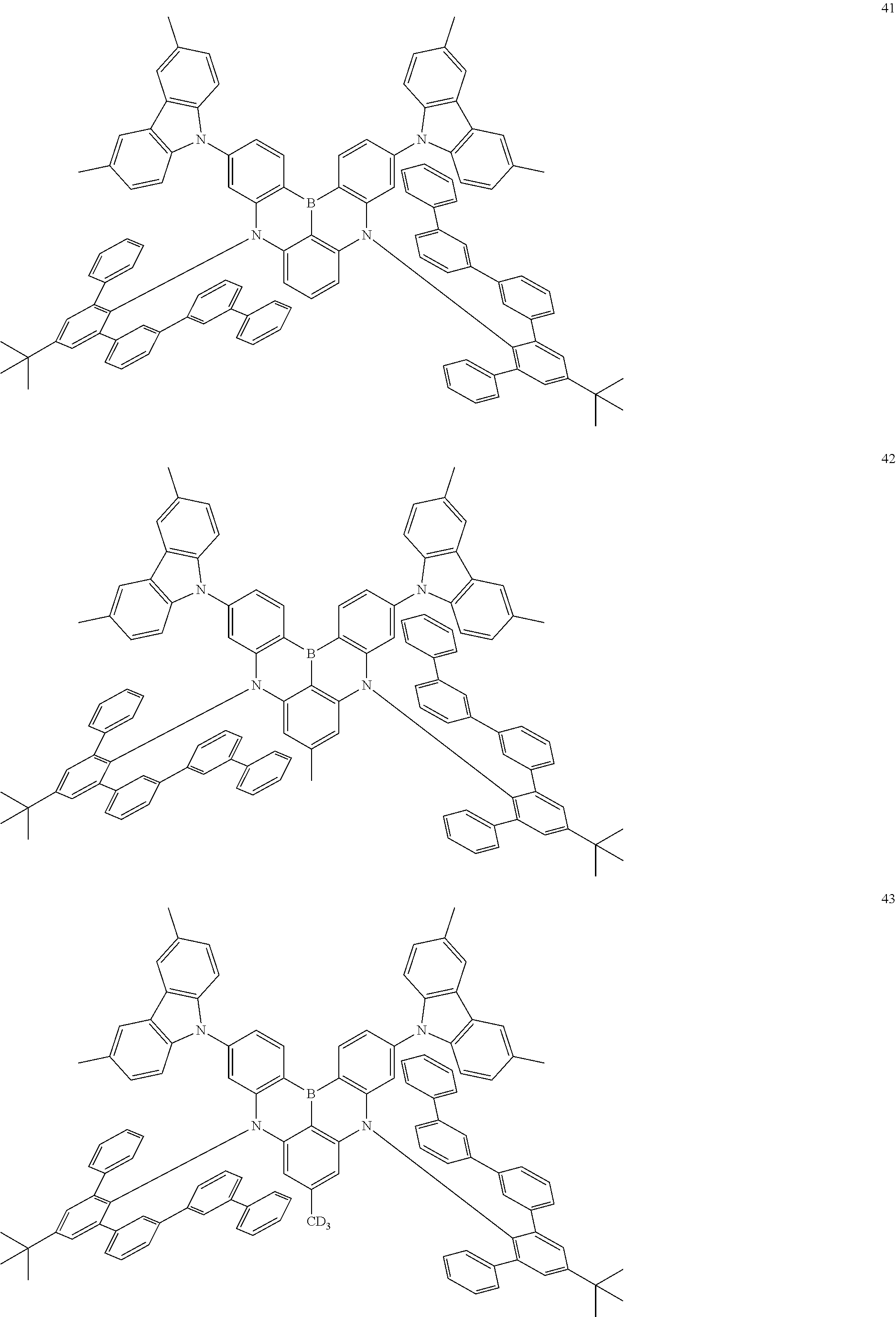

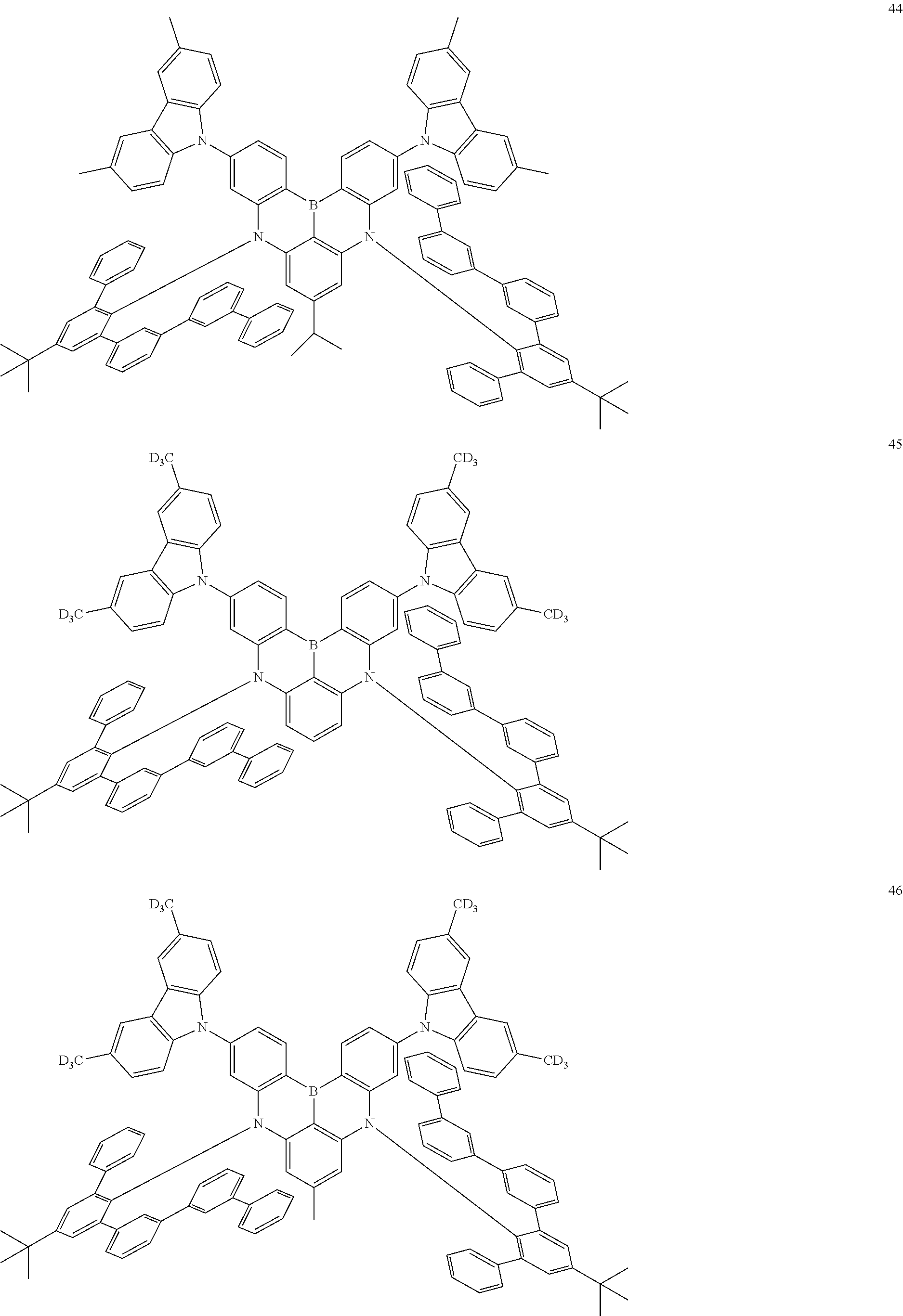

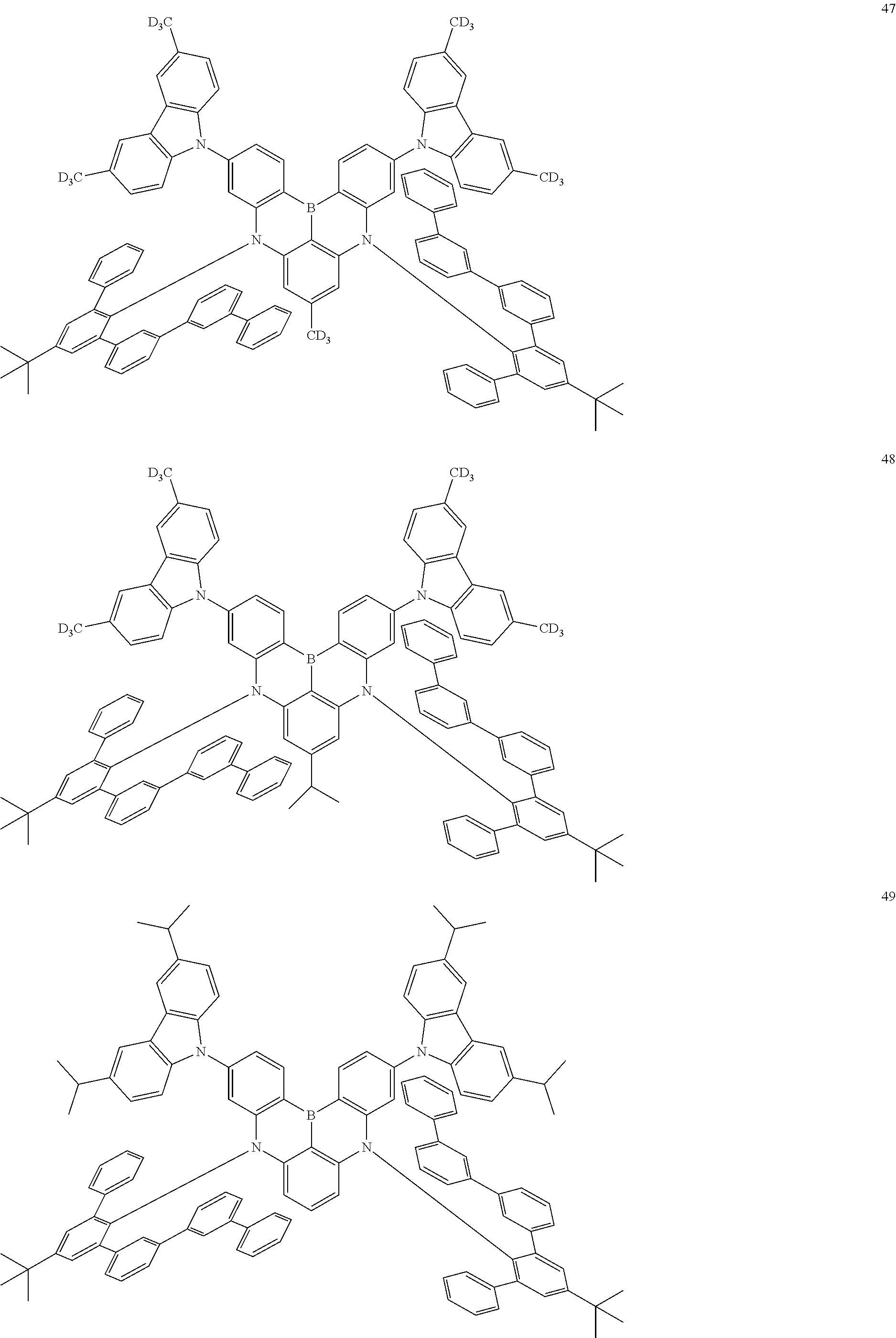

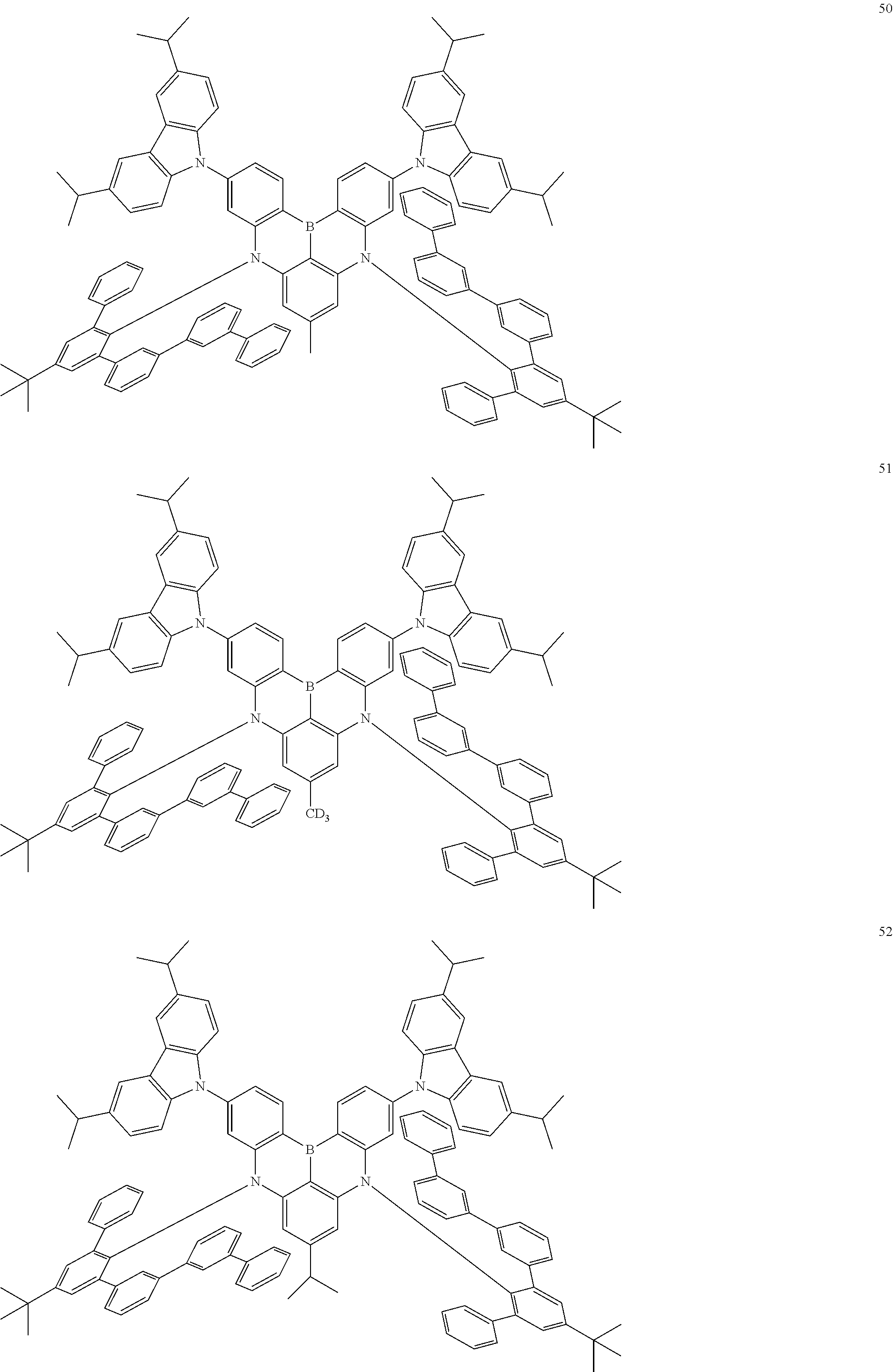

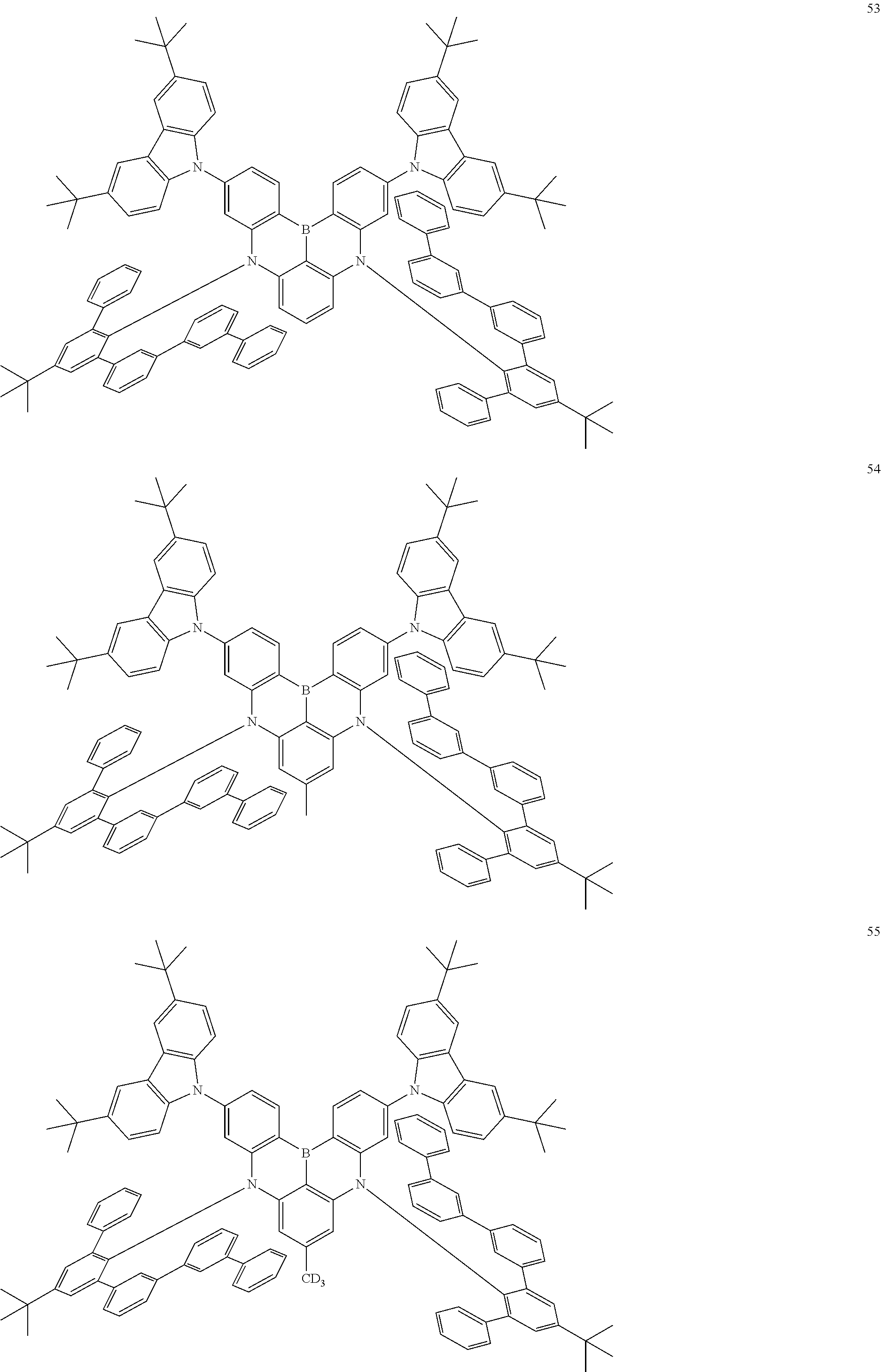

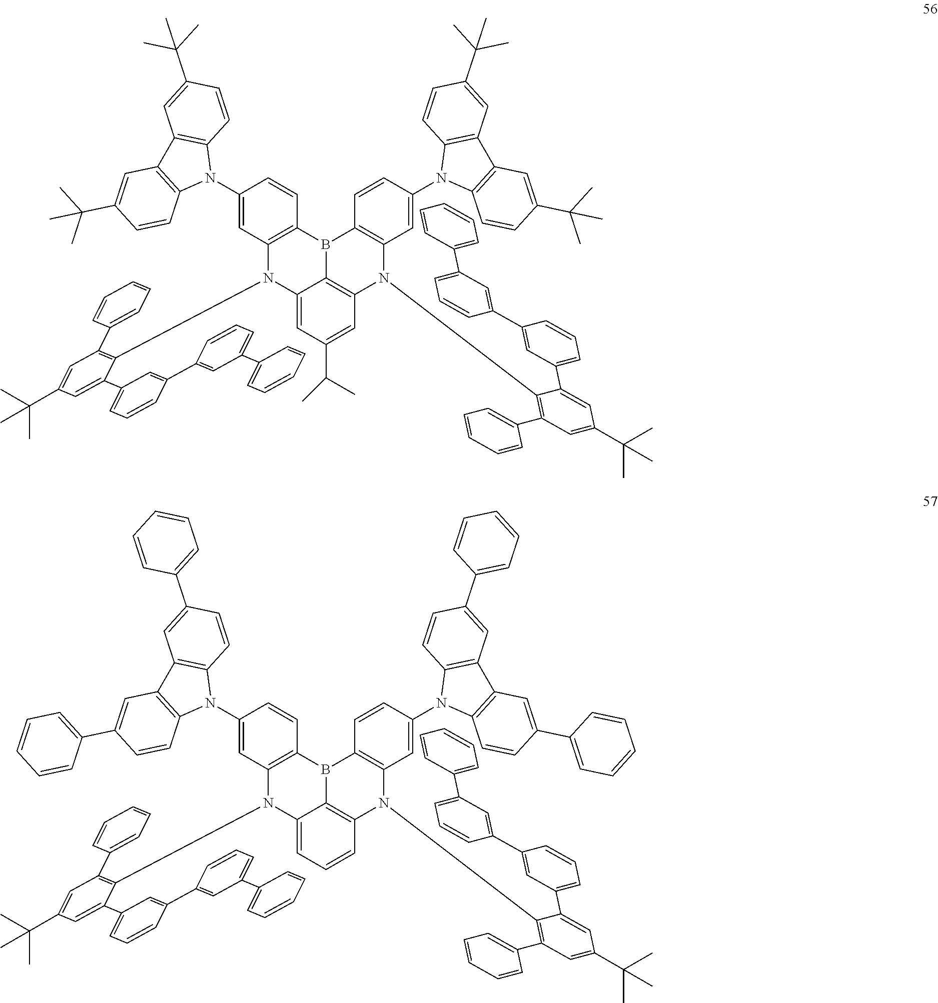

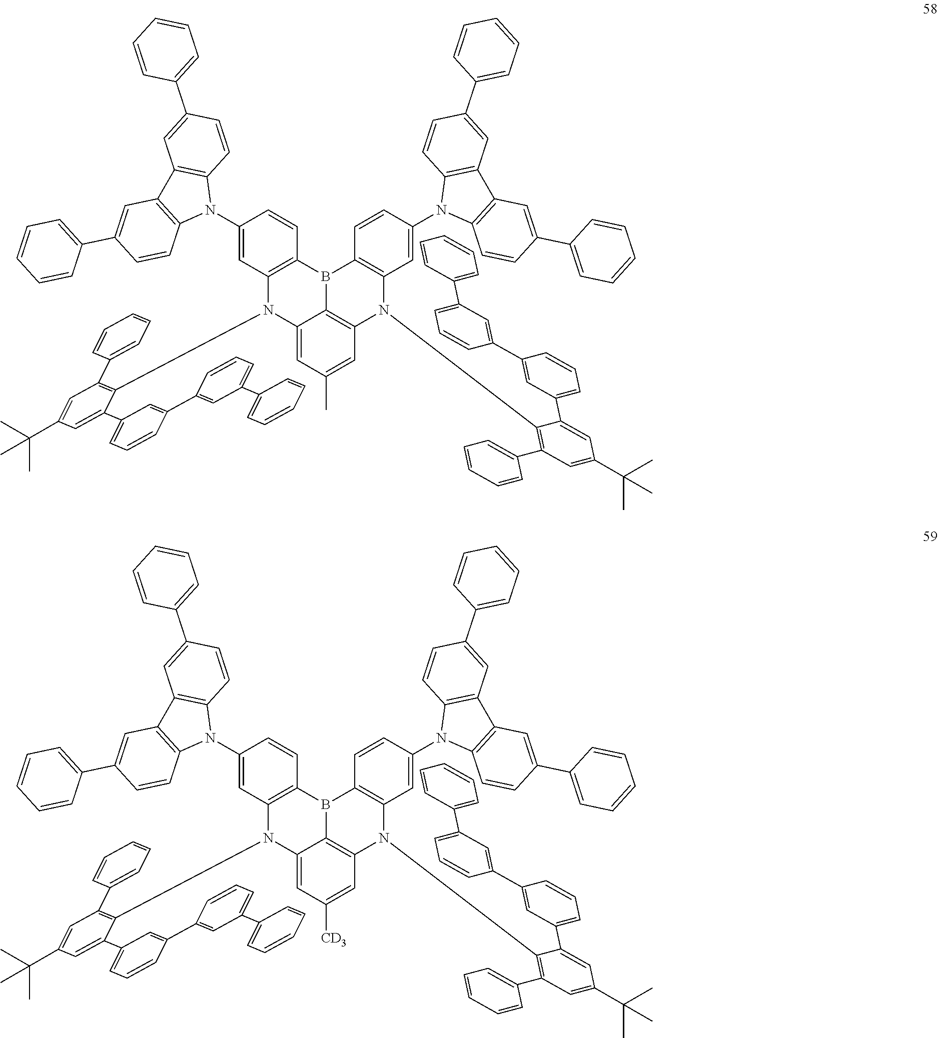

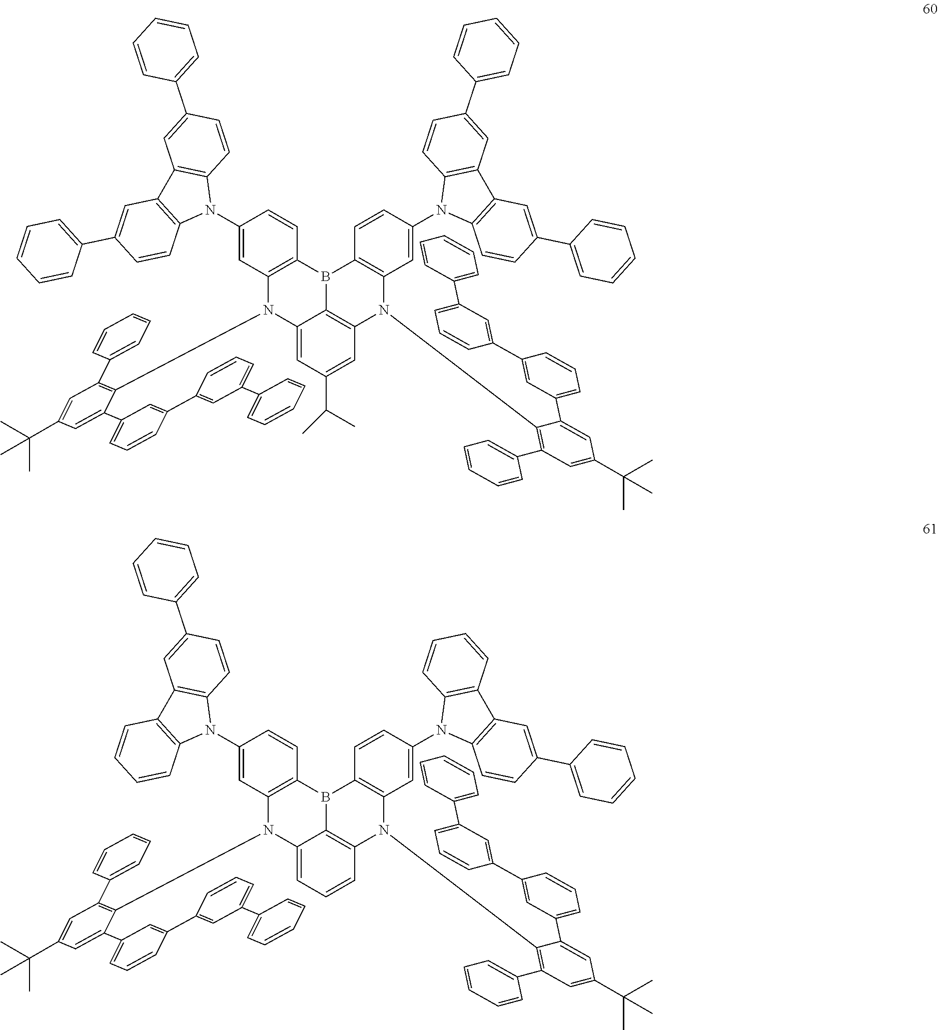

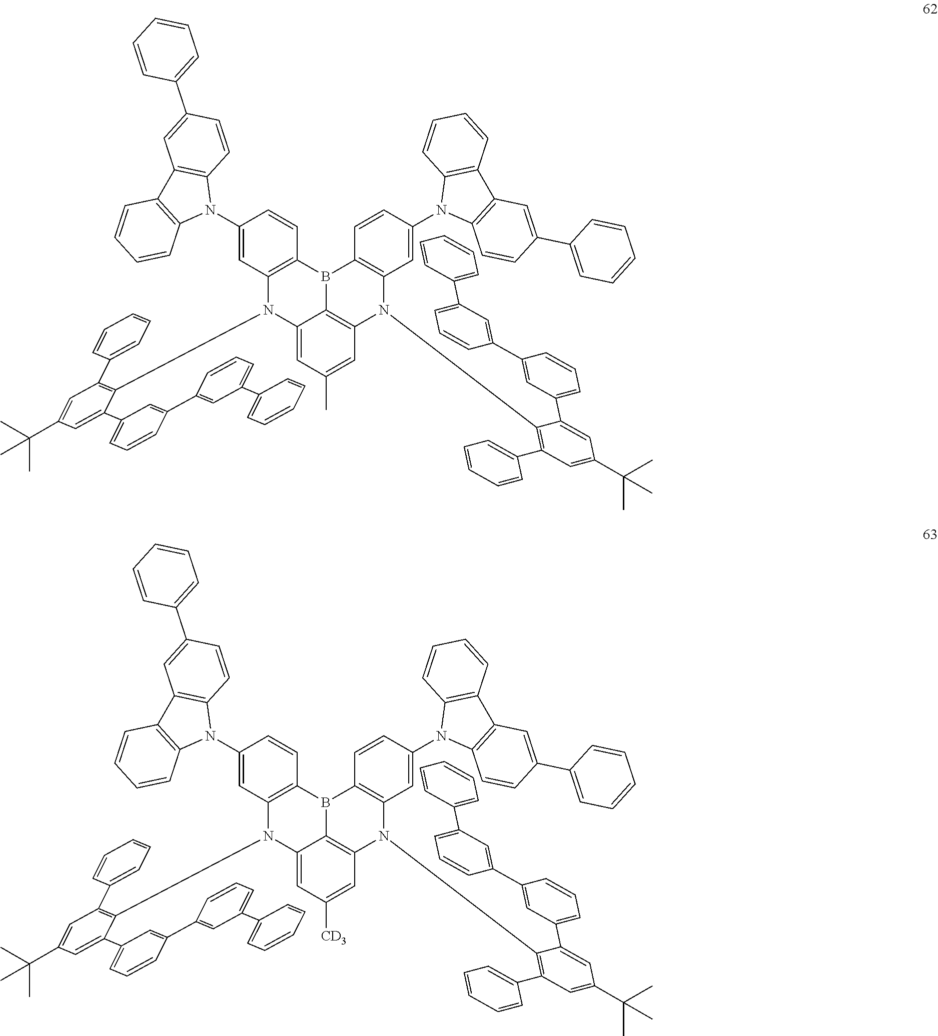

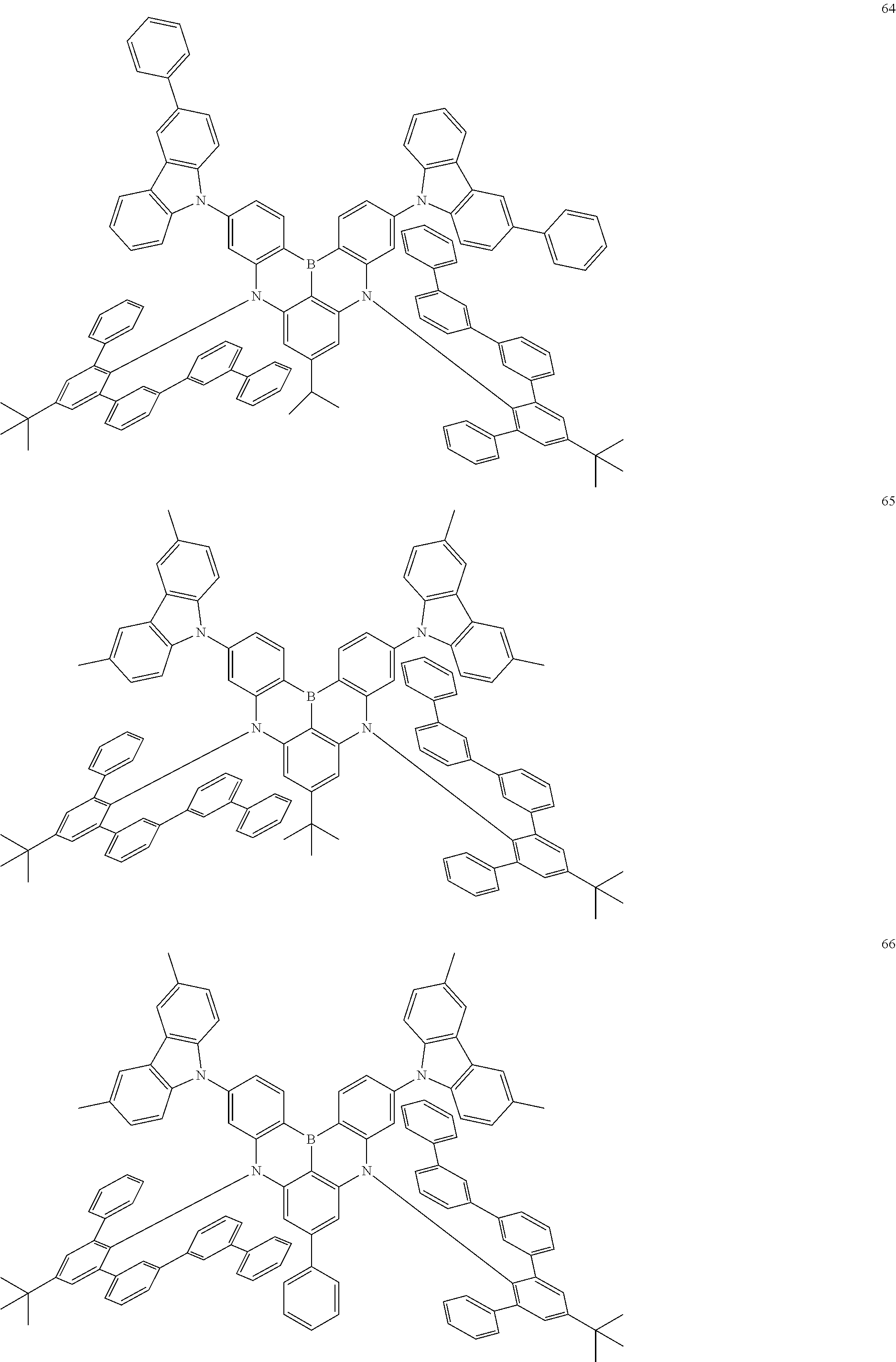

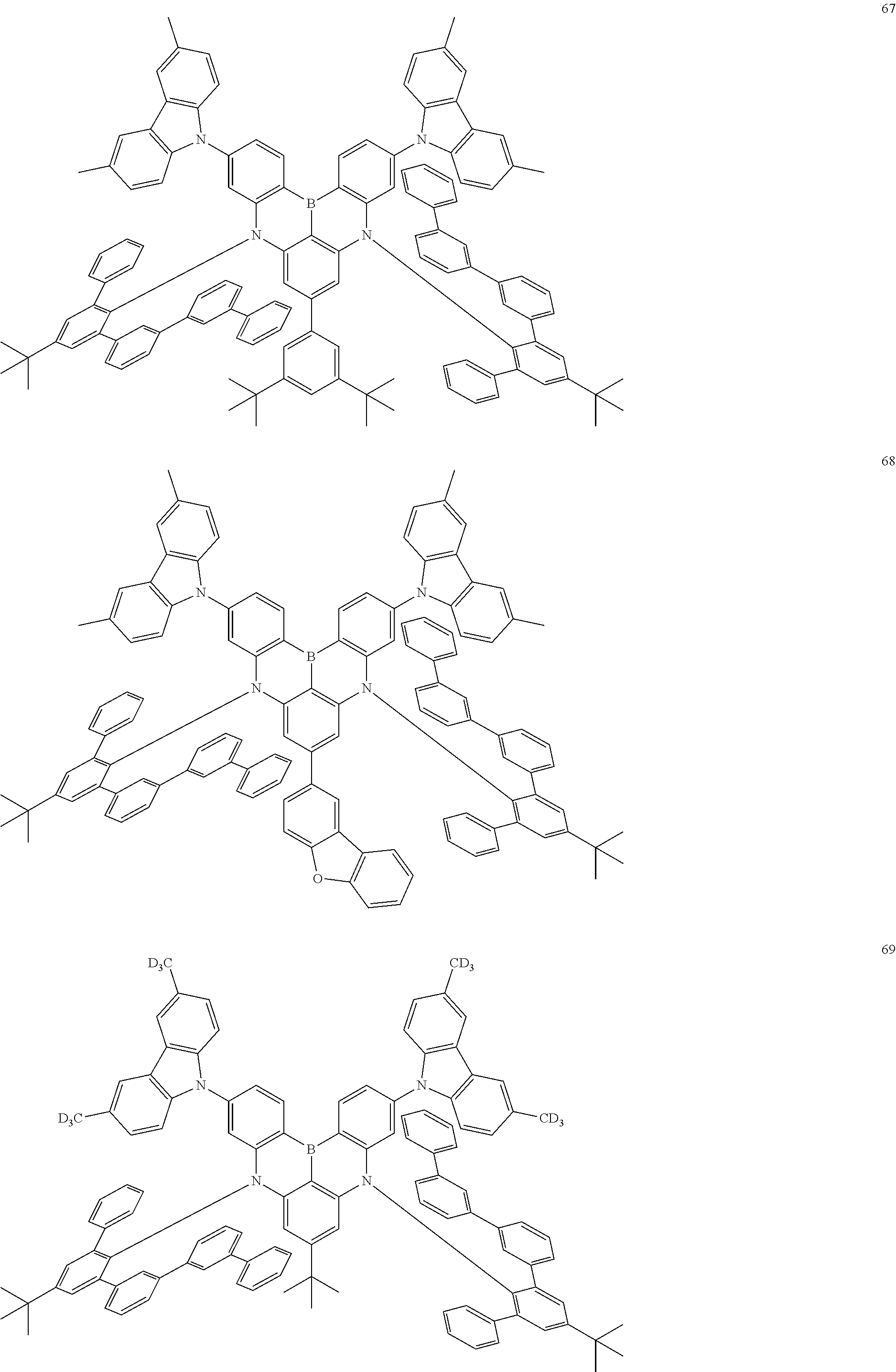

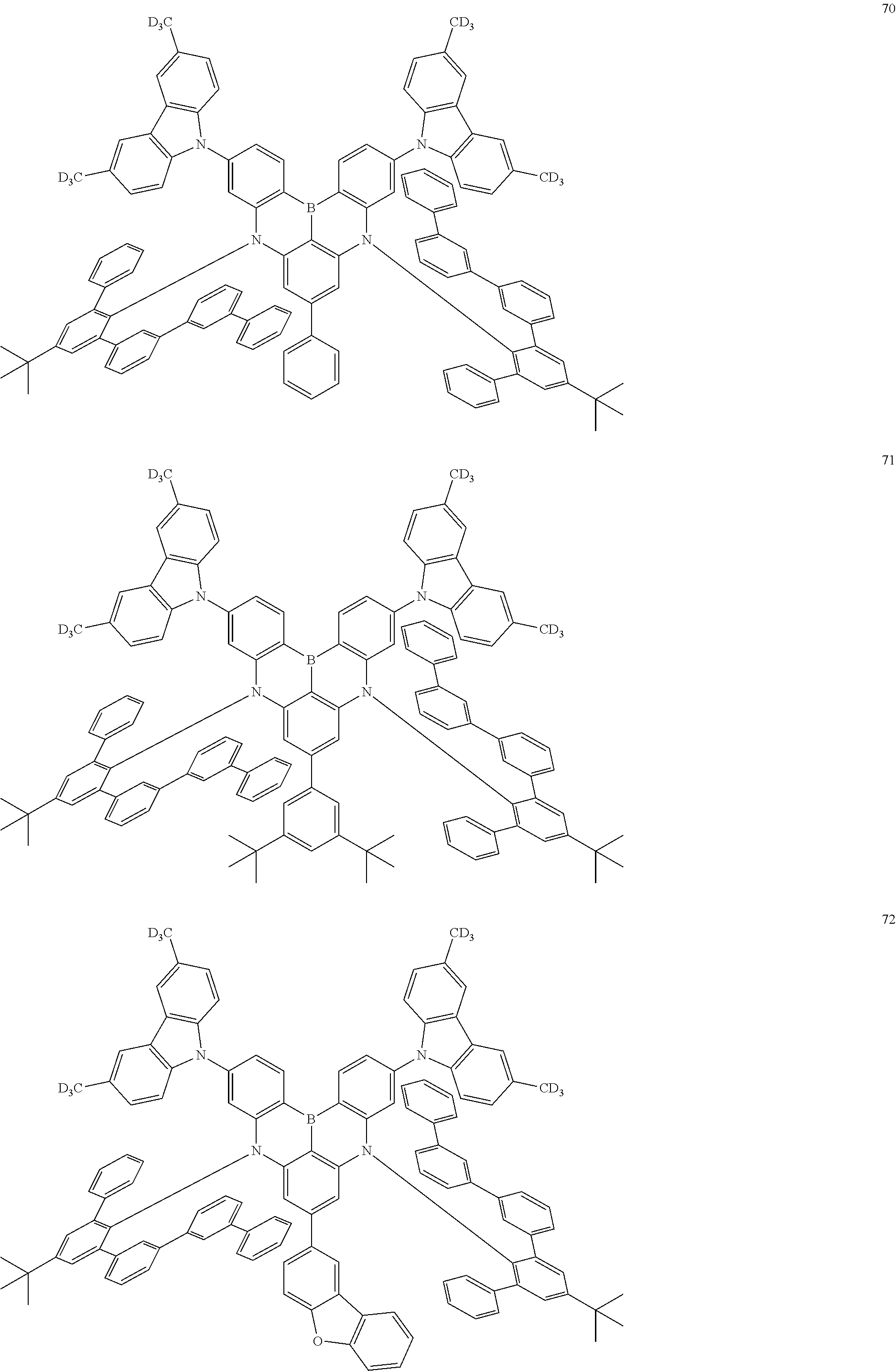

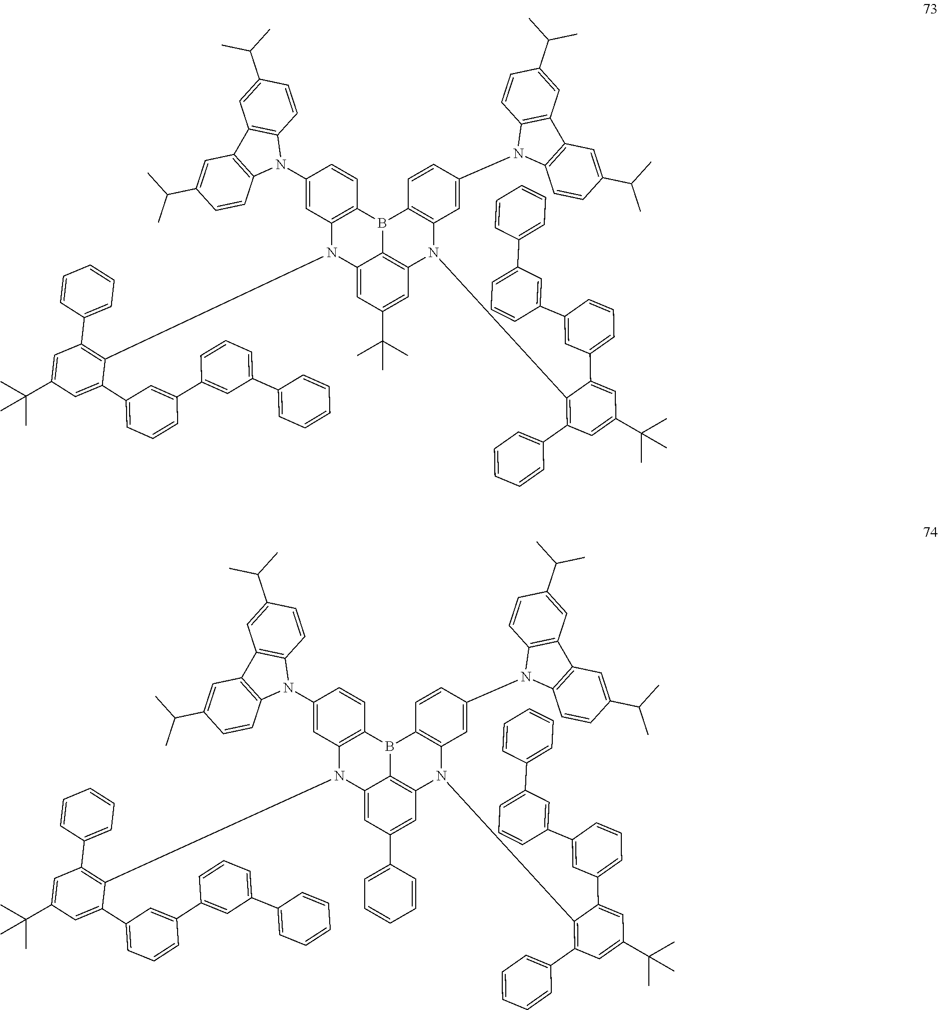

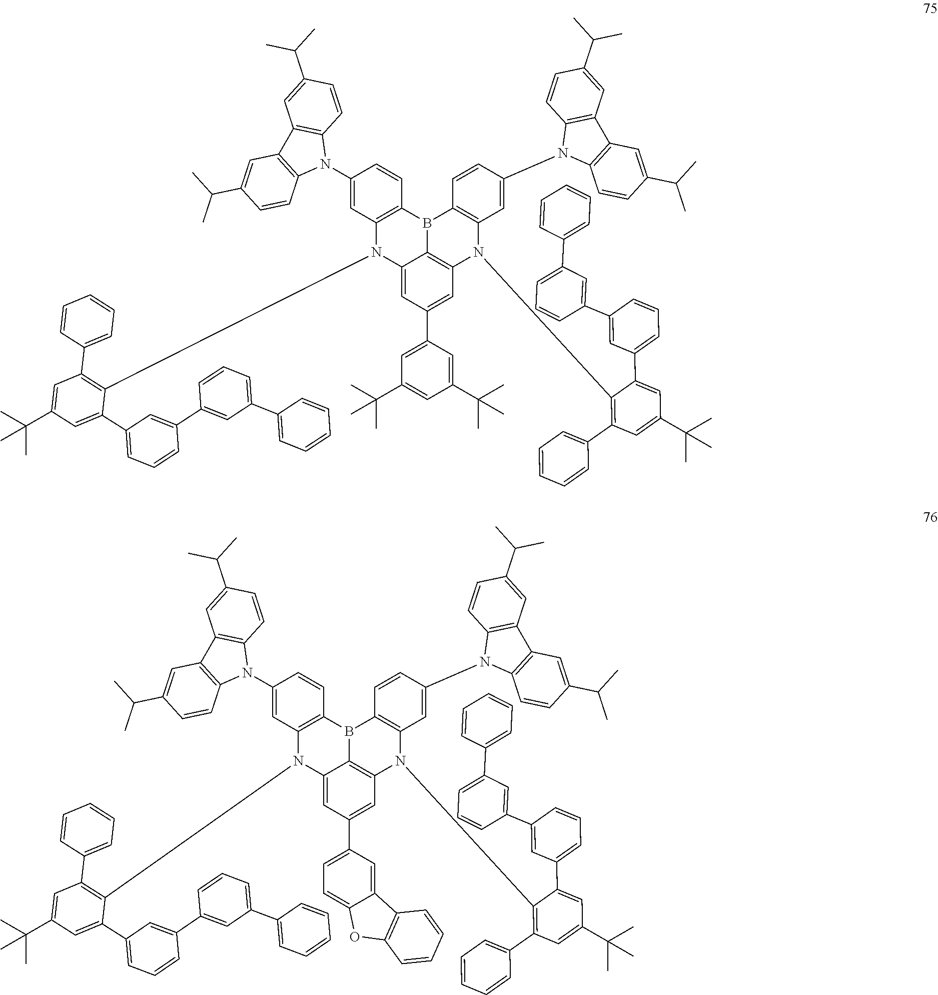

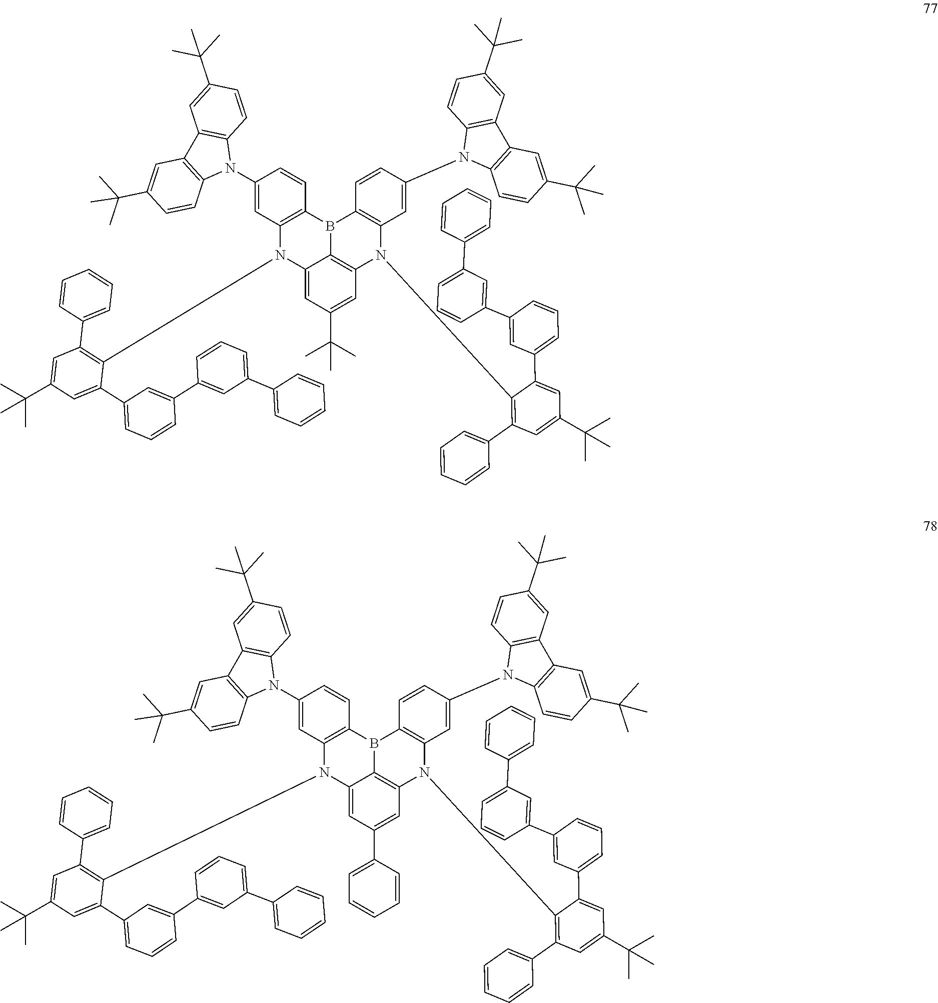

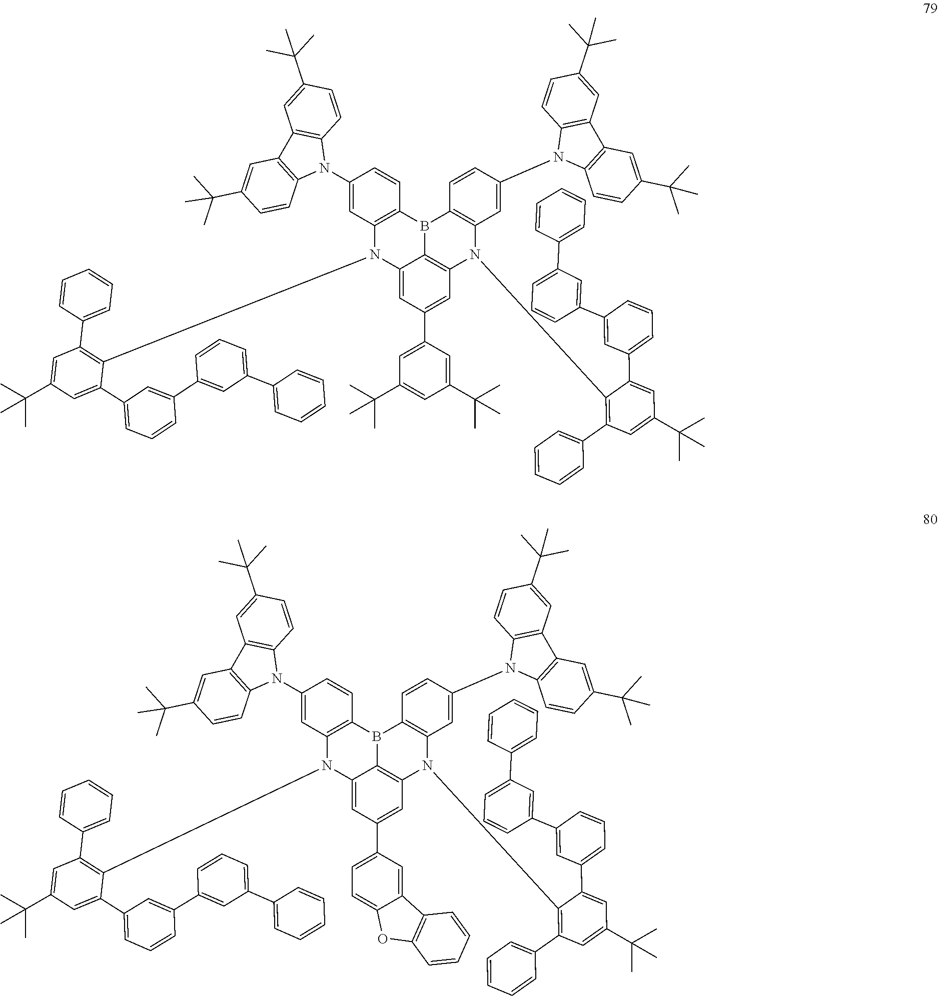

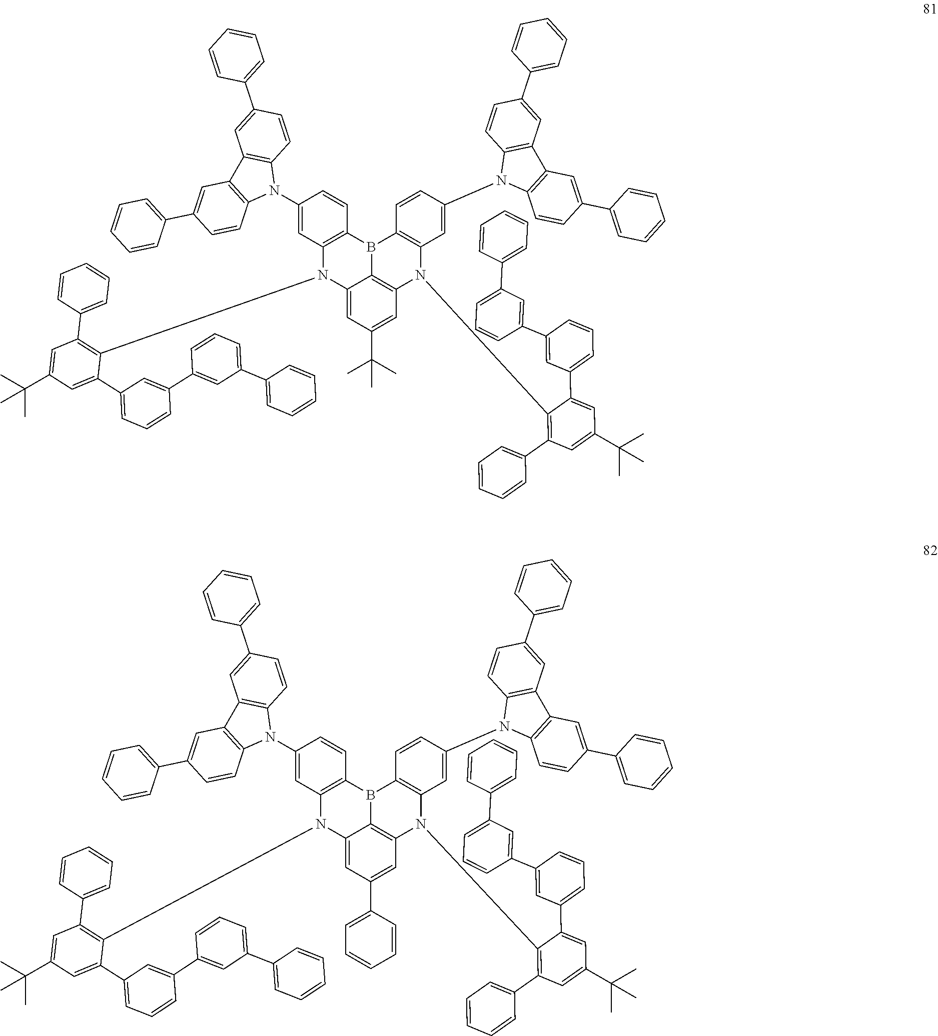

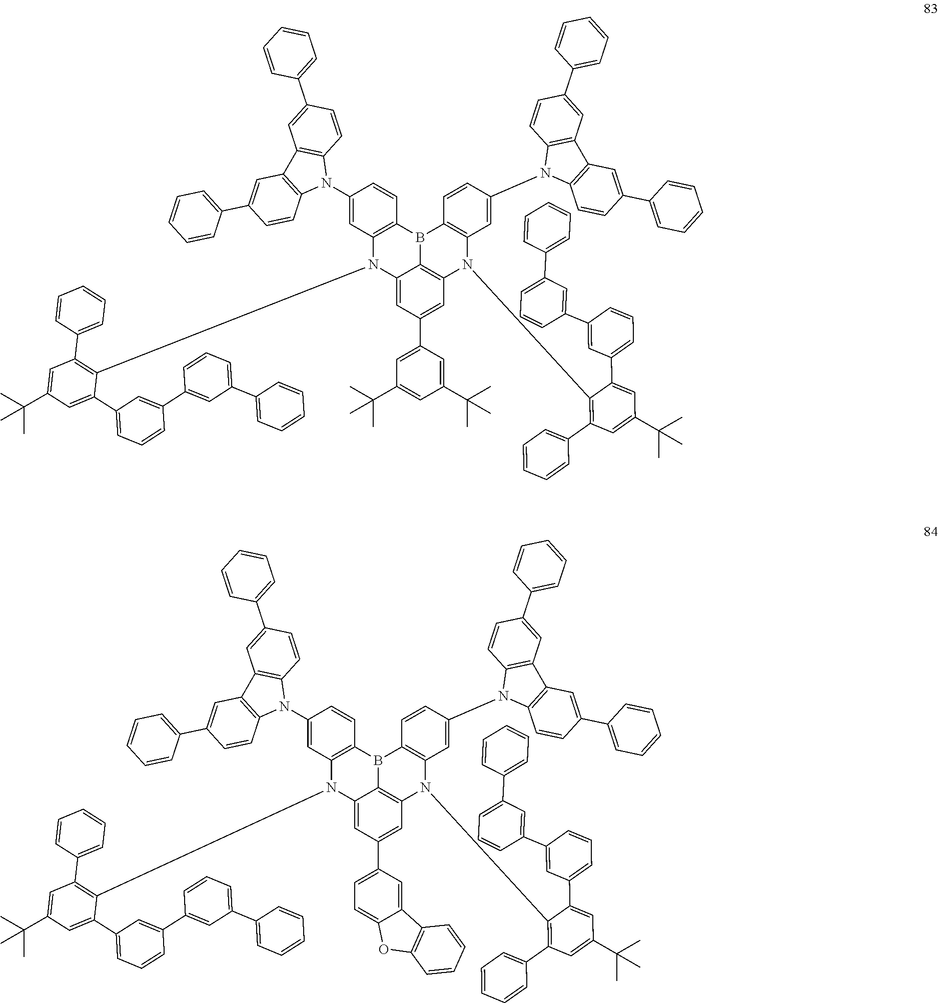

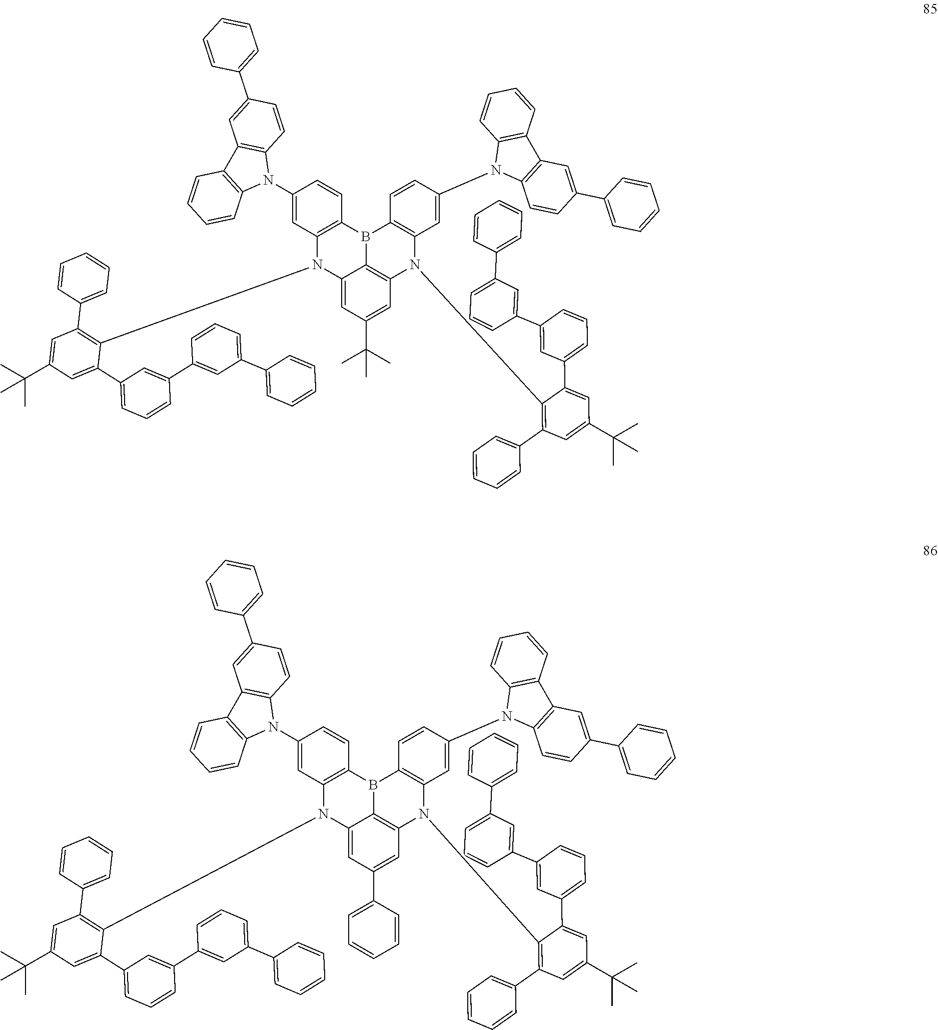 [SMILES: CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccccc5)cc(C(C)(C)C)cc4-c4cccc(-c5cccc(-c6ccccc6)c5)c4)c4cc(C(C)(C)C)cc2c43)c(-c2cccc(-c3cccc(-c4ccccc4)c3)c2)c1 ; CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccccc5)cc(C(C)(C)C)cc4-c4cccc(-c5cccc(-c6ccccc6)c5)c4)c4cc(-c5ccccc5)cc2c43)c(-c2cccc(-c3cccc(-c4ccccc4)c3)c2)c1]

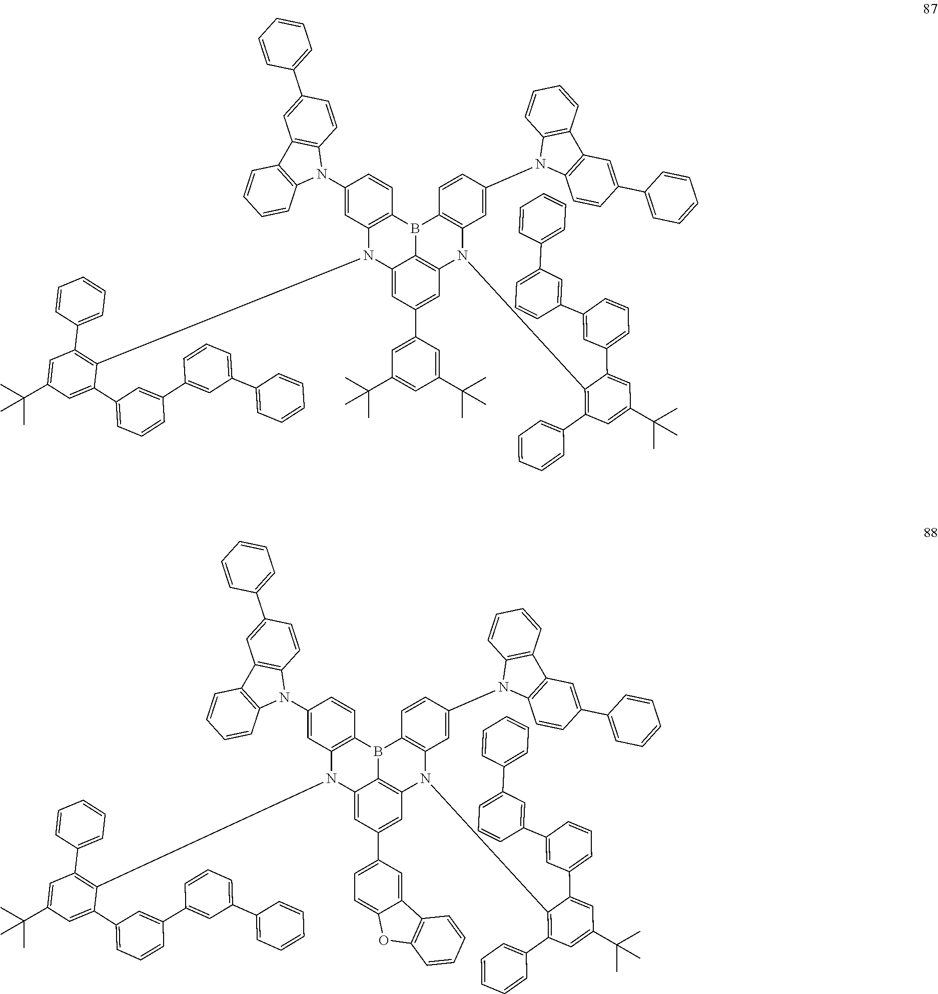 [SMILES: CC(C)(C)c1cc(-c2cc3c4c(c2)N(c2c(-c5ccccc5)cc(C(C)(C)C)cc2-c2cccc(-c5cccc(-c6ccccc6)c5)c2)c2cc(-n5c6ccccc6c6cc(-c7ccccc7)ccc65)ccc2B4c2ccc(-n4c5ccccc5c5cc(-c6ccccc6)ccc54)cc2N3c2c(-c3ccccc3)cc(C(C)(C)C)cc2-c2cccc(-c3cccc(-c4ccccc4)c3)c2)cc(C(C)(C)C)c1 ; CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccccc5)cc(C(C)(C)C)cc4-c4cccc(-c5cccc(-c6ccccc6)c5)c4)c4cc(-c5ccc6oc7ccccc7c6c5)cc2c43)c(-c2cccc(-c3cccc(-c4ccccc4)c3)c2)c1]

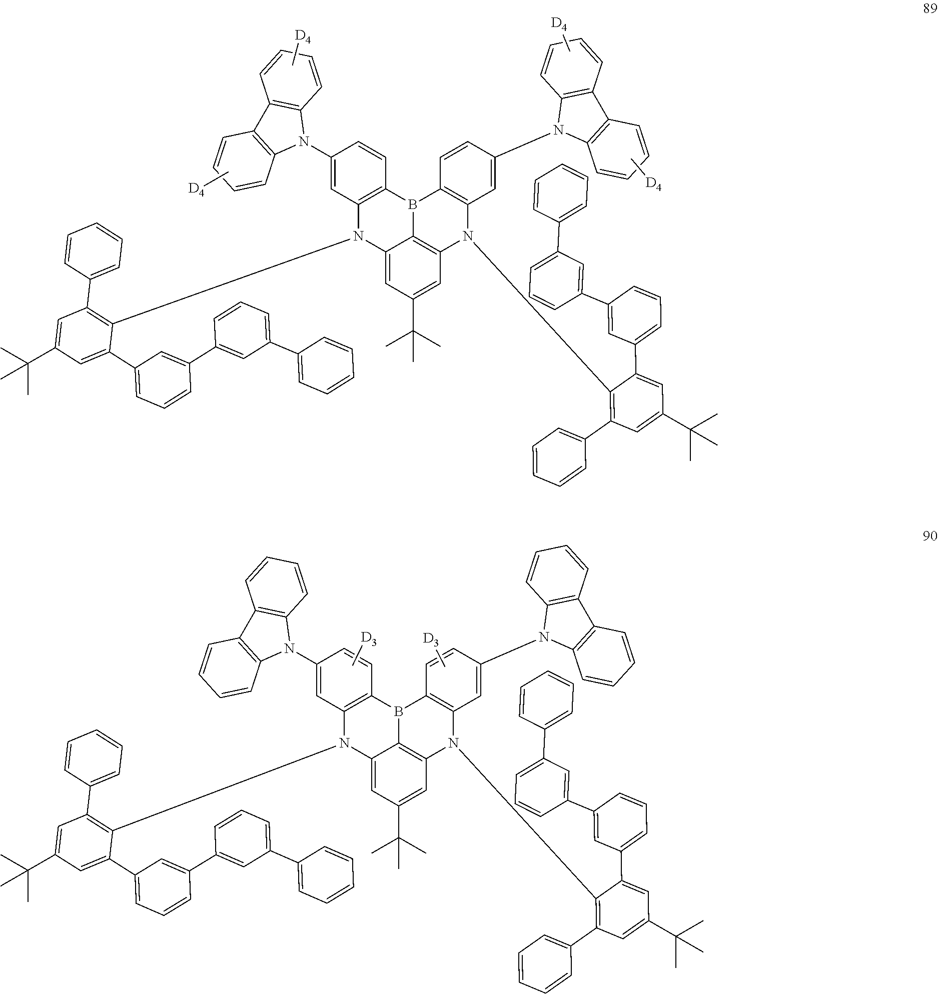

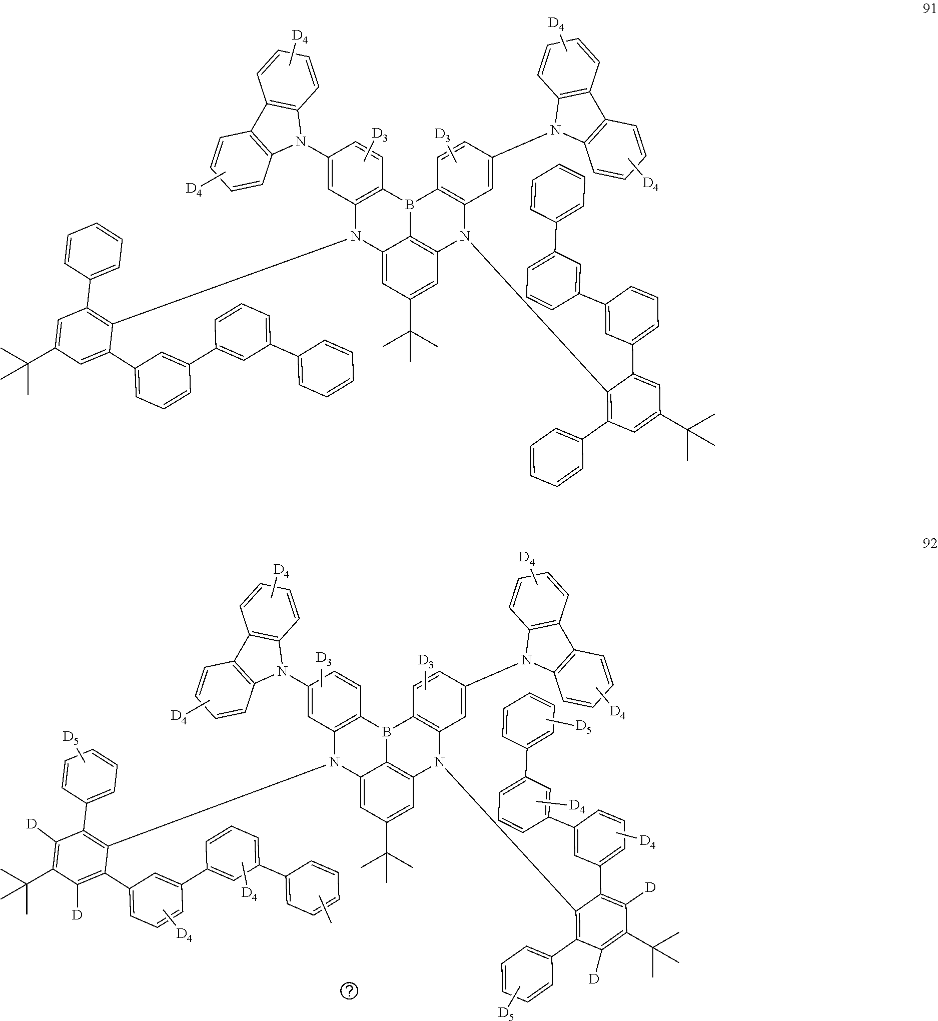

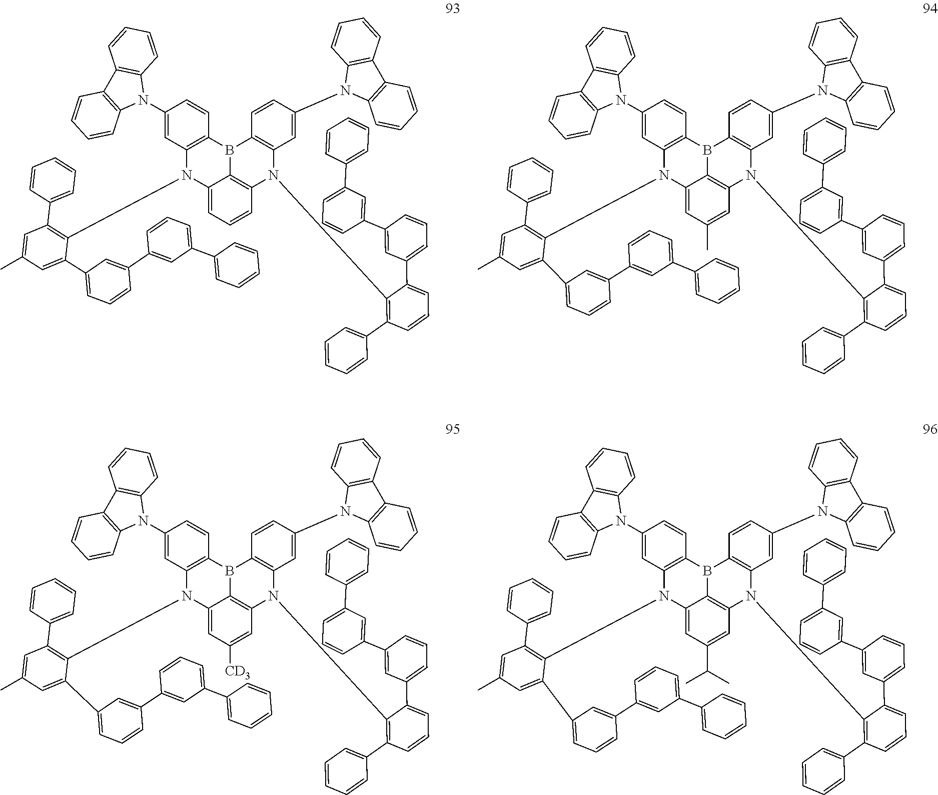

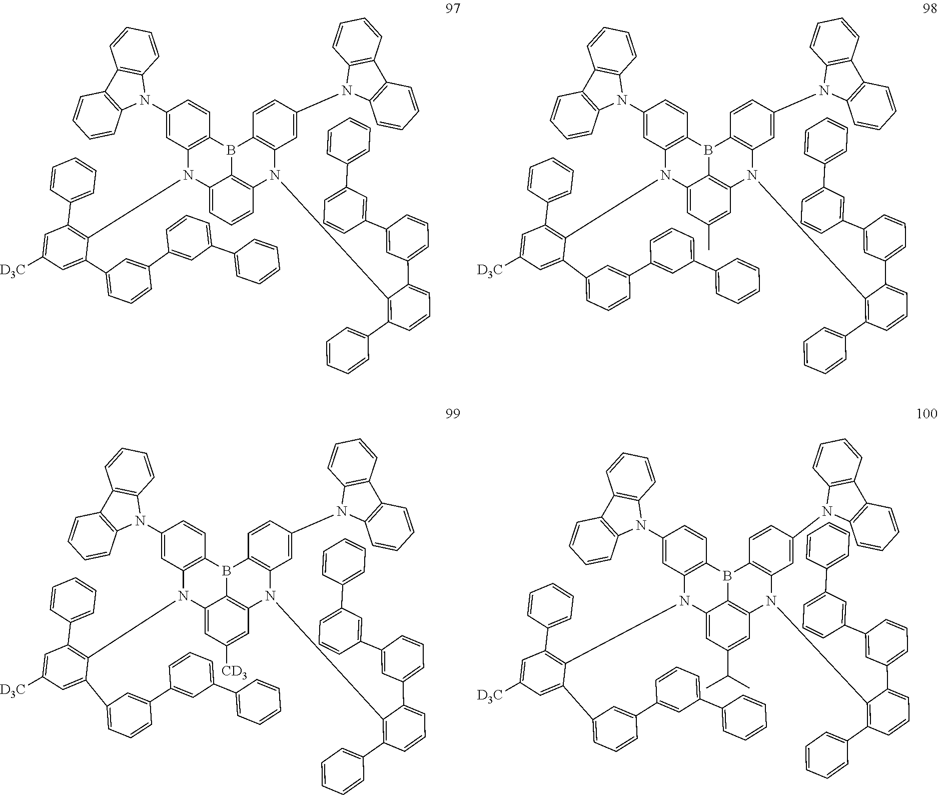

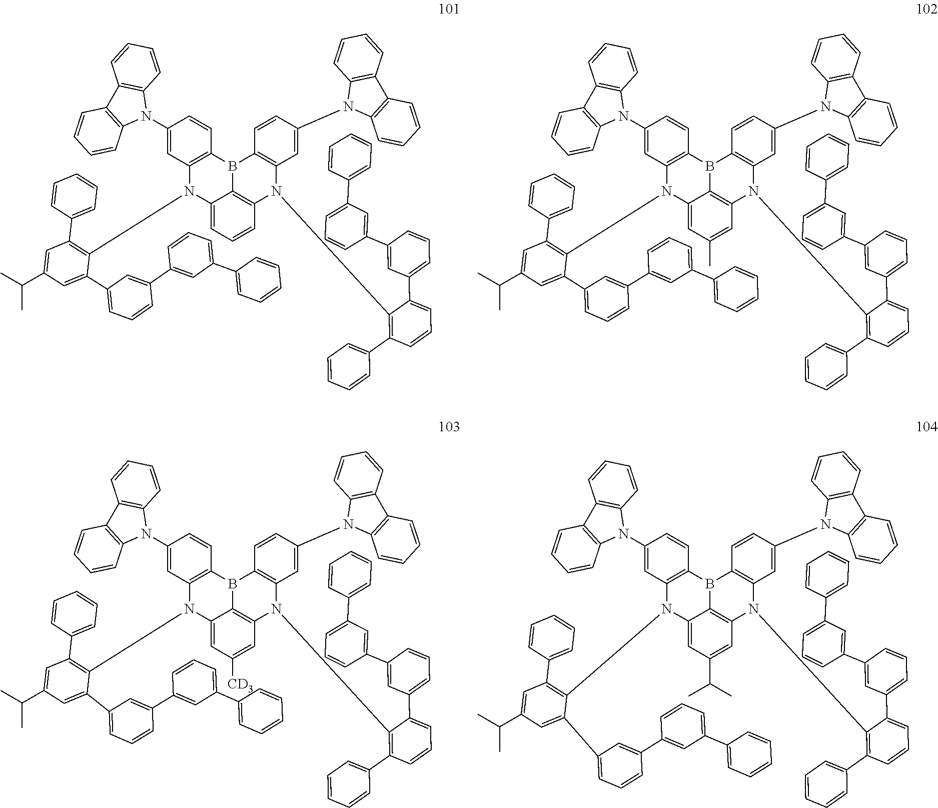

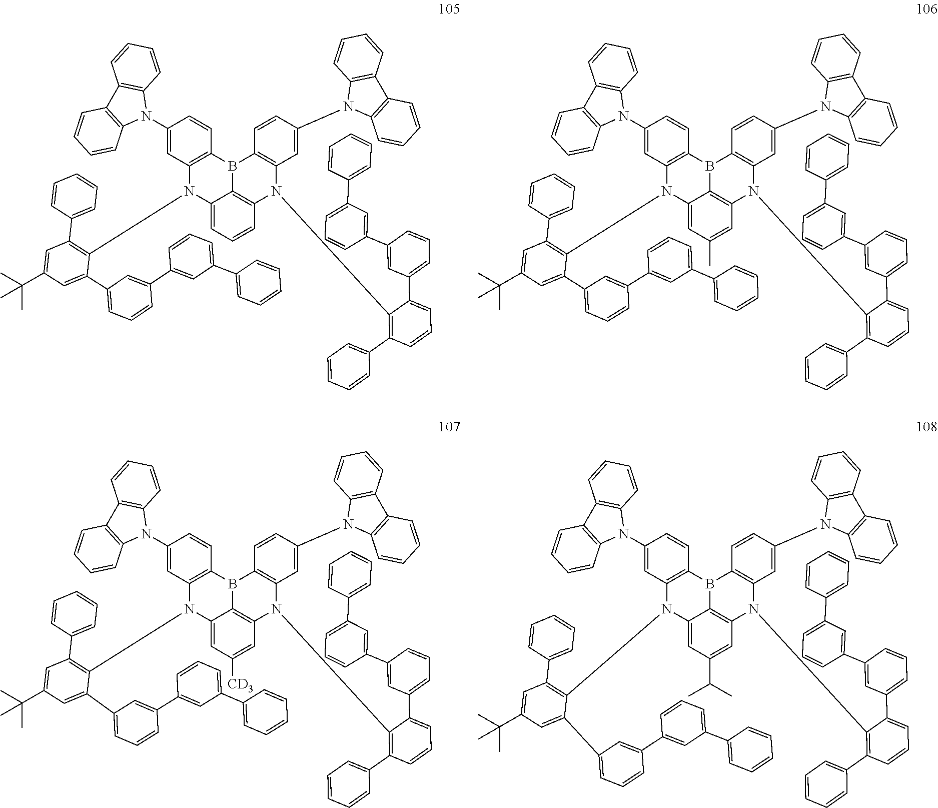

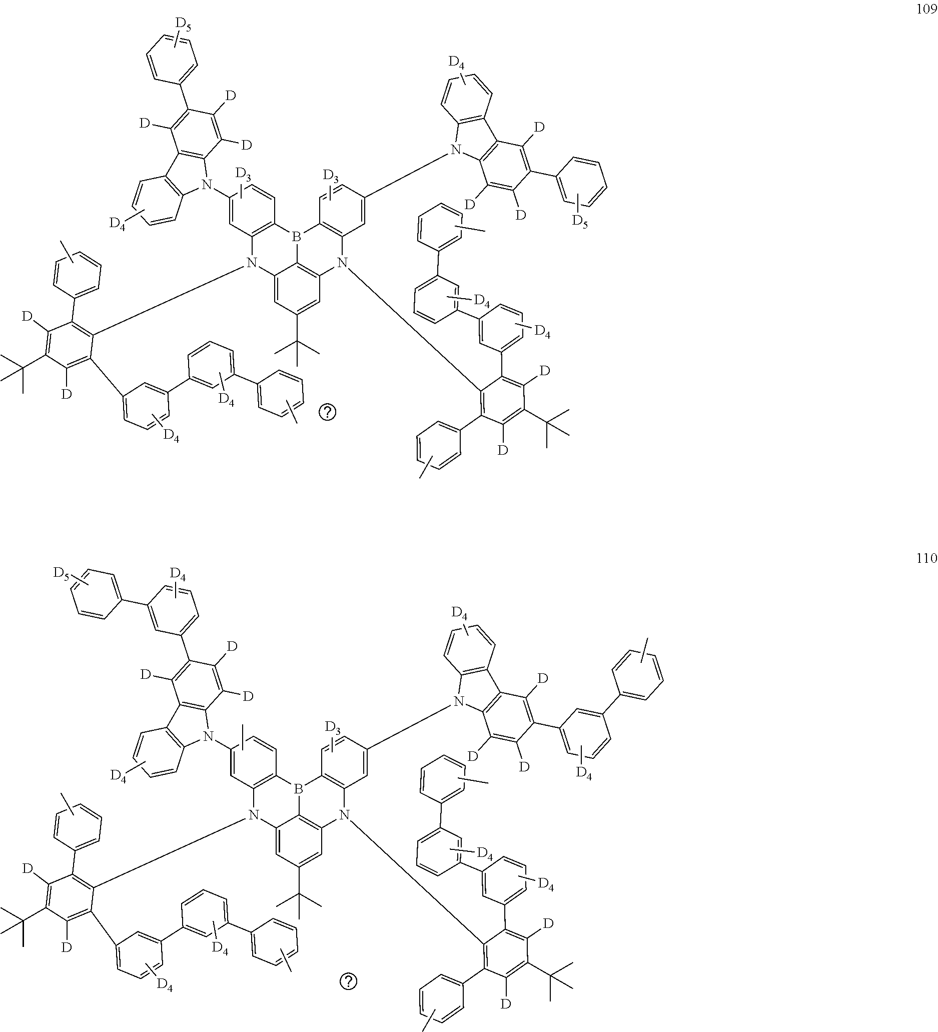

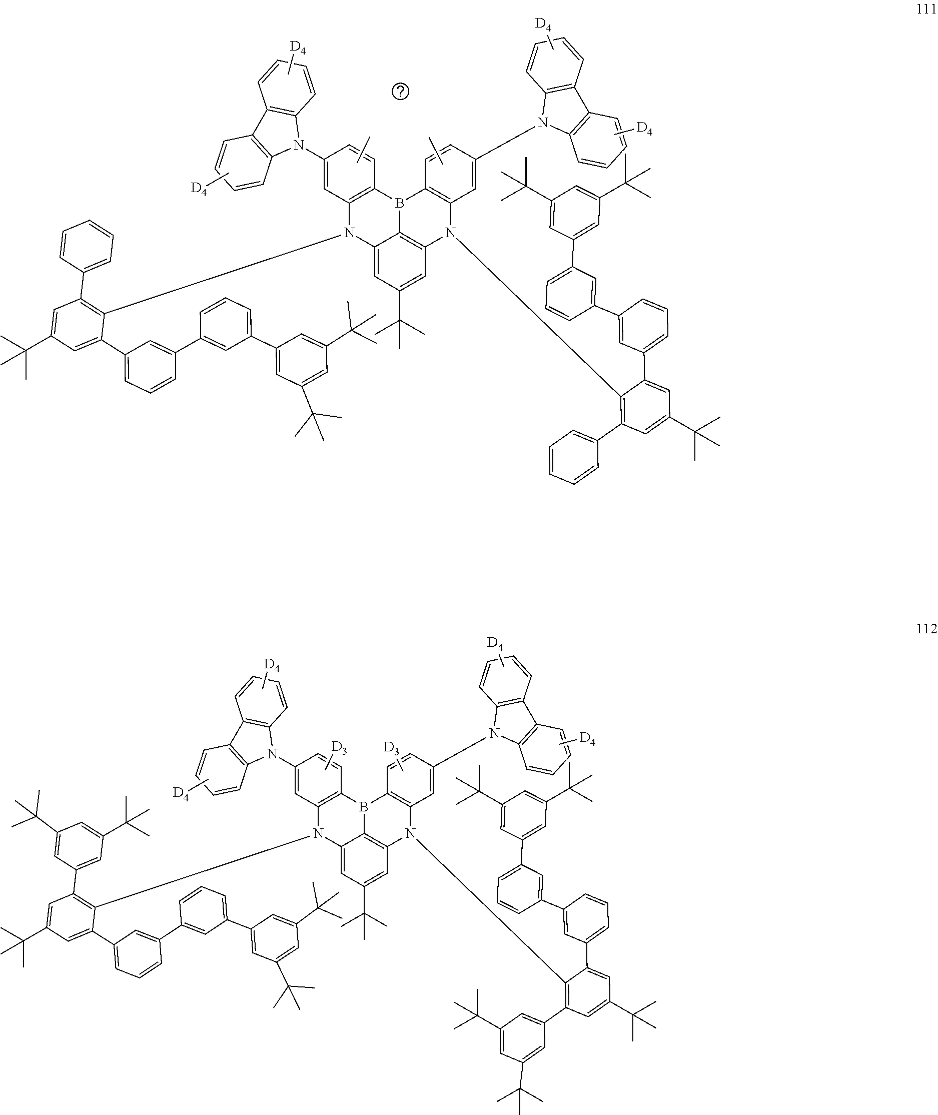

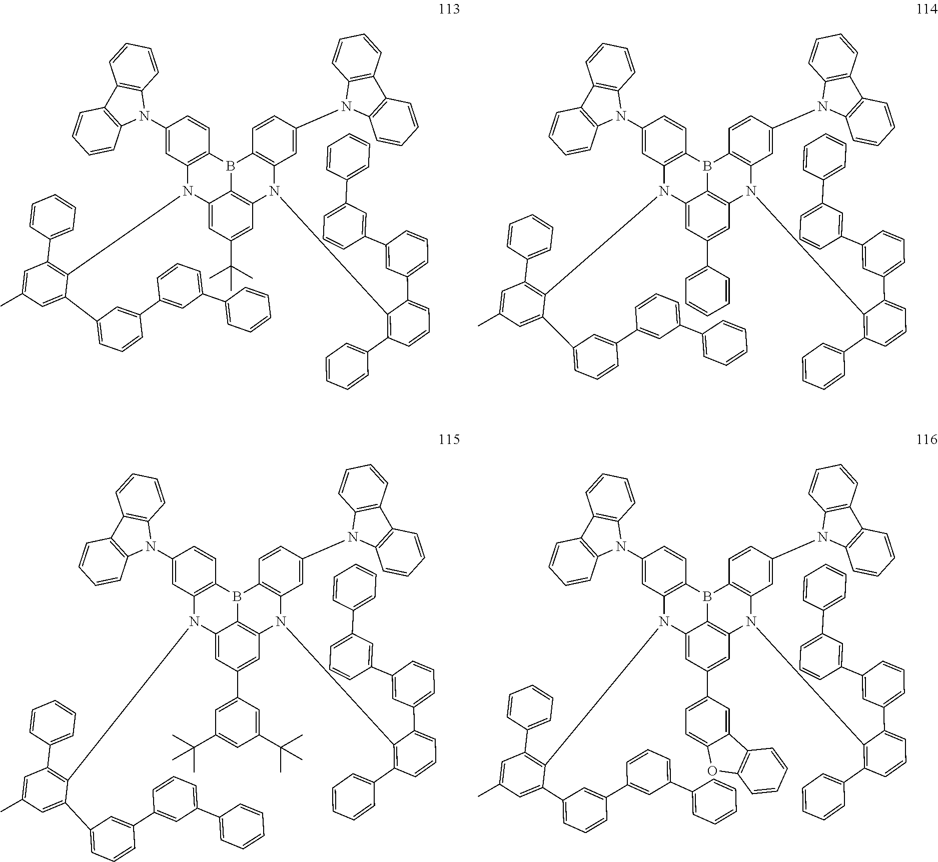

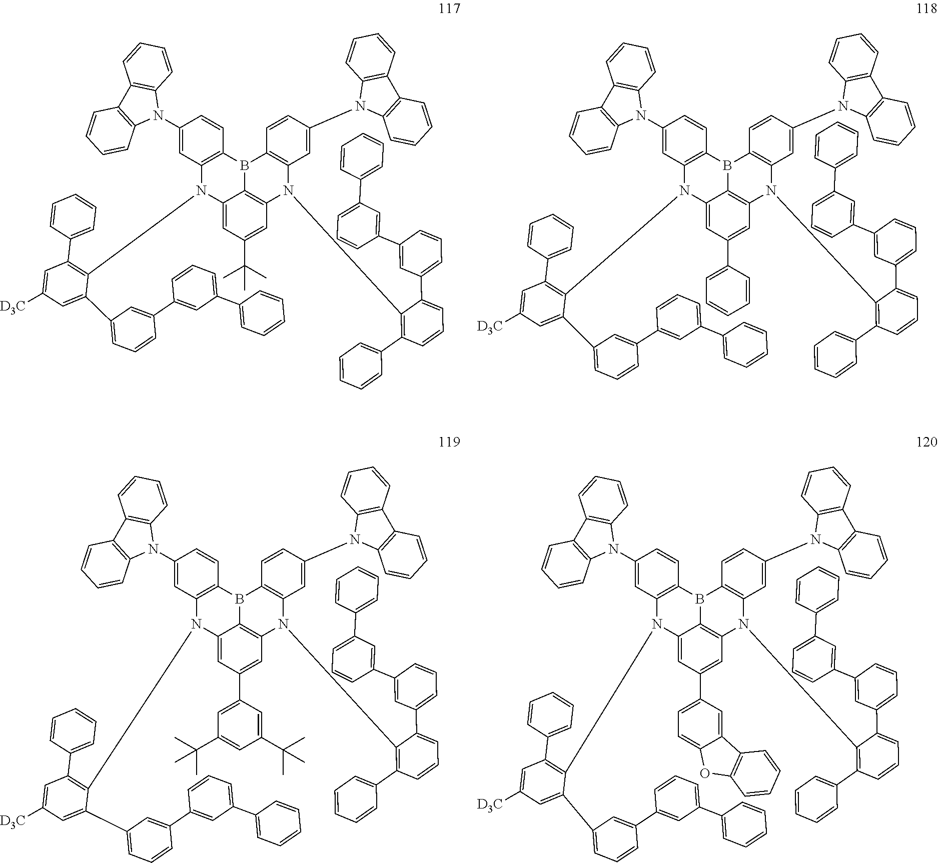

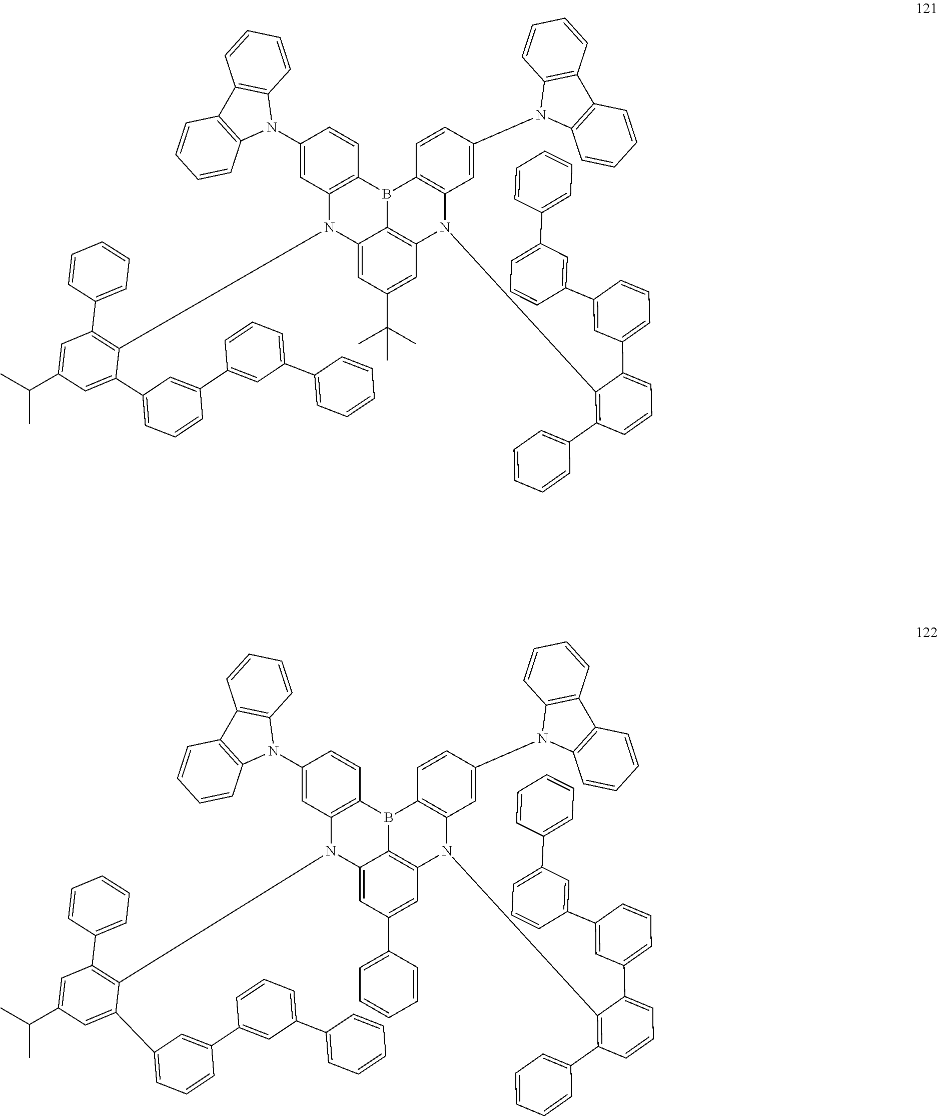 [SMILES: CC(C)c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cccc4-c4cccc(-c5cccc(-c6ccccc6)c5)c4)c4cc(C(C)(C)C)cc2c43)c(-c2cccc(-c3cccc(-c4ccccc4)c3)c2)c1 ; CC(C)c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cccc4-c4cccc(-c5cccc(-c6ccccc6)c5)c4)c4cc(-c5ccccc5)cc2c43)c(-c2cccc(-c3cccc(-c4ccccc4)c3)c2)c1]

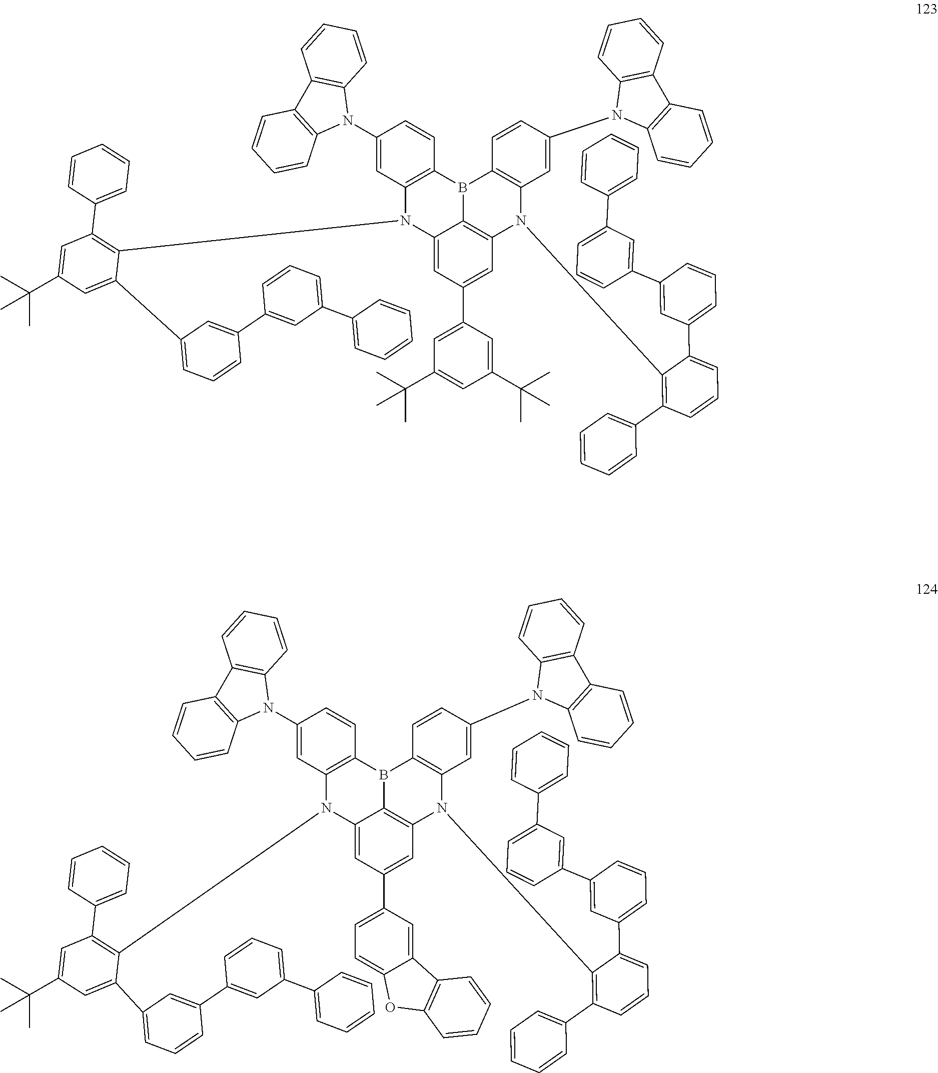 [SMILES: CC(C)(C)c1cc(-c2cc3c4c(c2)N(c2c(-c5ccccc5)cc(C(C)(C)C)cc2-c2cccc(-c5cccc(-c6ccccc6)c5)c2)c2cc(-n5c6ccccc6c6ccccc65)ccc2B4c2ccc(-n4c5ccccc5c5ccccc54)cc2N3c2c(-c3ccccc3)cccc2-c2cccc(-c3cccc(-c4ccccc4)c3)c2)cc(C(C)(C)C)c1 ; CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cccc4-c4cccc(-c5cccc(-c6ccccc6)c5)c4)c4cc(-c5ccc6oc7ccccc7c6c5)cc2c43)c(-c2cccc(-c3cccc(-c4ccccc4)c3)c2)c1]

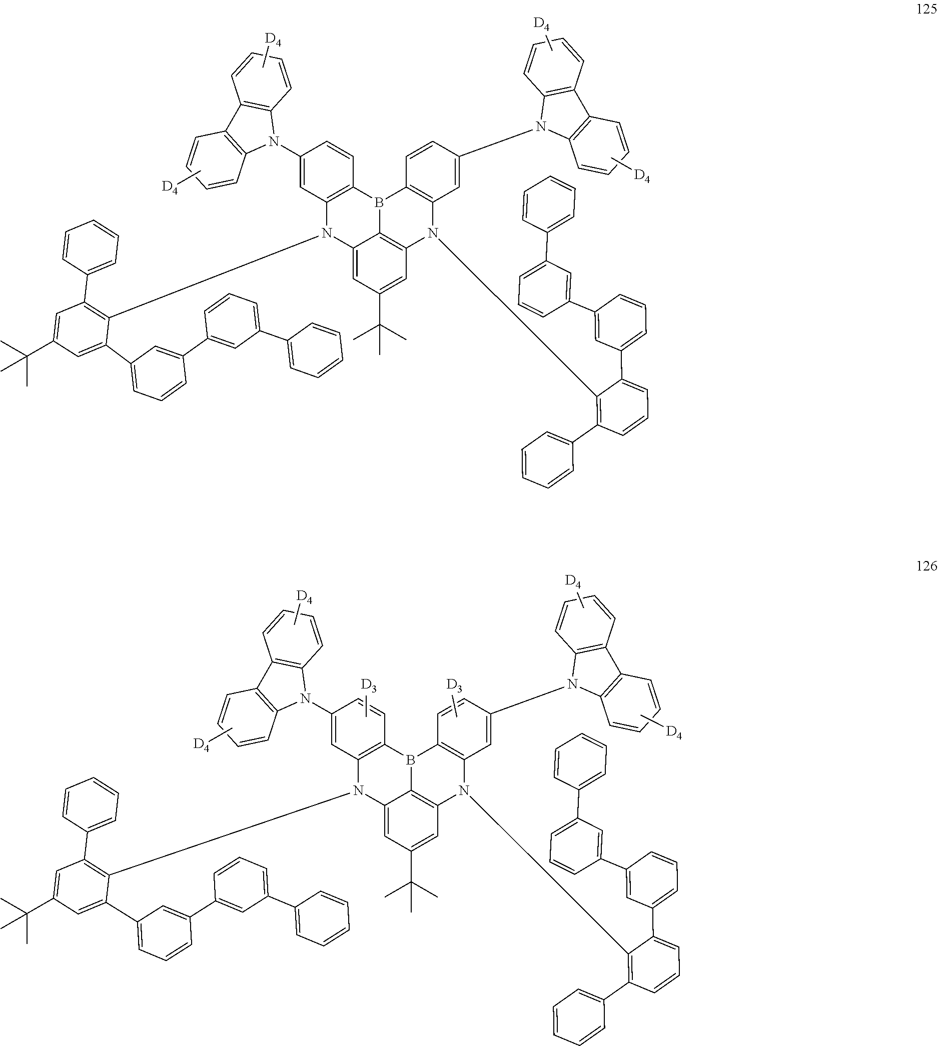

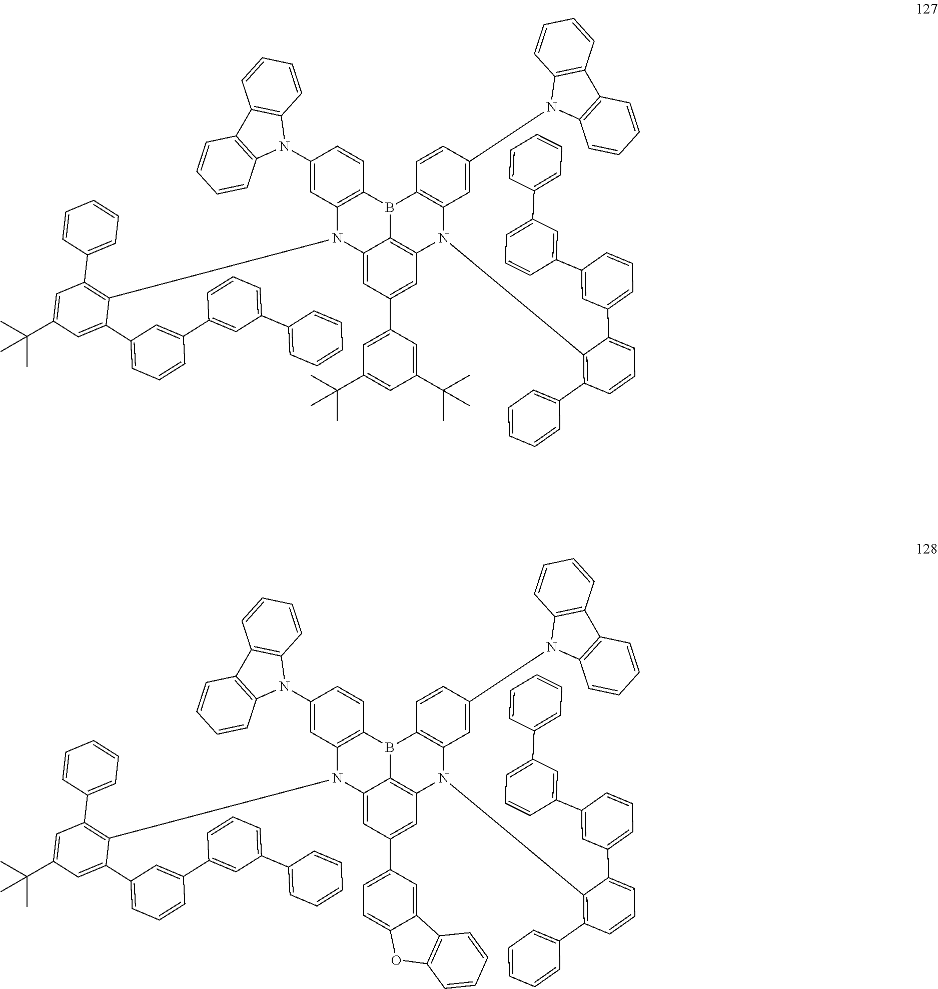 [SMILES: CC(C)(C)c1cc(-c2cc3c4c(c2)N(c2c(-c5ccccc5)cc(C(C)(C)C)cc2-c2cccc(-c5cccc(-c6ccccc6)c5)c2)c2cc(-n5c6ccccc6c6ccccc65)ccc2B4c2ccc(-n4c5ccccc5c5ccccc54)cc2N3c2c(-c3ccccc3)cccc2-c2cccc(-c3cccc(-c4ccccc4)c3)c2)cc(C(C)(C)C)c1 ; CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cccc4-c4cccc(-c5cccc(-c6ccccc6)c5)c4)c4cc(-c5ccc6oc7ccccc7c6c5)cc2c43)c(-c2cccc(-c3cccc(-c4ccccc4)c3)c2)c1]

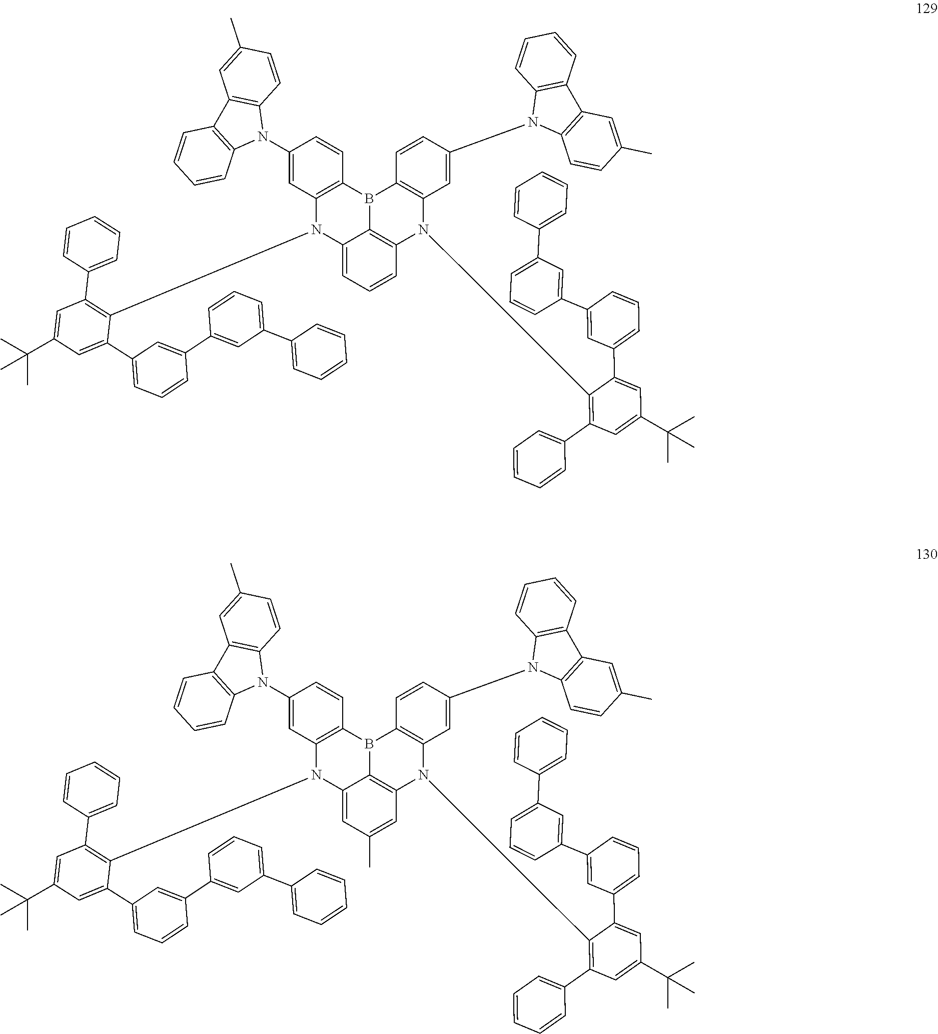

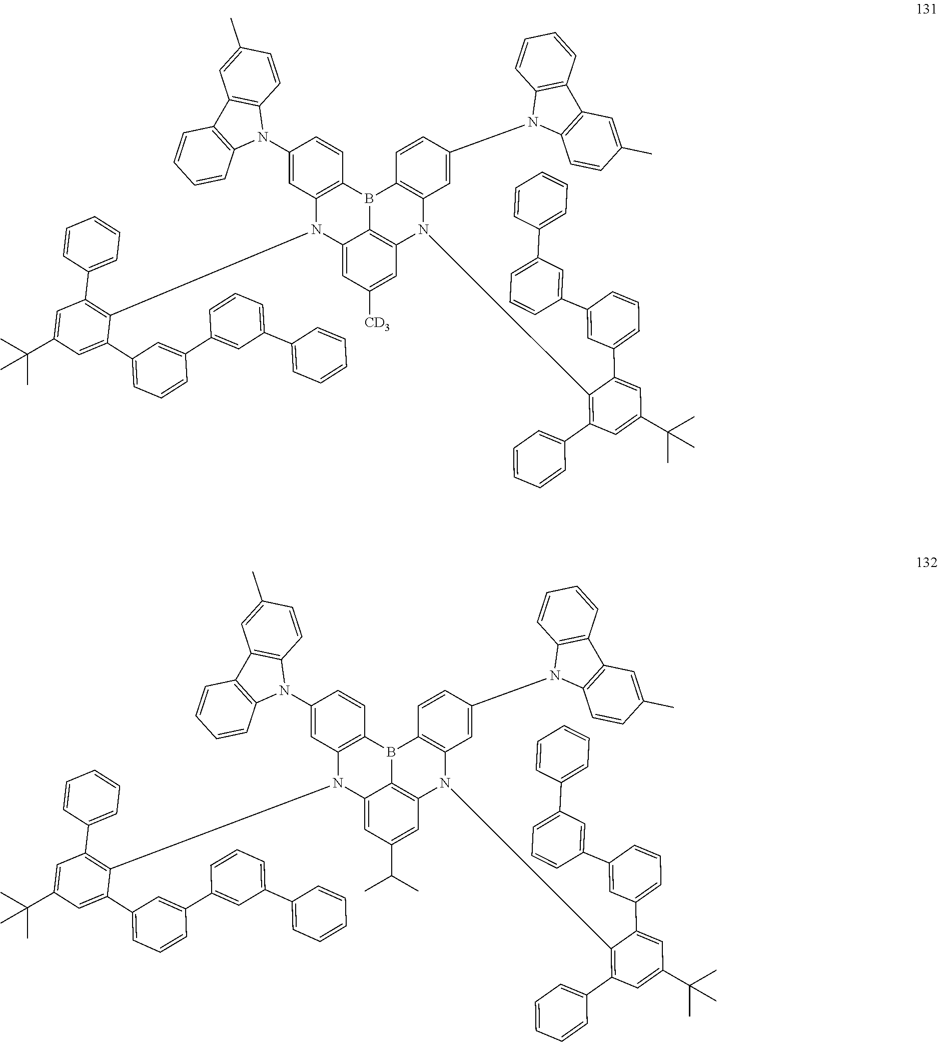

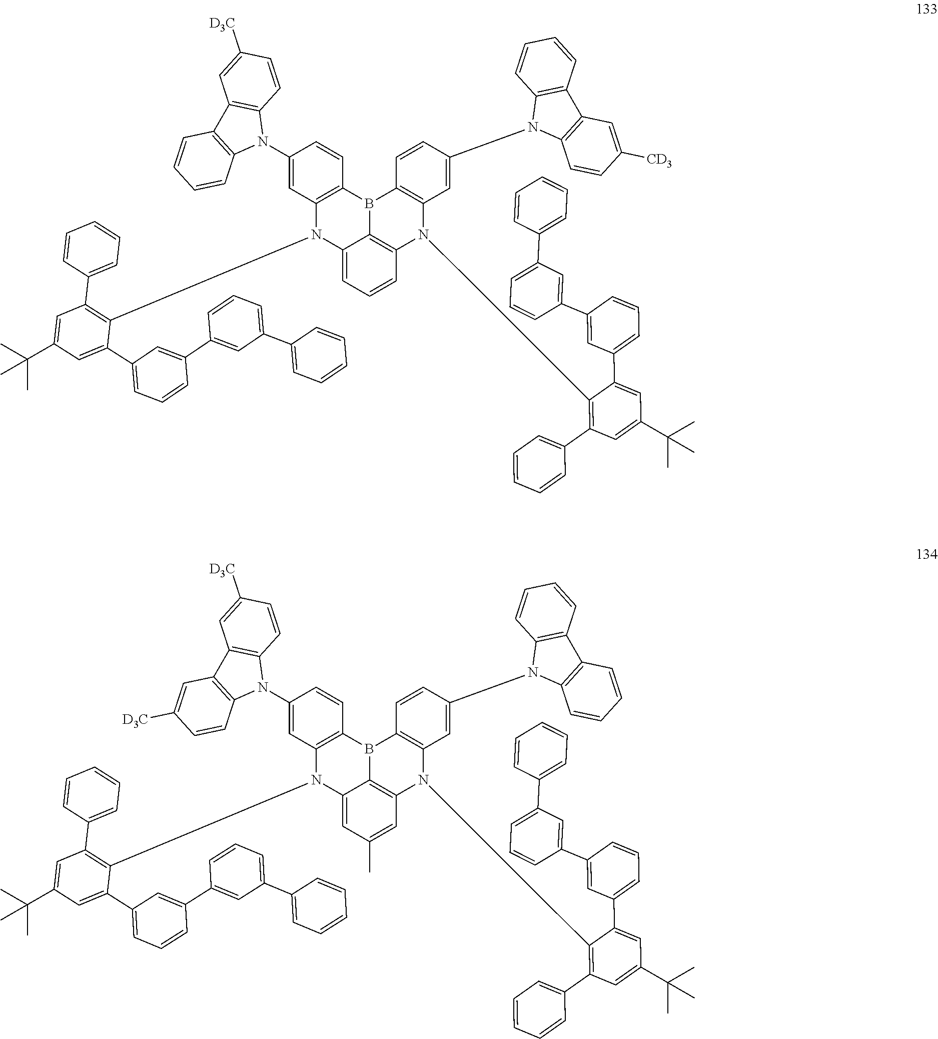

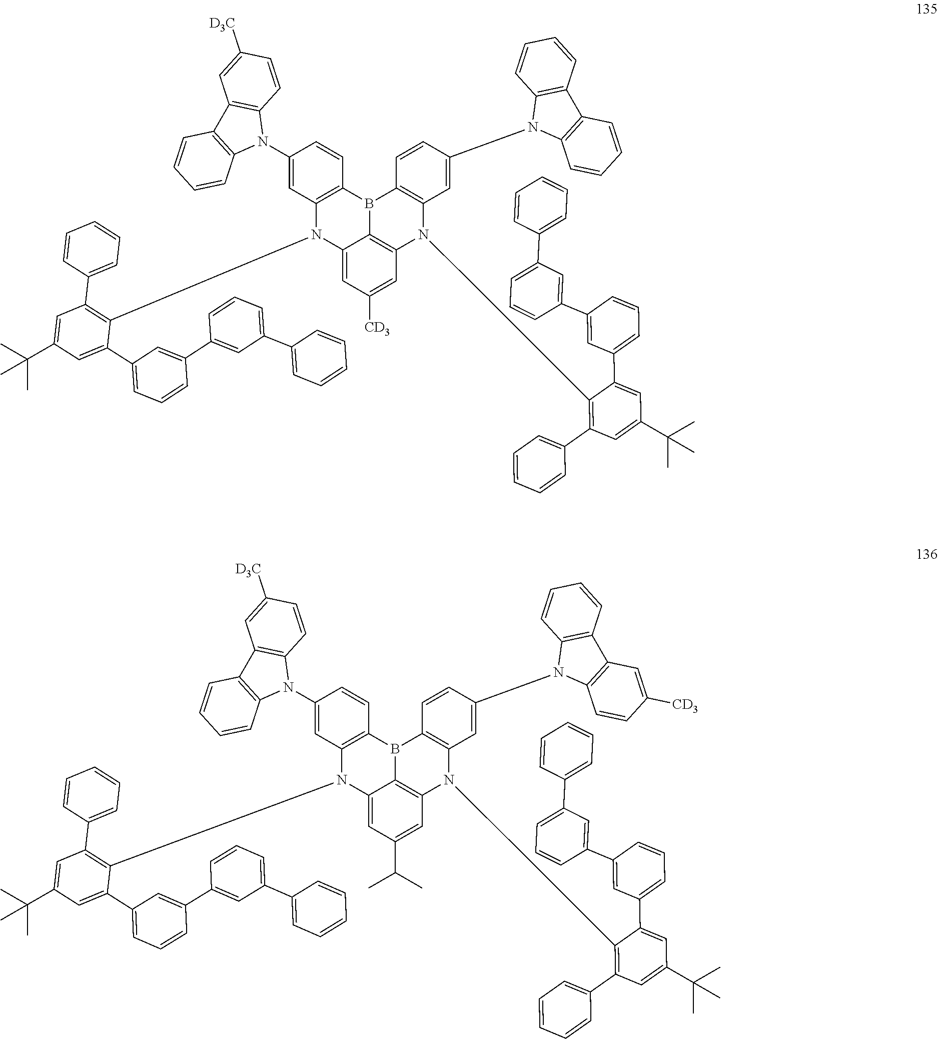

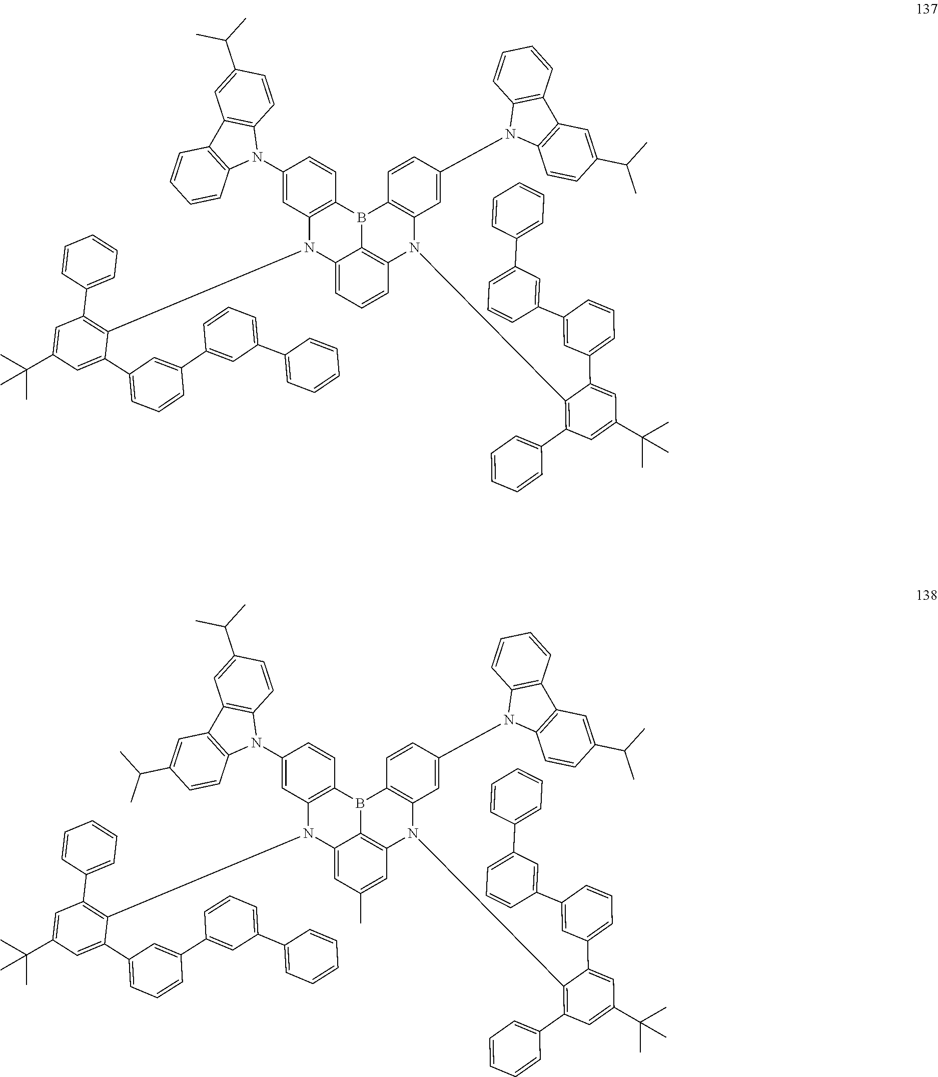

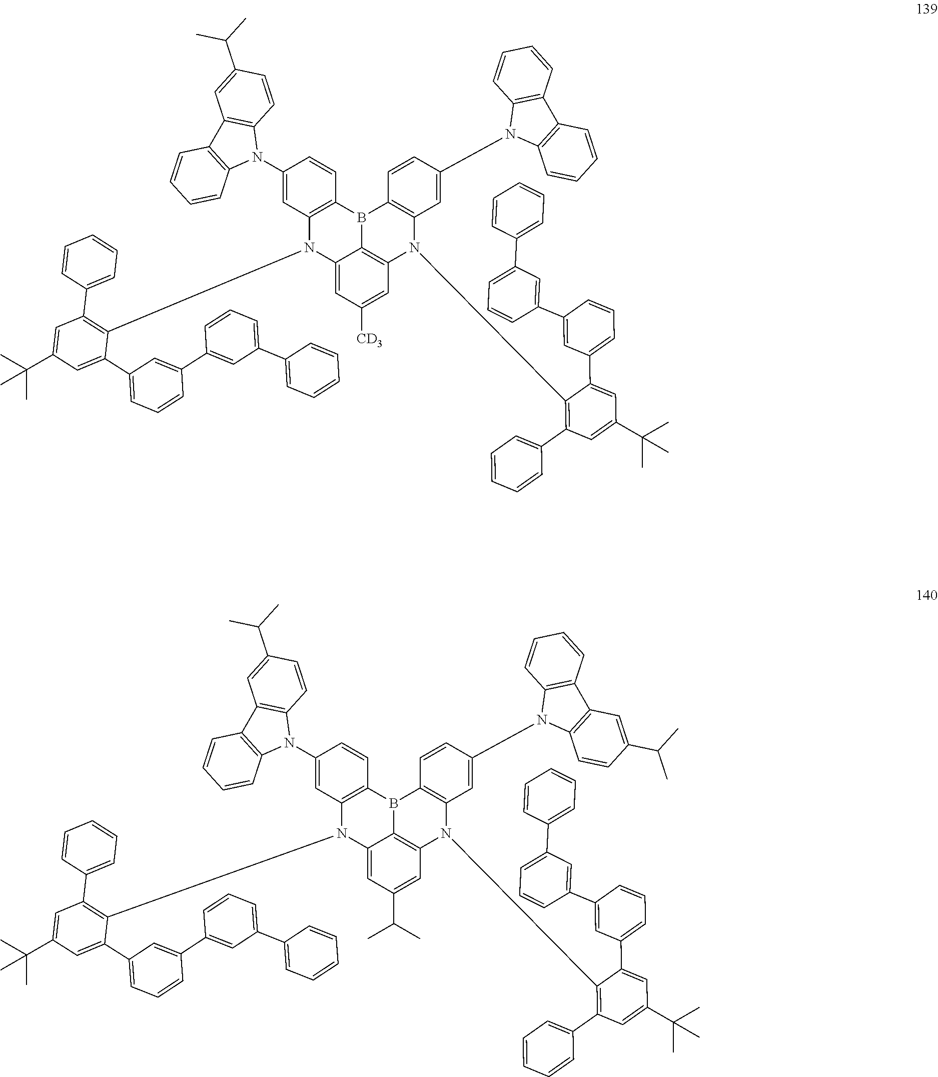

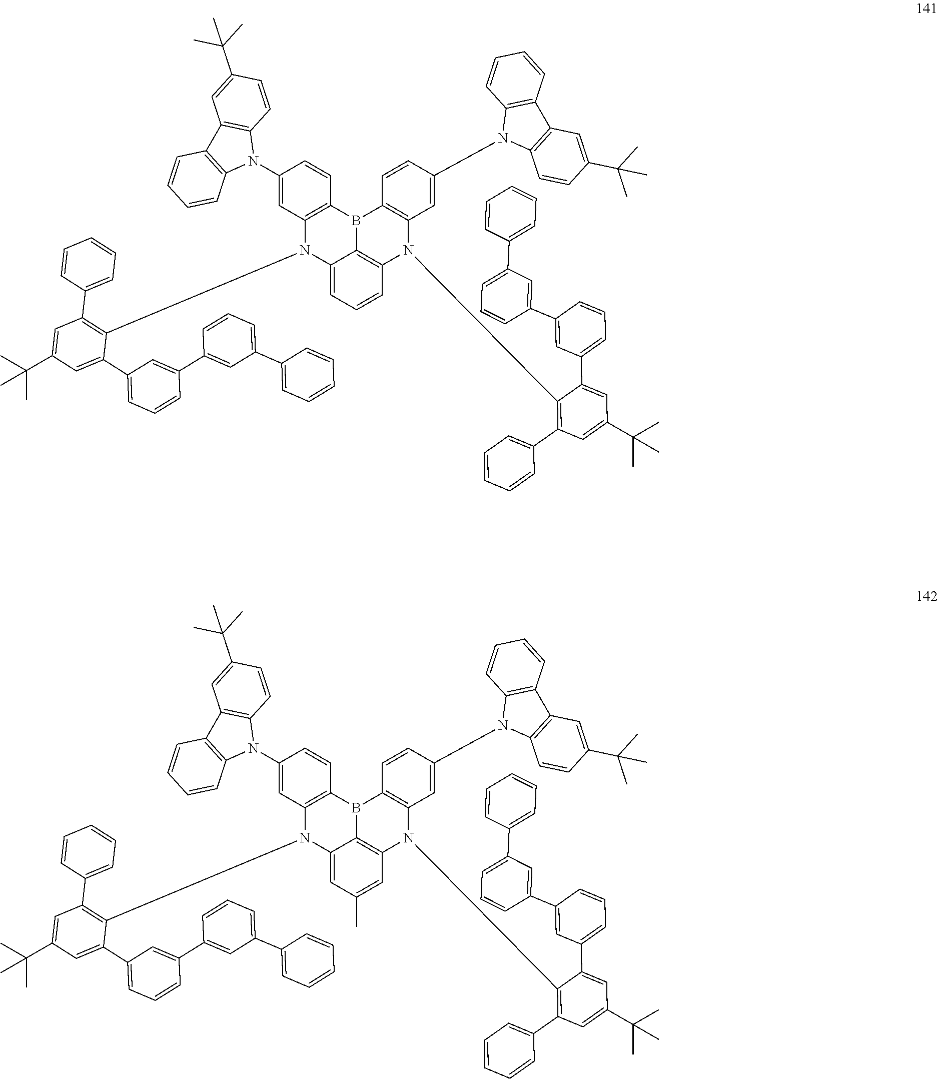

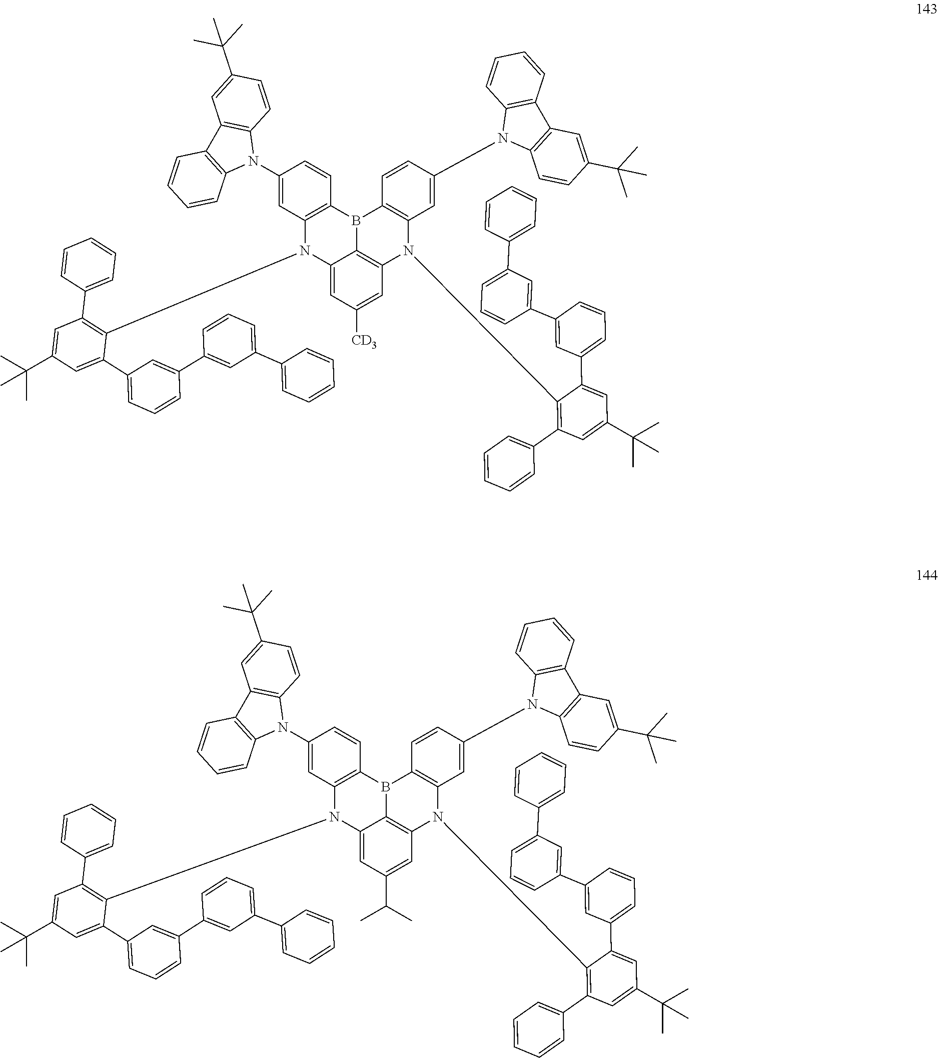

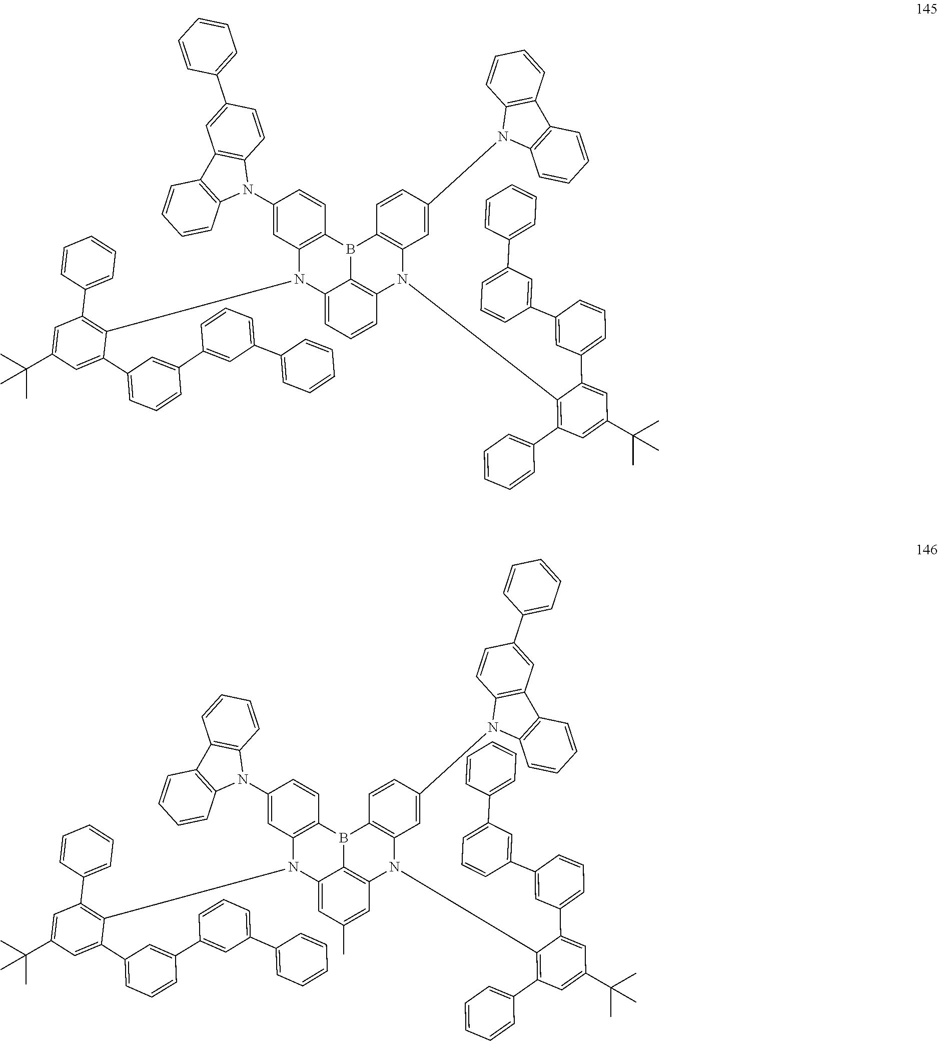

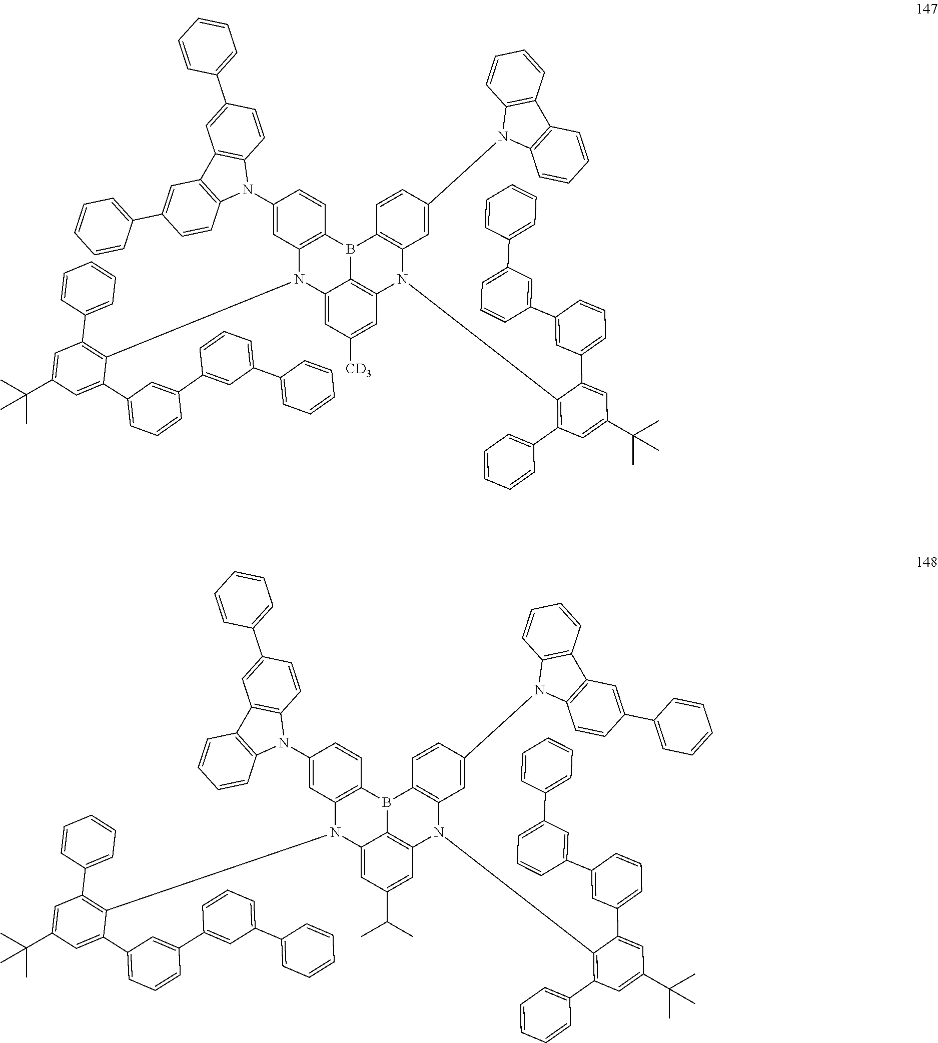

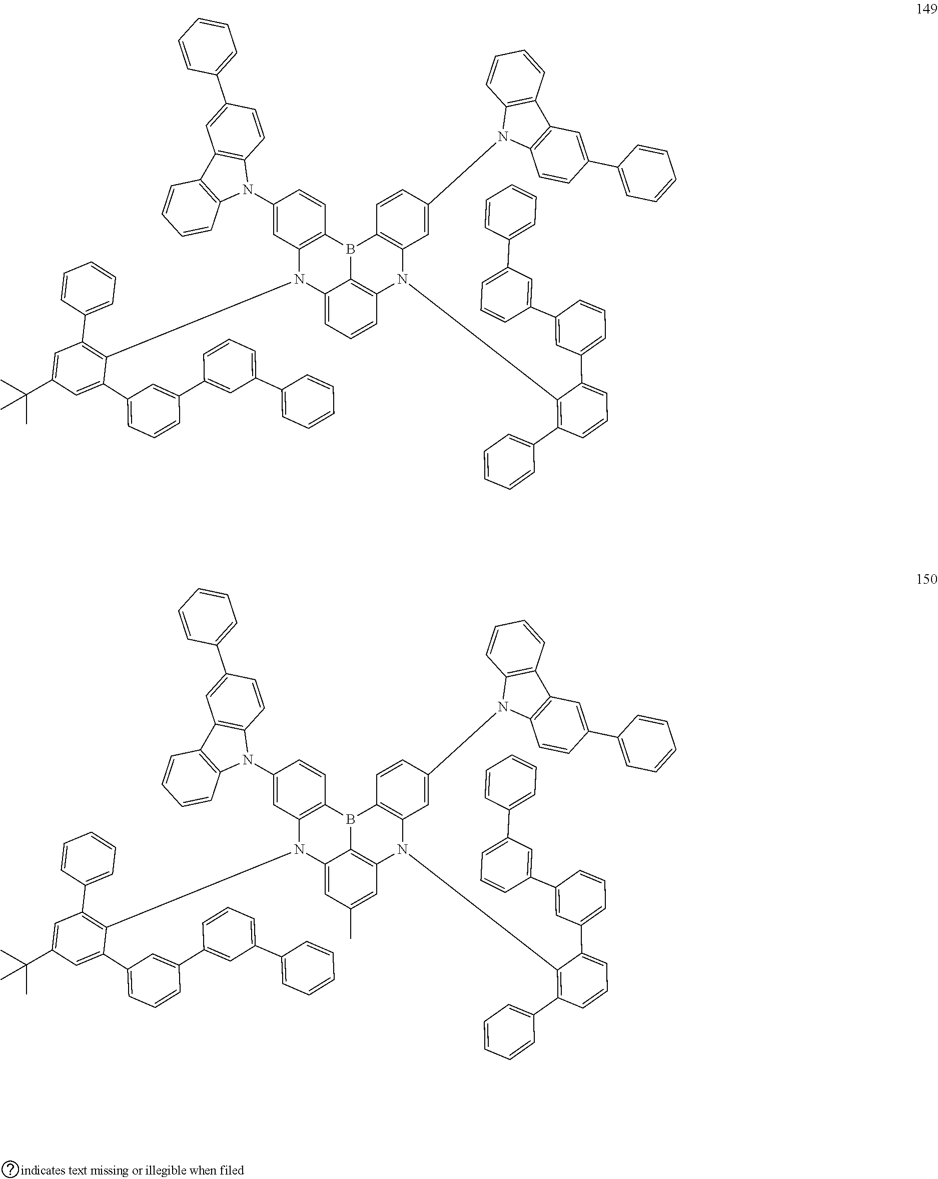 [SMILES: CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccccc5)cccc4-c4cccc(-c5cccc(-c6ccccc6)c5)c4)c4cccc2c43)c(-c2cccc(-c3cccc(-c4ccccc4)c3)c2)c1 ; Cc1cc2c3c(c1)N(c1c(-c4ccccc4)cc(C(C)(C)C)cc1-c1cccc(-c4cccc(-c5ccccc5)c4)c1)c1cc(-n4c5ccccc5c5cc(-c6ccccc6)ccc54)ccc1B3c1ccc(-n3c4ccccc4c4cc(-c5ccccc5)ccc43)cc1N2c1c(-c2ccccc2)cccc1-c1cccc(-c2cccc(-c3ccccc3)c2)c1]

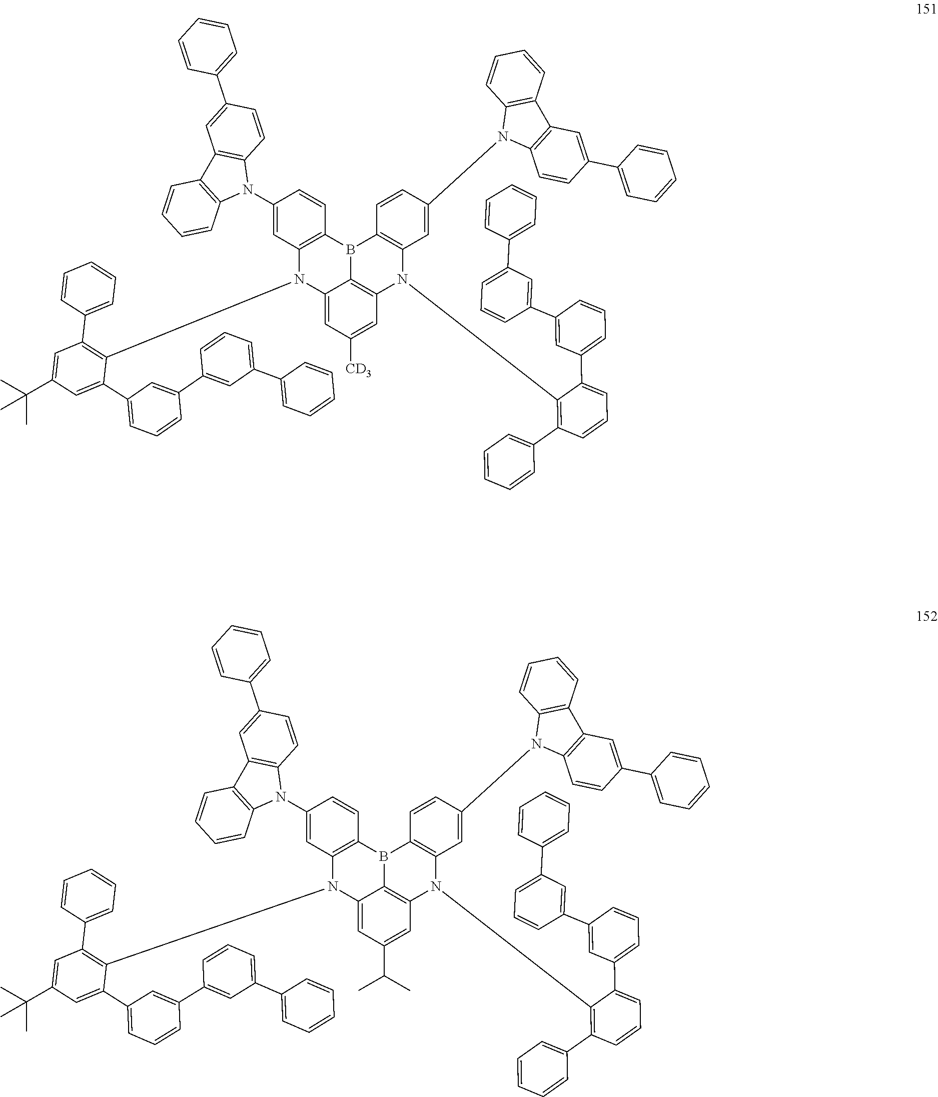 [SMILES: [2H]C([2H])([2H])c1cc2c3c(c1)N(c1c(-c4ccccc4)cc(C(C)(C)C)cc1-c1cccc(-c4cccc(-c5ccccc5)c4)c1)c1cc(-n4c5ccccc5c5cc(-c6ccccc6)ccc54)ccc1B3c1ccc(-n3c4ccccc4c4cc(-c5ccccc5)ccc43)cc1N2c1c(-c2ccccc2)cccc1-c1cccc(-c2cccc(-c3ccccc3)c2)c1 ; CC(C)c1cc2c3c(c1)N(c1c(-c4ccccc4)cc(C(C)(C)C)cc1-c1cccc(-c4cccc(-c5ccccc5)c4)c1)c1cc(-n4c5ccccc5c5cc(-c6ccccc6)ccc54)ccc1B3c1ccc(-n3c4ccccc4c4cc(-c5ccccc5)ccc43)cc1N2c1c(-c2ccccc2)cccc1-c1cccc(-c2cccc(-c3ccccc3)c2)c1]

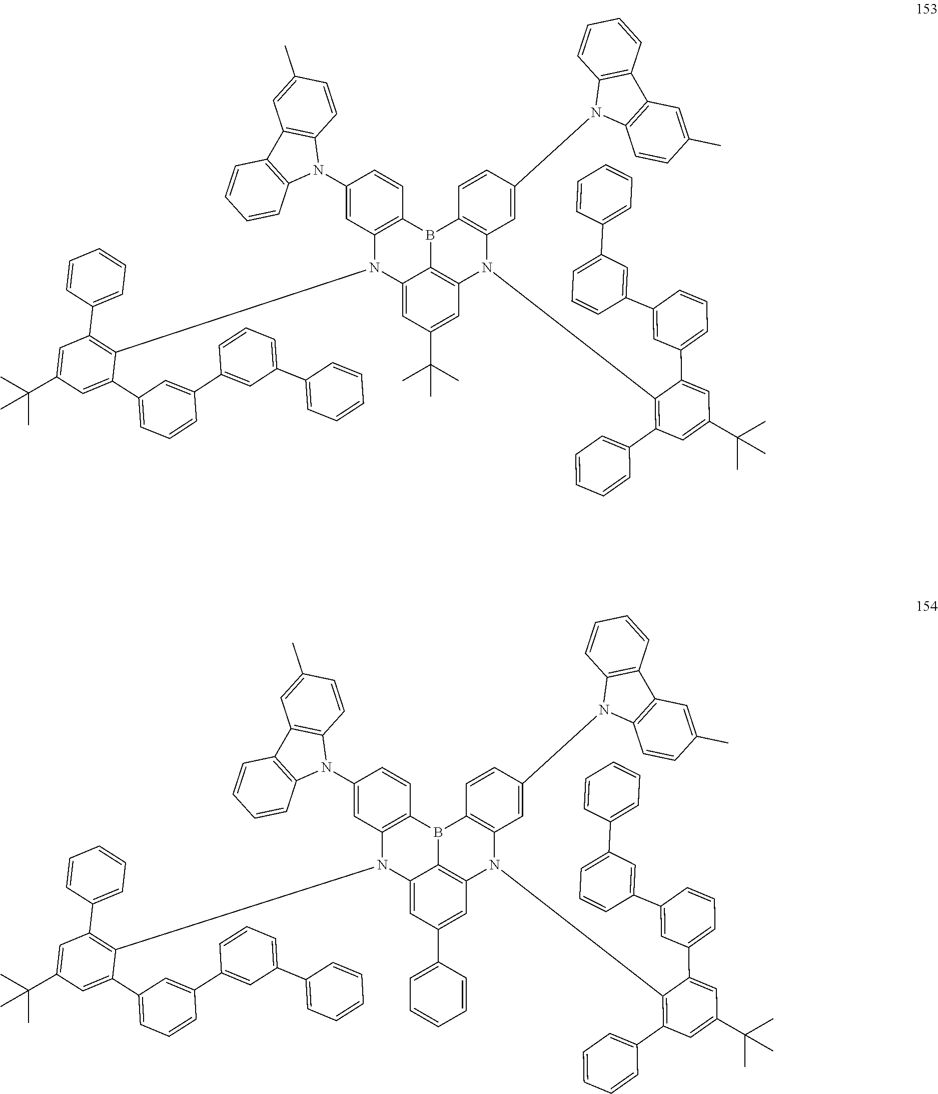

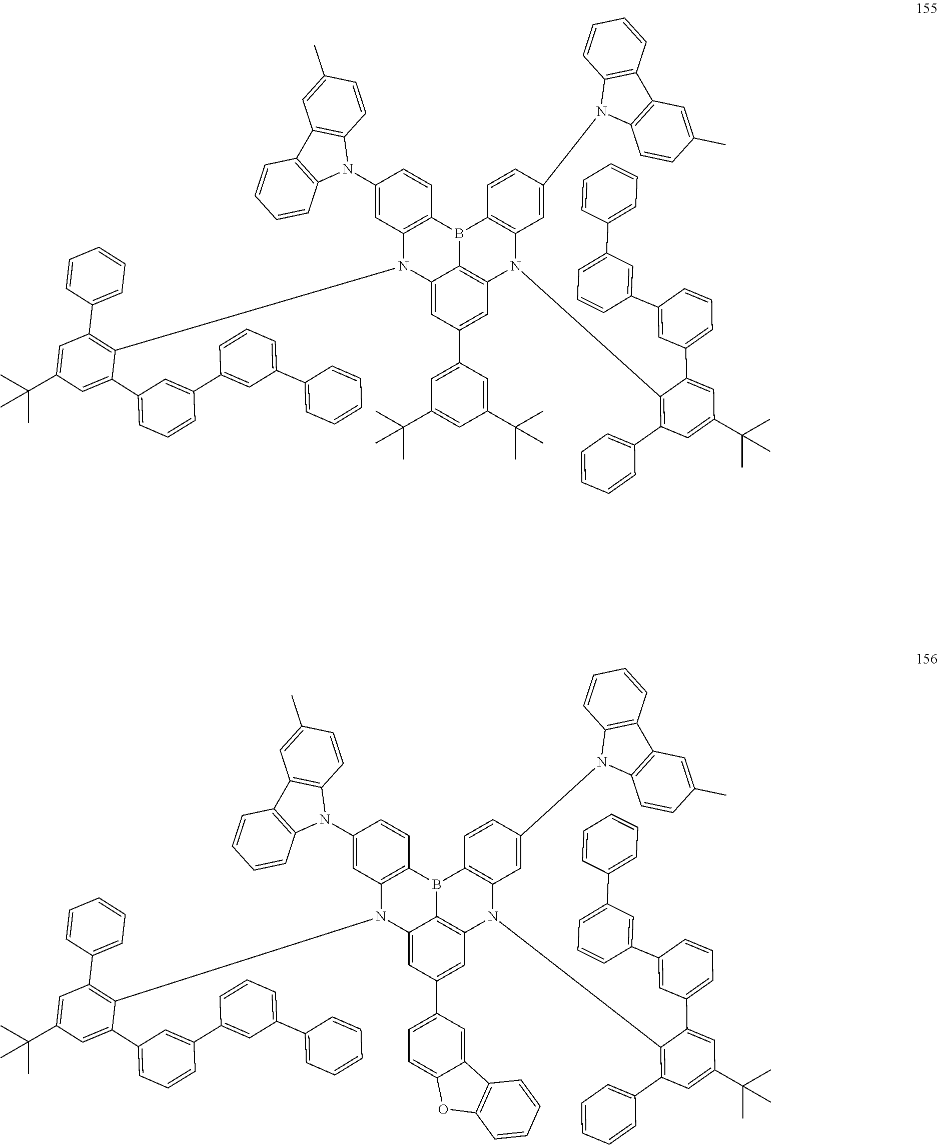

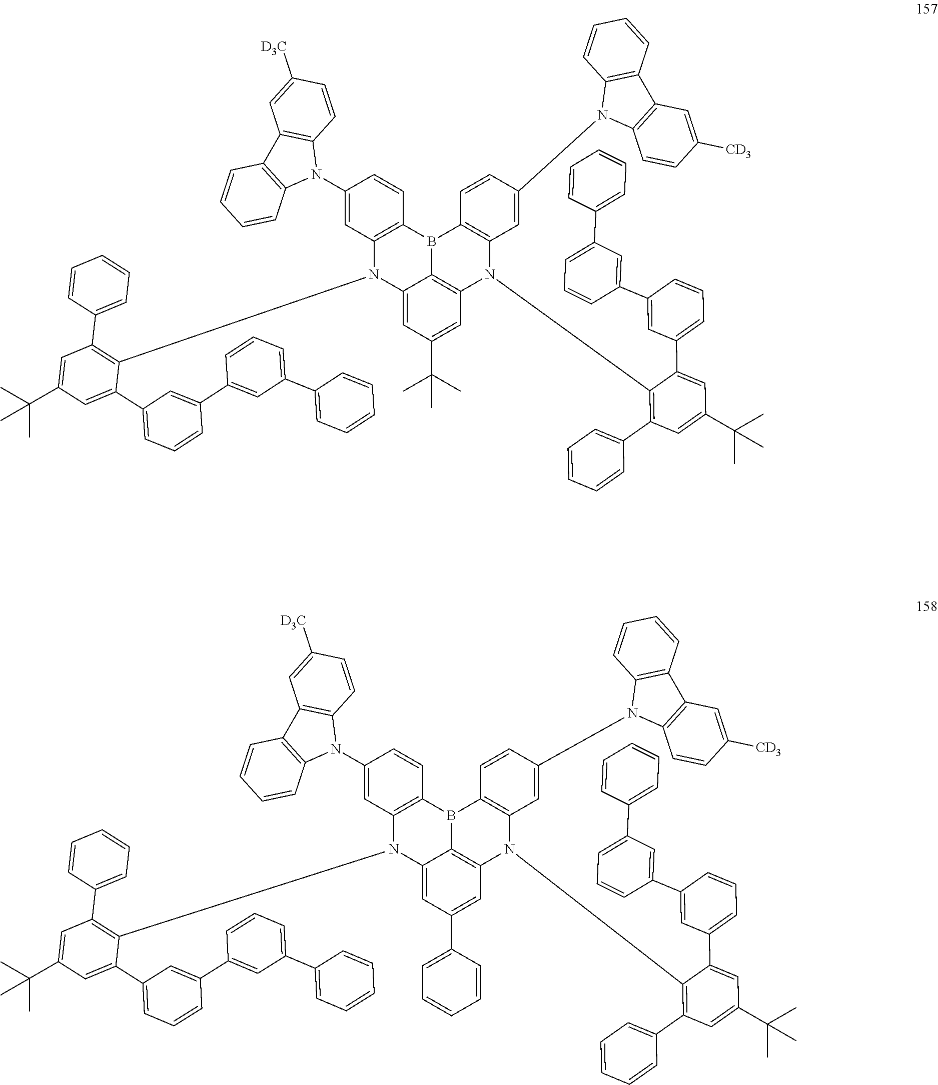

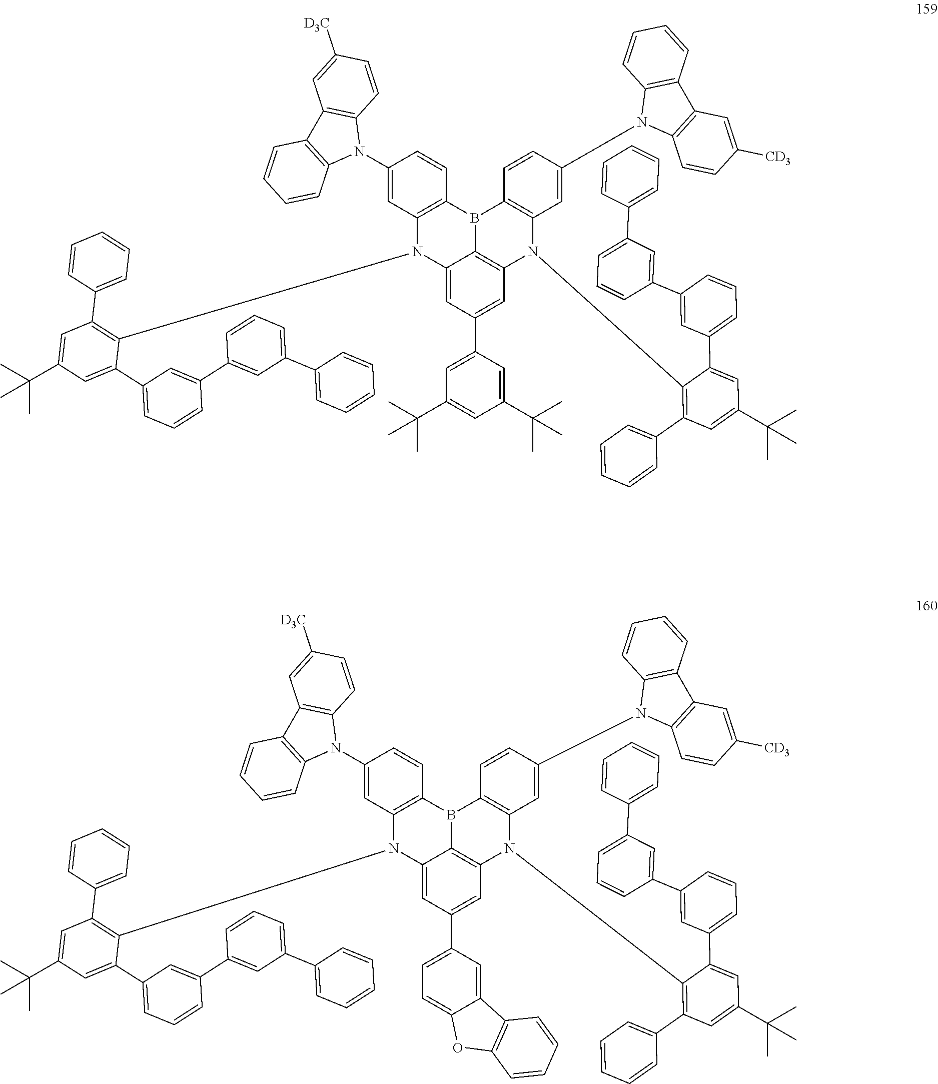

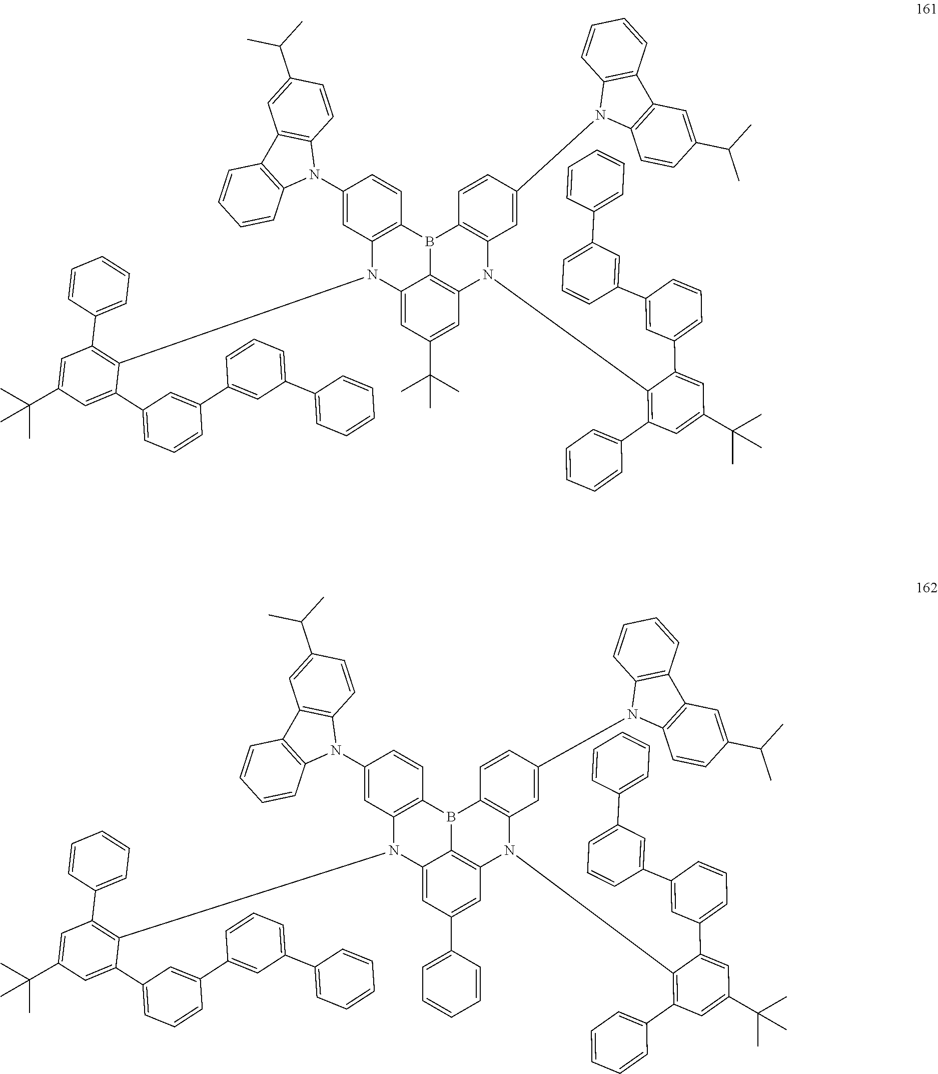

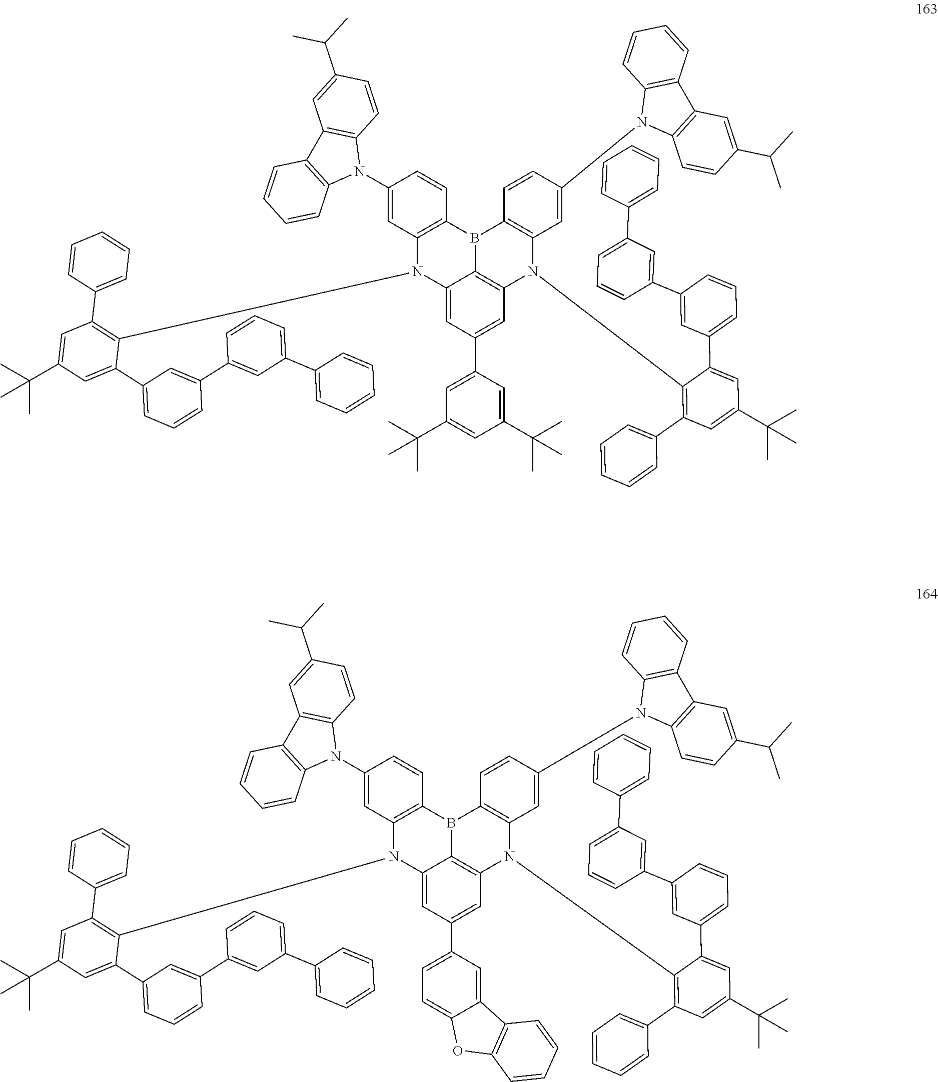

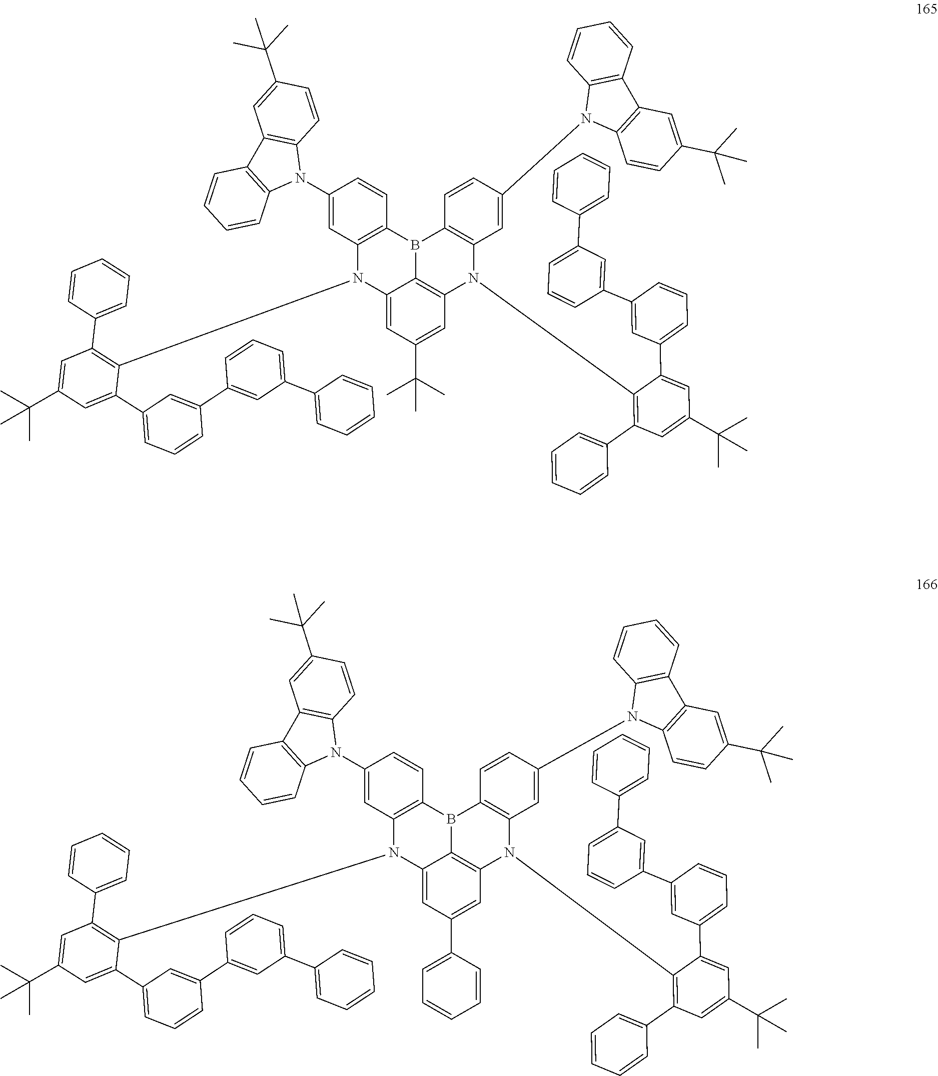

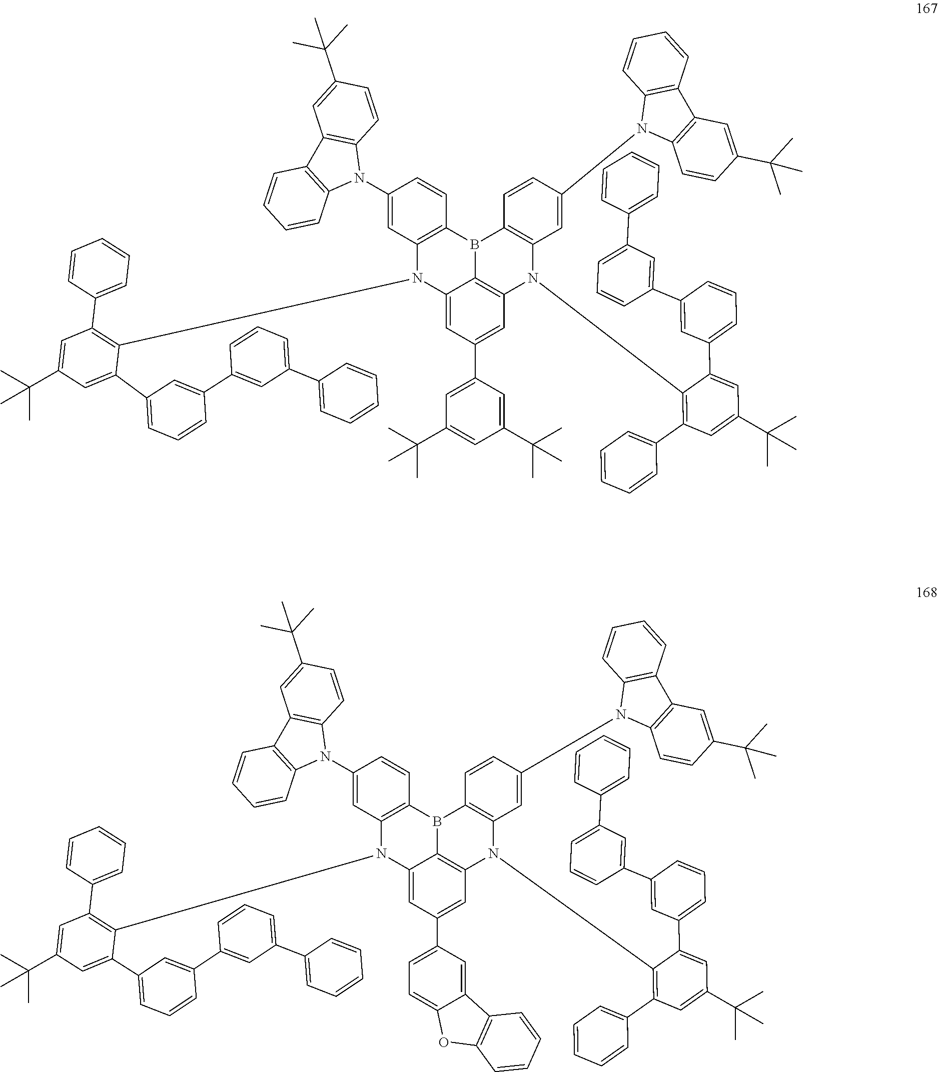

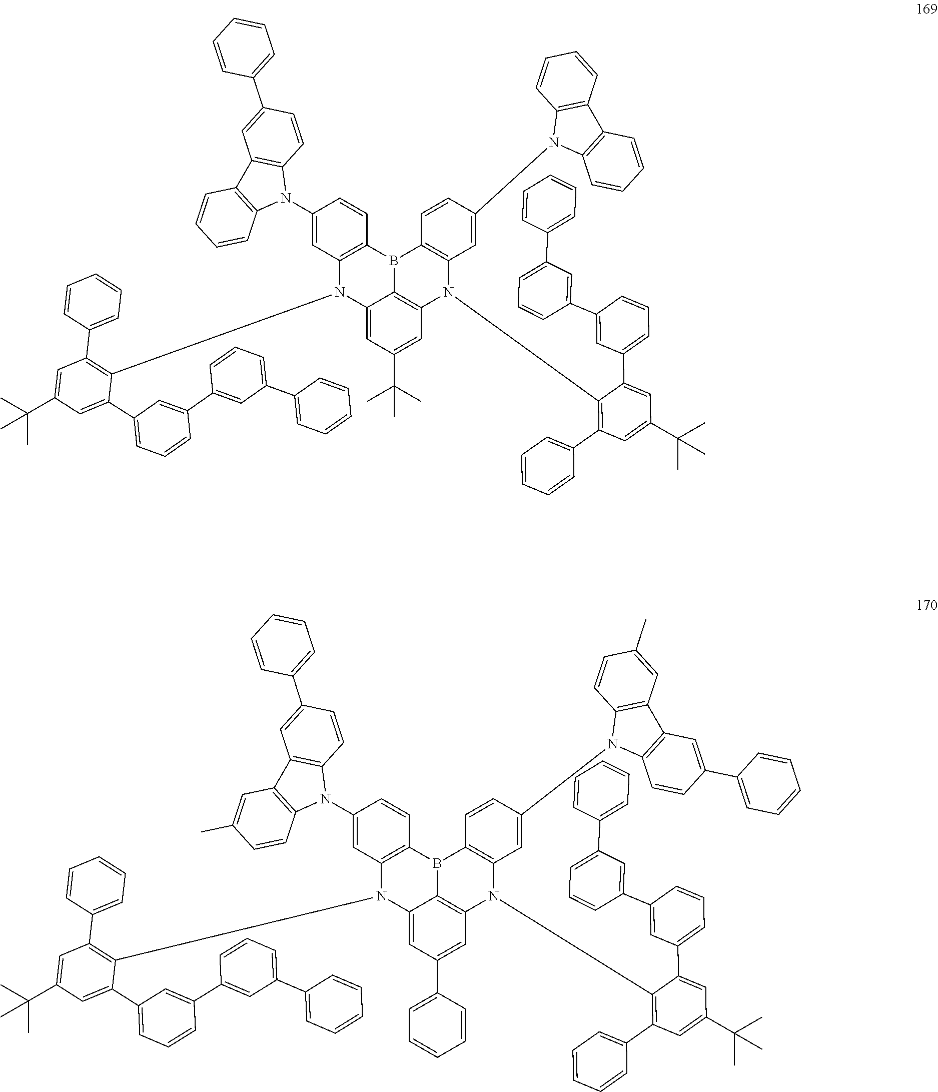

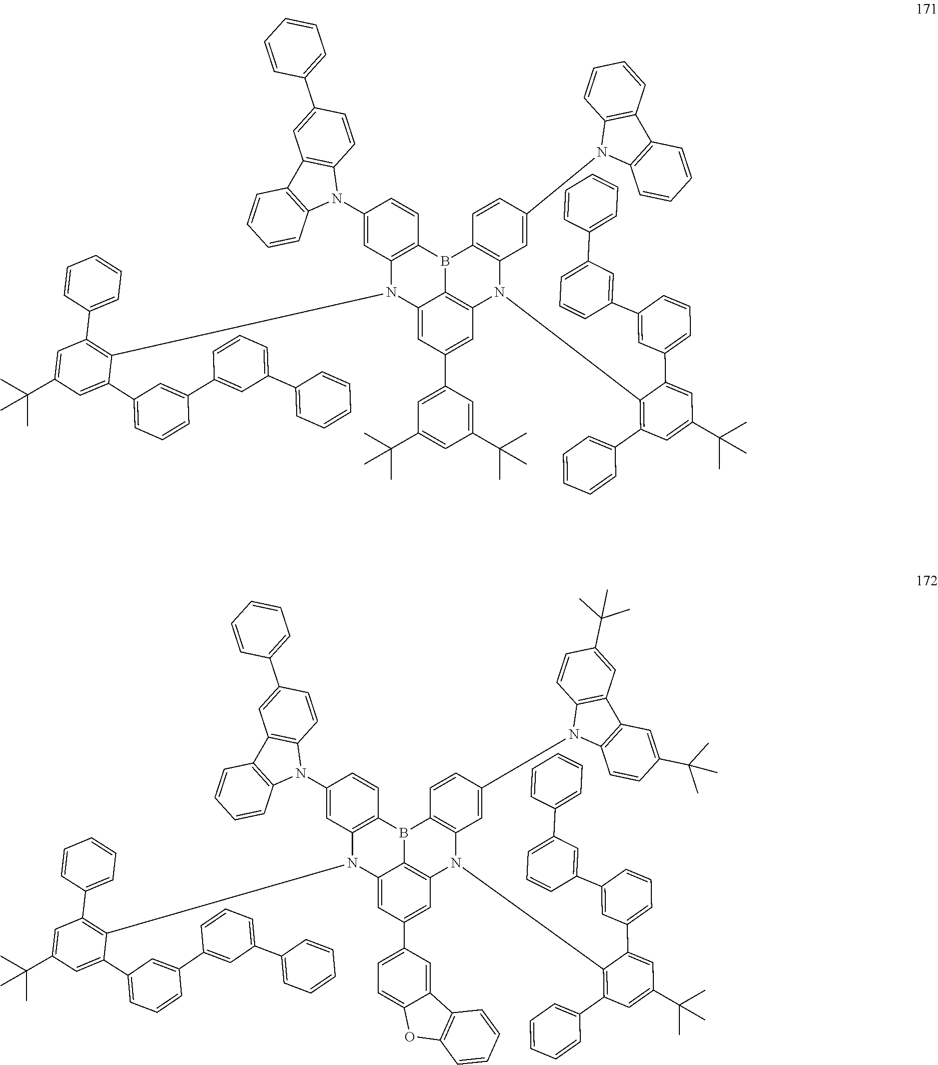

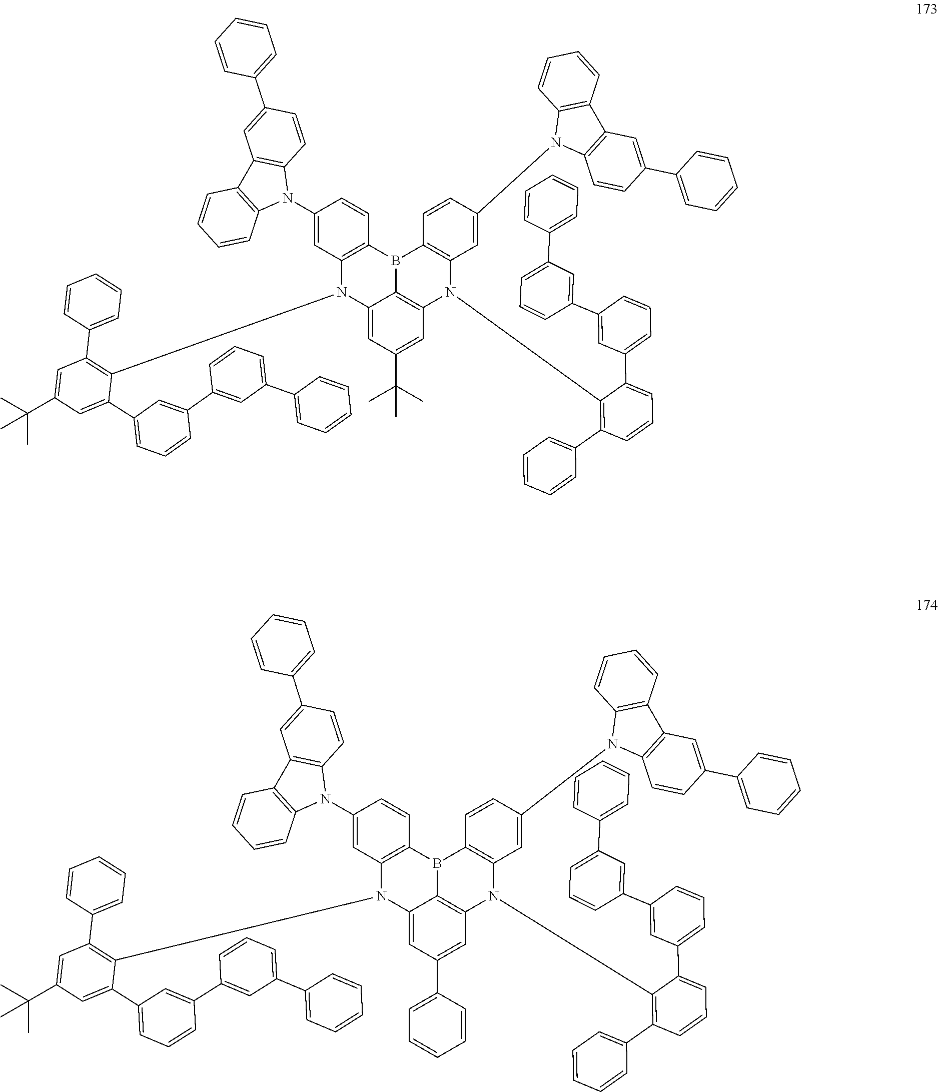 [SMILES: CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccccc5)cccc4-c4cccc(-c5cccc(-c6ccccc6)c5)c4)c4cc(C(C)(C)C)cc2c43)c(-c2cccc(-c3cccc(-c4ccccc4)c3)c2)c1 ; CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccccc5)cccc4-c4cccc(-c5cccc(-c6ccccc6)c5)c4)c4cc(-c5ccccc5)cc2c43)c(-c2cccc(-c3cccc(-c4ccccc4)c3)c2)c1]

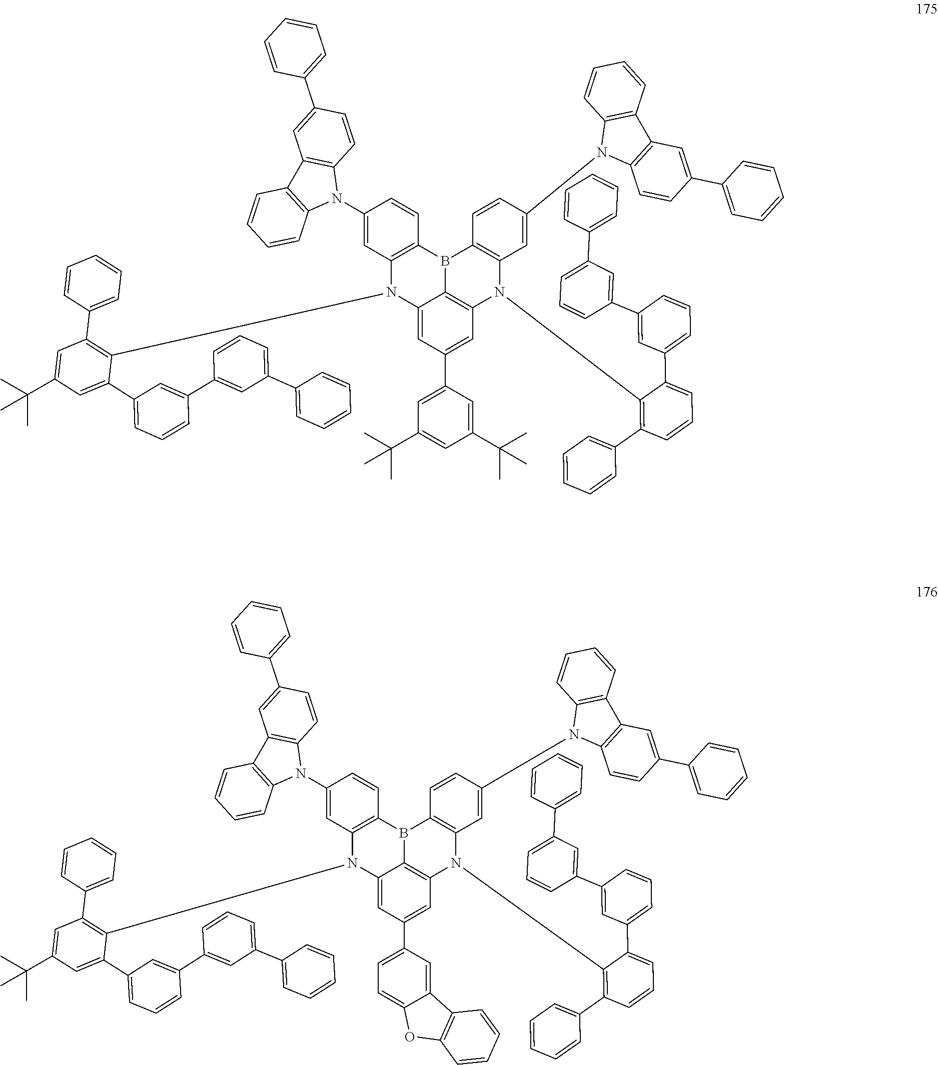 [SMILES: CC(C)(C)c1cc(-c2cc3c4c(c2)N(c2c(-c5ccccc5)cc(C(C)(C)C)cc2-c2cccc(-c5cccc(-c6ccccc6)c5)c2)c2cc(-n5c6ccccc6c6cc(-c7ccccc7)ccc65)ccc2B4c2ccc(-n4c5ccccc5c5cc(-c6ccccc6)ccc54)cc2N3c2c(-c3ccccc3)cccc2-c2cccc(-c3cccc(-c4ccccc4)c3)c2)cc(C(C)(C)C)c1 ; CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccccc5)cccc4-c4cccc(-c5cccc(-c6ccccc6)c5)c4)c4cc(-c5ccc6oc7ccccc7c6c5)cc2c43)c(-c2cccc(-c3cccc(-c4ccccc4)c3)c2)c1]

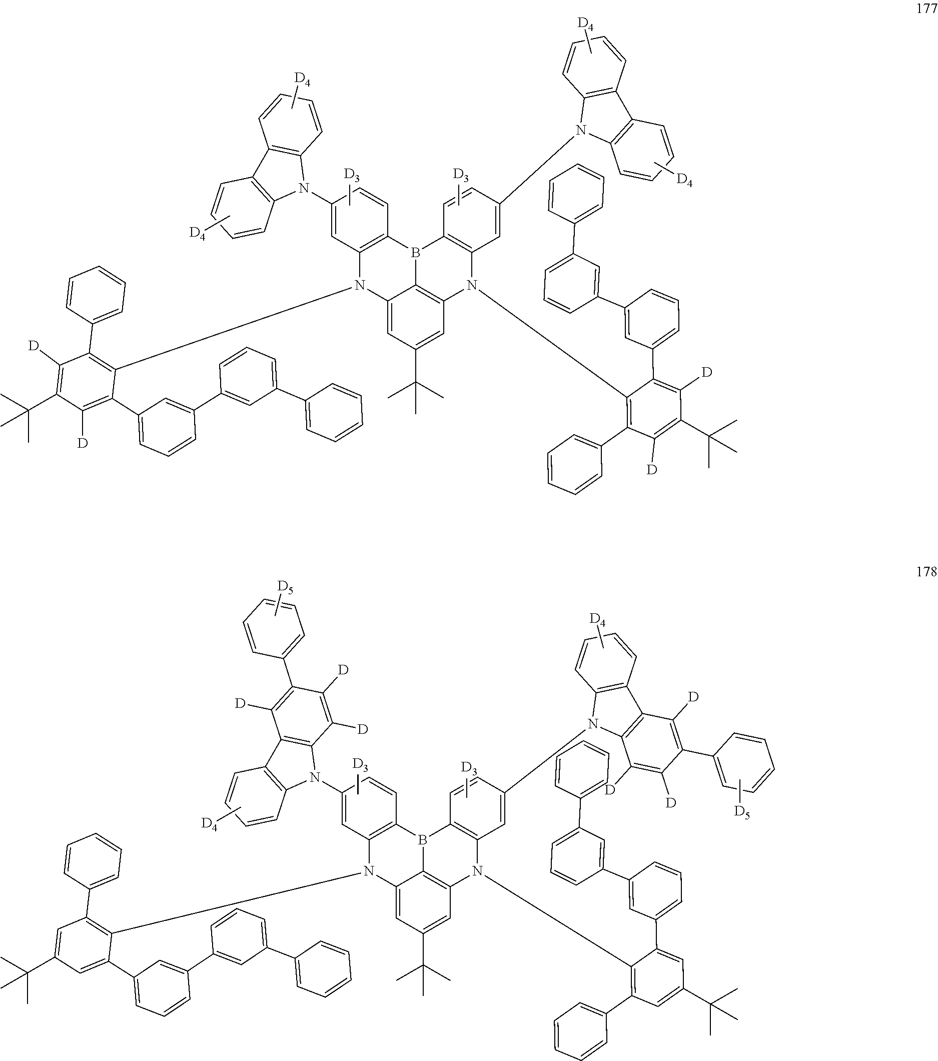

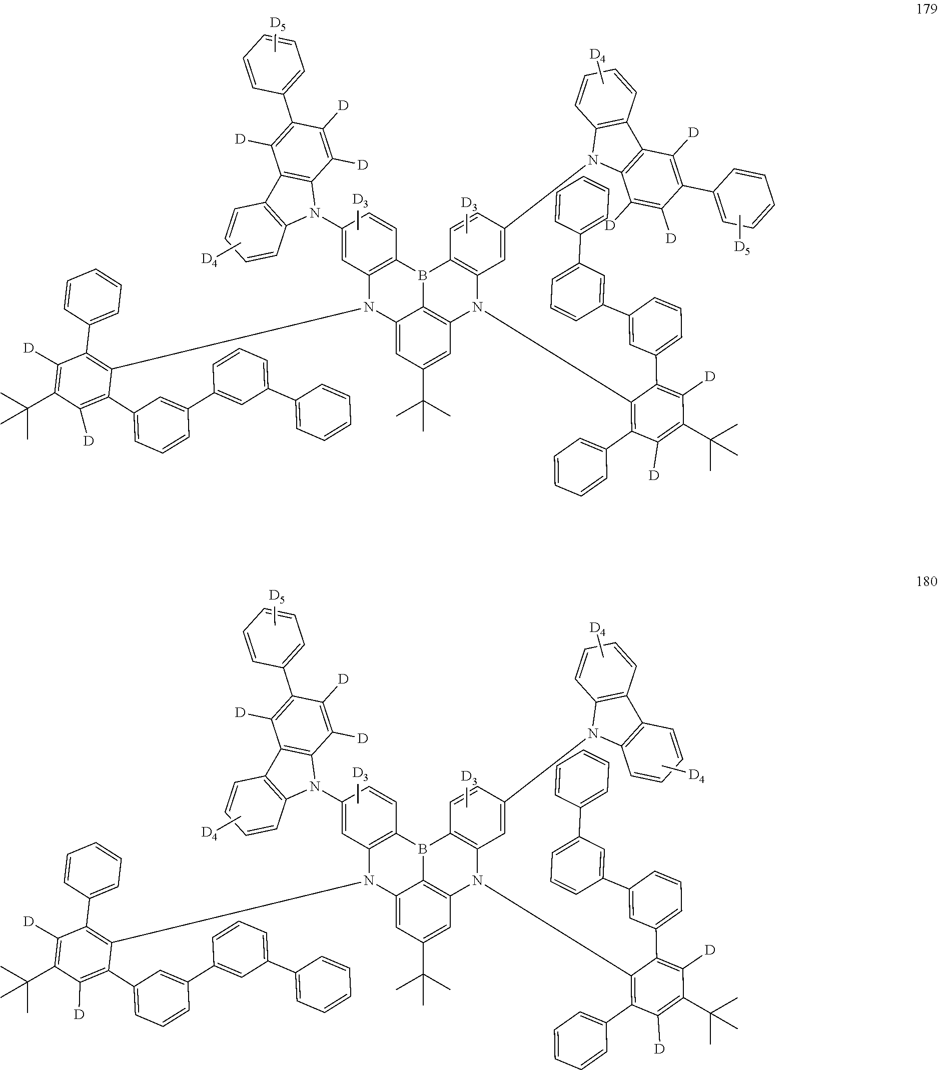

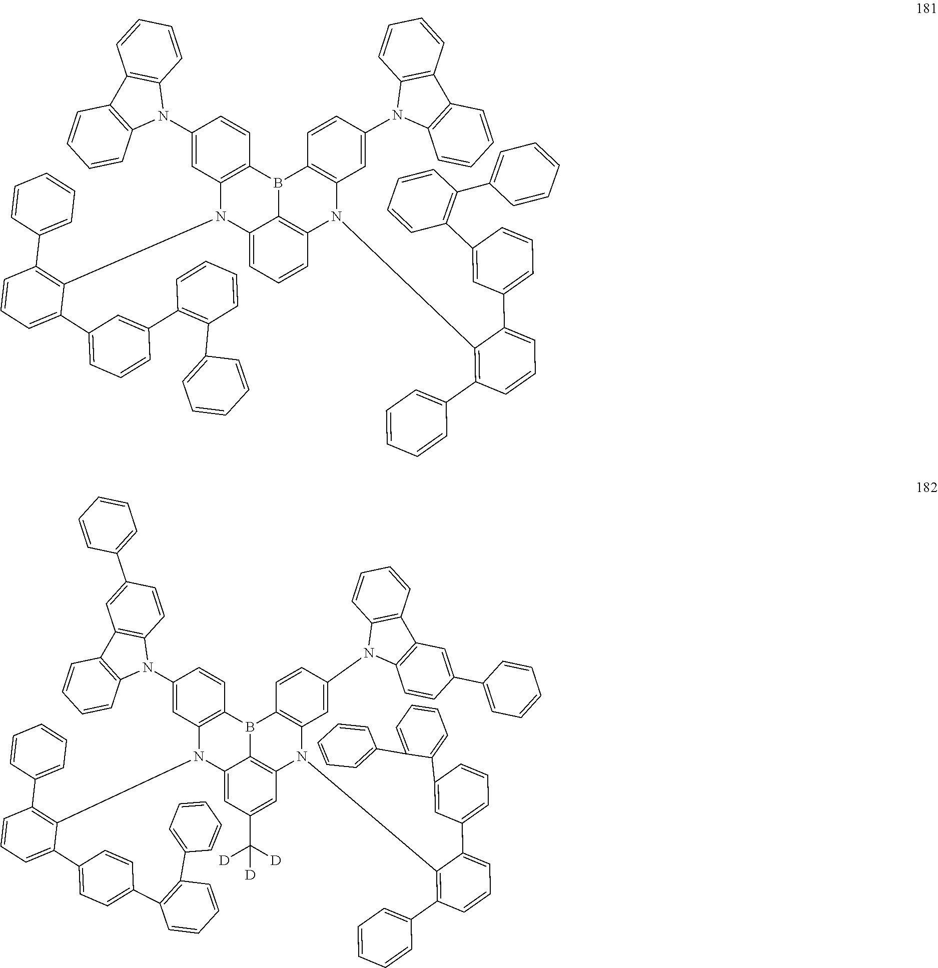 [SMILES: c1ccc(-c2ccccc2-c2cccc(-c3cccc(-c4ccccc4)c3N3c4cc(-n5c6ccccc6c6ccccc65)ccc4B4c5ccc(-n6c7ccccc7c7ccccc76)cc5N(c5c(-c6ccccc6)cccc5-c5cccc(-c6ccccc6-c6ccccc6)c5)c5cccc3c54)c2)cc1 ; [2H]C([2H])([2H])c1cc2c3c(c1)N(c1c(-c4ccccc4)cccc1-c1cccc(-c4ccccc4-c4ccccc4)c1)c1cc(-n4c5ccccc5c5cc(-c6ccccc6)ccc54)ccc1B3c1ccc(-n3c4ccccc4c4cc(-c5ccccc5)ccc43)cc1N2c1c(-c2ccccc2)cccc1-c1ccc(-c2ccccc2-c2ccccc2)cc1]

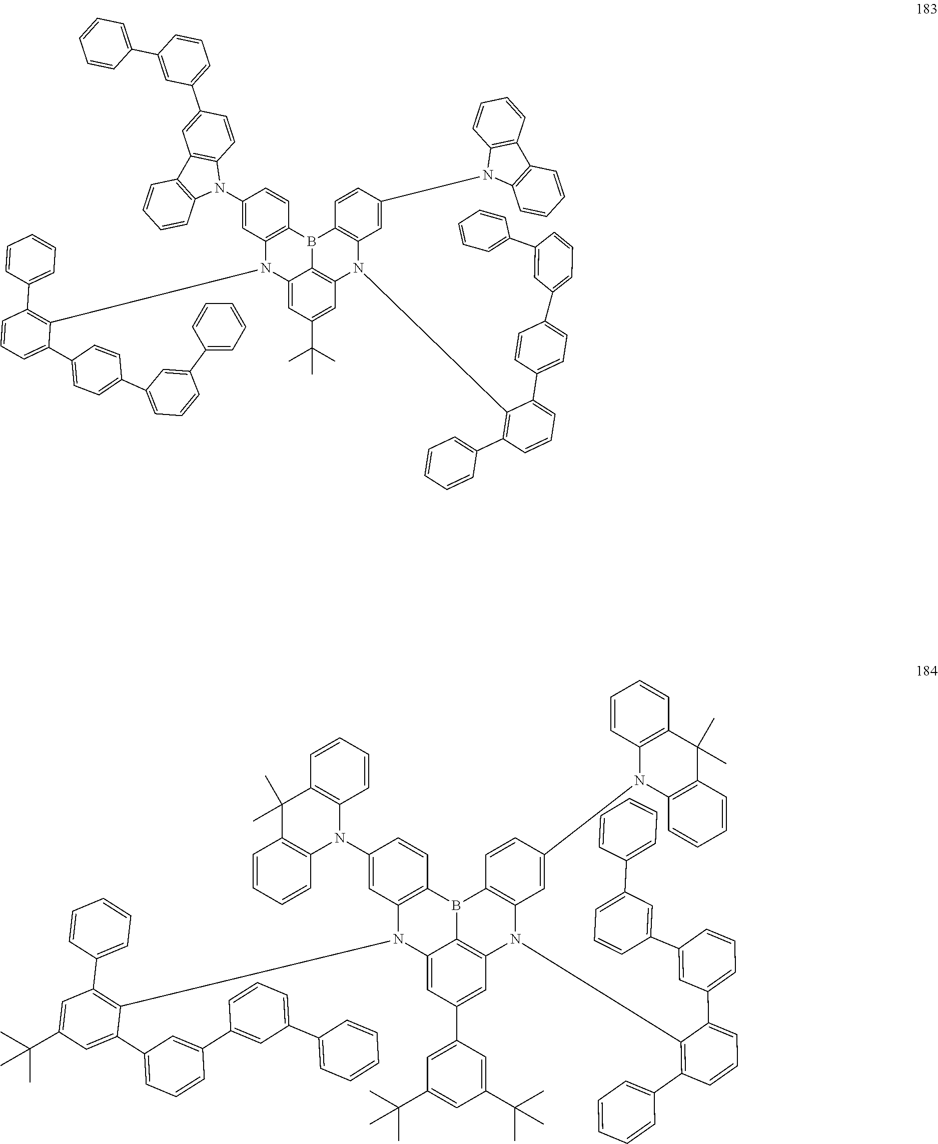 [SMILES: CC(C)(C)c1cc2c3c(c1)N(c1c(-c4ccccc4)cccc1-c1ccc(-c4cccc(-c5ccccc5)c4)cc1)c1cc(-n4c5ccccc5c5cc(-c6cccc(-c7ccccc7)c6)ccc54)ccc1B3c1ccc(-n3c4ccccc4c4ccccc43)cc1N2c1c(-c2ccccc2)cccc1-c1ccc(-c2cccc(-c3ccccc3)c2)cc1 ; CC(C)(C)c1cc(-c2cc3c4c(c2)N(c2c(-c5ccccc5)cc(C(C)(C)C)cc2-c2cccc(-c5cccc(-c6ccccc6)c5)c2)c2cc(N5c6ccccc6C(C)(C)c6ccccc65)ccc2B4c2ccc(N4c5ccccc5C(C)(C)c5ccccc54)cc2N3c2c(-c3ccccc3)cccc2-c2cccc(-c3cccc(-c4ccccc4)c3)c2)cc(C(C)(C)C)c1]

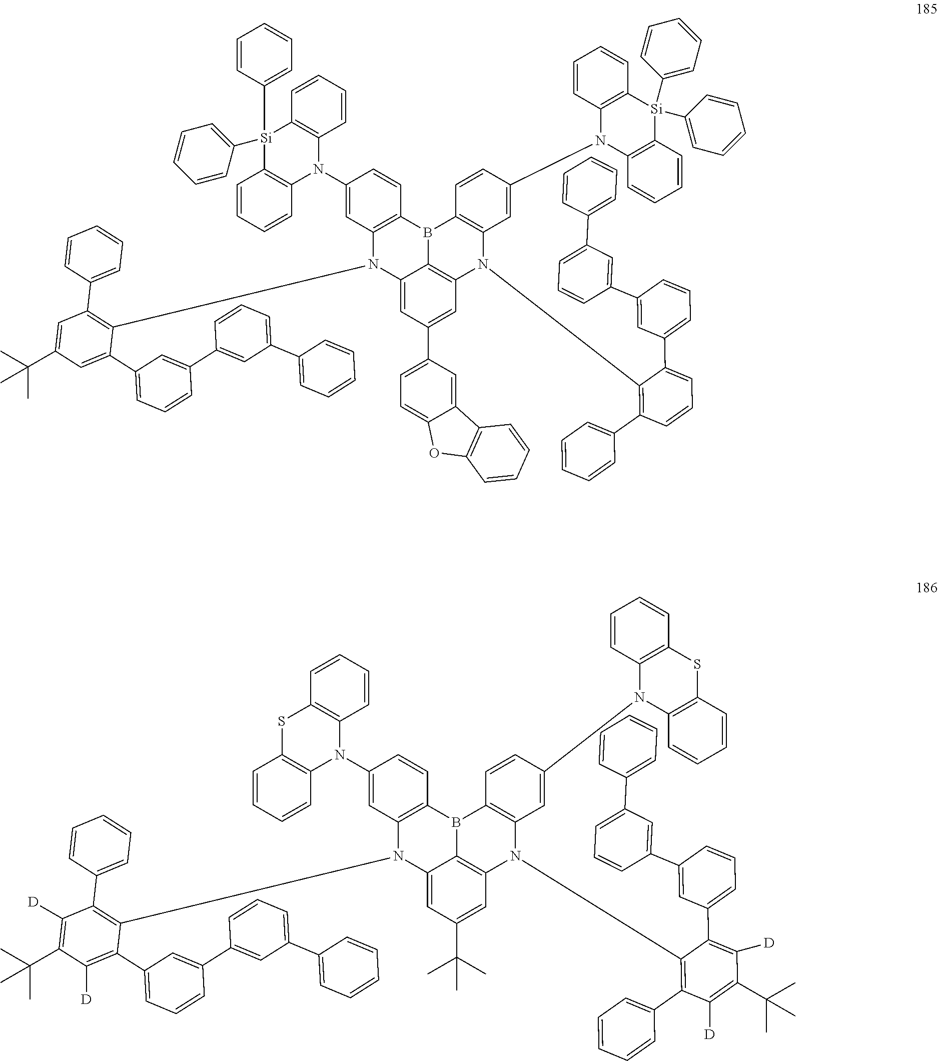 [SMILES: CC(C)(C)c1cc(-c2ccccc2)c(N2c3cc(N4c5ccccc5[Si](c5ccccc5)(c5ccccc5)c5ccccc54)ccc3B3c4ccc(N5c6ccccc6[Si](c6ccccc6)(c6ccccc6)c6ccccc65)cc4N(c4c(-c5ccccc5)cccc4-c4cccc(-c5cccc(-c6ccccc6)c5)c4)c4cc(-c5ccc6oc7ccccc7c6c5)cc2c43)c(-c2cccc(-c3cccc(-c4ccccc4)c3)c2)c1 ; [2H]c1c(-c2ccccc2)c(N2c3cc(N4c5ccccc5Sc5ccccc54)ccc3B3c4ccc(N5c6ccccc6Sc6ccccc65)cc4N(c4c(-c5ccccc5)c([2H])c(C(C)(C)C)c([2H])c4-c4cccc(-c5cccc(-c6ccccc6)c5)c4)c4cc(C(C)(C)C)cc2c43)c(-c2cccc(-c3cccc(-c4ccccc4)c3)c2)c([2H])c1C(C)(C)C]

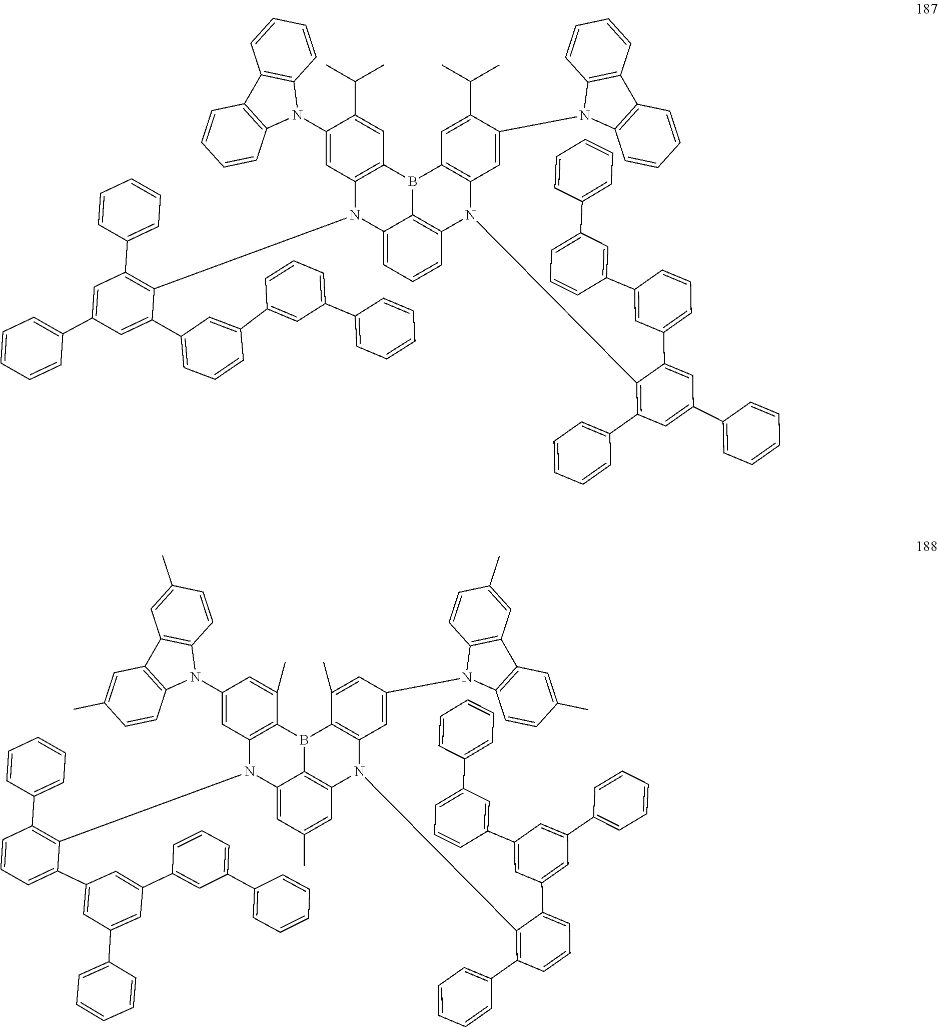 [SMILES: CC(C)c1cc2c(cc1-n1c3ccccc3c3ccccc31)N(c1c(-c3ccccc3)cc(-c3ccccc3)cc1-c1cccc(-c3cccc(-c4ccccc4)c3)c1)c1cccc3c1B2c1cc(C(C)C)c(-n2c4ccccc4c4ccccc42)cc1N3c1c(-c2ccccc2)cc(-c2ccccc2)cc1-c1cccc(-c2cccc(-c3ccccc3)c2)c1 ; Cc1cc2c3c(c1)N(c1c(-c4ccccc4)cccc1-c1cc(-c4ccccc4)cc(-c4cccc(-c5ccccc5)c4)c1)c1cc(-n4c5ccc(C)cc5c5cc(C)ccc54)cc(C)c1B3c1c(C)cc(-n3c4ccc(C)cc4c4cc(C)ccc43)cc1N2c1c(-c2ccccc2)cccc1-c1cc(-c2ccccc2)cc(-c2cccc(-c3ccccc3)c2)c1]

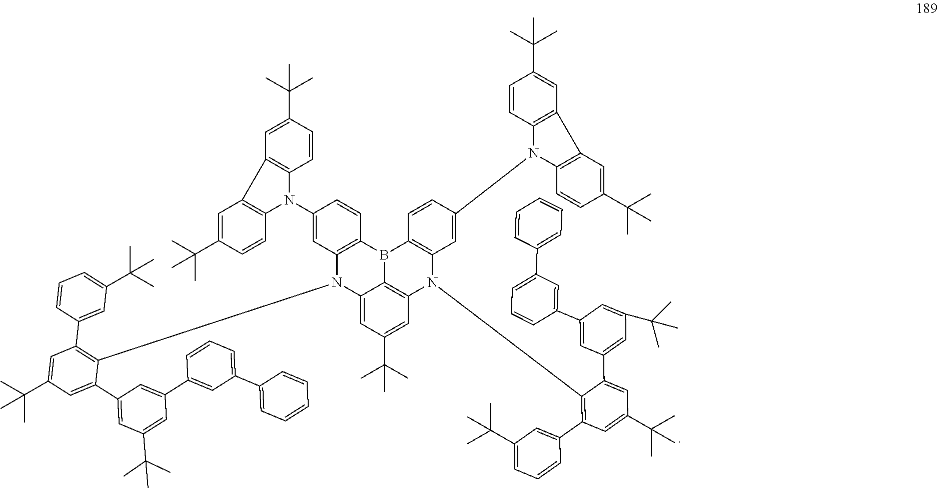 [SMILES: CC(C)(C)c1cccc(-c2cc(C(C)(C)C)cc(-c3cc(-c4cccc(-c5ccccc5)c4)cc(C(C)(C)C)c3)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5cccc(C(C)(C)C)c5)cc(C(C)(C)C)cc4-c4cc(-c5cccc(-c6ccccc6)c5)cc(C(C)(C)C)c4)c4cc(C(C)(C)C)cc2c43)c1]

11. A display device comprising:
a circuit layer disposed on a base layer; and
a display element layer disposed on the circuit layer and including a light emitting element, wherein
the light emitting element includes:
a first electrode;
a second electrode disposed on the first electrode; and
a light emitting layer disposed between the first electrode and the second electrode and including a first compound represented by Formula 1: 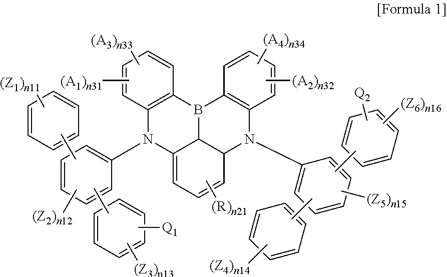
wherein in Formula 1,
Z₁ to Z₆ are each independently a hydrogen atom, a deuterium atom, a substituted or unsubstituted alkyl group having 1 to 30 carbon atoms, or a substituted or unsubstituted aryl group having 6 to 30 ring-forming carbon atoms,
R is a hydrogen atom, a deuterium atom, a substituted or unsubstituted alkyl group having 1 to 20 carbon atoms, a substituted or unsubstituted cycloalkyl group having 3 to 60 ring-forming carbon atoms, a substituted or unsubstituted aryl group having 6 to 60 ring-forming carbon atoms, or a substituted or unsubstituted heteroaryl group having 2 to 60 ring-forming carbon atoms,
A₁ and A₂ are each independently a substituted or unsubstituted heteroaryl group having 2 to 60 ring-forming carbon atoms,
A₃ and A₄ are each independently a hydrogen atom, a deuterium atom, a substituted or unsubstituted alkyl group having 1 to 20 carbon atoms, or a substituted or unsubstituted aryl group having 6 to 60 ring-forming carbon atoms,
Q₁ and Q₂ are each independently a substituted or unsubstituted biphenyl group,
n11 and n14 are each independently an integer from 0 to 5,
n12, n15, n21, n33, and n34 are each independently an integer from 0 to 3,
n13 and n16 are each independently an integer from 0 to 4,
n31 and n32 are each independently an integer from 1 to 4,
the sum of n31 and n33 is an integer from 1 to 4, and
the sum of n32 and n34 is an integer from 1 to 4.

12. A polycyclic compound represented by Formula 1: 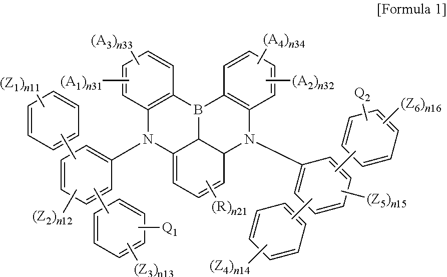
wherein in Formula 1,
Z₁ to Z₆ are each independently a hydrogen atom, a deuterium atom, a substituted or unsubstituted alkyl group having 1 to 30 carbon atoms, or a substituted or unsubstituted aryl group having 6 to 30 ring-forming carbon atoms,
R is a hydrogen atom, a deuterium atom, a substituted or unsubstituted alkyl group having 1 to 20 carbon atoms, a substituted or unsubstituted cycloalkyl group having 3 to 60 ring-forming carbon atoms, a substituted or unsubstituted aryl group having 6 to 60 ring-forming carbon atoms, or a substituted or unsubstituted heteroaryl group having 2 to 60 ring-forming carbon atoms,
A₁ and A₂ are each independently a substituted or unsubstituted heteroaryl group having 2 to 60 ring-forming carbon atoms,
A₃ and A₄ are each independently a hydrogen atom, a deuterium atom, a substituted or unsubstituted alkyl group having 1 to 20 carbon atoms, or a substituted or unsubstituted aryl group having 6 to 60 ring-forming carbon atoms,
Q₁ and Q₂ are each independently a substituted or unsubstituted biphenyl group,
n11 and n14 are each independently an integer from 0 to 5,
n12, n15, n21, n33, and n34 are each independently an integer from 0 to 3,
n13 and n16 are each independently an integer from 0 to 4,
n31 and n32 are each independently an integer from 1 to 4, and
the sum of n31 and n33 is an integer from 1 to 4, and
the sum of n32 and n34 is an integer from 1 to 4.

13. The polycyclic compound of claim 12, wherein the polycyclic compound represented by Formula 1 is a polycyclic compound represented by Formula 2: 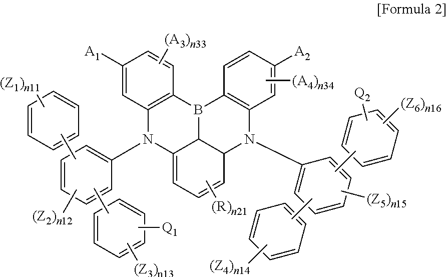
wherein in Formula 2,
Z₁ to Z₆, R, A₁ to A₄, Q₁, Q₂, n11 to n16, n21, n33, and n34 are the same as defined in Formula 1.

14. The polycyclic compound of claim 12, wherein the polycyclic compound represented by Formula 1 is a polycyclic compound represented by Formula 3: 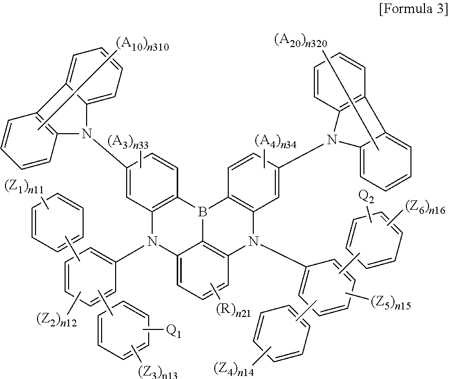
wherein in Formula 3,
A₁₀ and A₂₀ are each independently a hydrogen atom, a deuterium atom, a halogen atom, a cyano group, a substituted or unsubstituted silyl group, a substituted or unsubstituted oxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring,
n310 and n320 are each independently an integer from 0 to 8, and
Z₁ to Z₆, R, A₃, A₄, Q₁, Q₂, n11 to n16, n21, n33, and n34 are the same as defined in Formula 1.

15. The polycyclic compound of claim 12, wherein in Formula 1, R is a group represented by one of Formula X-1 to Formula X-8: 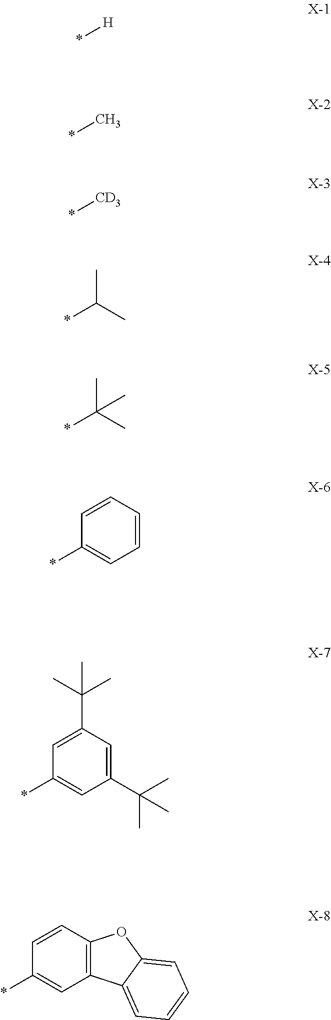
wherein in Formula X-1 to Formula X-8,
*— is a position connected to Formula 1.

16. The polycyclic compound of claim 12, wherein the polycyclic compound represented by Formula 1 is a polycyclic compound represented by Formula 4: 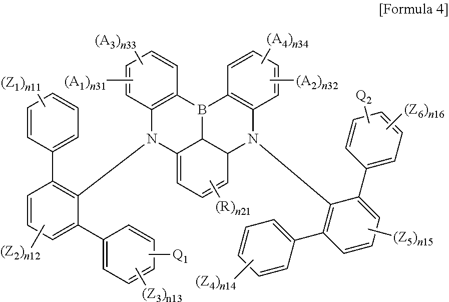
wherein in Formula 4,
Z₁ to Z₆, R, A₁ to A₄, Q₁, Q₂, n11 to n16, n21, and n31 to n34 are the same as defined in Formula 1 above.

17. The polycyclic compound of claim 16, wherein the polycyclic compound represented by Formula 4 is a polycyclic compound represented by Formula 5-1 or Formula 5-2: 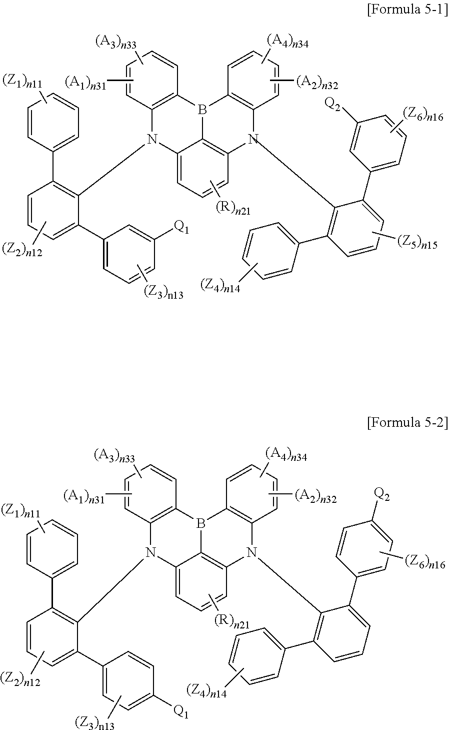
wherein in Formula 5-1 and Formula 5-2,
Z₁ to Z₆, R, A₁ to A₄, Q₁, Q₂, n11 to n16, n21, and n31 to n34 are the same as defined in Formula 1.

18. The polycyclic compound of claim 16, wherein the polycyclic compound represented by Formula 4 is a polycyclic compound represented by one of Formula 6-1 to Formula 6-4: 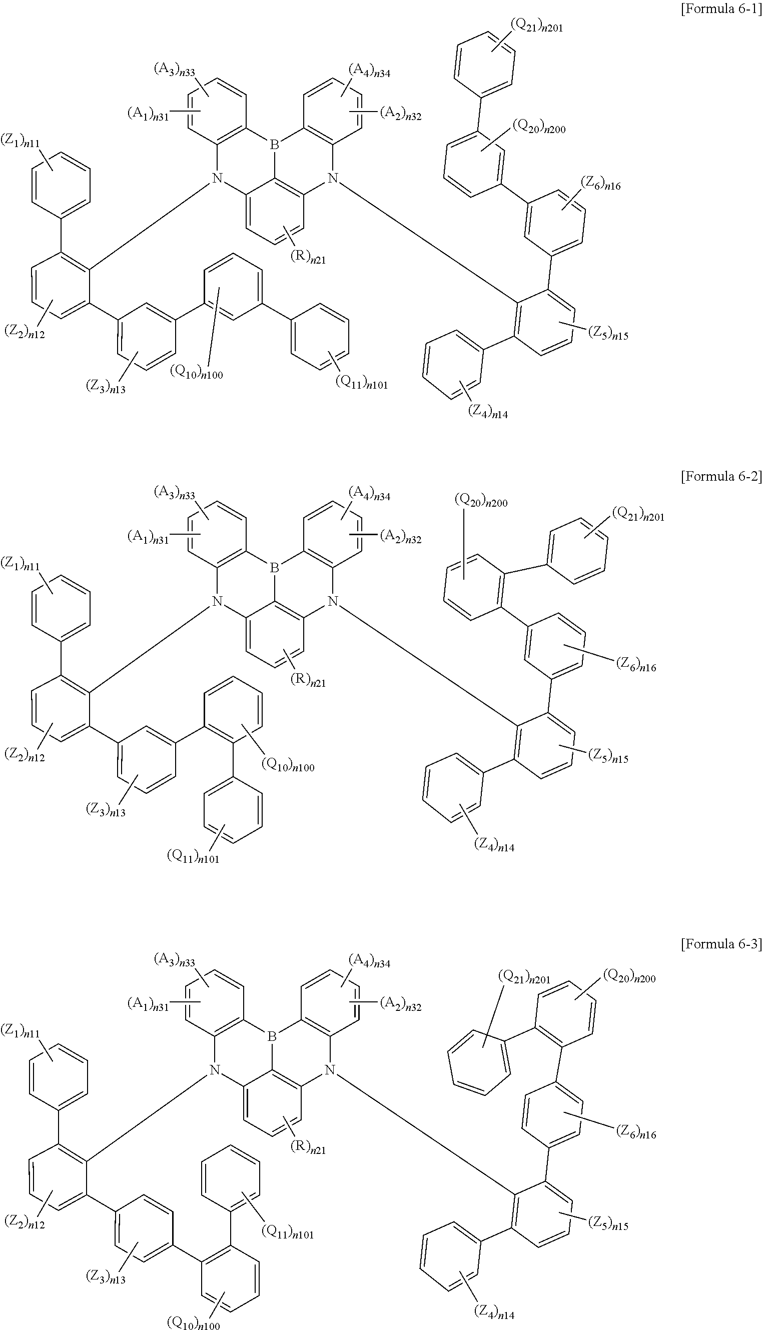 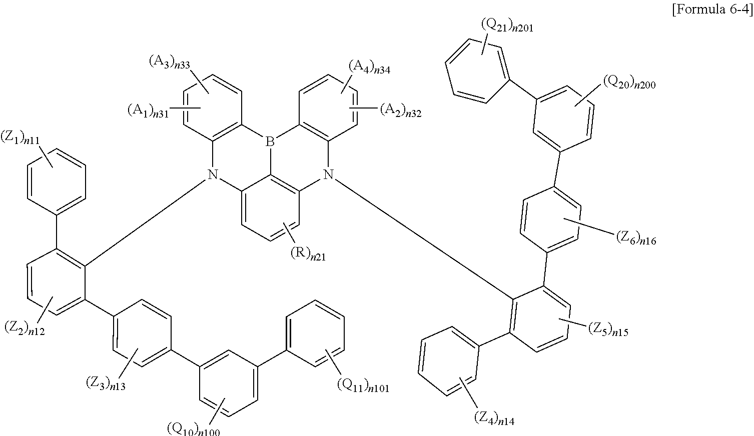
wherein in Formula 6-1 to Formula 6-4,
Q₁₀, Q₁₁, Q₂₀, and Q₂₁ are each independently a hydrogen atom, a deuterium atom, a halogen atom, a cyano group, a substituted or unsubstituted silyl group, a substituted or unsubstituted oxy group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring,
n100 and n200 are each independently an integer from 0 to 4,
n101 and n201 are each independently an integer from 0 to 5, and
A₁ to A₄, Z₁ to Z₆, R, n11 to n16, n21, and n31 to n34 are the same as defined in Formula 1.

19. The polycyclic compound of claim 12, wherein in Formula 1, Z₂ and Z₅ are each independently a group represented by one of Formula Y-1 to Formula Y-7: 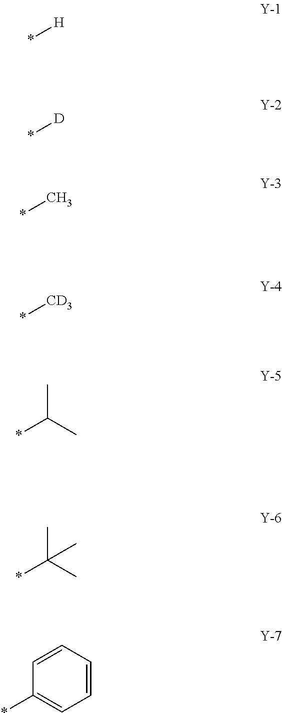
wherein in Formula Y-1 to Formula Y-7,
*— is a position connected to Formula 1.

20. The polycyclic compound of claim 12, wherein the polycyclic compound represented by Formula 1 is selected from Compound Group 1: 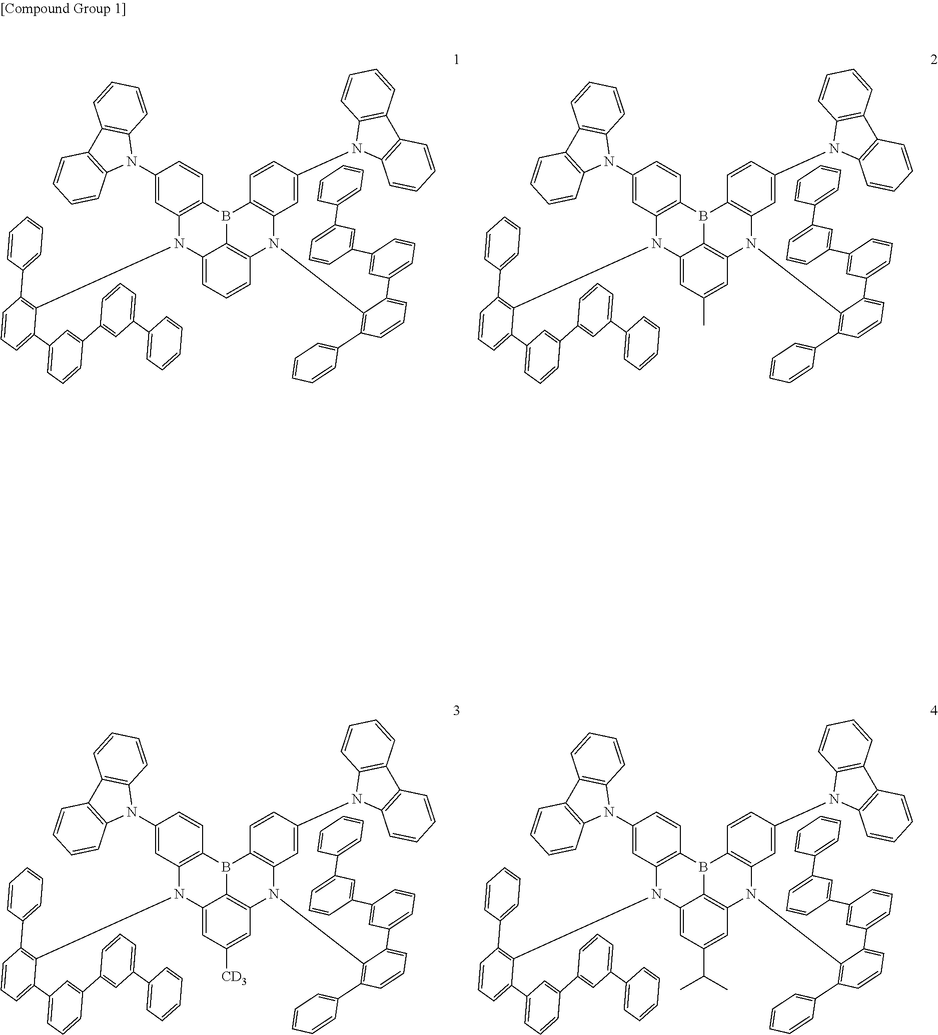 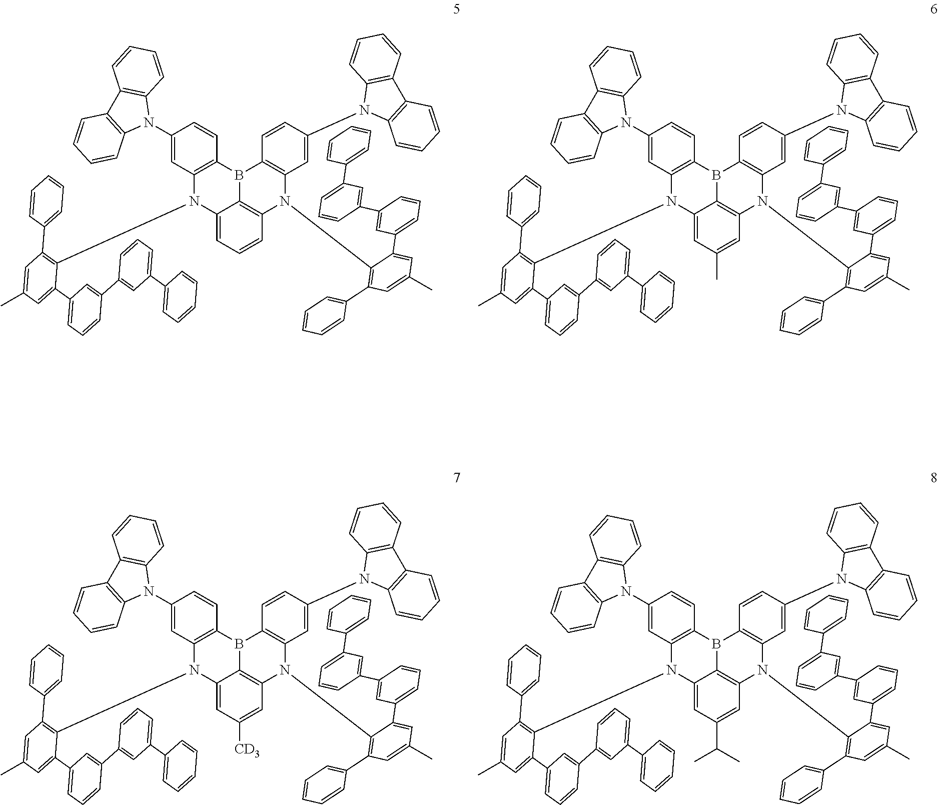 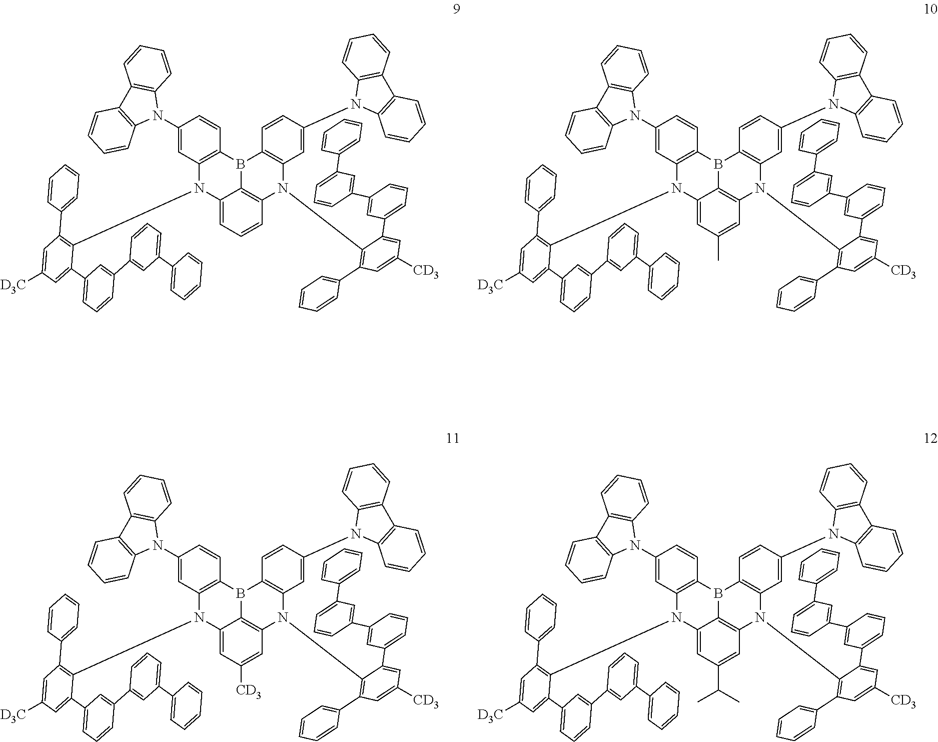 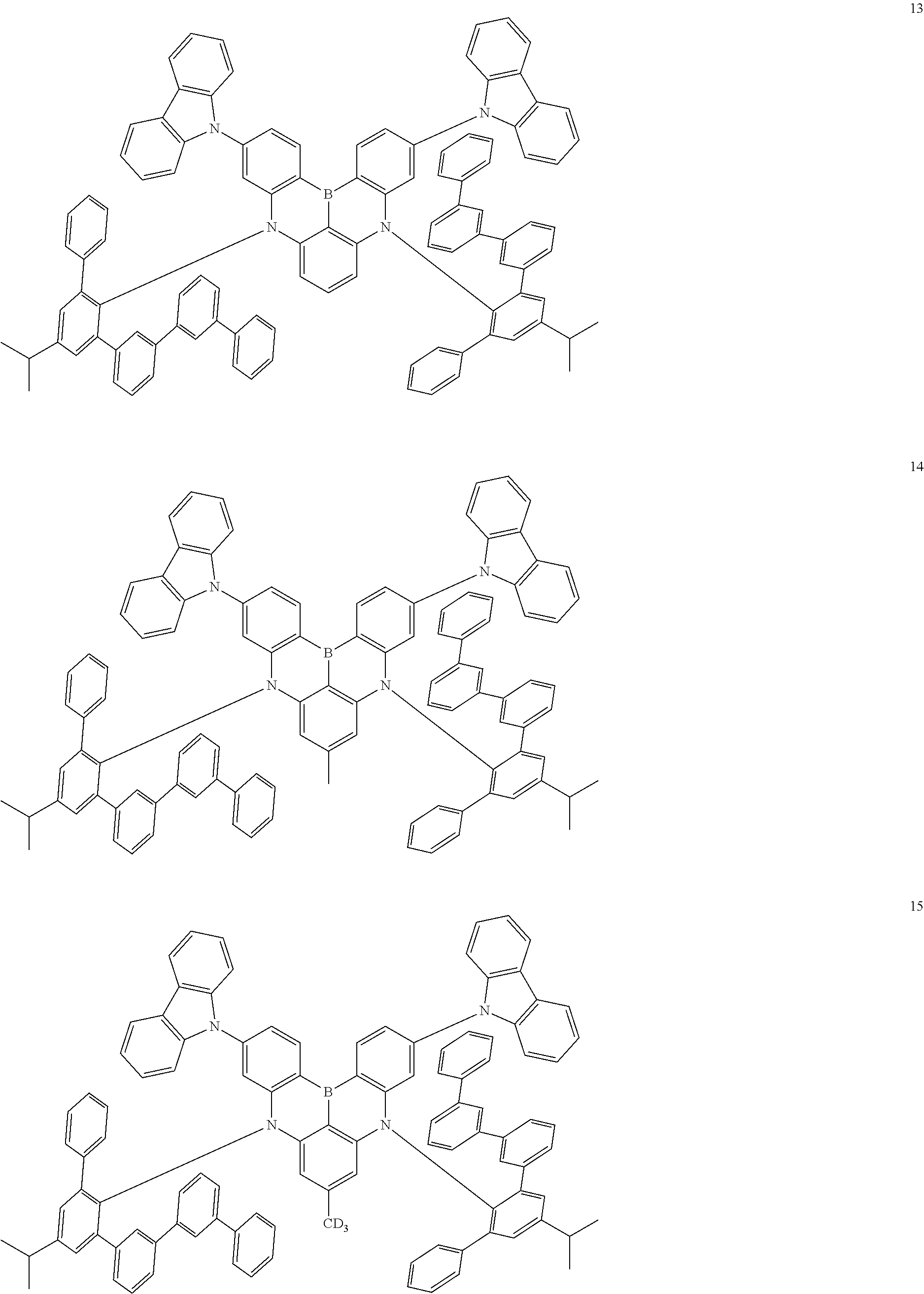 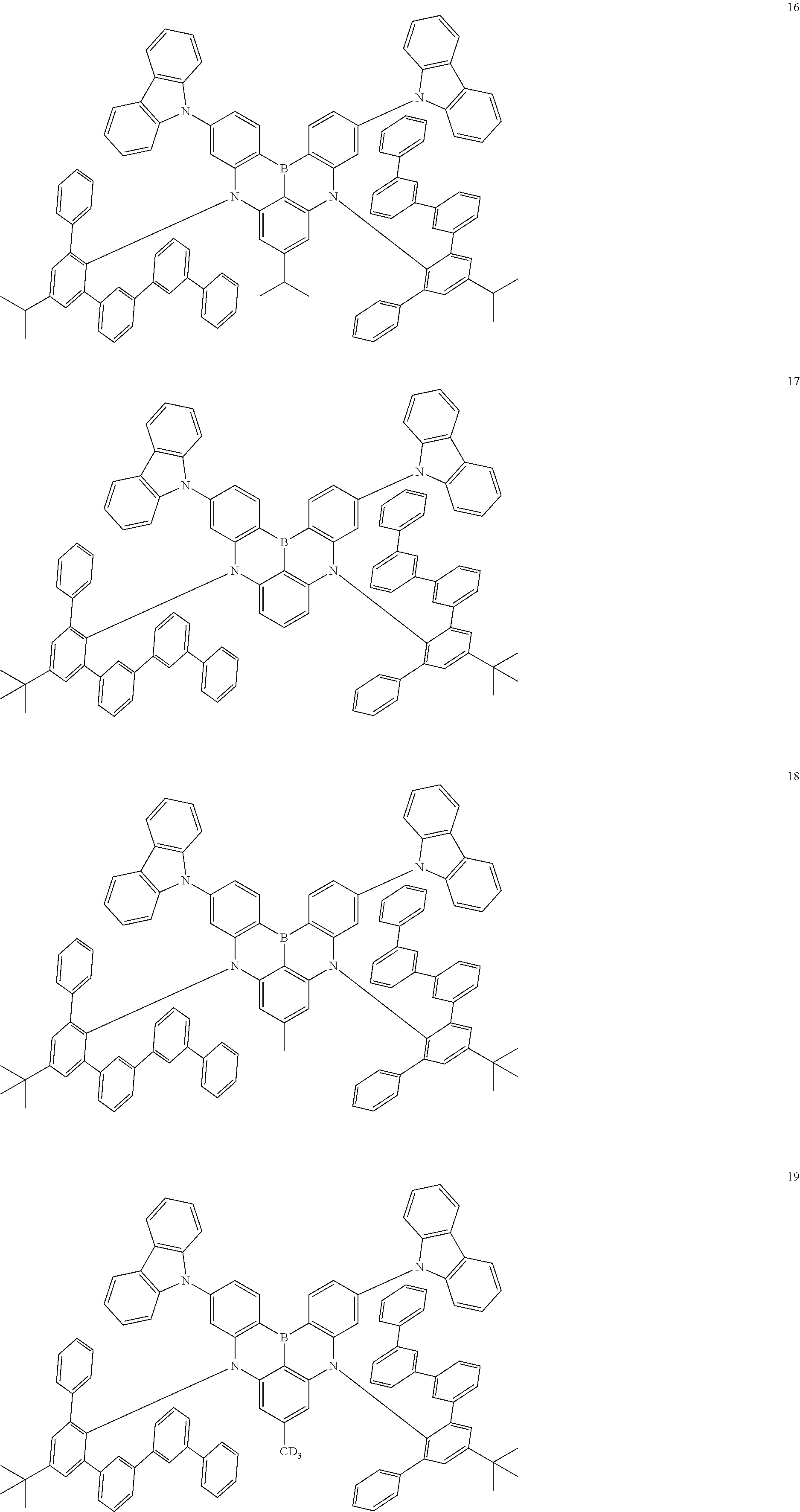 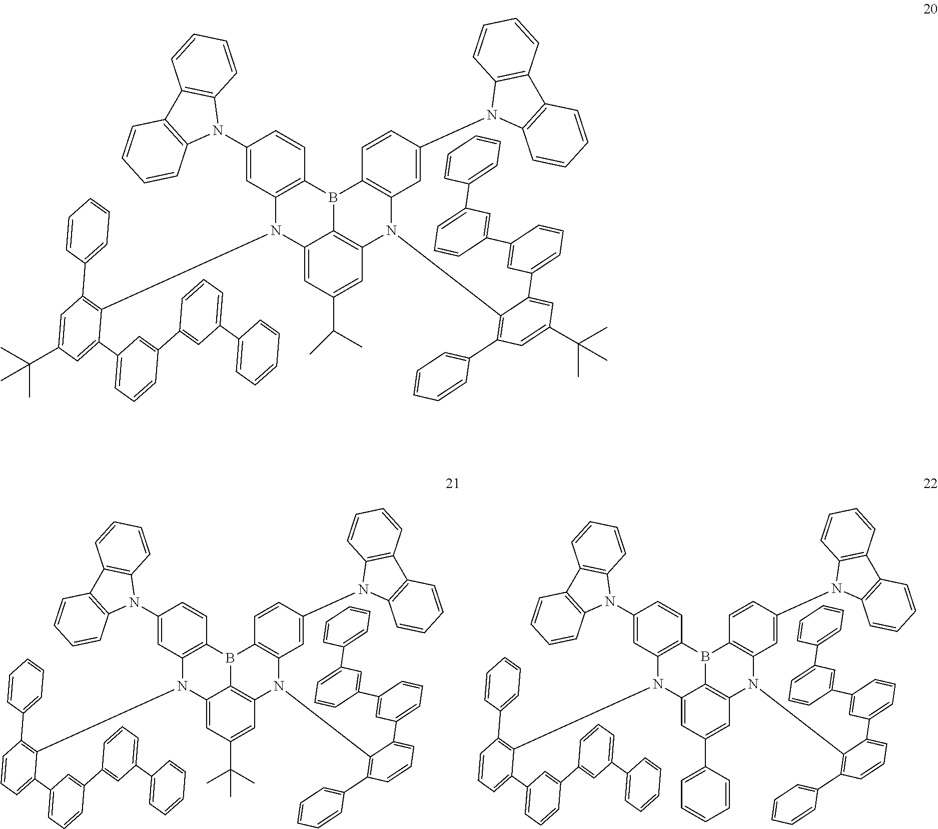 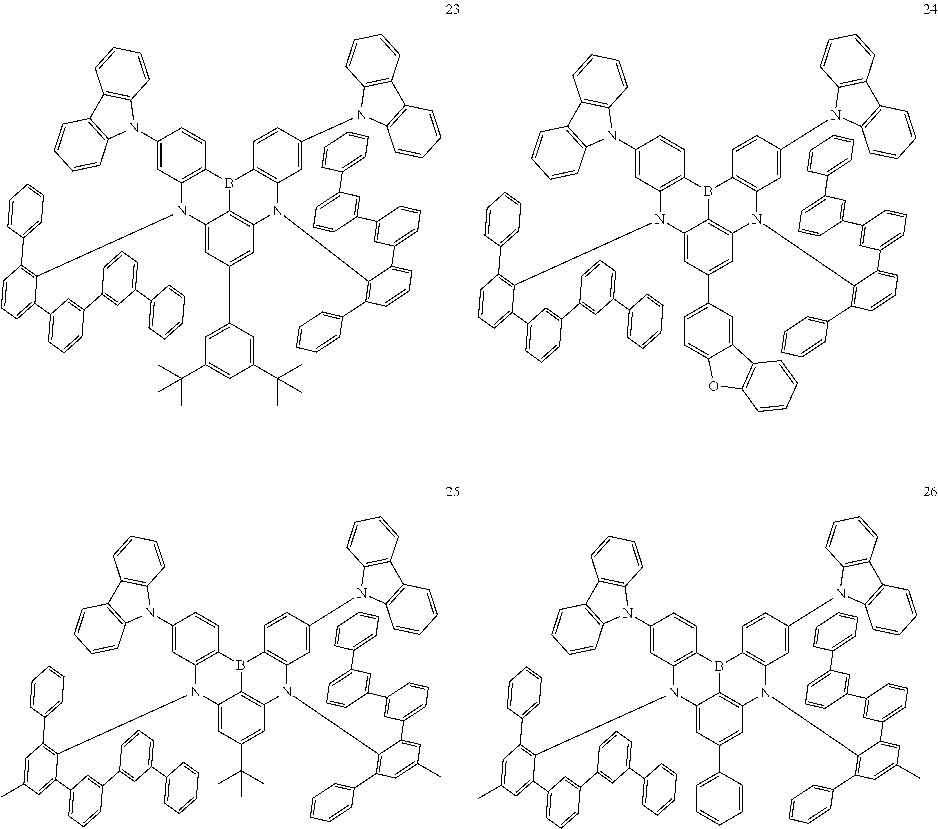 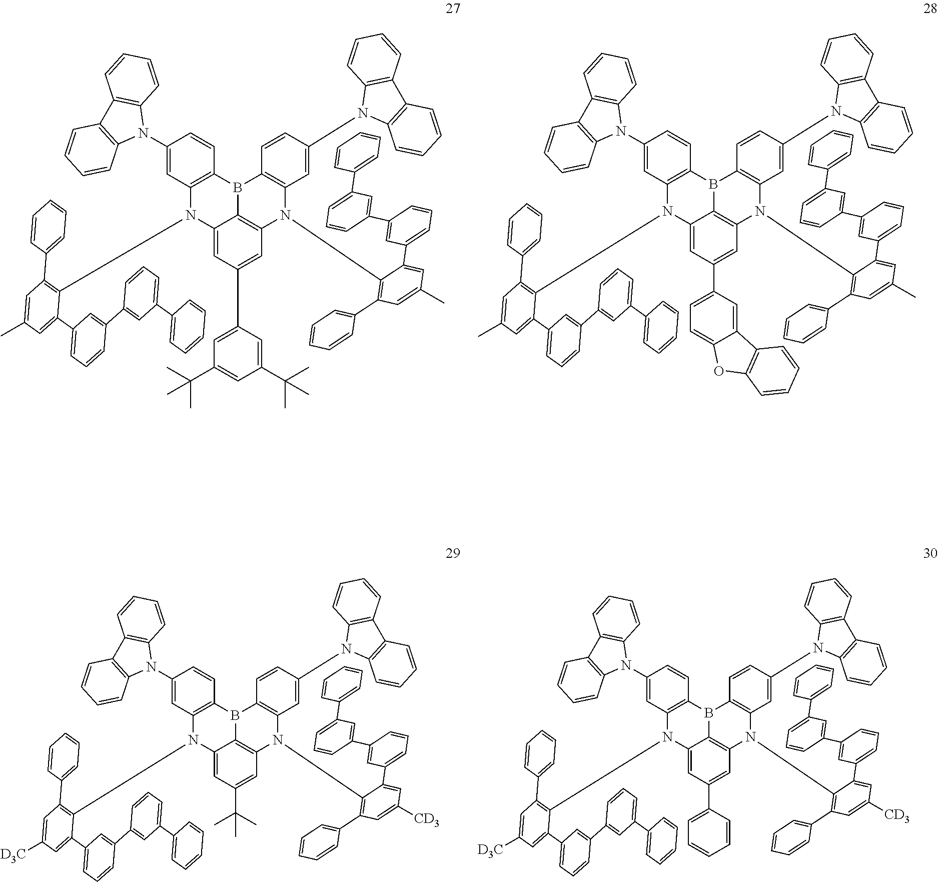 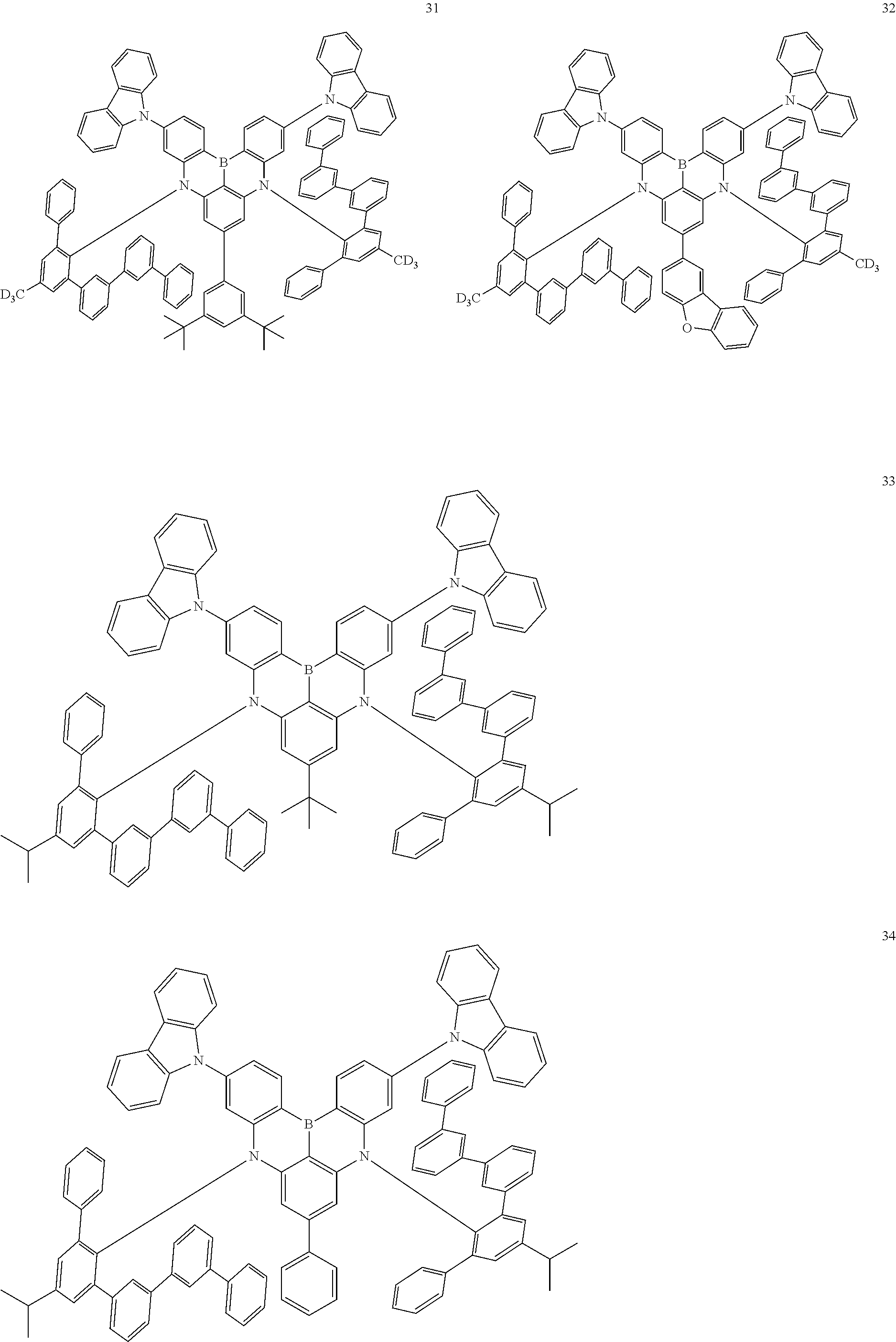 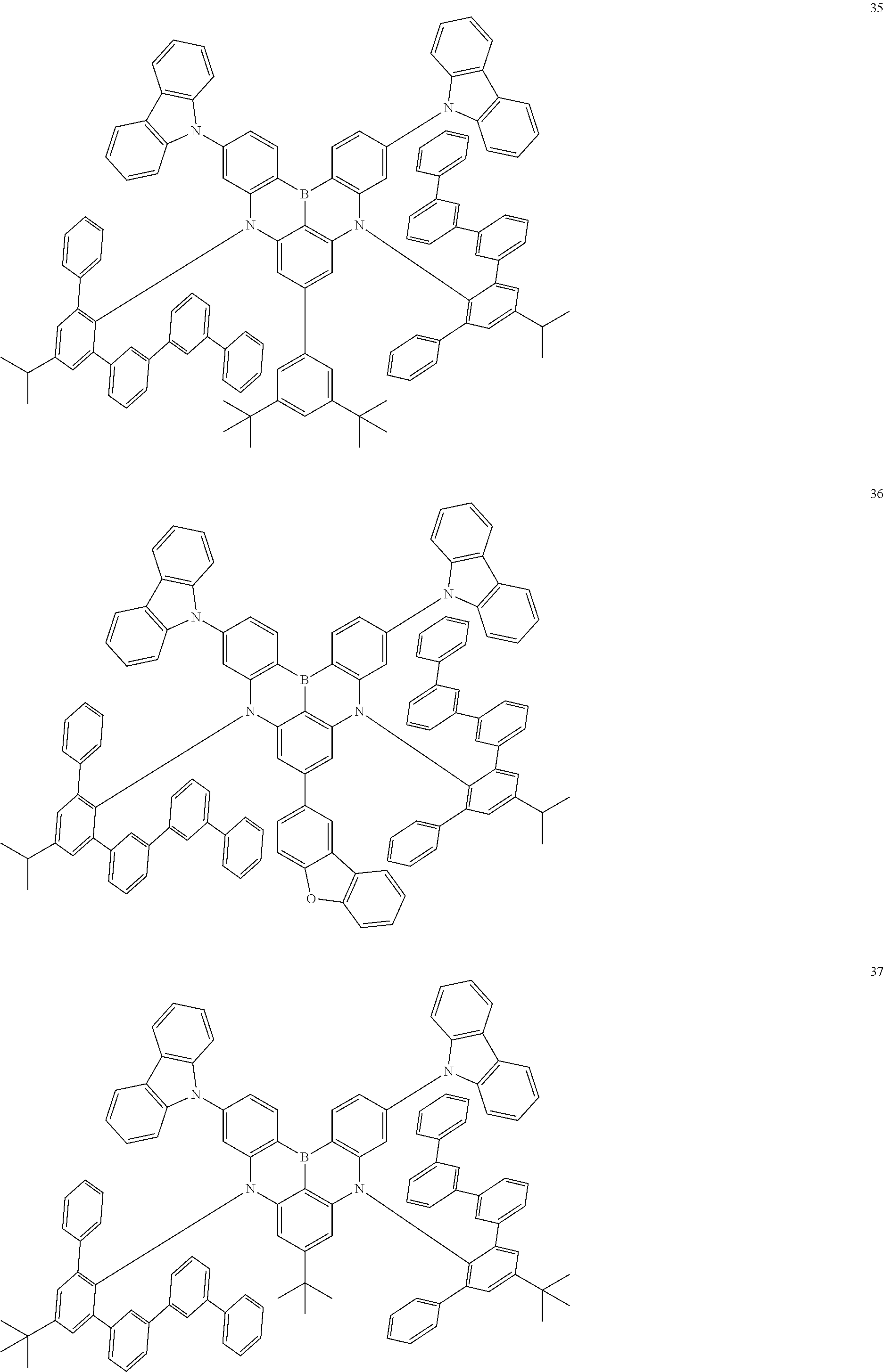 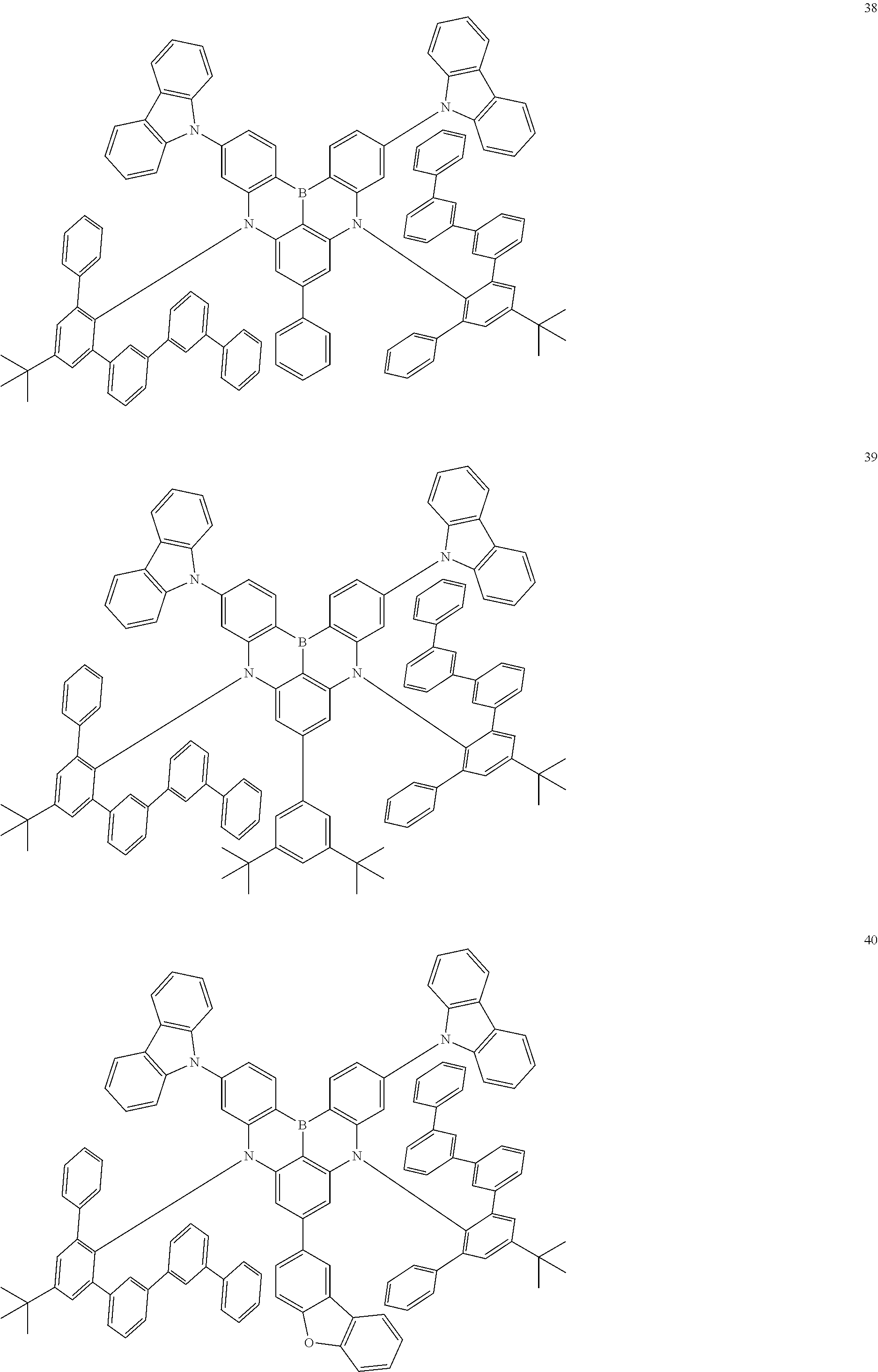 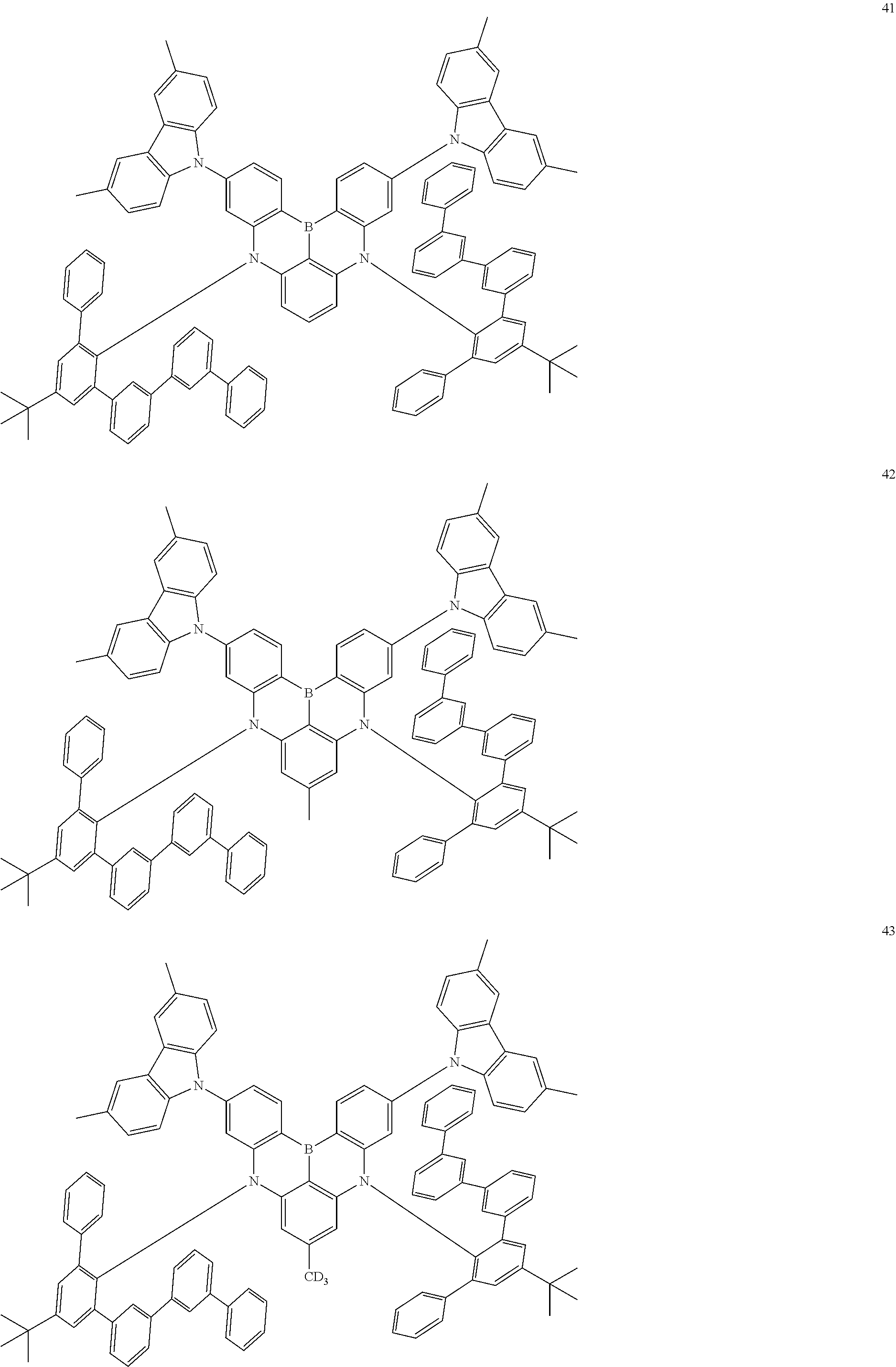 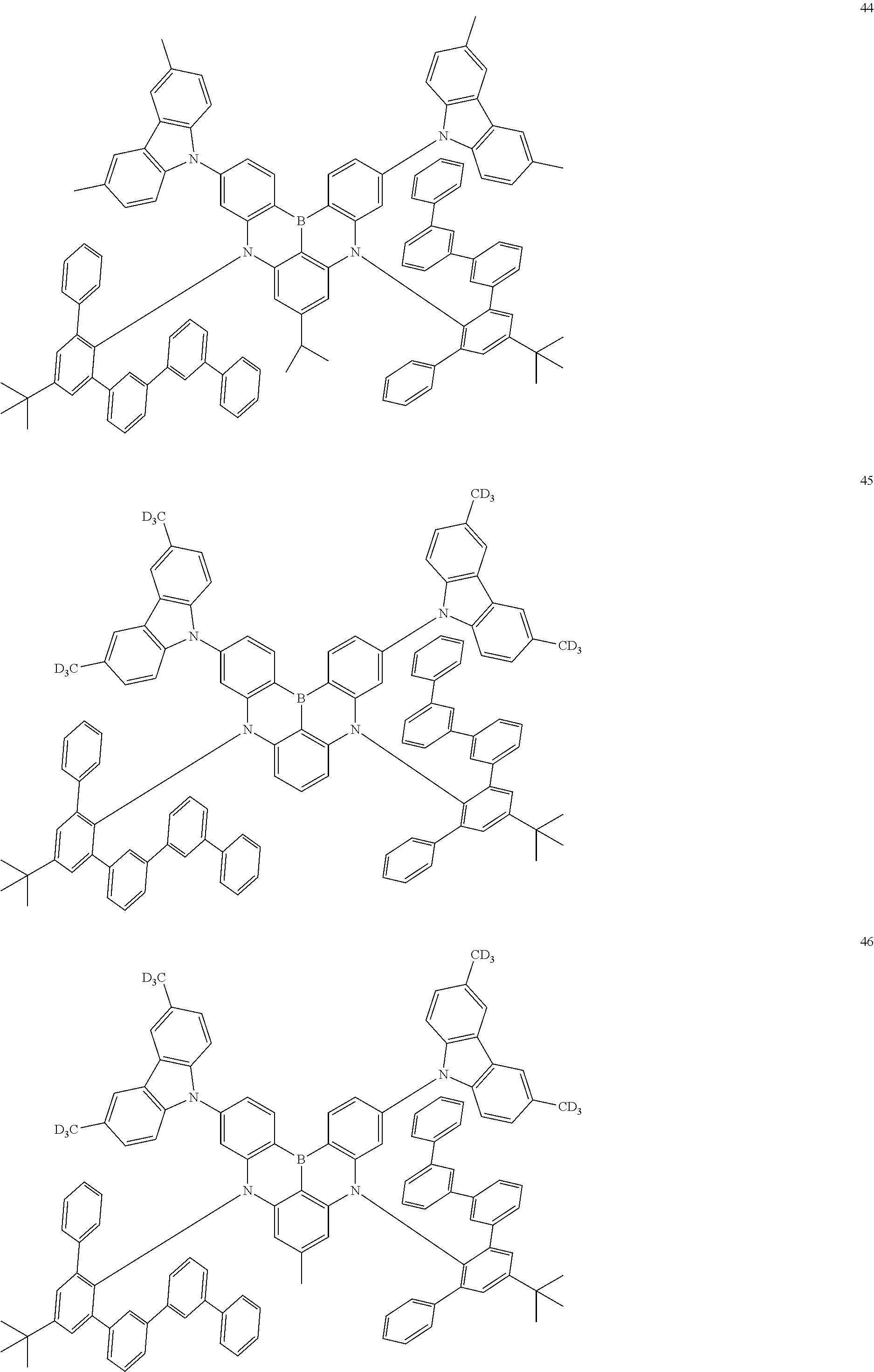 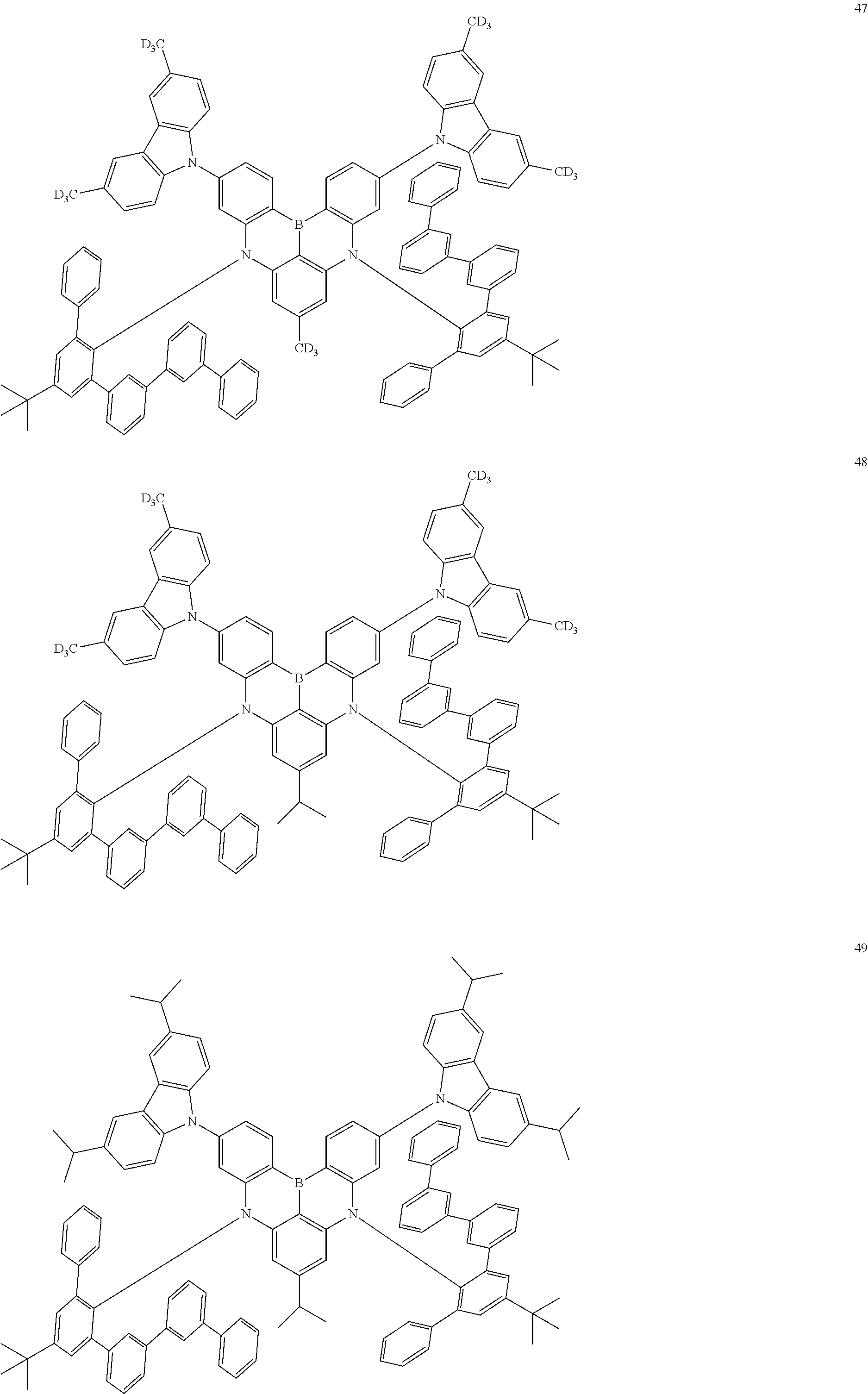 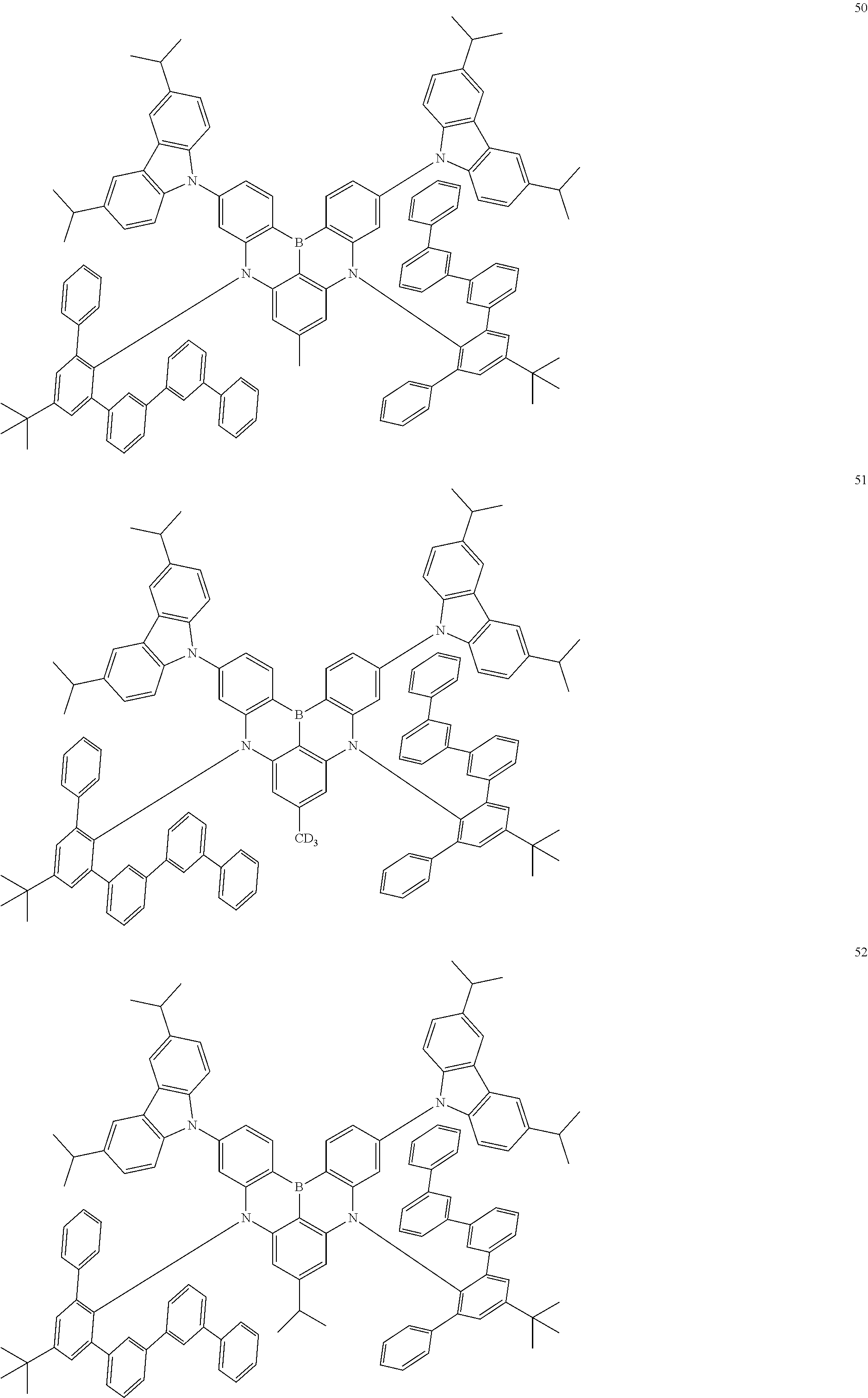 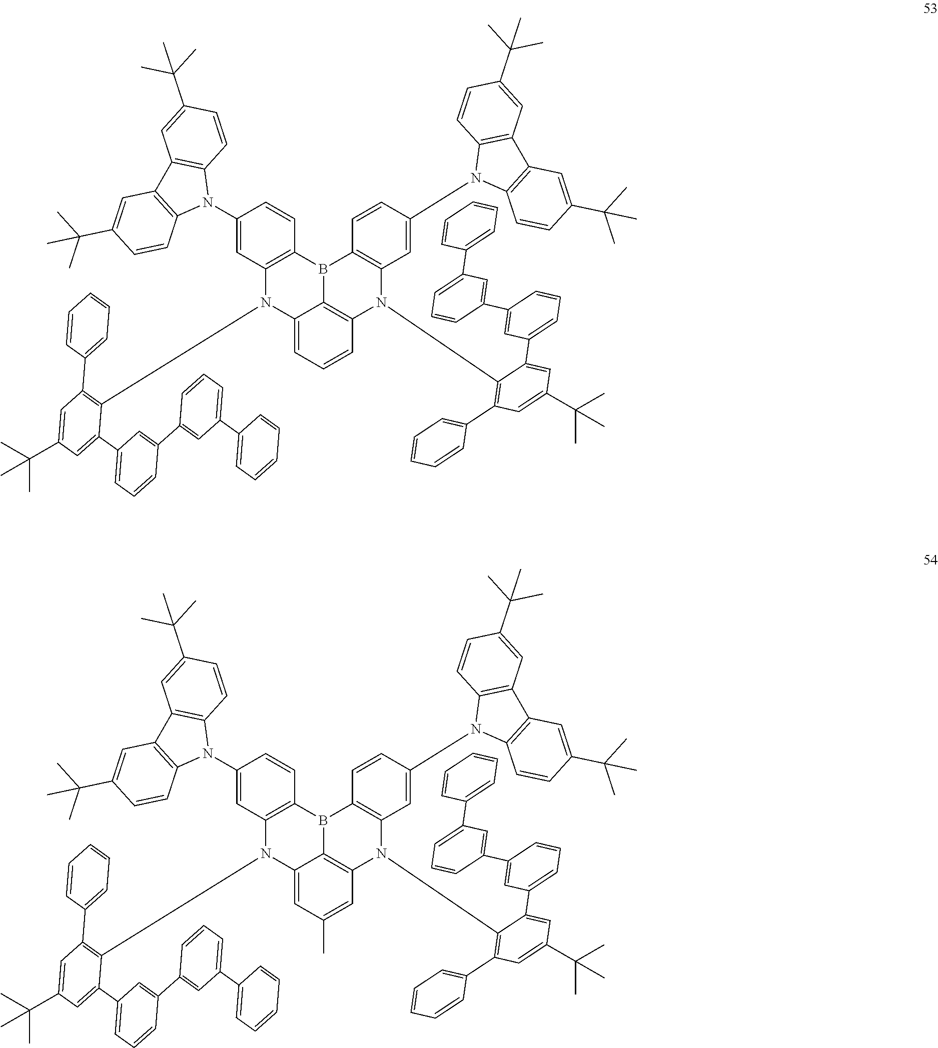 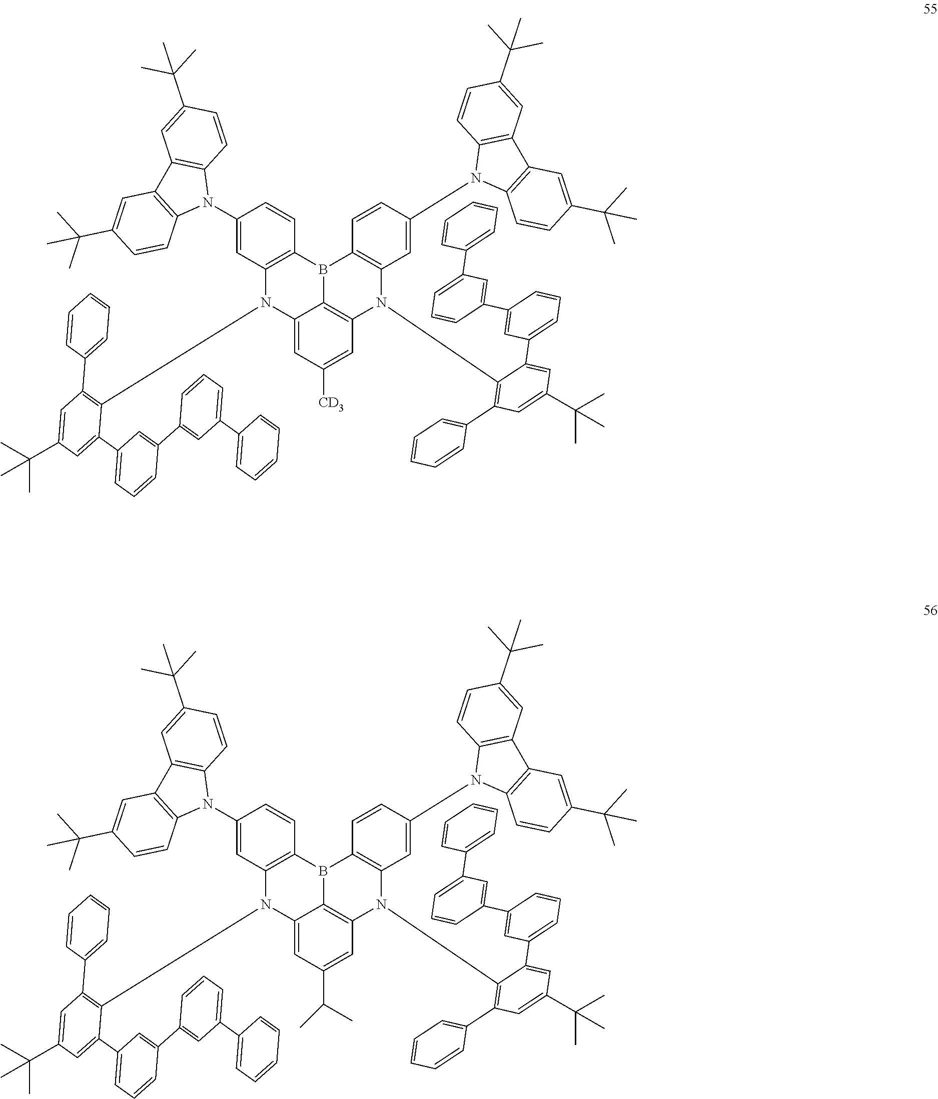 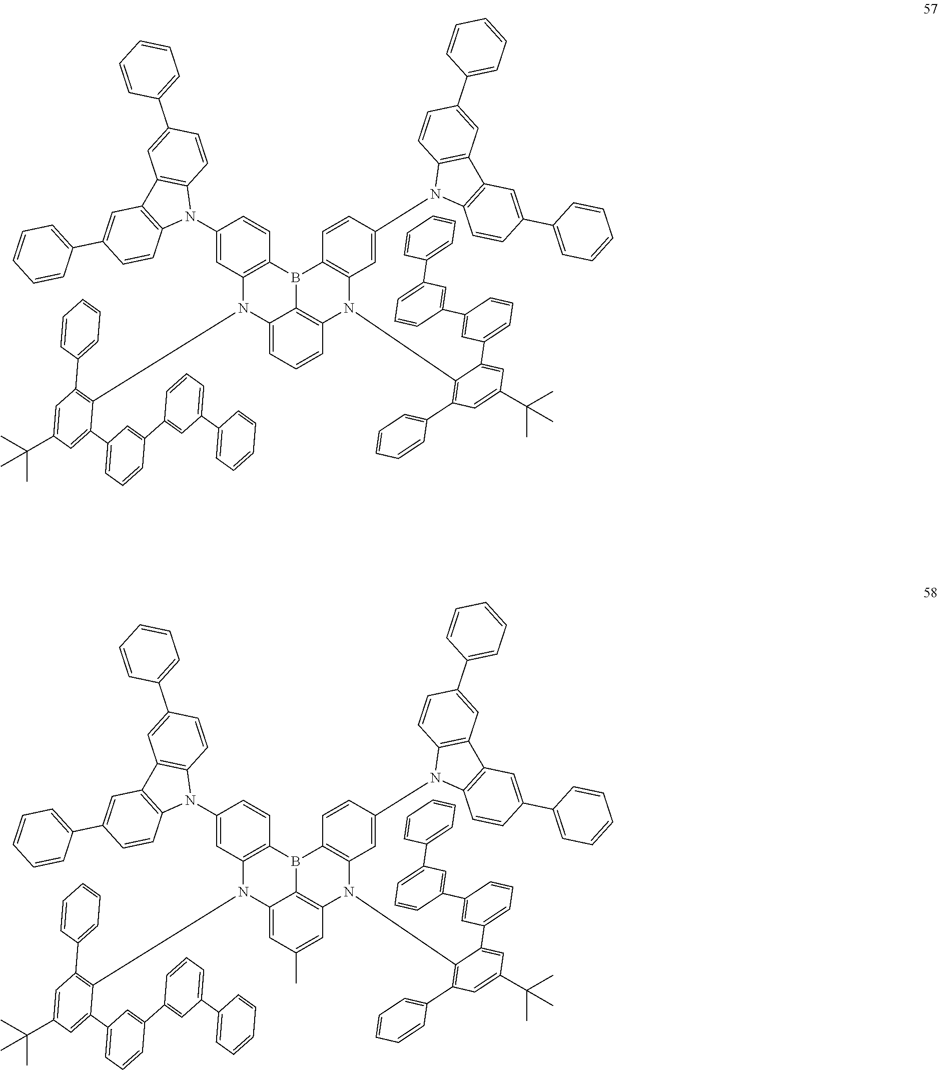 [SMILES: CC(C)(C)c1cc(-c2ccccc2)c(N2c3cc(-n4c5ccc(-c6ccccc6)cc5c5cc(-c6ccccc6)ccc54)ccc3B3c4ccc(-n5c6ccc(-c7ccccc7)cc6c6cc(-c7ccccc7)ccc65)cc4N(c4c(-c5ccccc5)cc(C(C)(C)C)cc4-c4cccc(-c5cccc(-c6ccccc6)c5)c4)c4cccc2c43)c(-c2cccc(-c3cccc(-c4ccccc4)c3)c2)c1 ; Cc1cc2c3c(c1)N(c1c(-c4ccccc4)cc(C(C)(C)C)cc1-c1cccc(-c4cccc(-c5ccccc5)c4)c1)c1cc(-n4c5ccc(-c6ccccc6)cc5c5cc(-c6ccccc6)ccc54)ccc1B3c1ccc(-n3c4ccc(-c5ccccc5)cc4c4cc(-c5ccccc5)ccc43)cc1N2c1c(-c2ccccc2)cc(C(C)(C)C)cc1-c1cccc(-c2cccc(-c3ccccc3)c2)c1] 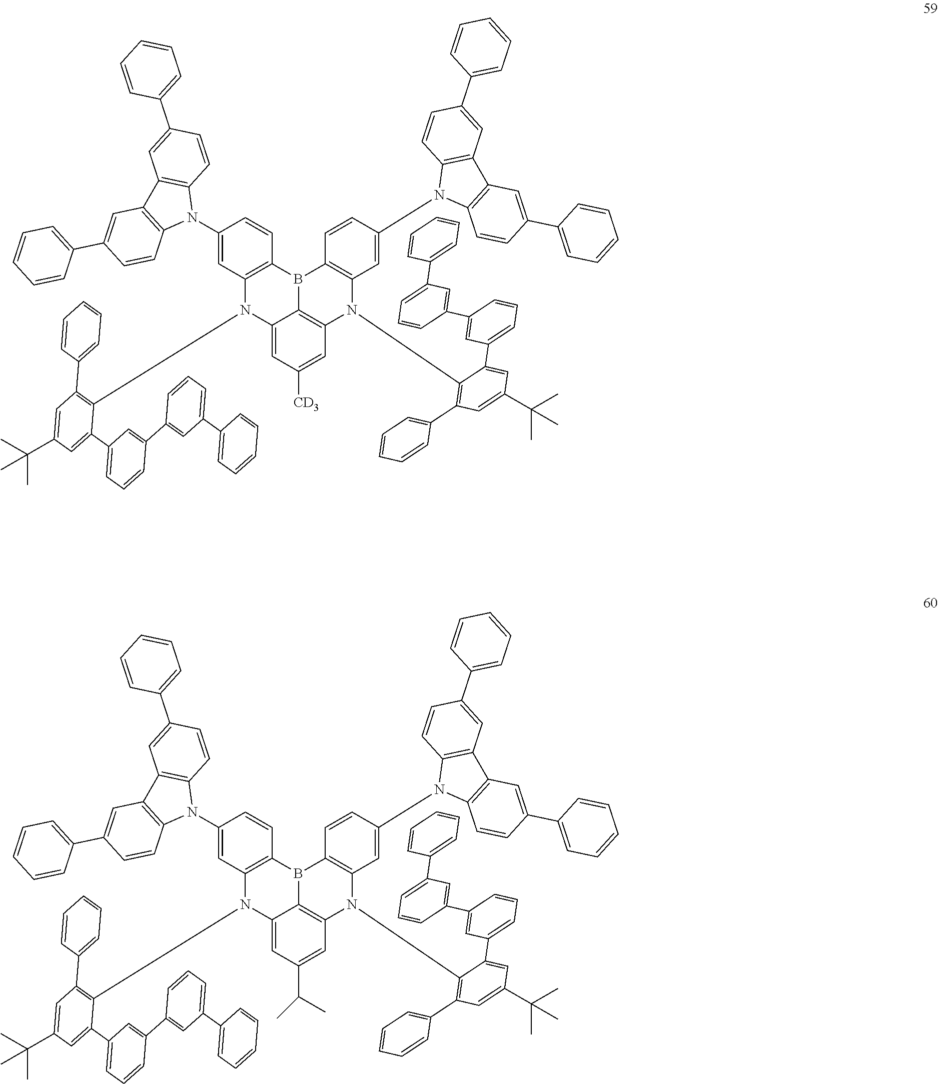 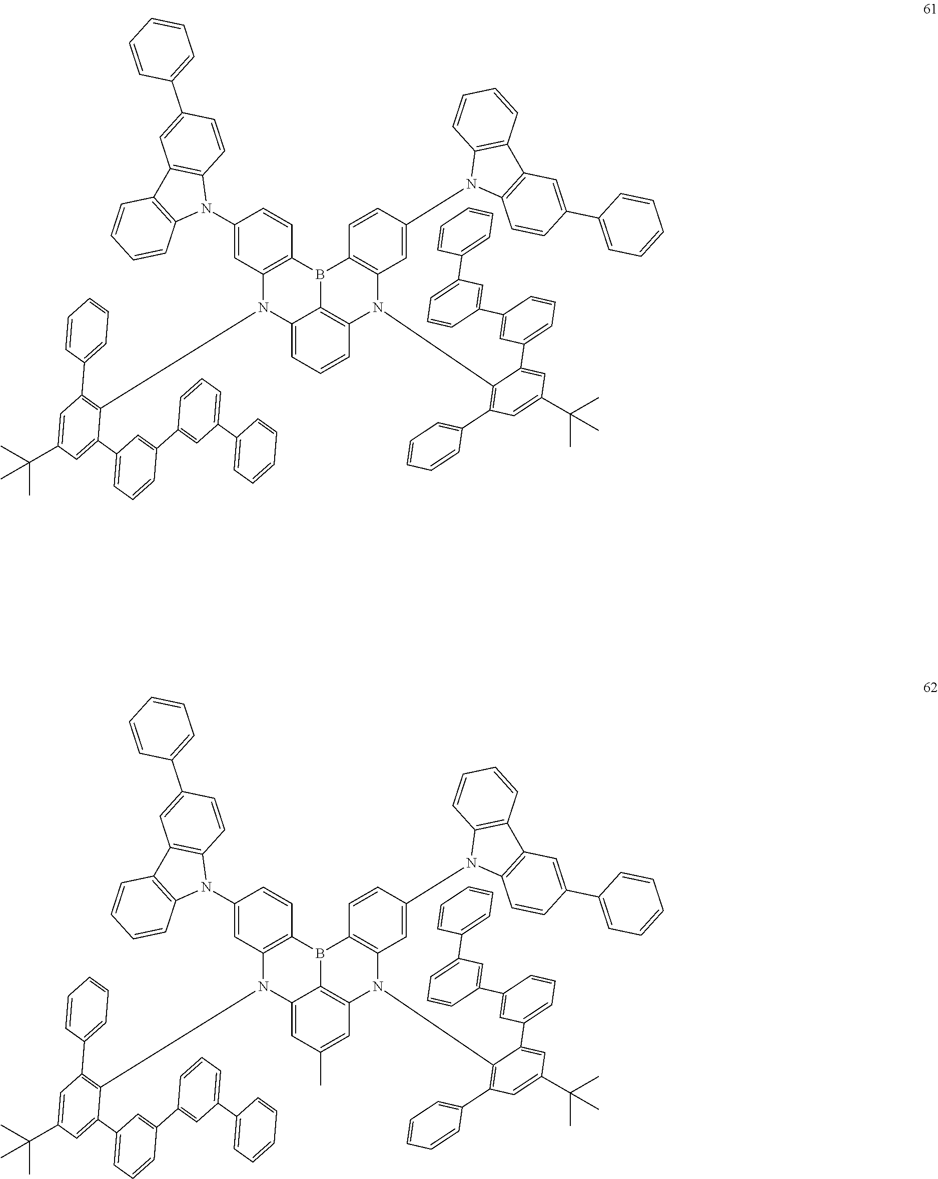 [SMILES: CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccccc5)cc(C(C)(C)C)cc4-c4cccc(-c5cccc(-c6ccccc6)c5)c4)c4cccc2c43)c(-c2cccc(-c3cccc(-c4ccccc4)c3)c2)c1 ; Cc1cc2c3c(c1)N(c1c(-c4ccccc4)cc(C(C)(C)C)cc1-c1cccc(-c4cccc(-c5ccccc5)c4)c1)c1cc(-n4c5ccccc5c5cc(-c6ccccc6)ccc54)ccc1B3c1ccc(-n3c4ccccc4c4cc(-c5ccccc5)ccc43)cc1N2c1c(-c2ccccc2)cc(C(C)(C)C)cc1-c1cccc(-c2cccc(-c3ccccc3)c2)c1] 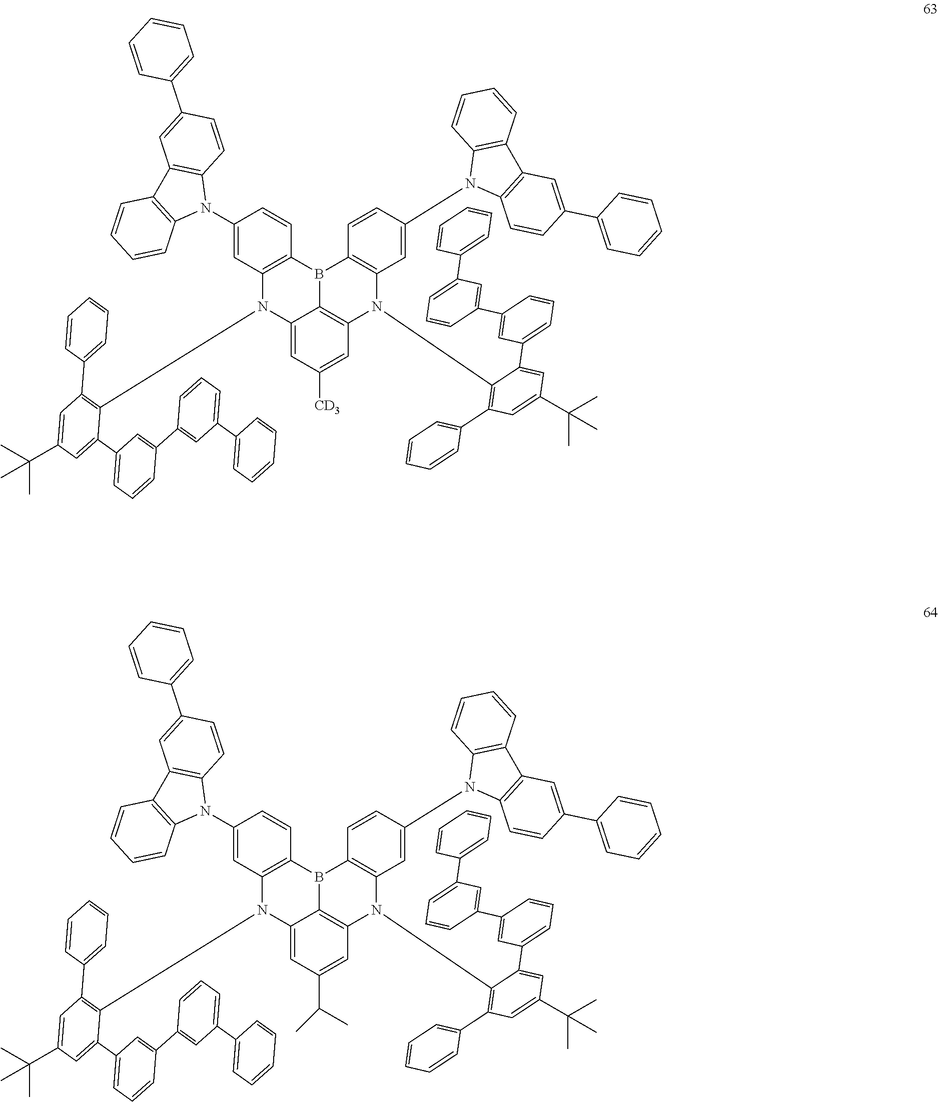 [SMILES: [2H]C([2H])([2H])c1cc2c3c(c1)N(c1c(-c4ccccc4)cc(C(C)(C)C)cc1-c1cccc(-c4cccc(-c5ccccc5)c4)c1)c1cc(-n4c5ccccc5c5cc(-c6ccccc6)ccc54)ccc1B3c1ccc(-n3c4ccccc4c4cc(-c5ccccc5)ccc43)cc1N2c1c(-c2ccccc2)cc(C(C)(C)C)cc1-c1cccc(-c2cccc(-c3ccccc3)c2)c1 ; CC(C)c1cc2c3c(c1)N(c1c(-c4ccccc4)cc(C(C)(C)C)cc1-c1cccc(-c4cccc(-c5ccccc5)c4)c1)c1cc(-n4c5ccccc5c5cc(-c6ccccc6)ccc54)ccc1B3c1ccc(-n3c4ccccc4c4cc(-c5ccccc5)ccc43)cc1N2c1c(-c2ccccc2)cc(C(C)(C)C)cc1-c1cccc(-c2cccc(-c3ccccc3)c2)c1] 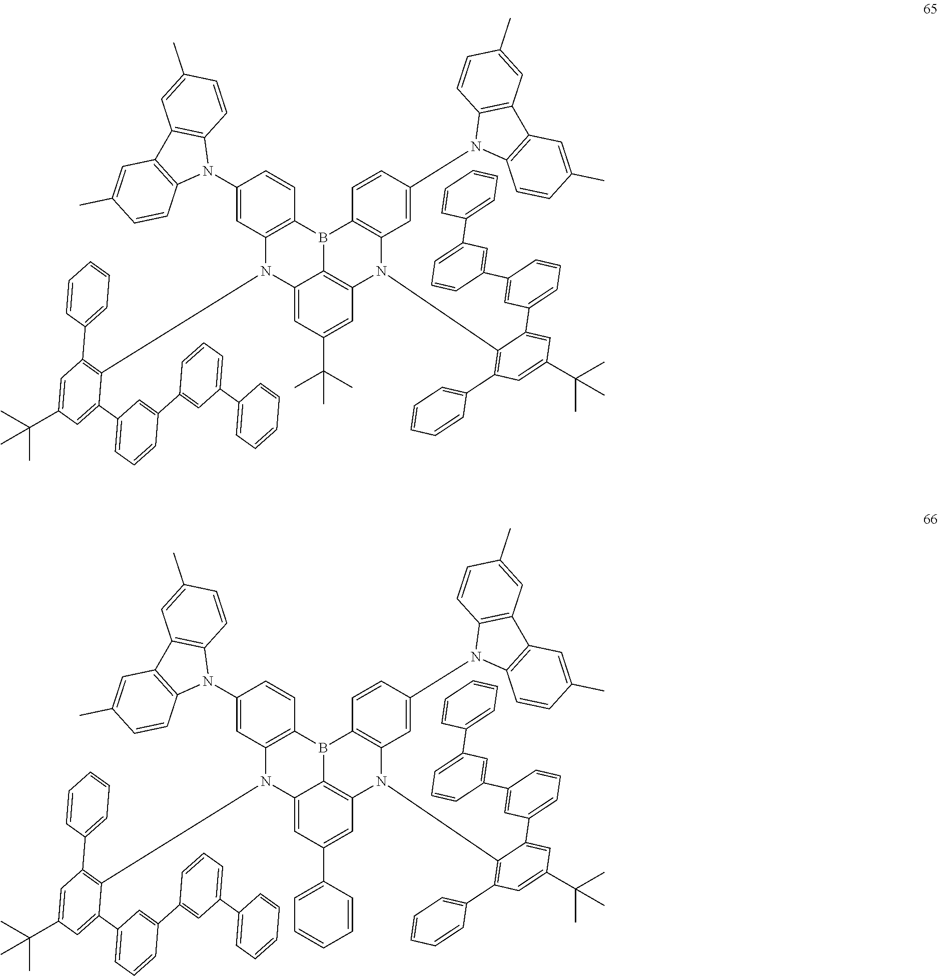 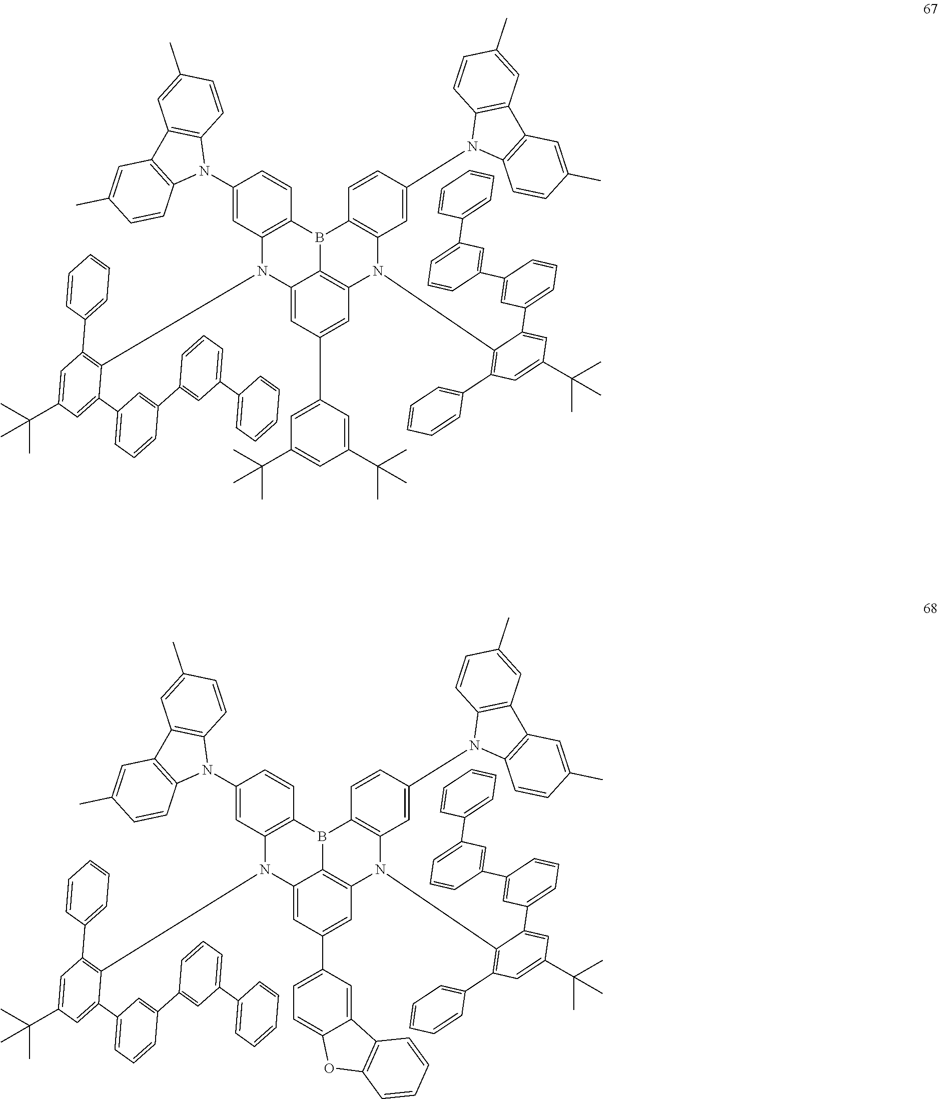 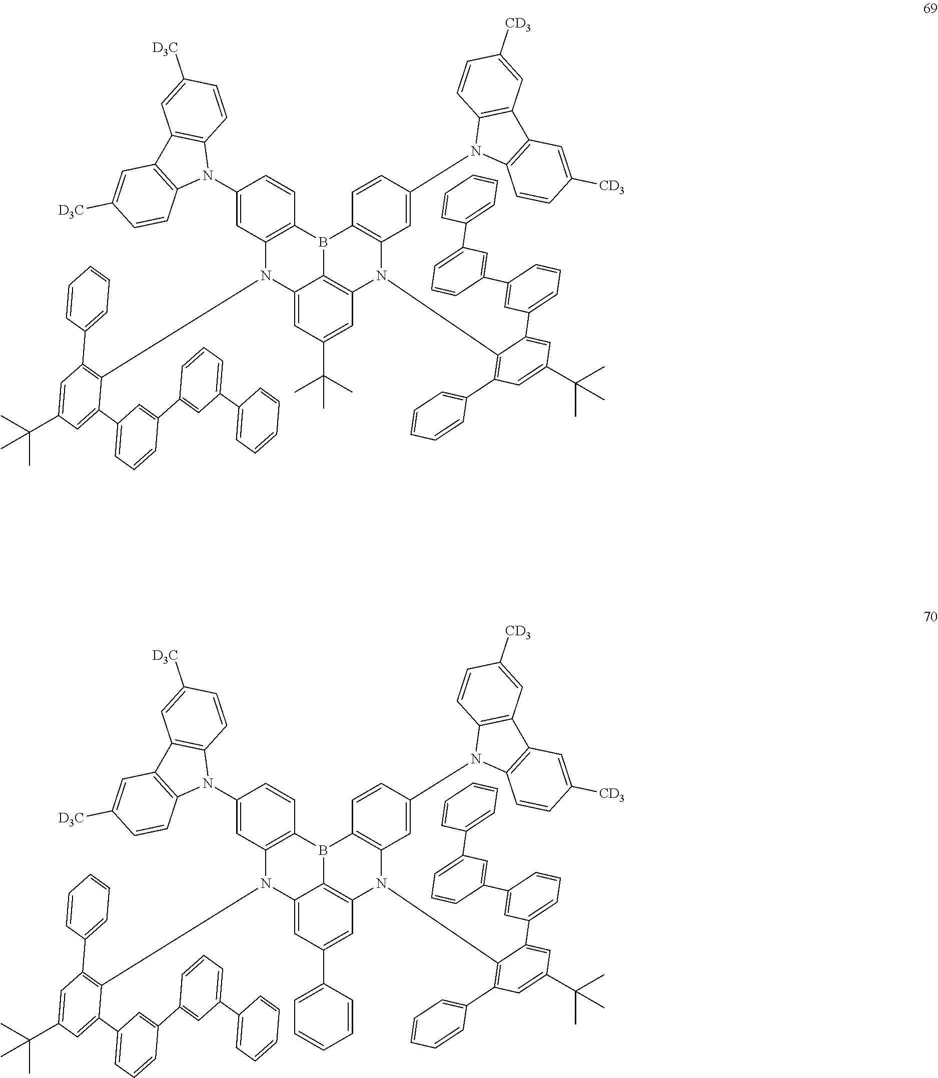 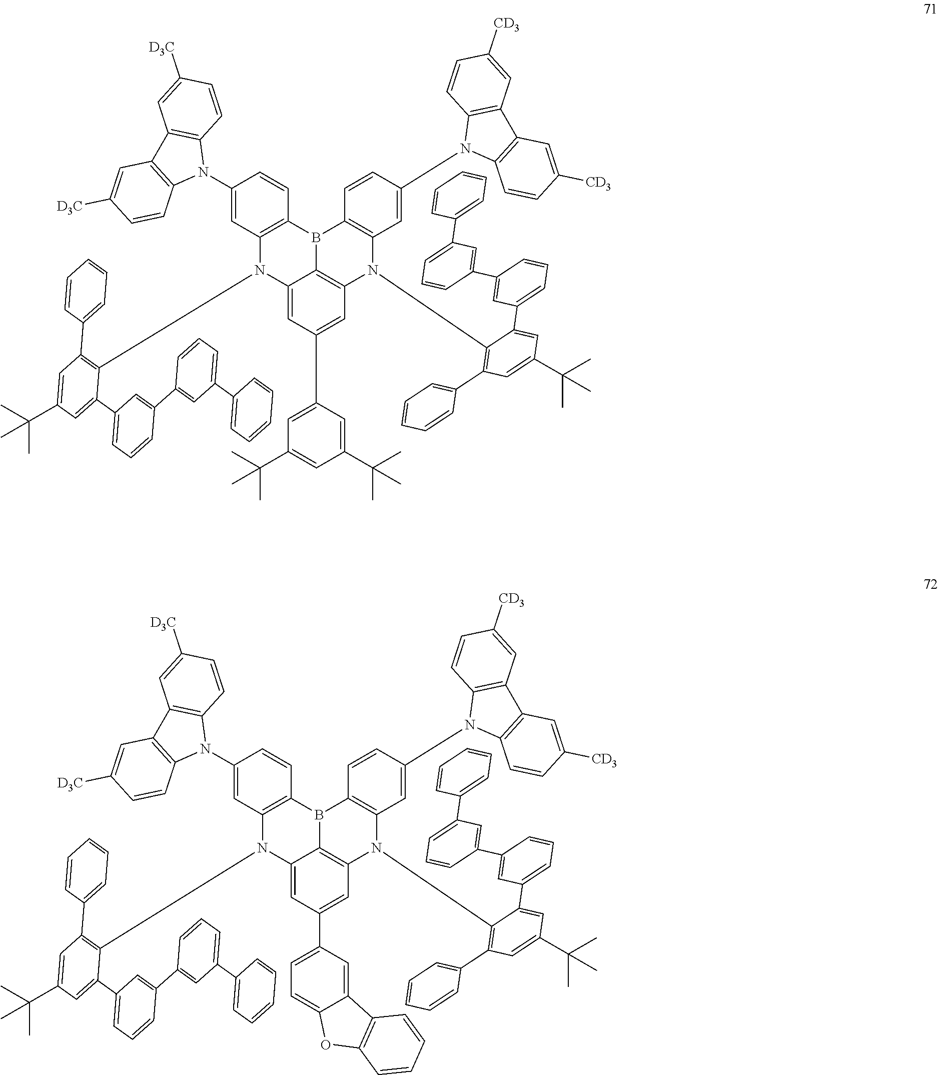 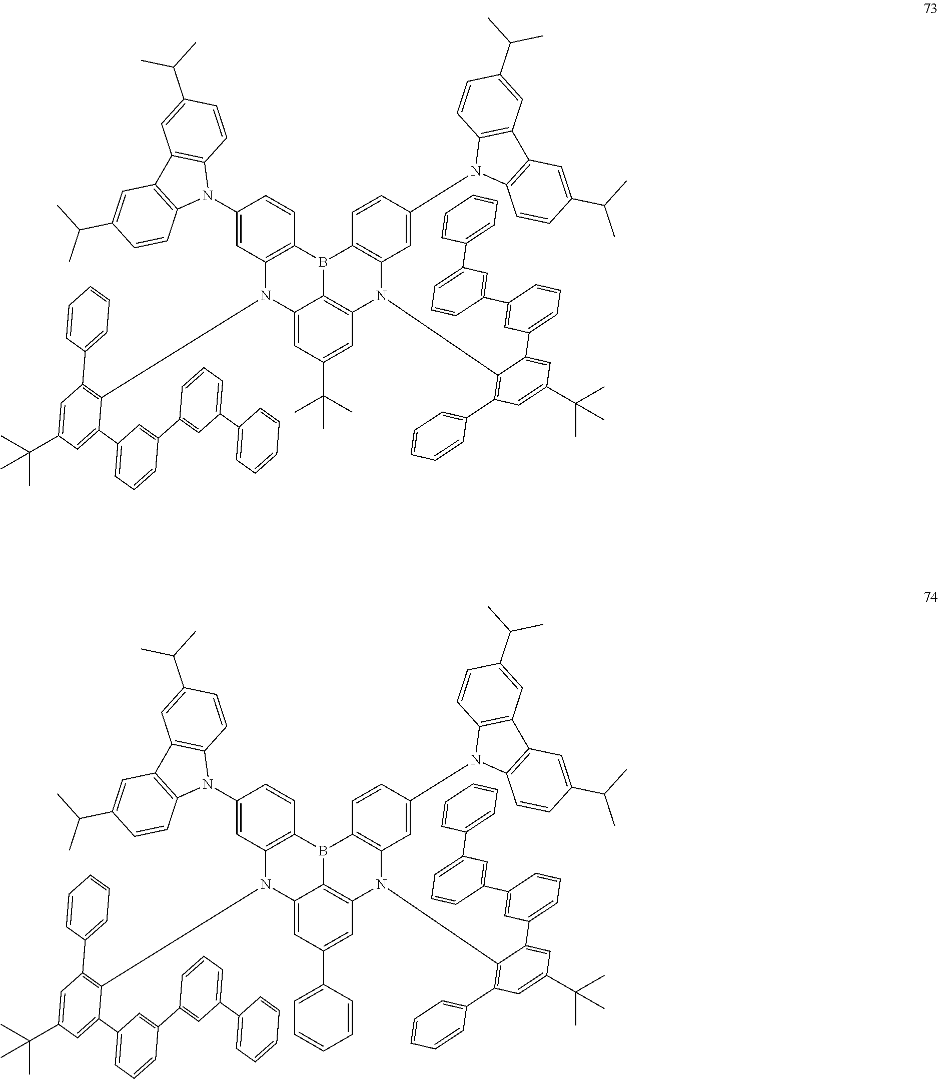 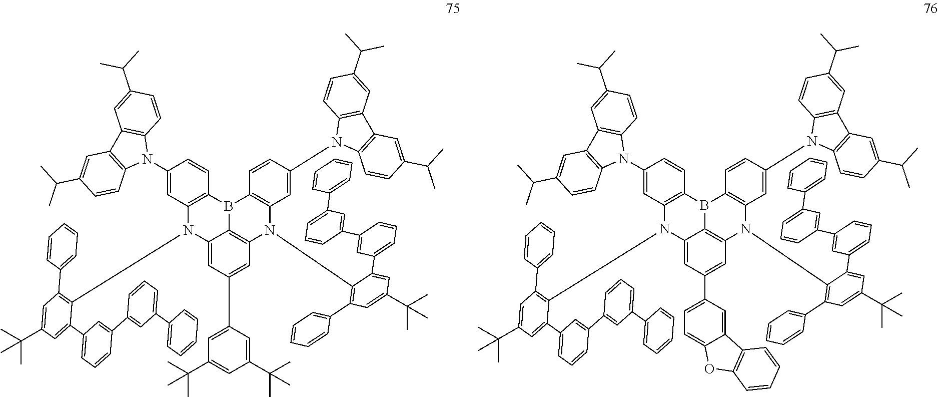 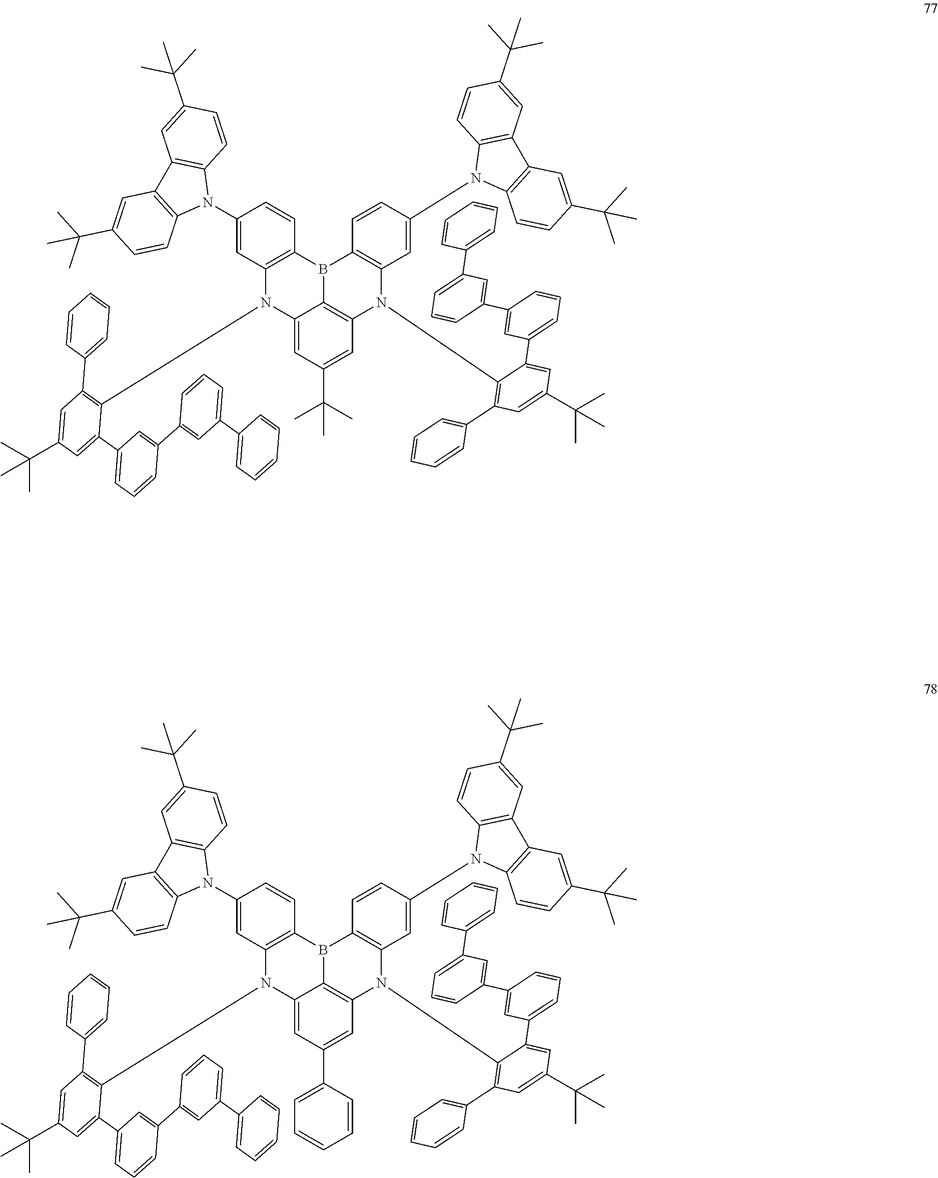 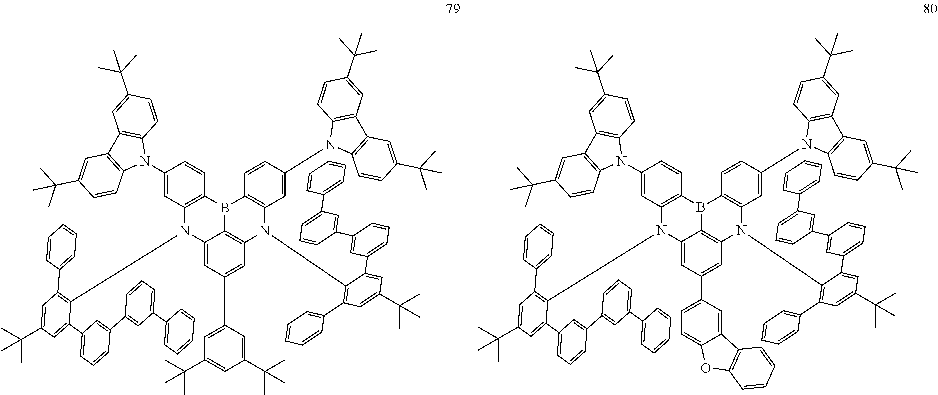 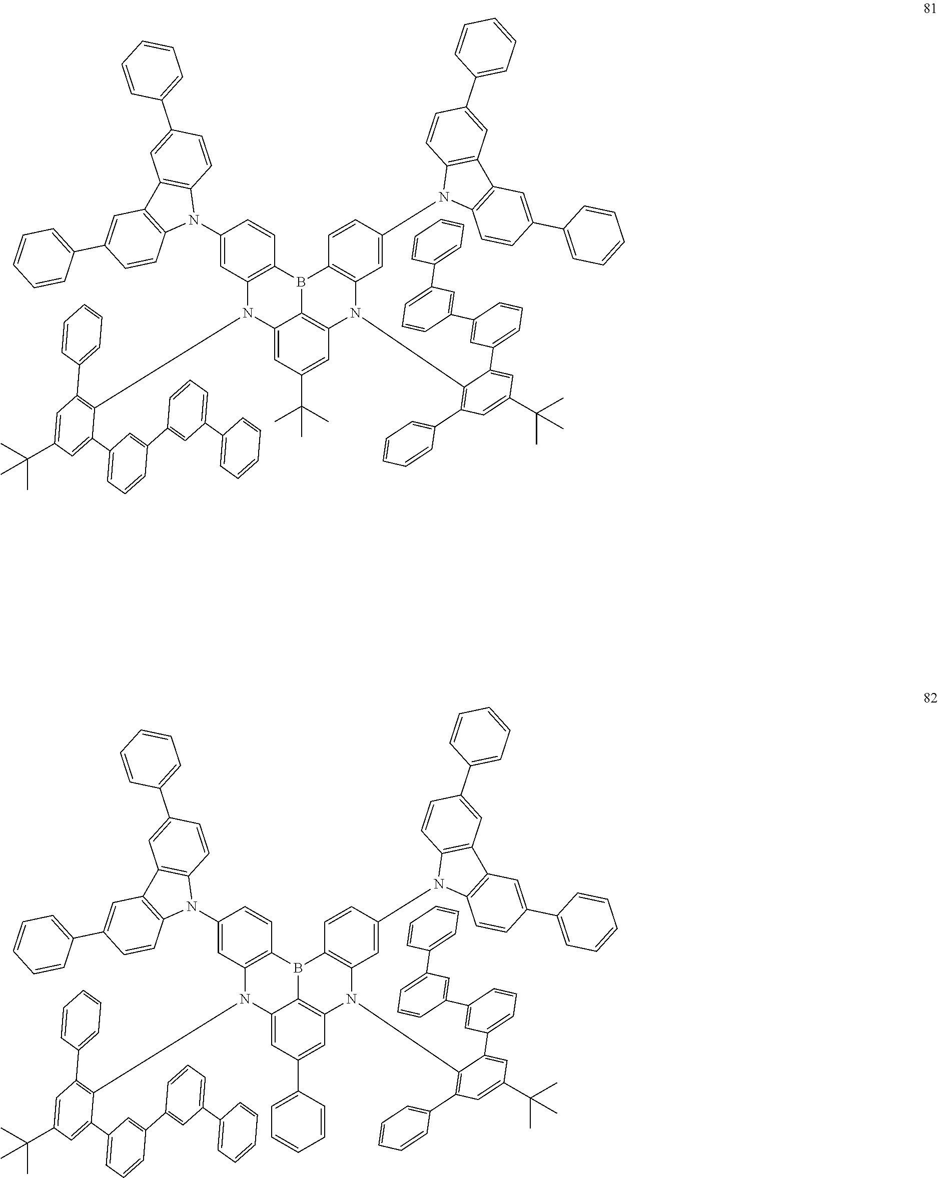 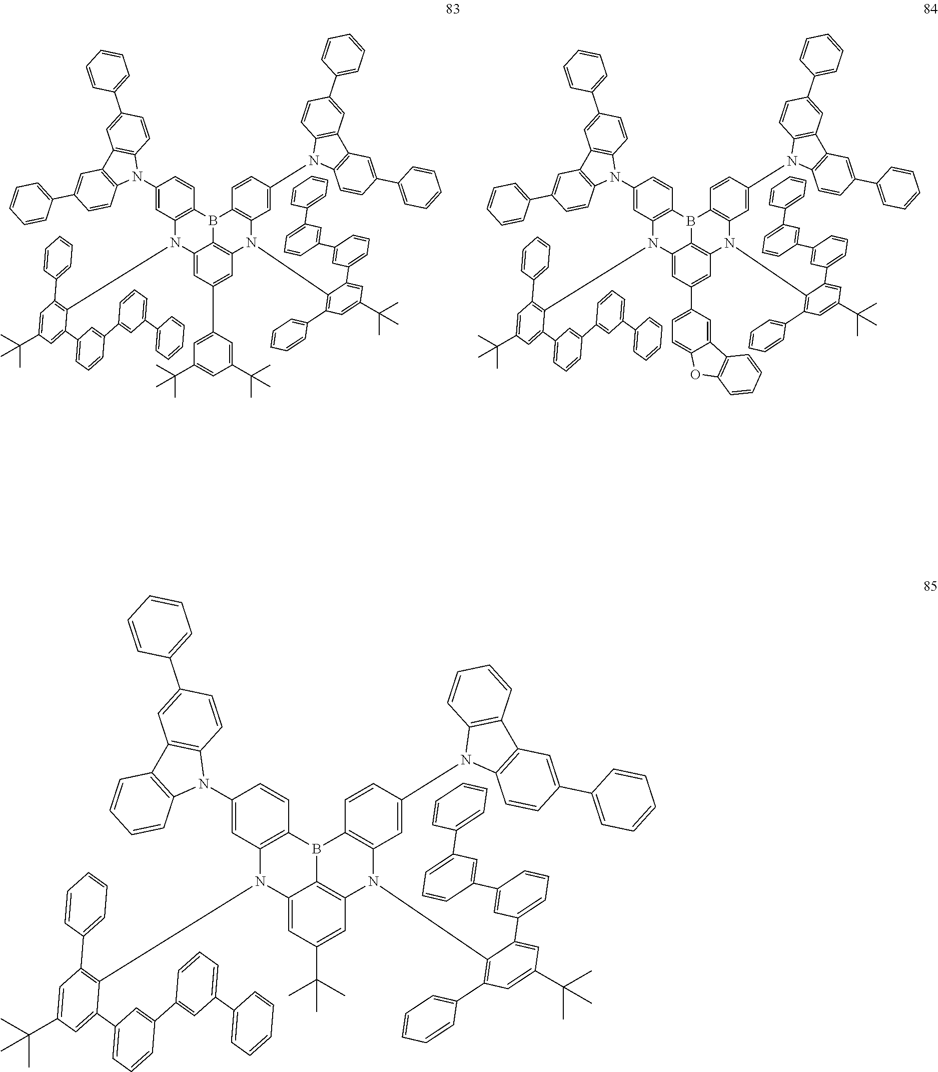 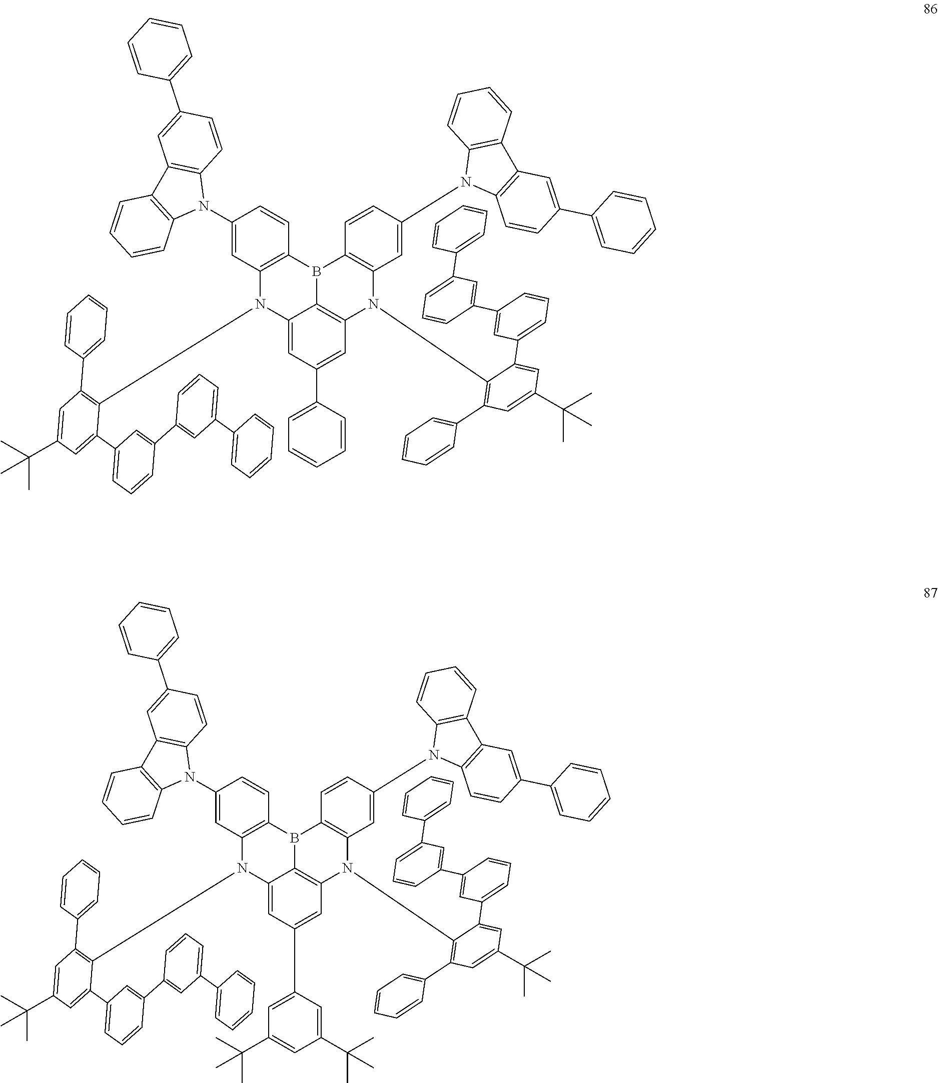 [SMILES: CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccccc5)cc(C(C)(C)C)cc4-c4cccc(-c5cccc(-c6ccccc6)c5)c4)c4cc(-c5ccccc5)cc2c43)c(-c2cccc(-c3cccc(-c4ccccc4)c3)c2)c1 ; CC(C)(C)c1cc(-c2cc3c4c(c2)N(c2c(-c5ccccc5)cc(C(C)(C)C)cc2-c2cccc(-c5cccc(-c6ccccc6)c5)c2)c2cc(-n5c6ccccc6c6cc(-c7ccccc7)ccc65)ccc2B4c2ccc(-n4c5ccccc5c5cc(-c6ccccc6)ccc54)cc2N3c2c(-c3ccccc3)cc(C(C)(C)C)cc2-c2cccc(-c3cccc(-c4ccccc4)c3)c2)cc(C(C)(C)C)c1] 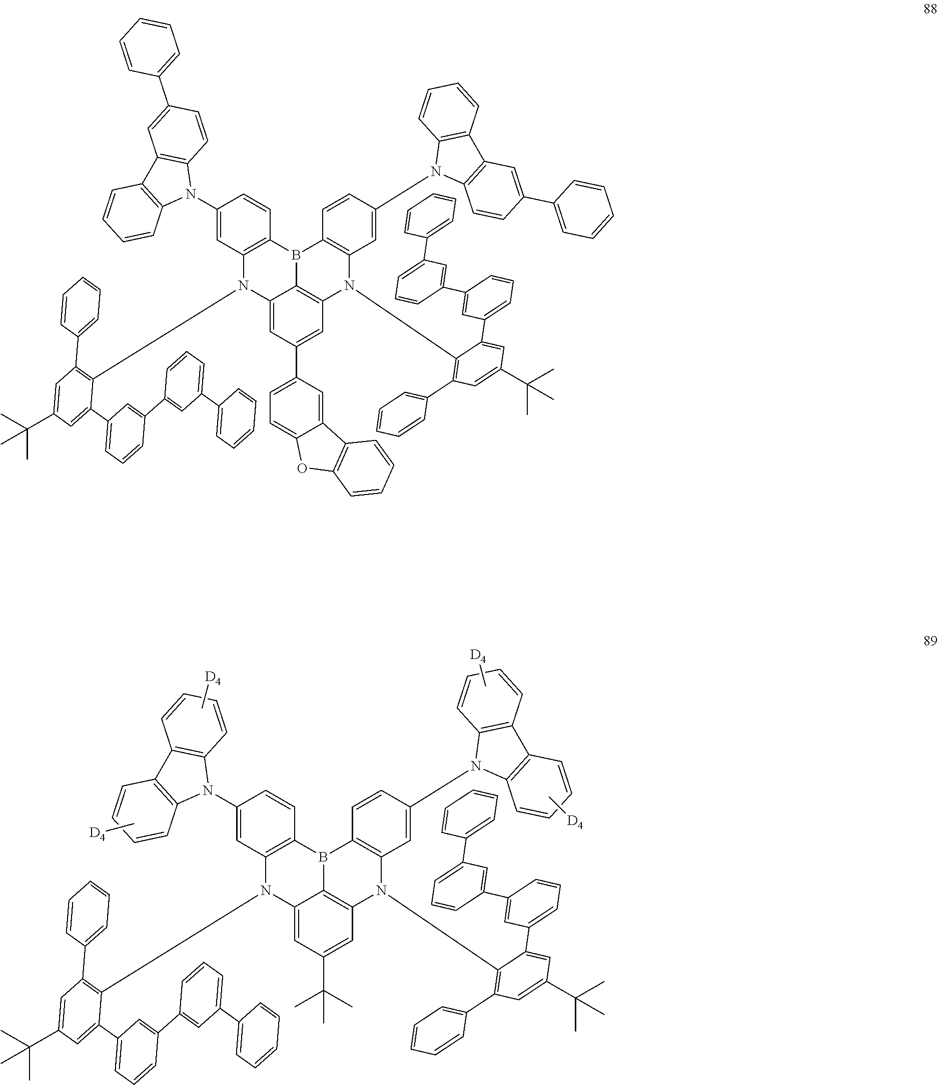 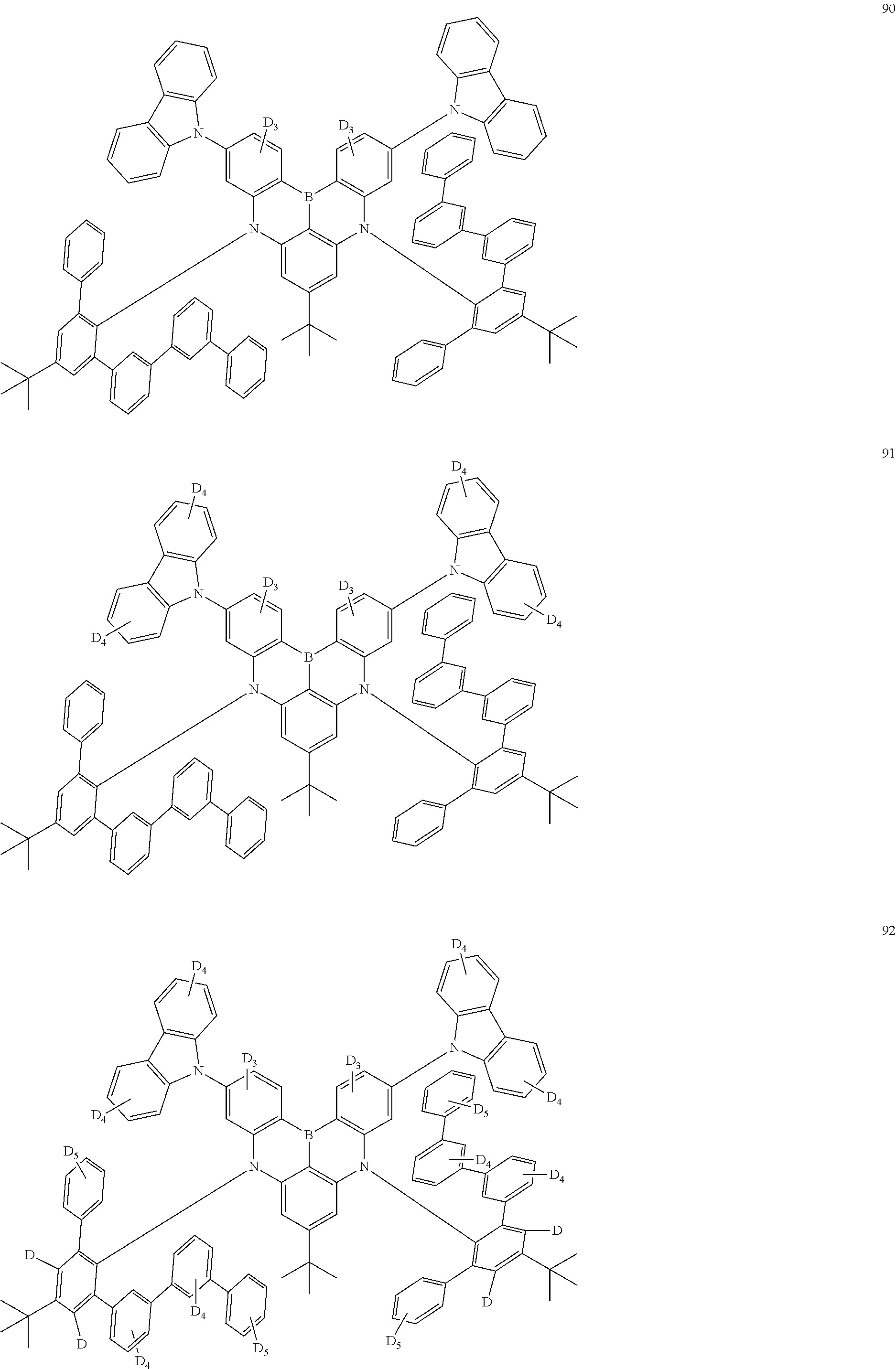 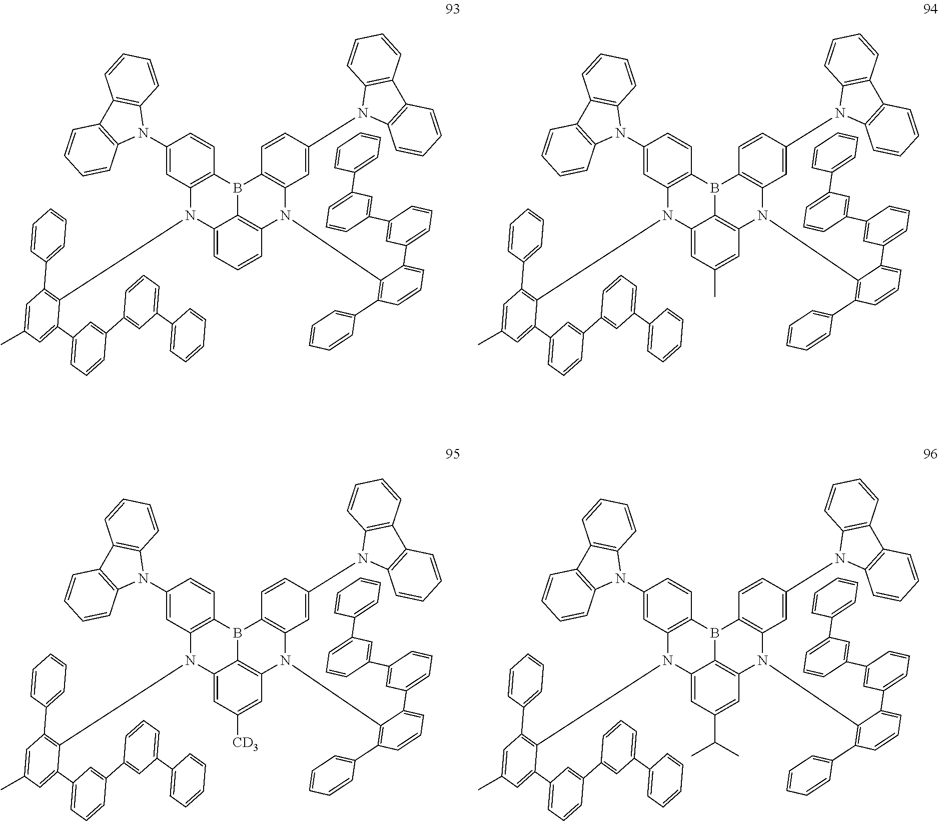 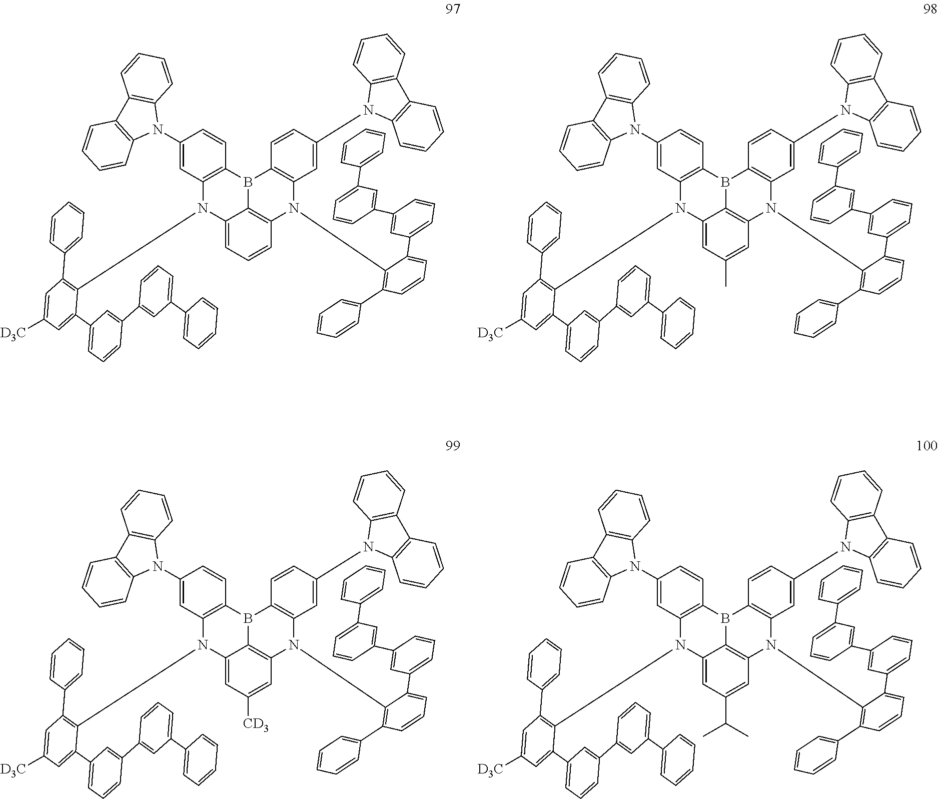 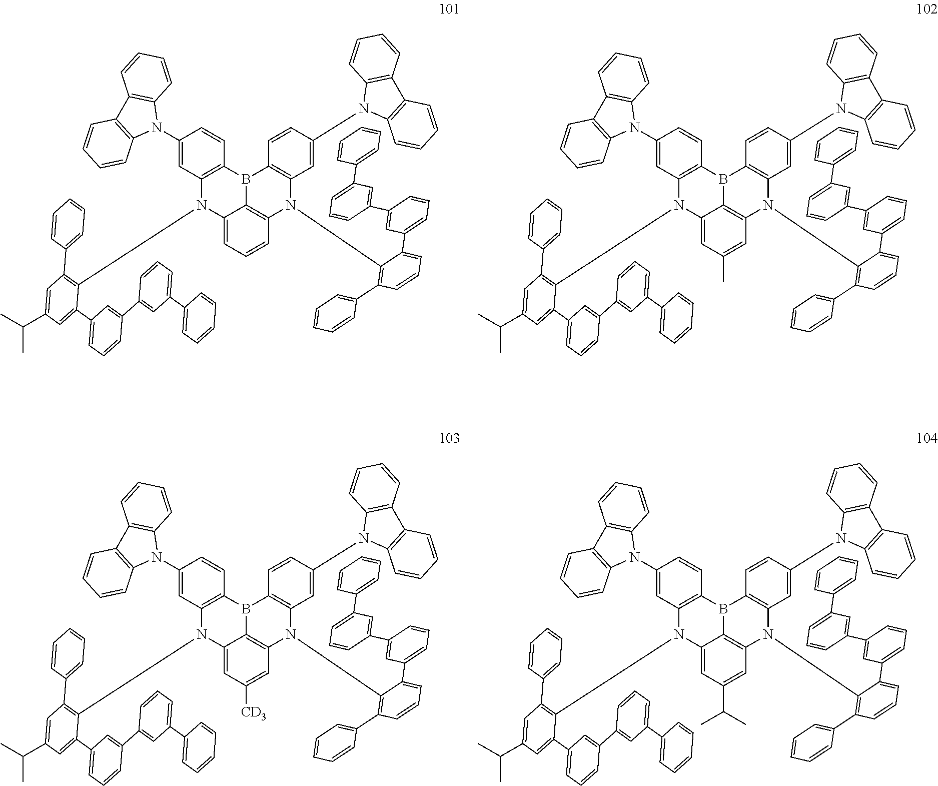 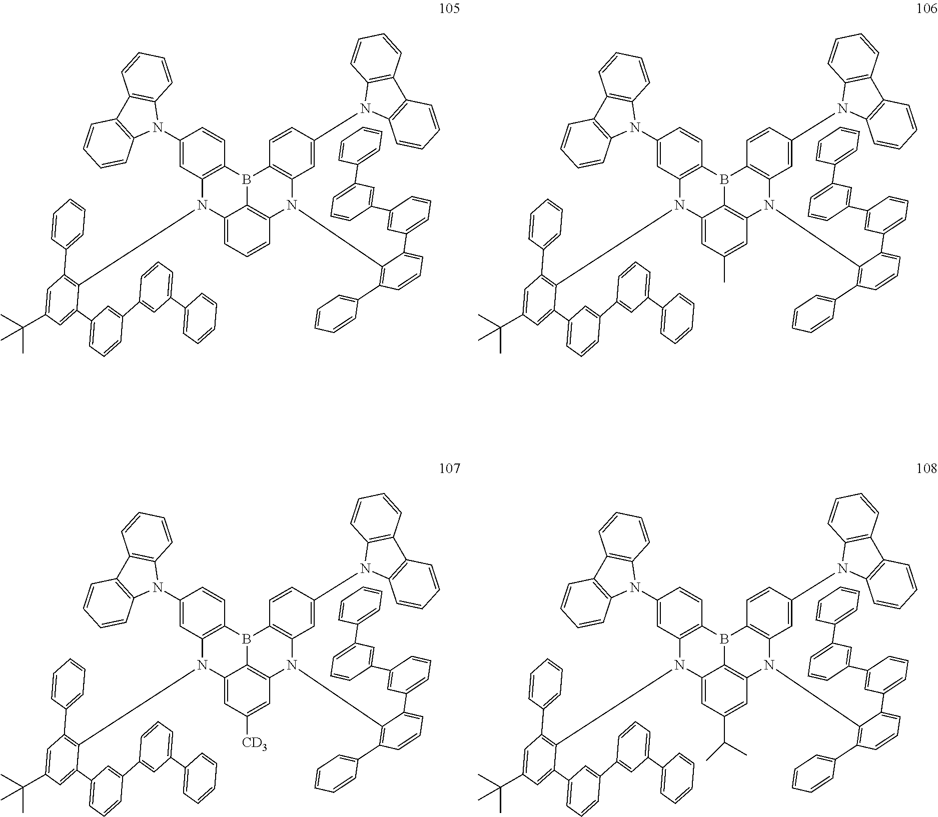 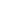 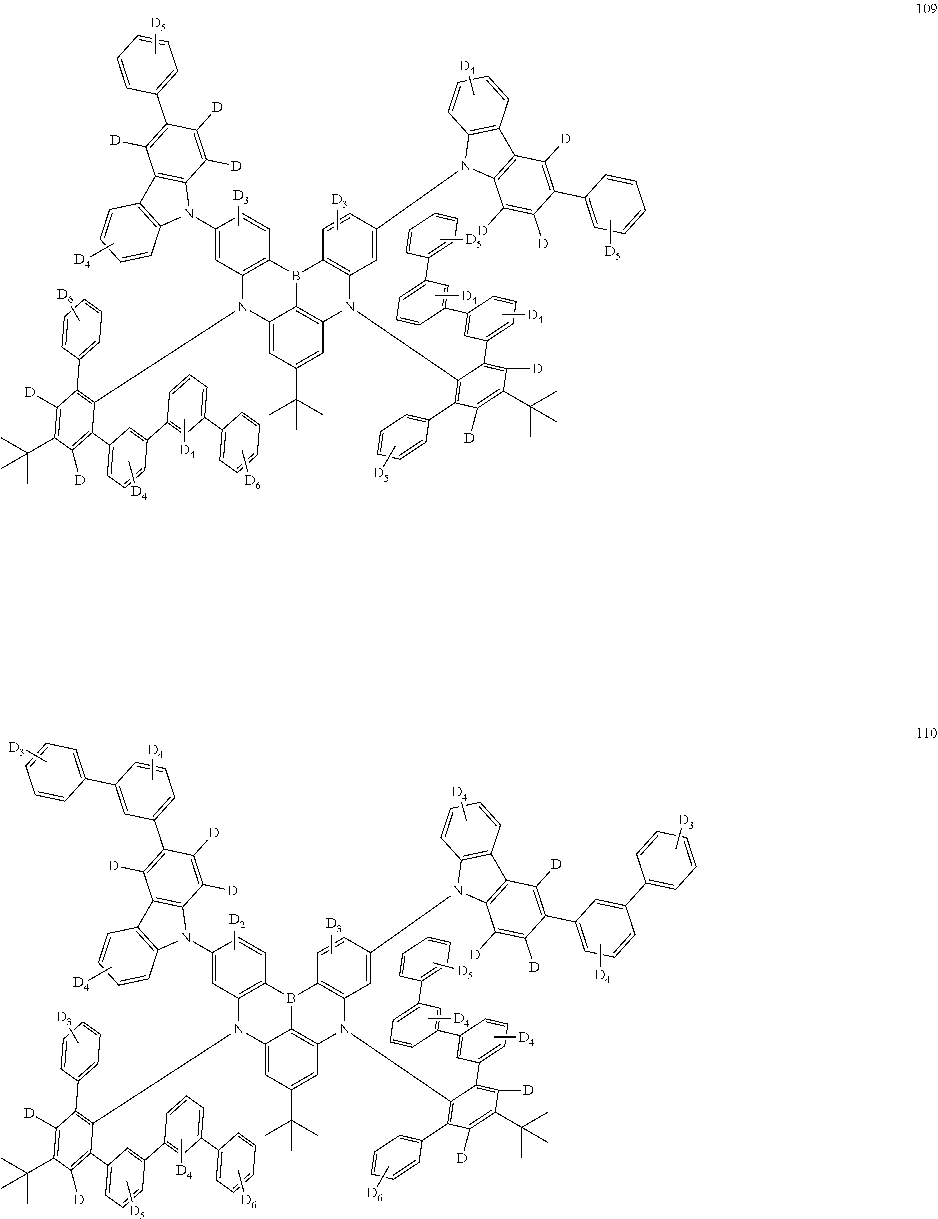 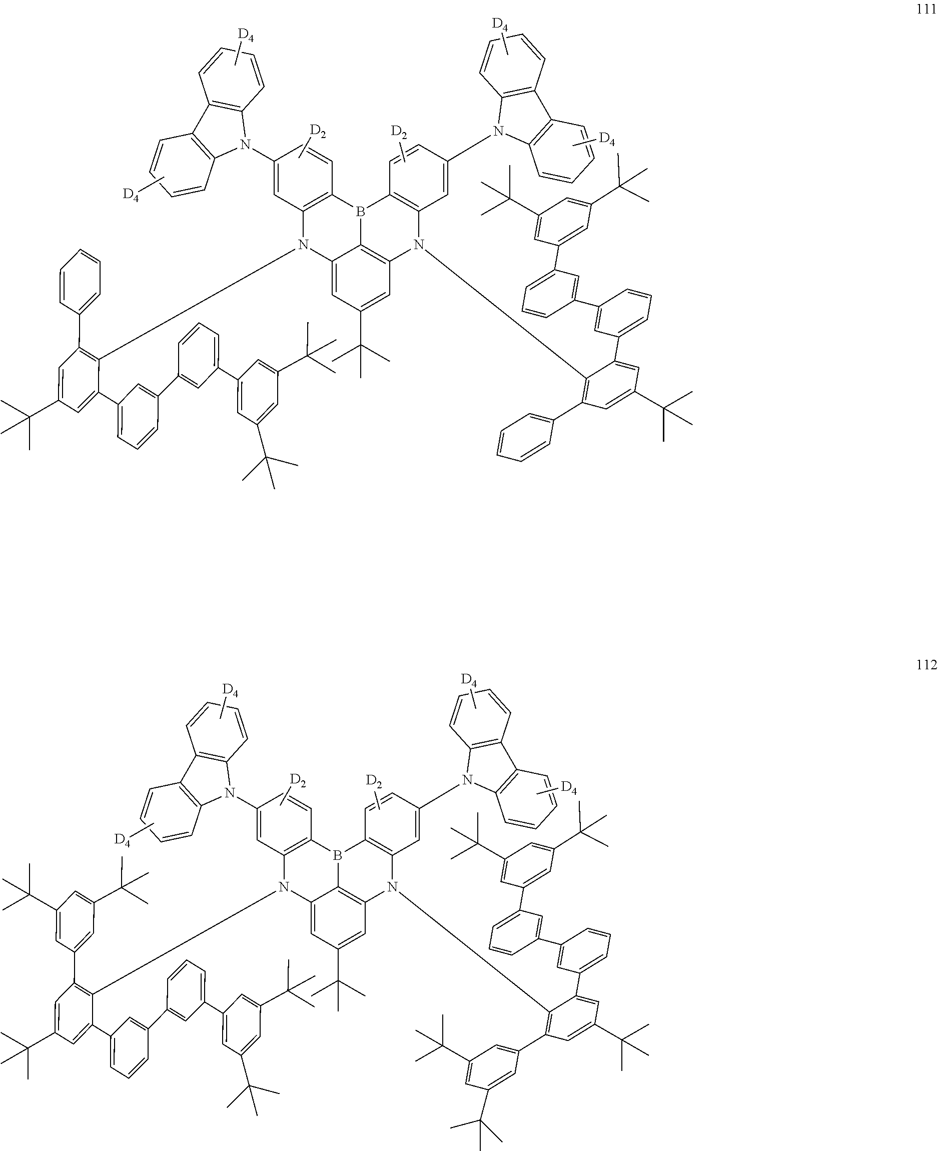 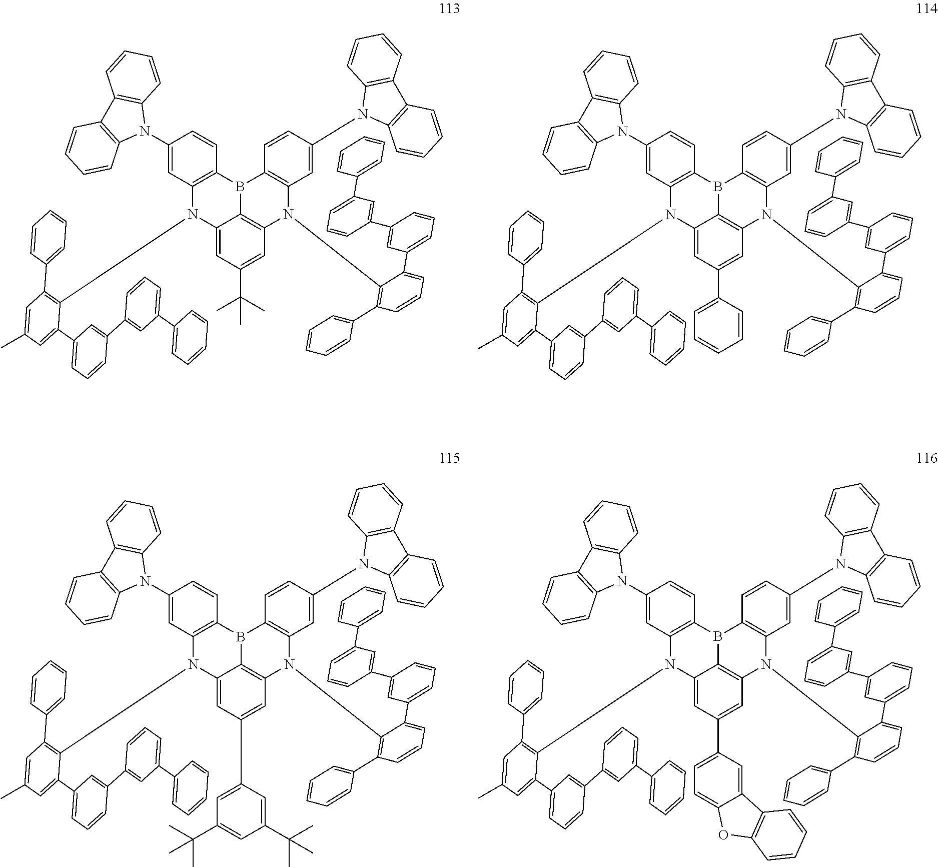 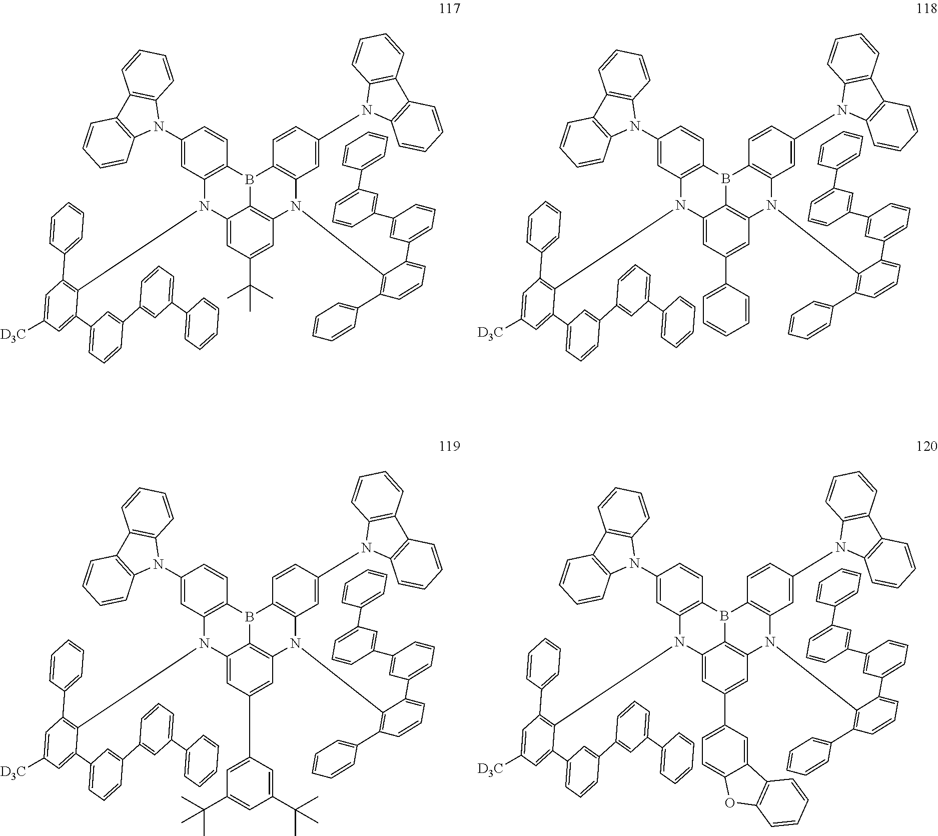 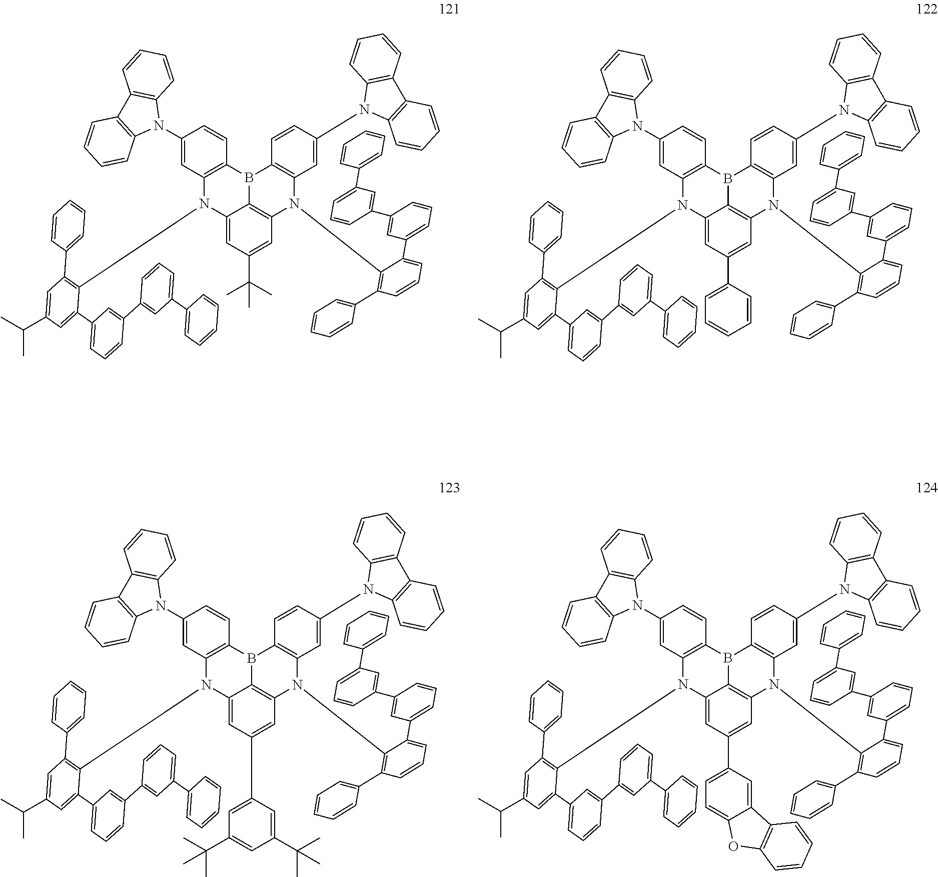 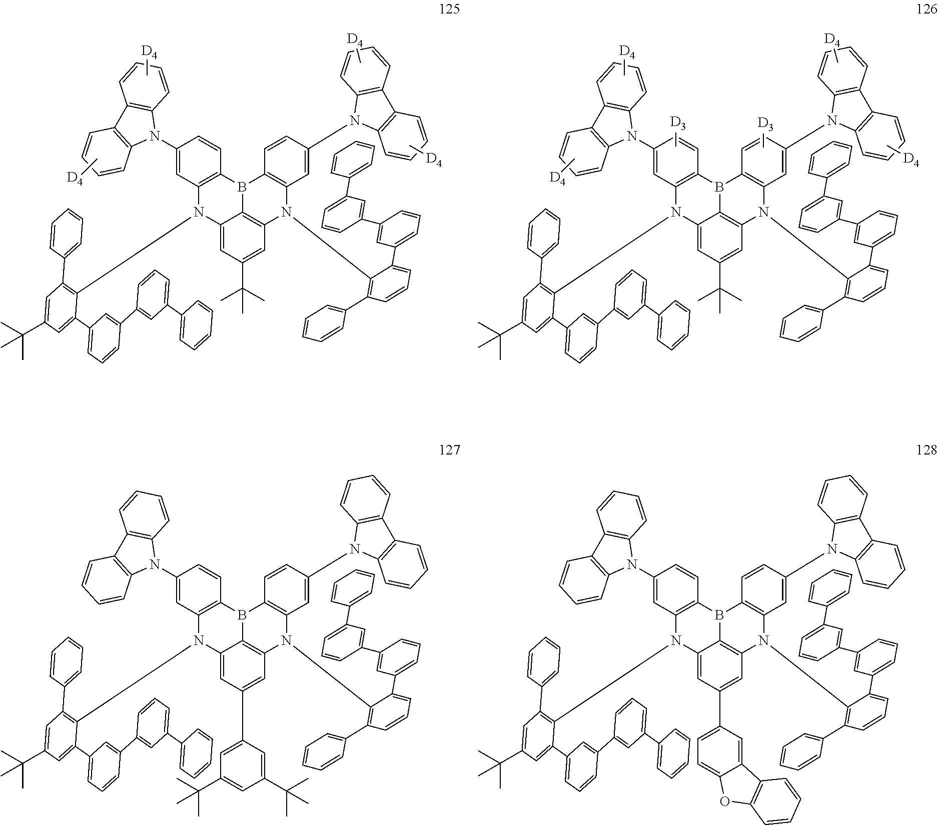 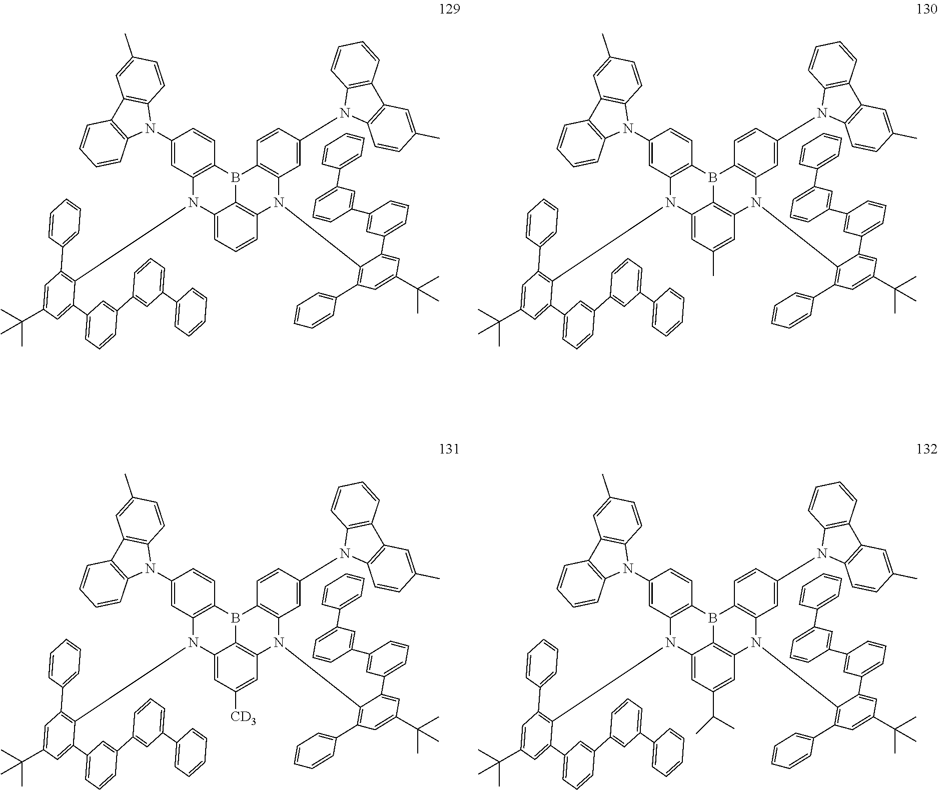 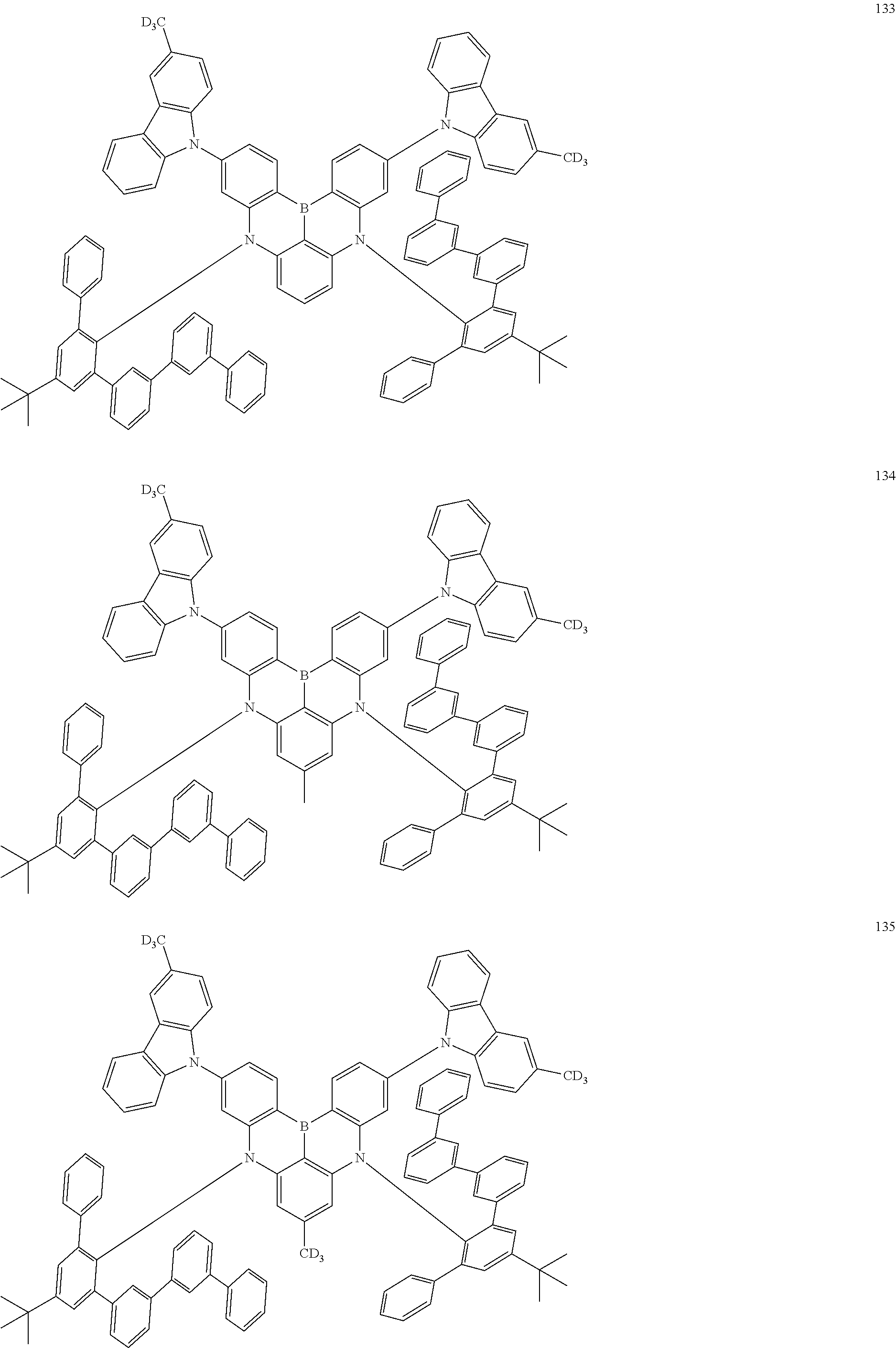 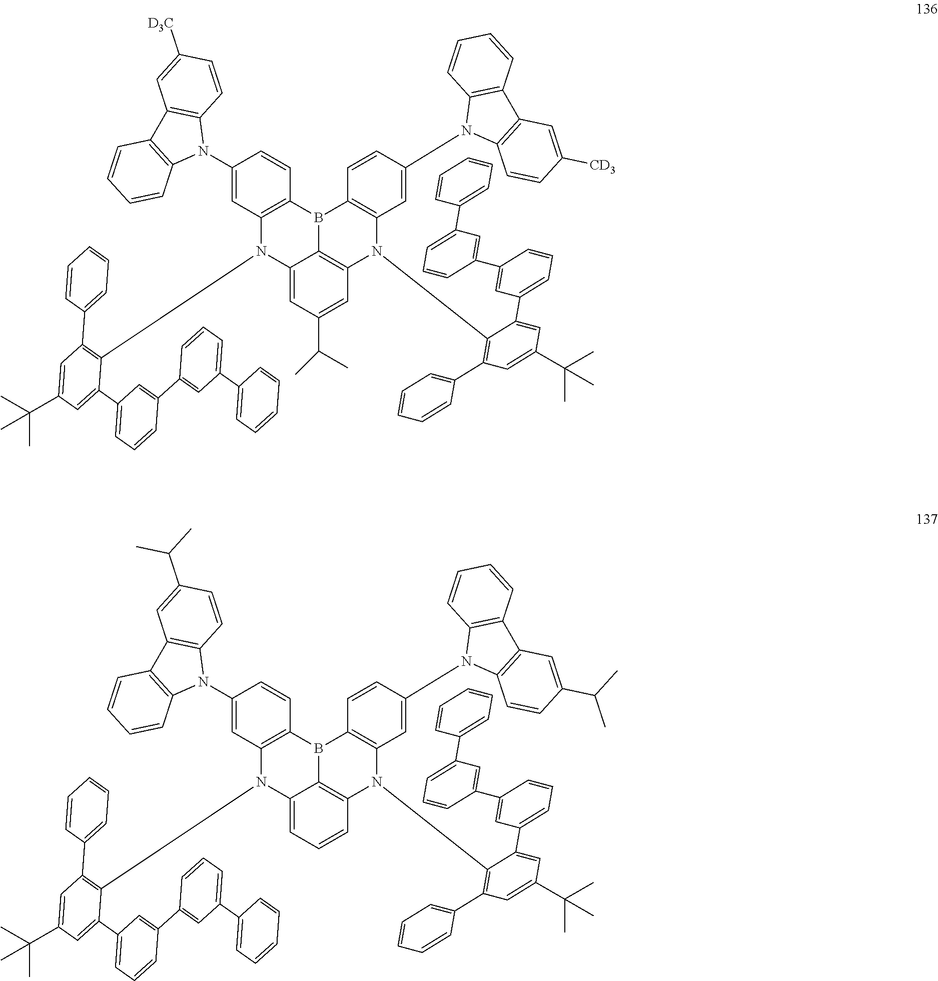 [SMILES: [2H]C([2H])([2H])c1ccc2c(c1)c1ccccc1n2-c1ccc2c(c1)N(c1c(-c3ccccc3)cc(C(C)(C)C)cc1-c1cccc(-c3cccc(-c4ccccc4)c3)c1)c1cc(C(C)C)cc3c1B2c1ccc(-n2c4ccccc4c4cc(C([2H])([2H])[2H])ccc42)cc1N3c1c(-c2ccccc2)cc(C(C)(C)C)cc1-c1cccc(-c2cccc(-c3ccccc3)c2)c1 ; CC(C)c1ccc2c(c1)c1ccccc1n2-c1ccc2c(c1)N(c1c(-c3ccccc3)cc(C(C)(C)C)cc1-c1cccc(-c3cccc(-c4ccccc4)c3)c1)c1cccc3c1B2c1ccc(-n2c4ccccc4c4cc(C(C)C)ccc42)cc1N3c1c(-c2ccccc2)cc(C(C)(C)C)cc1-c1cccc(-c2cccc(-c3ccccc3)c2)c1] 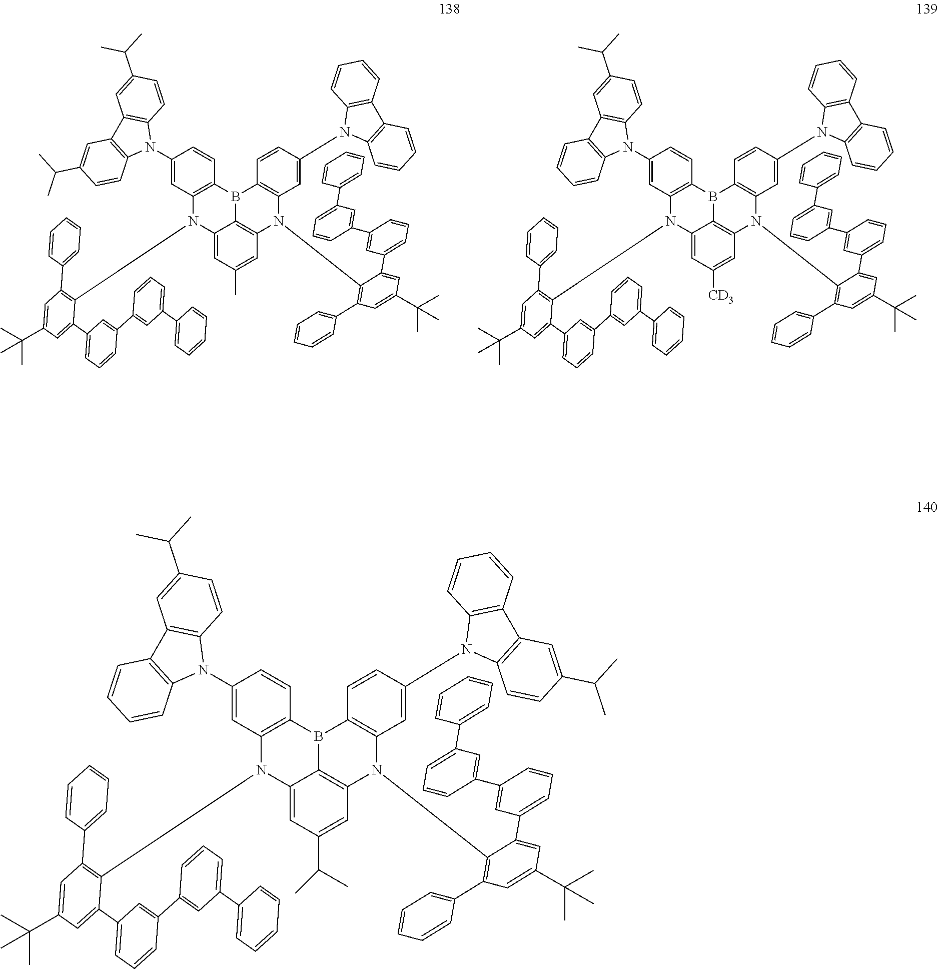 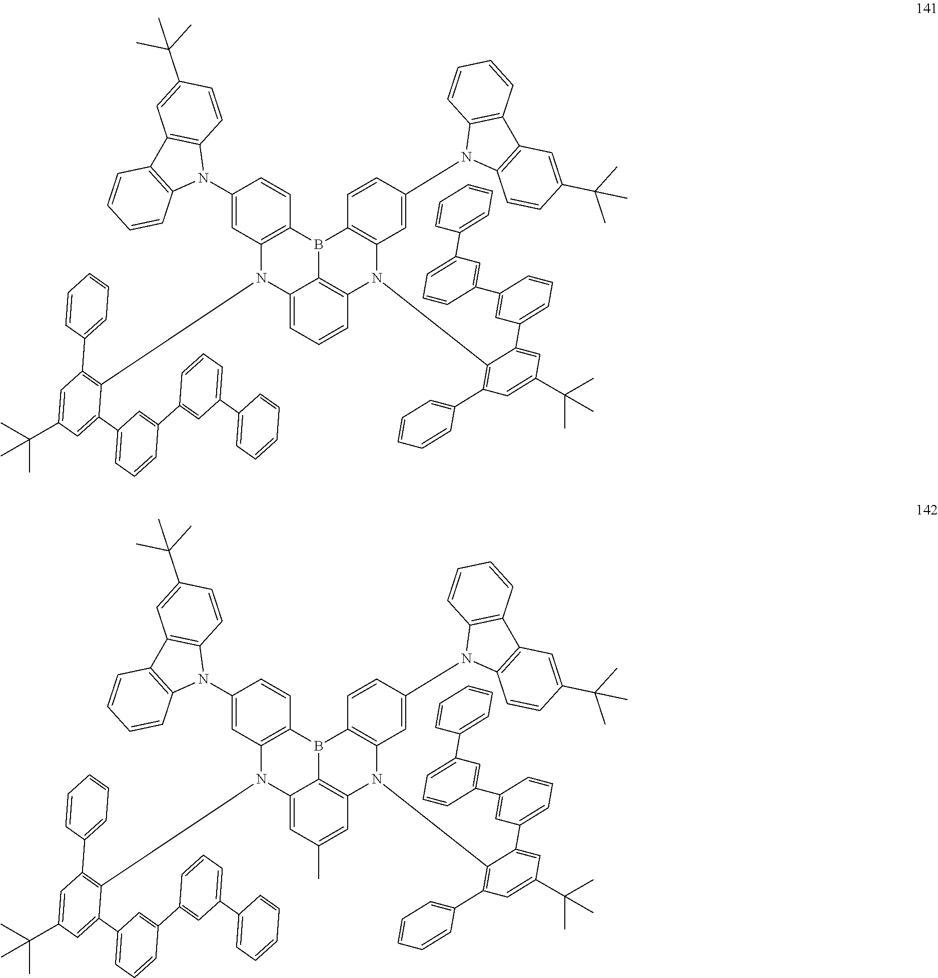 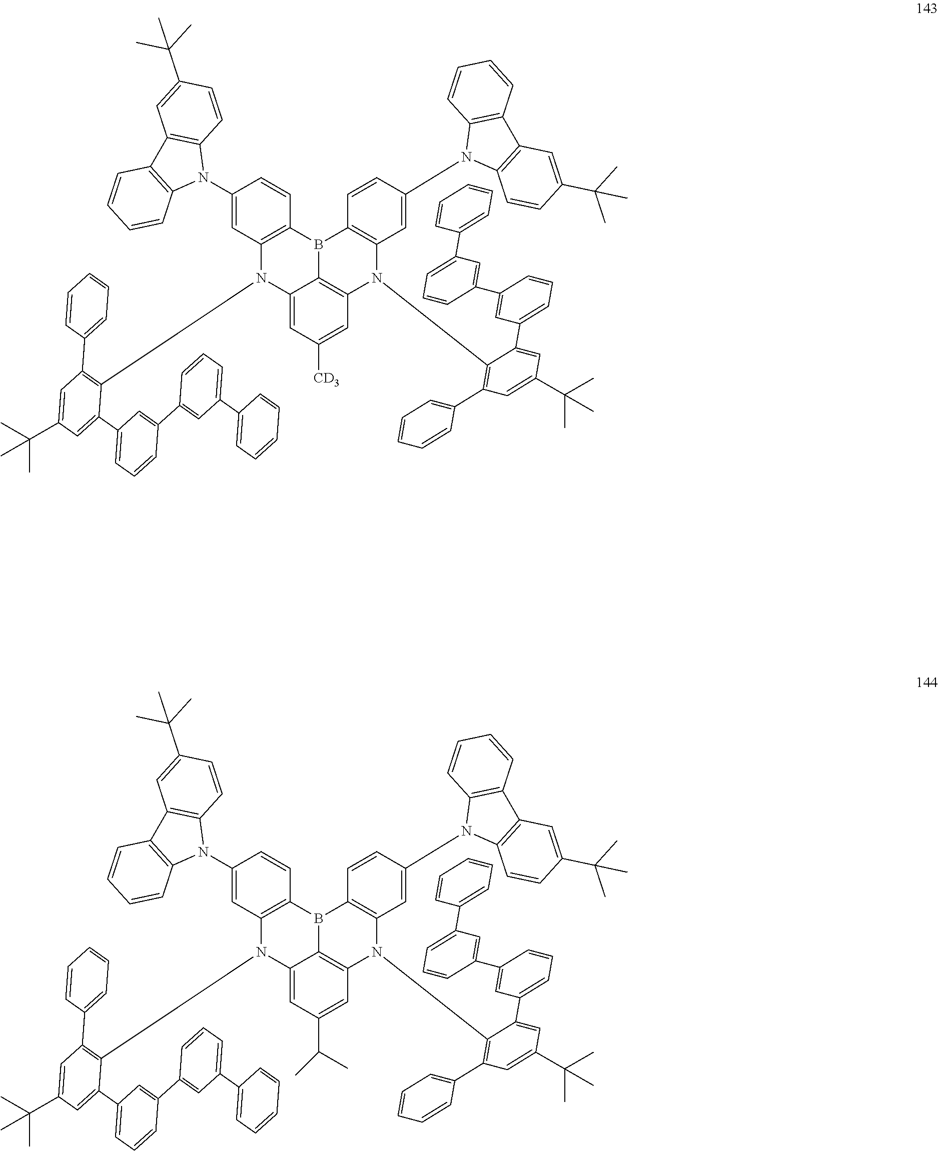 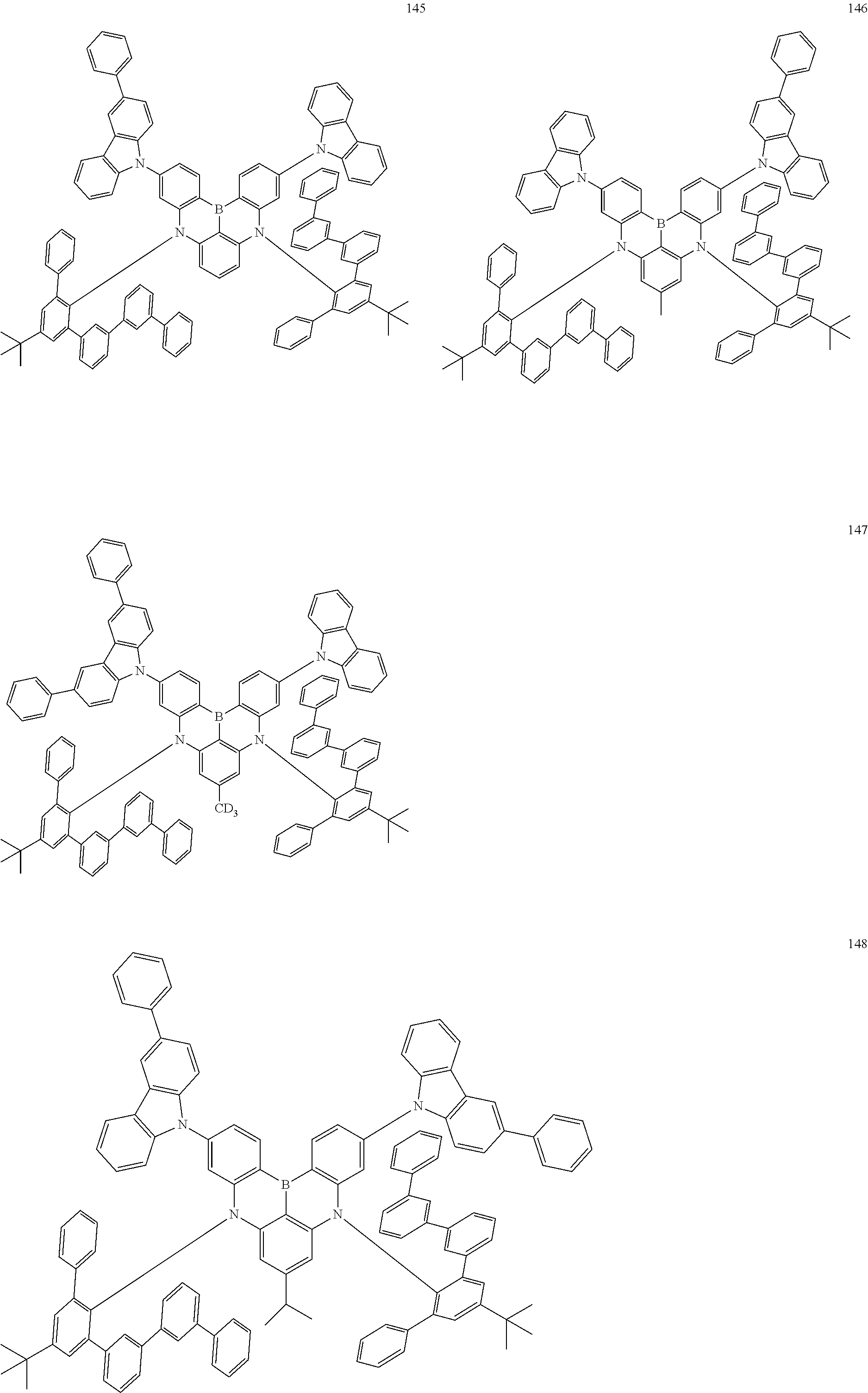 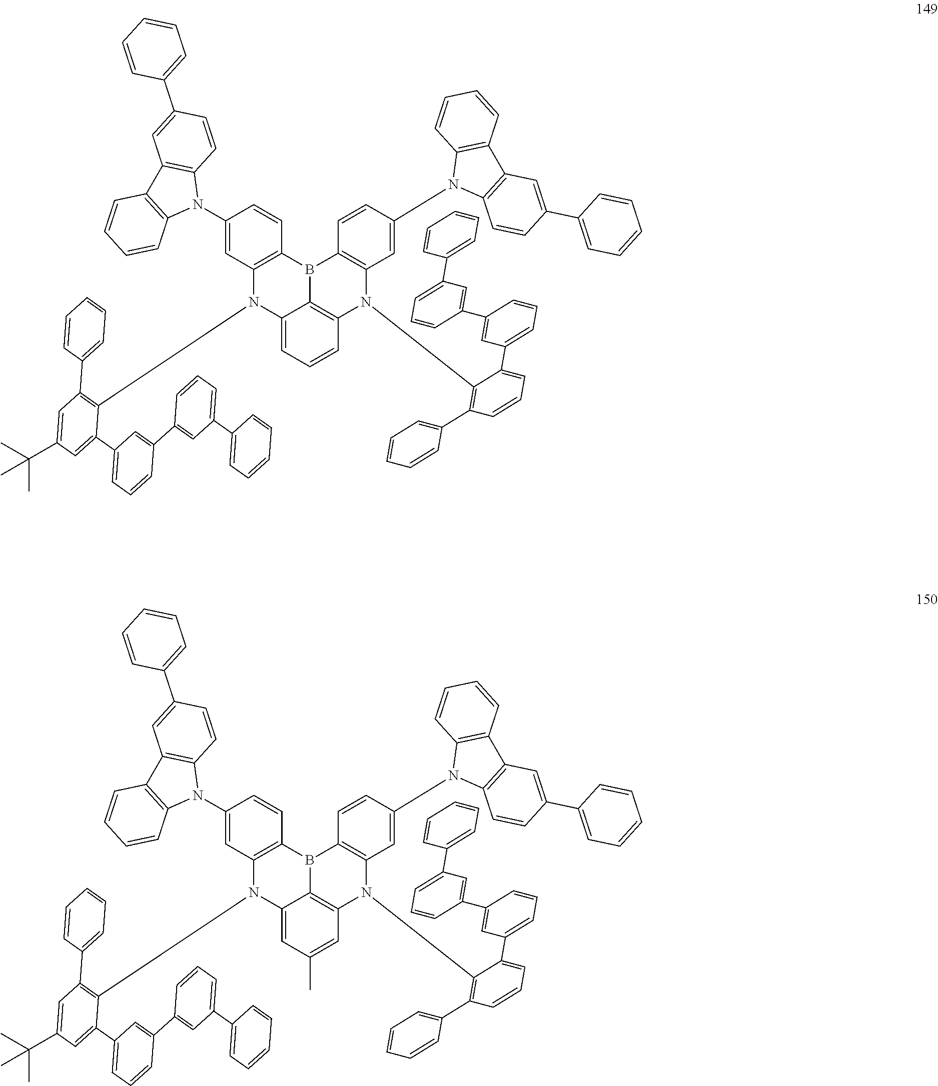 [SMILES: CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccccc5)cccc4-c4cccc(-c5cccc(-c6ccccc6)c5)c4)c4cccc2c43)c(-c2cccc(-c3cccc(-c4ccccc4)c3)c2)c1 ; Cc1cc2c3c(c1)N(c1c(-c4ccccc4)cc(C(C)(C)C)cc1-c1cccc(-c4cccc(-c5ccccc5)c4)c1)c1cc(-n4c5ccccc5c5cc(-c6ccccc6)ccc54)ccc1B3c1ccc(-n3c4ccccc4c4cc(-c5ccccc5)ccc43)cc1N2c1c(-c2ccccc2)cccc1-c1cccc(-c2cccc(-c3ccccc3)c2)c1] 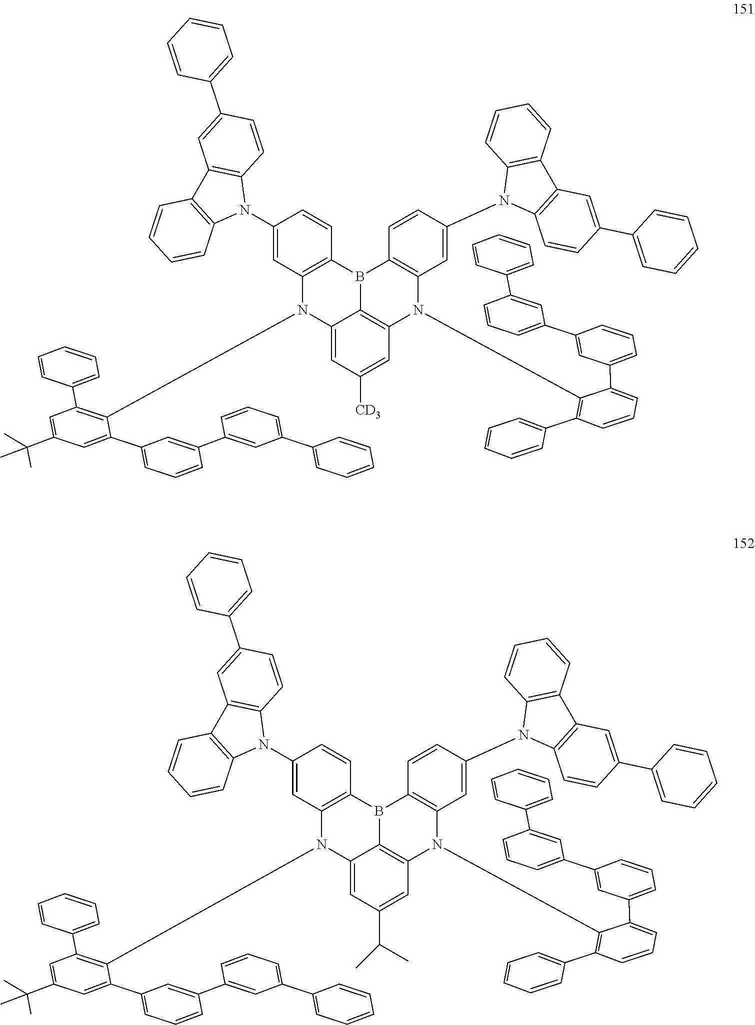 [SMILES: [2H]C([2H])([2H])c1cc2c3c(c1)N(c1c(-c4ccccc4)cc(C(C)(C)C)cc1-c1cccc(-c4cccc(-c5ccccc5)c4)c1)c1cc(-n4c5ccccc5c5cc(-c6ccccc6)ccc54)ccc1B3c1ccc(-n3c4ccccc4c4cc(-c5ccccc5)ccc43)cc1N2c1c(-c2ccccc2)cccc1-c1cccc(-c2cccc(-c3ccccc3)c2)c1 ; CC(C)c1cc2c3c(c1)N(c1c(-c4ccccc4)cc(C(C)(C)C)cc1-c1cccc(-c4cccc(-c5ccccc5)c4)c1)c1cc(-n4c5ccccc5c5cc(-c6ccccc6)ccc54)ccc1B3c1ccc(-n3c4ccccc4c4cc(-c5ccccc5)ccc43)cc1N2c1c(-c2ccccc2)cccc1-c1cccc(-c2cccc(-c3ccccc3)c2)c1] 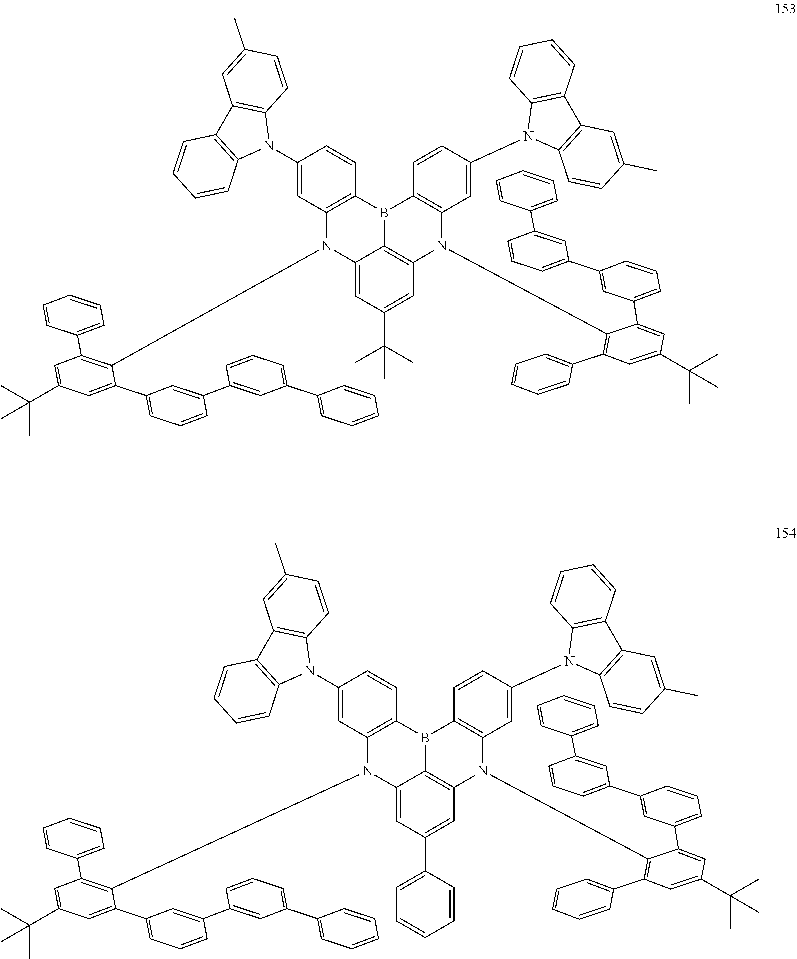 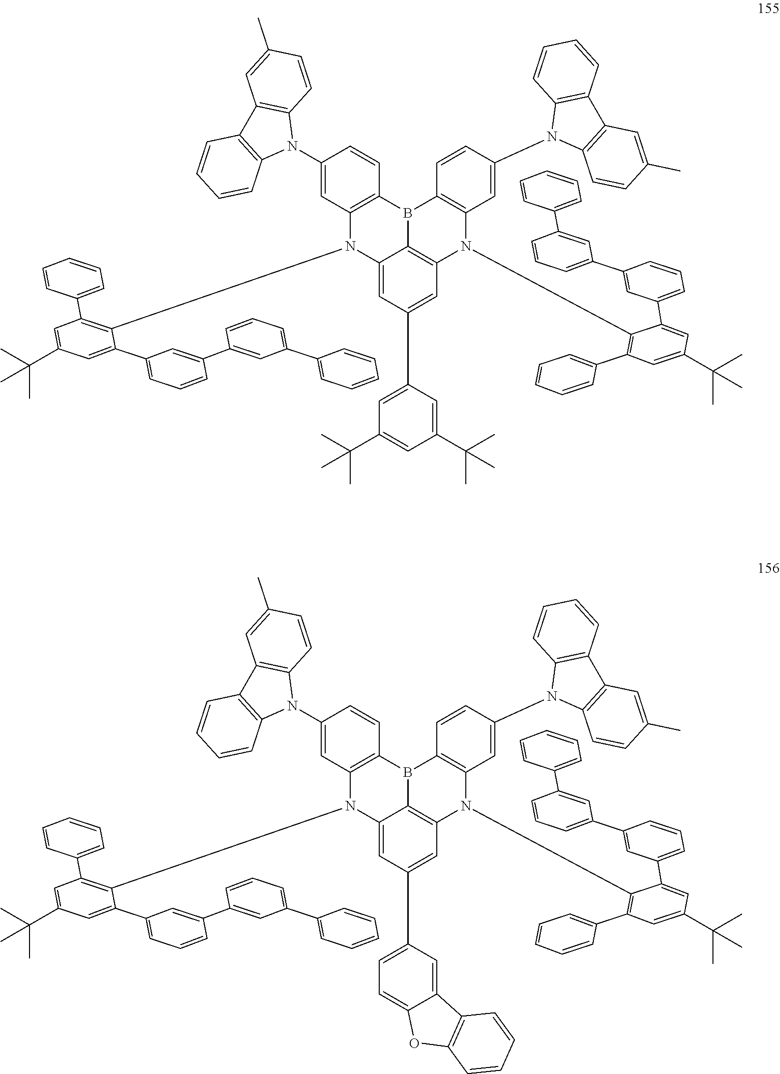 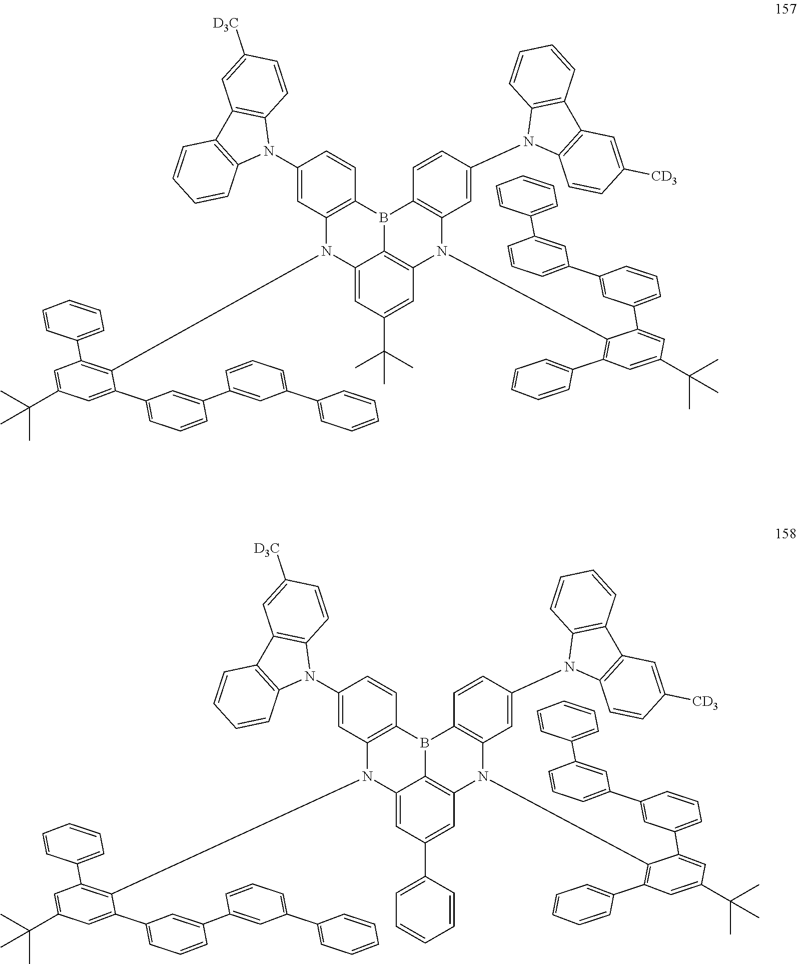 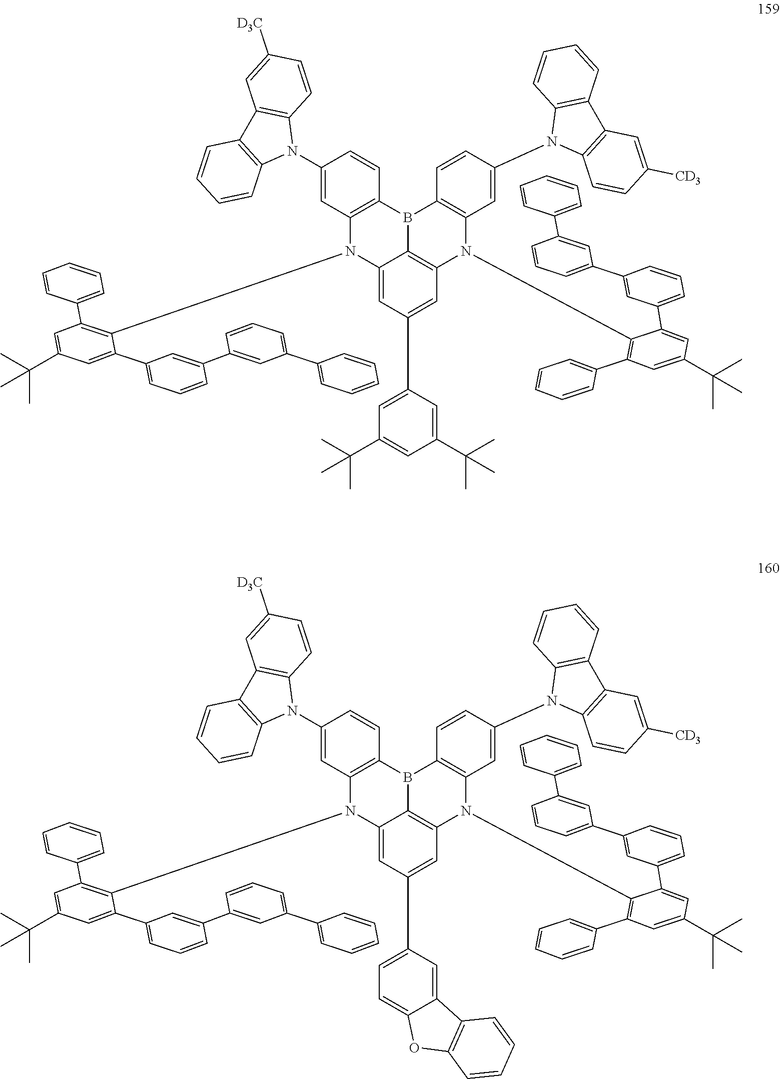 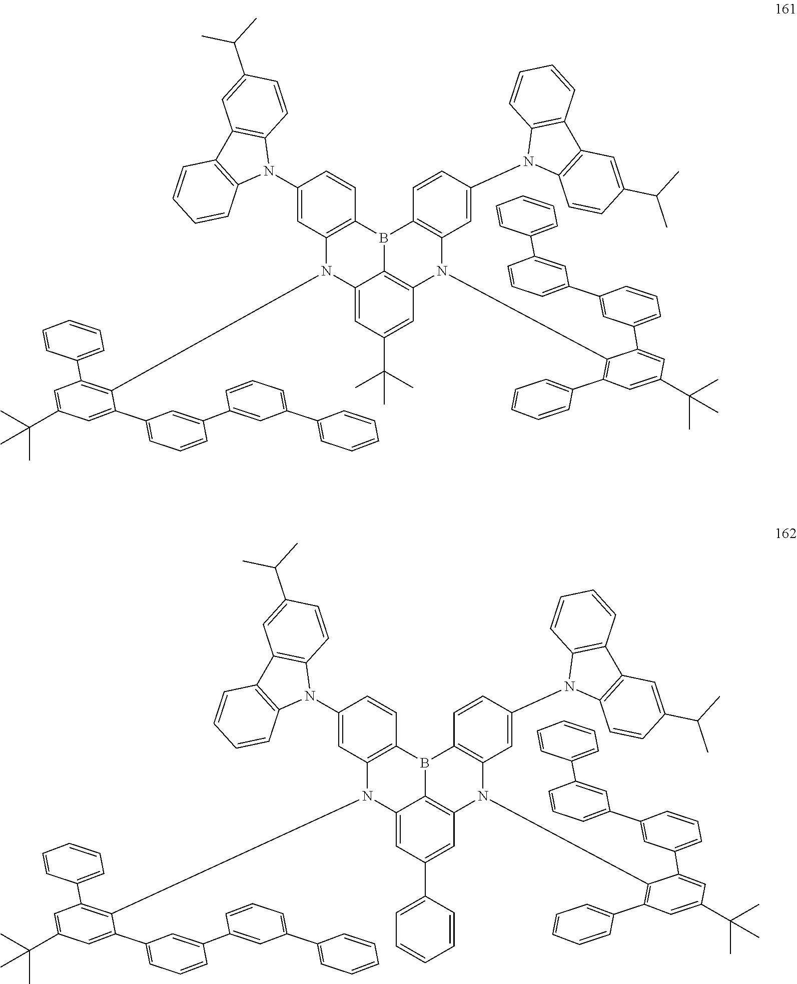 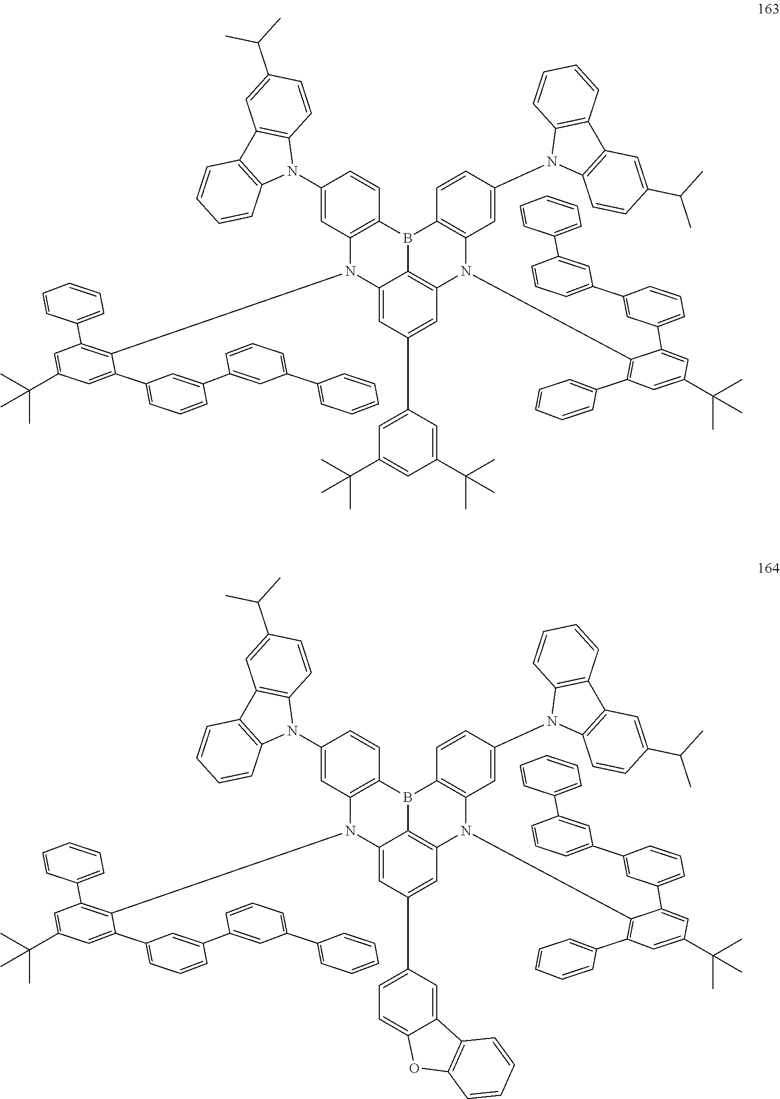 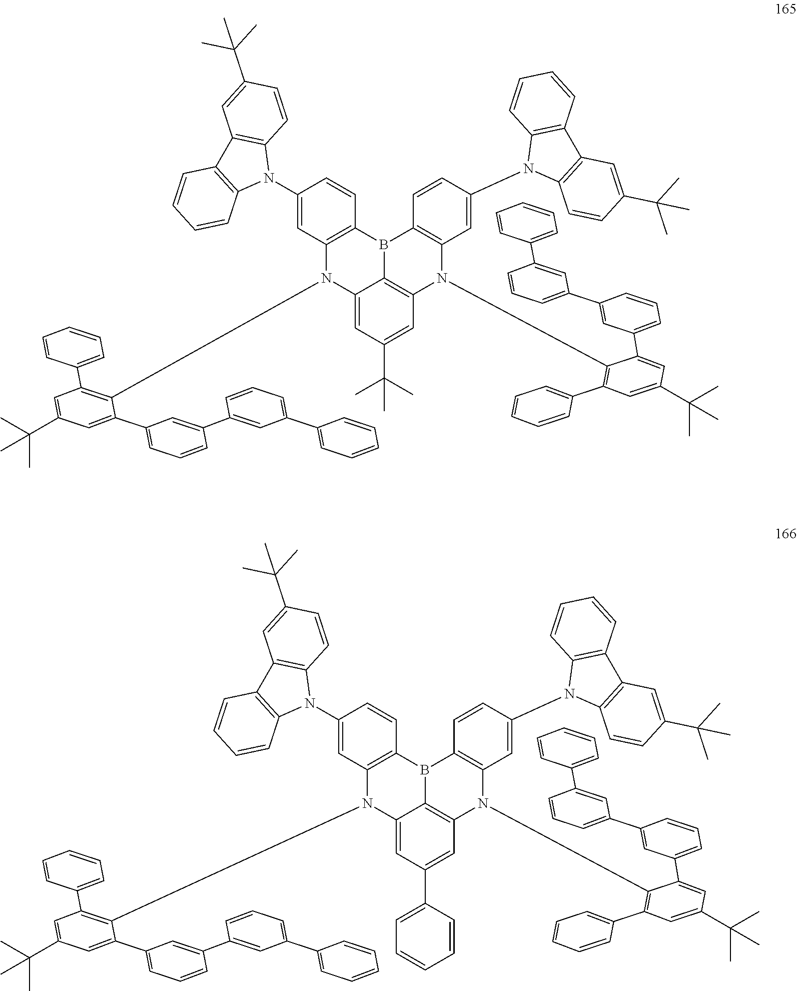 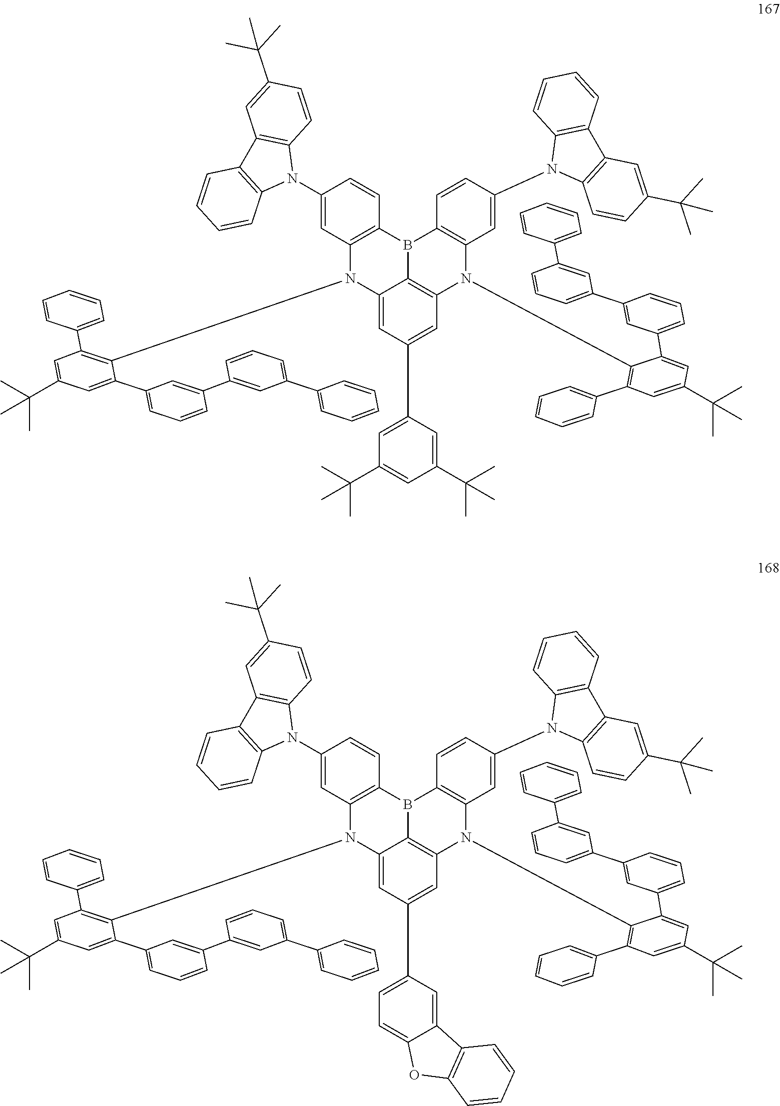 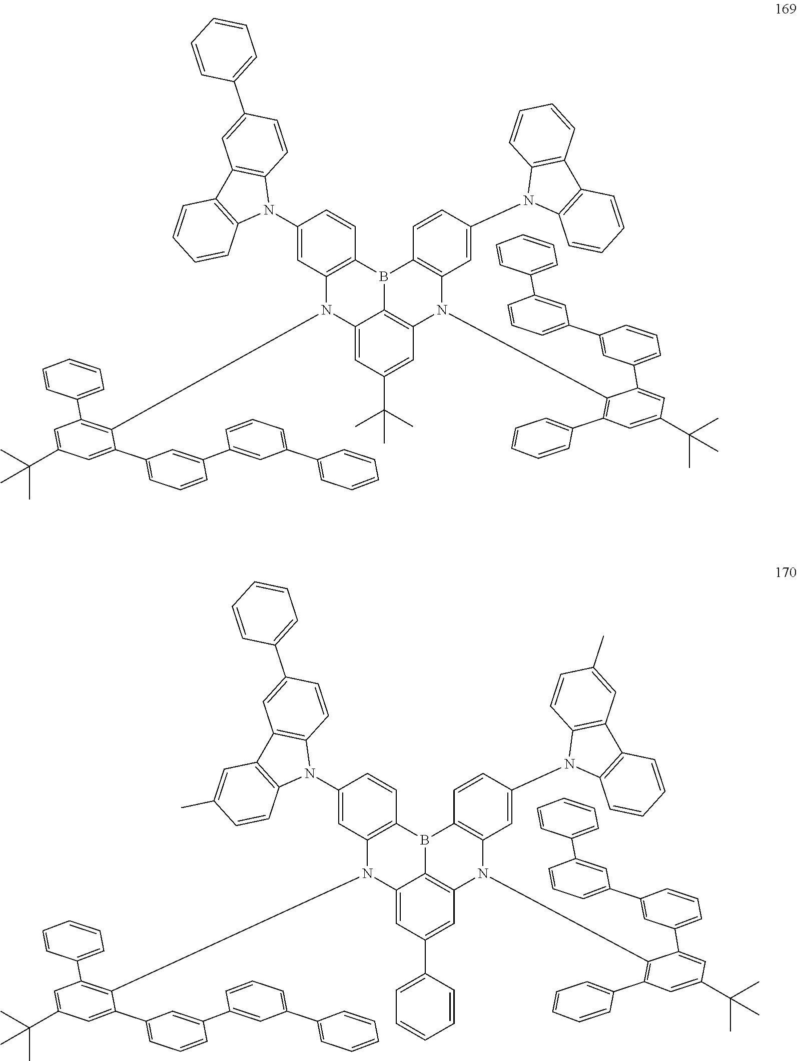 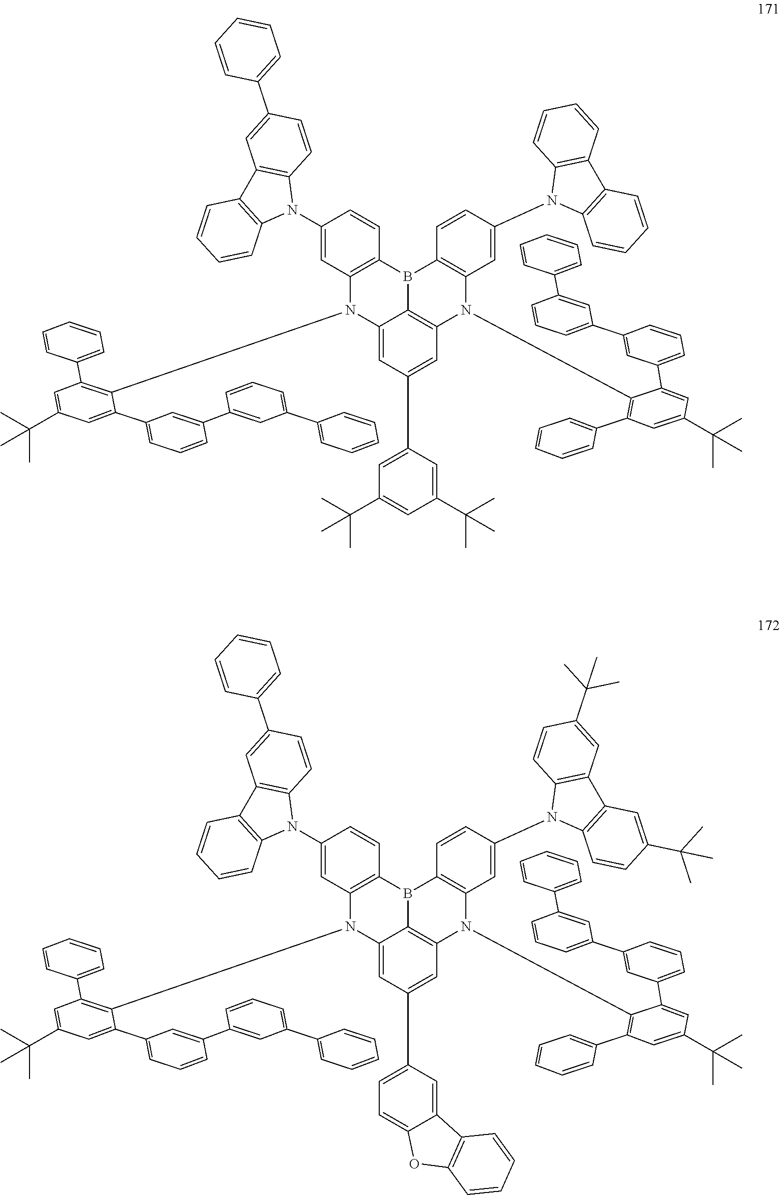 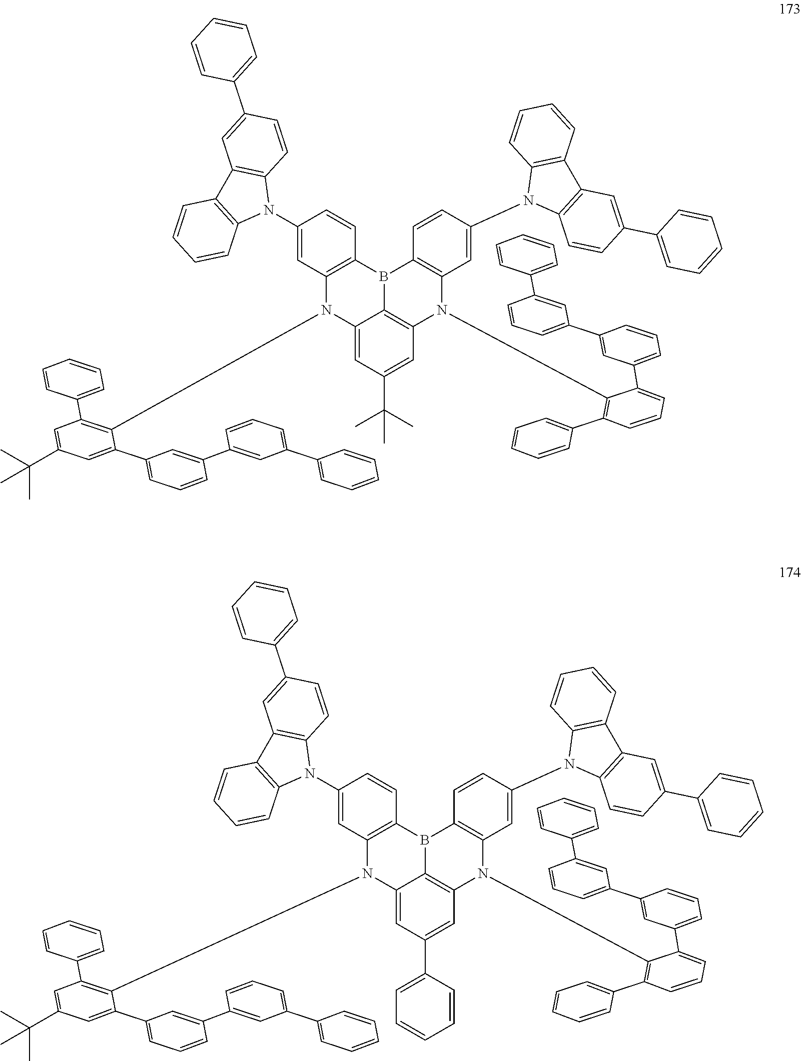 [SMILES: CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccccc5)cccc4-c4cccc(-c5cccc(-c6ccccc6)c5)c4)c4cc(C(C)(C)C)cc2c43)c(-c2cccc(-c3cccc(-c4ccccc4)c3)c2)c1 ; CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccccc5)cccc4-c4cccc(-c5cccc(-c6ccccc6)c5)c4)c4cc(-c5ccccc5)cc2c43)c(-c2cccc(-c3cccc(-c4ccccc4)c3)c2)c1] 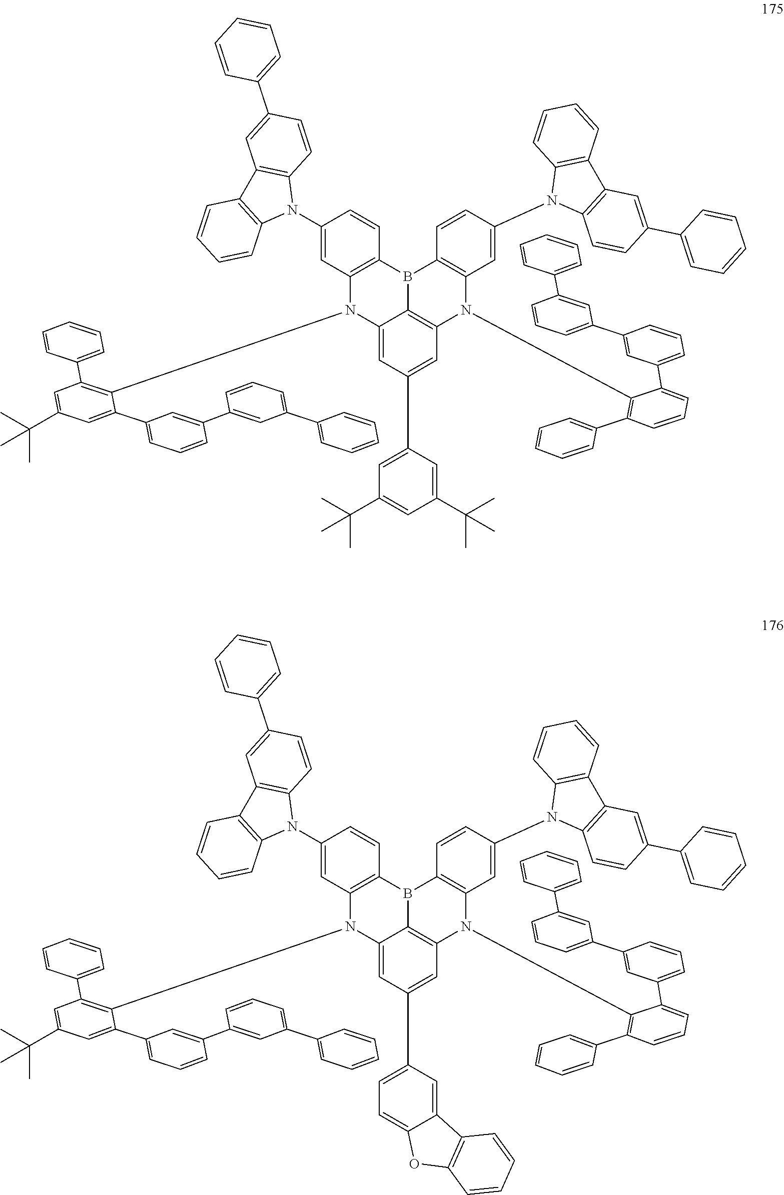 [SMILES: CC(C)(C)c1cc(-c2cc3c4c(c2)N(c2c(-c5ccccc5)cc(C(C)(C)C)cc2-c2cccc(-c5cccc(-c6ccccc6)c5)c2)c2cc(-n5c6ccccc6c6cc(-c7ccccc7)ccc65)ccc2B4c2ccc(-n4c5ccccc5c5cc(-c6ccccc6)ccc54)cc2N3c2c(-c3ccccc3)cccc2-c2cccc(-c3cccc(-c4ccccc4)c3)c2)cc(C(C)(C)C)c1 ; CC(C)(C)c1cc(-c2ccccc2)c(N2c3cc(-n4c5ccccc5c5cc(-c6ccccc6)ccc54)ccc3B3c4ccc(-n5c6ccccc6c6cc(-c7ccccc7)ccc65)cc4N(c4c(-c5ccccc5)cccc4-c4cccc(-c5cccc(-c6ccccc6)c5)c4)c4cc(-c5ccc6oc7ccccc7c6c5)cc2c43)c(-c2cccc(-c3cccc(-c4ccccc4)c3)c2)c1] 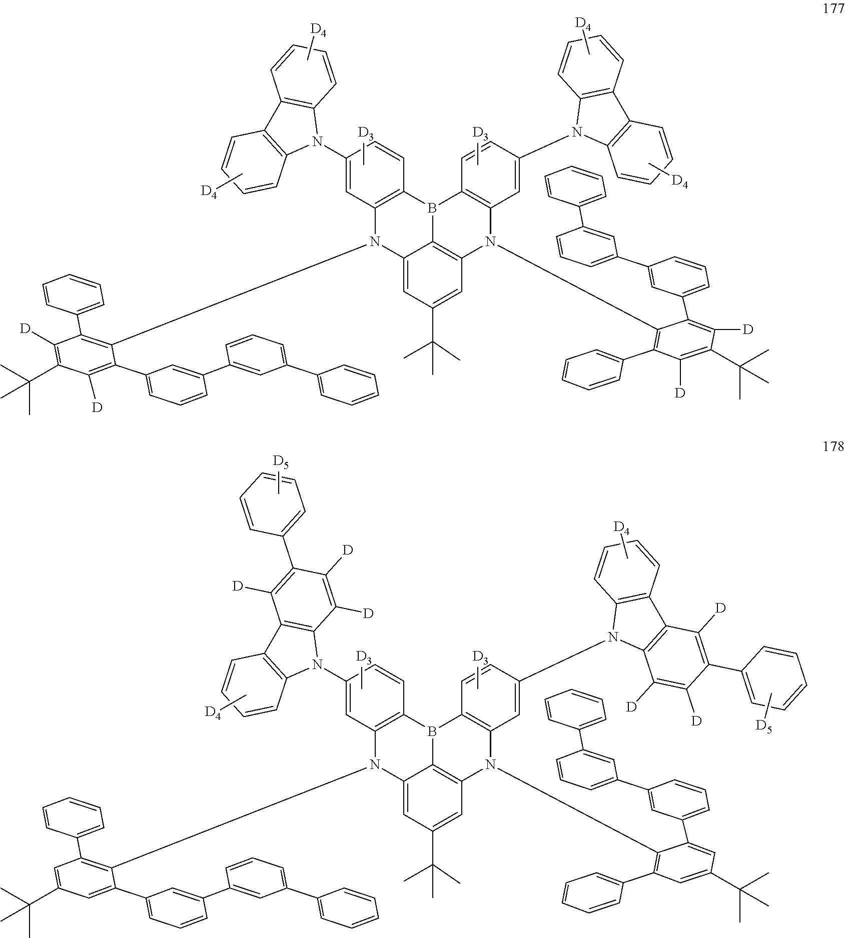 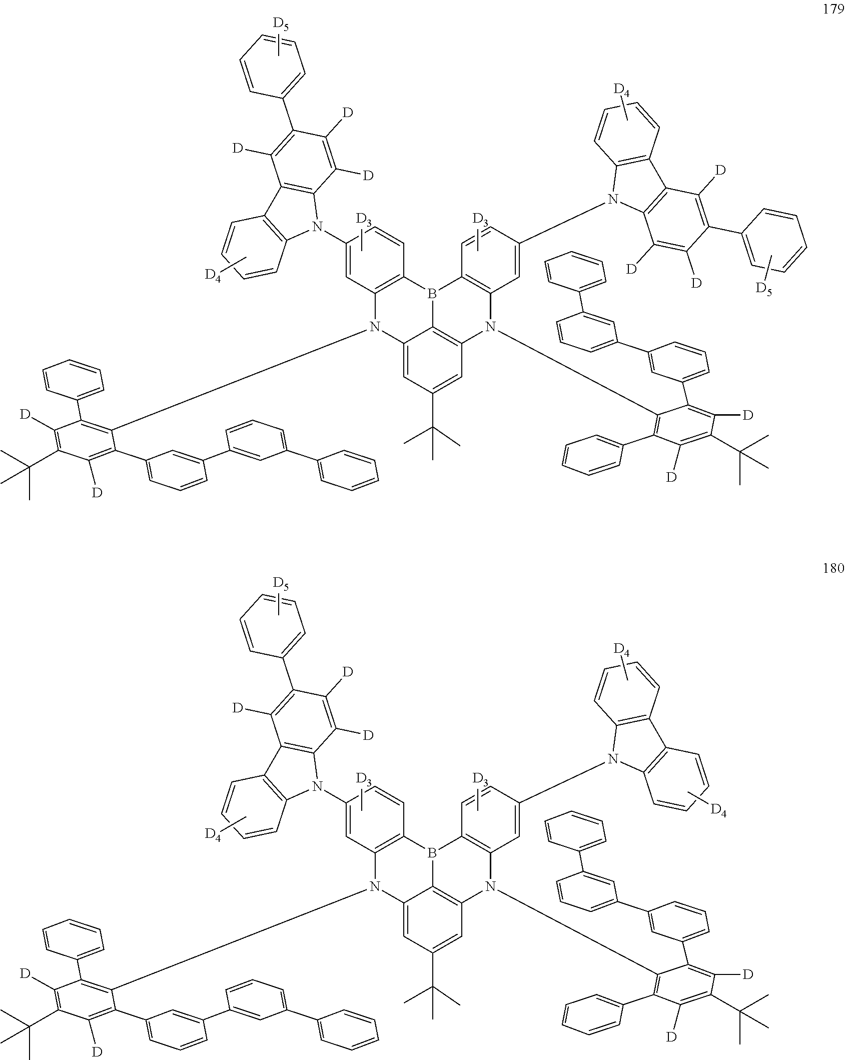 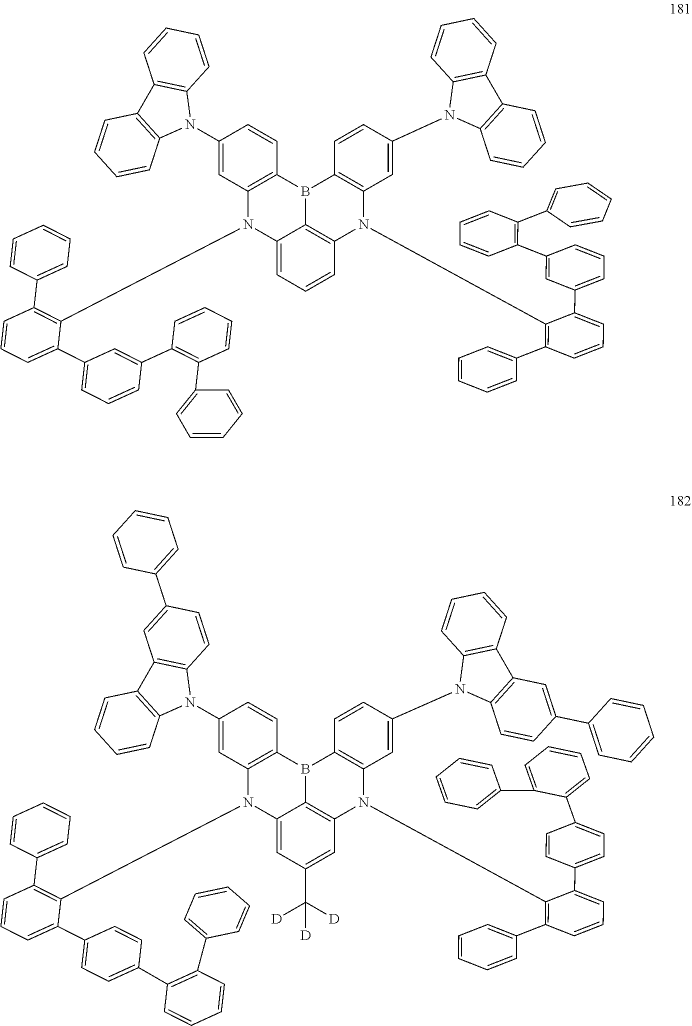 [SMILES: c1ccc(-c2ccccc2-c2cccc(-c3cccc(-c4ccccc4)c3N3c4cc(-n5c6ccccc6c6ccccc65)ccc4B4c5ccc(-n6c7ccccc7c7ccccc76)cc5N(c5c(-c6ccccc6)cccc5-c5cccc(-c6ccccc6-c6ccccc6)c5)c5cccc3c54)c2)cc1 ; [2H]C([2H])([2H])c1cc2c3c(c1)N(c1c(-c4ccccc4)cccc1-c1ccc(-c4ccccc4-c4ccccc4)cc1)c1cc(-n4c5ccccc5c5cc(-c6ccccc6)ccc54)ccc1B3c1ccc(-n3c4ccccc4c4cc(-c5ccccc5)ccc43)cc1N2c1c(-c2ccccc2)cccc1-c1ccc(-c2ccccc2-c2ccccc2)cc1] 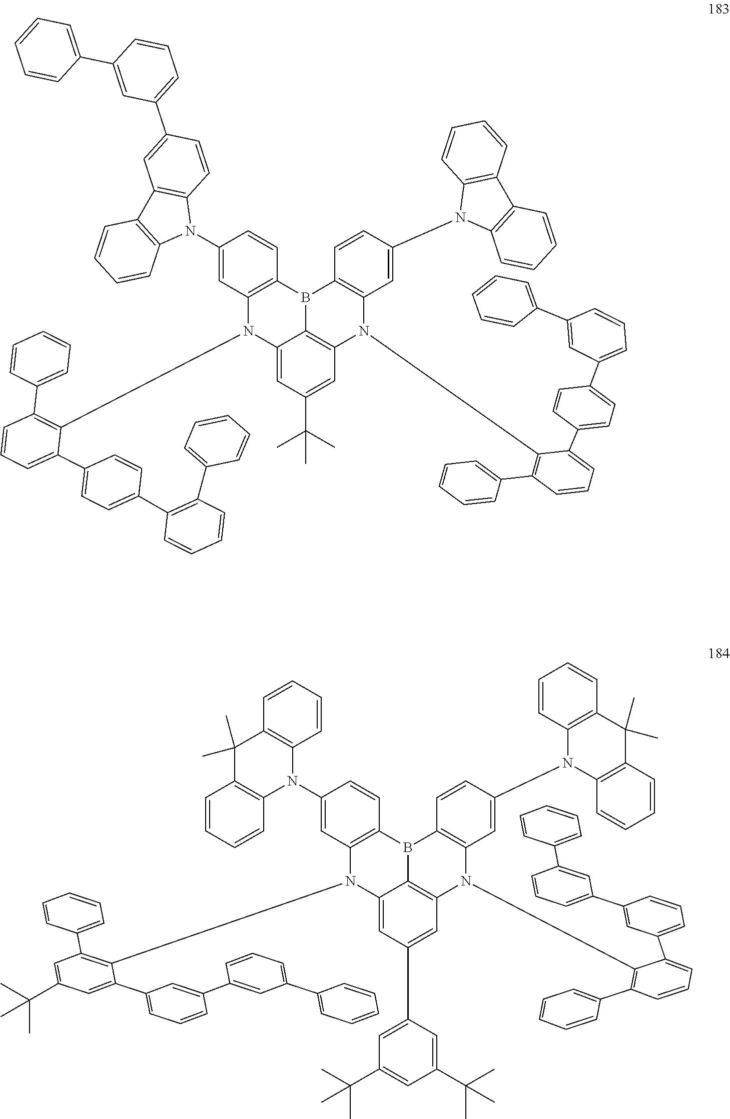 [SMILES: CC(C)(C)c1cc2c3c(c1)N(c1c(-c4ccccc4)cccc1-c1ccc(-c4ccccc4-c4ccccc4)cc1)c1cc(-n4c5ccccc5c5cc(-c6cccc(-c7ccccc7)c6)ccc54)ccc1B3c1ccc(-n3c4ccccc4c4ccccc43)cc1N2c1c(-c2ccccc2)cccc1-c1ccc(-c2cccc(-c3ccccc3)c2)cc1 ; CC(C)(C)c1cc(-c2cc3c4c(c2)N(c2c(-c5ccccc5)cc(C(C)(C)C)cc2-c2cccc(-c5cccc(-c6ccccc6)c5)c2)c2cc(N5c6ccccc6C(C)(C)c6ccccc65)ccc2B4c2ccc(N4c5ccccc5C(C)(C)c5ccccc54)cc2N3c2c(-c3ccccc3)cccc2-c2cccc(-c3cccc(-c4ccccc4)c3)c2)cc(C(C)(C)C)c1] 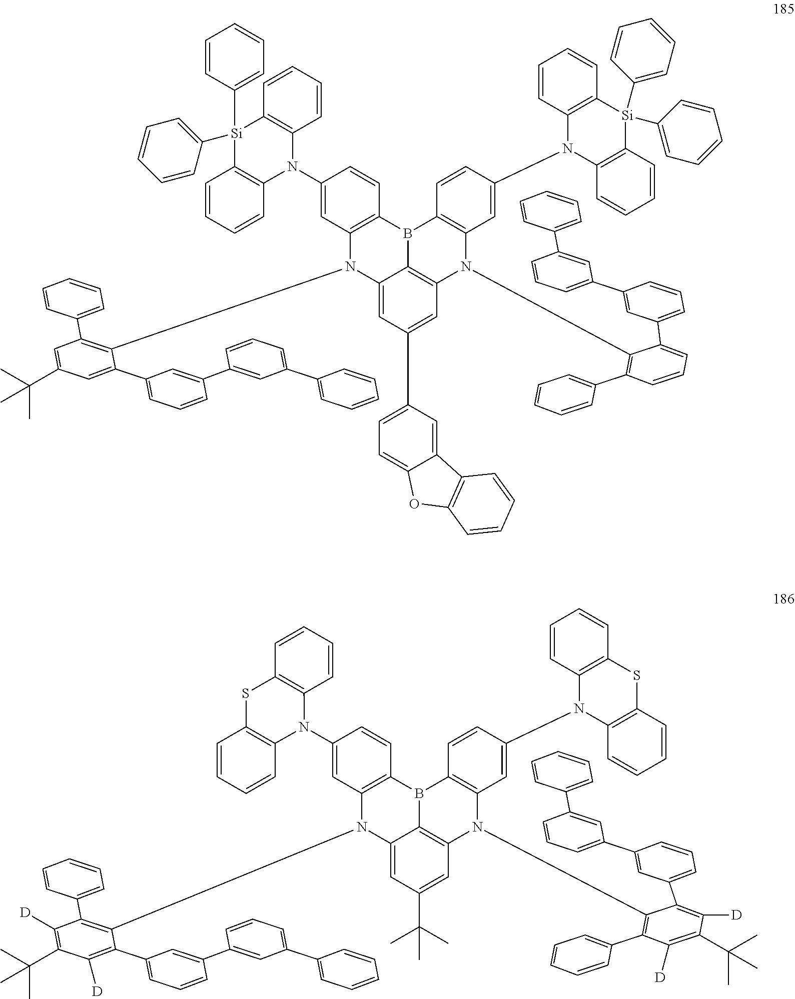 [SMILES: CC(C)(C)c1cc(-c2ccccc2)c(N2c3cc(N4c5ccccc5[Si](c5ccccc5)(c5ccccc5)c5ccccc54)ccc3B3c4ccc(N5c6ccccc6[Si](c6ccccc6)(c6ccccc6)c6ccccc65)cc4N(c4c(-c5ccccc5)cccc4-c4cccc(-c5cccc(-c6ccccc6)c5)c4)c4cc(-c5ccc6oc7ccccc7c6c5)cc2c43)c(-c2cccc(-c3cccc(-c4ccccc4)c3)c2)c1 ; [2H]c1c(-c2ccccc2)c(N2c3cc(N4c5ccccc5Sc5ccccc54)ccc3B3c4ccc(N5c6ccccc6Sc6ccccc65)cc4N(c4c(-c5ccccc5)c([2H])c(C(C)(C)C)c([2H])c4-c4cccc(-c5cccc(-c6ccccc6)c5)c4)c4cc(C(C)(C)C)cc2c43)c(-c2cccc(-c3cccc(-c4ccccc4)c3)c2)c([2H])c1C(C)(C)C] [chemical structure]
